(19) United States
(12) Patent Application Publication
(10) Pub. No.: US 2022/0223803 A1
(43) Pub. Date: Jul. 14, 2022

(54) ORGANIC METAL COMPOUND, ORGANIC LIGHT EMITTING DIODE AND ORGANIC LIGHT EMITTING DEVICE HAVING THE COMPOUND

(71) Applicants: LG DISPLAY CO., LTD., Seoul (KR); LT Materials Co.,Ltd, Yongin-si (KR)

(72) Inventors: Sung-Jin PARK, Paju-si (KR); Do-Han KIM, Paju-si (KR); Hye-Seung KANG, Paju-si (KR); Jae-Min MOON, Paju-si (KR); Yoo-Jeong JEONG, Paju-si (KR); Ji-Young KIM, Yongin-si (KR); Seok-Hyeon YU, Yongin-si (KR)

(73) Assignees: LG DISPLAY CO., LTD., Seoul (KR); LT Materials Co.,Ltd, Cheoin-gu, Yongin-si, Gyeonggi-do (KR)

(21) Appl. No.: 17/507,087

(22) Filed: Oct. 21, 2021

(30) Foreign Application Priority Data
Dec. 22, 2020 (KR) 10-2020-0180820

(51) Int. Cl. H01L 51/00; C07F 15/00; C09K 11/06

(52) U.S. Cl. CPC H01L 51/0085; C07F 15/0033; C09K 11/06; C09K 2211/185; H01L 51/5012; C09K 2211/1037; C09K 2211/1044; C09K 2211/1048; C09K 2211/1051; C09K 2211/1033

(57) ABSTRACT

The present disclosure relates to an organic metal compound, an organic light emitting diode and organic light emitting device having the same, in particular, to an organic metal compound having the following structure of Formula 1, an organic light emitting diode (OLED) and an organic light emitting device that includes the organic metal compound. The OLED and the organic light emitting device including the organic metal compound can improve their luminous efficiency, luminous color purity and luminous lifespan.

### CROSS-REFERENCE TO RELATED APPLICATIONS

This application claims the priority benefit under 35 U.S.C. § 119(a) of Korean Patent Application No. 10-2020-0180820, filed in the Republic of Korea on Dec. 22, 2020, which is expressly incorporated hereby in its entirety into the present application.

### BACKGROUND

### Technical Field

The present disclosure relates to an organic metal compound, and more specifically, to an organic metal compound having excellent luminous efficiency and luminous lifespan, an organic light emitting diode and an organic light emitting device including the organic metal compound.

### Discussion of the Related Art

An organic light emitting diode (OLED) among a flat display device used widely has come into the spotlight as a display device replacing rapidly a liquid crystal display device (LCD). The OLED can be formed as a thin organic film less than 2000 Å and can implement unidirectional or bidirectional images by electrode configurations. Also, the OLED can be formed even on a flexible transparent substrate such as a plastic substrate so that a flexible or a foldable display device can be realized with ease using the OLED. In addition, the OLED can be driven at a lower voltage and the OLED has excellent high color purity compared to the LCD.

Since fluorescent material uses only singlet exciton energy in the luminous process, the related art fluorescent material shows low luminous efficiency. On the contrary, phosphorescent material can show high luminous efficiency since it uses triplet exciton energy as well as singlet exciton energy in the luminous process. However, metal complex, representative phosphorescent material, has short luminous lifespan for commercial use. Therefore, there remains a need to develop a new compound that can enhance luminous efficiency and luminous lifespan.

### SUMMARY

Accordingly, embodiments of the present disclosure are directed to an organic light emitting device that substantially obviates one or more of the problems due to the limitations and disadvantages of the related art.

An aspect of the present disclosure is to provide an organic metal compound having excellent luminous efficiency and luminous lifespan, an organic light emitting diode and an organic light emitting device including the compound.

Additional features and aspects will be set forth in the description that follows, and in part will be apparent from the description, or can be learned by practice of the inventive concepts provided herein. Other features and aspects of the inventive concept can be realized and attained by the structure particularly pointed out in the written description, or derivable therefrom, and the claims hereof as well as the appended drawings.

To achieve these and other aspects of the inventive concepts, as embodied and broadly described herein, in one aspect, an organic metal compound having the following structure of Formula 1 is disclosed:

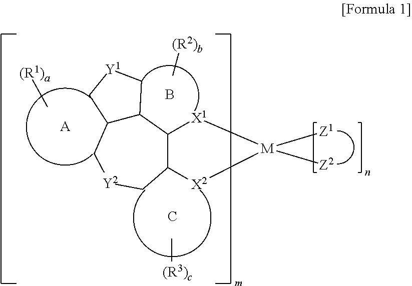

wherein M is molybdenum (Mo), tungsten (W), rhenium (Re), ruthenium (Ru), osmium (Os), rhodium (Rh), iridium (Ir), palladium (Pd), platinum (Pt) or silver (Ag); each of A, B and C is independently a 5-membered or 6-membered aromatic ring or a 5-membered or 6-membered hetero aromatic ring; each of X¹ and X² is independently CR⁴, N or P, one of X¹ and X² is CR⁴ and the other of X¹ and X² is N or P; each of Y¹ and Y² is independently selected from the group consisting of BR⁵, CR⁵R⁶, C═O, C═NR⁵, SiR⁵R⁶, NR⁵, PR⁵, AsR⁵, SbR⁵, BiR⁵, P(O)R⁵, P(S)R⁵, P(Se)R⁵, As(O)R⁵, As(S)R⁵, As(Se)R⁵, Sb(O)R⁵, Sb(S)R⁵, Sb(Se)R⁵, Bi(O)R⁵, Bi(S)R⁵, Bi(Se)R⁵, O, S, Se, Te, SO, SO₂, SeO, SeO₂, TeO and TeO₂; each of R¹ to R⁶ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R¹, adjacent two of R² and adjacent two of R³ independently forms a C₄-C₂₀ alicyclic ring, a C₃-C₂₀ hetero alicyclic ring, a C₆-C₂₀ aromatic ring or a C₃-C₂₀ hetero aromatic ring when each of a, b and c is 2 or more; each of the alkyl group, the hetero alkyl group, the alkenyl group, the hetero alkenyl group, the alkoxy group, the alkyl amino group, the alkyl silyl group, the alicyclic group, the hetero alicyclic group, the aromatic group and the hetero aromatic group of R¹ to R⁶ is independently unsubstituted or substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the alicyclic ring, the hetero alicyclic ring, the aromatic ring and the hetero aromatic ring formed by each of adjacent two of R¹, adjacent two of R² and adjacent two of R³ is independently unsubstituted or substituted with at least one C₁-C₁₀ alkyl group; each of a, b and c is a number of substitutent R¹, R² and R³, respectively, a is an integer of 0 to 3, b is an integer of 0 to 2 and c is an integer of 0 to 4;

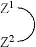

is an acetylacetonate-based auxiliary ligand; m is an integer of 1 to 3, n is an integer of 0 to 2, wherein m plus n is an oxidation number of M.

In another aspect, an organic light emitting diode comprises a first electrode; a second electrode facing the first electrode; and an emissive layer disposed between the first and second electrodes and including at least one emitting material layer, wherein the at least one emitting material layer includes the organic metal compound.

As an example, the organic metal compound may be comprised as dopant in the at least one emitting material layer.

The emissive layer may have single emitting part or multiple emitting parts to form a tandem structure.

In still another aspect, an organic light emitting device, for example, an organic light emitting display device or an organic light emitting illumination device, comprises a substrate and the organic light emitting diode over the substrate.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 is a schematic circuit diagram illustrating an organic light emitting display device in accordance with the present disclosure.

FIG. 2 is a cross-sectional view illustrating an organic light emitting display device as an example of an organic light emitting device in accordance with an exemplary aspect of the present disclosure.

FIG. 3 is a cross-sectional view illustrating an organic light emitting diode having single emitting part in accordance with an exemplary aspect of the present disclosure.

FIG. 4 is a cross-sectional view illustrating an organic light emitting display device in accordance with another exemplary aspect of the present disclosure.

FIG. 5 is a cross-sectional view illustrating an organic light emitting diode having a double-stack structure in accordance with still another exemplary aspect of the present disclosure.

FIG. 6 is a cross-sectional view illustrating an organic light emitting diode having a triple-stack structure in accordance with still further another exemplary aspect of the present disclosure.

### DETAILED DESCRIPTION

Reference will now be made in detail to embodiments of the disclosure, examples of which are illustrated in the accompanying drawings.

[Organic Metal Compound]

When excitons are activated in general phosphorescent materials, they show wide photoluminescence spectrum, low color purity and quantum efficiency. An organic metal compound in accordance with the present disclosure has a rigid chemical conformation. Accordingly, when the organic metal compound is applied into an organic light emitting diode, it can lower driving voltage of the diode and can improve luminous efficiency and luminous lifespan of the diode. The organic metal compound of the present disclosure may have the following structure of Formula 1:
[Formula 1]

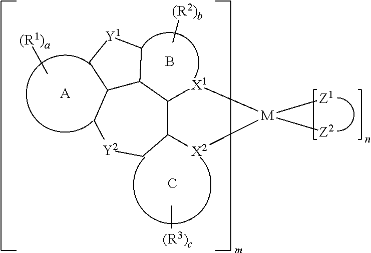

wherein M is molybdenum (Mo), tungsten (W), rhenium (Re), ruthenium (Ru), osmium (Os), rhodium (Rh), iridium (Ir), palladium (Pd), platinum (Pt) or silver (Ag); each of A, B and C is independently a 5-membered or 6-membered aromatic ring or a 5-membered or 6-membered hetero aromatic ring; each of X¹ and X² is independently CR⁴, N or P, one of X¹ and X² is CR⁴ and the other of X¹ and X² is N or P; each of Y¹ and Y² is independently selected from the group consisting of BR⁵, CR⁵R⁶, C═O, C═NR⁵, SiR⁵R⁶, NR⁵, PR⁵, AsR⁵, SbR⁵, BiR⁵, P(O)R⁵, P(S)R⁵, P(Se)R⁵, As(O)R⁵, As(S)R⁵, As(Se)R⁵, Sb(O)R⁵, Sb(S)R⁵, Sb(Se)R⁵, Bi(O)R⁵,Bi(S)R⁵, Bi(Se)R⁵, O, S, Se, Te, SO, SO₂, SeO, SeO₂, TeO and TeO₂; each of R¹ to R⁶ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R¹, adjacent two of R² and adjacent two of R³ independently forms a C₄-C₂₀ alicyclic ring, a C₃-C₂₀ hetero alicyclic ring, a C₆-C₂₀ aromatic ring or a C₃-C₂₀ hetero aromatic ring when each of a, b and c is 2 or more; each of the alkyl group, the hetero alkyl group, the alkenyl group, the hetero alkenyl group, the alkoxy group, the alkyl amino group, the alkyl silyl group, the alicyclic group, the hetero alicyclic group, the aromatic group and the hetero aromatic group of R¹ to R⁶ is independently unsubstituted or substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the alicyclic ring, the hetero alicyclic ring, the aromatic ring and the hetero aromatic ring formed by each of adjacent two of R¹, adjacent two of R² and adjacent two of R³ is independently unsubstituted or substituted with at least one C₁-C₁₀ alkyl group; each of a, b and c is a number of substitutent R¹, R² and R³, respectively, a is an integer of 0 to 3, b is an integer of 0 to 2 and c is an integer of 0 to 4;

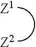

is an acetylacetonate-based auxiliary ligand; m is an integer of 1 to 3, n is an integer of 0 to 2, wherein m plus n is an oxidation number of M.

As used herein, the term “unsubstituted” means that hydrogen is linked, and in this case, hydrogen comprises protium.

As used herein, substituent in the term “substituted” comprises, but is not limited to, deuterium, tritium, unsubstituted or deuterium or halogen-substituted C₁-C₂₀ alkyl, unsubstituted or deuterium or halogen-substituted C₁-C₂₀ alkoxy, halogen, cyano, —CF₃, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a C₆-C₃₀ aryl group, a C₃-C₃₀ hetero aryl group, a nitro group, a hydrazyl group, a sulfonate group, a C₁-C₂₀ alkyl silyl group, a C₆-C₃₀ aryl silyl group and a C₃-C₃₀ hetero aryl silyl group.

As used herein, the term ‘hetero” in such as “hetero alkyl”, “hetero alkenyl”, “hetero alkynyl”, “a hetero alicyclic group”, “a hetero aromatic group”, “a hetero alicyclic ring”, “a hetero aromatic ring” means that at least one carbon atom, for example 1-5 carbons atoms, constituting an aliphatic chain, an alicyclic group or ring or an aromatic group or ring is substituted with at least one hetero atom selected from the group consisting of N, O, S, P and combination thereof.

In one exemplary aspect, when each of R¹ to R⁶ in Formula 1 is independently a C₆-C₃₀ aromatic group, each of R¹ to R⁶ may independently be, but is not limited to, a C₆-C₃₀ aryl group, a C₇-C₃₀ aryl alkyl group, a C₆-C₃₀ aryl oxy group and a C₆-C₃₀ aryl amino group. As an example, when each of R¹ to R⁶ is independently a C₆-C₃₀ aryl group, each of R¹ to R⁶ may independently comprise, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl and spiro-fluorenyl.

Alternatively, when each of R¹ to R⁶ in Formula 1 is independently a C₃-C₃₀ hetero aromatic group, each of R¹ to R⁶ may independently be, but is not limited to, a C₃-C₃₀ hetero aryl group, a C₄-C₃₀ hetero aryl alkyl group, a C₃-C₃₀ hetero aryl oxy group and a C₃-C₃₀ hetero aryl amino group. As an example, when each of R¹ to R⁶ is independently a C₃-C₃₀ hetero aryl group, each of R¹ to R⁶ may independently comprise, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthalzinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aromatic group or the hetero aromatic group of R¹ to R⁶ may consist of one to three aromatic or hetero aromatic rings. When the number of the aromatic or hetero aromatic rings of R¹ to R⁶ becomes more than four, the whole molecule has too long conjugated structure, thus, the organic metal compound may have too narrow energy bandgap. For example, each of the aryl group or the hetero aryl group of R¹ to R⁶ may comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl and/or phenothiazinyl.

Alternatively, each of adjacent two of R¹, adjacent two of R² and adjacent two of R³ may form independently an unsubstituted or alkyl-substituted C₄-C₂₀ alicyclic ring (e.g. C₄-C₁₀ alicyclic ring, an unsubstituted or alkyl-substituted C₃-C₂₀ hetero alicyclic ring (e.g. C₃-C₁₀ hetero alicyclic ring), an unsubstituted or alkyl-substituted C₆-C₂₀ aromatic ring (e.g. C₆-C₁₀ aromatic ring), or an unsubstituted or alkyl-substituted C₃-C₂₀ hetero aromatic ring (e.g. C₃-C₁₀ hetero aromatic ring). The alicyclic ring, the hetero alicyclic ring, the aromatic ring and/or the hetero aromatic ring formed by each of adjacent two of R¹, adjacent two of R² and adjacent two of R³ are not limited to a particular ring. For example, the aromatic ring or the hetero aromatic ring formed by those groups may include, but is not limited to, a benzene ring, a pyridine ring, an indole ring, a pyran ring and a fluorene ring each of which is optionally substituted with at least one C₁-C₁₀ alkyl.

The organic metal compound having the structure of Formula 1 has a main ligand having at least five fused rings. The organic metal compound has a rigid chemical conformation, so that its conformation is not rotated in the luminous process, therefore, and it can maintain good luminous lifespan stably. The organic metal compound has specific ranges of photoluminescence emissions by exciton activations, so that its color purity can be improved.

In one exemplary aspect, the organic metal compound may be a heteroleptic metal complex including two different bidentate ligands coordinated to the central metal atom, so that the photoluminescence color purity and emission colors of the organic metal compound can be controlled with ease by combining two different bidentate ligands. In addition, it is possible to control the color purity and emission peaks of the organic metal compound by introducing various substituents to each of the ligands. The organic metal compound having the structure of Formula 1 may emit red light and can improve luminous efficiency of an organic light emitting diode.

In one exemplary aspect, each of the A ring, the B ring and the C ring in Formula 1 may include independently a 6-membered aromatic ring or a 6-membered hetero aromatic ring. Such an organic metal compound may have the following structure of Formula 2:

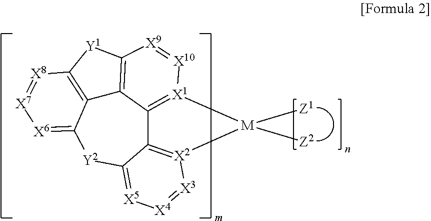

wherein each of M, X¹, X², Y¹, Y²,

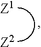

m and n is as same as defined in Formula 1; each of X³ to X⁵ is independently selected from the group consisting of CR⁷, N, P, S and O, wherein at least one of X³ to X⁵ is CR⁷; each of X⁶ to X⁸ is independently selected from the group consisting of CR⁸, N, P, S and O, wherein at least one of X⁶ to X⁸ is CR⁸; each of X⁹ and X¹⁰ is independently selected from the group consisting of CR⁹, N, P, S and O, wherein at least one of X⁹ and X¹⁰ is CR⁹; each of R⁷ to R⁹ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R⁷, adjacent two of R⁸ and adjacent two of R⁹ independently forms a C₄-C₂₀ alicyclic ring, a C₃-C₂₀ hetero alicyclic ring, a C₆-C₂₀ aromatic ring or a C₃-C₂₀ hetero aromatic ring; each of the alkyl group, the hetero alkyl group, the alkenyl group, the hetero alkenyl group, the alkoxy group, the alkyl amino group, the alkyl silyl group, the alicyclic group, the hetero alicyclic group, the aromatic group and the hetero aromatic group of R⁷ to R⁹ is independently unsubstituted or substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the alicyclic ring, the hetero alicyclic ring, the aromatic ring and the hetero aromatic ring formed by each of adjacent two of R⁷, adjacent two of R⁸ and adjacent two of R⁹ is independently unsubstituted or substituted with at least one C₁-C₁₀ alkyl group.

Each of the aromatic group, the hetero aromatic group, the alicyclic ring, the hetero alicyclic ring, the aromatic ring and the hetero aromatic ring of R⁷ to R⁹ may be identical to the corresponding groups and the rings of R¹ to R⁶ as described above.

Alternatively, the central metal atom may comprise iridium and the auxiliary ligand may comprise an acetylacetonate-based ligand. Such an organic metal compound may have the following structure of Formula 3:

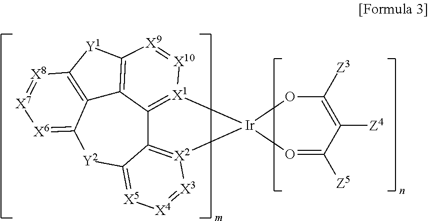

wherein each of X¹ to X¹⁰, Y¹ and Y² is as same as defined in Formula 2; m is an integer of 1 to 3, n is an integer of 0 to 2, wherein m plus n is 3; each of Z³ to Z⁵ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or adjacent two of Z³ to Z⁵ form a C₄-C₂₀ alicyclic ring, a C₃-C₂₀ hetero alicyclic ring, a C₆-C₂₀ aromatic ring or a C₃-C₂₀ hetero aromatic ring; each of the alkyl group, the hetero alkyl group, the alkenyl group, the hetero alkenyl group, the alkoxy group, the alkyl amino group, the alkyl silyl group, the alicyclic group, the hetero alicyclic group, the aromatic group and the hetero aromatic group of Z³ to Z⁵ is independently unsubstituted or substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the alicyclic ring, the hetero alicyclic ring, the aromatic ring and the hetero aromatic ring formed by adjacent two of Z³ to Z⁵ is independently unsubstituted or substituted with at least one C₁-C₁₀ alkyl group.

Each of the aromatic group, the hetero aromatic group, the alicyclic ring, the hetero alicyclic ring, the aromatic ring and the hetero aromatic ring of Z³ to Z⁵ may be identical to the corresponding groups and the rings of R¹ to R⁶ as described above.

In another exemplary aspect, the A ring may comprise a 6-membered aromatic ring, the B ring may comprise a 6-membered aromatic ring or a 6-membered hetero aromatic ring having 0 to 1 nitrogen atom and the C ring may comprise a 6-membered aromatic ring or a 6-membered hetero aromatic ring having 0 to 2 nitrogen atoms. As an example, such an organic metal compound may have the following structure of Formula 4:

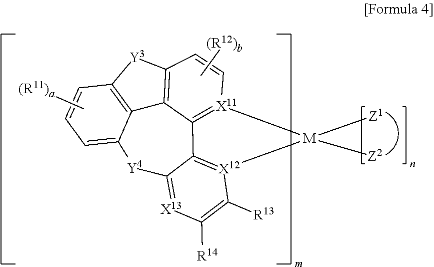

wherein each of M, a, b, m and n is as same as defined in Formula 1; each of X¹¹ to X¹³ is independently CR¹⁵ or N, wherein one of X¹¹ and X¹² is CR¹⁵ and the other of X¹¹ and X¹² is N; each of Y³ and Y⁴ is independently CR¹⁶R¹⁷, NR¹⁶, O, S, Se or SiR¹⁶R¹⁷; each of R¹¹ to R¹⁵ is independently selected from the group consisting of protium, deuterium, a C₁-C₁₀ alkyl group, a C₄-C₂₀ cyclo alkyl group, a C₄-C₂₀ hetero cyclo alkyl group, a C₆-C₂₀ aryl group and a C₃-C₂₀ hetero aryl group, or each of adjacent two of R¹¹ and adjacent two of R¹² independently forms a C₆-C₂₀ aromatic ring or a C₃-C₂₀ hetero aromatic ring unsubstituted or substituted with at least one C₁-C₁₀ alkyl group when each of a and b is 2 or more, or adjacent two of R¹³ to R¹⁵ form a C₆-C₂₀ aromatic ring or a C₃-C₂₀ hetero aromatic ring unsubstituted or substituted with at least one C₁-C₁₀ alkyl group; each of R¹⁶ and R¹⁷ is independently selected from the group consisting of protium, deuterium, a C₁-C₁₀ alkyl group, a C₄-C₂₀ cyclo alkyl group, a C₄-C₂₀ hetero cyclo alkyl group, a C₆-C₂₀ aryl group and a C₃-C₂₀ hetero aryl group.

Each of the aromatic group, the hetero aromatic group, the alicyclic ring, the hetero alicyclic ring, the aromatic ring and the hetero aromatic ring of R¹¹ to R¹⁷ may be identical to the corresponding groups and the rings of R¹ to R⁶ as described above.

For example, X¹¹ in Formula 4 may comprise an unsubstituted or substituted carbon atom, X¹² in Formula 4 may comprise a nitrogen atom. Alternatively, the adjacent two of R¹³ to R¹⁵ in Formula 4 may form a C₆-C₁₀ aromatic ring or a C₃-C₁₀ hetero aromatic ring.

In still another exemplary aspect, the organic metal compound having the structure of Formulae 1 to 4 may comprise iridium as a central metal and an acetylacetonate-based ligand as an auxiliary ligand. Such an organic metal compound may have the following structure of Formula 5:

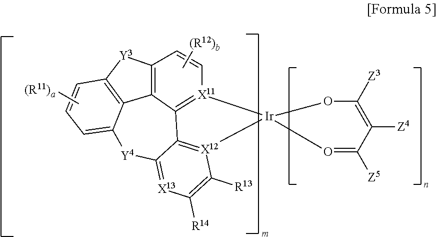

wherein each of R¹¹ to R¹⁴, X¹¹ to X¹³, Y³, Y⁴, a and b is as same as defined in Formula 4; m is an integer of 1 to 3, n is an integer of 0 to 2, wherein m plus n is 3; each of Z³ to Z⁵ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or adjacent two of Z³ to Z⁵ form a C₄-C₂₀ alicyclic ring, a C₃-C₂₀ hetero alicyclic ring, a C₆-C₂₀ aromatic ring or a C₃-C₂₀ hetero aromatic ring; each of the alkyl group, the hetero alkyl group, the alkenyl group, the hetero alkenyl group, the alkoxy group, the alkyl amino group, the alkyl silyl group, the alicyclic group, the hetero alicyclic group, the aromatic group and the hetero aromatic group of Z³ to Z⁵ is independently unsubstituted or substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the alicyclic ring, the hetero alicyclic ring, the aromatic ring and the hetero aromatic ring formed by adjacent two of Z³ to Z⁵ is independently unsubstituted or substituted with at least one C₁-C₁₀ alkyl group.

More particularly, the organic metal compound having the structure of Formula 1 may be selected from any one having the following structure of Formula 6:

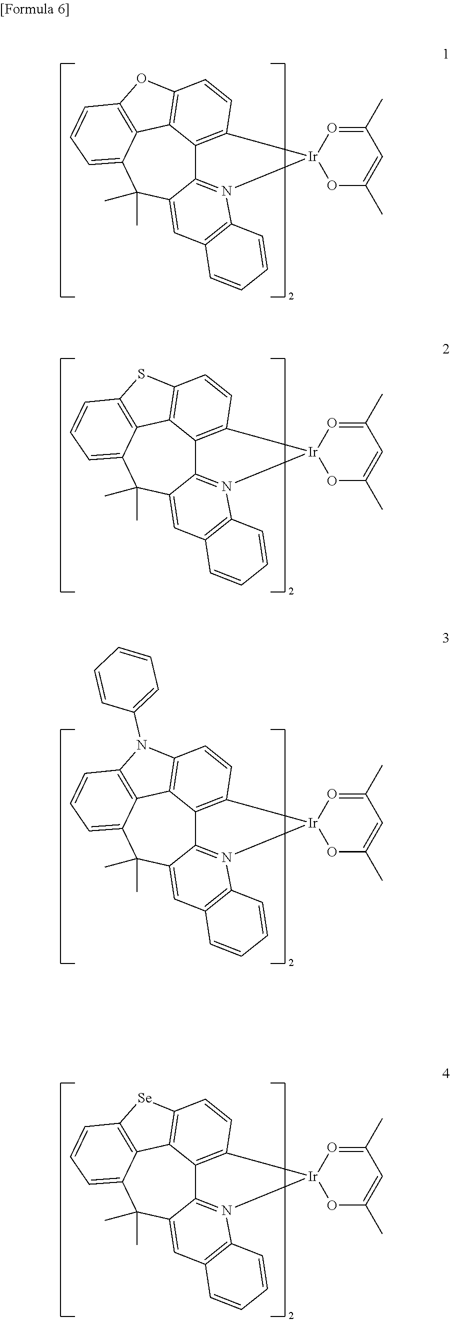

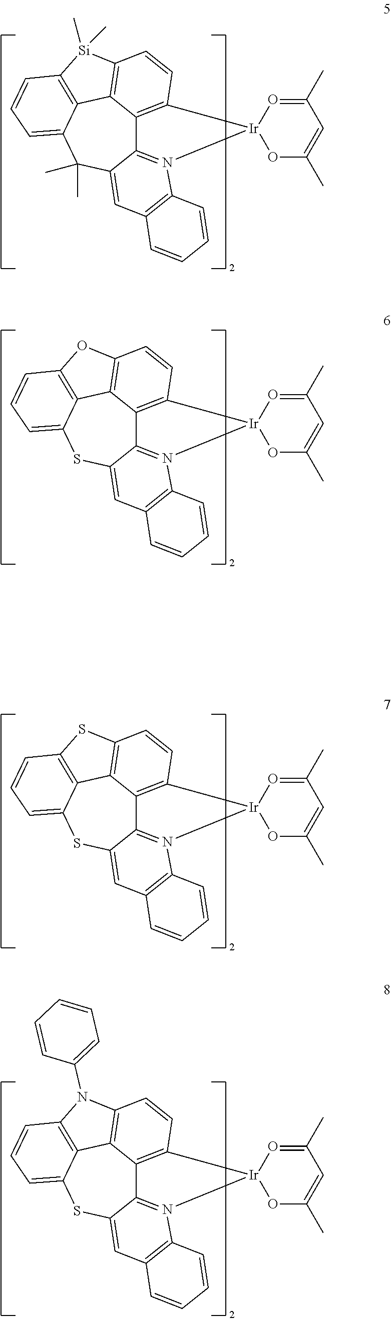

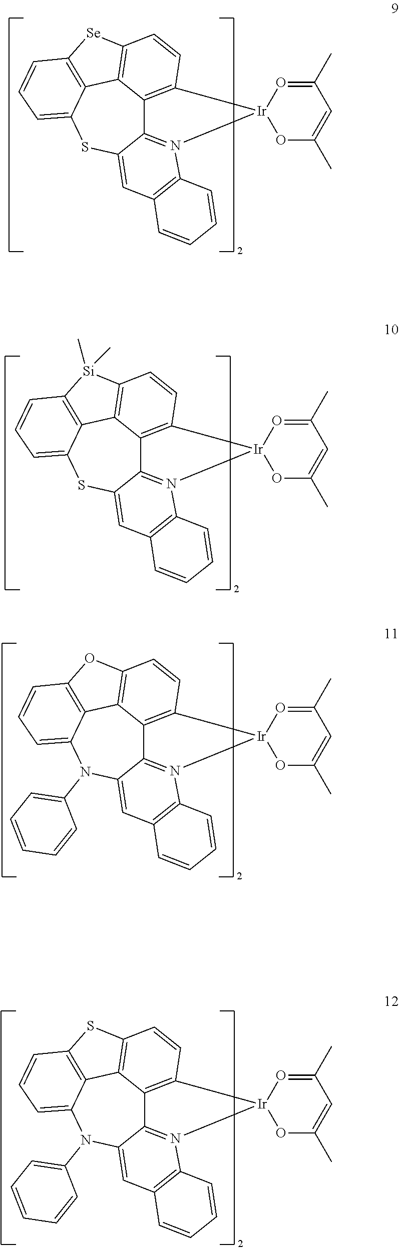

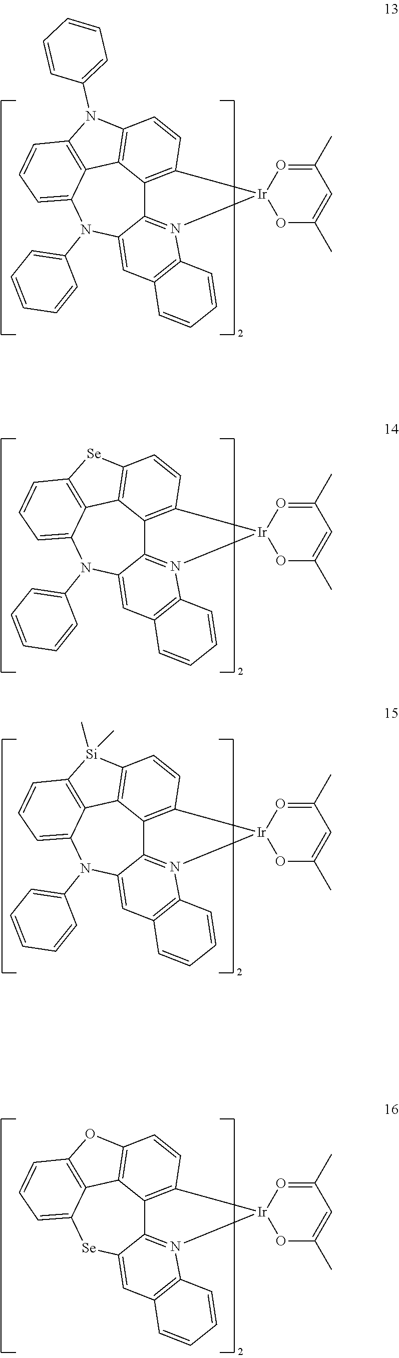

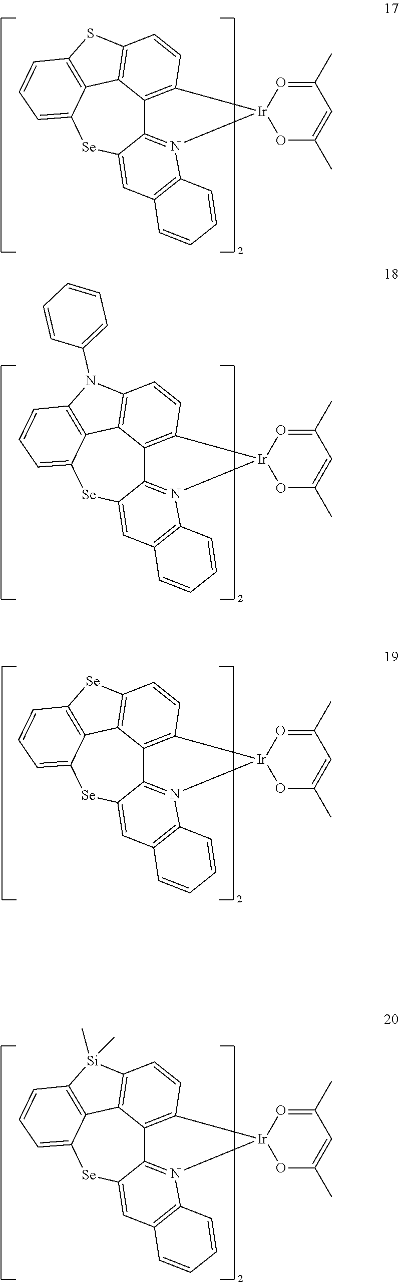

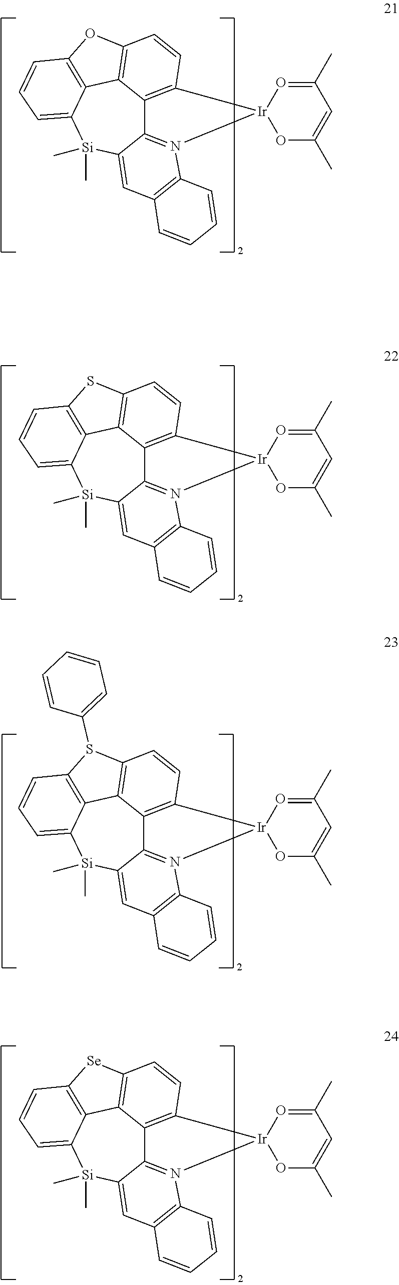

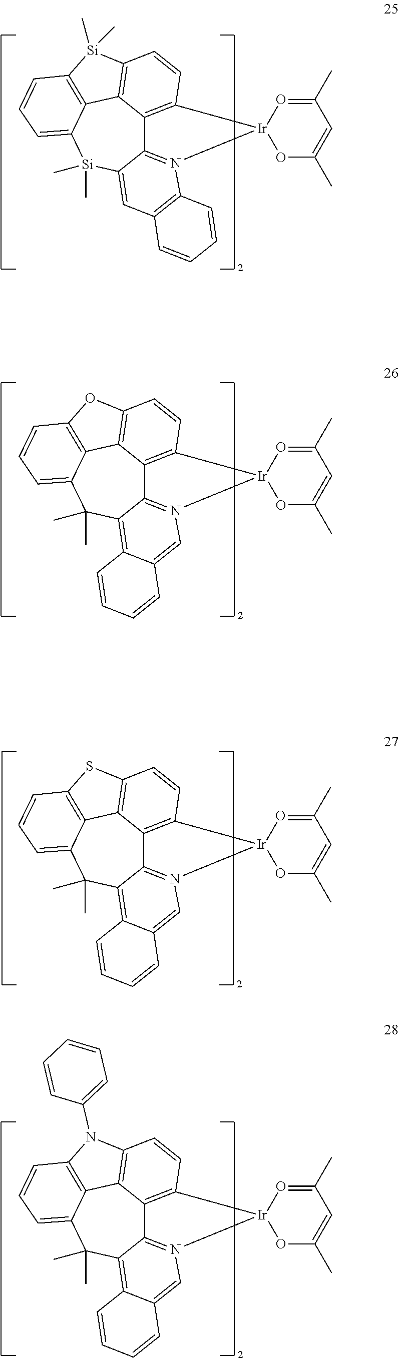

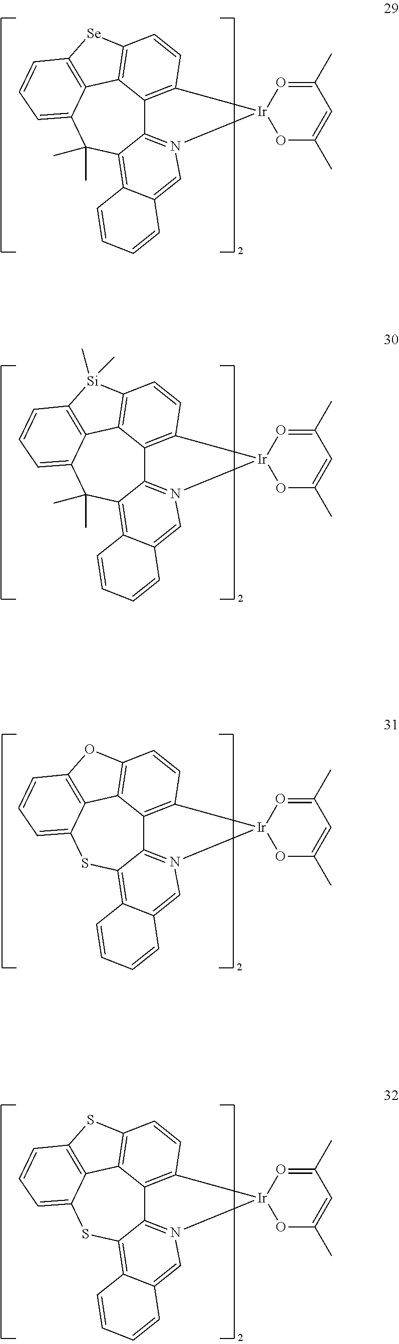

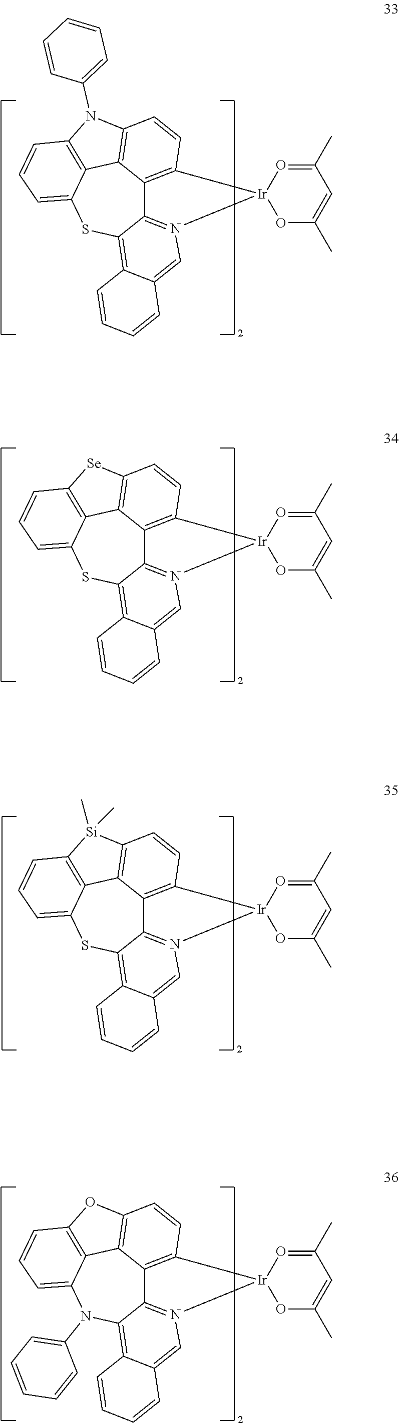

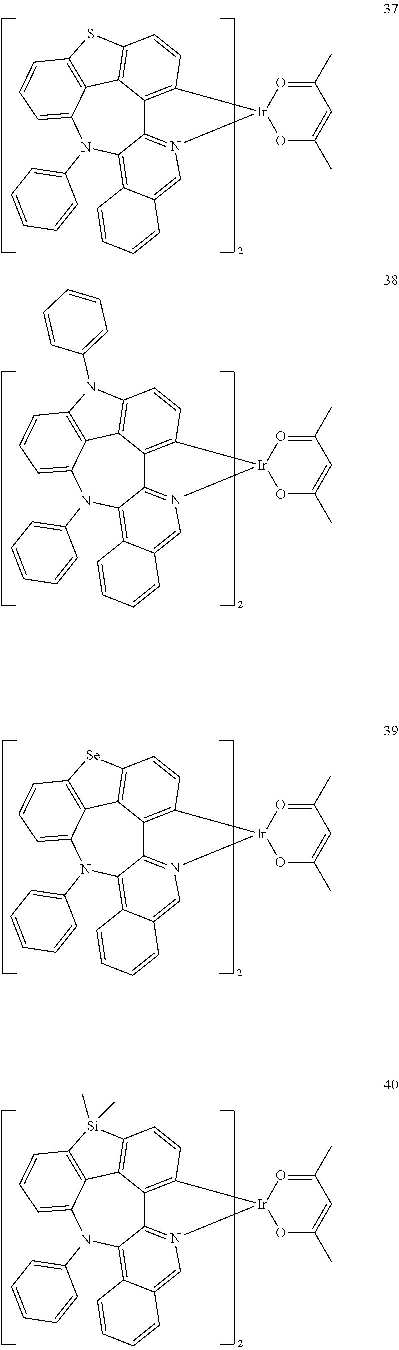

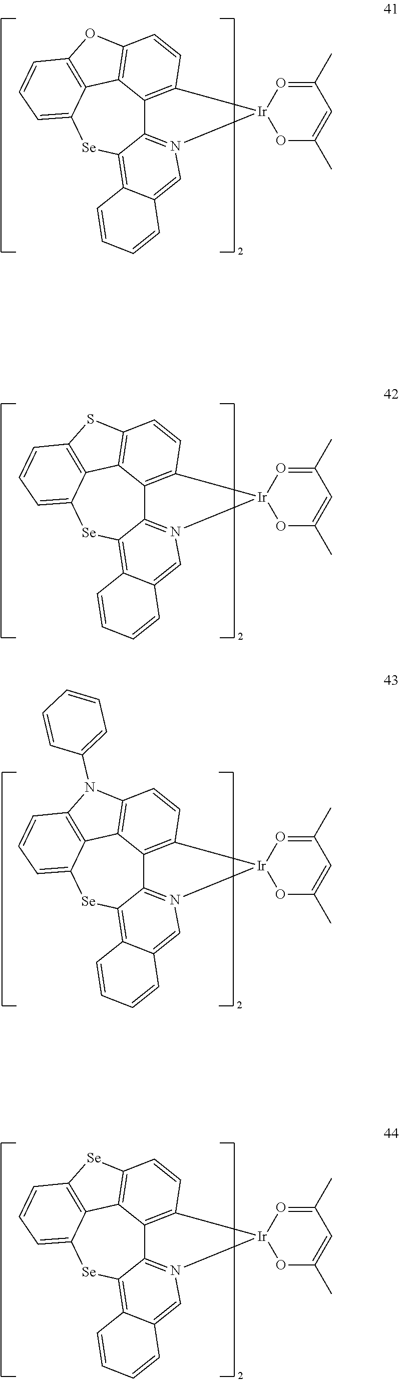

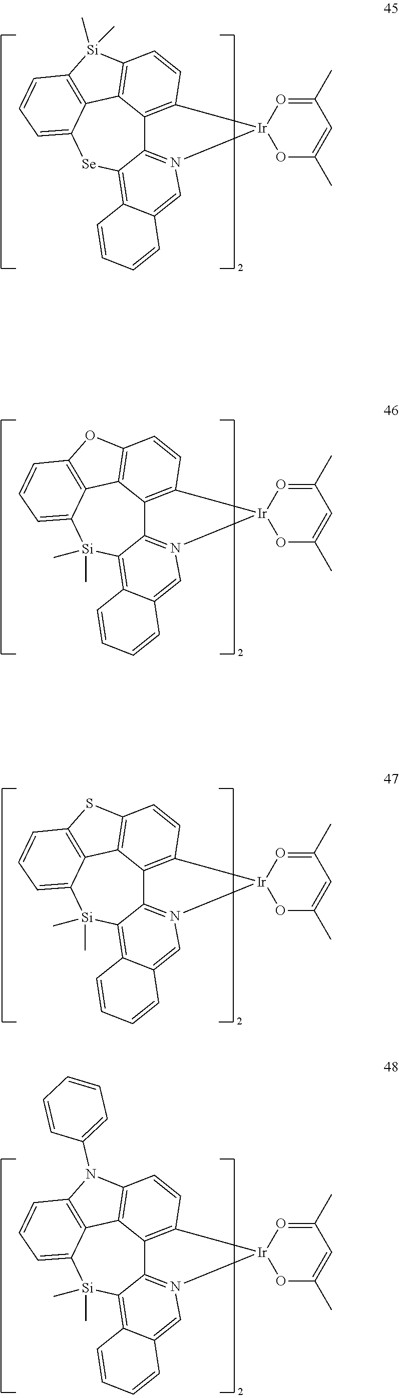

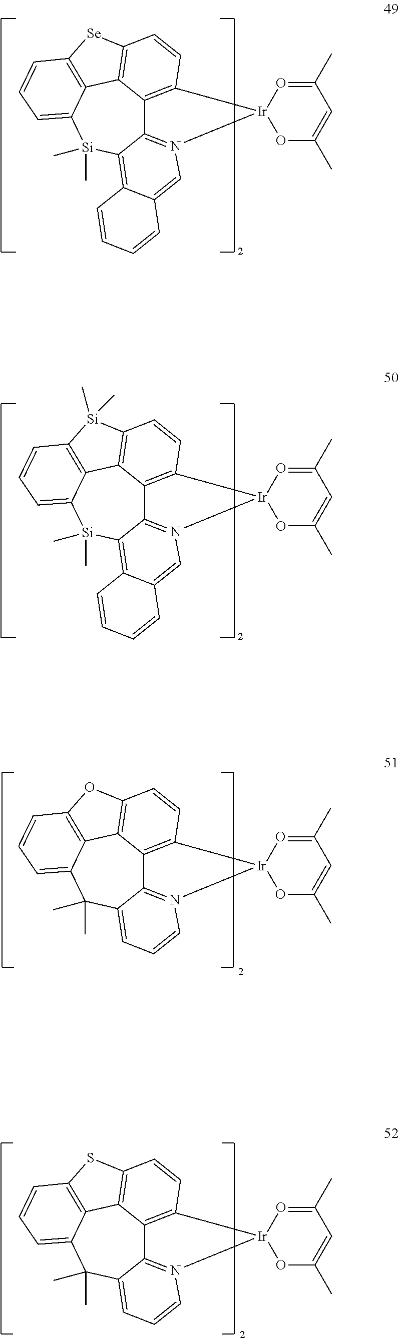

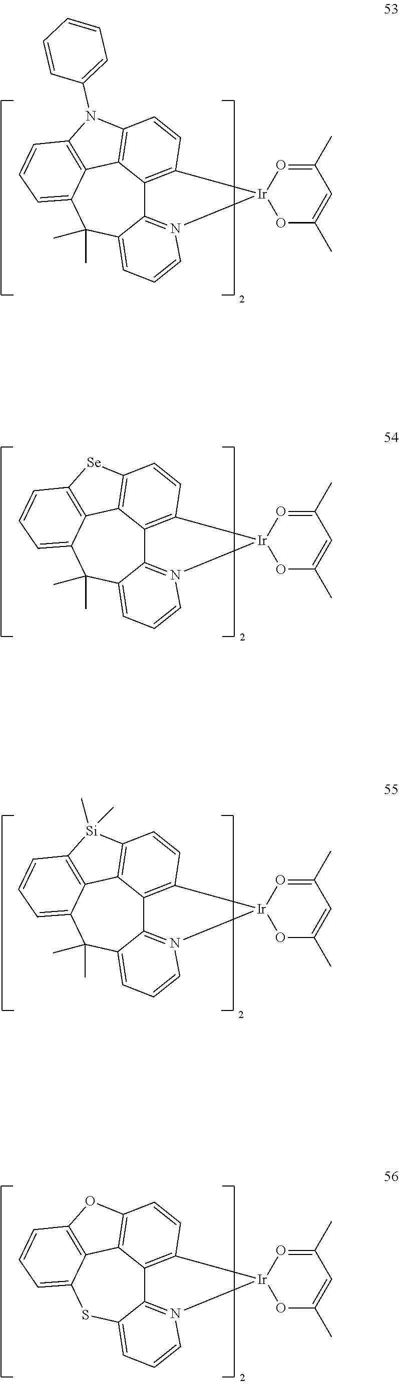

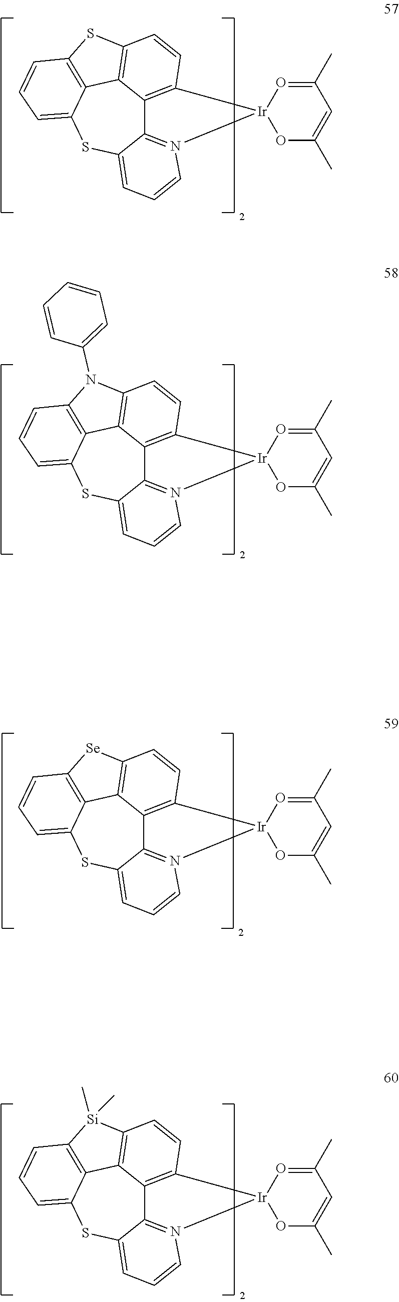

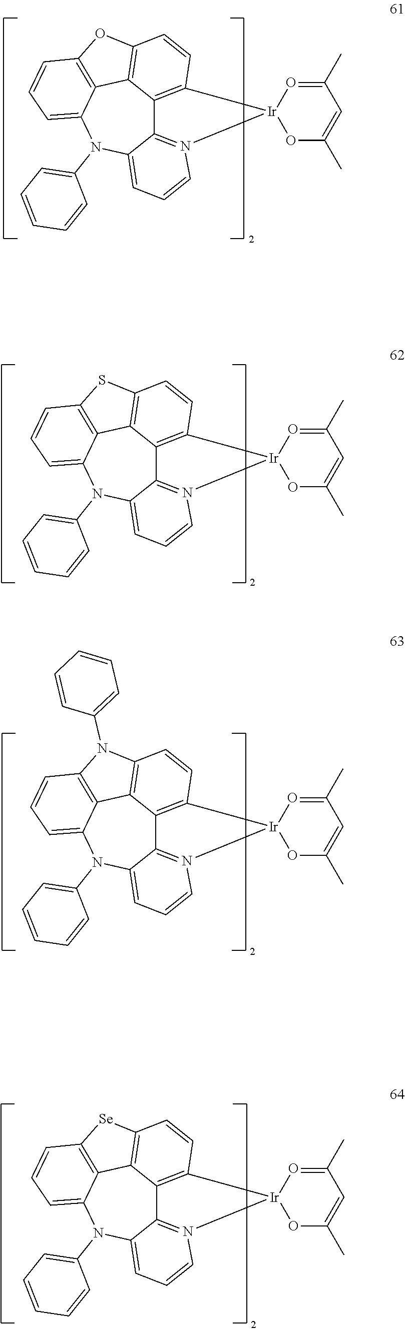

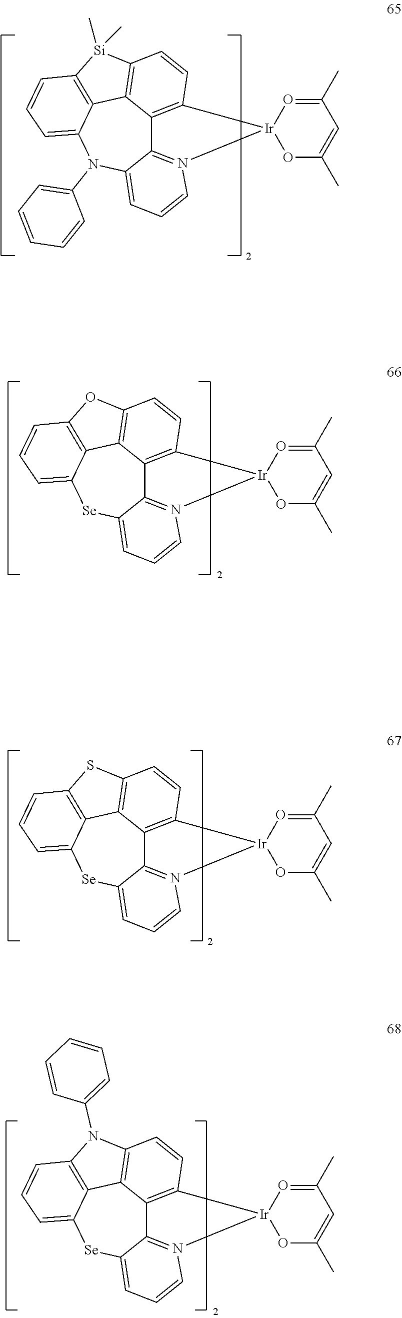

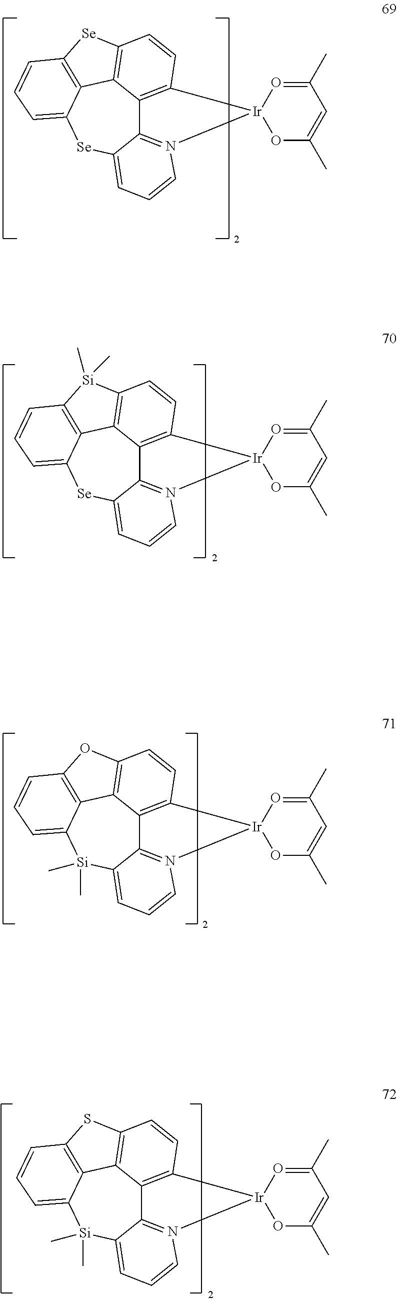

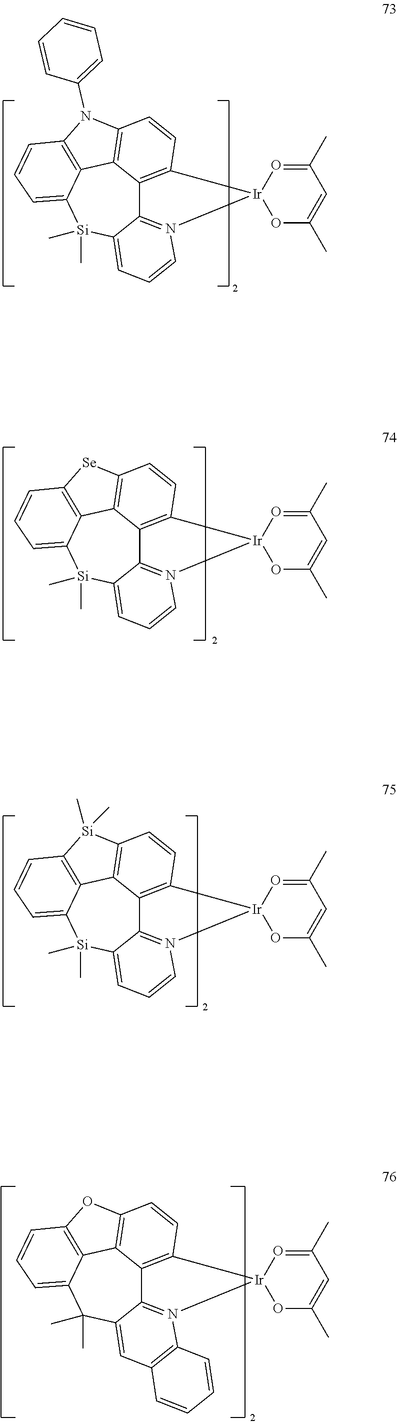

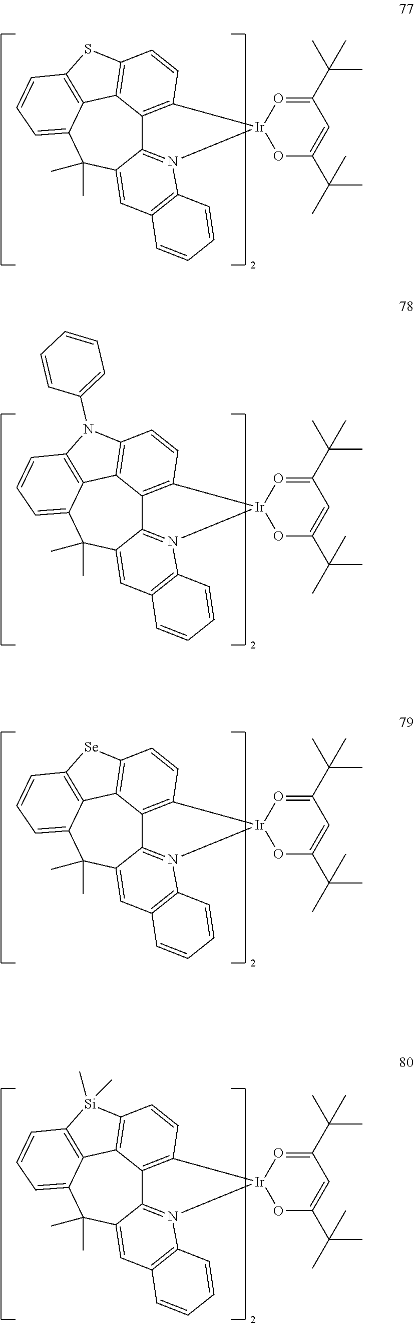

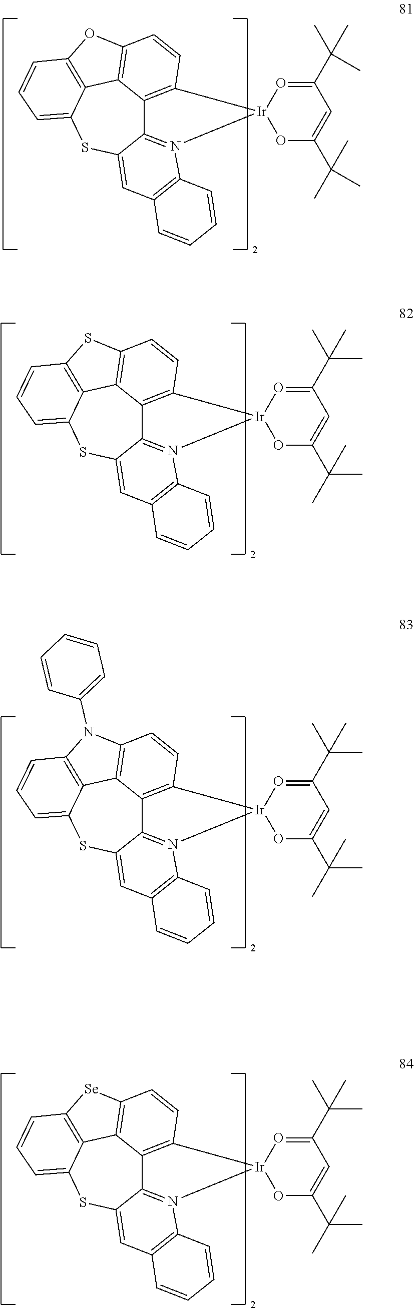

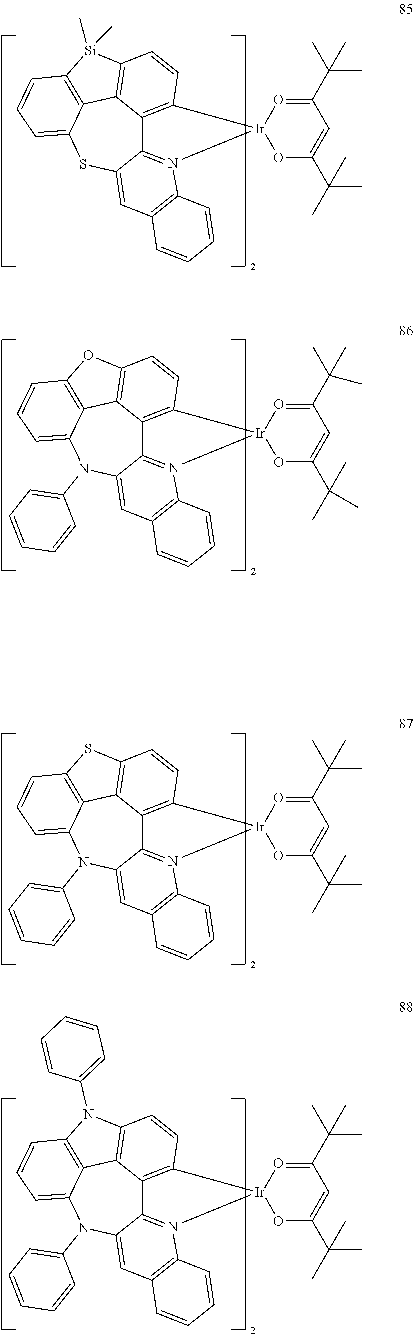

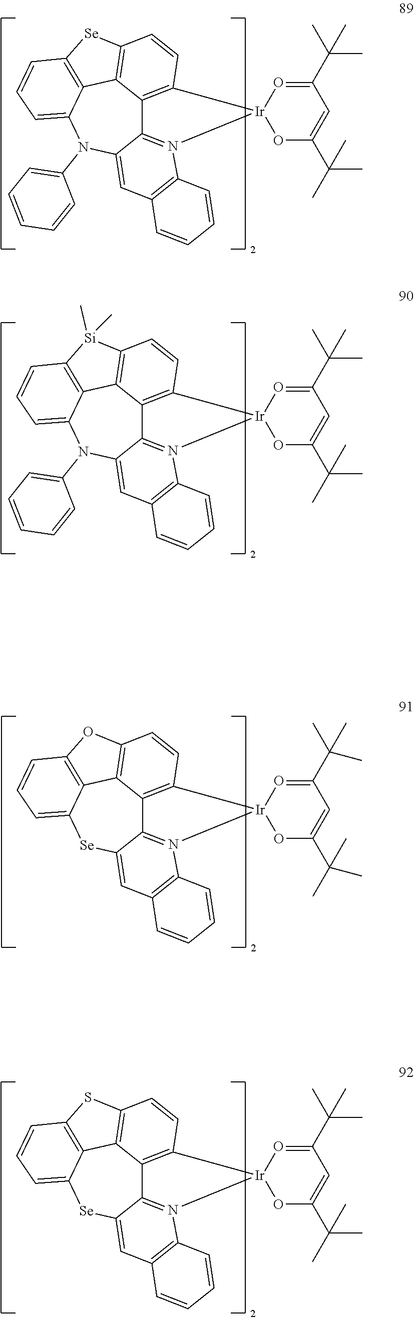

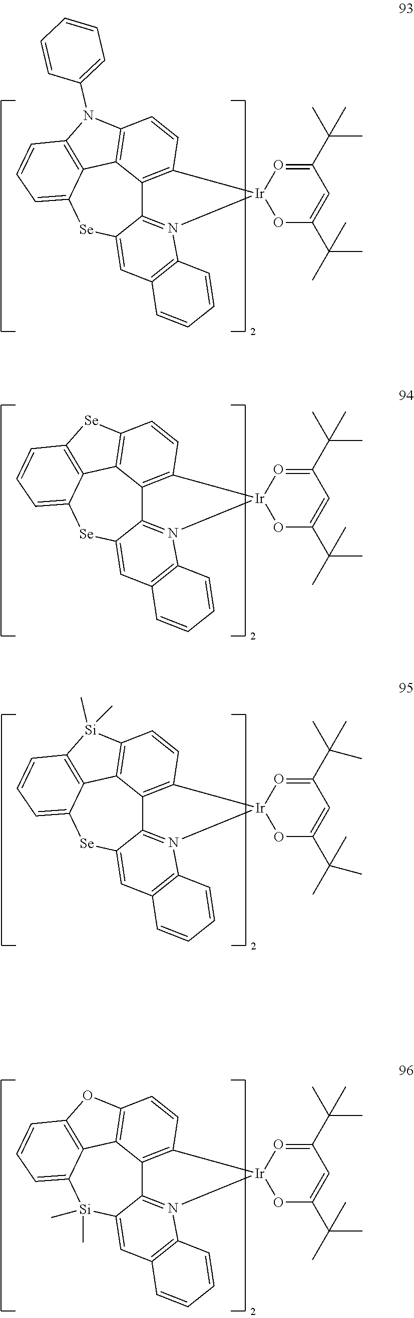

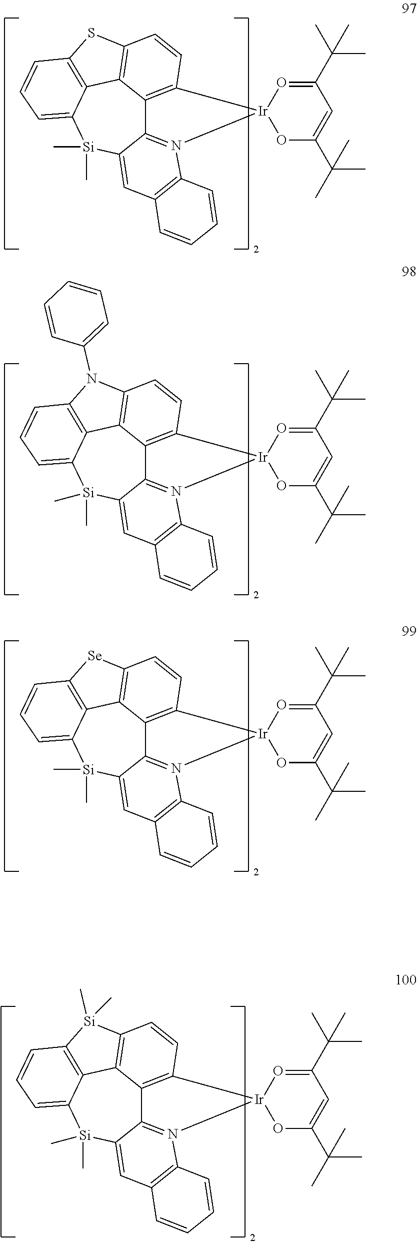

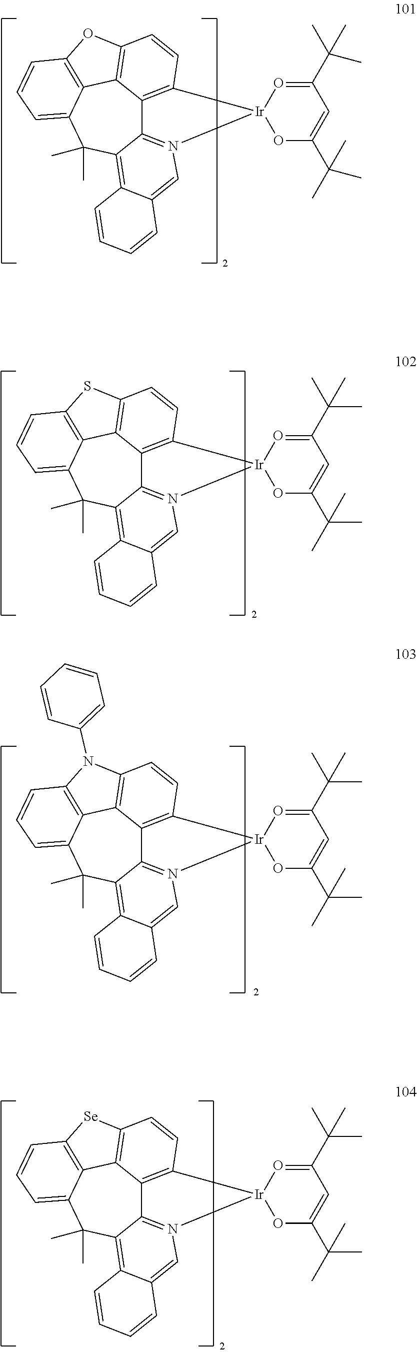

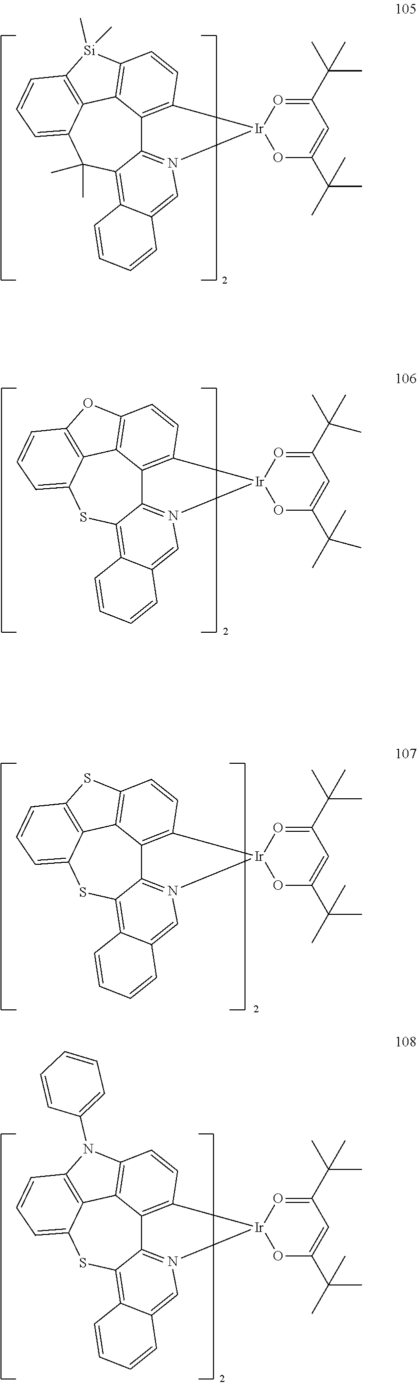

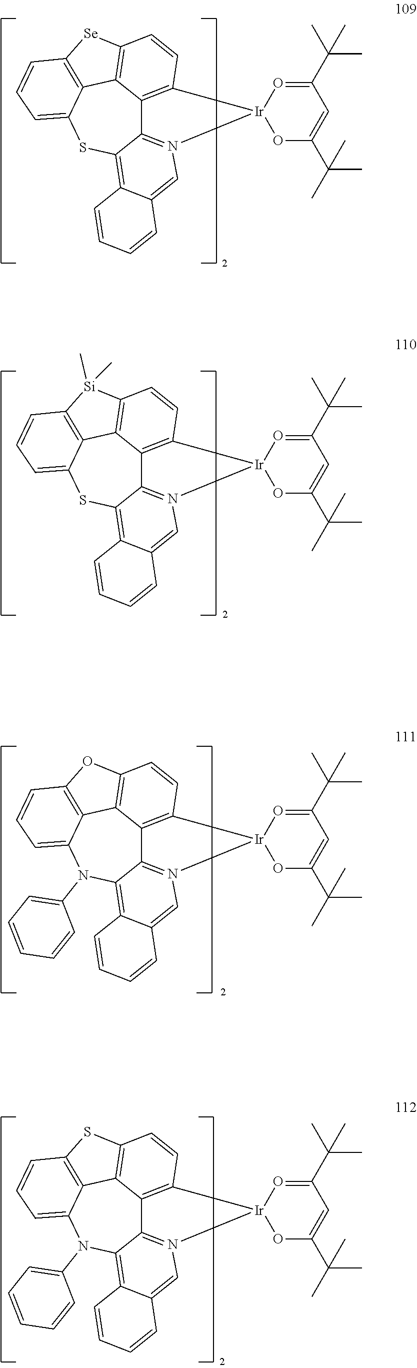

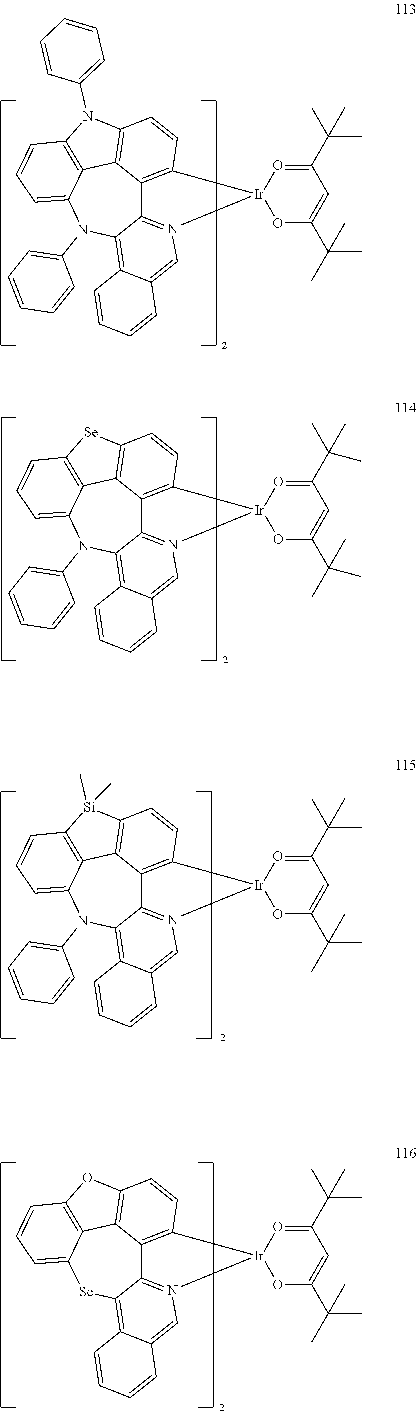

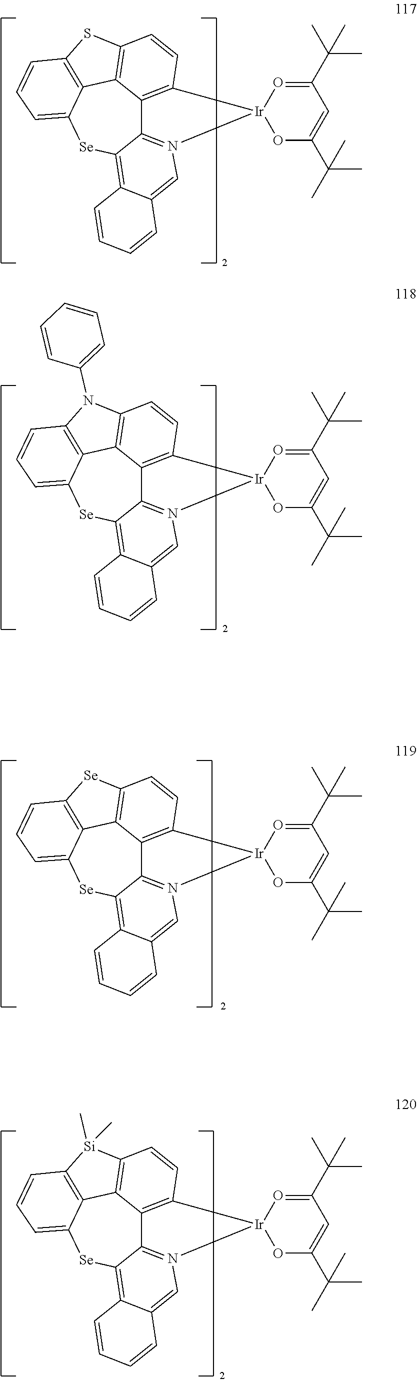

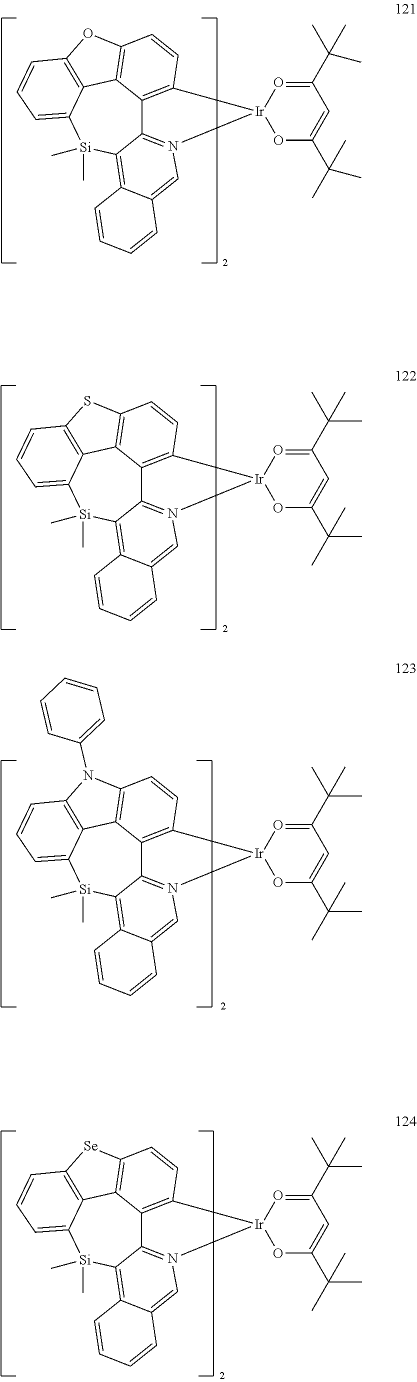

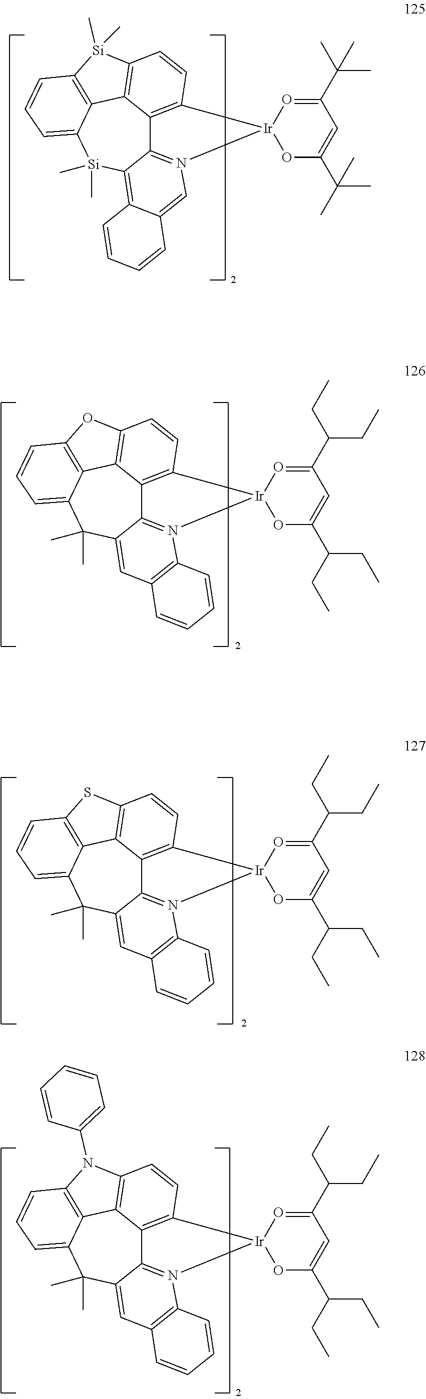

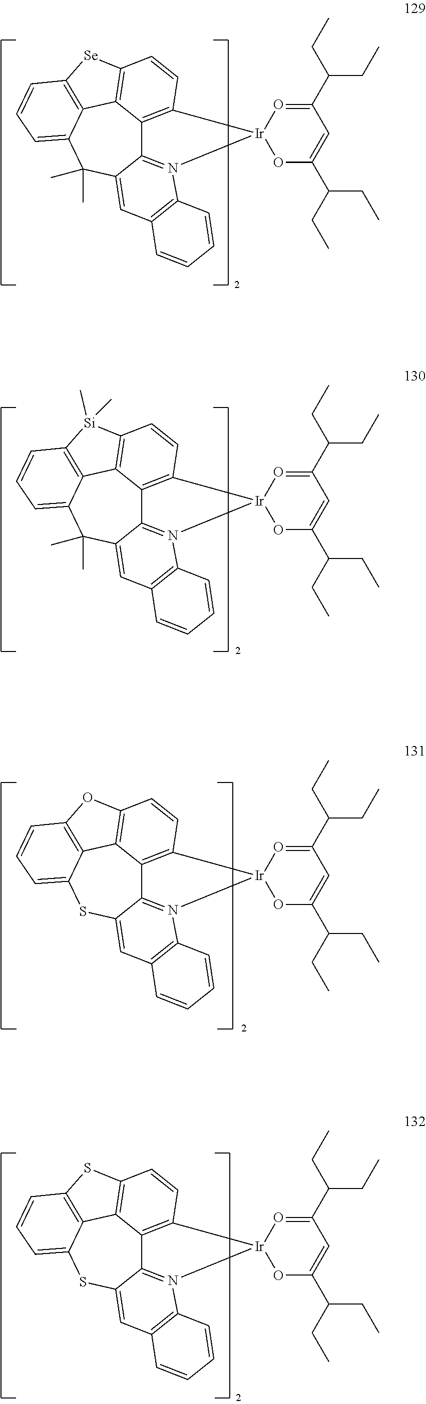

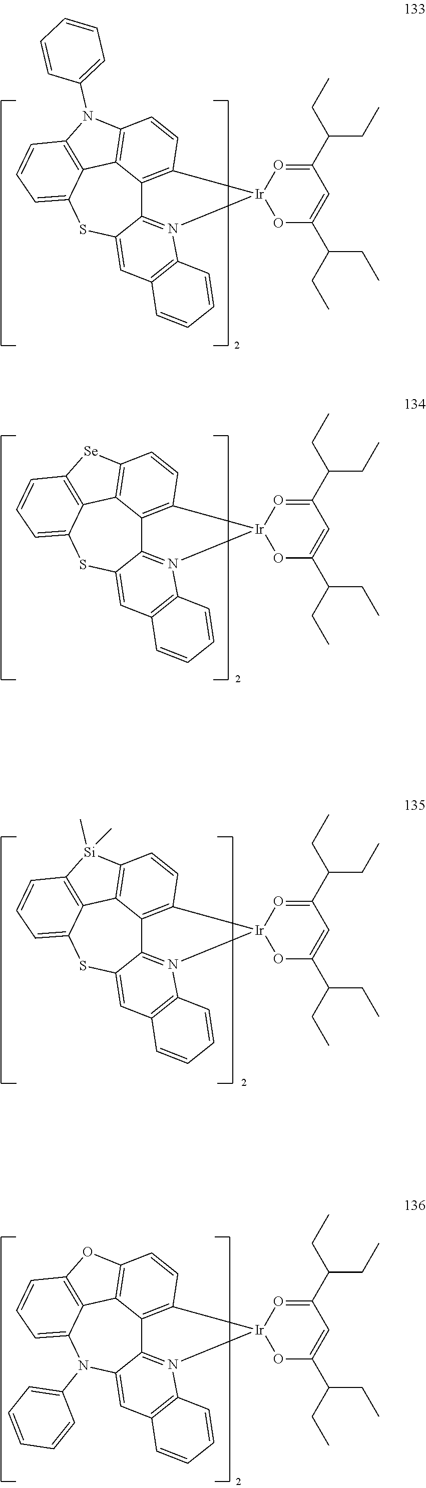

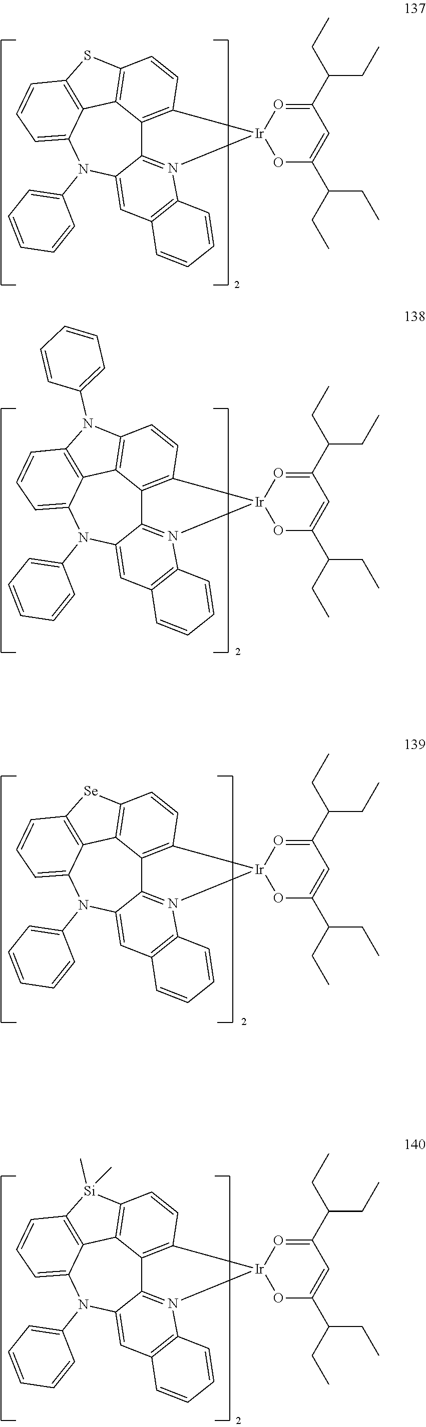

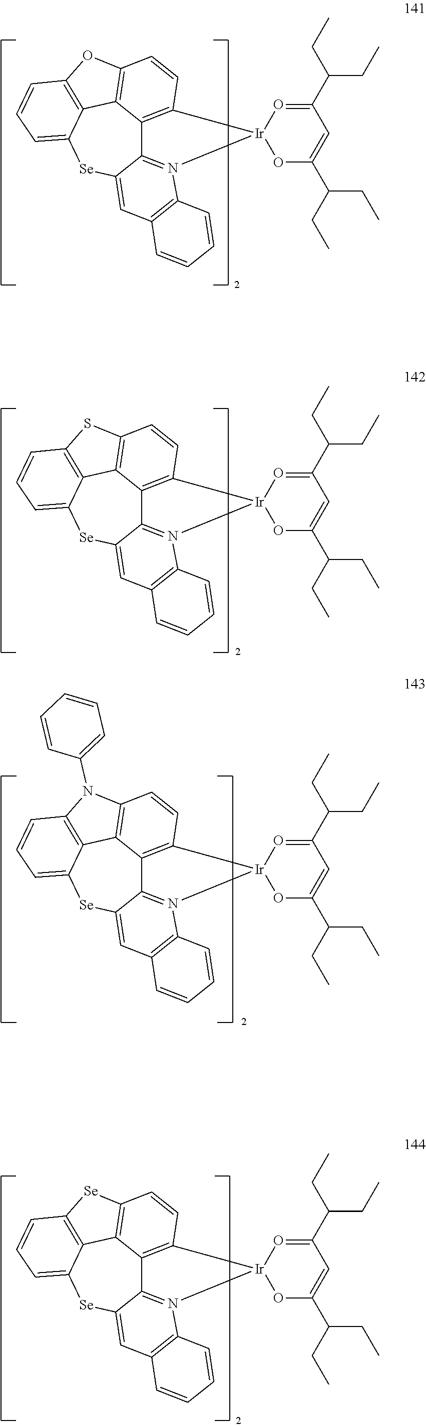

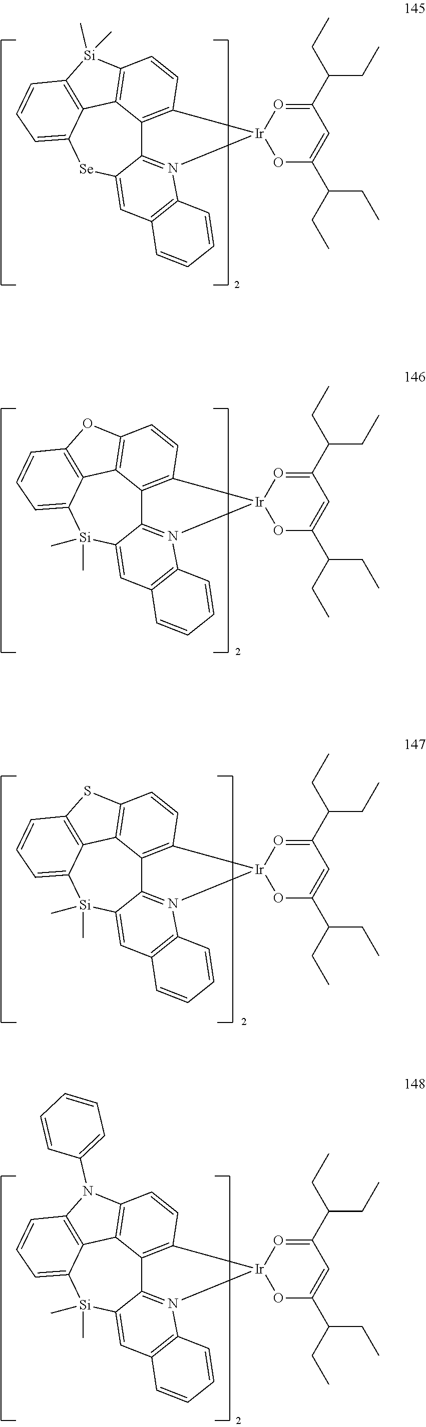

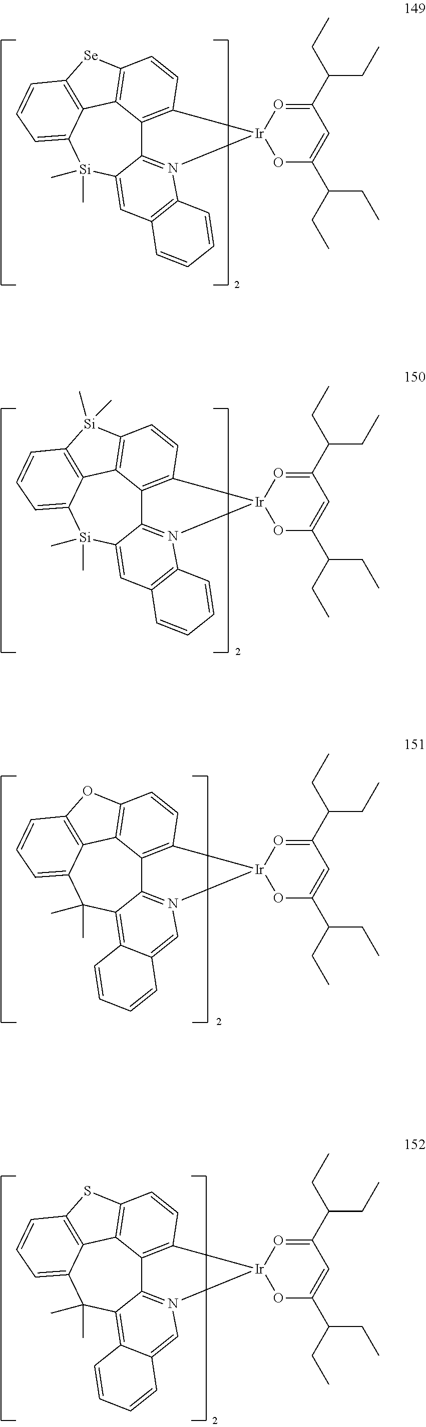

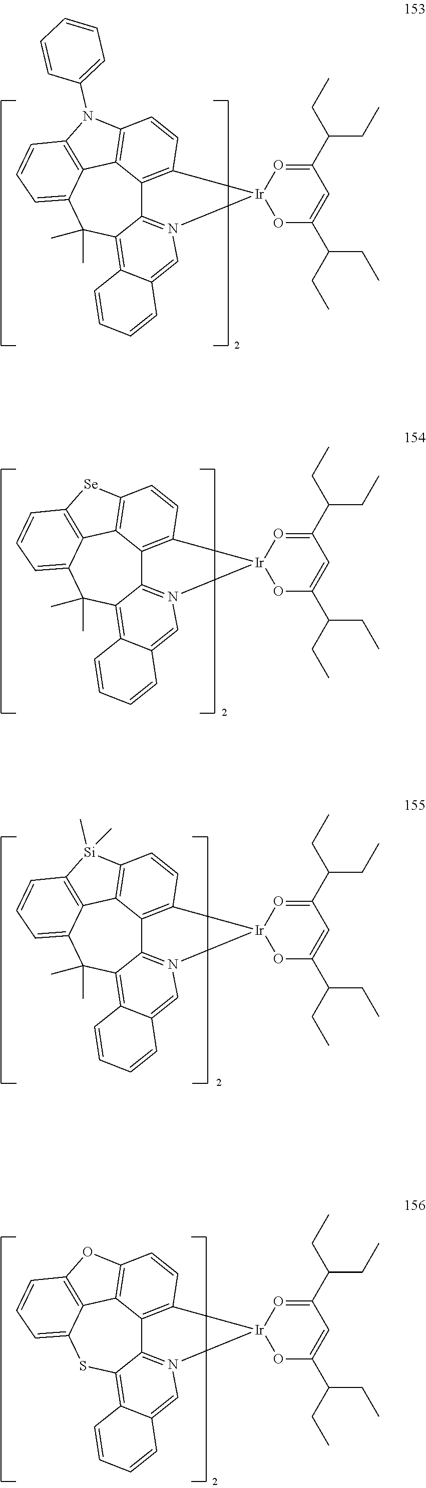

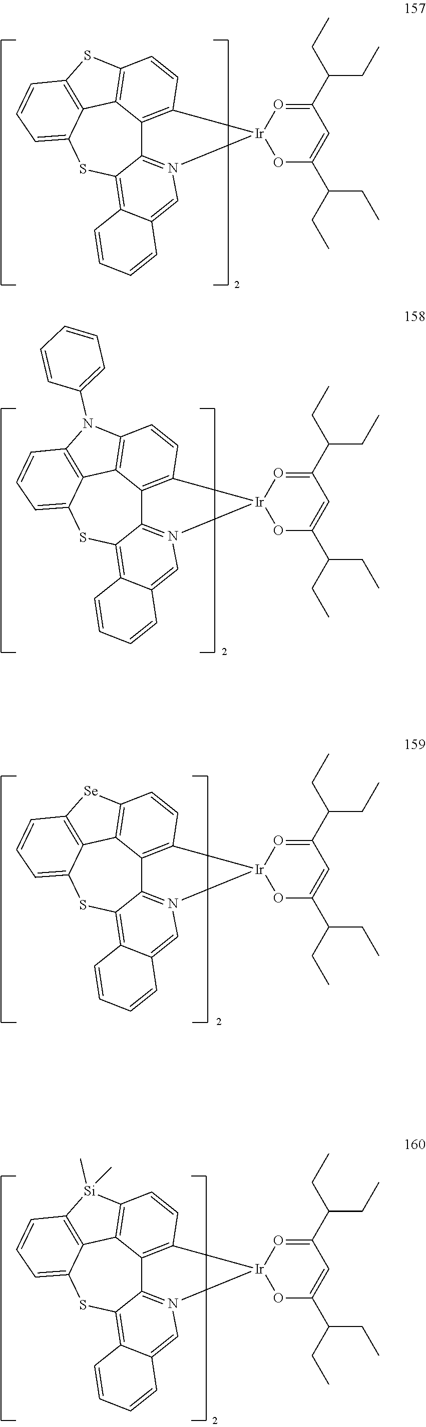

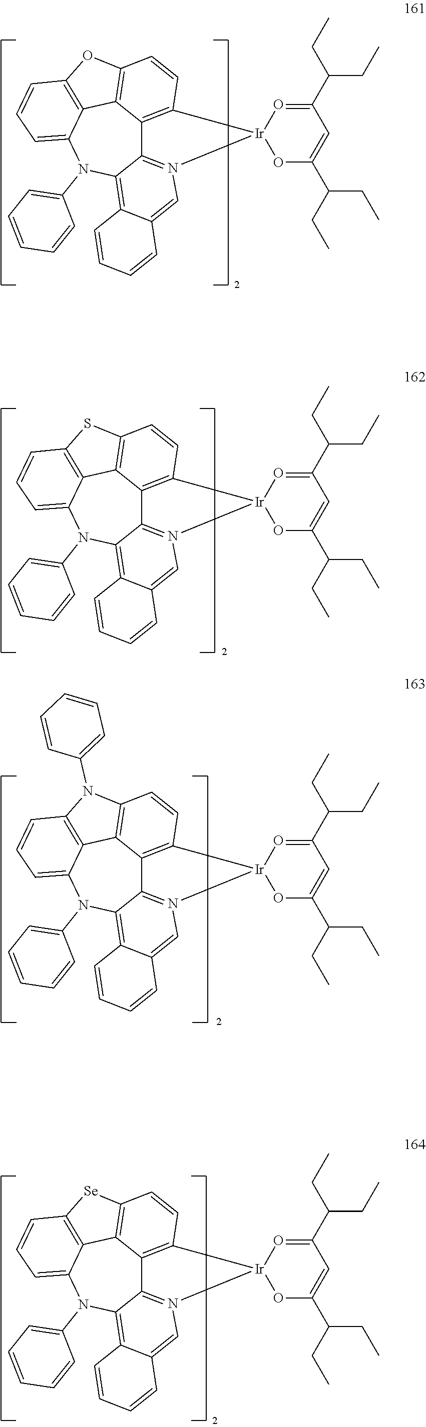

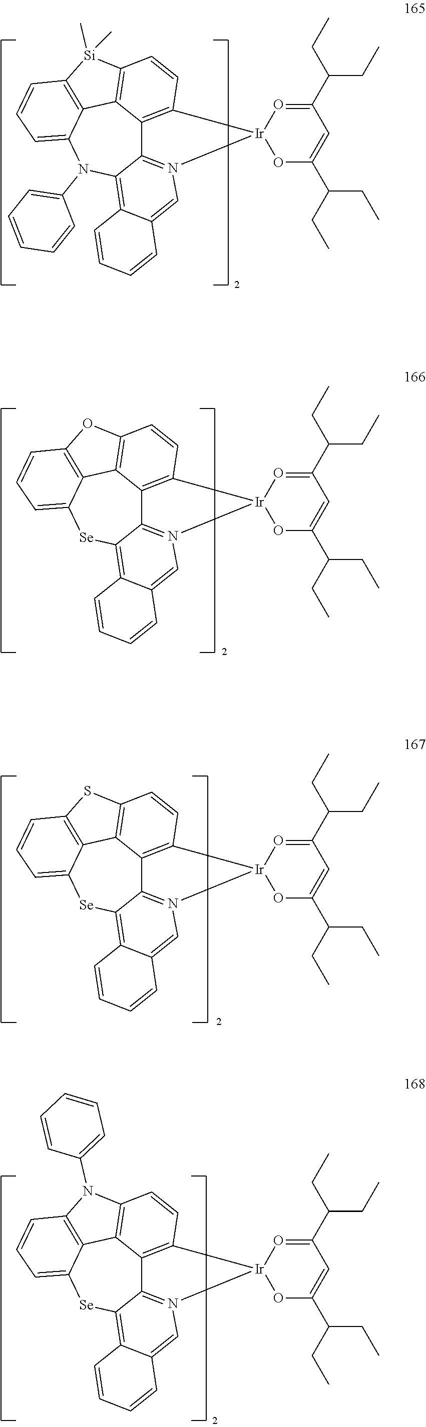

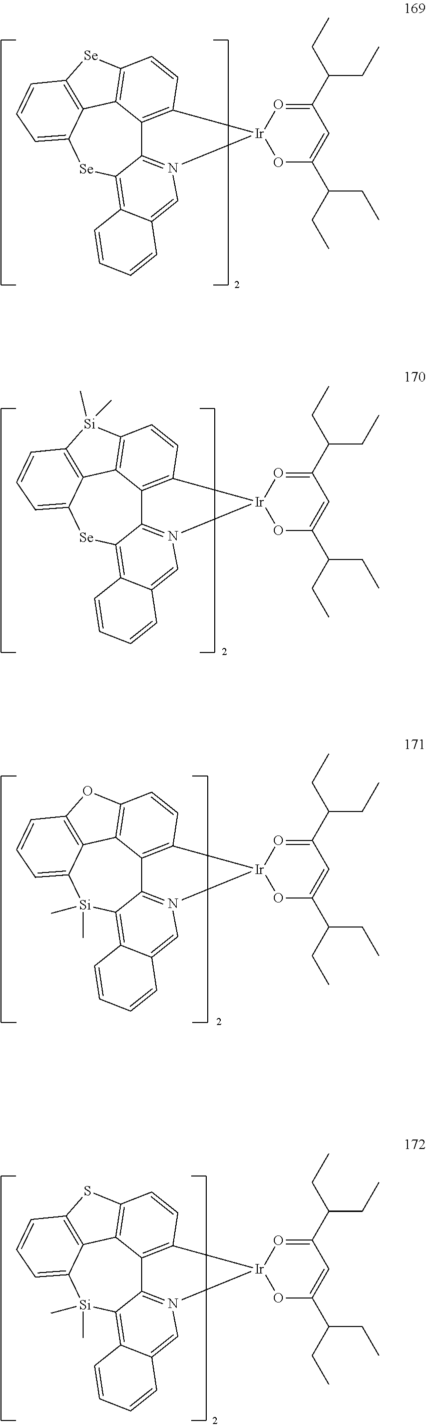

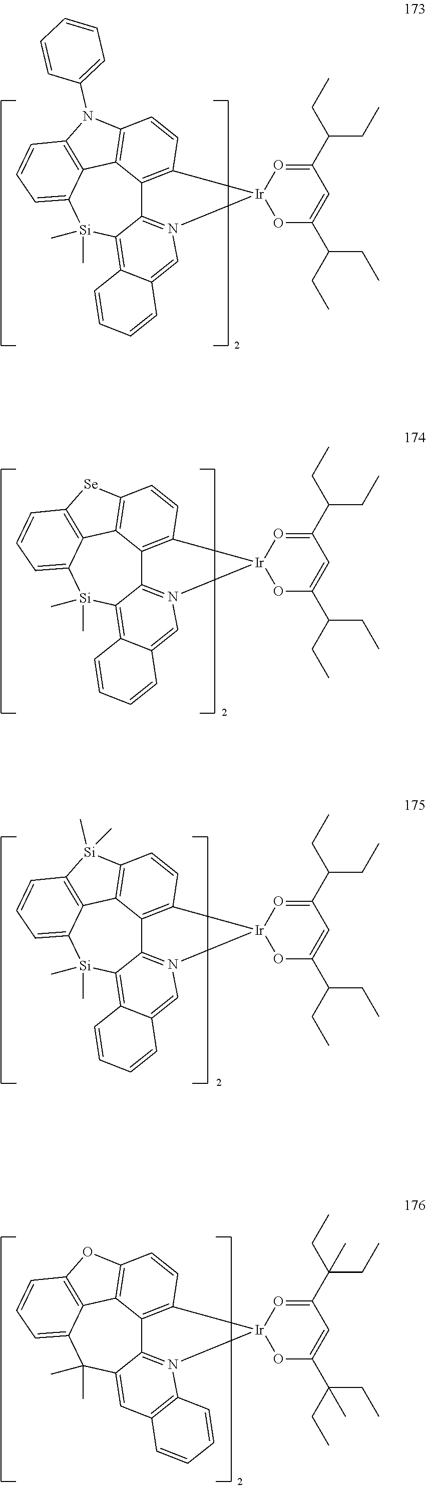

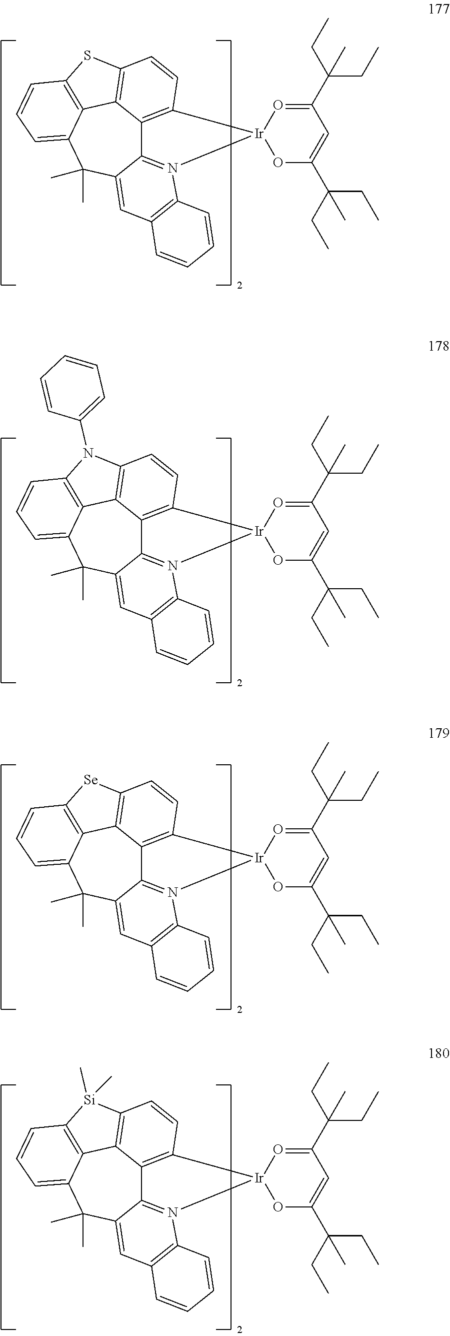

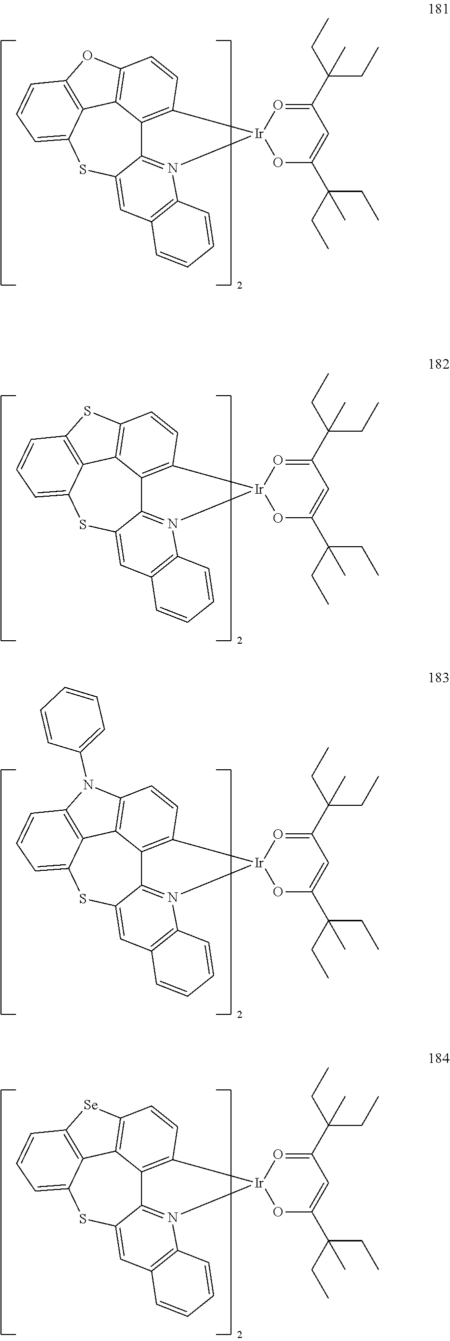

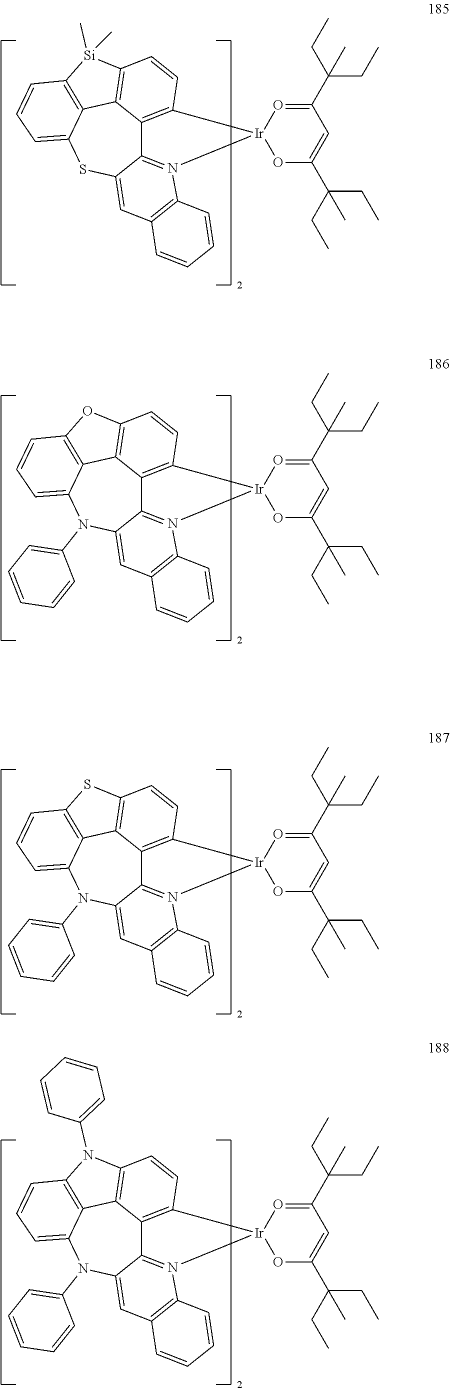

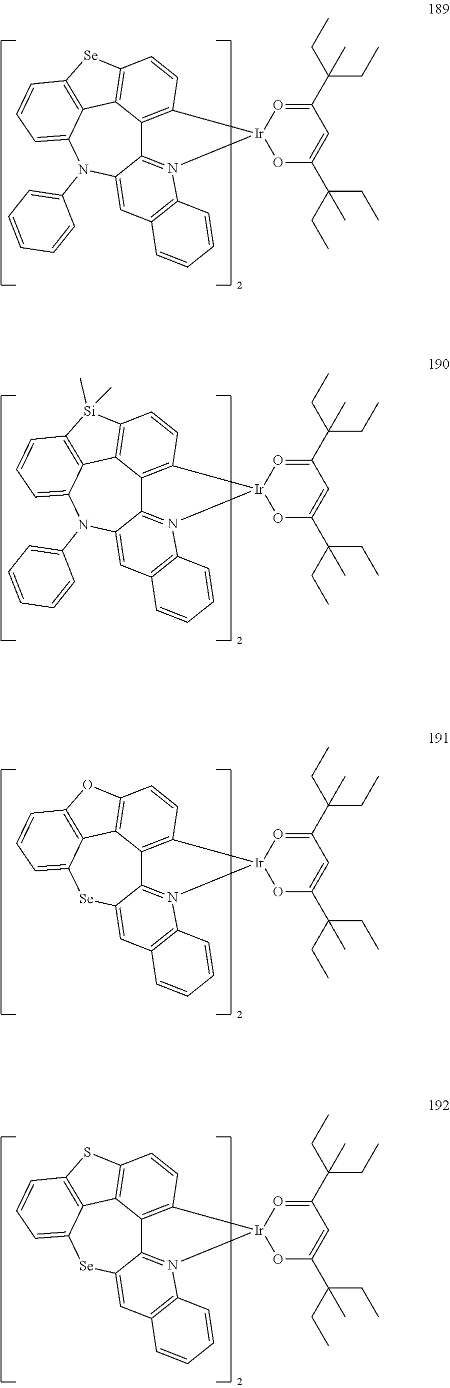

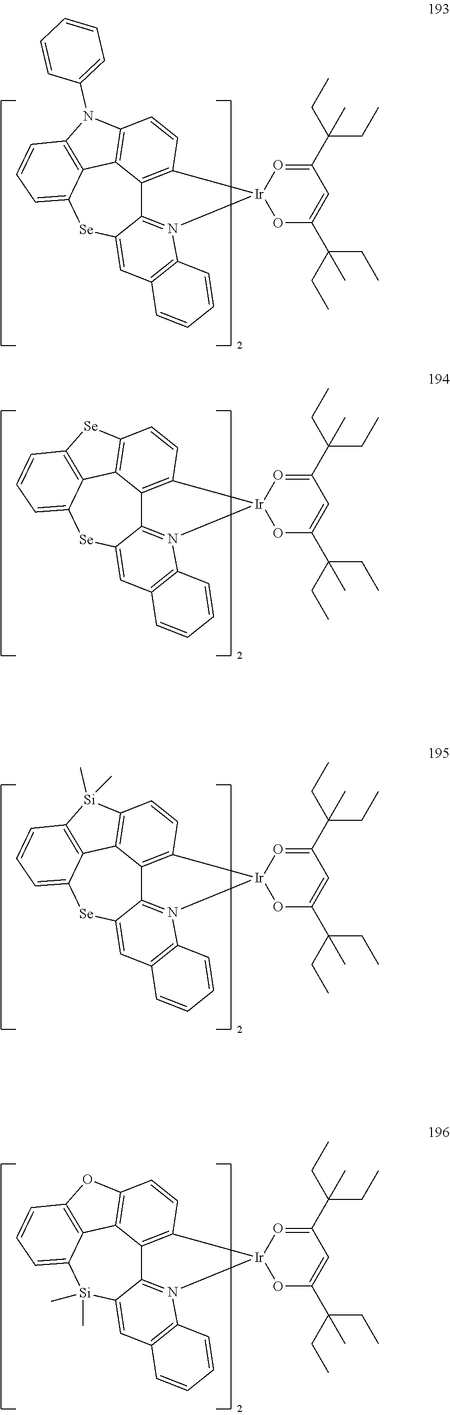

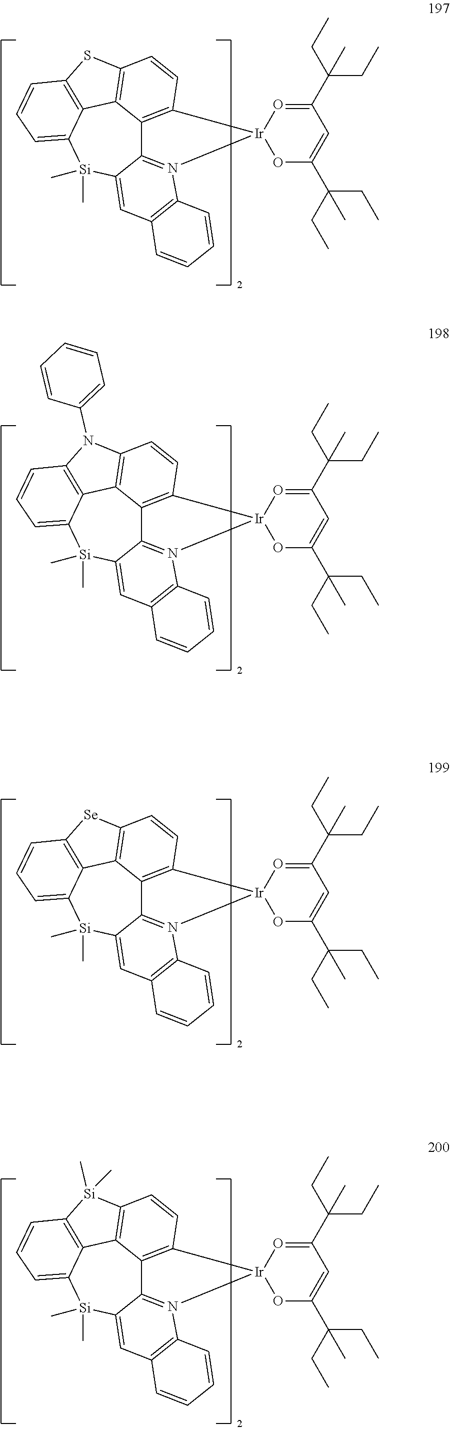

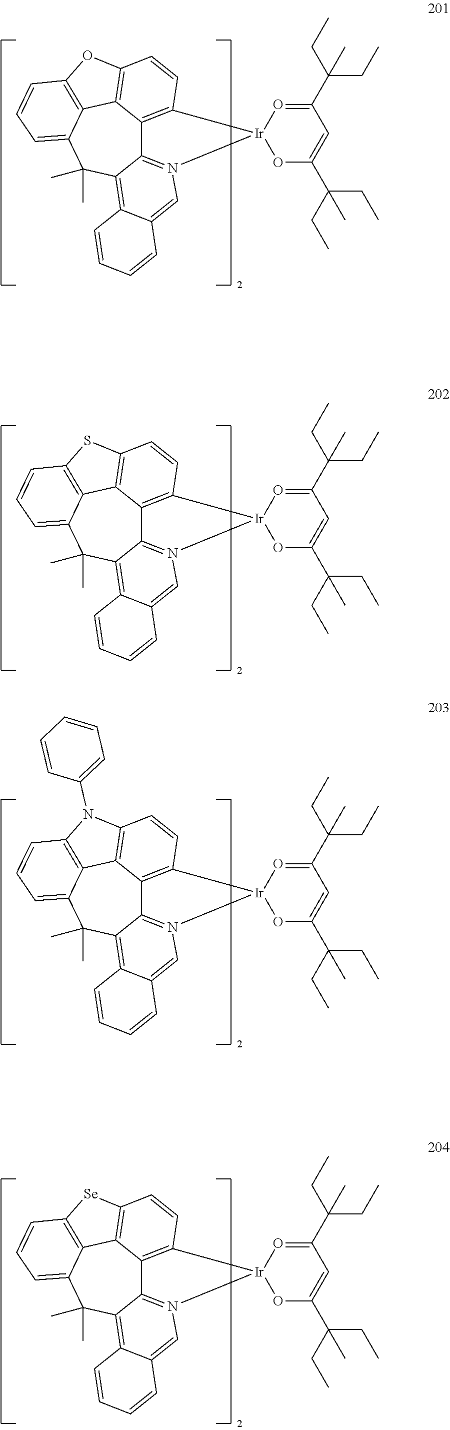

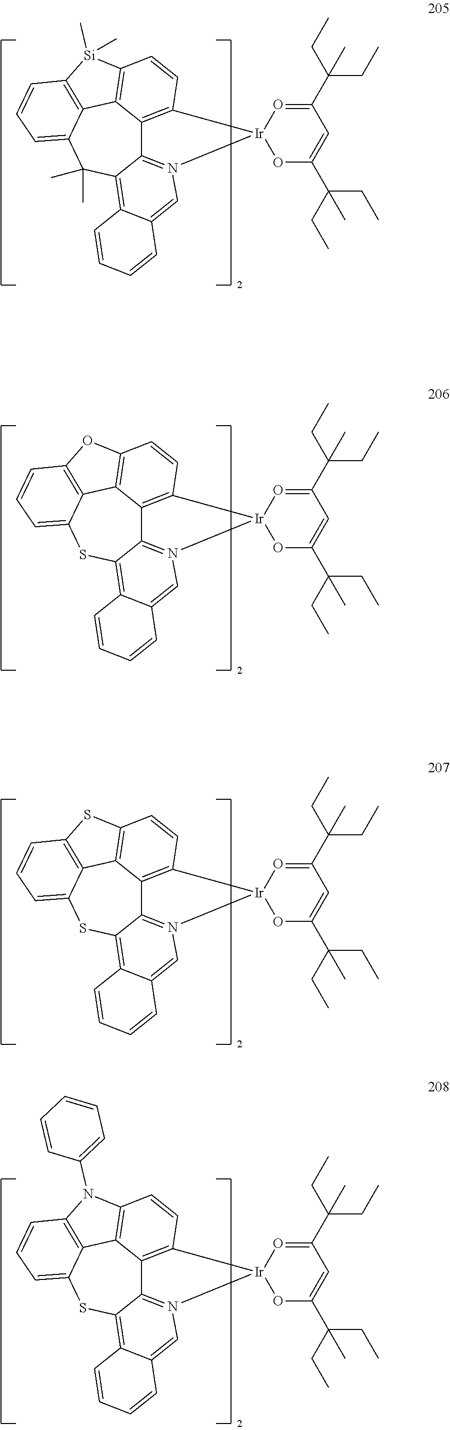

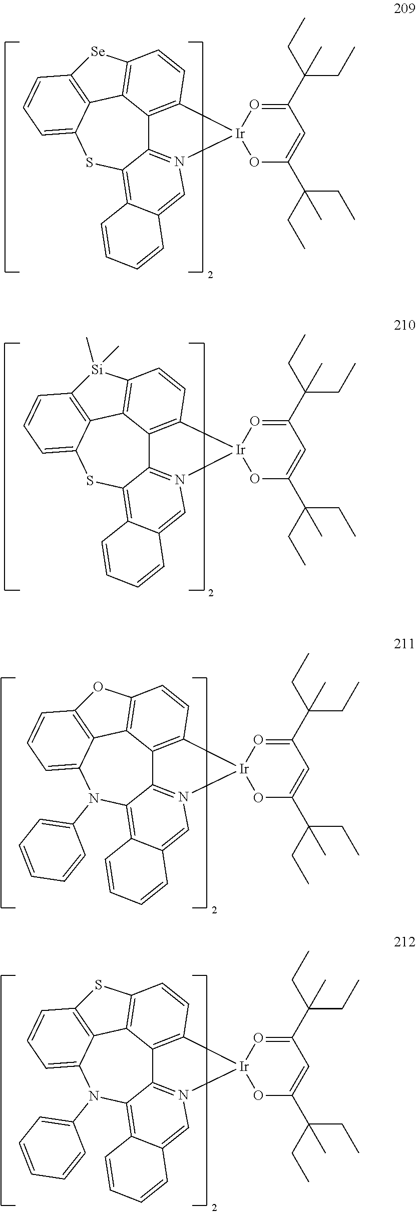

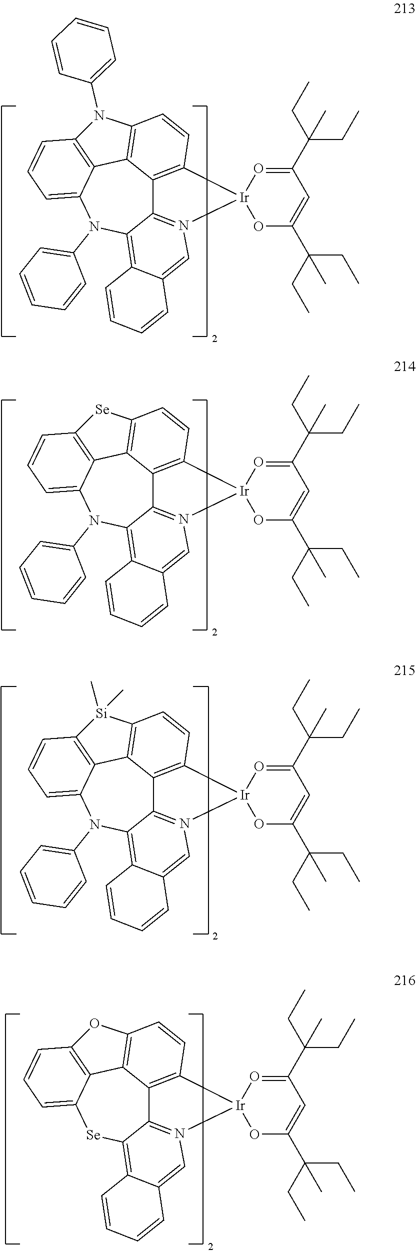

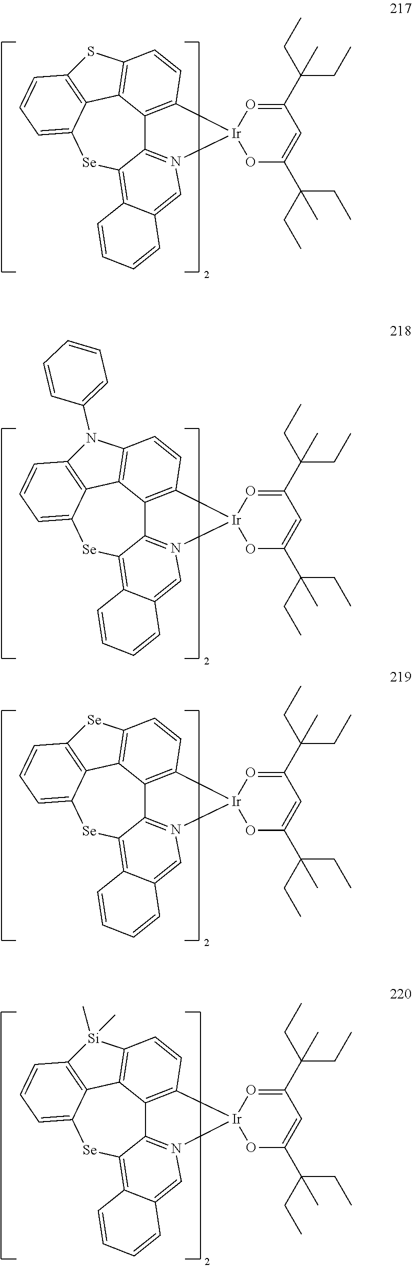

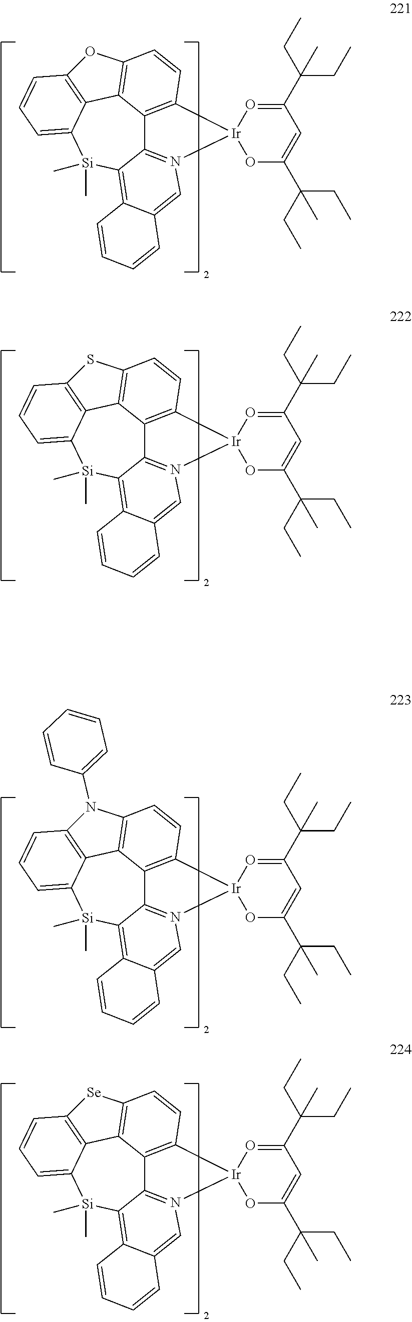

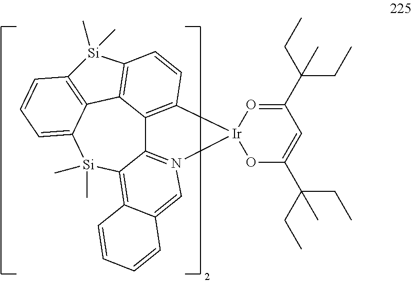

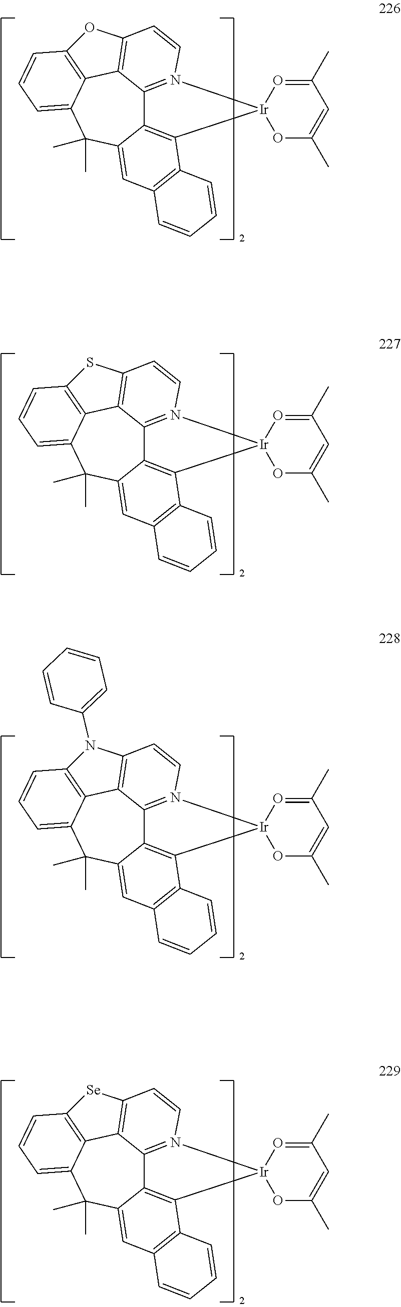

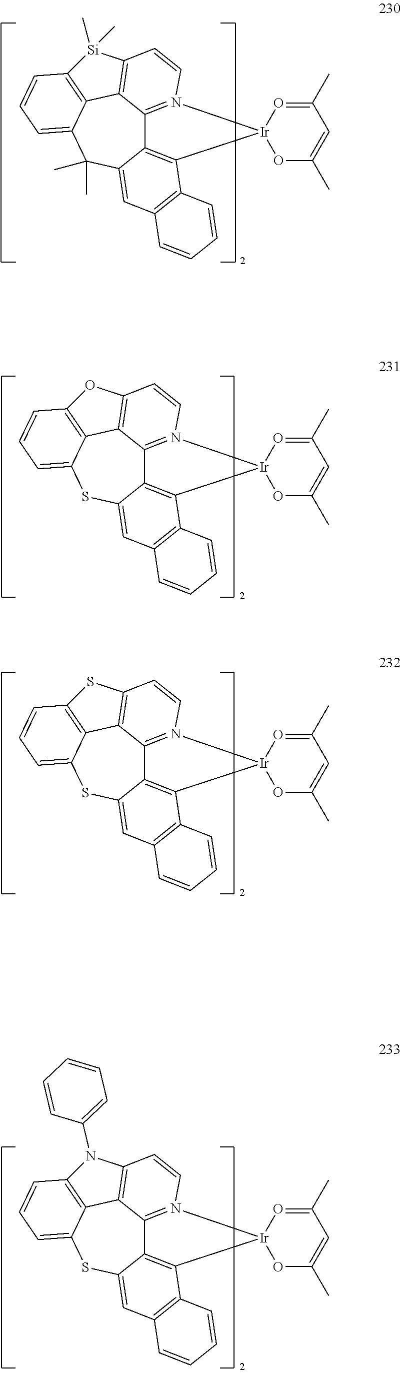

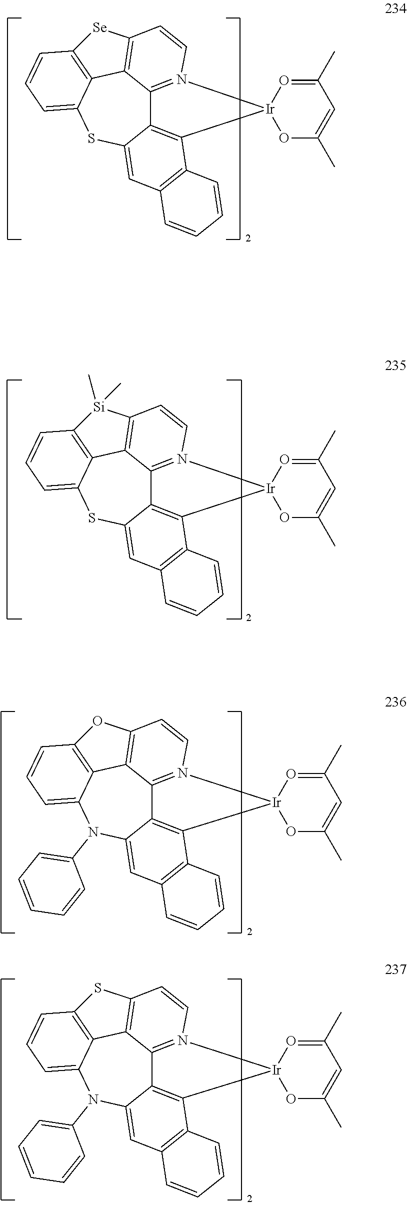

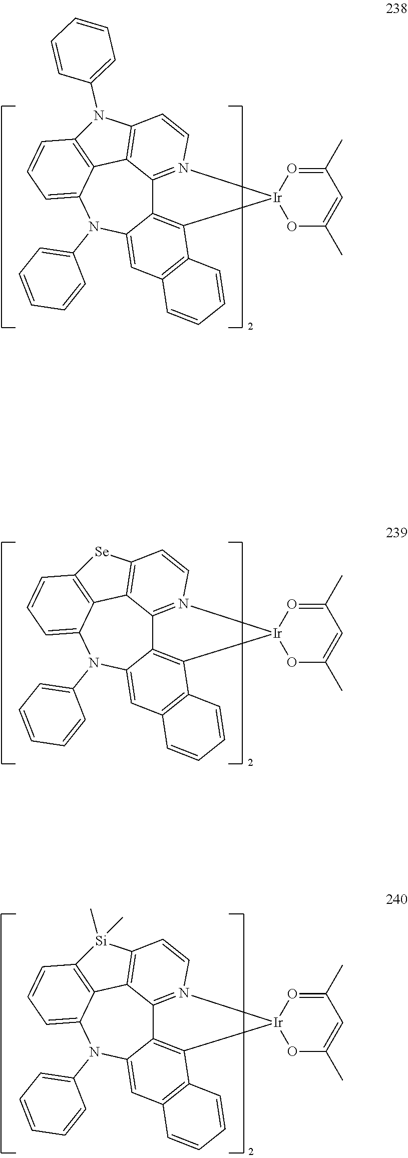

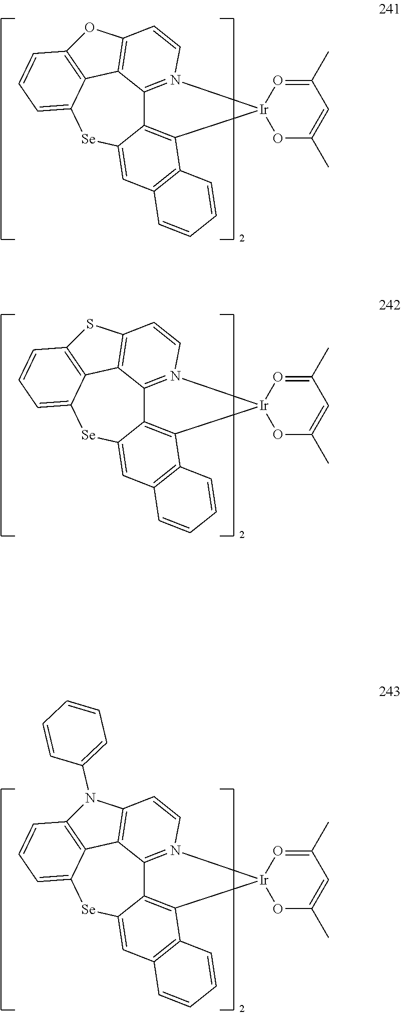

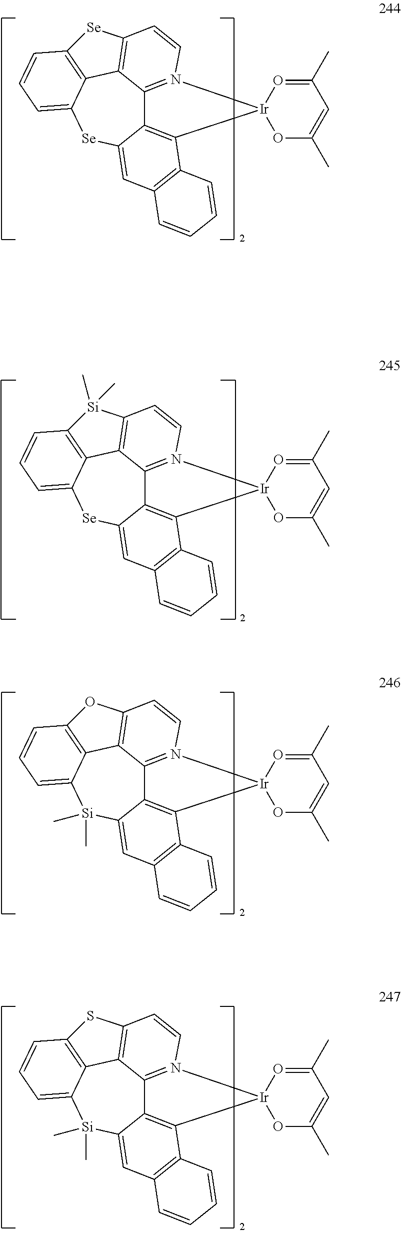

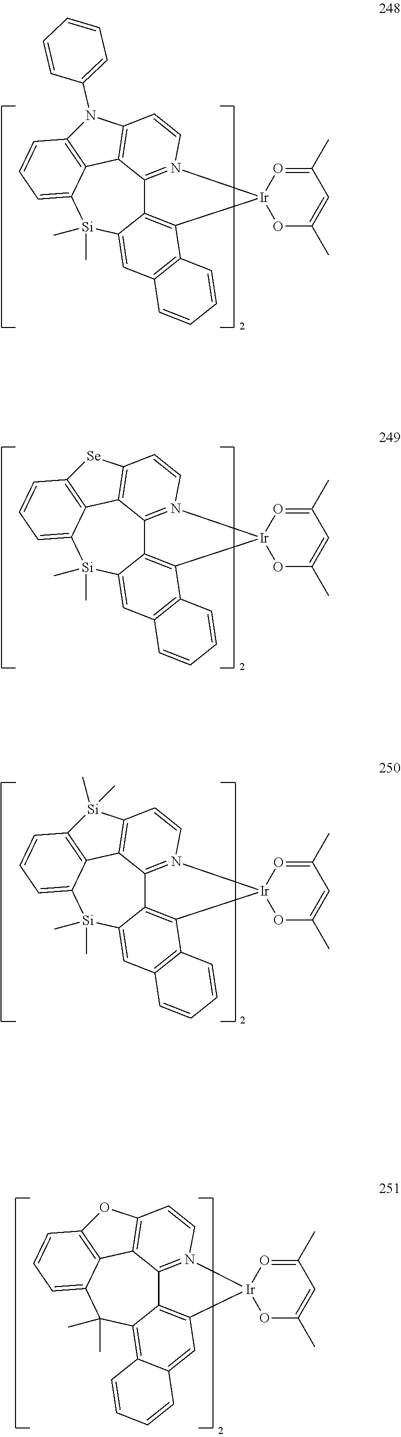

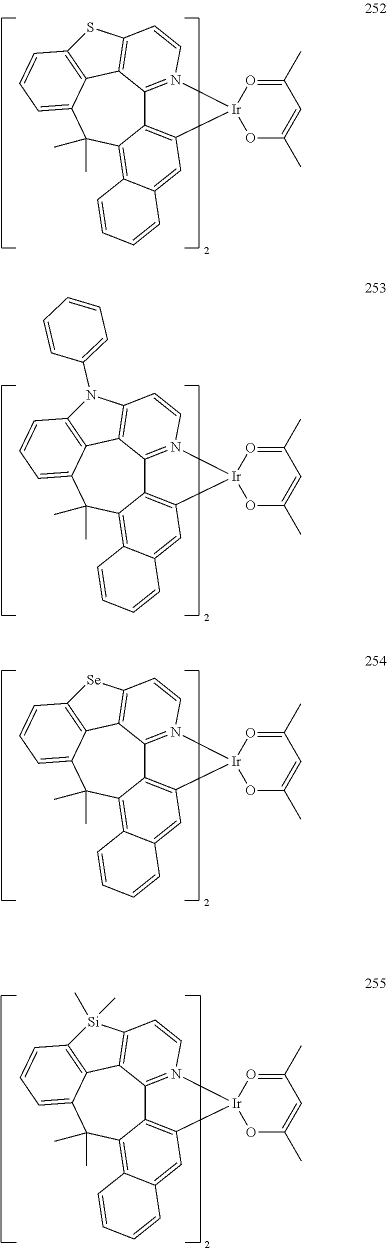

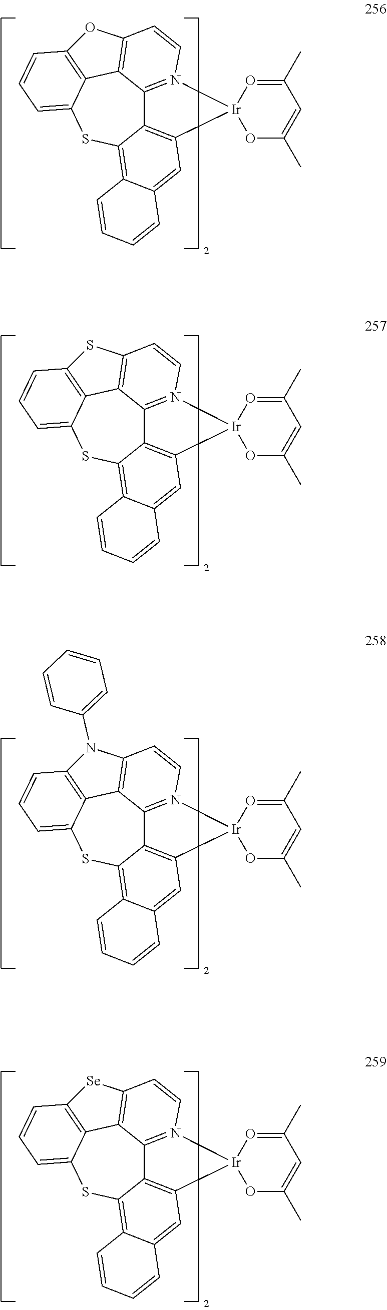

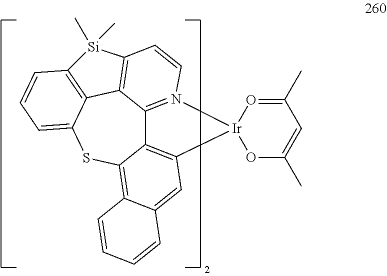

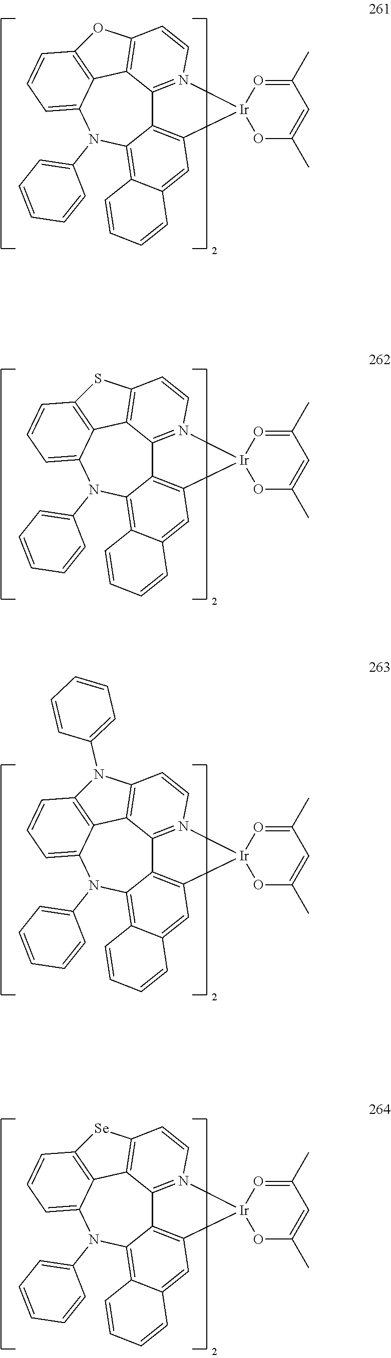

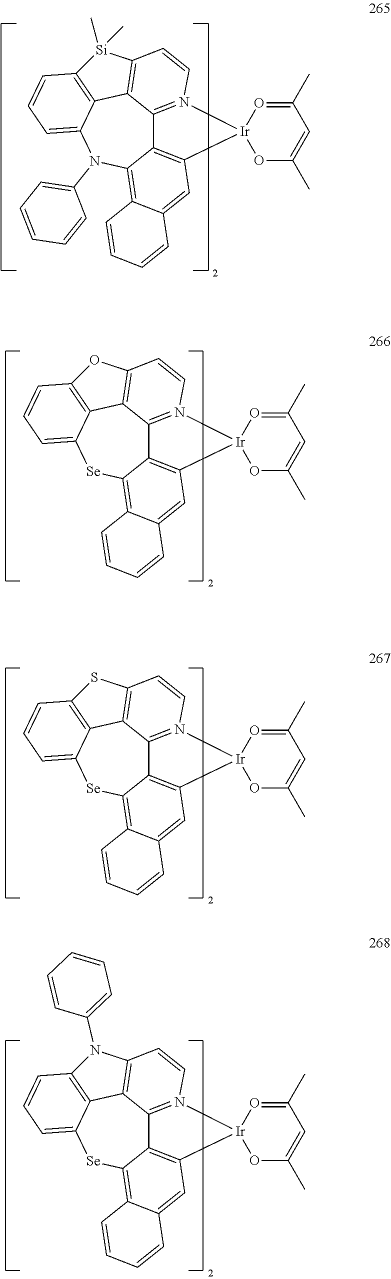

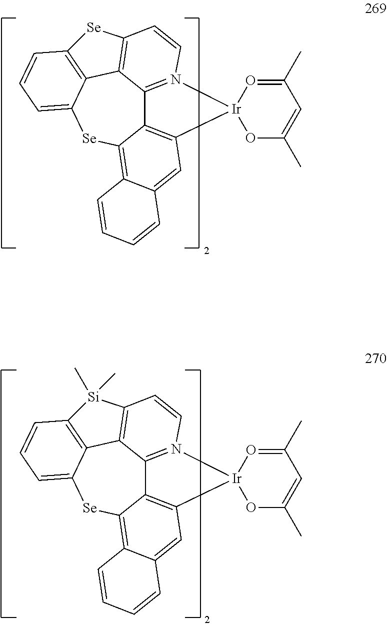

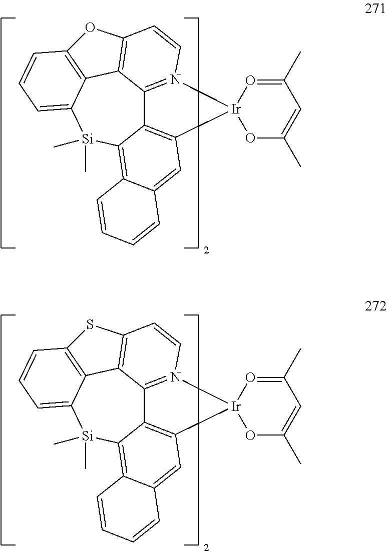

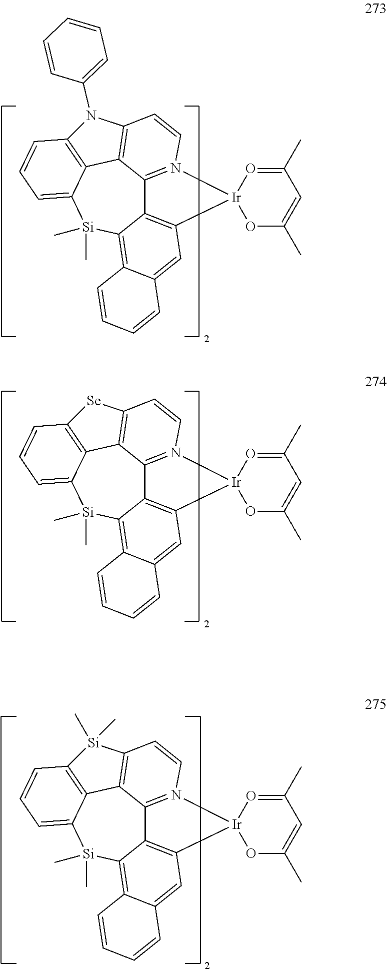

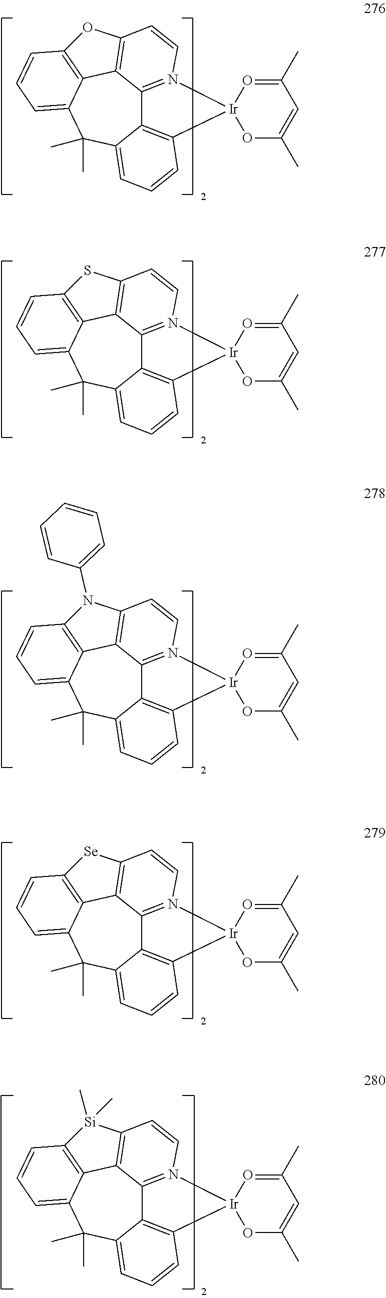

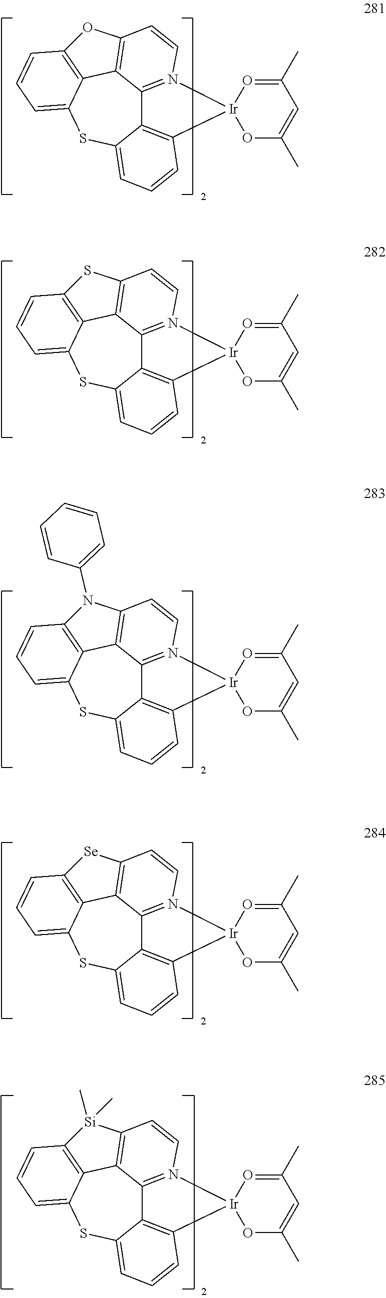

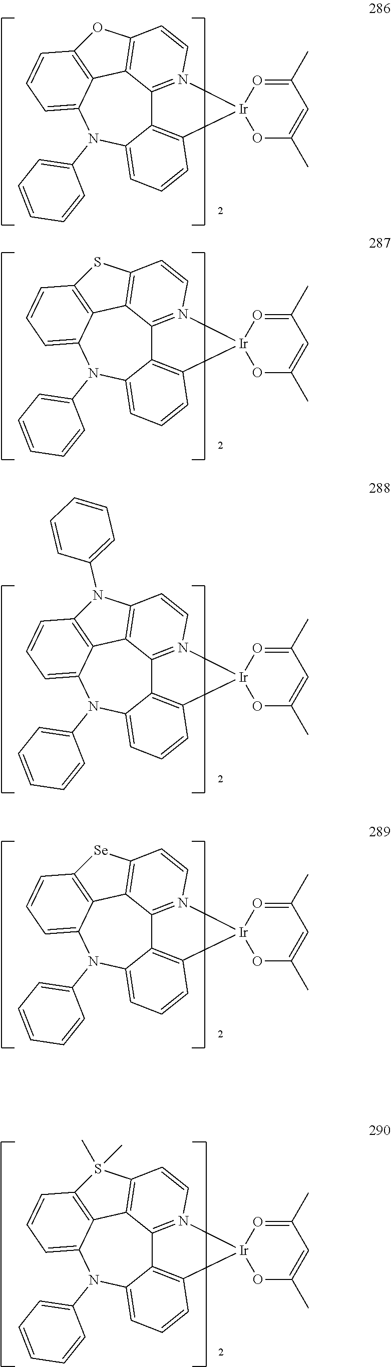

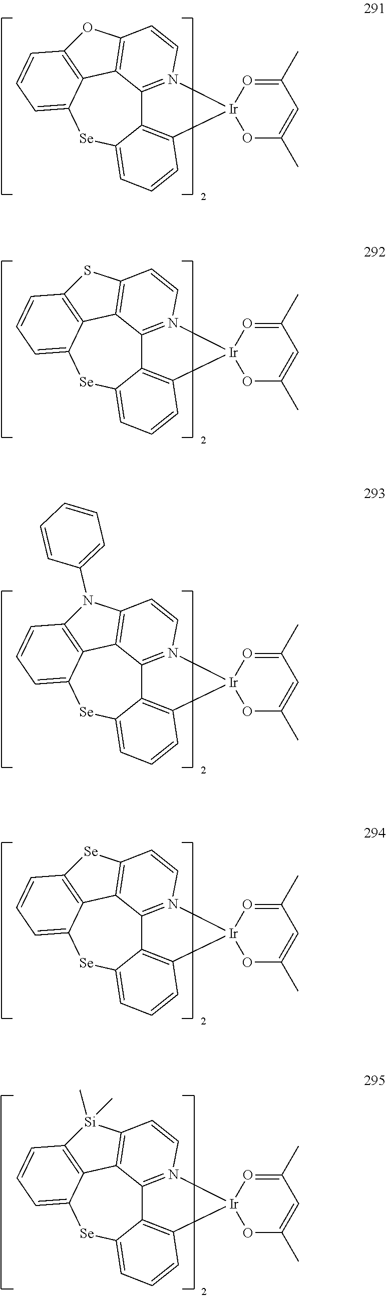

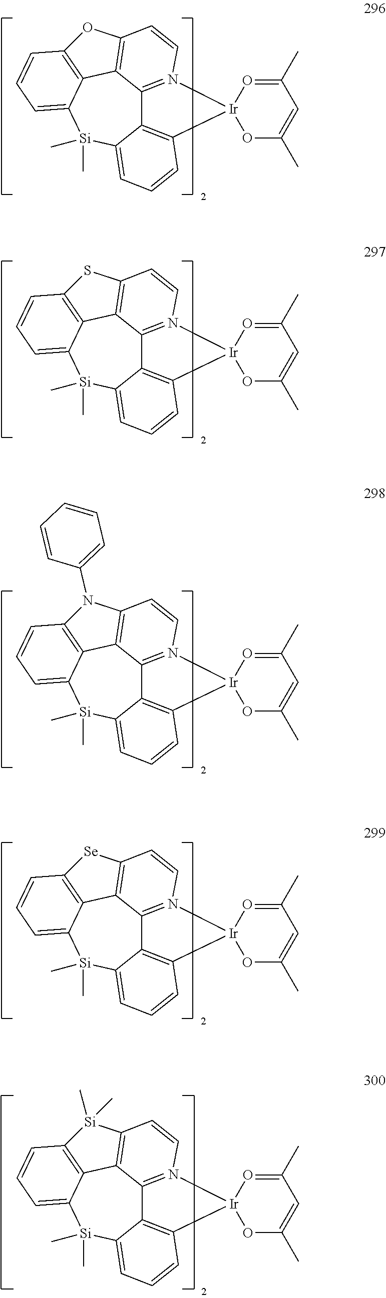

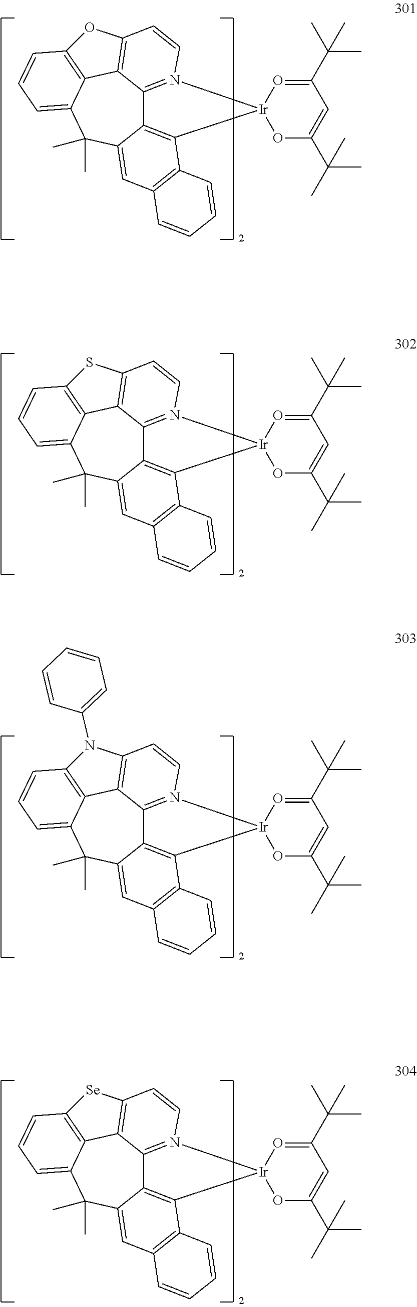

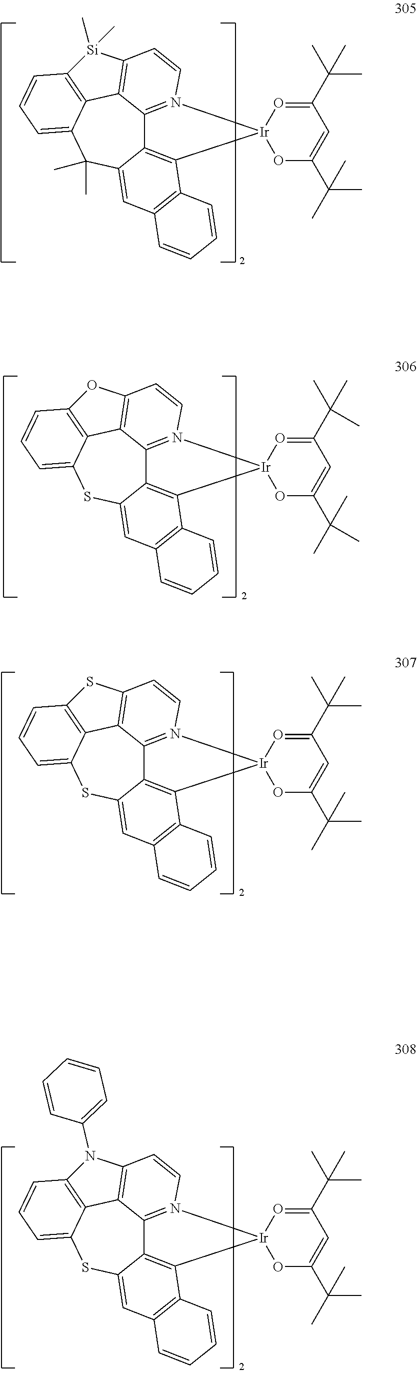

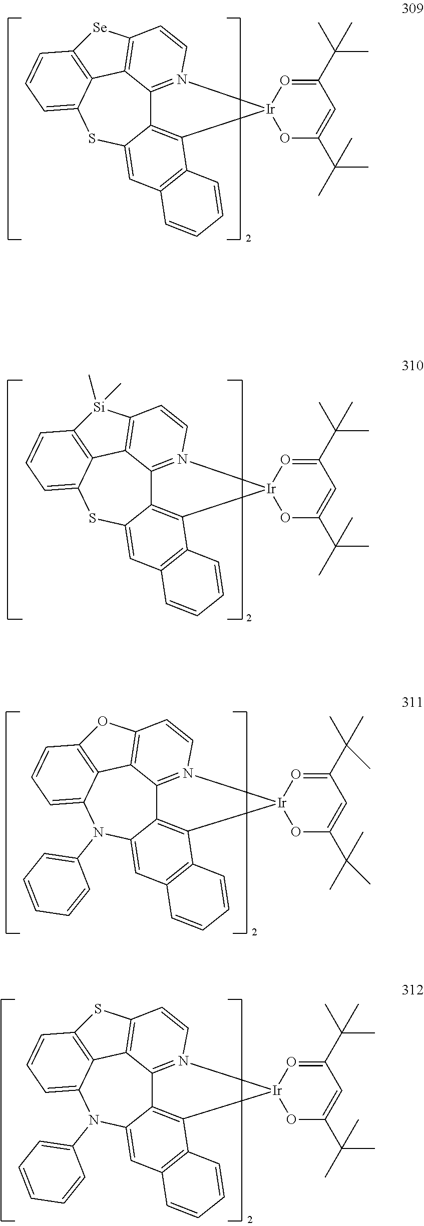

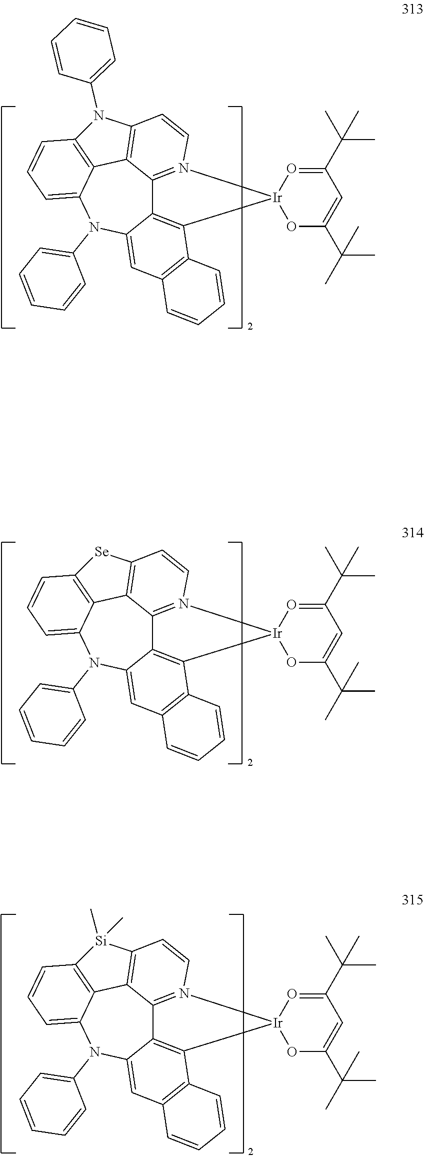

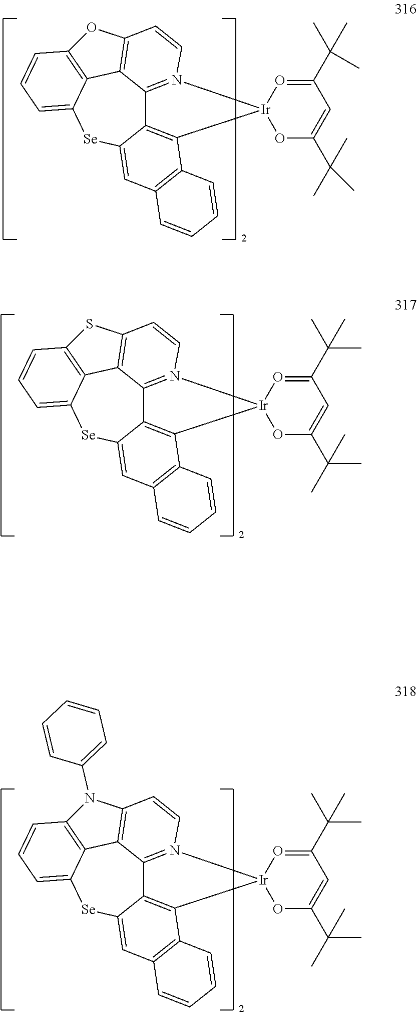

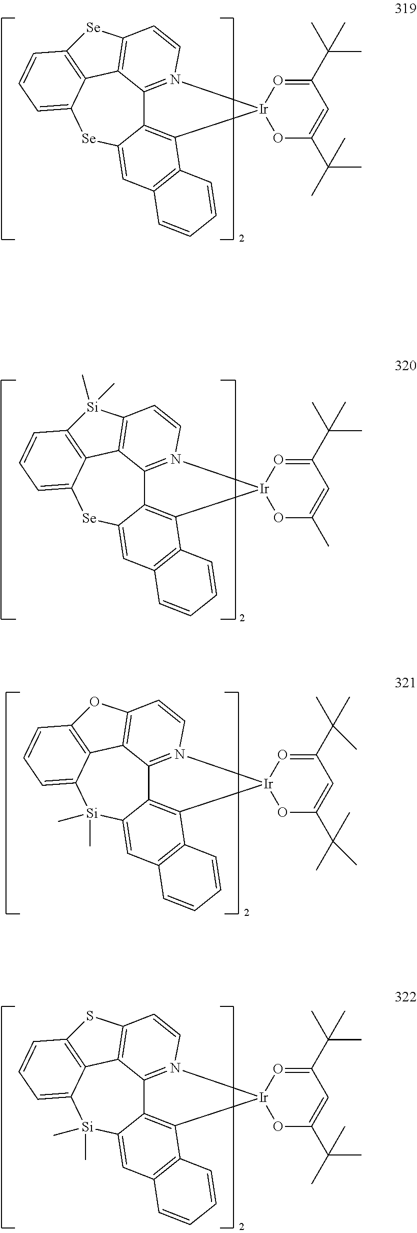

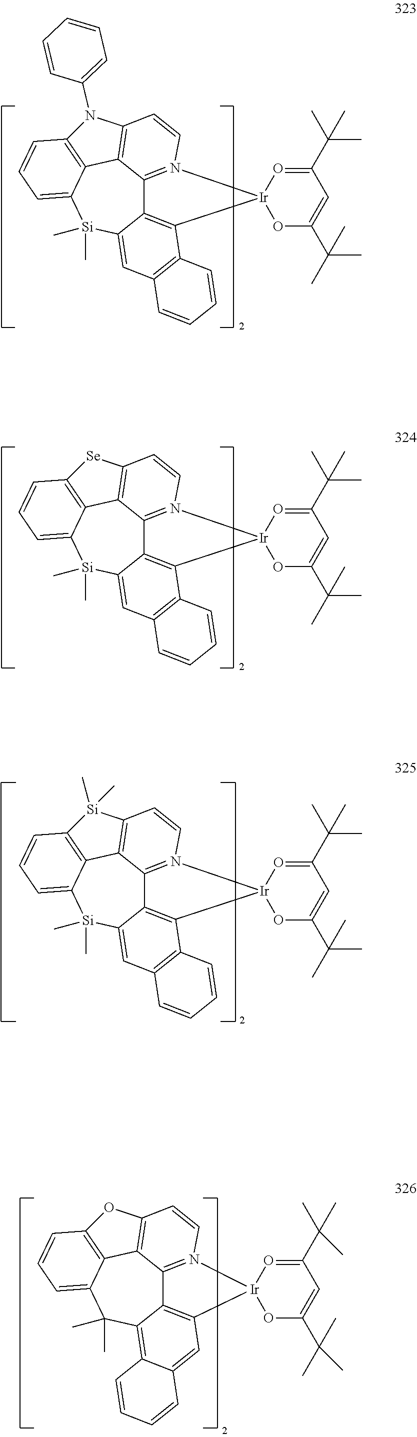

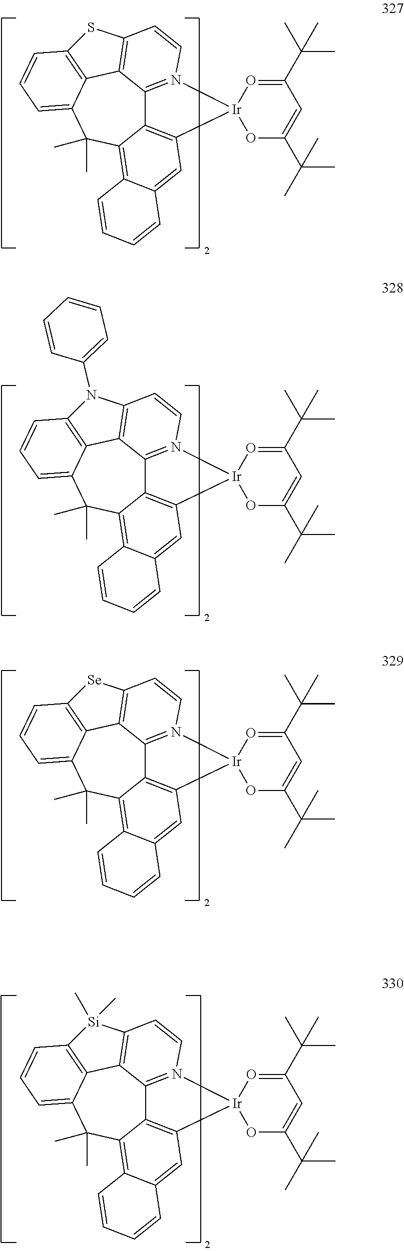

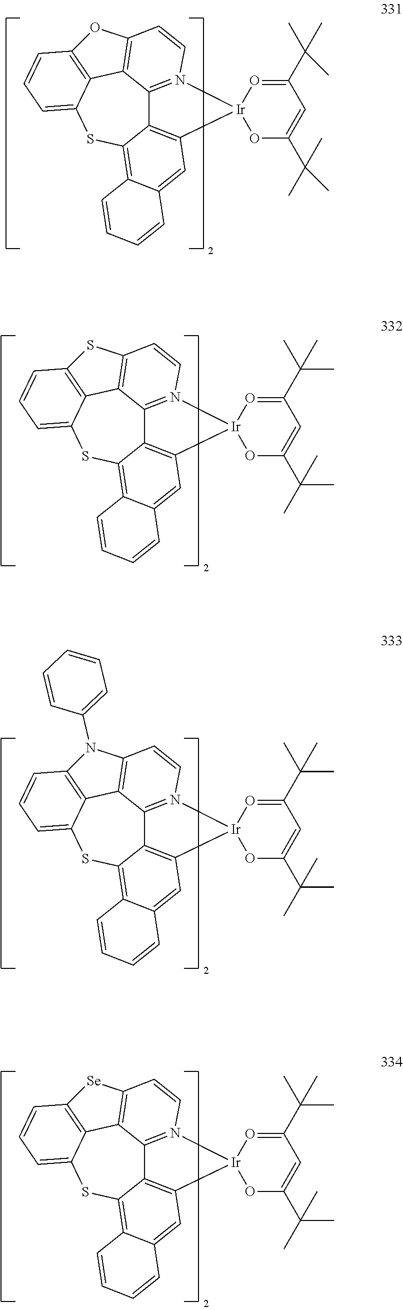

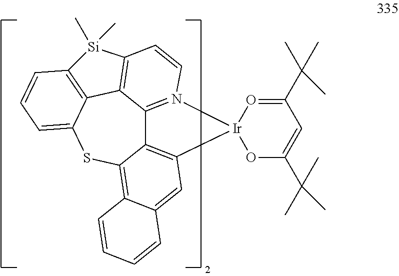

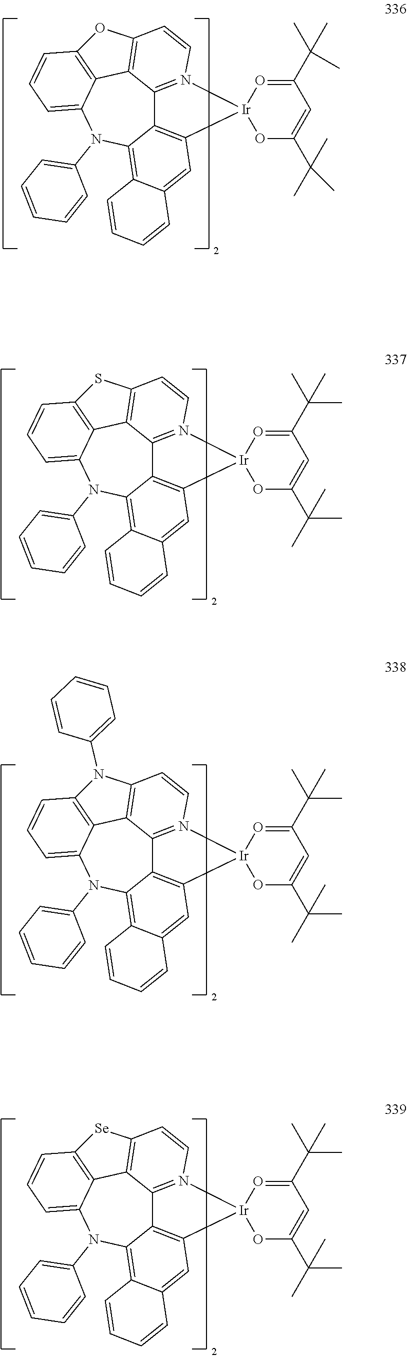

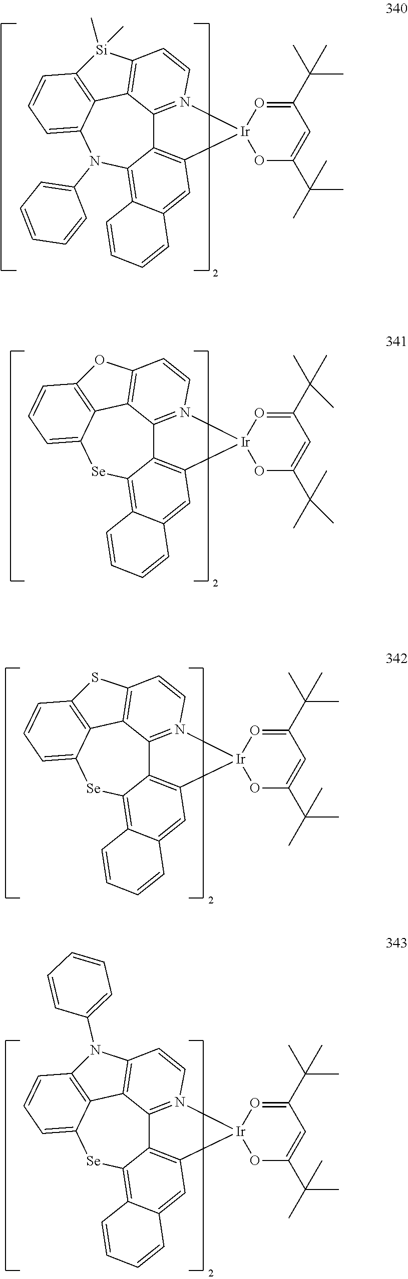

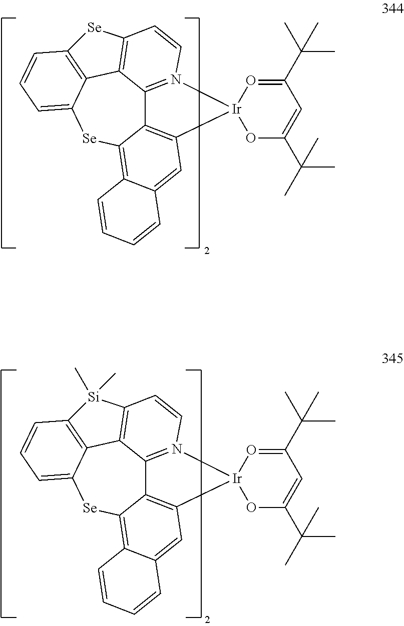

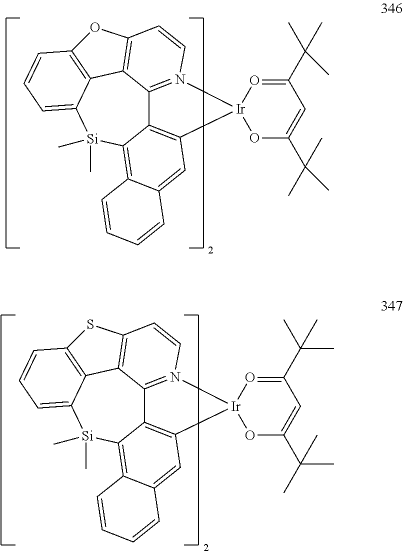

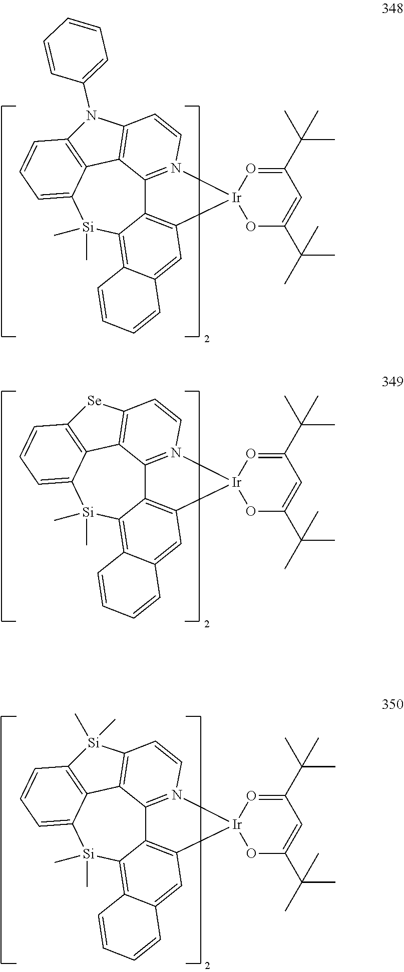

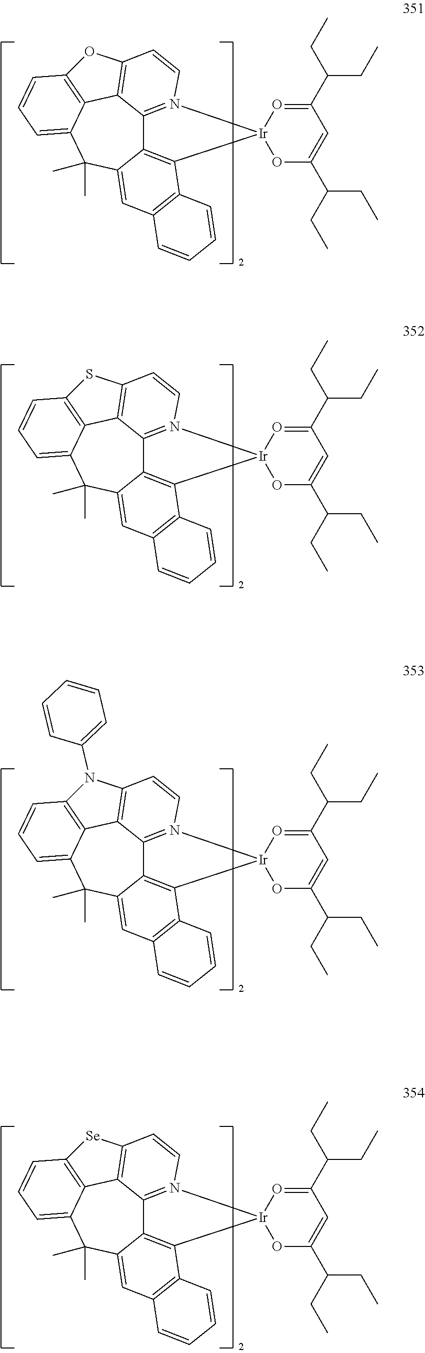

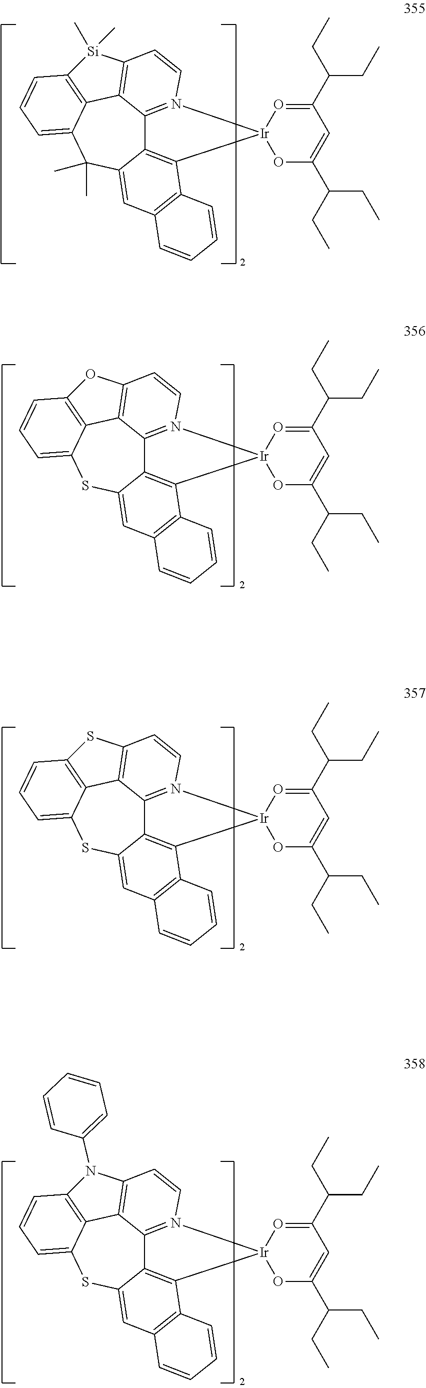

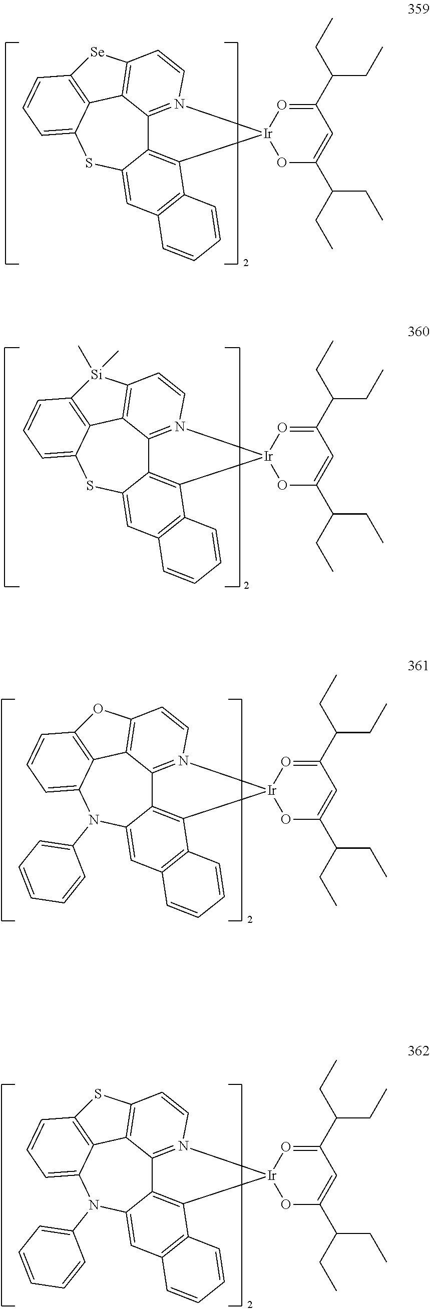

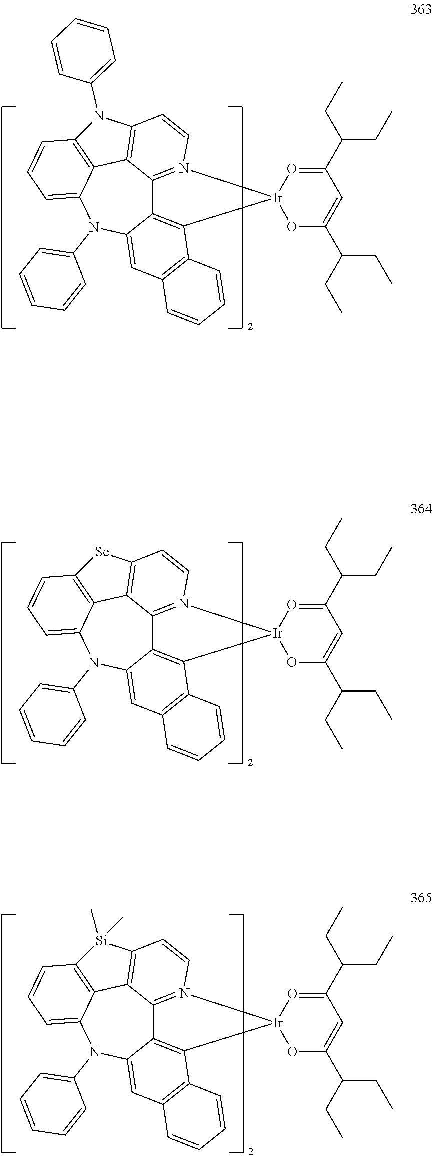

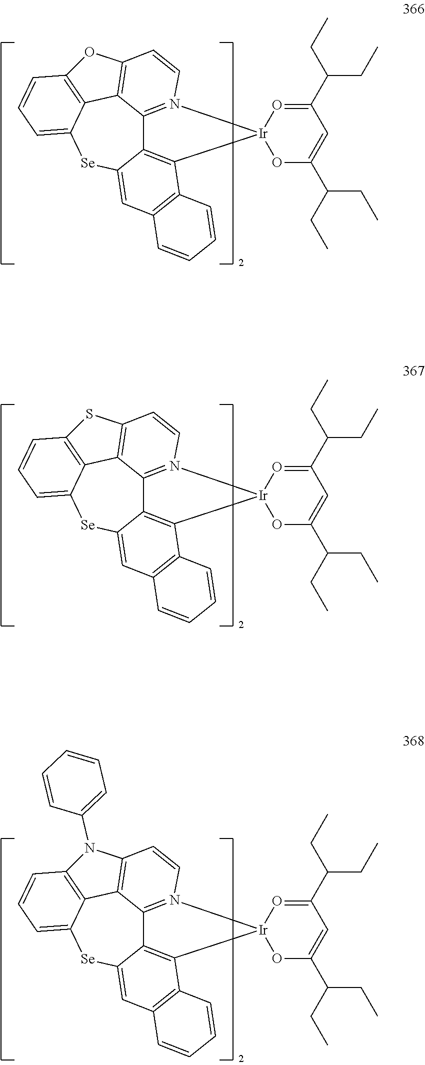

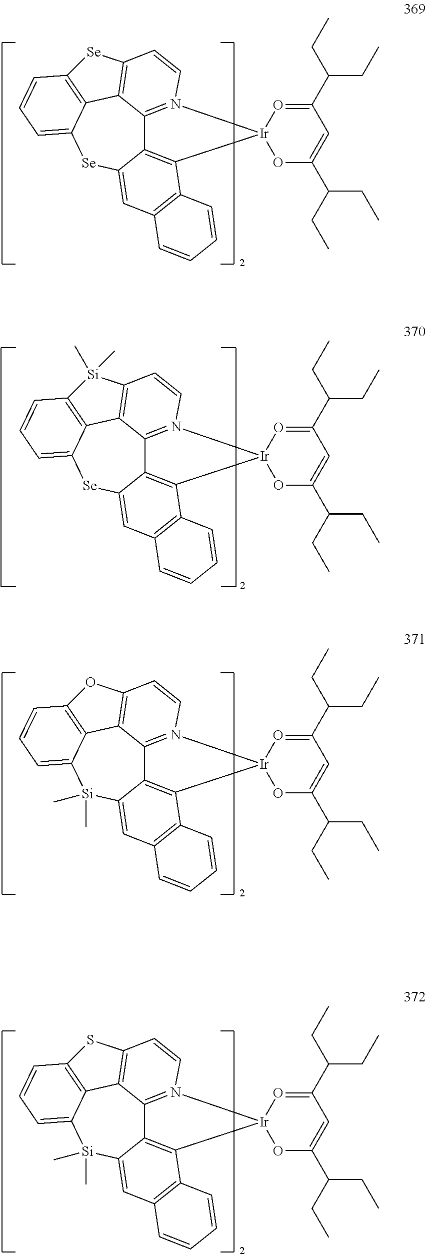

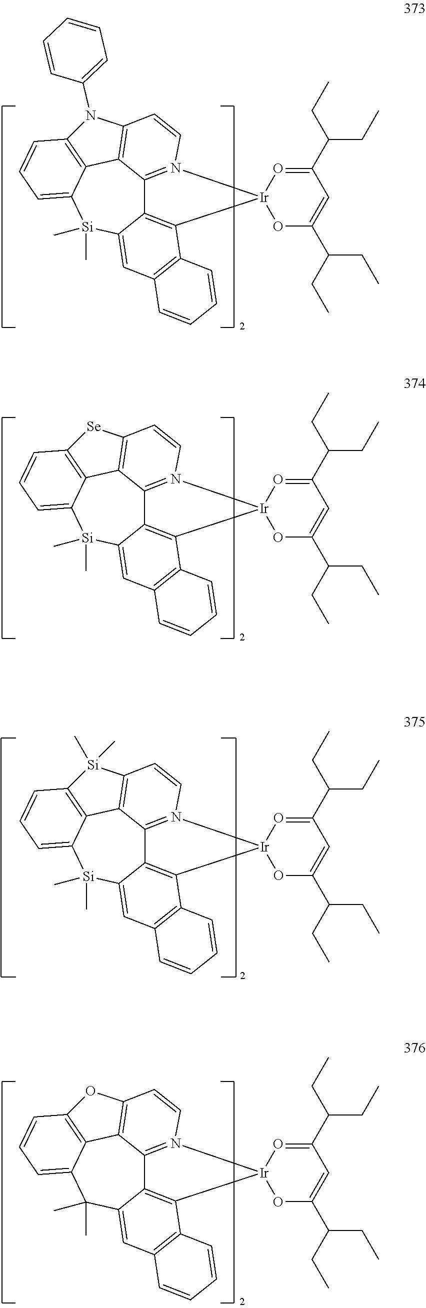

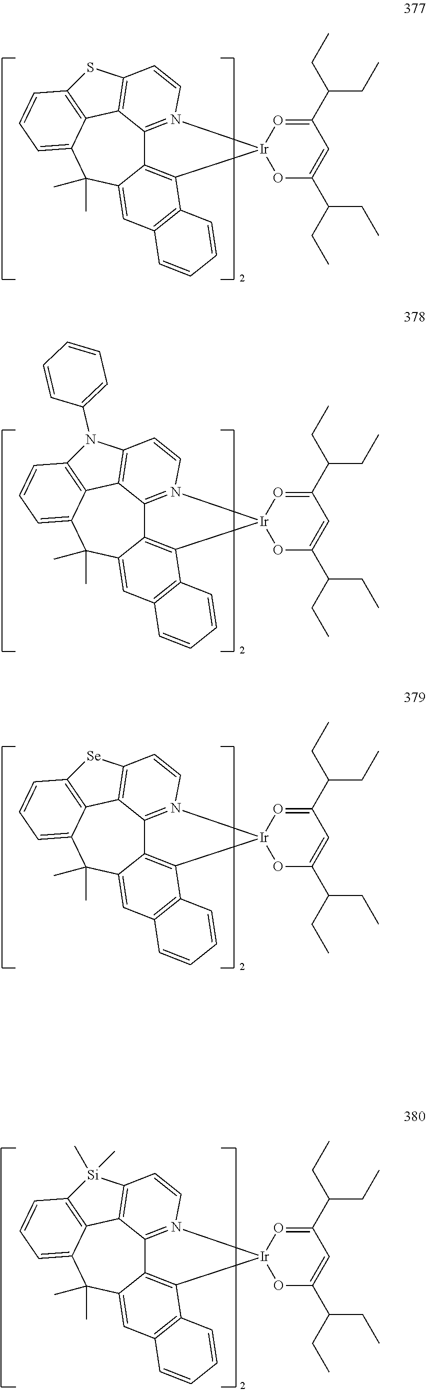

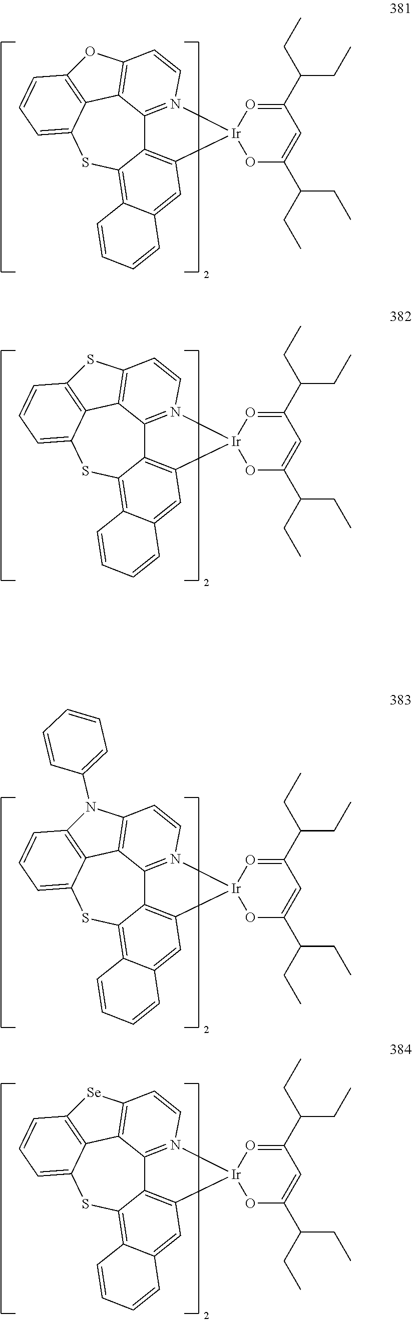

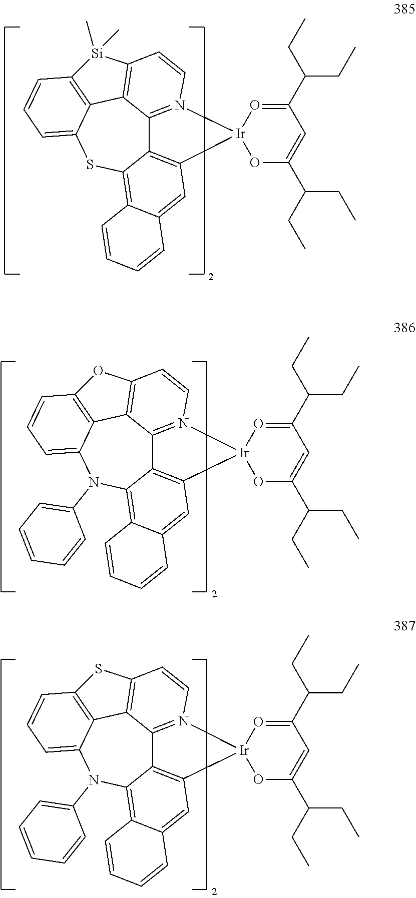

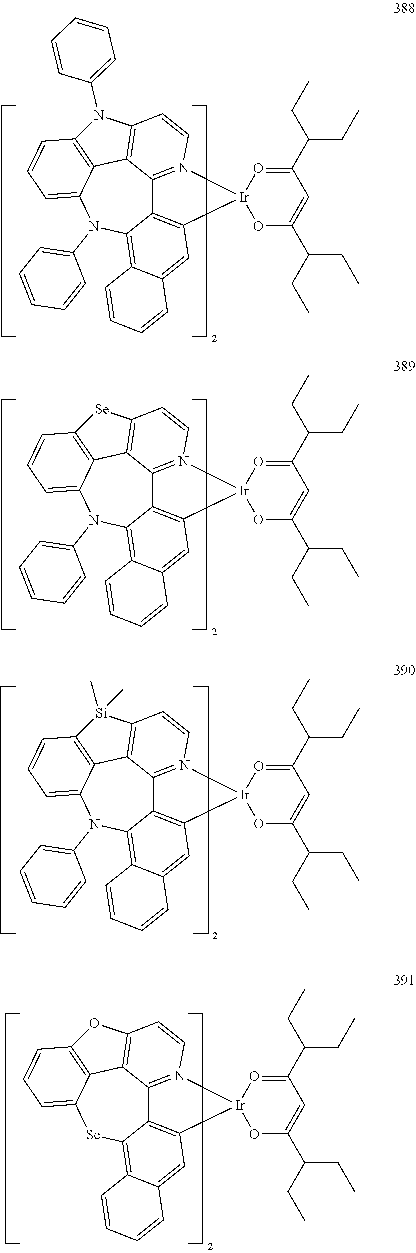

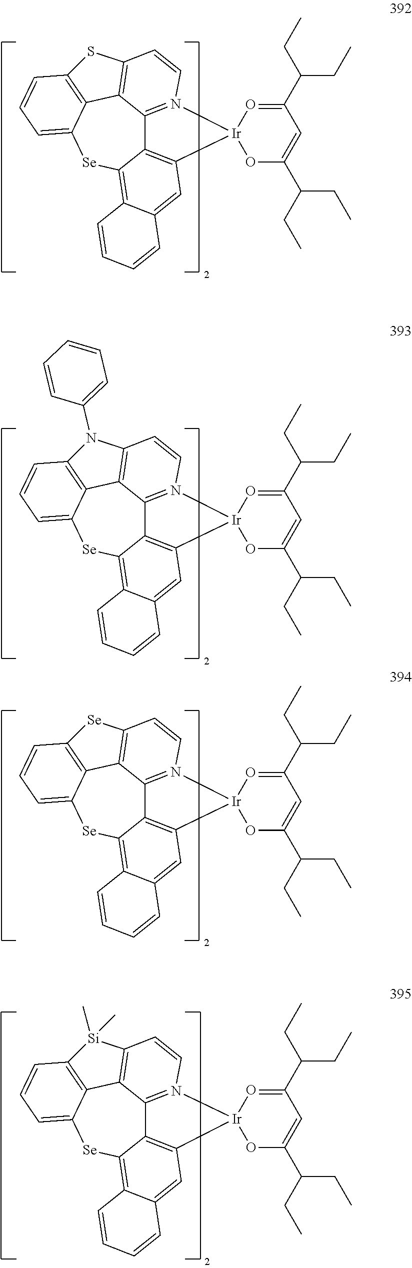

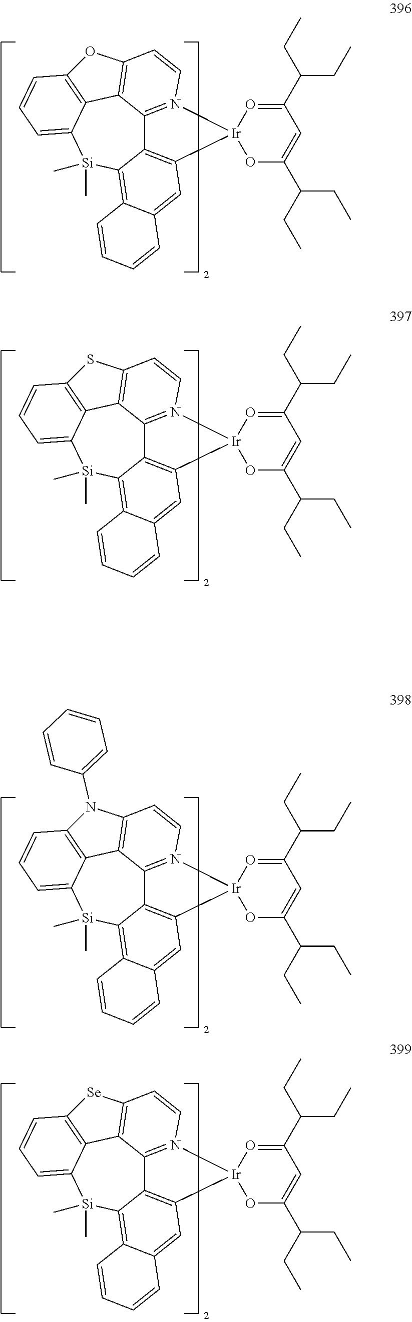

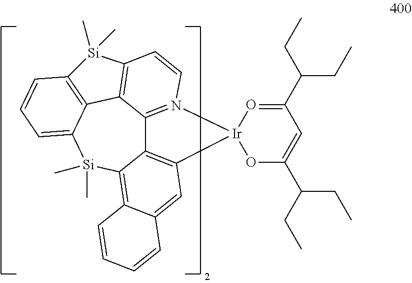

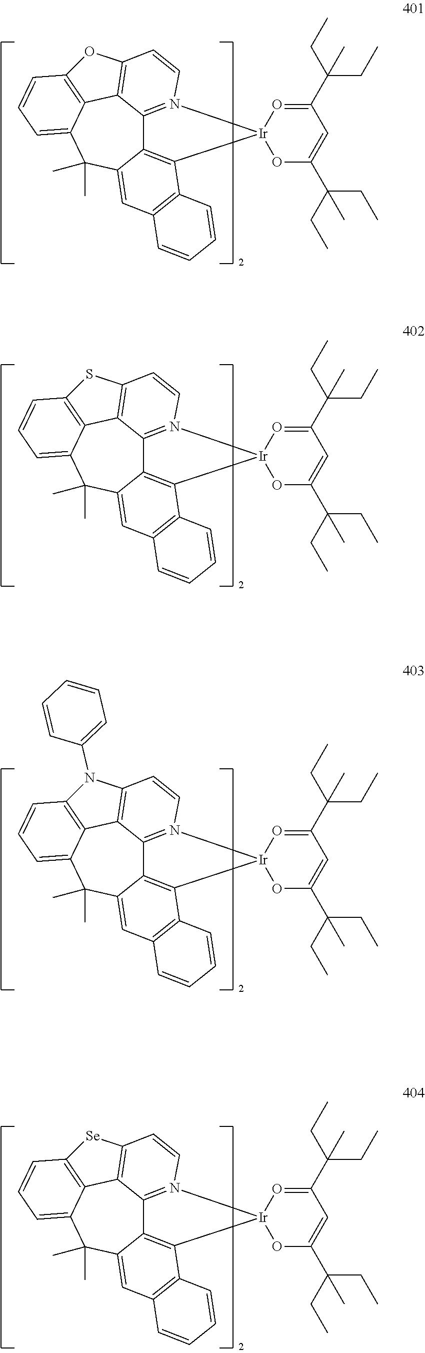

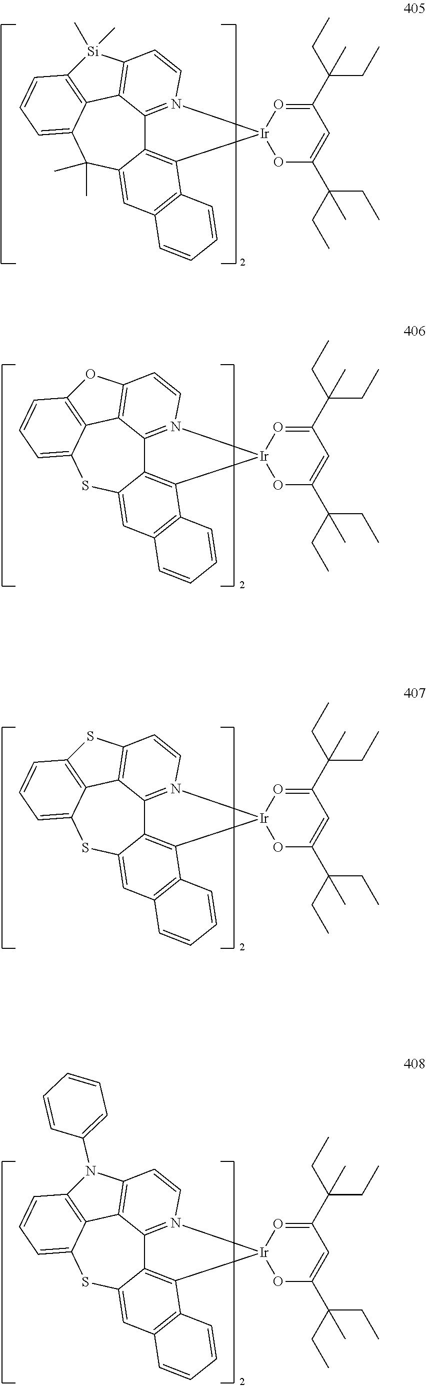

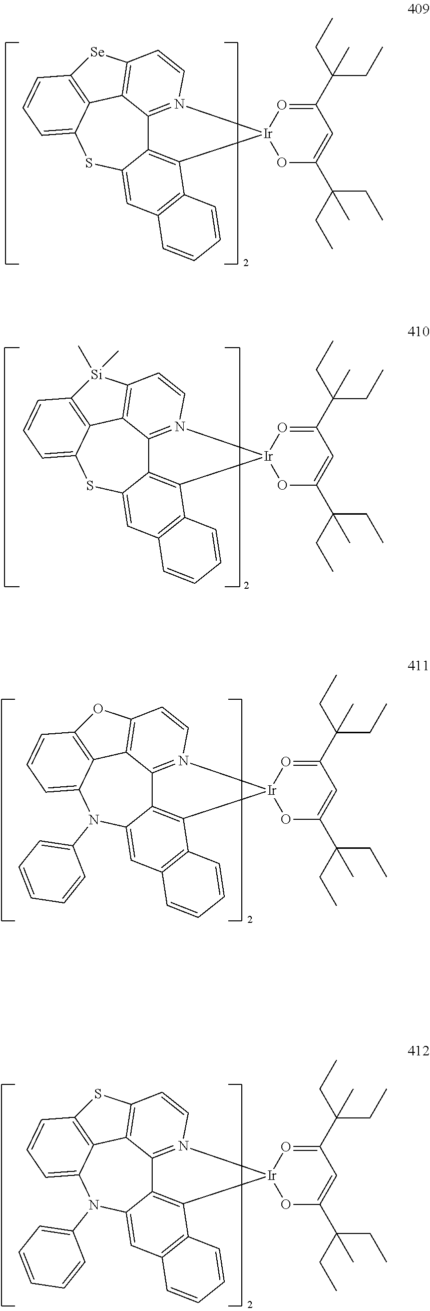

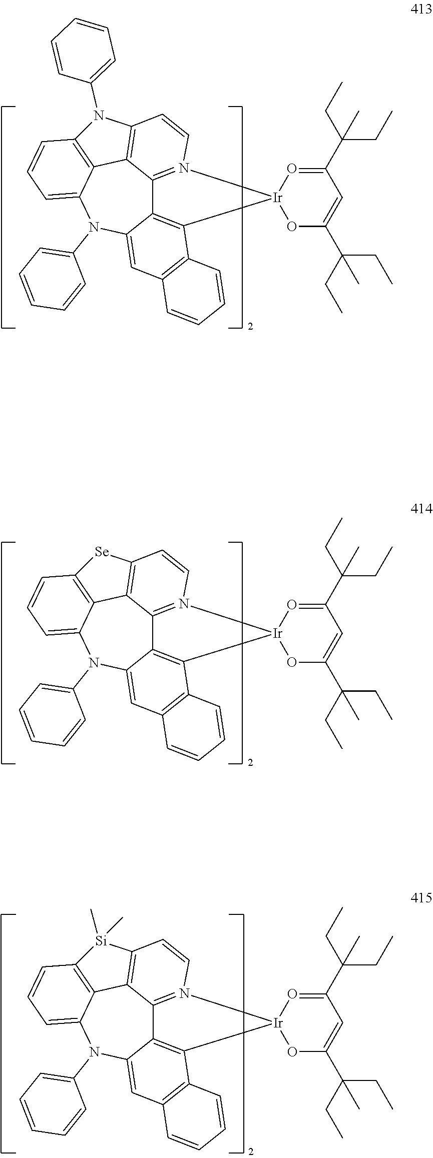

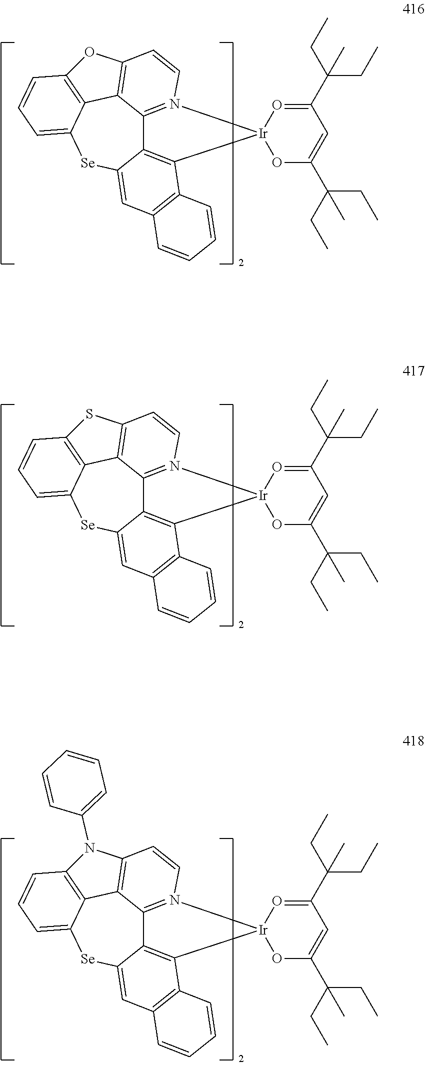

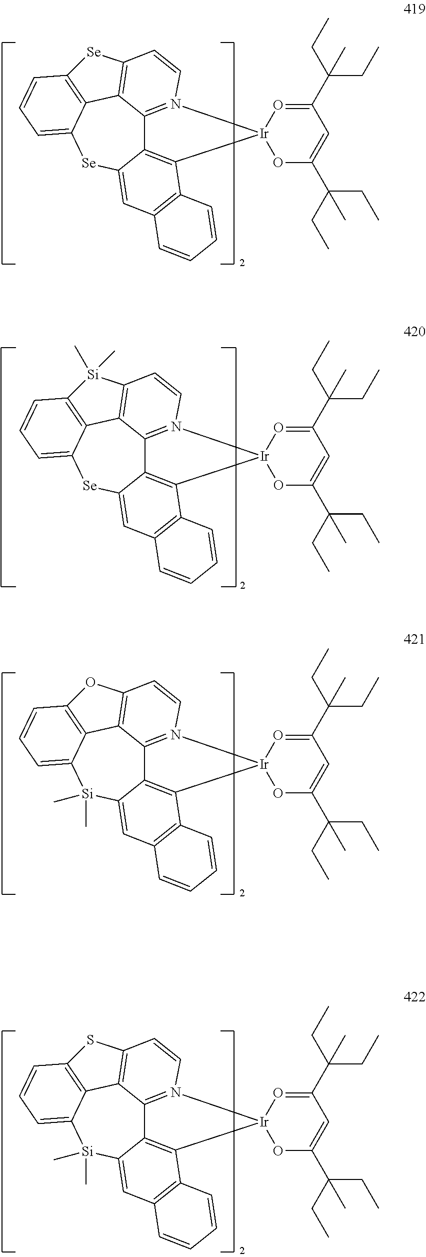

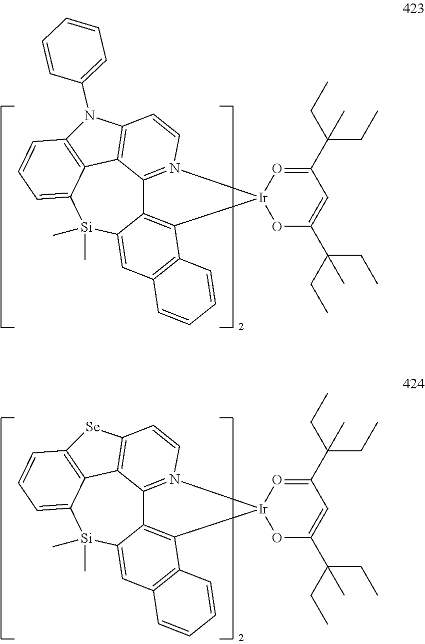

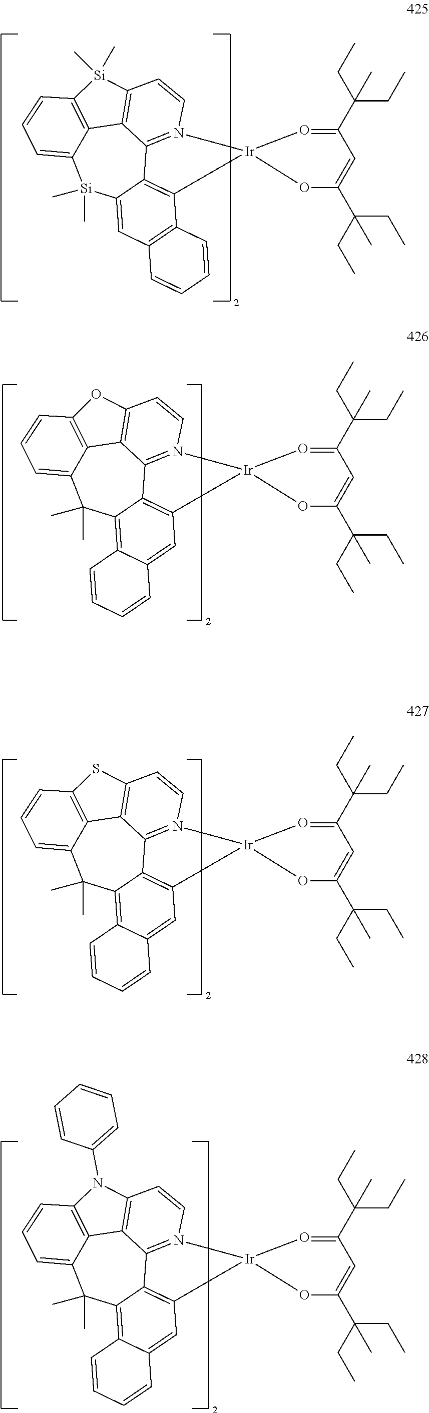

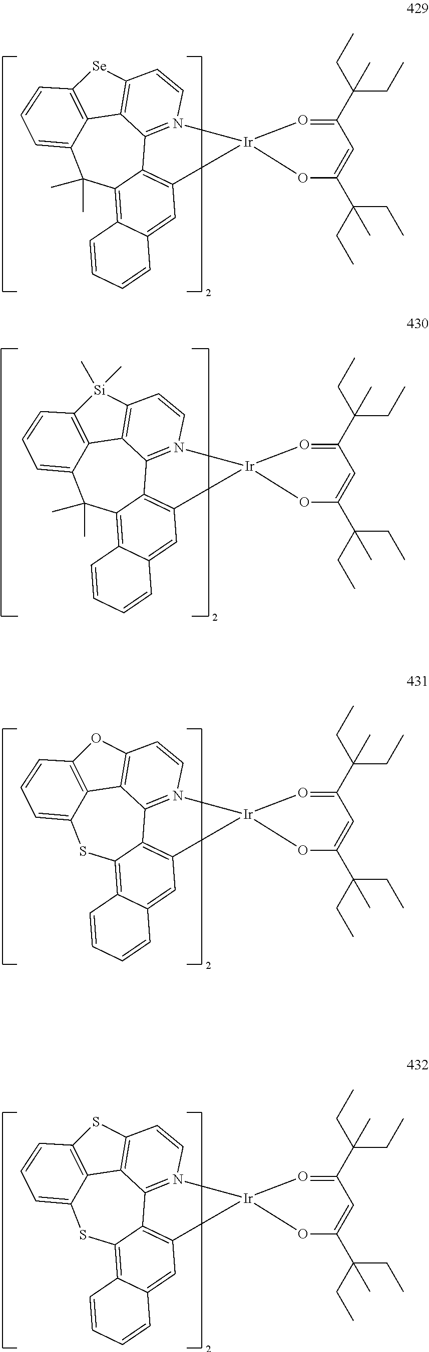

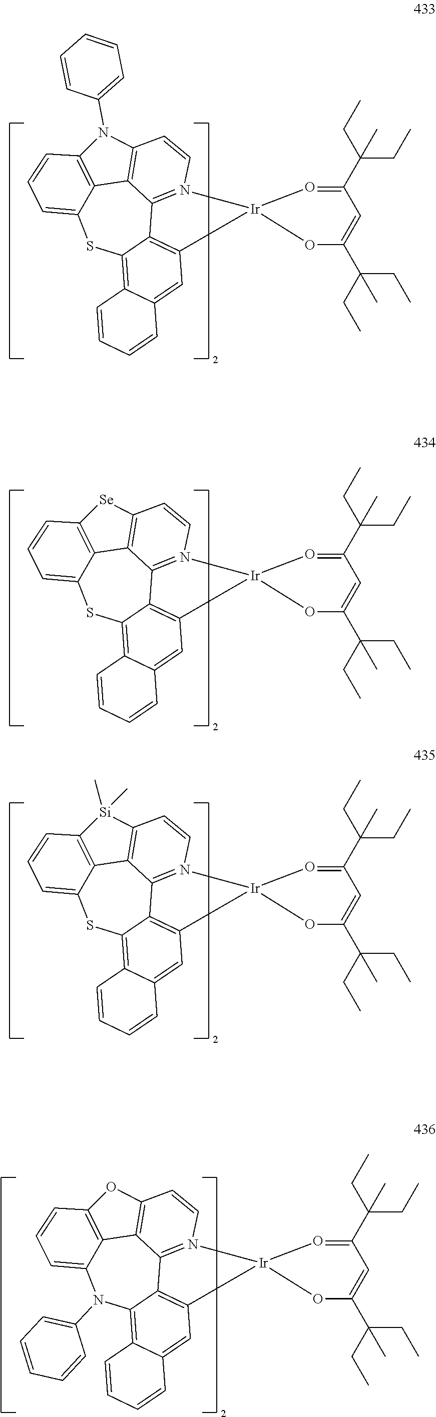

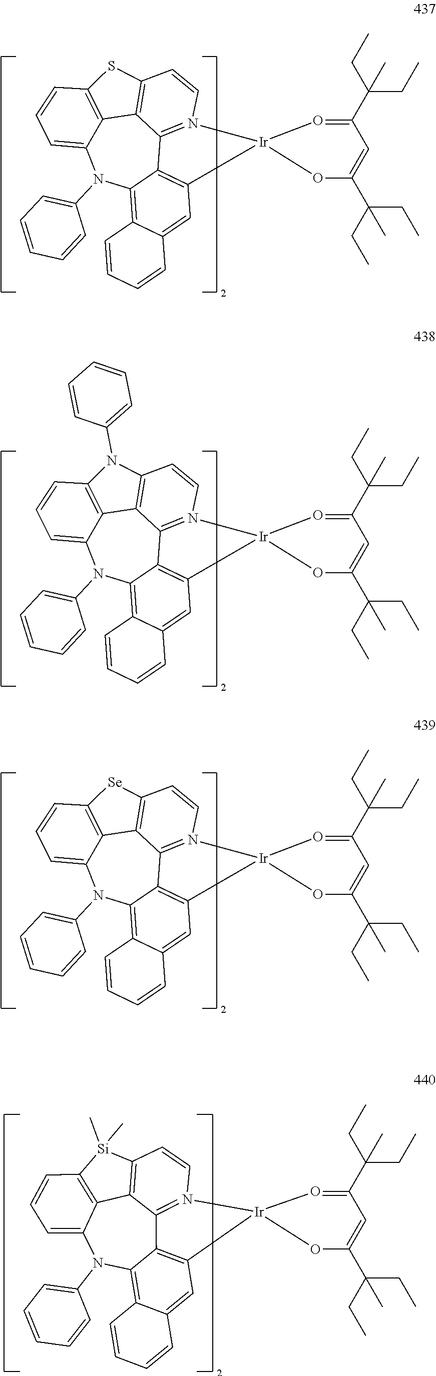

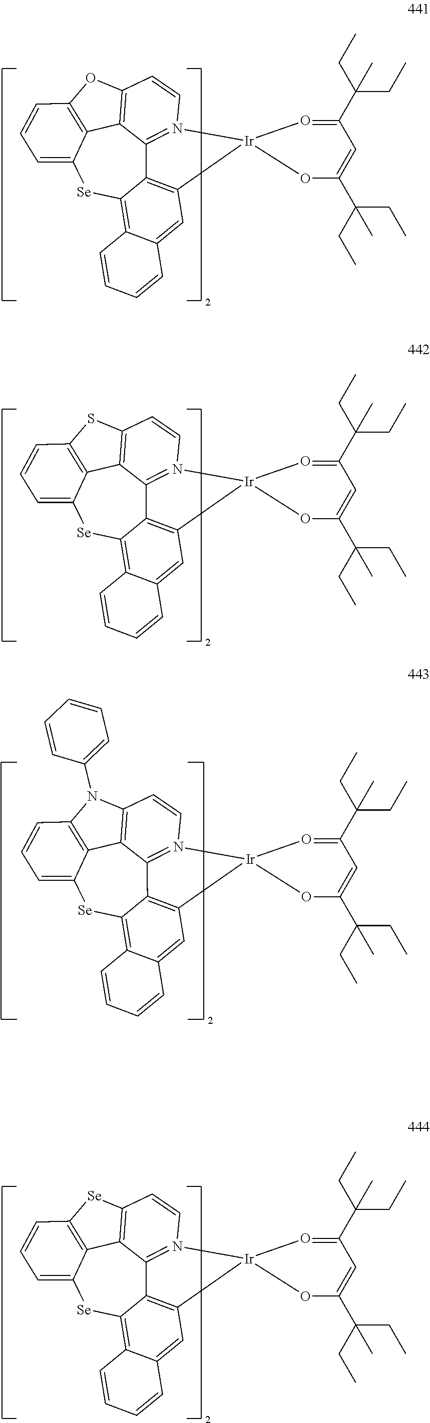

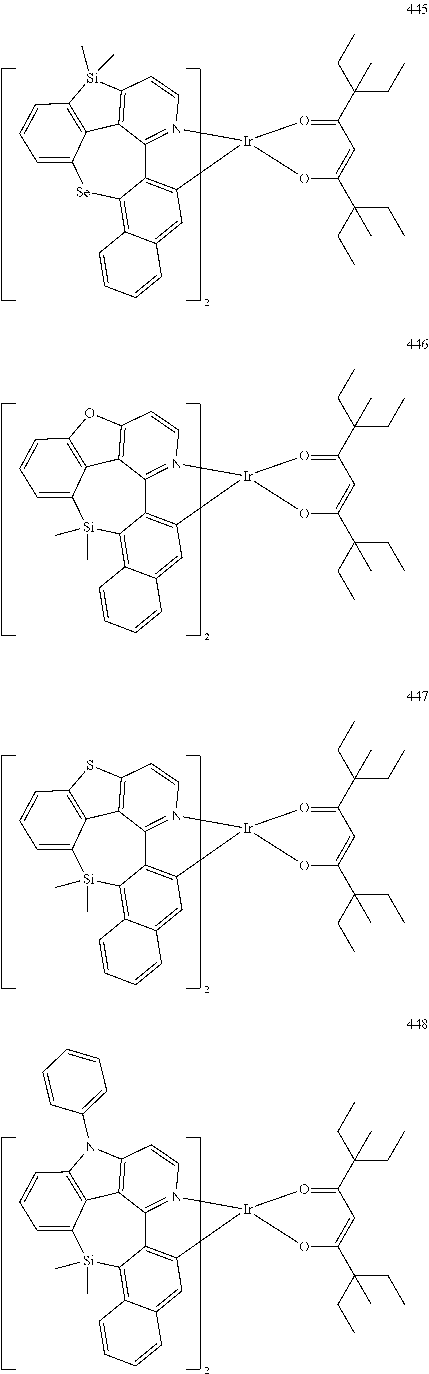

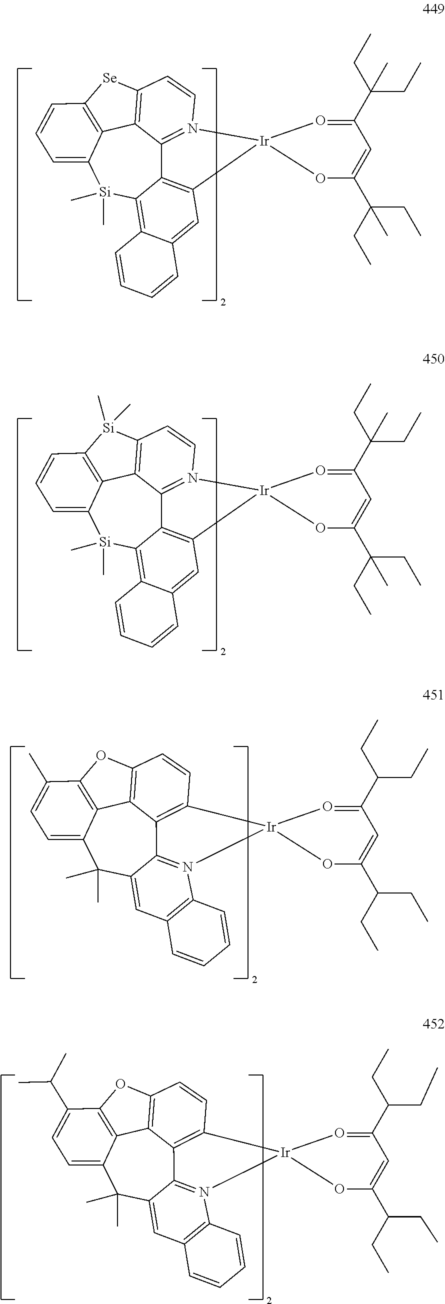

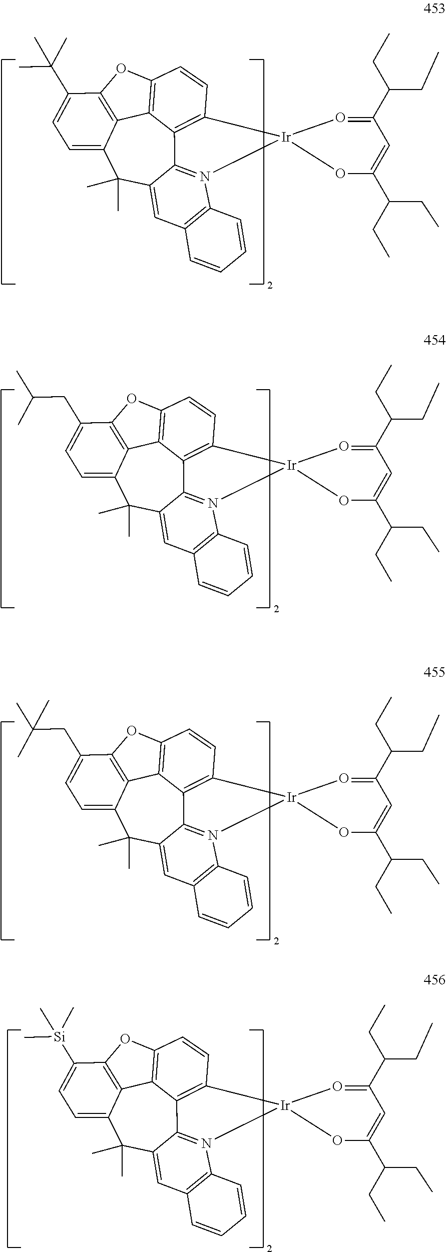

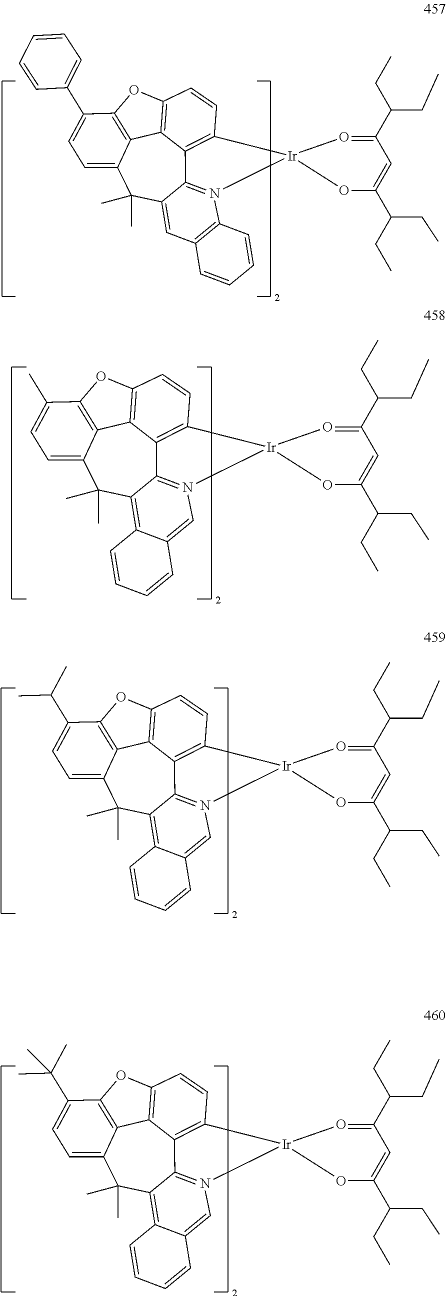

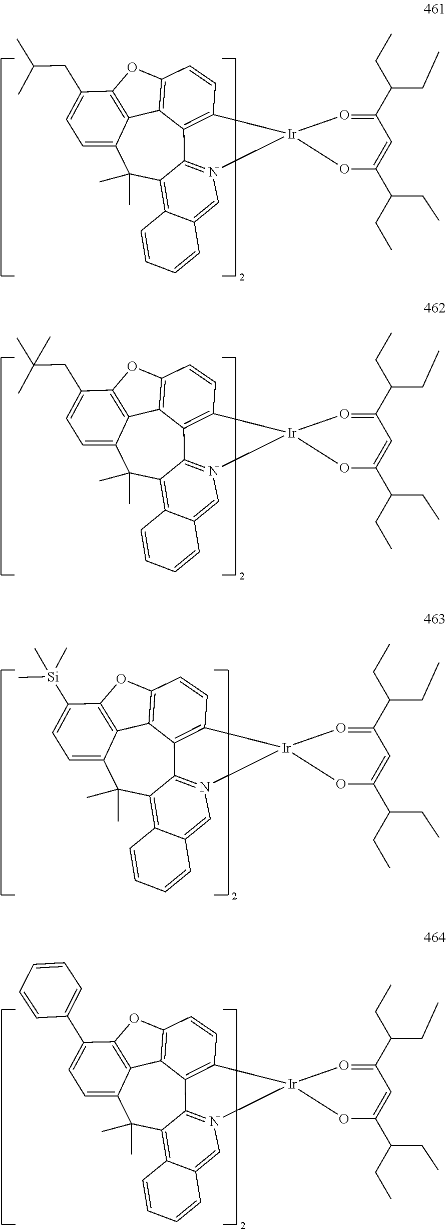

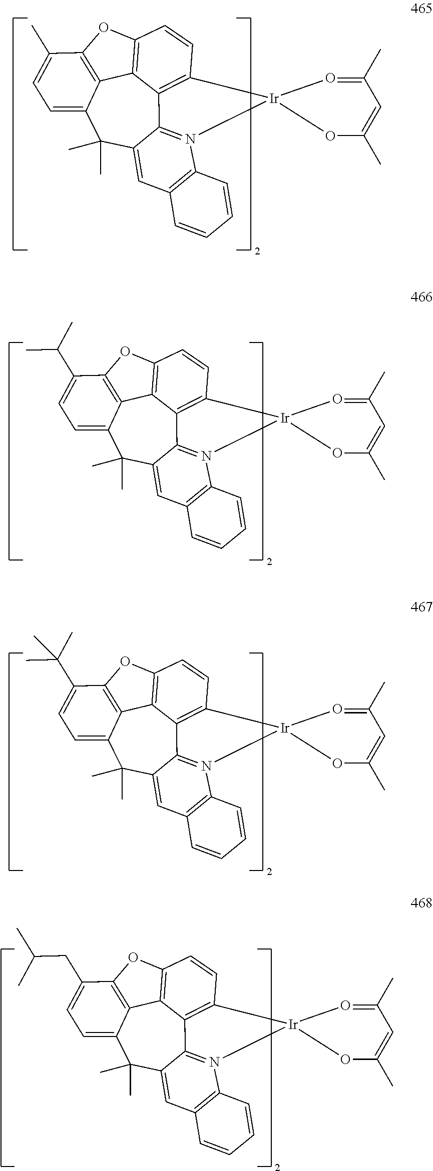

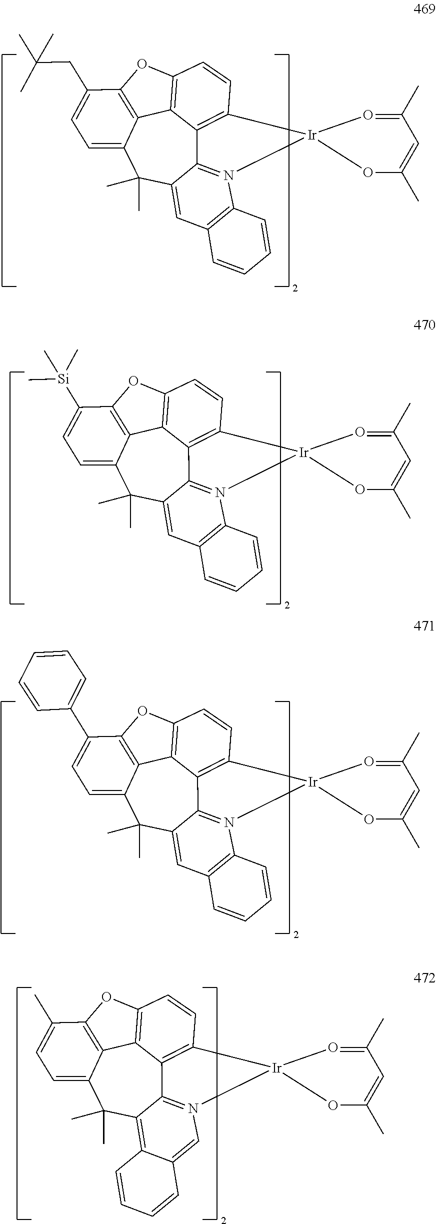

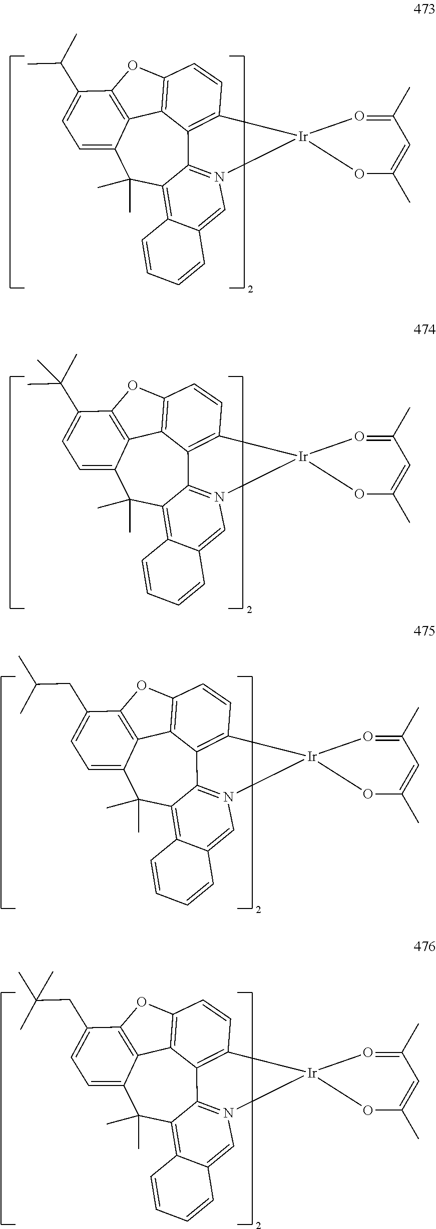

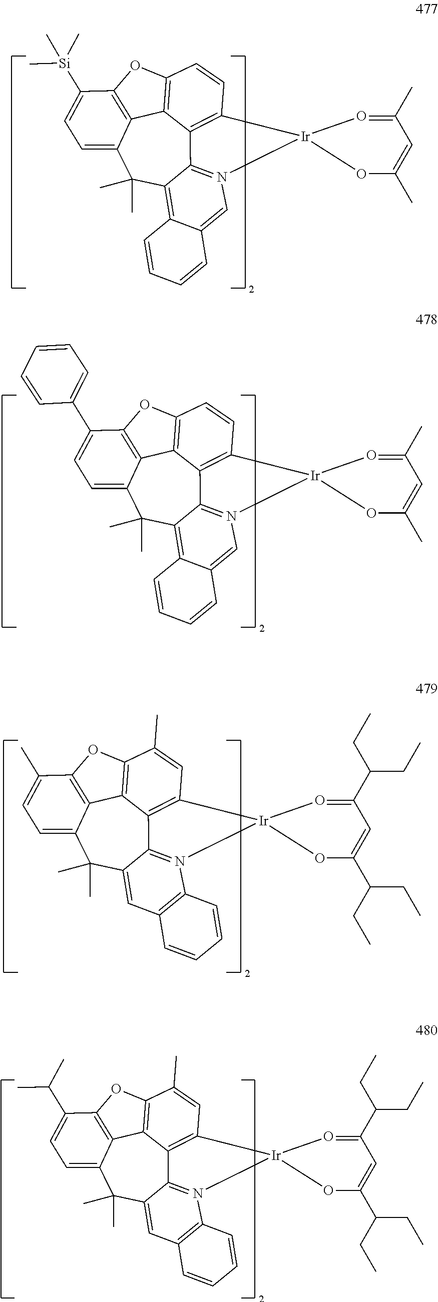

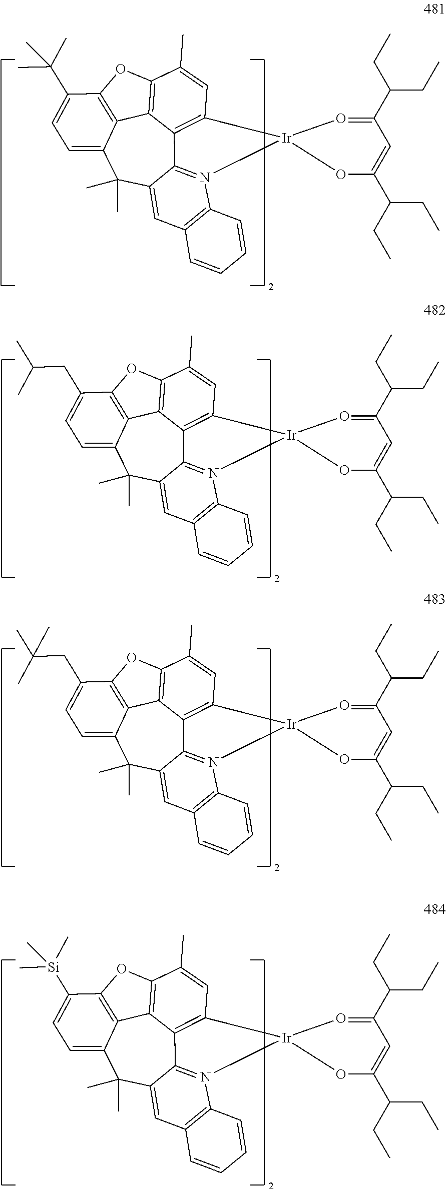

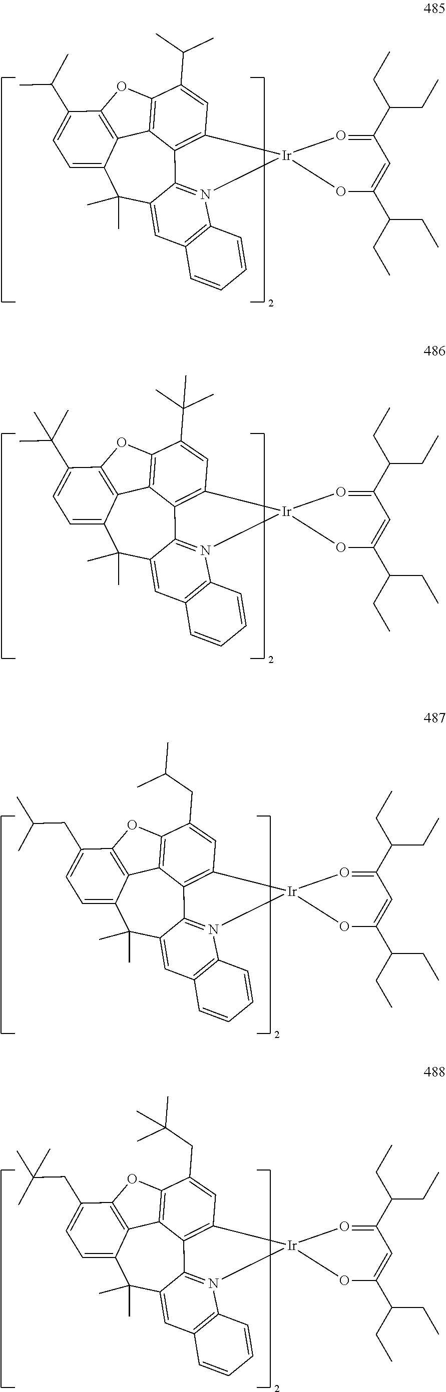

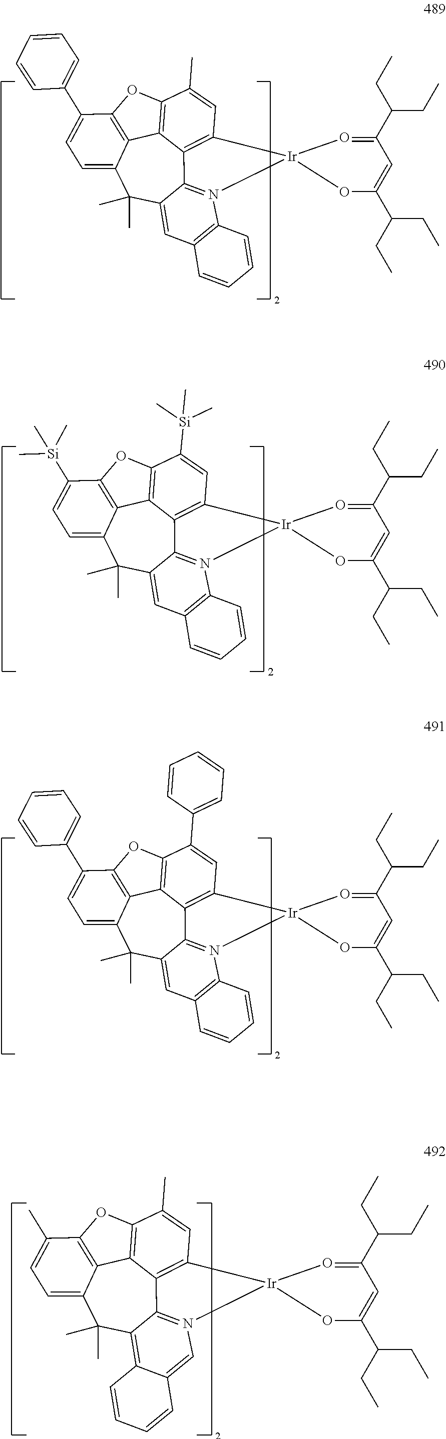

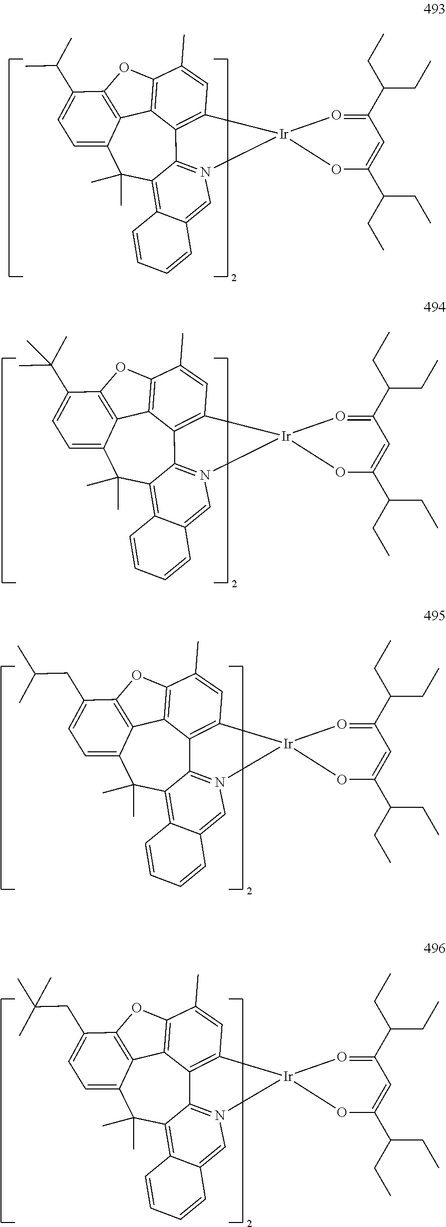

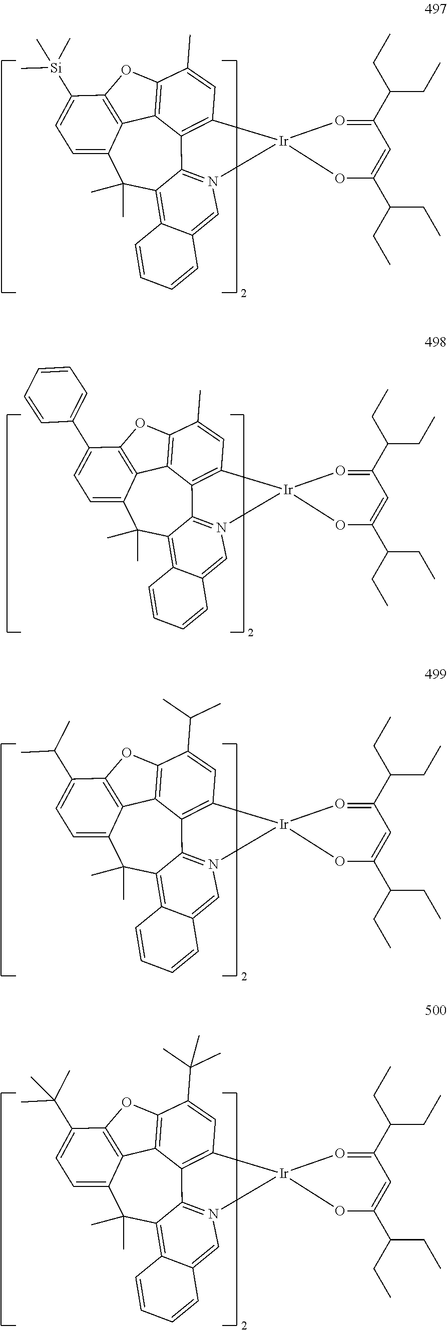

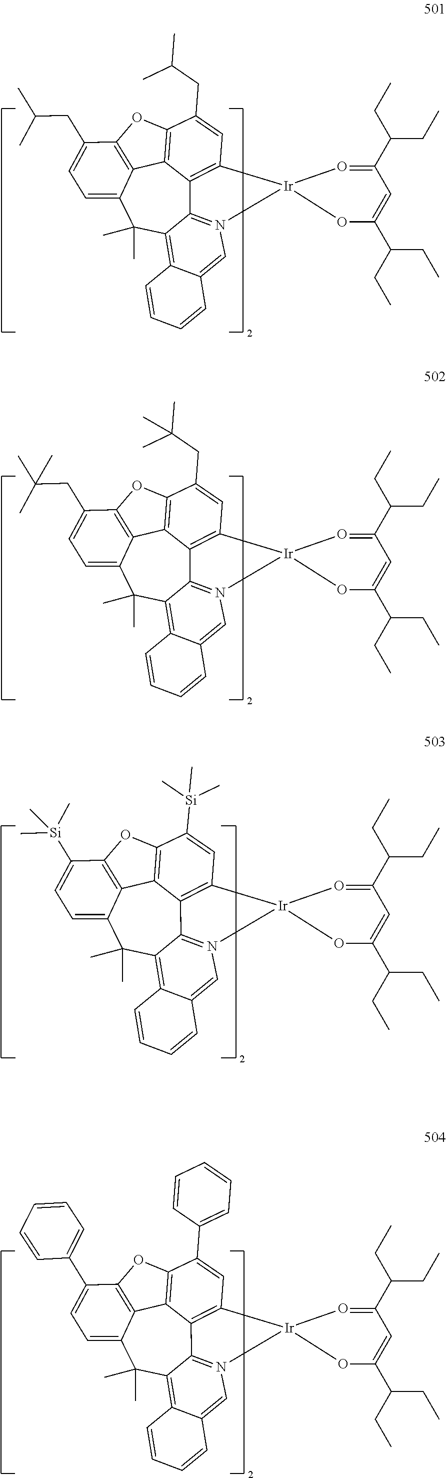

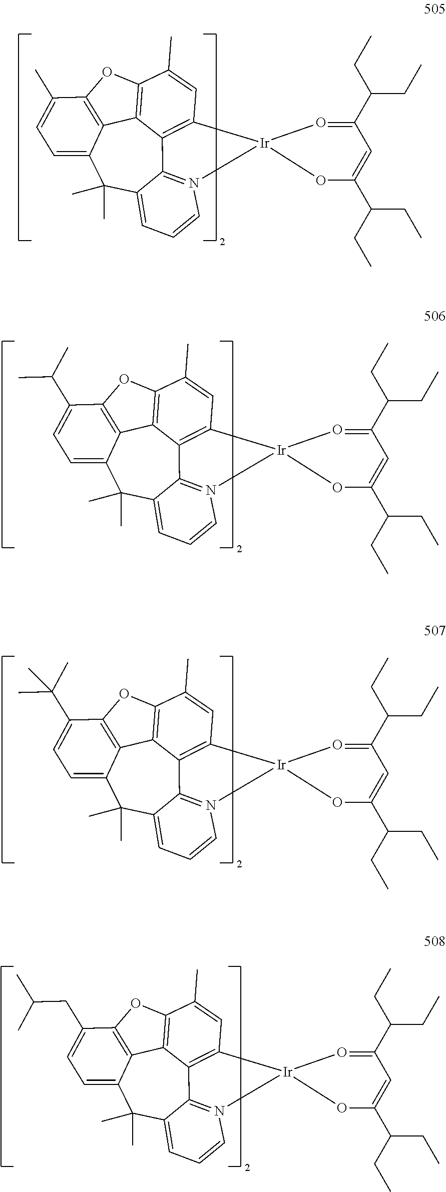

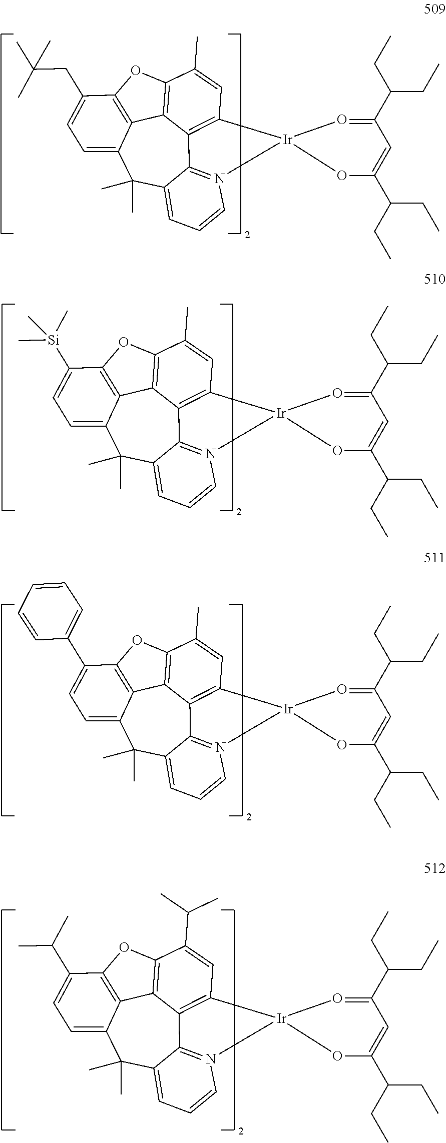

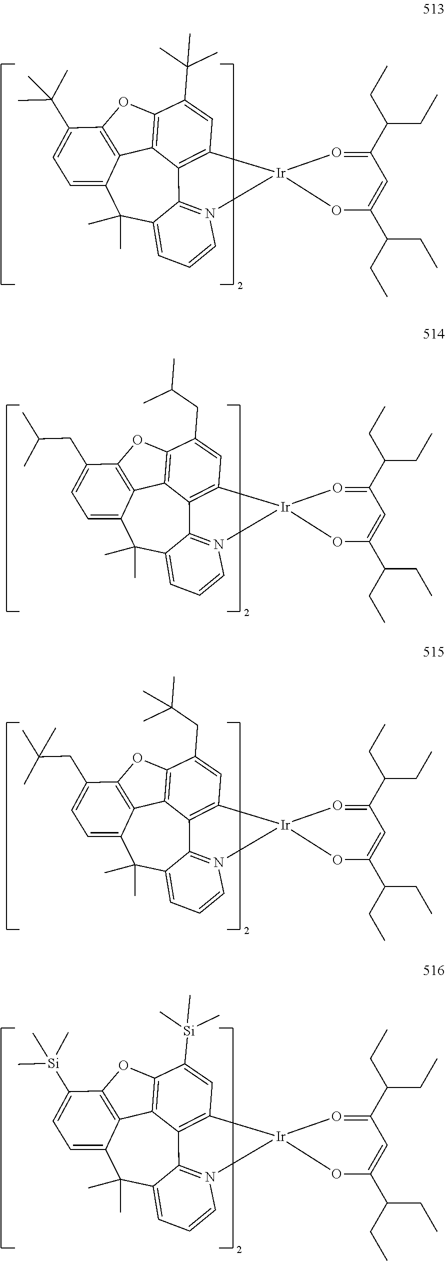

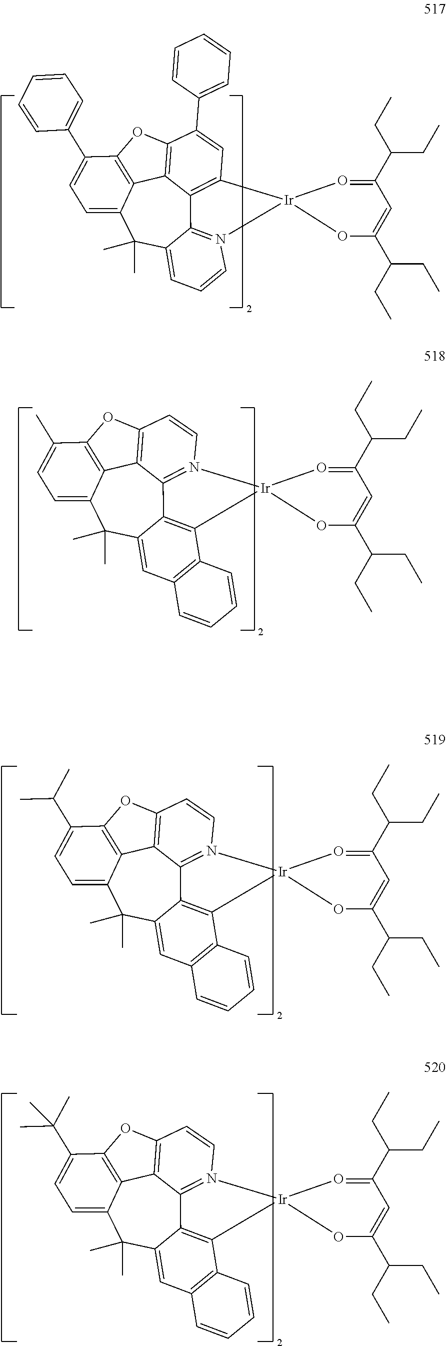

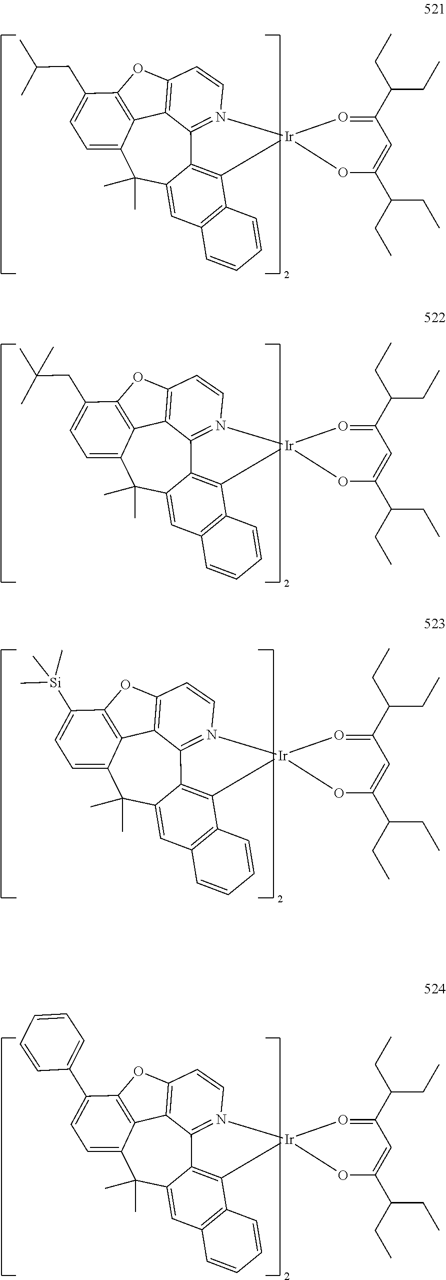

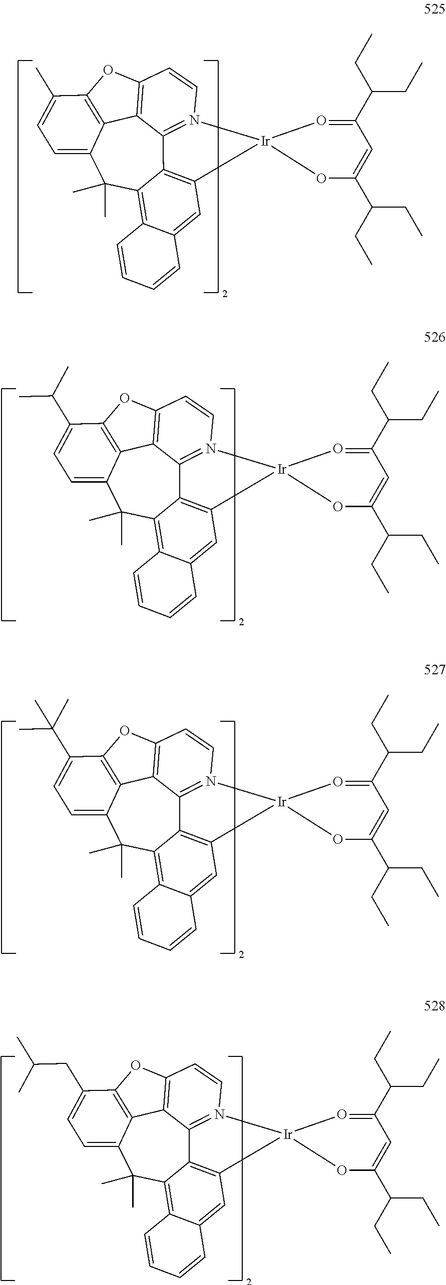

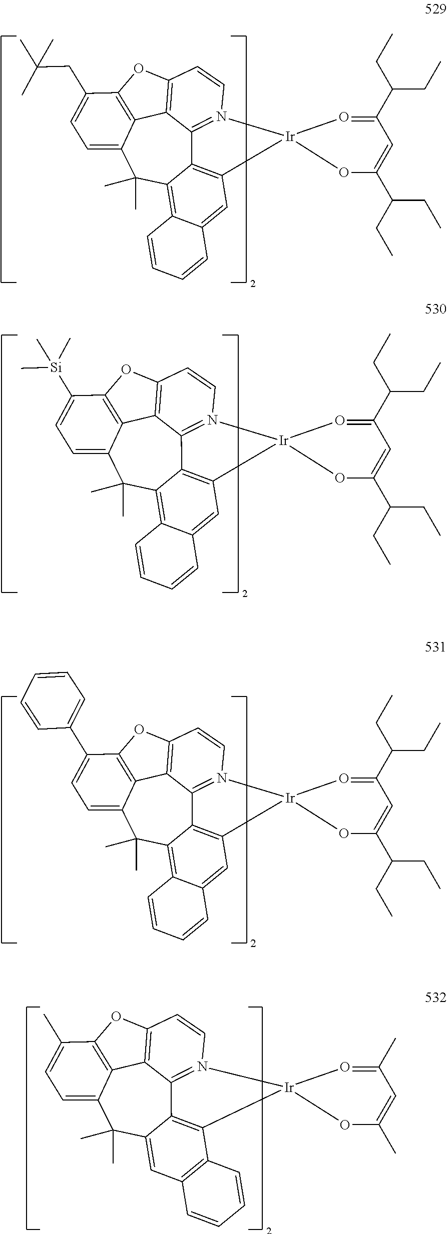

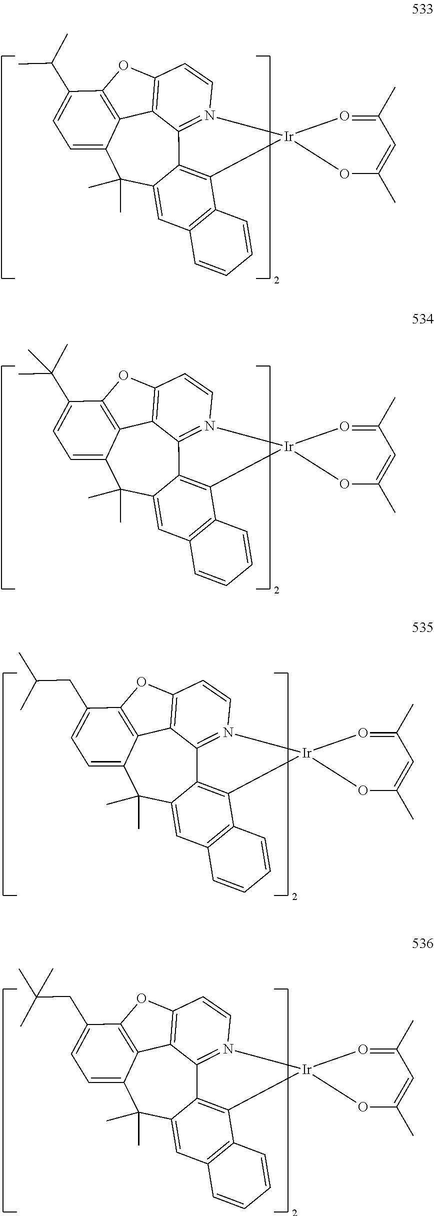

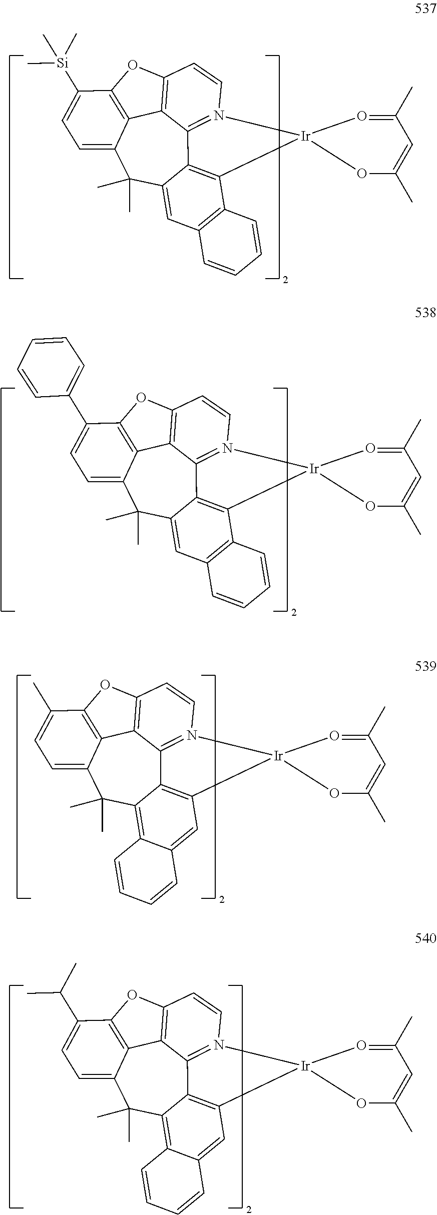

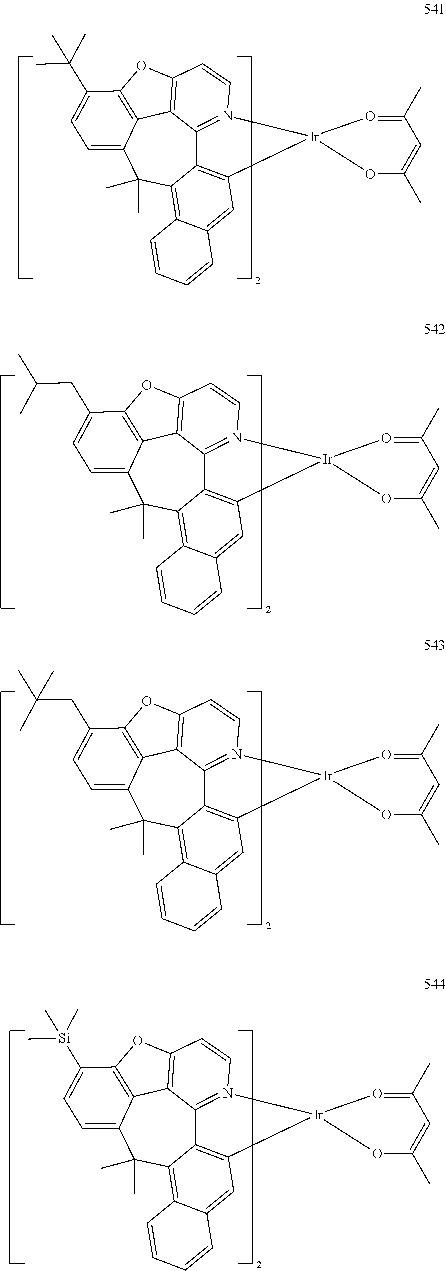

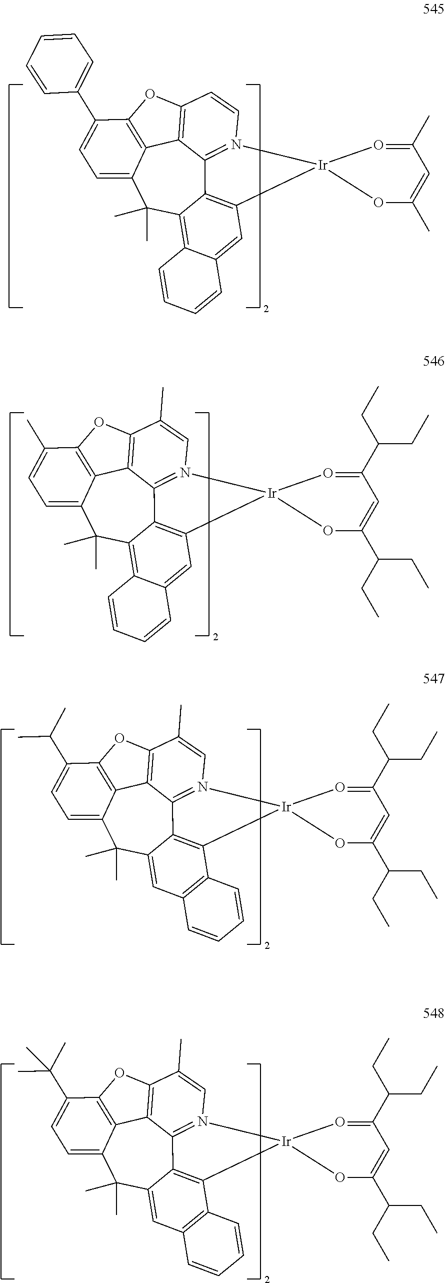

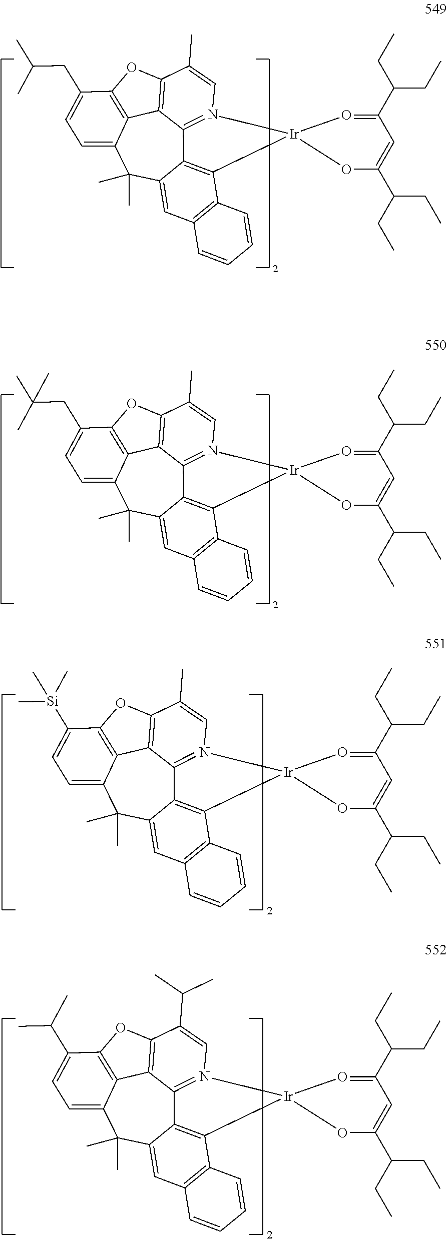

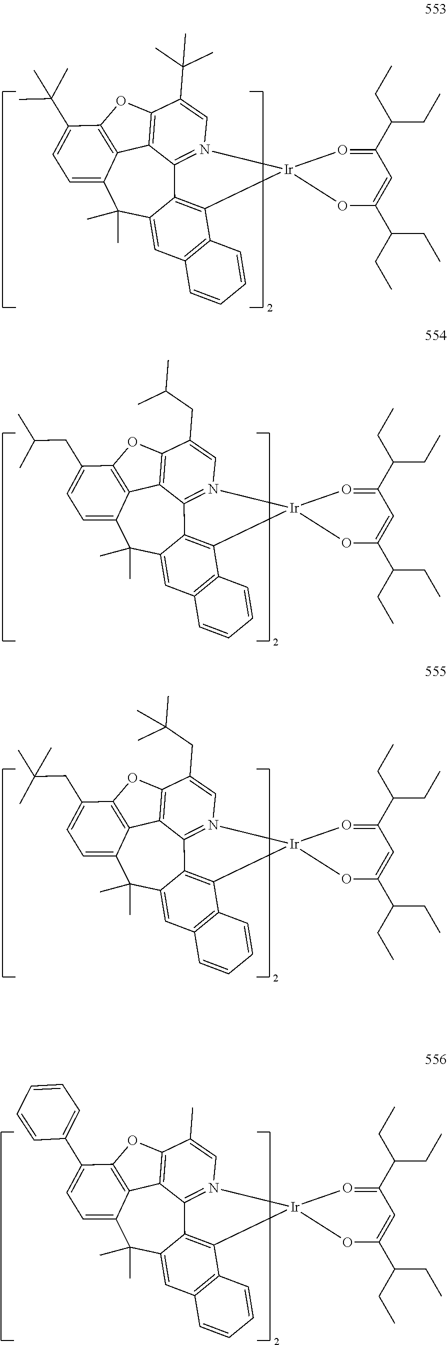

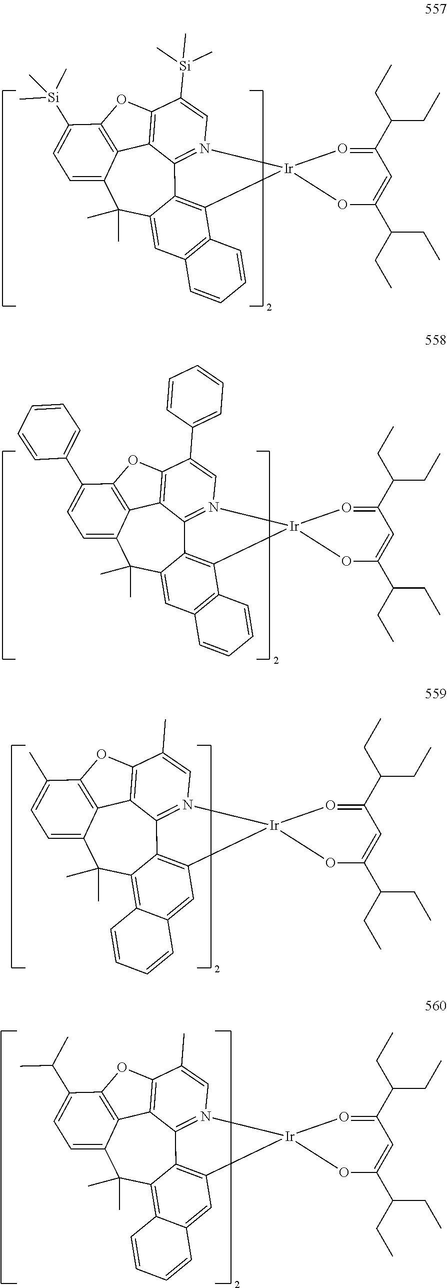

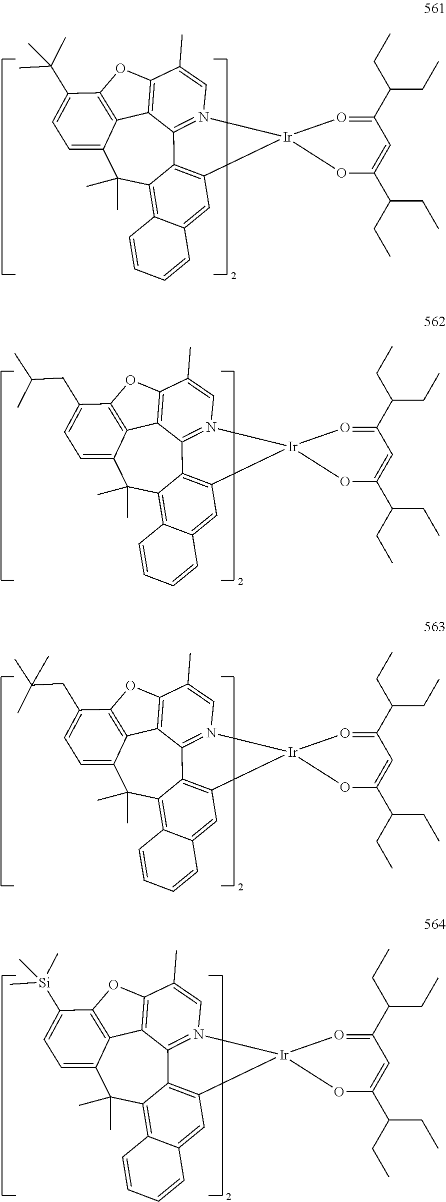

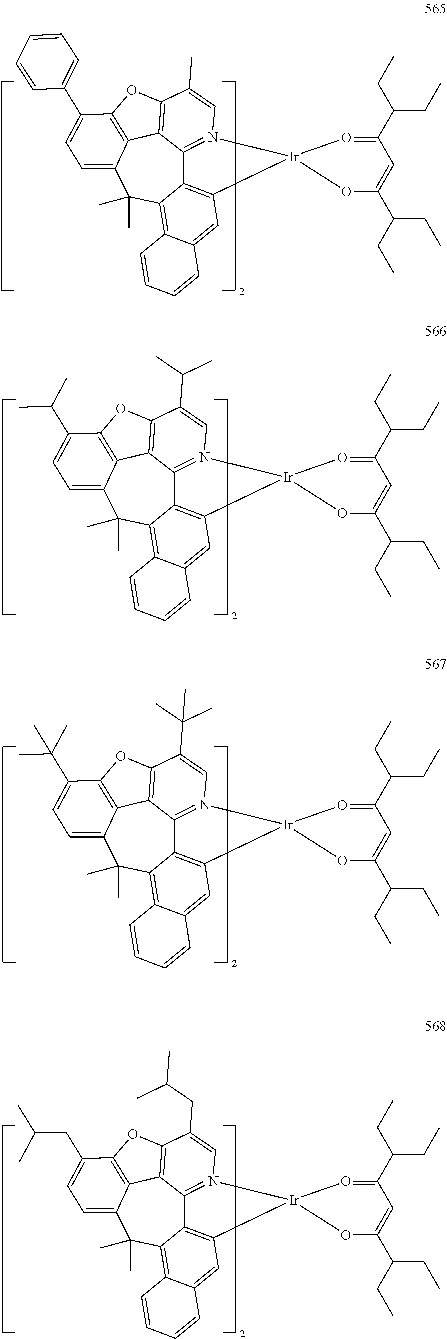

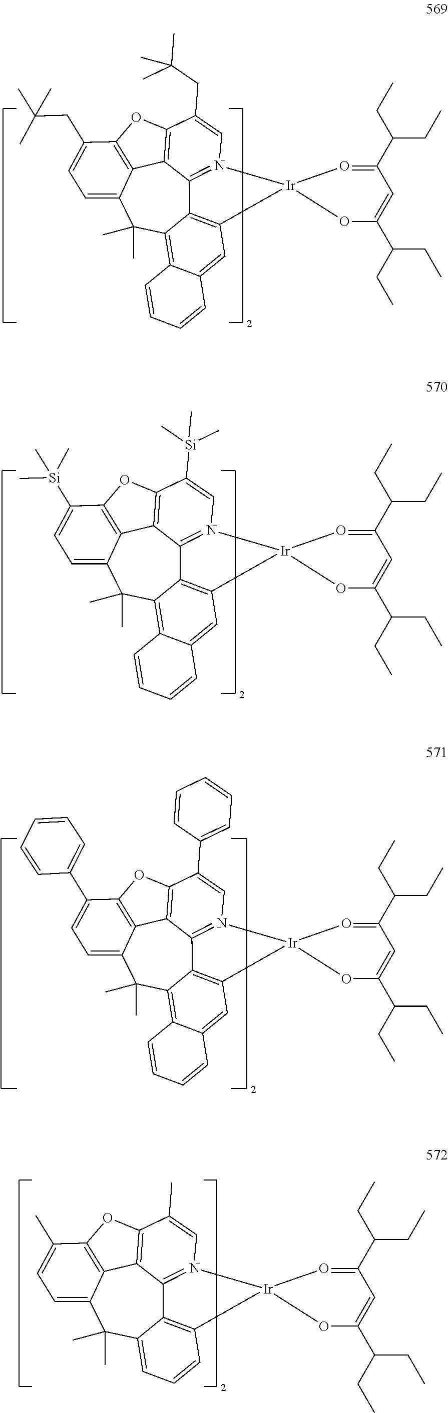

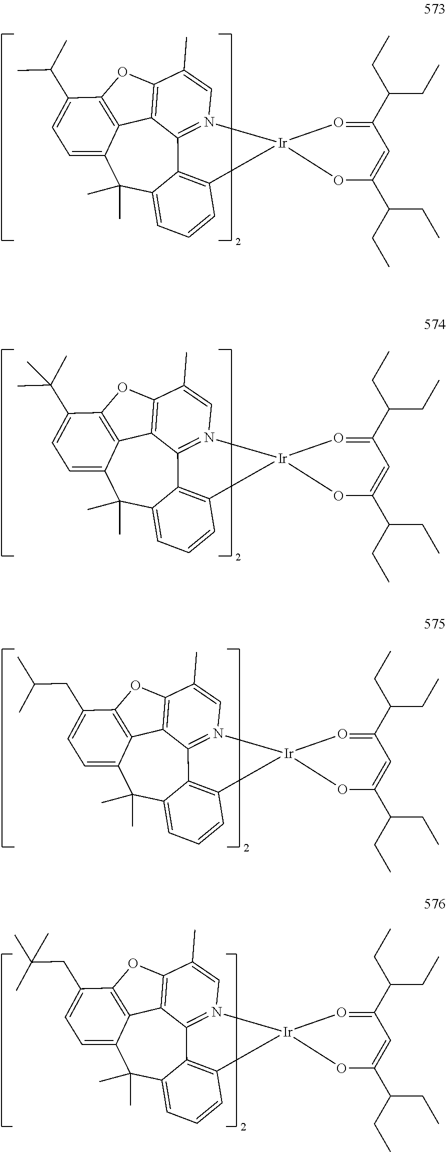

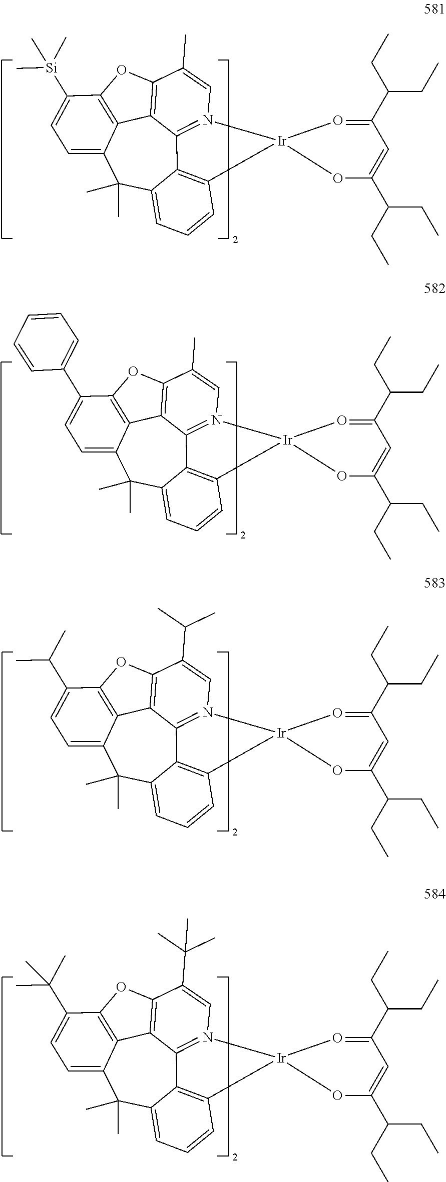

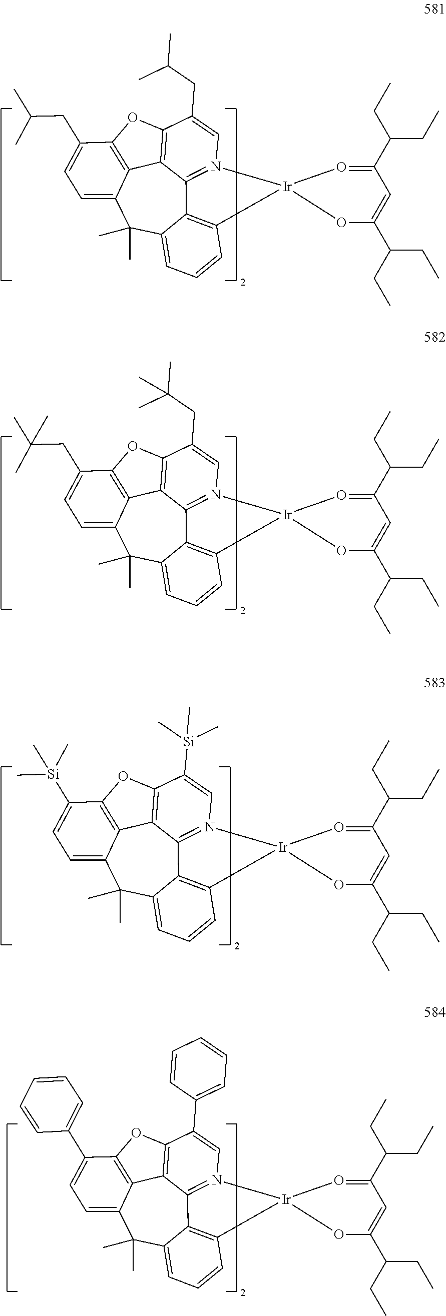

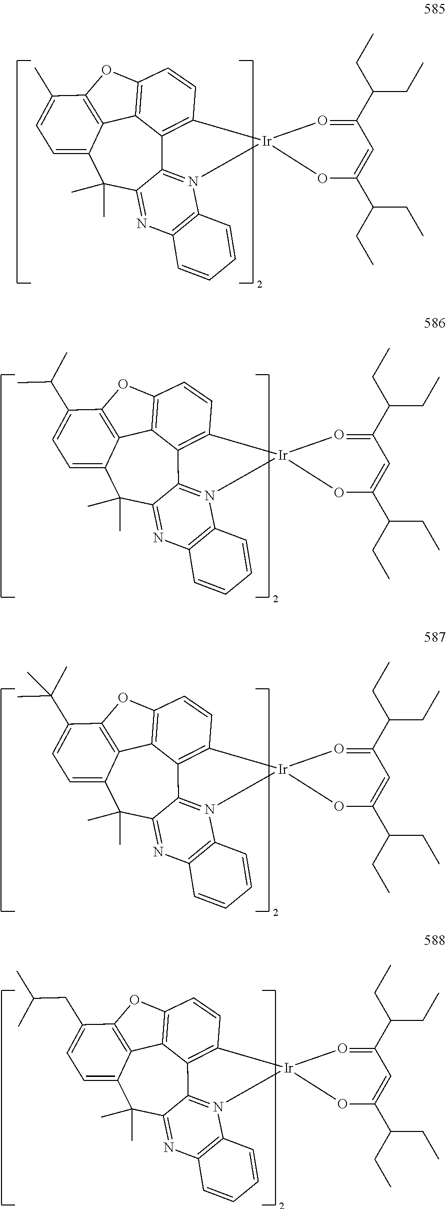

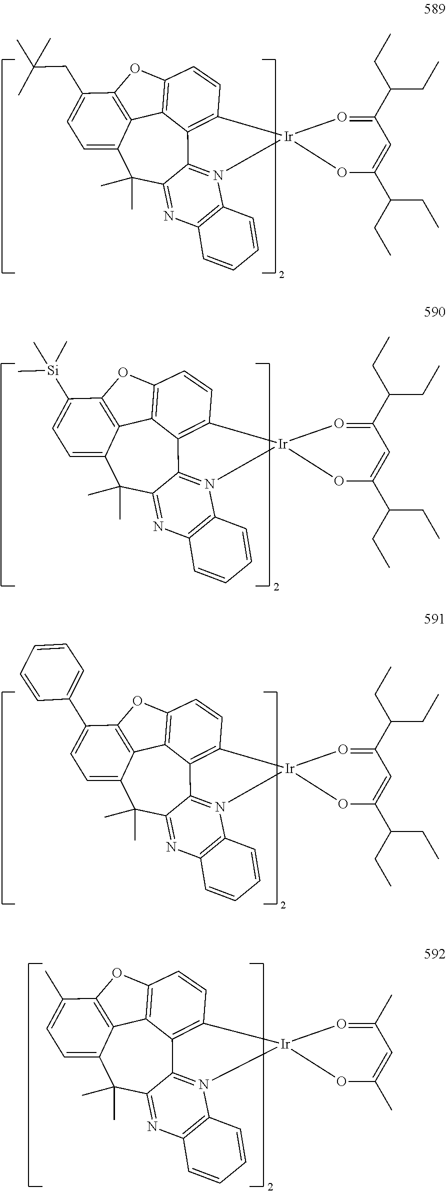

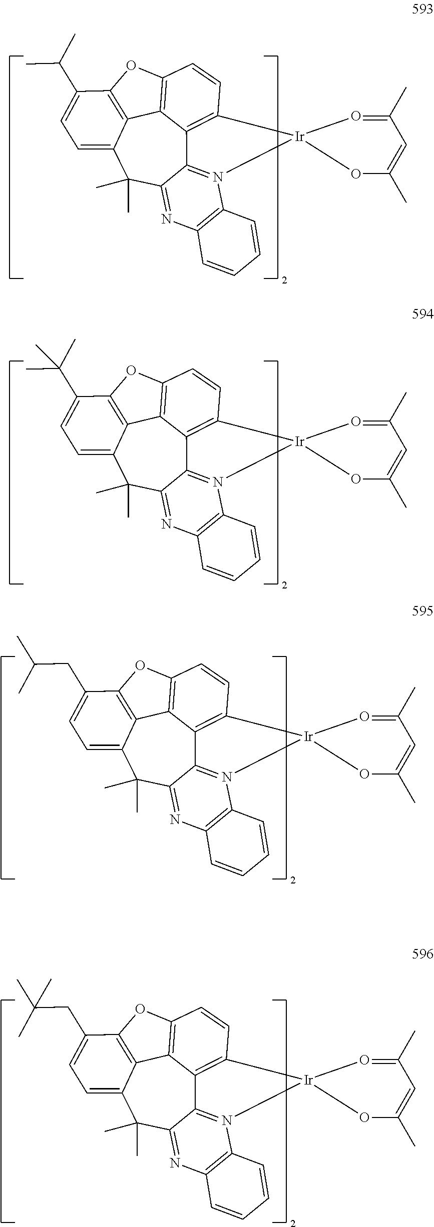

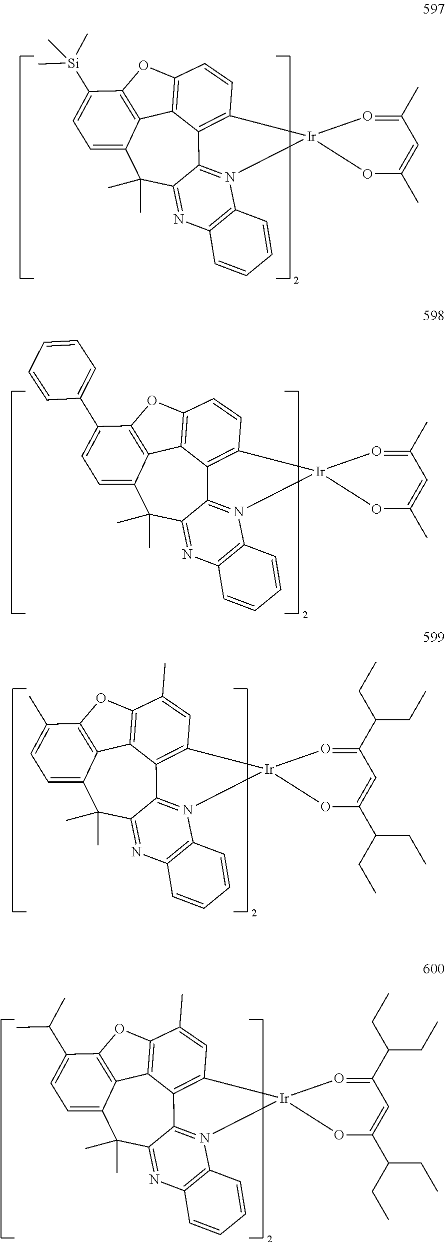

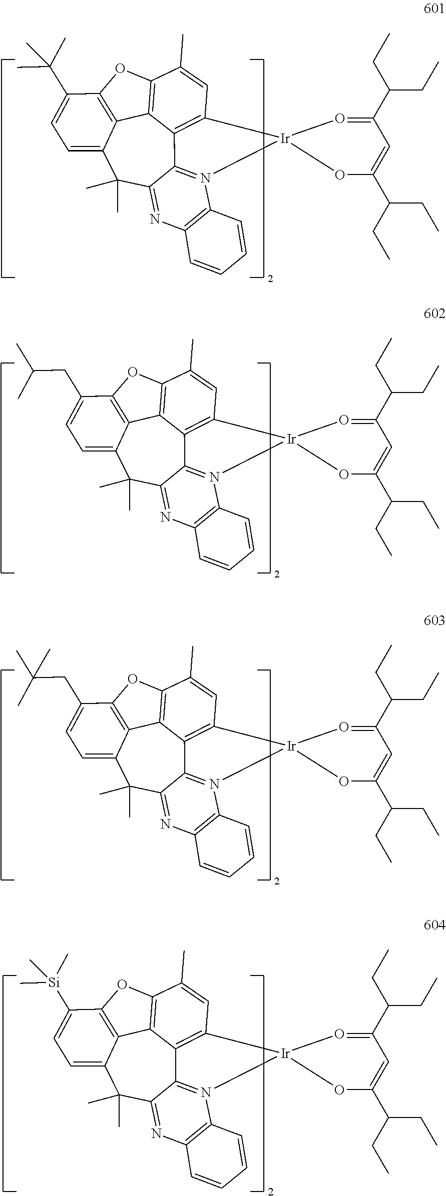

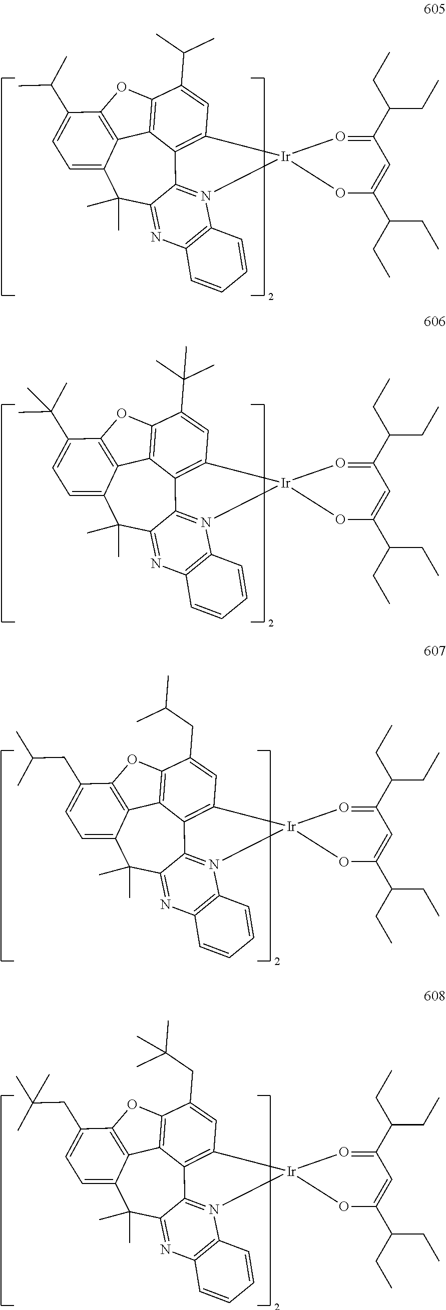

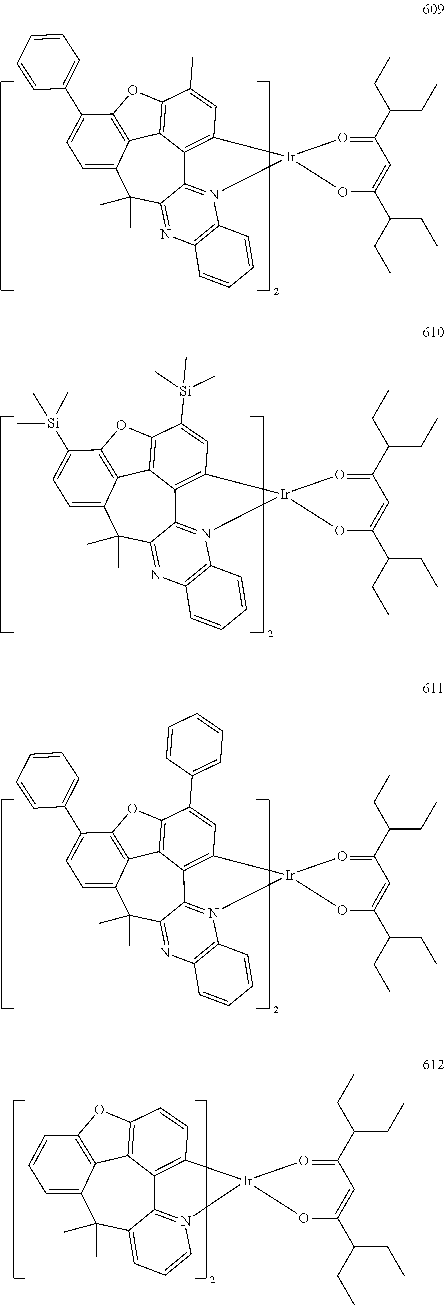

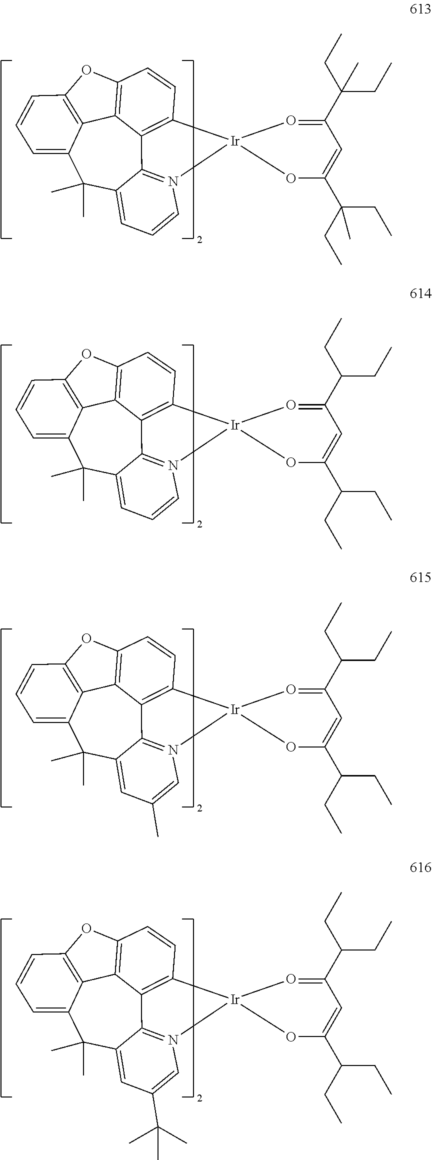

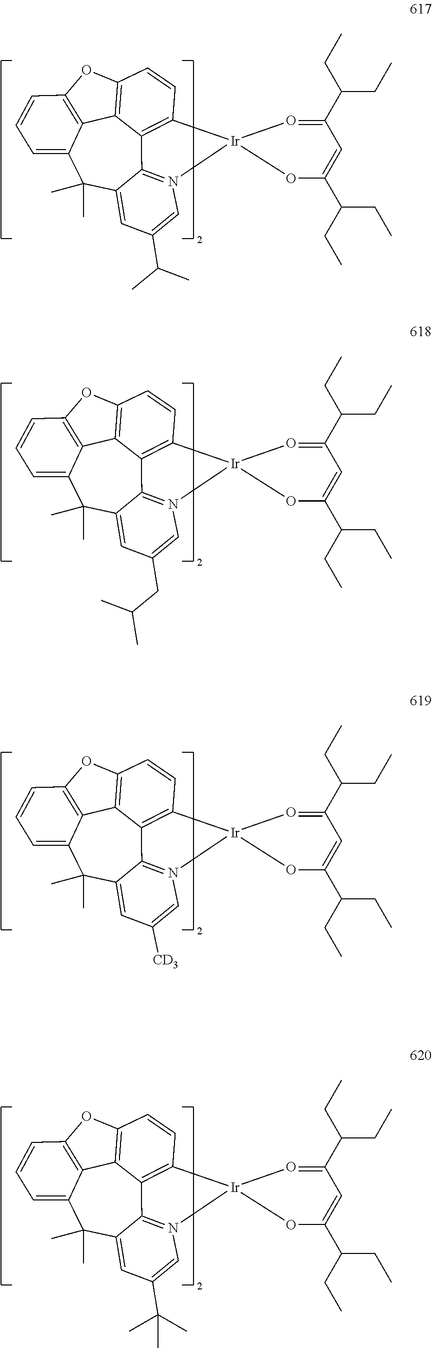

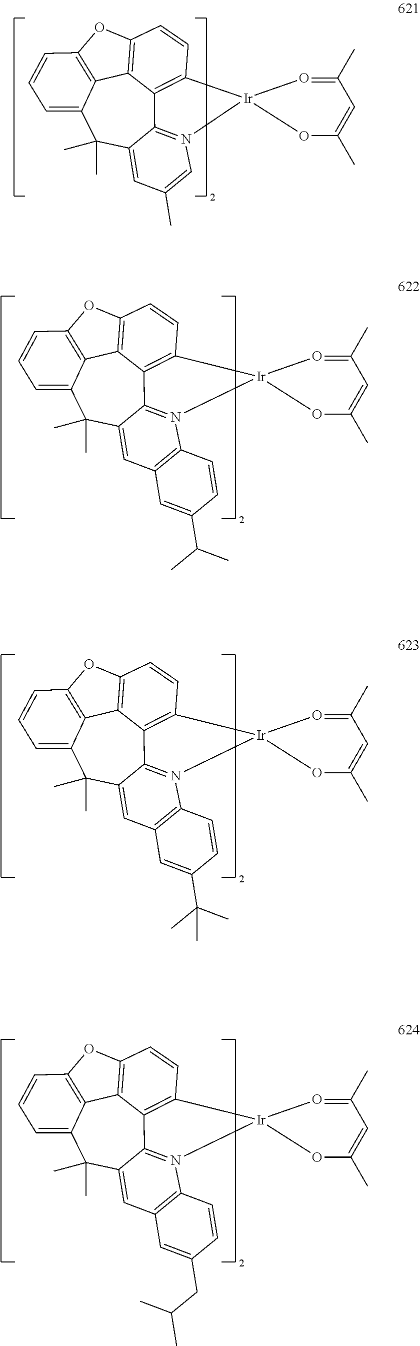

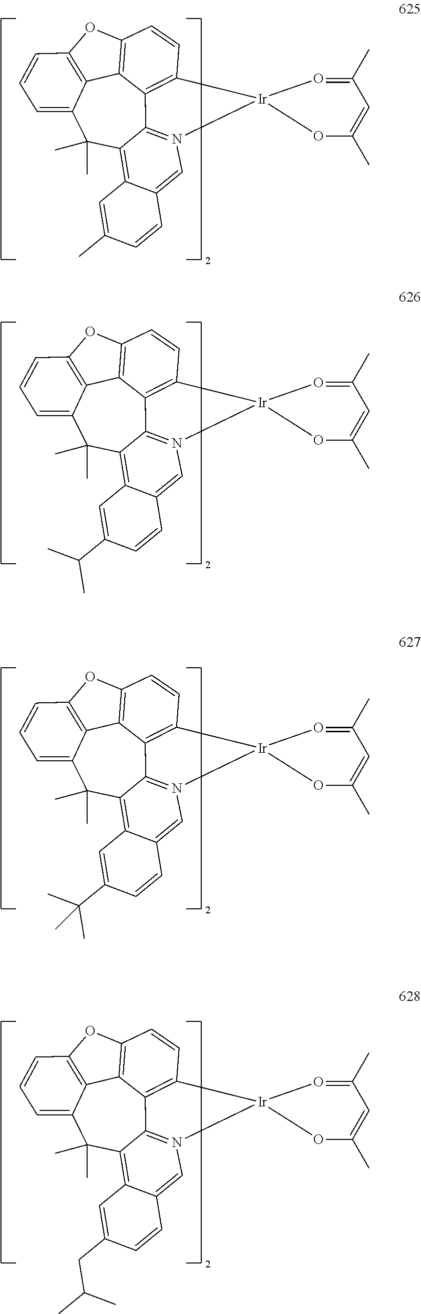

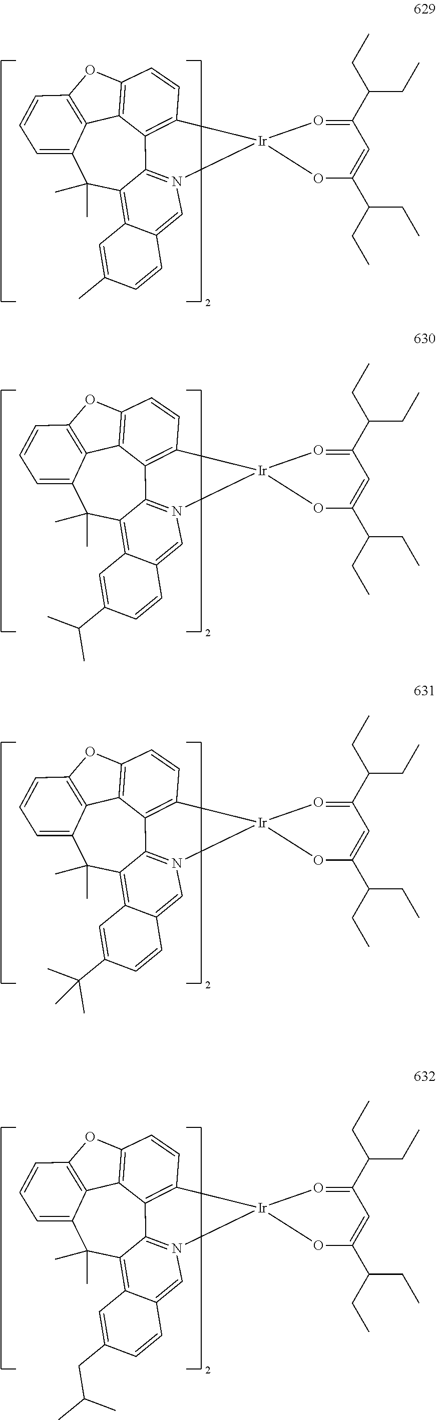

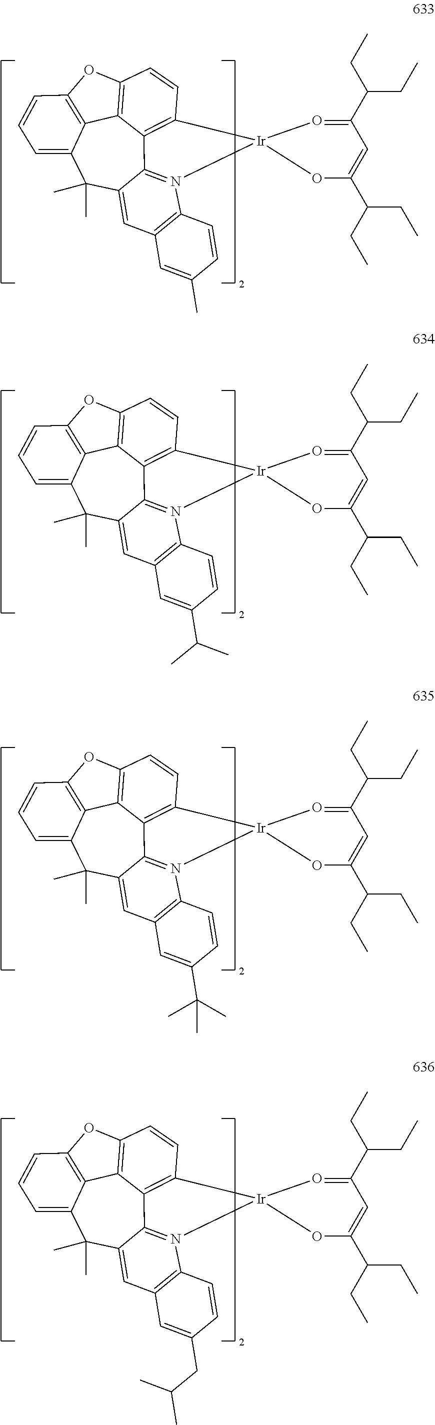

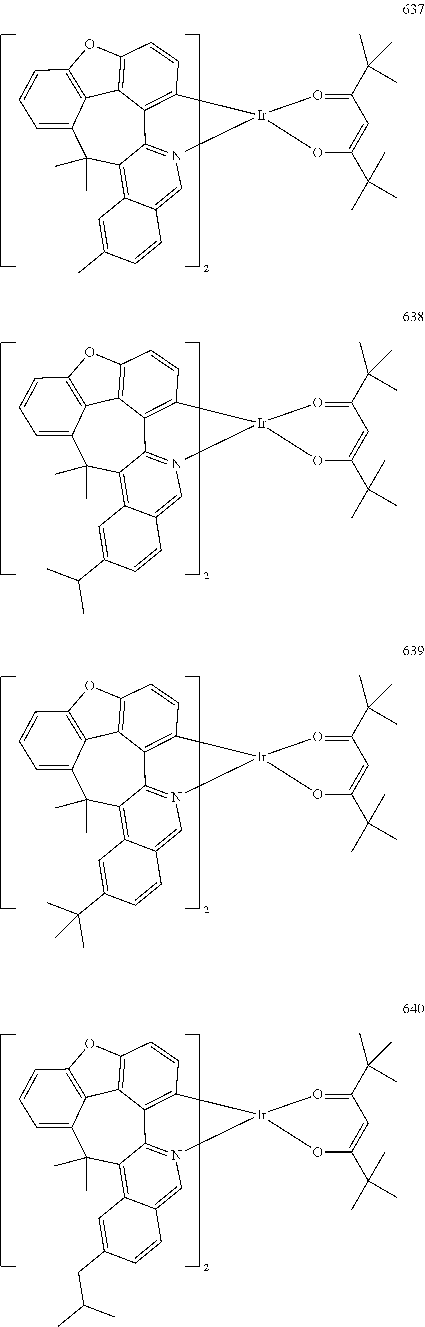

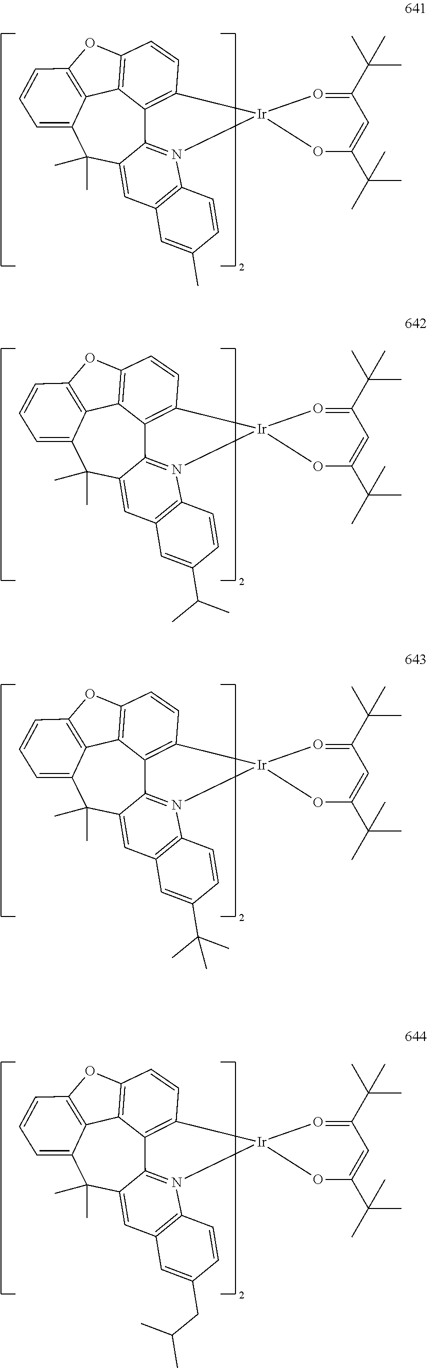

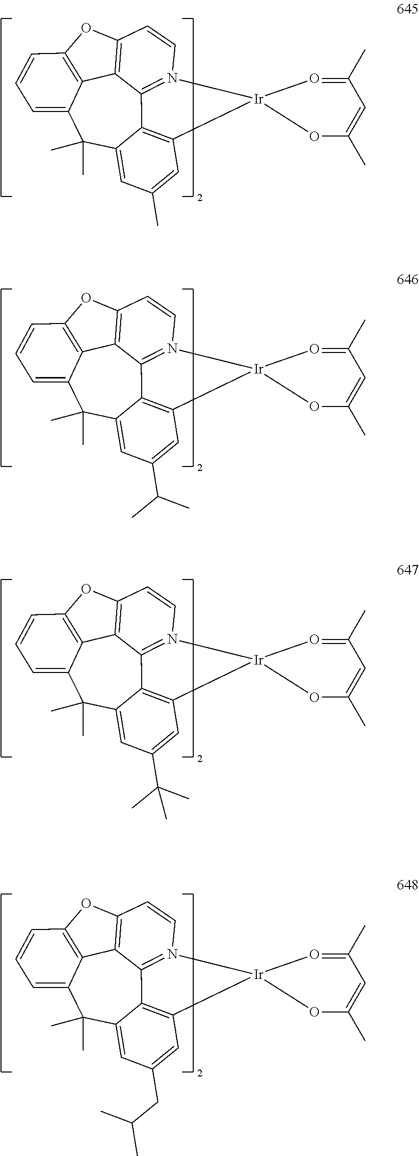

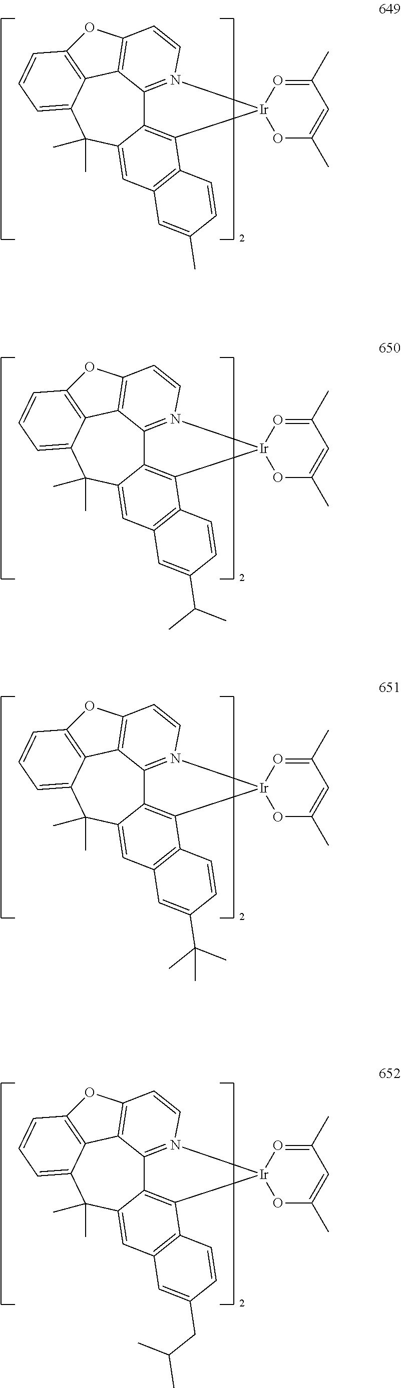

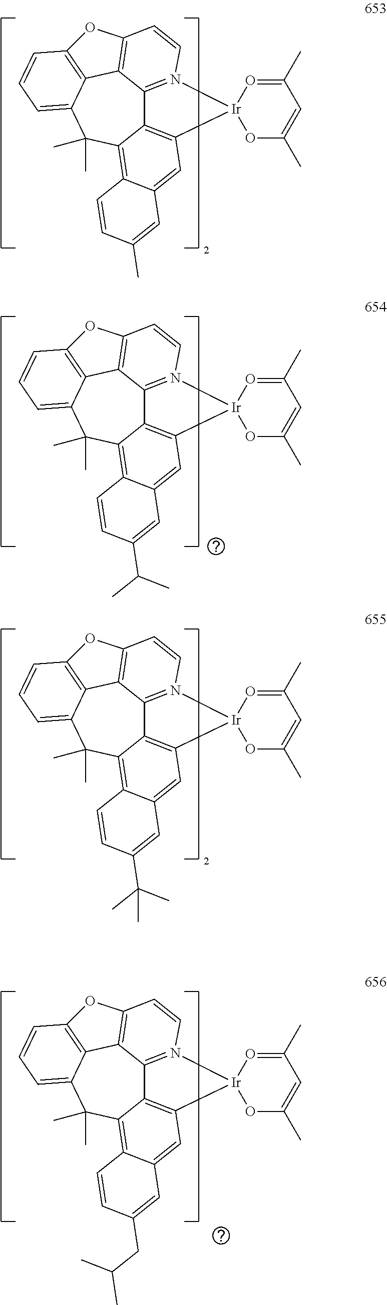

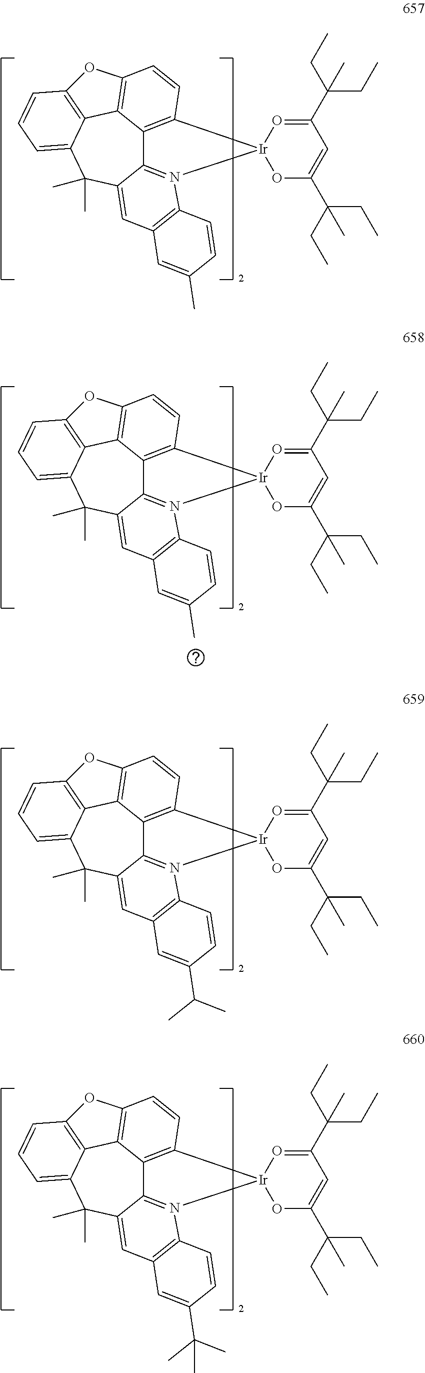

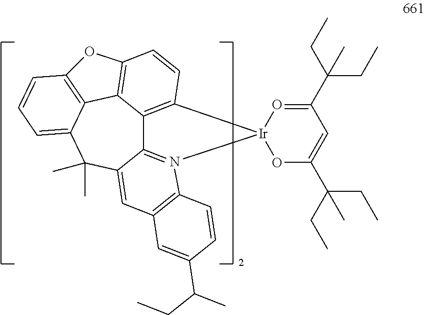

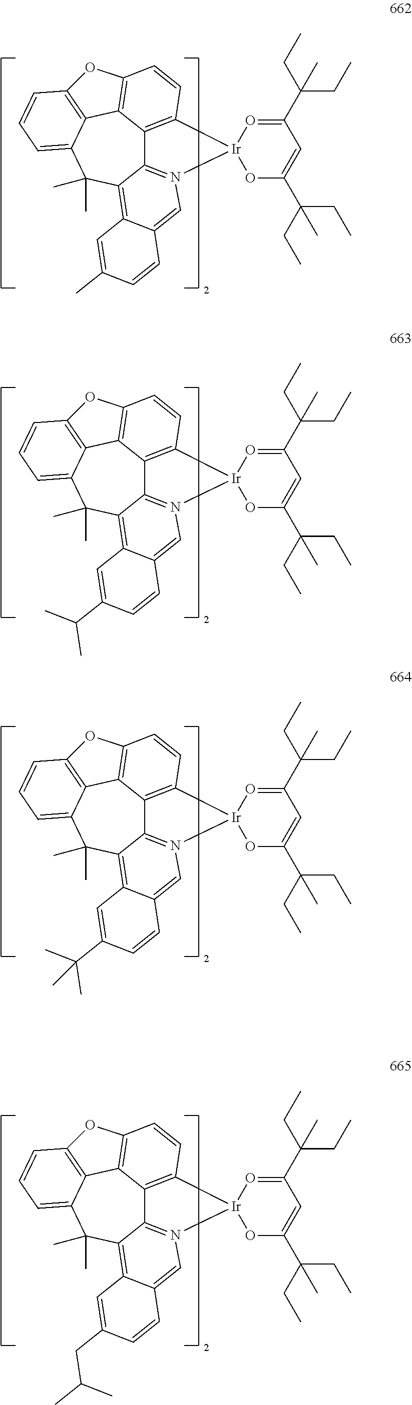

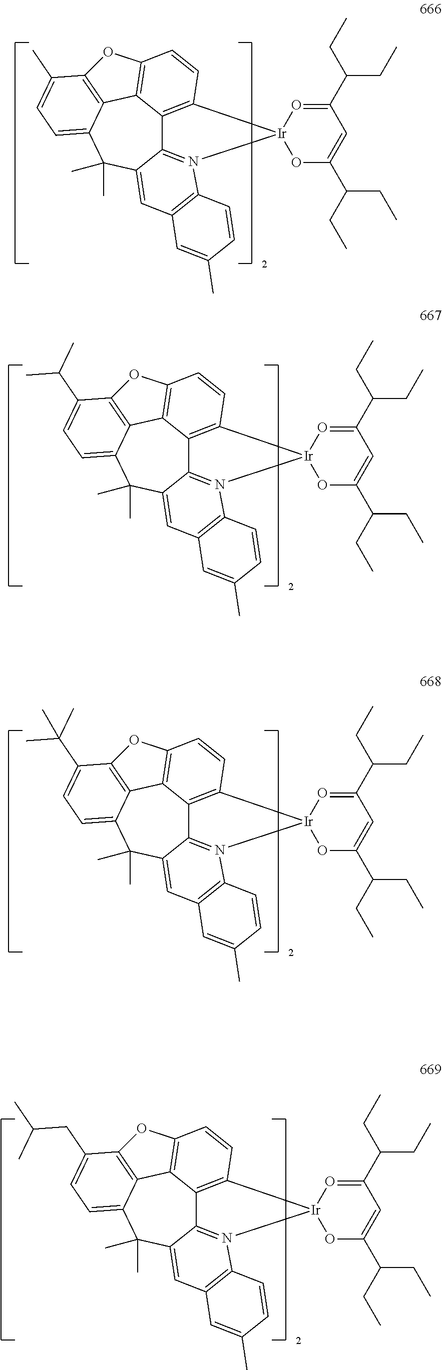

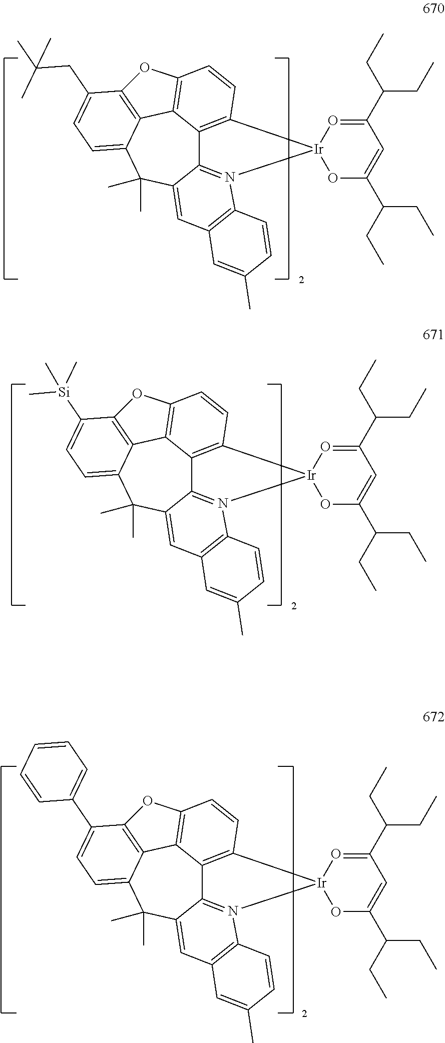

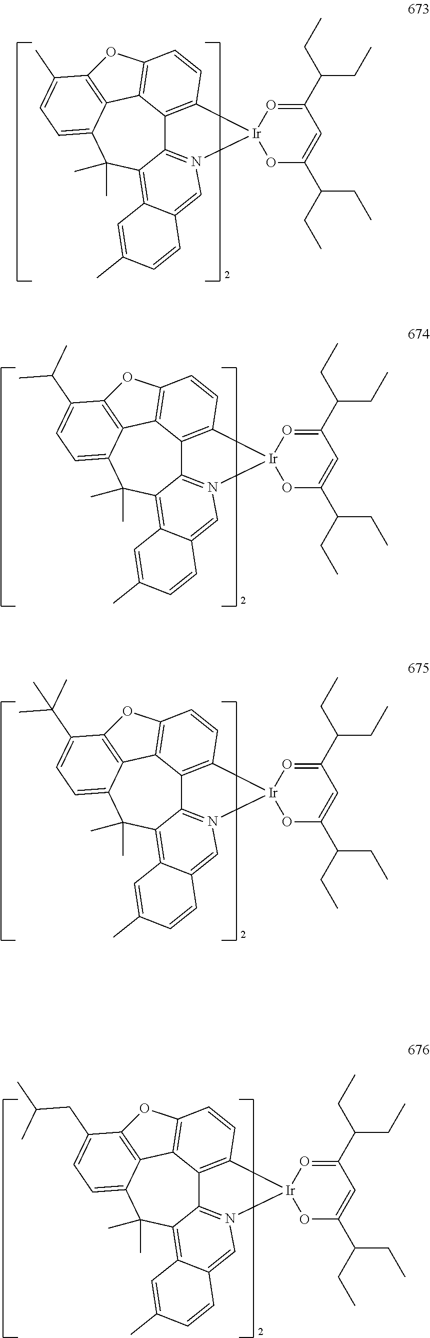

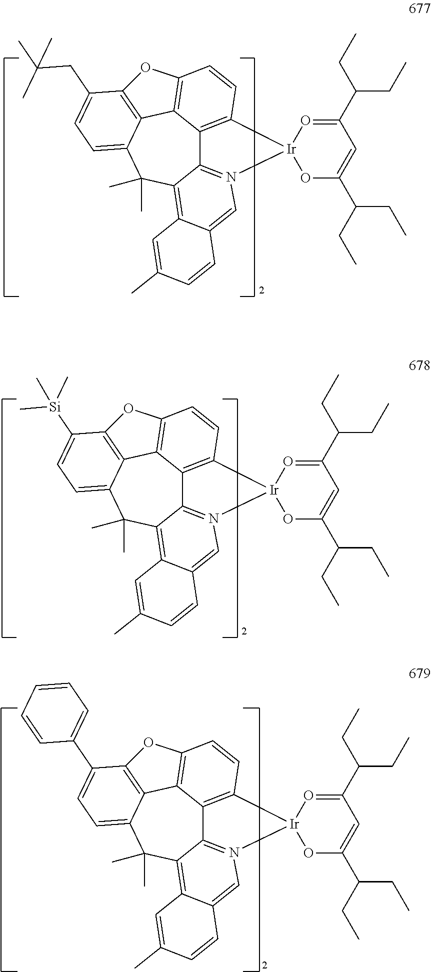

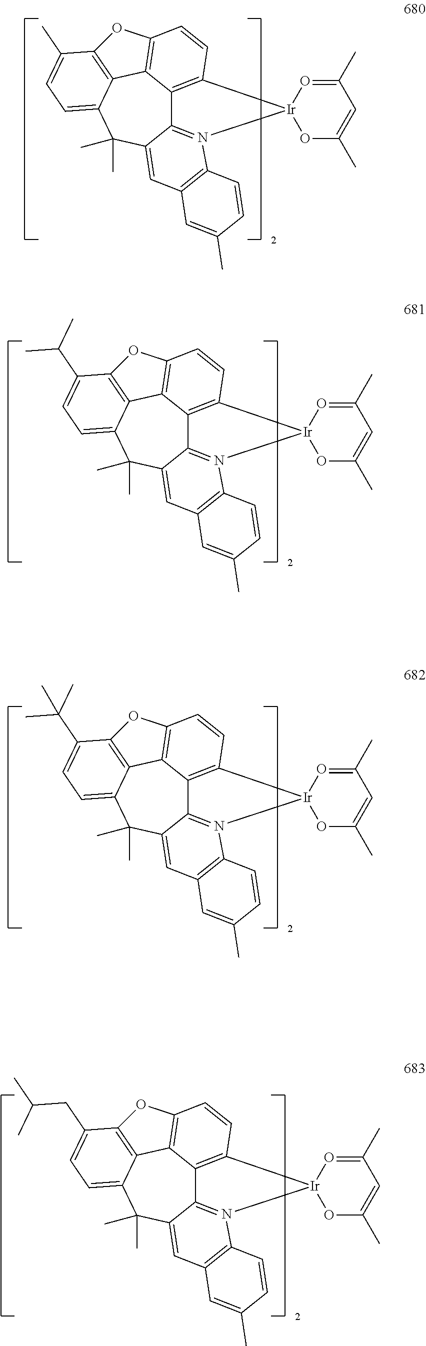

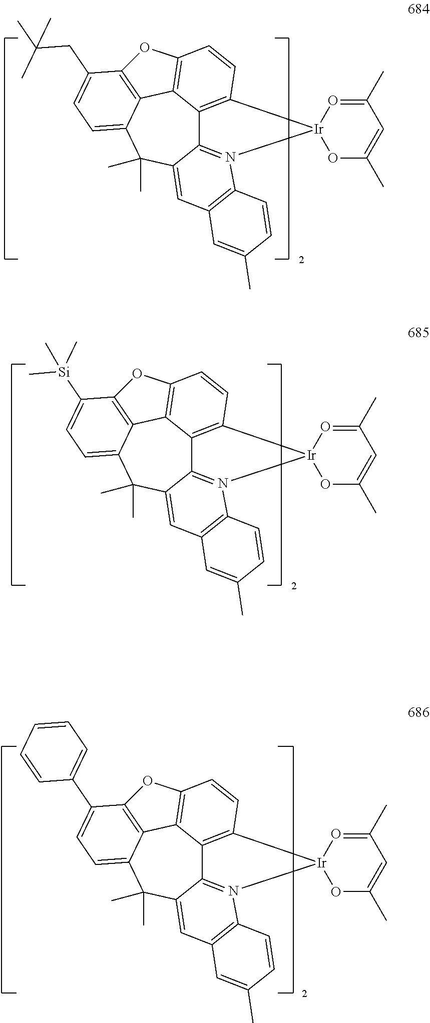

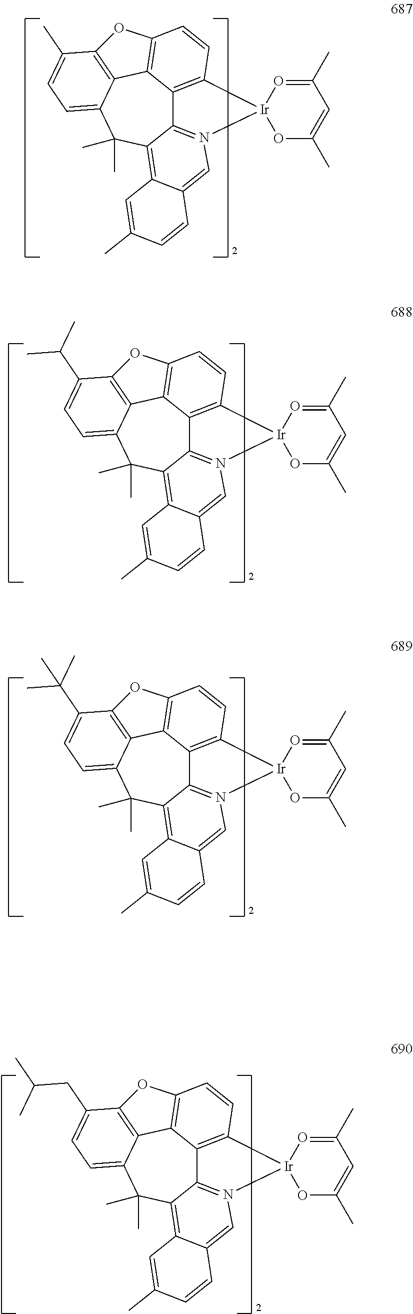

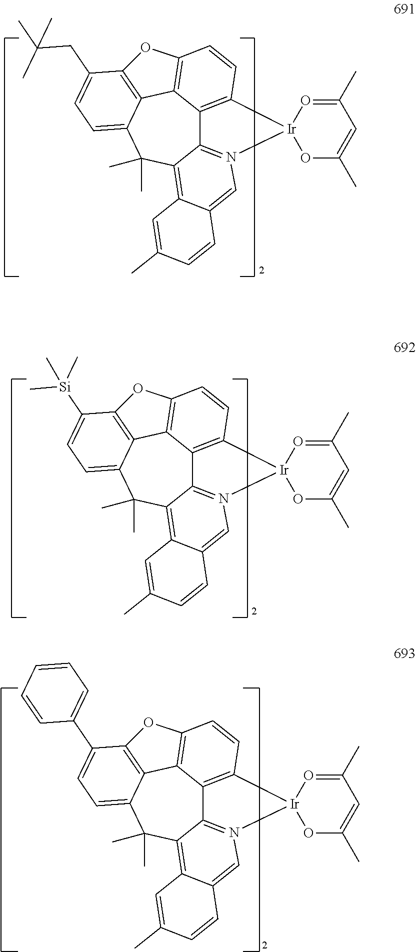

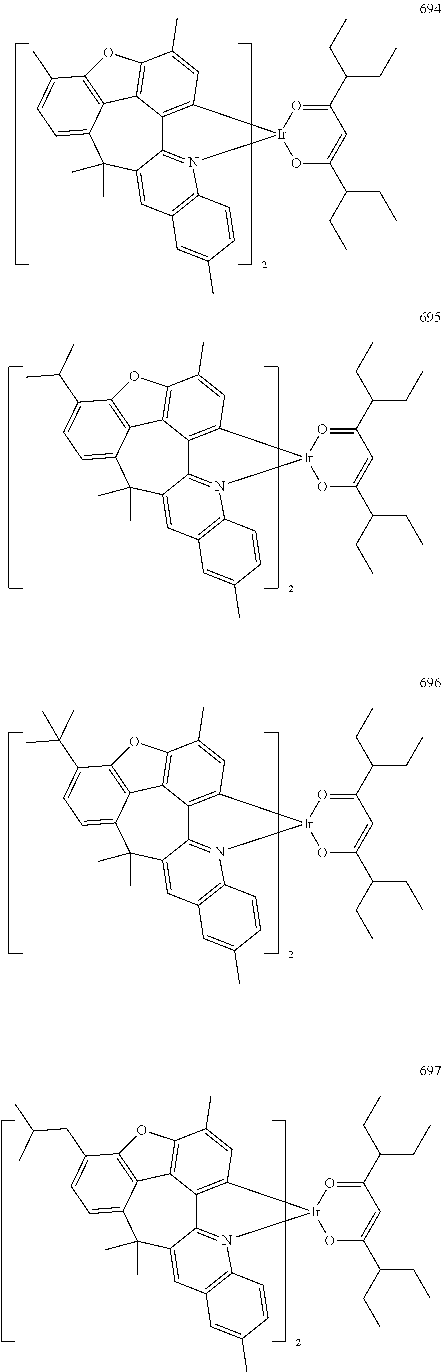

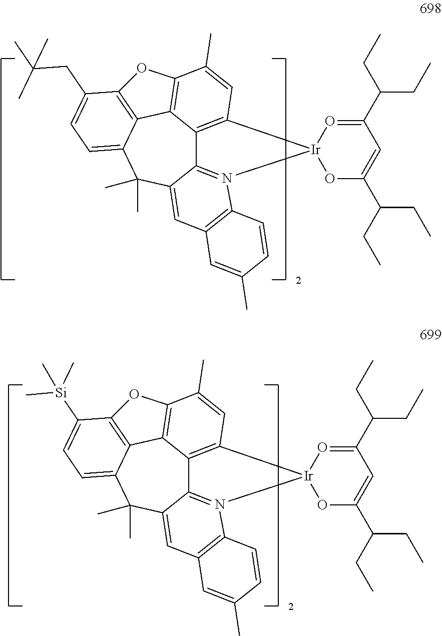

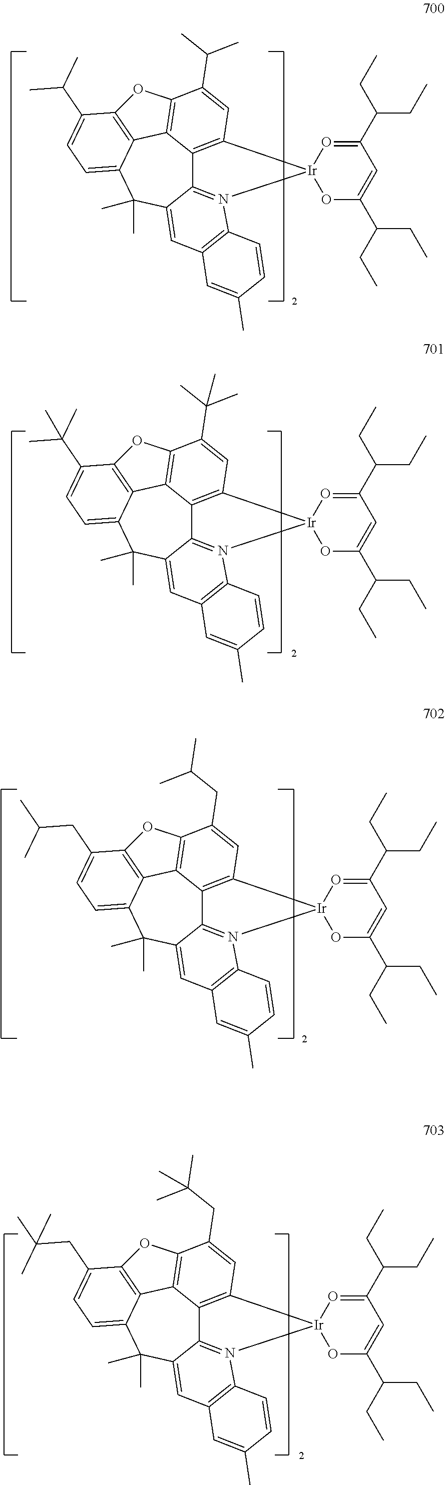

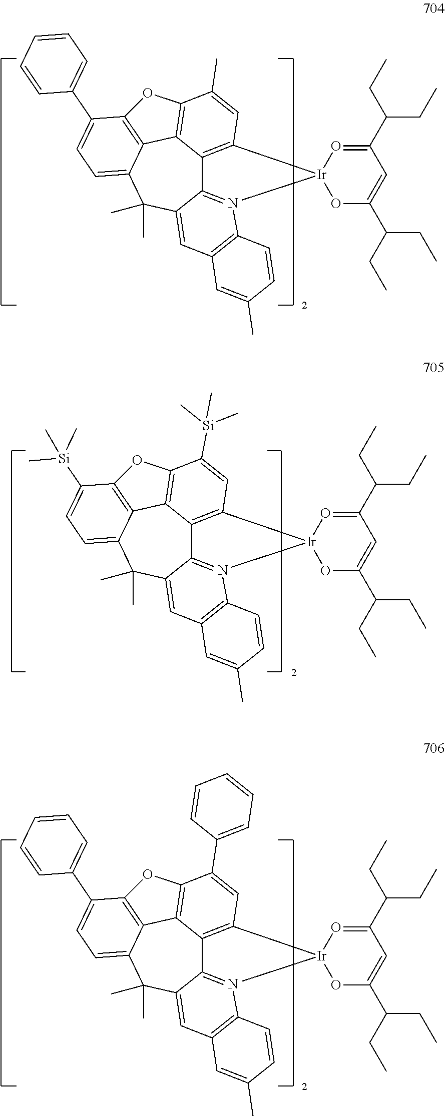

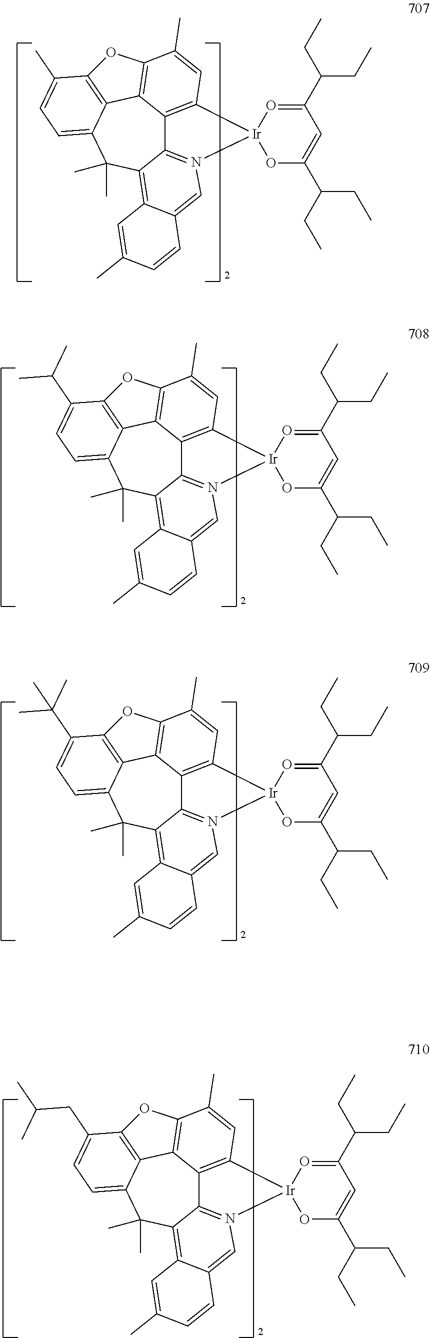

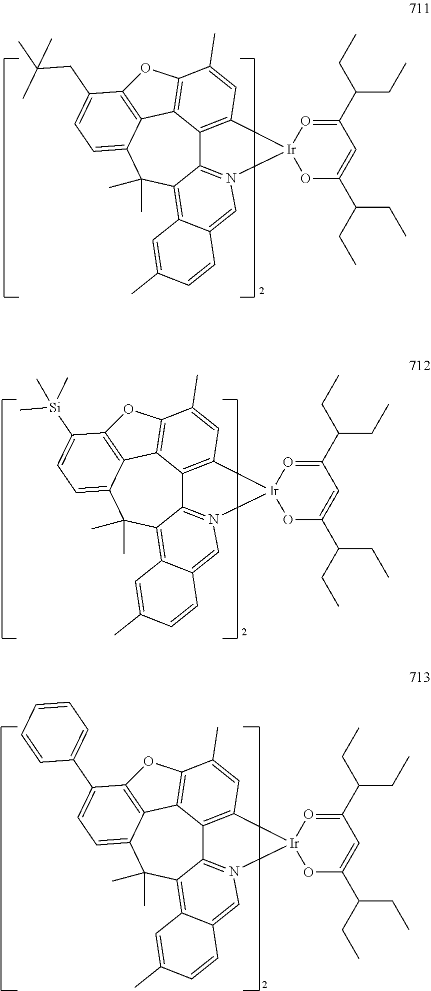

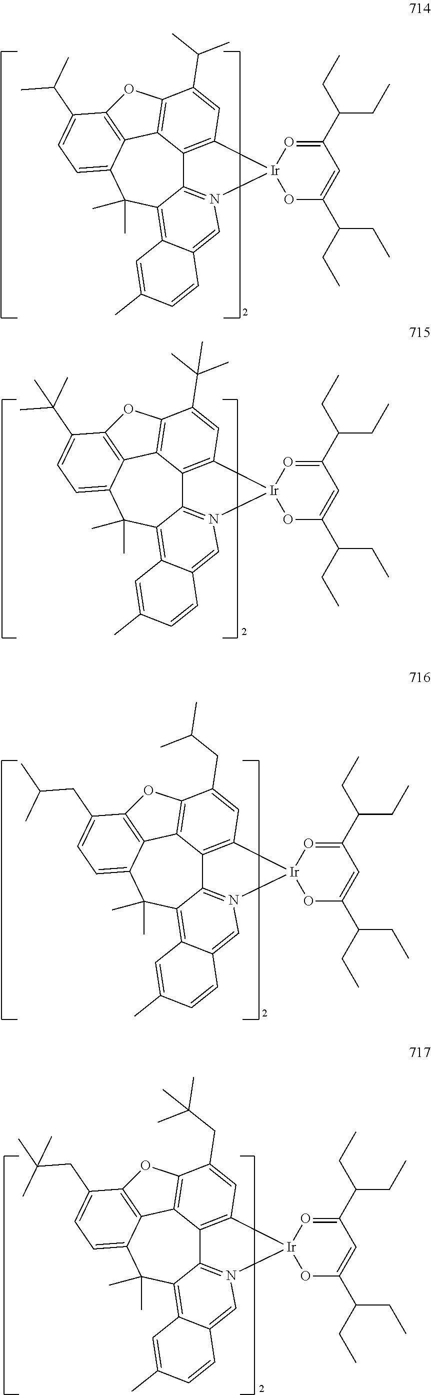

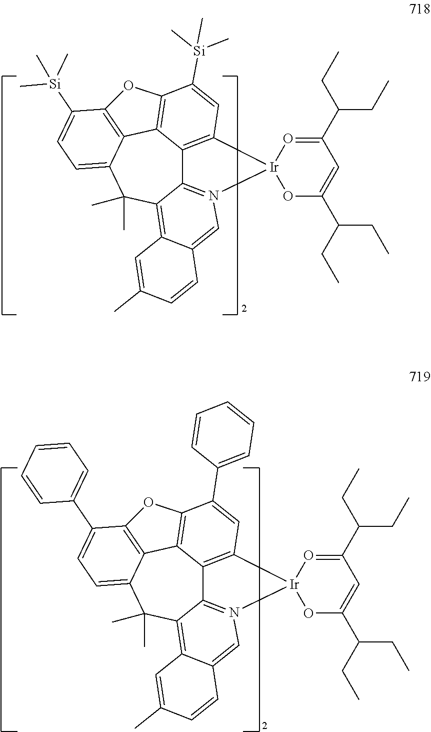

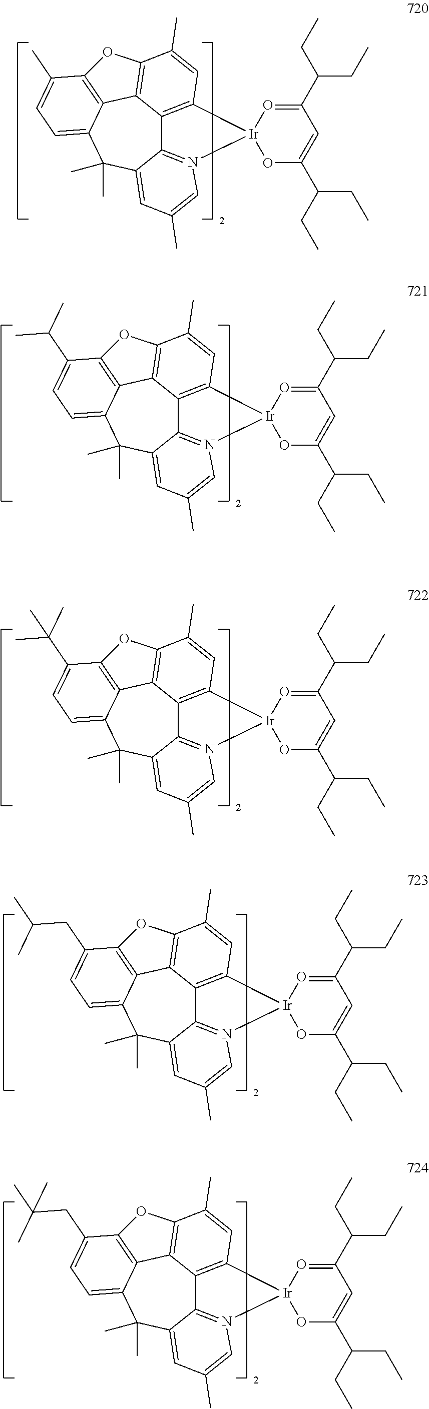

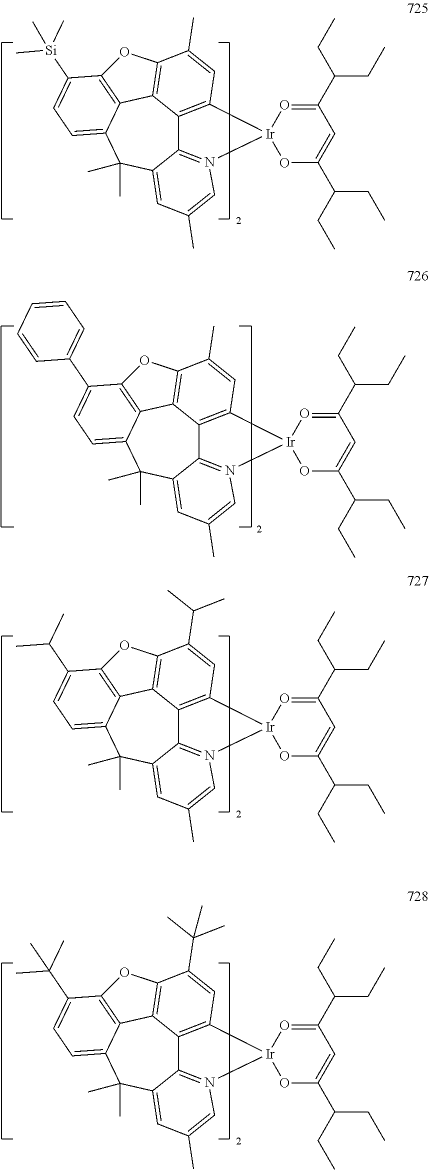

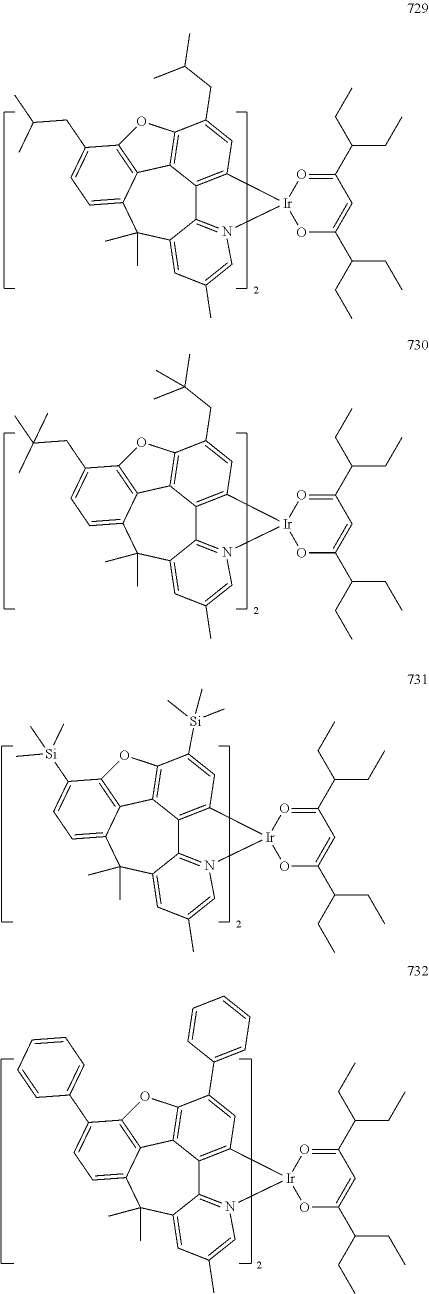

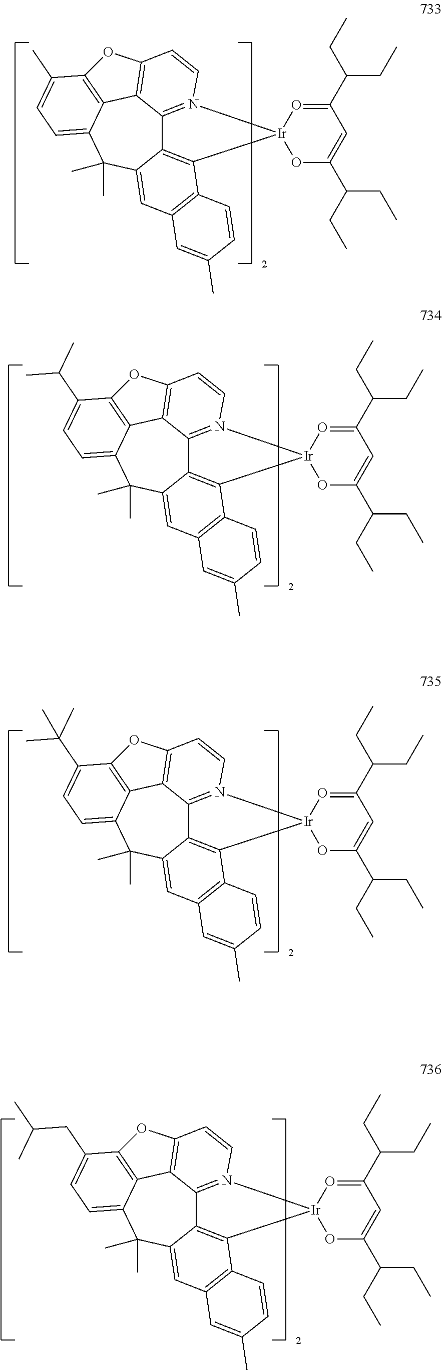

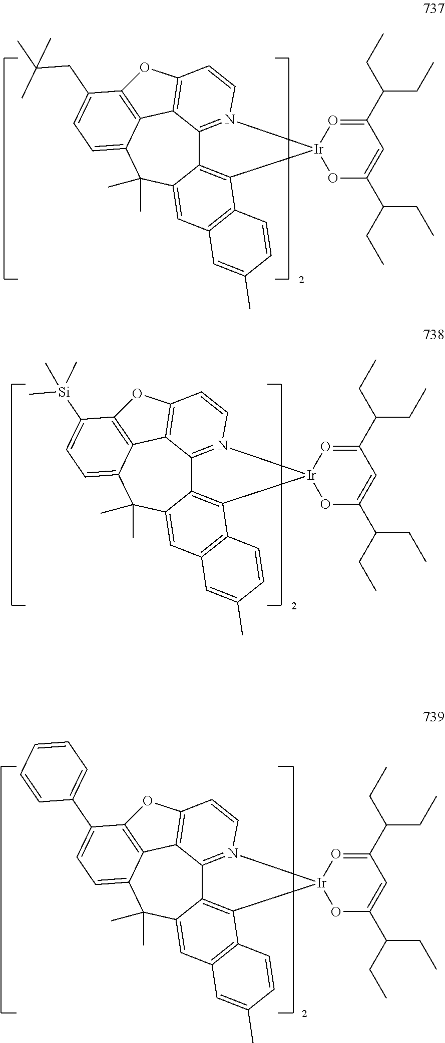

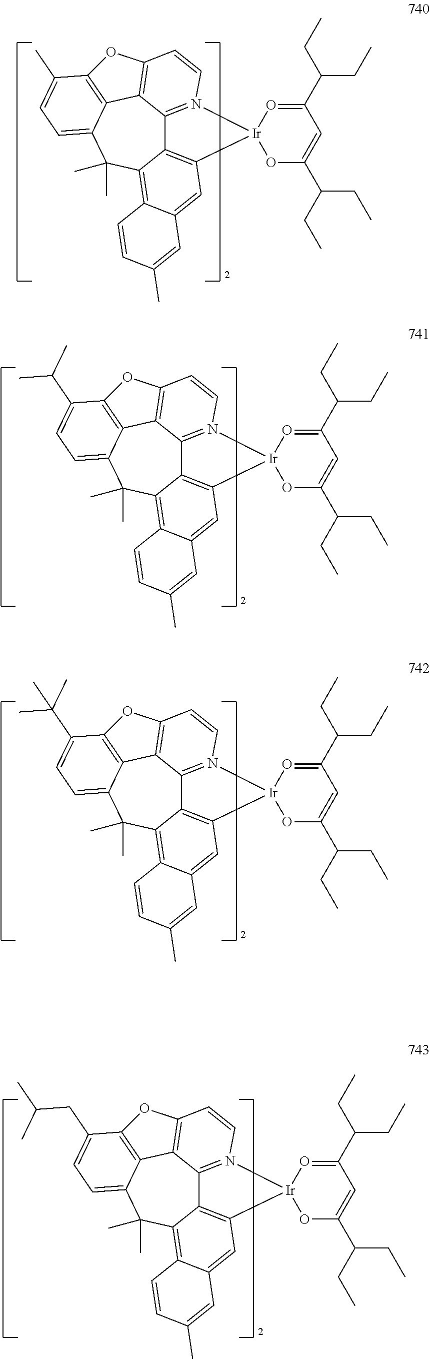

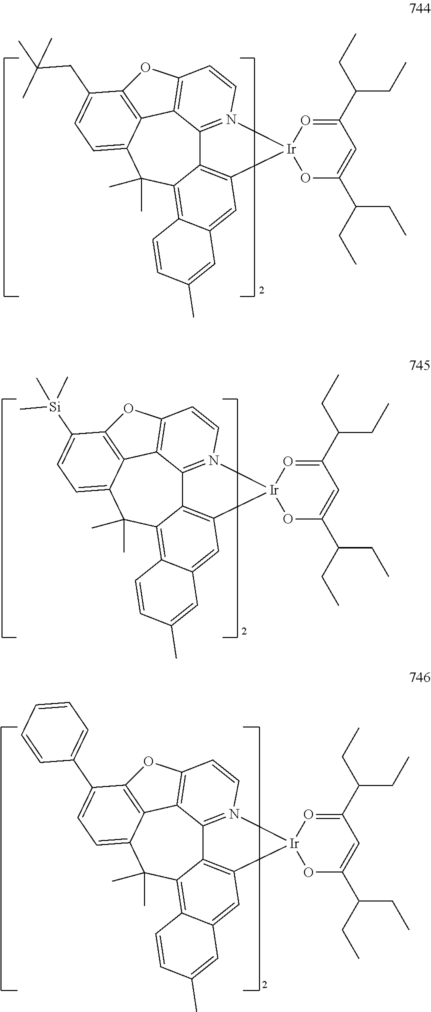

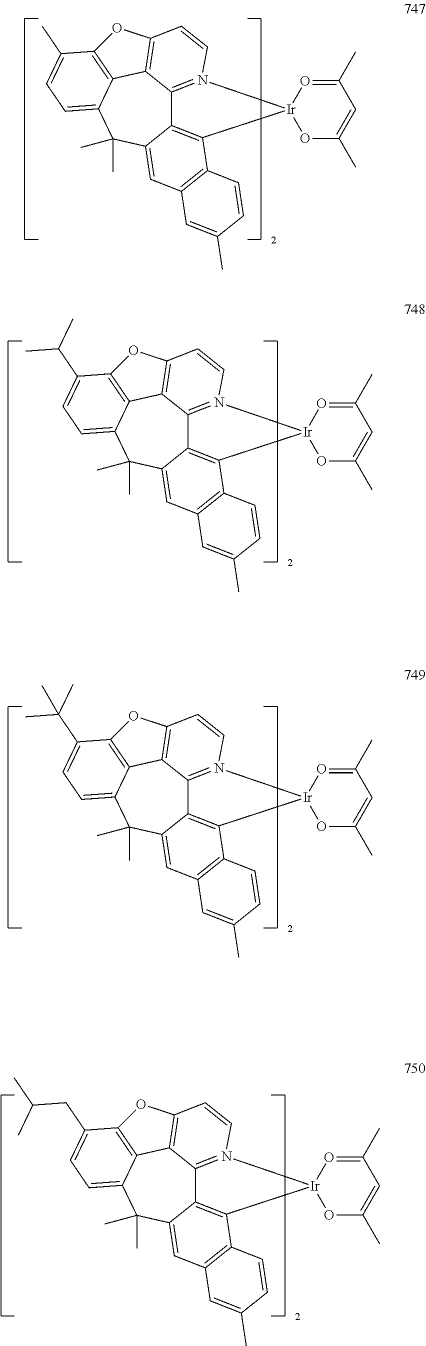

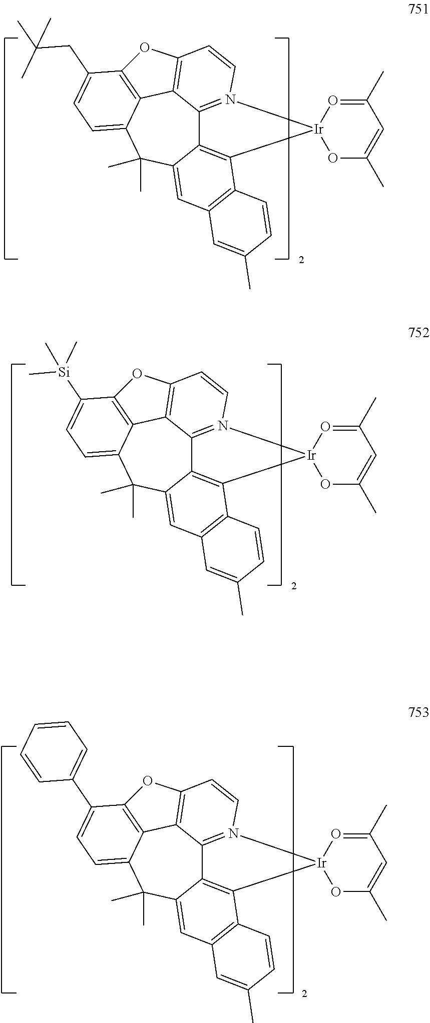

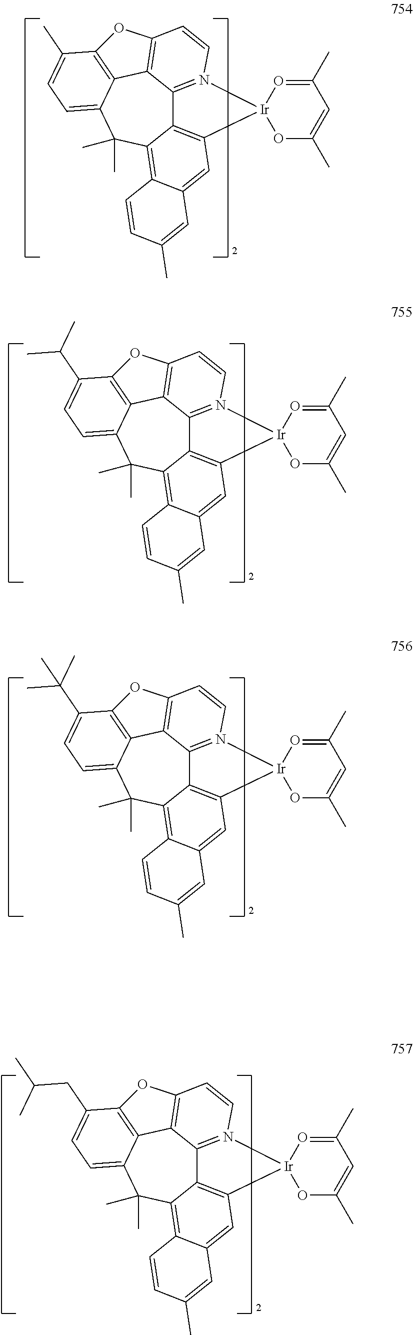

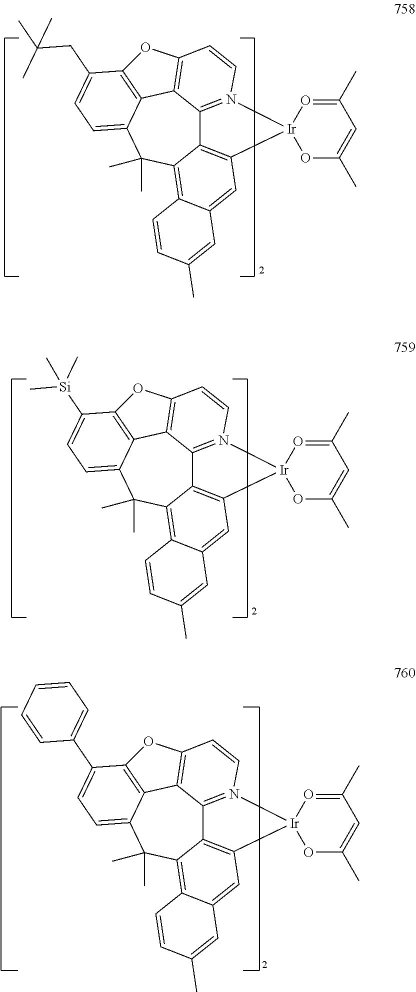

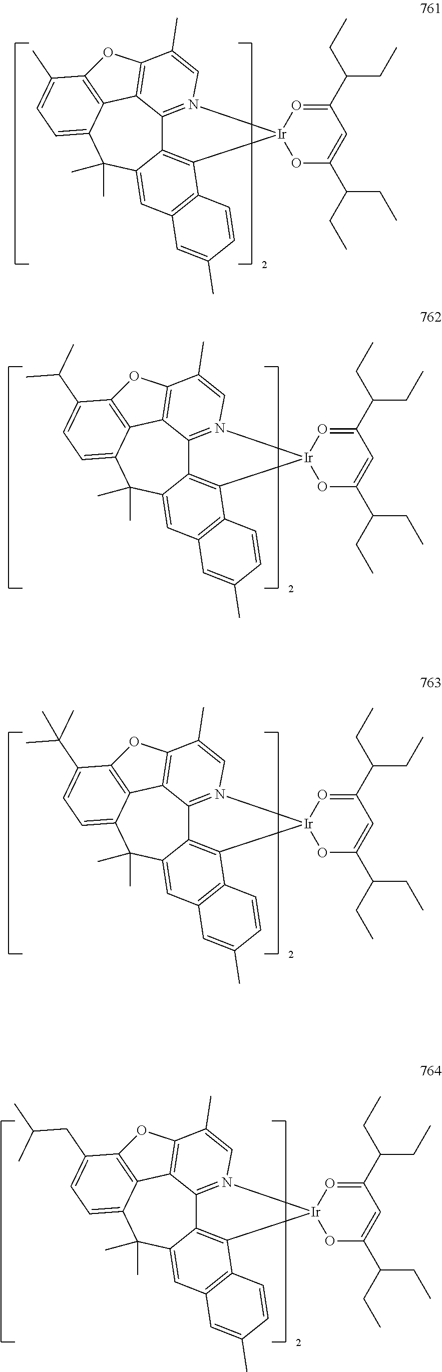

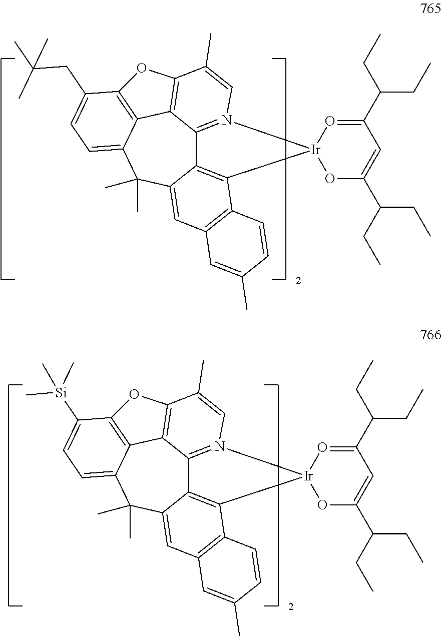

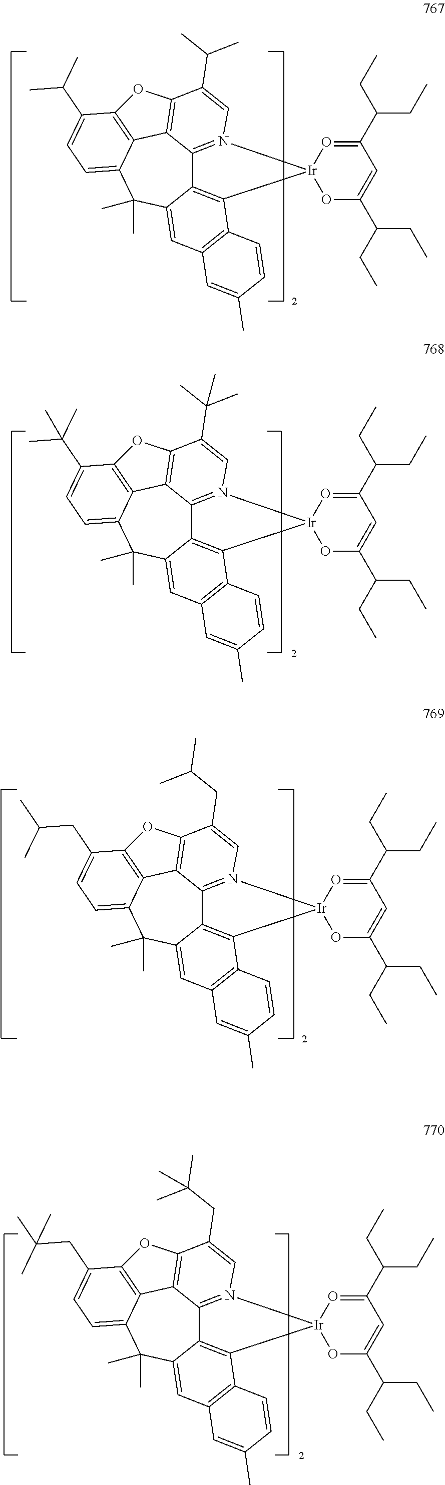

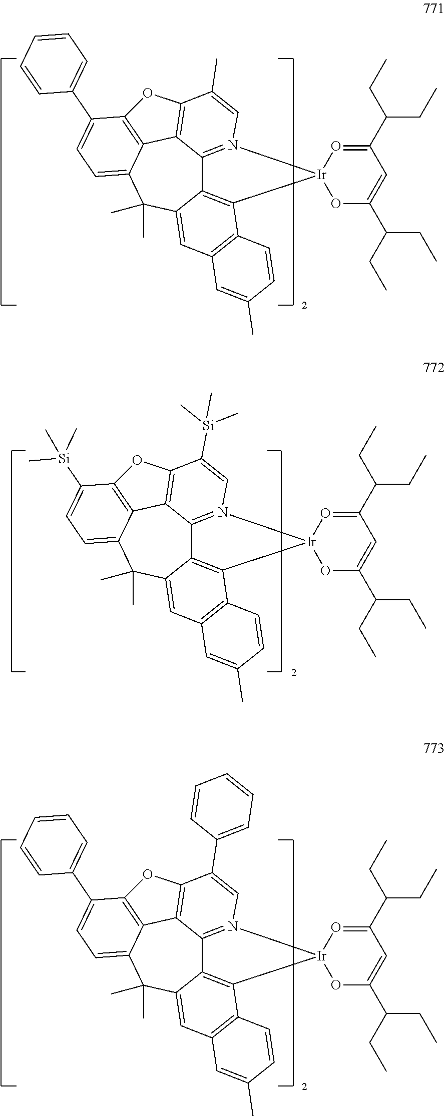

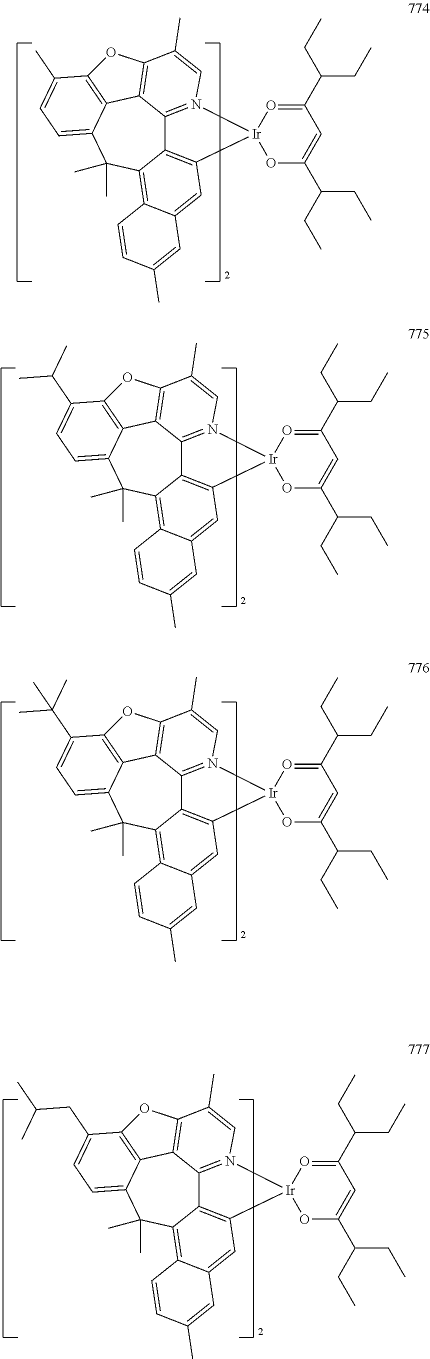

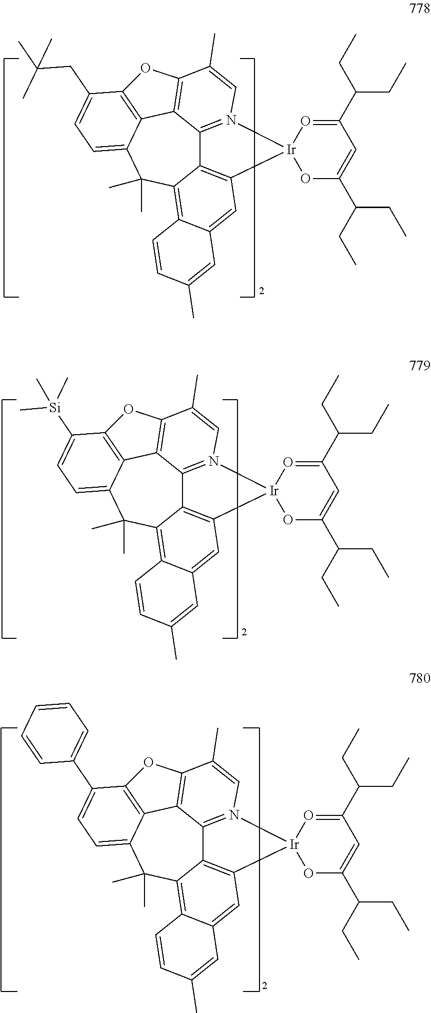

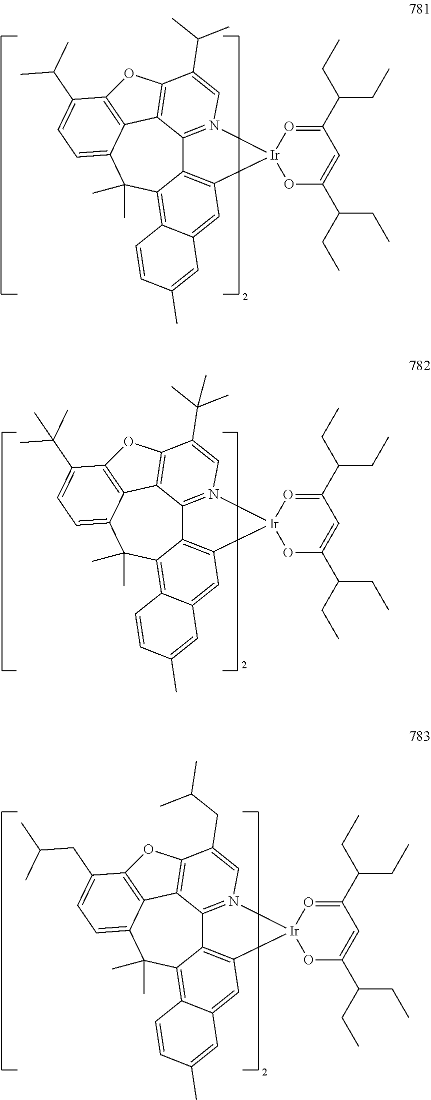

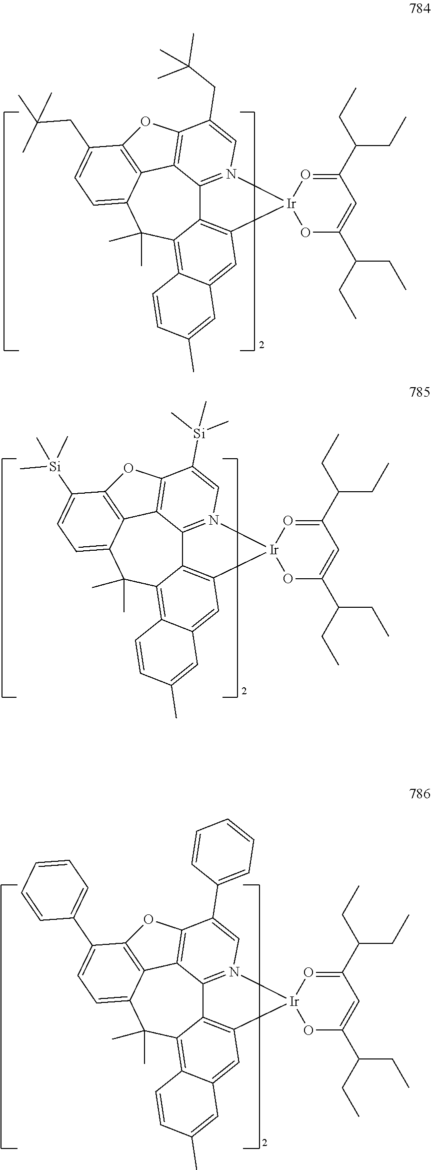

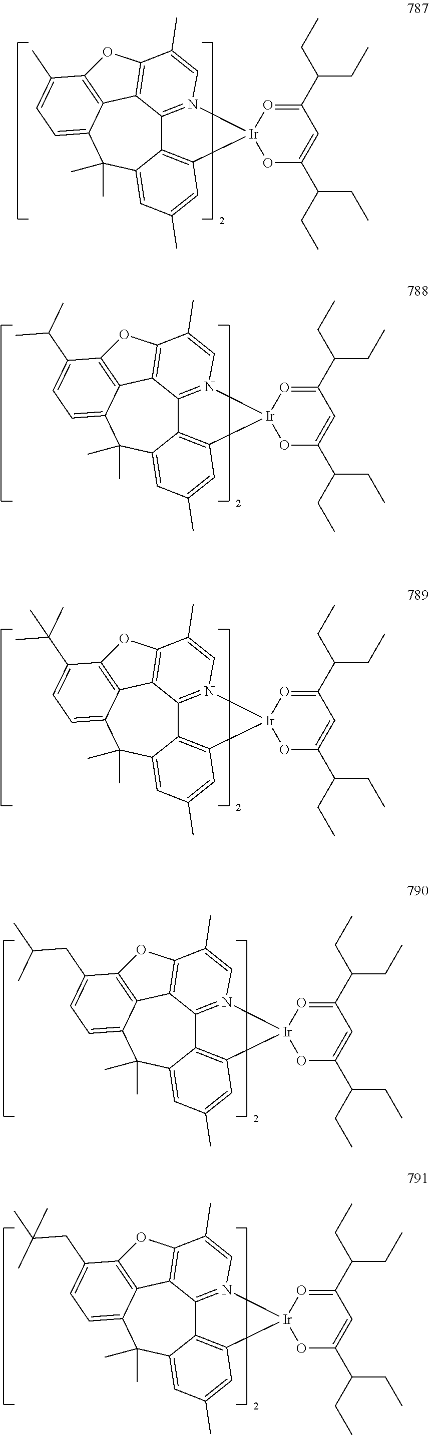

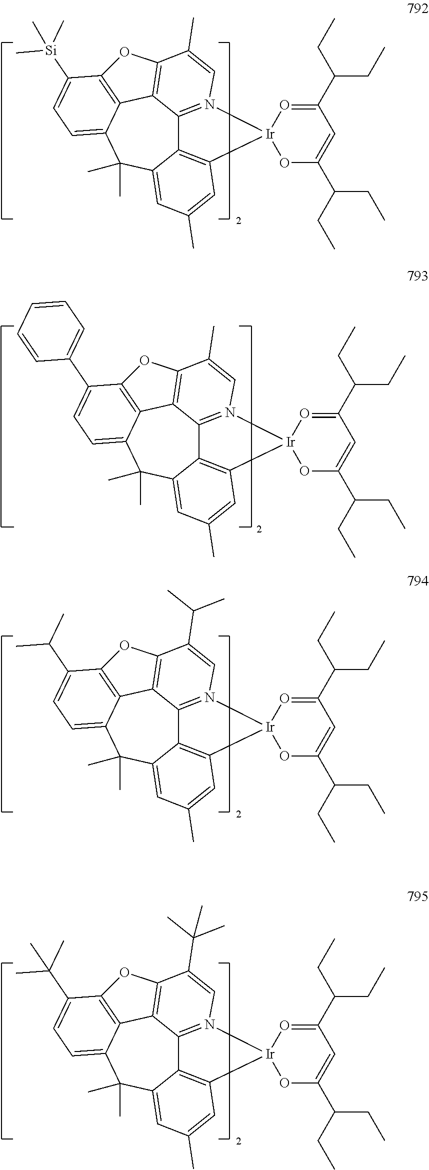

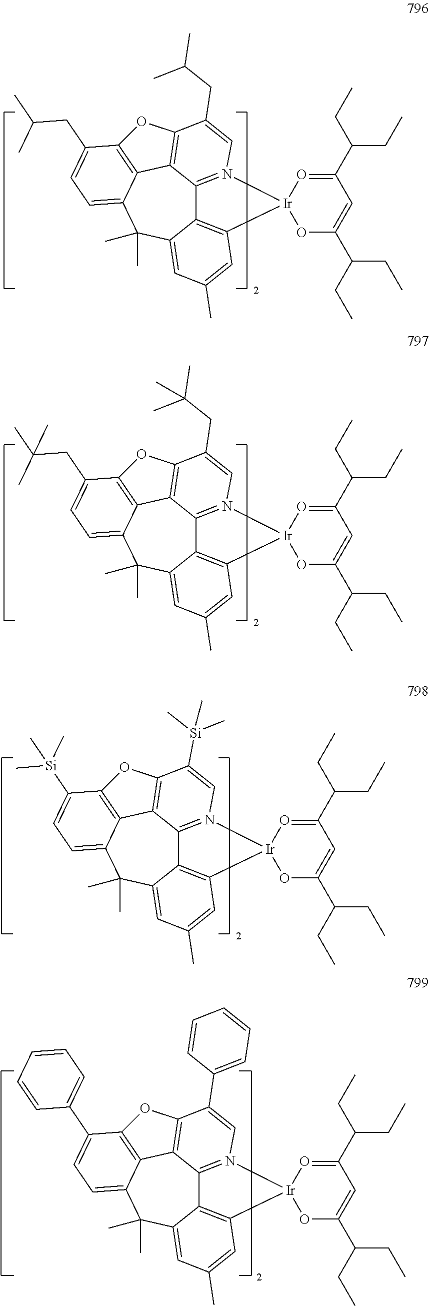

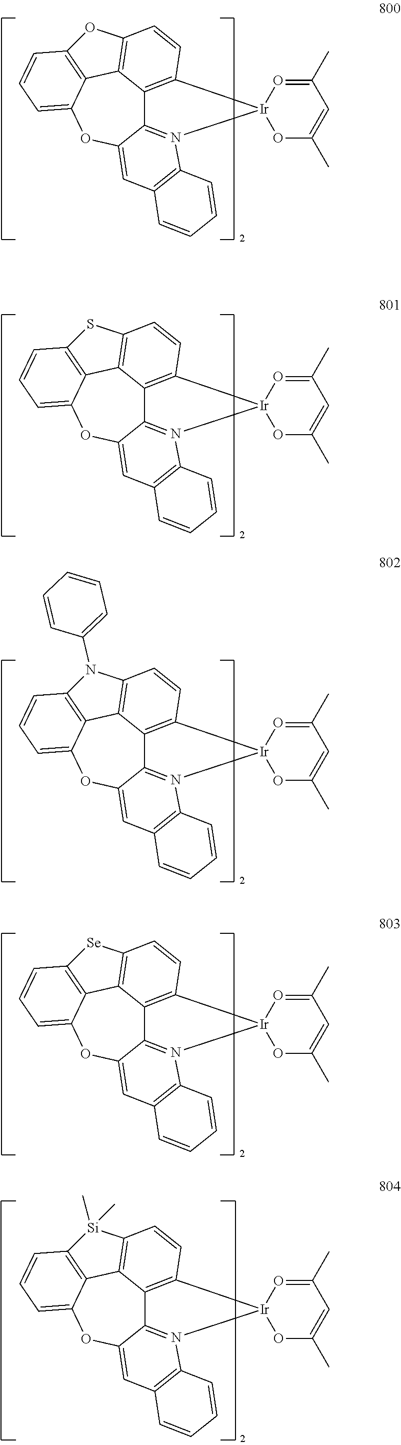

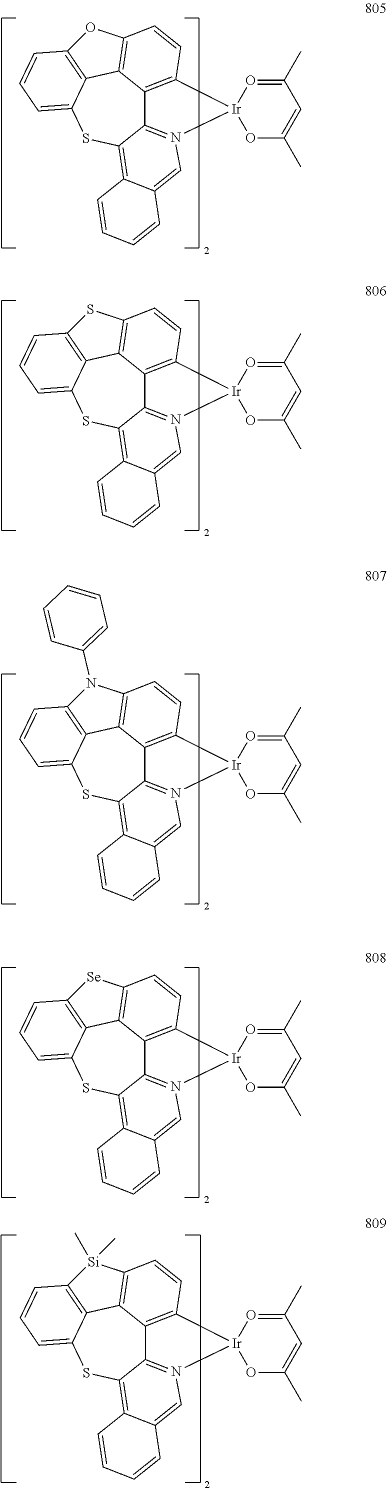

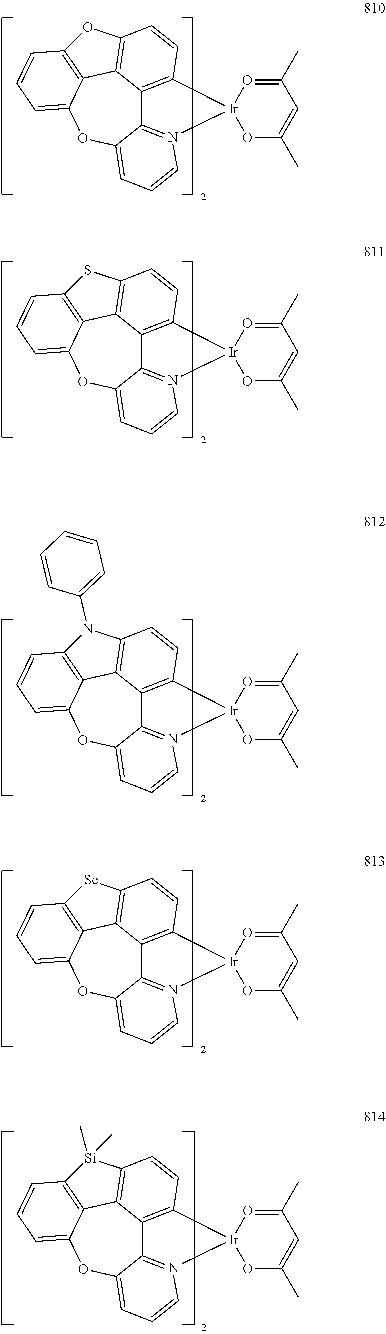

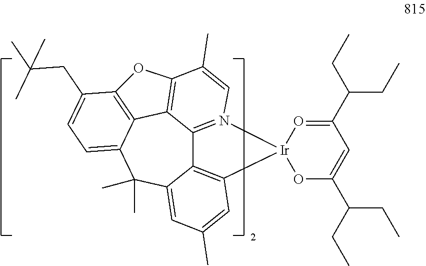

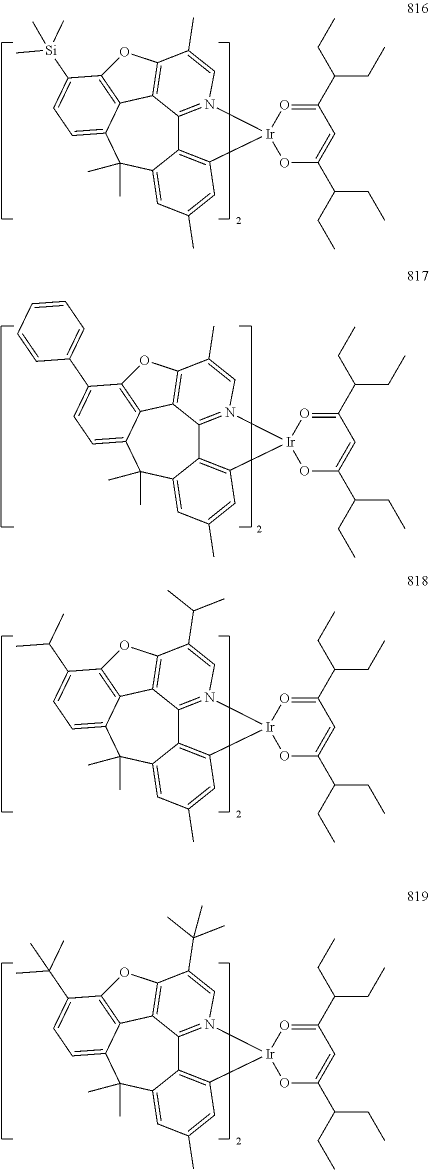

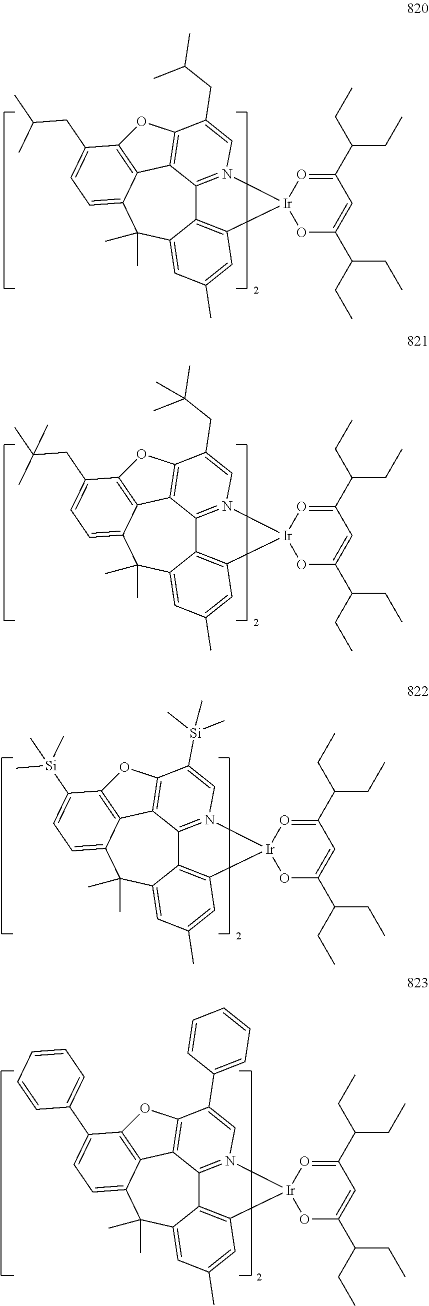

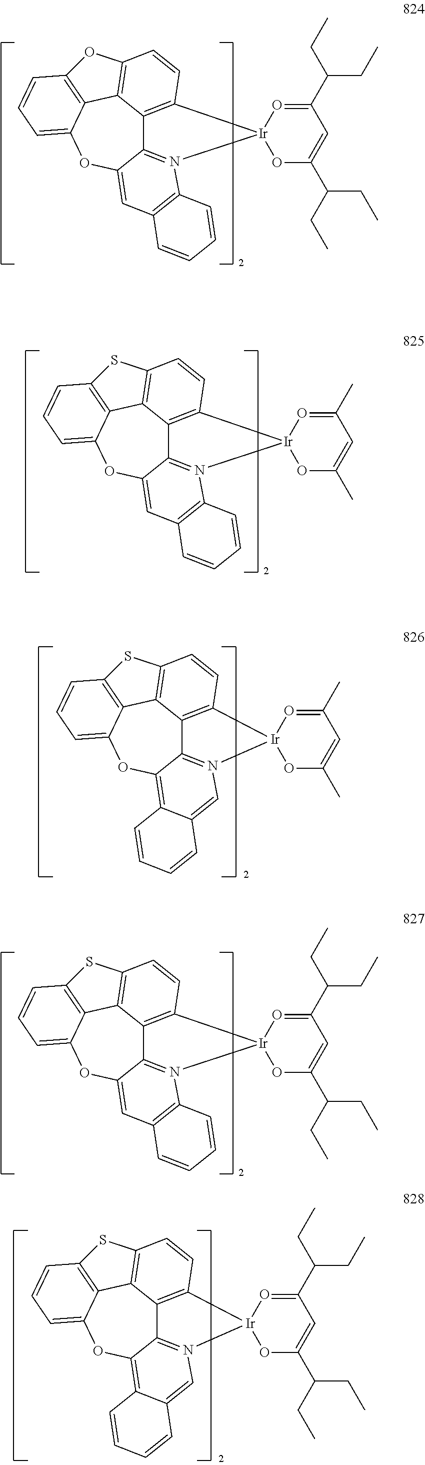

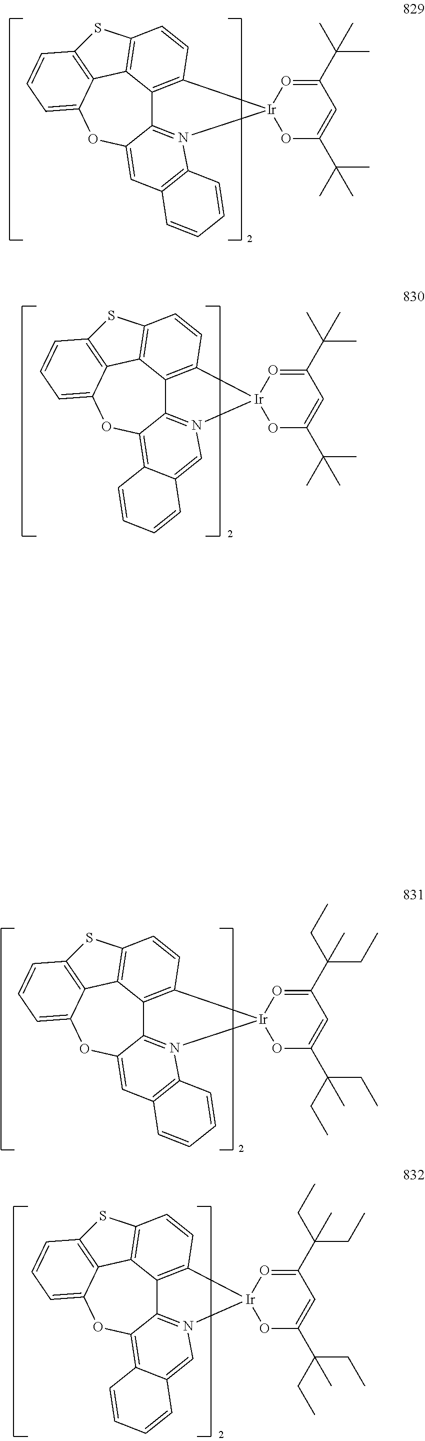

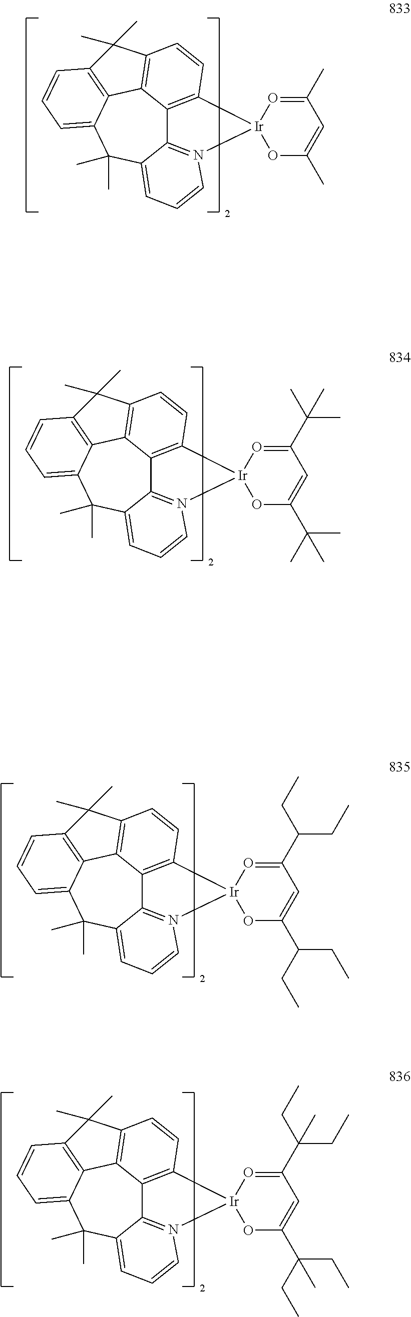

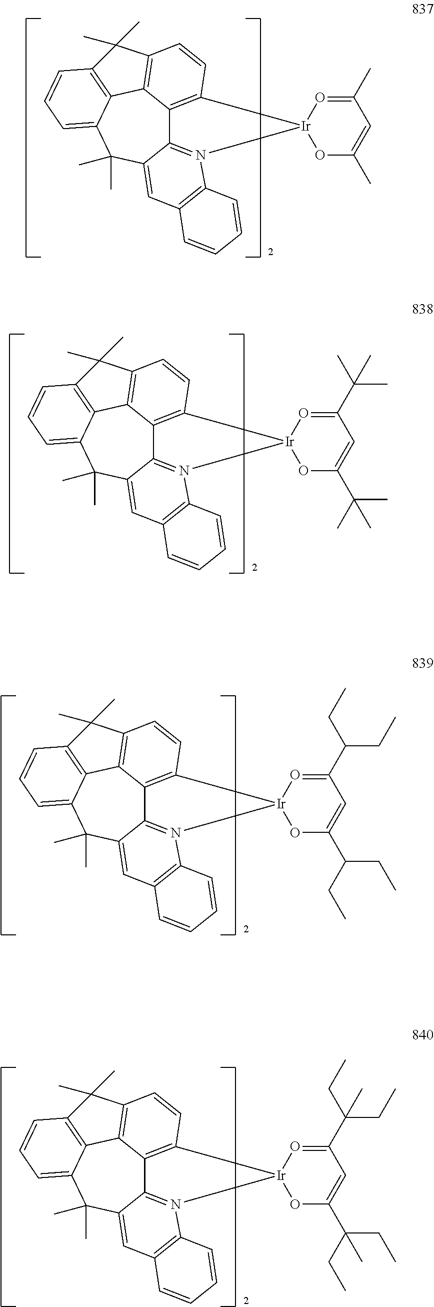

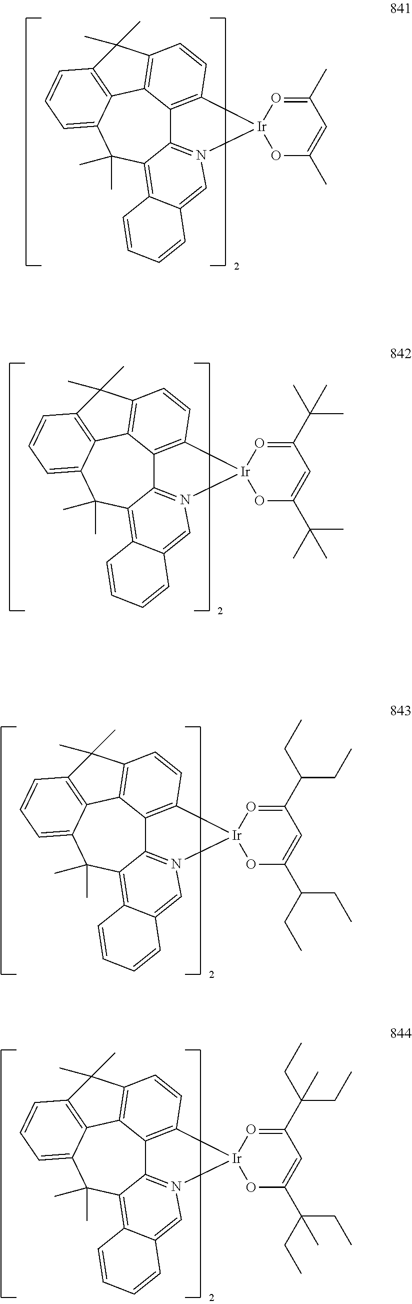

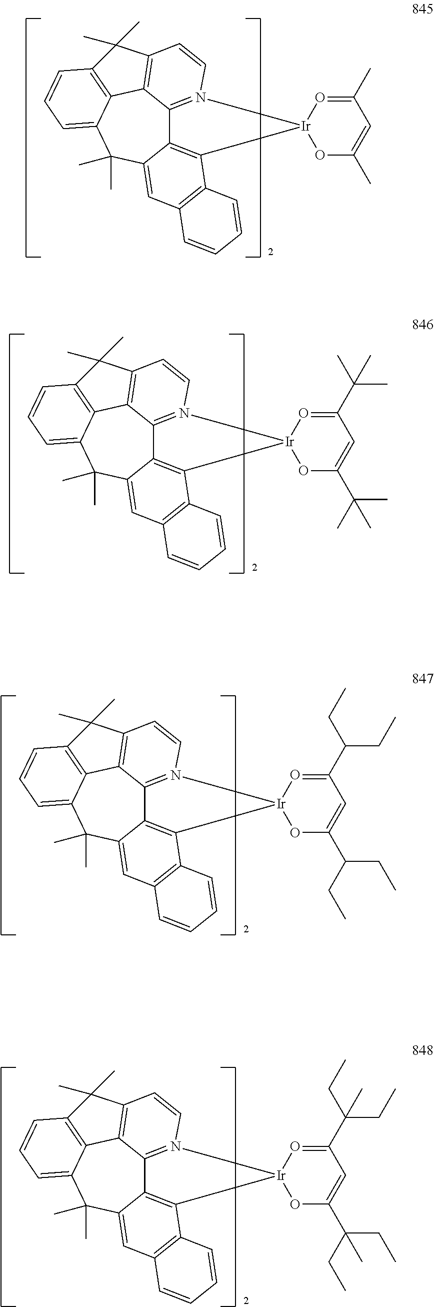

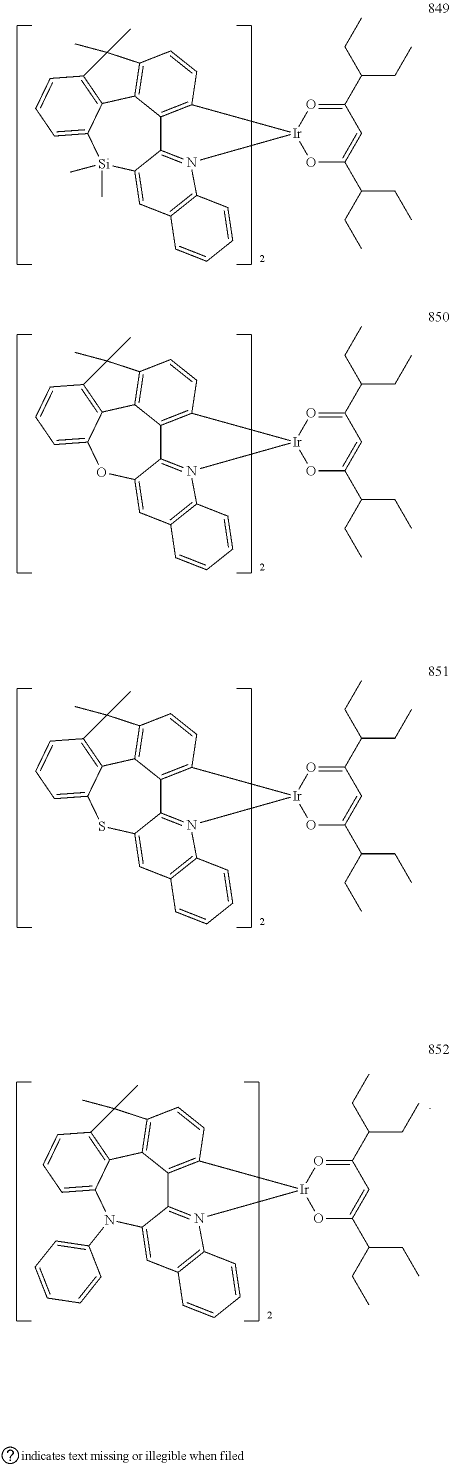

The organic metal compound having any one of the structures of Formula 1 to Formula 6 includes a ligand comprising a fused aromatic or hetero aromatic ring with multiple aromatic or hetero aromatic ring, so that it has a rigid chemical conformation. The organic metal compound can improve its color purity with narrow FWHM (Full-width at half maximum) and can enhance its luminous lifespan because it can maintain its stable chemical conformation in the emission process. In addition, since the organic metal compound may be a metal complex with bidentate ligands, it is possible to control the emission color purity and emission colors with ease. Accordingly, an organic light emitting diode having excellent luminous efficiency can be realized by applying the organic metal compound having the structure of Formulae 1 to 6 into an emissive layer.

[Organic Light Emitting Device and Organic Light Emitting Diode]

It is possible to realize an OLED having reduced driving voltage and excellent luminous efficiency and improved luminous lifespan by applying the organic metal compound having the structure of Formulae 1 to 6 into an emissive layer, for example an emitting material layer of the OLED. The OLED of the present disclosure may be applied to an organic light emitting device such as an organic light emitting display device or an organic light emitting illumination device. An organic light emitting display device including the OLED will be explained.

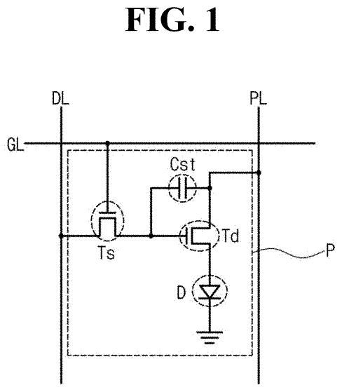

FIG. 1 is a schematic circuit diagram illustrating an organic light emitting display device in accordance with an exemplary aspect of the present disclosure. As illustrated in FIG. 1, a gate line GL, a data line DL and power line PL, each of which cross each other to define a pixel region P, are formed in the organic light emitting display device. A switching thin film transistor Ts, a driving thin film transistor Td, a storage capacitor Cst and an organic light emitting diode D are formed within the pixel region P. The pixel region P may include a red (R) pixel region, a green (G) pixel region and a blue (B) pixel region.

The switching thin film transistor Ts is connected to the gate line GL and the data line DL, and the driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied into the gate line GL, a data signal applied into the data line DL is applied into a gate electrode of the driving thin film transistor Td and one electrode of the storage capacitor Cst through the switching thin film transistor Ts.

The driving thin film transistor Td is turned on by the data signal applied into the gate electrode so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charge with a voltage proportional to the data signal so that the voltage of the gate electrode in the driving thin film transistor Td is kept constant during one frame. Therefore, the organic light emitting display device can display a desired image.

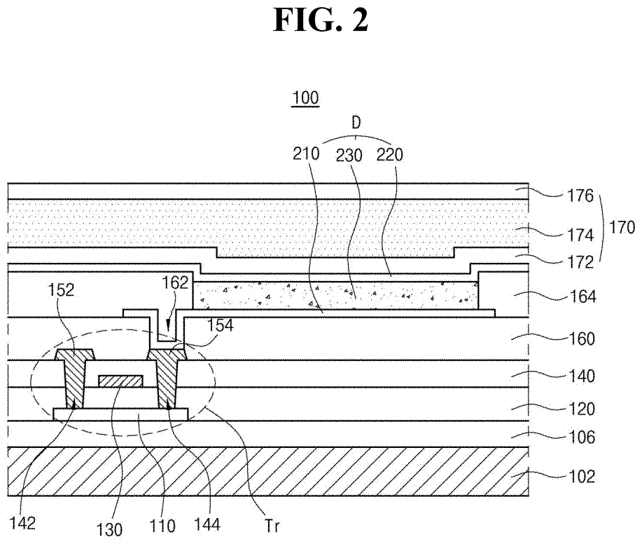

FIG. 2 is a schematic cross-sectional view illustrating an organic light emitting display device in accordance with an exemplary aspect of the present disclosure. As illustrated in FIG. 2, the organic light emitting display device 100 comprises a substrate 102, a thin-film transistor Tr over the substrate 102, and an organic light emitting diode D connected to the thin film transistor Tr. As an example, the substrate 102 defines a red pixel region, a green pixel region and a blue pixel region and the organic light emitting diode D is located in each pixel region. In other words, the organic light emitting diode D, which emits red, green or blue light, is located correspondingly in the red pixel region, the green pixel region and the blue pixel region.

The substrate 102 may include, but is not limited to, glass, thin flexible material and/or polymer plastics. For example, the flexible material may be selected from the group of, but is not limited to, polyimide (PI), polyethersulfone (PES), polyethylenenaphthalate (PEN), polyethylene terephthalate (PET), polycarbonate (PC) and combination thereof. The substrate 102, over which the thin film transistor Tr and the organic light emitting diode D are arranged, forms an array substrate.

A buffer layer 106 may be disposed over the substrate 102, and the thin film transistor Tr is disposed over the buffer layer 106. The buffer layer 106 may be omitted.

A semiconductor layer 110 is disposed over the buffer layer 106. In one exemplary aspect, the semiconductor layer 110 may include, but is not limited to, oxide semiconductor materials. In this case, a light-shield pattern may be disposed under the semiconductor layer 110, and the light-shield pattern can prevent light from being incident toward the semiconductor layer 110, and thereby, preventing the semiconductor layer 110 from being deteriorated by the light. Alternatively, the semiconductor layer 110 may include polycrystalline silicon. In this case, opposite edges of the semiconductor layer 110 may be doped with impurities.

A gate insulating layer 120 including an insulating material is disposed on the semiconductor layer 110. The gate insulating layer 120 may include, but is not limited to, an inorganic insulating material such as silicon oxide (SiOₓ) or silicon nitride (SiNₓ).

A gate electrode 130 made of a conductive material such as a metal is disposed over the gate insulating layer 120 so as to correspond to a center of the semiconductor layer 110. While the gate insulating layer 120 is disposed over a whole area of the substrate 102 in FIG. 2, the gate insulating layer 120 may be patterned identically as the gate electrode 130.

An interlayer insulating layer 140 including an insulating material is disposed on the gate electrode 130 with covering over an entire surface of the substrate 102. The interlayer insulating layer 140 may include an inorganic insulating material such as silicon oxide (SiOₓ) or silicon nitride (SiNₓ), or an organic insulating material such as benzocyclobutene or photo-acryl.

The interlayer insulating layer 140 has first and second semiconductor layer contact holes 142 and 144 that expose both sides of the semiconductor layer 110. The first and second semiconductor layer contact holes 142 and 144 are disposed over opposite sides of the gate electrode 130 with spacing apart from the gate electrode 130. The first and second semiconductor layer contact holes 142 and 144 are formed within the gate insulating layer 120 in FIG. 2. Alternatively, the first and second semiconductor layer contact holes 142 and 144 are formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other with respect to the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed over the semiconductor layer 110. Alternatively, the thin film transistor Tr may have an inverted staggered structure in which a gate electrode is disposed under a semiconductor layer and a source and drain electrodes are disposed over the semiconductor layer. In this case, the semiconductor layer may include amorphous silicon.

Although not shown in FIG. 2, a gate line and a data line, which cross each other to define a pixel region, and a switching element, which is connected to the gate line and the data line, is may be further formed in the pixel region. The switching element is connected to the thin film transistor Tr, which is a driving element. In addition, a power line is spaced apart in parallel from the gate line or the data line, and the thin film transistor Tr may further include a storage capacitor configured to constantly keep a voltage of the gate electrode for one frame.

A passivation layer 160 is disposed on the source and drain electrodes 152 and 154 with covering the thin film transistor Tr over the whole substrate 102. The passivation layer 160 has a flat top surface and a drain contact hole 162 that exposes the drain electrode 154 of the thin film transistor Tr. While the drain contact hole 162 is disposed on the second semiconductor layer contact hole 144, it may be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The organic light emitting diode D further includes an emissive layer 230 and a second electrode 220 each of which is disposed sequentially on the first electrode 210.

The first electrode 210 is disposed in each pixel region. The first electrode 210 may be an anode and include conductive material having relatively high work function value. For example, the first electrode 210 may include, but is not limited to, a transparent conductive oxide (TCO) such as indium tin oxide (ITO), indium zinc oxide (IZO), indium tin zinc oxide (ITZO), SnO, ZnO, indium cerium oxide (ICO), aluminum doped zinc oxide (AZO), and the like.

In one exemplary aspect, when the organic light emitting display device 100 is a bottom-emission type, the first electrode 210 may have a single-layered structure of the TCO. Alternatively, when the organic light emitting display device 100 is a top-emission type, a reflective electrode or a reflective layer may be disposed under the first electrode 210. For example, the reflective electrode or the reflective layer may include, but are not limited to, silver (Ag) or aluminum-palladium-copper (APC) alloy. In the OLED D of the top-emission type, the first electrode 210 may have a triple-layered structure of ITO/Ag/ITO or ITO/APC/ITO.

In addition, a bank layer 164 is disposed on the passivation layer 160 in order to cover edges of the first electrode 210. The bank layer 164 exposes a center of the first electrode 210 corresponding to each pixel region. The bank layer 164 may be omitted.

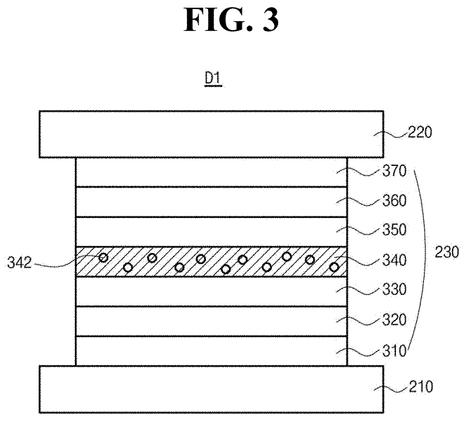

An emissive layer 230 is disposed on the first electrode 210. In one exemplary aspect, the emissive layer 230 may have a single-layered structure of an emitting material layer (EML). Alternatively, the emissive layer 230 may have a multiple-layered structure of a hole injection layer (HIL), a hole transport layer (HTL), an electron blocking layer (EBL), an EML, a hole blocking layer (HBL), an electron transport layer (ETL) and/or an electron injection layer (EIL) (see, FIGS. 3, 5 and 6). In one aspect, the emissive layer 230 may have single emitting part. Alternatively, the emissive layer 230 may have multiple emitting parts to form a tandem structure.

The emissive layer 230 may comprise the organic metal compound having the structure of Formulae 1 to 6. The emissive layer 230 including the organic metal compound enables the OLED D and the organic light emitting display device 100 to improve their luminous efficiency and luminous lifespan considerably.

The second electrode 220 is disposed over the substrate 102 above which the emissive layer 230 is disposed. The second electrode 220 may be disposed over a whole display area, and may include a conductive material with a relatively low work function value compared to the first electrode 210, and may be a cathode. For example, the second electrode 220 may include, but is not limited to, aluminum (Al), magnesium (Mg), calcium (Ca), silver (Ag), alloy thereof or combination thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 may be disposed over the second electrode 220 in order to prevent outer moisture from penetrating into the organic light emitting diode D. The encapsulation film 170 may have, but is not limited to, a laminated structure of a first inorganic insulating film 172, an organic insulating film 174 and a second inorganic insulating film 176. The encapsulation film 170 may be omitted.

A polarizing plate may be attached onto the encapsulation film to reduce reflection of external light. For example, the polarizing plate may be a circular polarizing plate. When the organic light emitting display device 100 is a bottom-emission type, the polarizing plate may be disposed under the substrate 102. Alternatively, when the organic light emitting display device 100 is a top-emission type, the polarizing plate may be disposed over the encapsulation film 170. In addition, a cover window may be attached to the encapsulation film 170 or the polarizing plate when the organic light emitting display device 100 is a top-emission type. In this case, the substrate 102 and the cover window may have a flexible property, thus the organic light emitting display device 100 may be a flexible display device.

Now, we will describe the OLED D including the organic metal compound in more detail. FIG. 3 is a schematic cross-sectional view illustrating an organic light emitting diode having a single emitting part in accordance with an exemplary embodiment of the present disclosure. As illustrated in FIG. 3, the organic light emitting diode (OLED) D1 in accordance with the present disclosure includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 may be disposed in the red pixel region.

In an exemplary embodiment, the emissive layer 230 includes an EML 340 disposed between the first and second electrodes 210 and 220. Also, the emissive layer 230 may comprise at least one of an HTL 320 disposed between the first electrode 210 and the EML 340 and an ETL 360 disposed between the second electrode 220 and the EML 340. In addition, the emissive layer 230 may further comprise at least one of an HIL 310 disposed between the first electrode 210 and the HTL 320 and an EIL 370 disposed between the second electrode 220 and the ETL 360. Alternatively, the emissive layer 230 may further comprise a first exciton blocking layer, i.e. an EBL 330 disposed between the HTL 320 and the EML 340 and/or a second exciton blocking layer, i.e. an HBL 350 disposed between the EML 340 and the ETL 360.

The first electrode 210 may be an anode that provides a hole into the EML 340. The first electrode 210 may include a conductive material having a relatively high work function value, for example, a transparent conductive oxide (TCO). In an exemplary embodiment, the first electrode 210 may include, but is not limited to, ITO, IZO, ITZO, SnO, ZnO, ICO, AZO, and the like.

The second electrode 220 may be a cathode that provides an electron into the EML 340. The second electrode 220 may include a conductive material having a relatively low work function values, i.e., a highly reflective material such as Al, Mg, Ca, Ag, alloy thereof or combination thereof such as Al—Mg.

The HIL 310 is disposed between the first electrode 210 and the HTL 320 and improves an interface property between the inorganic first electrode 210 and the organic HTL 320. In one exemplary embodiment, the HIL 310 may include, but is not limited to, 4,4′4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 1,3,5-tris[4-(diphenylamino)phenyl]benzene (TDAPB), poly(3,4-ethylenedioxythiphene)polystyrene sulfonate (PEDOT/PSS), 2,3,5,6-tetrafluoro-7,7,8,8-tetracyanoquinodimethane (F4TCNQ), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and combination thereof. The HIL 310 may be omitted in compliance of the OLED D1 property.

The HTL 320 is disposed adjacently to the EML 340 between the first electrode 210 and the EML 340. In one exemplary embodiment, the HTL 320 may include, but is not limited to, N,N′-Diphenyl-N,N′-bis(3-methylphenyl)-1,1′-biphenyl-4,4′-diamine (TPD), NPB (NPD), N,N′-bis[4-[bis(3-methylphenyl)amino]phenyl]-N,N′-diphenyl-[1,1′-biphenyl]-4,4′-diamine (DNTPD), 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), 1,1-bis(4-(N,N′-di(p-tolyl)amino)phenyl)cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and combination thereof.

The EML 340 may comprise a host (first host) and a dopant (first dopant) 342 in which substantial emission is occurred. As an example, the EML 340 may emit red color. For example, the organic metal compound having the structure of Formulae 1 to 6 may be used as the dopant 342 in the EML 340.

The ETL 360 and the EIL 370 may be laminated sequentially between the EML 340 and the second electrode 220. The ETL 360 includes a material having high electron mobility so as to provide electrons stably with the EML 340 by fast electron transportation.

In one exemplary aspect, the ETL 360 may comprise, but is not limited to, at least one of oxadiazole-based compounds, triazole-based compounds, phenanthroline-based compounds, benzoxazole-based compounds, benzothiazole-based compounds, benzimidazole-based compounds, triazine-based compounds, and the like.

As an example, the ETL 360 may comprise, but is not limited to, tris-(8-hydroxyquinoline) aluminum (Alq3), Bis(2-methyl-8-quinolinolato-N1,O8)-(1,1′-biphenyl-4-olato)aluminum (BAlq), lithium quinolate (Liq),2-biphenyl-4-yl-5-(4-t-butylphenyl)-1,3,4-oxadiazole (PBD), spiro-PBD, 1,3,5-Tris(N-phenylbenzimidazol-2-yl)benzene (TPBi), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenanthroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[(9,9-bis(3′-((N,N-dimethyl)-N-ethylammonium)-propyl)-2,7-fluorene)-alt-2,7-(9,9-dioctylfluorene)]dibromide (PFNBr), tris(phenylquinoxaline) (TPQ), diphenyl-4-triphenylsilyl-phenylphosphine oxide (TSPO1), 2-[4-(9,10-di-2-naphthalen-2-yl-2-anthracen-2-yl)phenyl]1-phenyl-1H-benzimidazole (ZADN) and combination thereof.

The EIL 370 is disposed between the second electrode 220 and the ETL 360, and can improve physical properties of the second electrode 220 and therefore, can enhance the lifetime of the OLED D1. In one exemplary aspect, the EIL 370 may comprise, but is not limited to, an alkali metal halide and/or an alkaline earth metal halide such as LiF, CsF, NaF, BaF₂ and the like, and/or an organic metal compound such as Liq, lithium benzoate, sodium stearate, and the like. Alternatively, the EIL 370 may be omitted.

In an alternative aspect, the electron transport material and the electron injection material may be admixed to form a single ETL-EIL. The electron transport material and the electron injection material may be mixed with, but is not limited to, about 4:1 to about 1:4 by weight, for example, about 2:1 to about 1:2.

When holes are transferred to the second electrode 220 via the EML 340 and/or electrons are transferred to the first electrode 210 via the EML 340, the OLED D1 may have short lifetime and reduced luminous efficiency. In order to prevent those phenomena, the OLED D1 in accordance with this aspect of the present disclosure may have at least one exciton blocking layer adjacent to the EML 340.

For example, the OLED D1 may include the EBL 330 between the HTL 320 and the EML 340 so as to control and prevent electron transfers. In one exemplary aspect, the EBL 330 may comprise, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, 1,3-bis(carbazol-9-yl)benzene (mCP), 3,3′-bis(N-carbazolyl)-1,1′-biphenyl (mCBP), CuPc, DNTPD, TDAPB, DCDPA, 2,8-bis(9-phenyl-9H-carbazol-3-yl)dibenzo[b,d]thiophene and combination thereof.

In addition, the OLED D1 may further include the HBL 350 as a second exciton blocking layer between the EML 340 and the ETL 360 so that holes cannot be transferred from the EML 340 to the ETL 360. In one exemplary aspect, the HBL 350 may comprise, but is not limited to, at least one of oxadiazole-based compounds, triazole-based compounds, phenanthroline-based compounds, benzoxazole-based compounds, benzothiazole-based compounds, benzimidazole-based compounds, and triazine-based compounds each of which can be used in the ETL 360.

For example, the HBL 350 may comprise a compound having a relatively low HOMO energy level compared to the luminescent materials in EML 340. The HBL 350 may comprise, but is not limited to, Alq3, BAlq, Liq, PBD, spiro-PBD, BCP, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and combination thereof.

As described above, the EML 340 may comprise the host and the dopant 342. The dopant 342 may comprise the organic metal compound having the structure of Formulae 1 to 6.

The host used with the dopant 342 may comprise, but is not limited to, 9-(3-(9H-carbazol-9-yl)phenyl)-9H-carbazole-3-carbonitrile(mCP-CN), CBP, mCBP, mCP, DPEPO, 2,8-bis(diphenylphosphoryl)dibenzothiphene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-Diphenyl-9H,9′H-3,3′-bicarbazole (BCzPh), 1,3,5-Tris(carbazole-9-yl)benzene (TCP), TCTA, 4,4′-Bis(carbazole-9-yl)-2,2′-dimethylbiphenyl (CDBP), 2,7-Bis(carbazole-9-yl)-9,9-dimethylfluorene(DMFL-CBP), 2,2′,7,7′-Tetrakis(carbazole-9-yl)-9,9-spiorofluorene (Spiro-CBP), 3,6-Bis(carbazole-9-yl)-9-(2-ethyl-hexyl)-9H-carbazole (TCz1) and combination thereof. For example, the contents of the dopant 342 in the EML 340 may be between about 1 wt % to about 50 wt %, for example, about 1 wt % and about 30 wt %.

As described above, since the organic metal compound having the structure of Formulae 1 to 6 has a rigid chemical conformation, it can show excellent color purity and luminous lifespan with maintaining its stable chemical conformation in the luminous process. Changing the structure of the bidentate ligands and substituents to the ligand allows the organic metal compound to control its luminescent color. Accordingly, the OLED D1 can lower its driving voltage and improve its luminous efficiency and luminous lifespan.

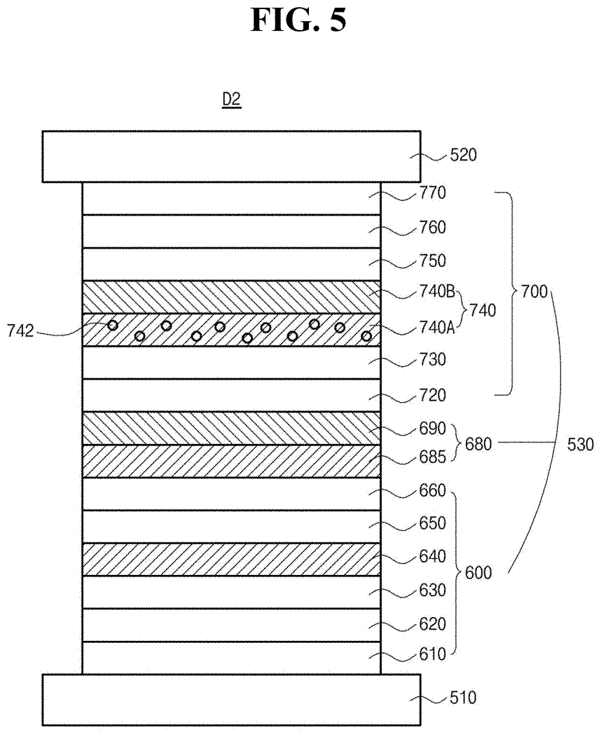

In the above exemplary first aspect, the OLED and the organic light emitting display device include single emitting part emitting red color. Alternatively, the OLED may include multiple emitting parts (see, FIG. 5) each of which includes an emitting material layer having the organic metal compound having the structure of Formulae 1 to 6.

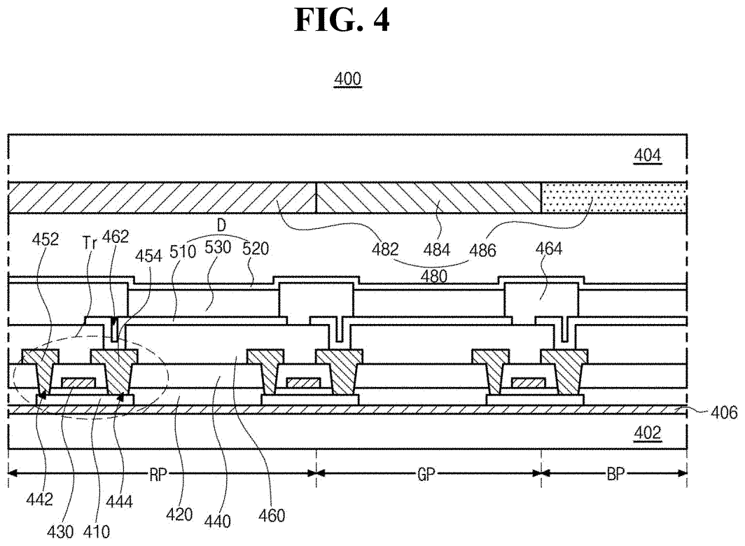

In another exemplary aspect, an organic light emitting display device can implement full-color including white color. FIG. 4 is a schematic cross-sectional view illustrating an organic light emitting display device in accordance with another exemplary aspect of the present disclosure.

As illustrated in FIG. 4, the organic light emitting display device 400 comprises a first substrate 402 that defines each of a red pixel region RP, a green pixel region GP and a blue pixel region BP, a second substrate 404 facing the first substrate 402, a thin film transistor Tr over the first substrate 402, an organic light emitting diode D disposed between the first and second substrates 402 and 404 and emitting white (W) light and a color filter layer 480 disposed between the organic light emitting diode D and the second substrate 404.

Each of the first and second substrates 402 and 404 may include, but is not limited to, glass, flexible material and/or polymer plastics. For example, each of the first and second substrates 402 and 404 may be made of PI, PES, PEN, PET, PC and combination thereof. The first substrate 402, over which a thin film transistor Tr and an organic light emitting diode D are arranged, forms an array substrate.

A buffer layer 406 may be disposed over the first substrate 402, and the thin film transistor Tr is disposed over the buffer layer 406 correspondingly to each of the red pixel region RP, the green pixel region GP and the blue pixel region BP. The buffer layer 406 may be omitted.

A semiconductor layer 410 is disposed over the buffer layer 406. The semiconductor layer 410 may be made of oxide semiconductor material or polycrystalline silicon.

A gate insulating layer 420 including an insulating material, for example, inorganic insulating material such as silicon oxide (SiOₓ) or silicon nitride (SiNₓ) is disposed on the semiconductor layer 410.

A gate electrode 430 made of a conductive material such as a metal is disposed over the gate insulating layer 420 so as to correspond to a center of the semiconductor layer 410. An interlayer insulting layer 440 including an insulating material, for example, inorganic insulating material such as silicon oxide (SiOₓ) or silicon nitride (SiNₓ), or an organic insulating material such as benzocyclobutene or photo-acryl, is disposed on the gate electrode 430.

The interlayer insulating layer 440 has first and second semiconductor layer contact holes 442 and 444 that expose both sides of the semiconductor layer 410. The first and second semiconductor layer contact holes 442 and 444 are disposed over opposite sides of the gate electrode 430 with spacing apart from the gate electrode 430.

A source electrode 452 and a drain electrode 454, which are made of a conductive material such as a metal, are disposed on the interlayer insulating layer 440. The source electrode 452 and the drain electrode 454 are spaced apart from each other with respect to the gate electrode 430, and contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 4, a gate line and a data line, which cross each other to define a pixel region, and a switching element, which is connected to the gate line and the data line, is may be further formed in the pixel region. The switching element is connected to the thin film transistor Tr, which is a driving element. In addition, a power line is spaced apart in parallel from the gate line or the data line, and the thin film transistor Tr may further include a storage capacitor configured to constantly keep a voltage of the gate electrode for one frame.

A passivation layer 460 is disposed on the source and drain electrodes 452 and 454 with covering the thin film transistor Tr over the whole first substrate 402. The passivation layer 460 has a drain contact hole 462 that exposes the drain electrode 454 of the thin film transistor Tr.

The organic light emitting diode (OLED) D is located over the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region may be an anode and may include a conductive material having relatively high work function value. For example, the first electrode 510 may include, ITO, IZO, ITZO, SnO, ZnO, ICO, AZO, and the like. Alternatively, a reflective electrode or a reflective layer may be disposed under the first electrode 510. For example, the reflective electrode or the reflective layer may include, but is not limited to, Ag or APC alloy.

A bank layer 464 is disposed on the passivation layer 460 in order to cover edges of the first electrode 510. The bank layer 464 exposes a center of the first electrode 510 corresponding to each of the red pixel region RP, the green pixel region GP and the blue pixel region BP. The bank layer 464 may be omitted.

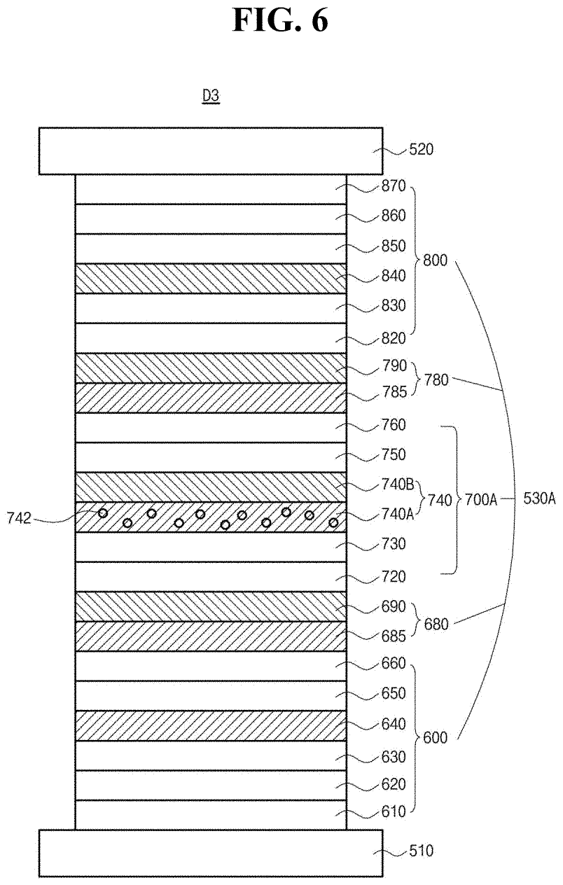

An emissive layer 530 that may include multiple emitting parts is disposed on the first electrode 510. As illustrated in FIGS. 5 and 6, the emissive layers 530 and 530A may include multiple emitting parts 600, 700, 700A and 800 and at least one charge generation layer 680 and 780. Each of the emitting parts 600, 700, 700A and 800 includes at least one emitting material layer and may further include an HIL, an HTL, an EBL, an HBL, an ETL and/or an EIL.

The second electrode 520 is disposed over the first substrate 402 above which the emissive layer 530 is disposed. The second electrode 520 may be disposed over a whole display area, and may include a conductive material with a relatively low work function value compared to the first electrode 510, and may be a cathode. For example, the second electrode 520 may include, but is not limited to, Al, Mg, Ca, Ag, alloy thereof or combination thereof such as Al—Mg.

Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light can be transmitted.

The color filter layer 480 is disposed over the OLED D and includes a red color filter 482, a green color filter 484 and a blue color filter 486 each of which is disposed correspondingly to the red pixel region RP, the green pixel region GP and the blue pixel region BP, respectively. Although not shown in FIG. 4, the color filter layer 480 may be attached to the OLED D through an adhesive layer. Alternatively, the color filter layer 480 may be disposed directly on the OLED D.

In addition, an encapsulation film may be disposed over the second electrode 520 in order to prevent outer moisture from penetrating into the OLED D. The encapsulation film may have, but is not limited to, a laminated structure of a first inorganic insulating film, an organic insulating film and a second inorganic insulating film (see, 170 in FIG. 2). In addition, a polarizing plate may be attached onto the second substrate 404 to reduce reflection of external light. For example, the polarizing plate may be a circular polarizing plate.

In FIG. 4, the light emitted from the OLED D is transmitted through the second electrode 520 and the color filter layer 480 is disposed over the OLED D. In other words, the organic light emitting display device 400 is a top-emission type. Alternatively, when the organic light emitting display device 400 is a bottom-emission type, the light emitted from the OLED D is transmitted through the first electrode 510 and the color filter layer 480 may be disposed between the OLED D and the first substrate 402.

In addition, a color conversion layer may be disposed between the OLED D and the color filter layer 480. The color conversion layer may include a red color conversion layer, a green color conversion layer and a blue color conversion layer each of which is disposed correspondingly to each pixel region (RP, GP and BP), respectively, so as to covert the white (W) color light to each of a red, green and blue color lights, respectively. For example, the color conversion layer may include quantum dot. The color conversion layer allows the organic light emitting display device 400 to have much enhanced color purity. Alternatively, the organic light emitting display device 400 may comprise the color conversion layer instead of the color filter layer 480.

As described above, the white (W) color light emitted from the OLED D is transmitted through the red color filter 482, the green color filter 484 and the blue color filter 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP, respectively.

FIG. 5 is a schematic cross-sectional view illustrating an organic light emitting diode having a tandem structure of two emitting parts. As illustrated in FIG. 5, the organic light emitting diode (OLED) D2 in accordance with the exemplary embodiment includes first and second electrodes 510 and 520 and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

The first electrode 510 may be an anode and may include a conductive material having relatively high work function value, for example, TCO. In an exemplary aspect, the first electrode 510 may include, but is not limited to, ITO, IZO, ITZO, SnO, ZnO, ICO, AZO, and the like. The second electrode 520 may be a cathode and may include a conductive material with a relatively low work function value. For example, the second electrode 520 may include, but is not limited to, Al, Mg, Ca, Ag, alloy thereof or combination thereof such as Al—Mg.

The first emitting part 600 comprises a first EML (EML1) 640. The first emitting part 600 may further comprise at least one of an HIL 610 disposed between the first electrode 510 and the EML1 640, a first HTL (HTL1) 620 disposed between the HIL 610 and the EML1 640 and a first ETL (ETL1) 660 disposed between the EML1 640 and the CGL 680. Alternatively, the first emitting part 600 may further comprise a first EBL (EBL1) 630 disposed between the HTL1 620 and the EML1 640 and/or a first HBL (HBL1) 650 disposed between the EML1 640 and the ETL1 660.

The second emitting part 700 comprise a second EML (EML2) 740. The second emitting part 700 may further comprise at least one of a second HTL (HTL2) 720 disposed between the CGL 680 and the EML2 740, a second ETL (ETL2) 760 disposed between the second electrode 520 and the EML2 740 and an EIL 770 disposed between the second electrode 520 and the ETL2 760. Alternatively, the second emitting part 700 may further comprise a second EBL (EBL2) 730 disposed between the HTL2 720 and the EML2 740 and/or a second HBL (HBL2) 750 disposed between the EML2 740 and the ETL2 760.

At least one of the EML1 640 and the EML2 740 may comprise the organic metal compound having the structure of Formulae 1 to 6 to emit red color. The other of the EML1 640 and the EML2 740 may emit a blue color so that the OLED D2 can realize white (W) emission. Hereinafter, the OLED D2 where the EML2 740 includes the organic metal compound having the structure of Formulae 1 to 6 will be described in detail.

The HIL 610 is disposed between the first electrode 510 and the HTL1 620 and improves an interface property between the inorganic first electrode 510 and the organic HTL1 620. In one exemplary embodiment, the HIL 610 may include, but is not limited to, MTDATA, NATA, 1T-NATA, 2T-NATA, CuPc, TCTA, NPB (NPD), HAT-CN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, NPNPB and combination thereof. The HIL 610 may be omitted in compliance of the OLED D2 property.

Each of the HTL1 620 and the HTL2 720 may comprise, but is not limited to, TPD, NPB (NPD), DNTPD, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and combination thereof, respectively.

Each of the ETL1 660 and the ETL2 760 facilitates electron transportation in each of the first emitting part 600 and the second emitting part 700, respectively. As an example, each of the ETL1 660 and the ETL2 760 may independently comprise, but is not limited to, at least one of oxadiazole-based compounds, triazole-based compounds, phenanthroline-based compounds, benzoxazole-based compounds, benzothiazole-based compounds, benzimidazole-based compounds, triazine-based compounds, and the like. For example, each of the ETL1 660 and the ETL2 770 may comprise, but is not limited to, Alq3, BAlq, Liq, PBD, spiro-PBD, TPBi, Bphen, NBphen, BCP, TAZ, NTAZ, TpPyPB, TmPPPyTz, PFNBr, TPQ, TSPO1, ZADN and combination thereof, respectively.

The EIL 770 is disposed between the second electrode 520 and the ETL2 760, and can improve physical properties of the second electrode 520 and therefore, can enhance the lifetime of the OLED D2. In one exemplary aspect, the EIL 770 may comprise, but is not limited to, an alkali metal halide and/or an alkaline earth metal halide such as LiF, CsF, NaF, BaF₂ and the like, and/or an organic metal compound such as Liq, lithium benzoate, sodium stearate, and the like.

Each of the EBL1 630 and the EBL2 730 may independently comprise, but is not limited to, TCTA, Tri s[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and combination thereof, respectively.

Each of the HBL1 650 and the HBL2 750 may comprise, but is not limited to, at least one of oxadiazole-based compounds, triazole-based compounds, phenanthroline-based compounds, benzoxazole-based compounds, benzothiazole-based compounds, benzimidazole-based compounds, and triazine-based compounds each of which can be used in the ETL1 660 and the ETL2 760. For example, each of the HBL1 650 and the HBL2 750 may independently comprise, but is not limited to, Alq3, BAlq, Liq, PBD, spiro-PBD, BCP, B3PYMPM, DPEPO, 9-(6-(9H-carbazol-9-yl)pyridine-3-yl)-9H-3,9′-bicarbazole, TSPO1 and combination thereof, respectively.

The CGL 680 is disposed between the first emitting part 600 and the second emitting part 700. The CGL 680 includes an N-type CGL (N-CGL) 685 disposed adjacently to the first emitting part 600 and a P-type CGL (P-CGL) 690 disposed adjacently to the second emitting part 700. The N-CGL 685 transports electrons to the EML1 640 of the first emitting part 600 and the P-CGL 690 transport holes to the EML2 740 of the second emitting part 700.

The N-CGL 685 may be an organic layer doped with an alkali metal such as Li, Na, K and Cs and/or an alkaline earth metal such as Mg, Sr, Ba and Ra. The host in the N-CGL 685 may comprise, but is not limited to, Bphen and MTDATA. The contents of the alkali metal or the alkaline earth metal in the N-CGL 685 may be between about 0.01 wt % and about 30 wt %.

The P-CGL 690 may comprise, but is not limited to, inorganic material selected from the group consisting of WOₓ, MoOₓ, V₂O₅ and combination thereof and/or organic material selected from the group consisting of NPD, HAT-CN, F4TCNQ, TPD, N,N,N′,N′-tetranaphthalenyl-benzidine (TNB), TCTA, N,N′-dioctyl-3,4,9,10-perylenedicarboximide (PTCDI-C8) and combination thereof.

The EML1 640 may be a blue EML. In this case, the EML1 640 may be a blue EML, a sky-blue EML or a deep-blue EML. The EML1 640 may include a host and a blue dopant. The host may be identical to the first host and the blue dopant may comprise at least one of blue phosphorescent material, blue fluorescent material and blue delayed fluorescent material.

The EML2 740 may comprise a lower EML 740A disposed between the EBL2 730 and the HBL2 750 and an upper EML 740B disposed between the lower EML 740A and the HBL2 750. One of the lower EML 740A and the upper EML 740B may emit red color and the other of the lower EML 740A and the upper EML 740B may emit green color. Hereinafter, the EML2 740 where the lower EML 740A emits red color and the upper EML 740B emits green color will be described in detail.

The lower EML 740A includes a first host and a first dopant 742. The first host may comprise, but is not limited to, mCP-CN, CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, BCzPh, TCP, TCTA, CDBP, DMFL-CBP, Spiro-CBP, TCz1 and combination thereof. The first dopant 742 may include the organic metal compound having the structure of Formulae 1 to 6 to emit red color. For example, the contents of the first dopant 742 in the lower EML 740A may be between about 1 wt % to about 50 wt %, for example, about 1 wt % and about 30 wt %.

The upper EML 740B includes a host and a green dopant. The host may be identical to the first host and the green dopant may comprise at least one of green phosphorescent material, green florescent material and green delayed fluorescent material.

The OLED D2 in accordance with this aspect has a tandem structure and includes the organic metal compound having the structure of Formulae 1 to 6. The OLED D2 including the organic metal compound with excellent thermal property, a rigid chemical conformation and adjustable luminescent colors can lower its driving voltage and improve its luminous efficiency and luminous lifespan.

The OLED may have three or more emitting parts to form a tandem structure. FIG. 6 is a schematic cross-sectional view illustrating an organic light emitting diode in accordance with still another exemplary aspect of the present disclosure. As illustrated in FIG. 6, the organic light emitting diode (OLED) D3 includes first and second electrodes 510 and 520 facing each other and an emissive layer 530A disposed between the first and second electrodes 510 and 520. The emissive layer 530A includes a first emitting part 600 disposed between the first and second electrodes 510 and 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

The first emitting part 600 comprise a first EML (EML1) 640. The first emitting part 600 may further comprise at least one of an HIL 610 disposed between the first electrode 510 and the EML1 640, a first HTL (HTL1) 620 disposed between the HIL 610 and the EML1 640 and a first ETL (ETL1) 660 disposed between the EML1 640 and the CGL 680. Alternatively, the first emitting part 600 may further comprise a first EBL (EBL1) 630 disposed between the HTL1 620 and the EML1 640 and/or a first HBL (HBL1) 650 disposed between the EML1 640 and the ETL1 660.

The second emitting part 700A comprise a second EML (EML2) 740. The second emitting part 700A may further comprise at least one of a second HTL (HTL2) 720 disposed between the CGL1 680 and the EML2 740 and a second ETL (ETL2) 760 disposed between the second electrode 520 and the EML2 740. Alternatively, the second emitting part 700A may further comprise a second EBL (EBL2) 730 disposed between the HTL2 720 and the EML2 740 and/or a second HBL (HBL2) 750 disposed between the EML2 740 and the ETL2 760.

The third emitting part 800 comprise a third EML (EML3) 840. The third emitting part 800 may further comprise at least one of a third HTL (HTL3) 820 disposed between the CGL2 780 and the EML3 840, a third ETL (ETL3) 860 disposed between the second electrode 520 and the EML3 840 and an EIL 870 disposed between the second electrode 520 and the ETL3 860. Alternatively, the third emitting part 800 may further comprise a third EBL (EBL3) 830 disposed between the HTL3 820 and the EML3 840 and/or a third HBL (HBL3) 850 disposed between the EML3 840 and the ETL3 860.

At least one of the EML1 640, the EML2 740 and the EML3 840 may comprise the organic metal compound having the structure of Formulae 1 to 6. For example, one of the EML1 640, the EML2 740 and the EML3 840 may emit red color. In addition, another two of the EML1 640, the EML2 740 and the EML3 840 emit a blue color so that the OLED D3 can realize white emission. Hereinafter, the OLED where the EML2 740 includes the organic metal compound having the structure of Formulae 1 to 6 to emit red color and each of the EML1 640 and the EML3 840 emits a blue light will be described in detail.

The CGL1 680 is disposed between the first emitting part 600 and the second emitting part 700A and the CGL2 780 is disposed between the second emitting part 700A and the third emitting part 800. The CGL1 680 includes a first N-type CGL (N-CGL1) 685 disposed adjacently to the first emitting part 600 and a first P-type CGL (P-CGL1) 690 disposed adjacently to the second emitting part 700A. The CGL2 780 includes a second N-type CGL (N-CGL2) 785 disposed adjacently to the second emitting part 700A and a second P-type CGL (P-CGL2) 790 disposed adjacently to the third emitting part 800. Each of the N-CGL1 685 and the N-CGL2 785 transports electrons to the EML1 640 of the first emitting part 600 and the EM1L2 740 of the second emitting part 700A, respectively, and each of the P-CGL1 690 and the P-CGL2 790 transport holes to the EML2 740 of the second emitting part 700A and the EML3 840 of the third emitting part 800, respectively.

Each of the EML1 640 and the EML3 840 may be independently a blue EML. In this case, each of the EML1 640 and the EML3 840 may be independently a blue EML, a sky-blue EML or a deep-blue EML. Each of the EML1 640 and the EML3 840 may include independently a host and a blue dopant. The host may be identical to the first host and the blue dopant may comprise at least one of blue phosphorescent material, blue fluorescent material and blue delayed fluorescent material. In one exemplary aspect, the blue dopant in the EML1 640 may have different color and luminous efficiency from the blue dopant in the EML3 840.

The E-L2 740 may comprise a lower EML 740A disposed between the EBL2 730 and the HBL2 750 and an upper EML 740B disposed between the lower EML 740A and the HBL2 750. One of the lower EML 740A and the upper EML 740B may emit red color and the other of the lower EML 740A and the upper EML 740B may emit green color. Hereinafter, the EML2 740 where the lower EML 740A emits red color and the upper EML 740B emits green color will be described in detail.

The lower EML 740A may include a first host and a first dopant 742. As an example, the first dopant 742 includes the organic metal compound having the structure of Formulae 1 to 6 to emit red color. For example, the contents of the first dopant 742 in the lower EML 740A may be between about 1 wt % to about 50 wt %, for example, about 1 wt % and about 30 wt %.

The upper EML 740B includes a host and a green dopant. The host may be identical to the first host and the green dopant may include at least one of green phosphorescent material, green fluorescent material and green delayed fluorescent material.

The OLED D3 in accordance with this aspect includes the organic metal compound having the structure of Formulae 1 to 6 in at least one emitting material layer. The organic metal compound can maintain its stable chemical conformations in the luminescent process. The OLED including the organic metal compound and having three emitting parts can realize white luminescence with improved luminous efficiency, color purity and luminous lifespan.

### Synthesis Example 1: Synthesis of Compound 1

(1) Synthesis of Intermediate A-1

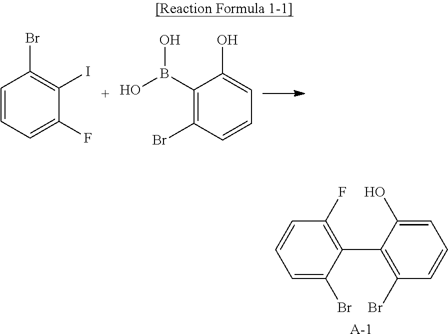

1-bromo-3-fluoro-2-iodobenzene (100 g, 332.35 mmol), 2-bromo-6-hydroxyphenyl boronic acid (72.1 g, 332.35 mmol), Na₂SO₄ (141.6 g, 997.04 mmol) dissolved in THE (1000 ml) were put into a reaction vessel, Pd(PPh₃)₄ (tetrakis(triphenylphosphine)palladium(0), 19.2 g, 16.62 mmol) was added into the reaction vessel, and then the solution was stirred at 80° C. for 12 hours. After the reaction was complete, the temperature of the solution was cooled to room temperature (RT), and an organic layer was extracted with toluene. MgSO₄ was put into the organic layer, and the organic layer was filtered. The filtrate was distilled under reduced pressure, and then the mixture was recrystallized with chloroform/ethanol to give the Intermediate A-1 (60.9 g, yield: 53%).

MS (m/z): 343.88

(2) Synthesis of Intermediate A-2

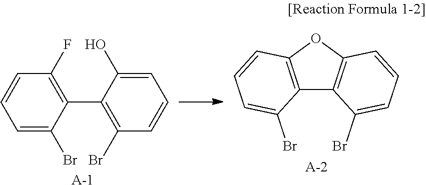

The Intermediate A-1 (60.9 g, 176.02 mmol) dissolved in DMF (400 ml) was put into a reaction vessel, K₂CO₃ (69.8 g, 528.05 mmol) was added into the reaction vessel, and then the solution was stirred at 100° C. for 1 hour. After the reaction was complete, the temperature of the solution was cooled to RT, and ethanol (100 ml) was added slowly into the solution. After the mixture was distilled under reduced pressure, then the mixture was recrystallized with chloroform/ethyl acetate to give the Intermediate A-2 (43.0 g, yield: 75%).

MS (m/z): 323.88

(3) Synthesis of Intermediate A-3

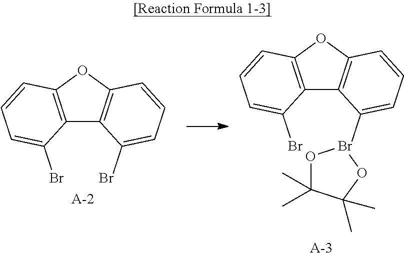

The Intermediate A-2 (40 g, 122.71 mmol), bis(pinacolato)diboron (35.0 g, 147.25 mmol), Pd(dppf)Cl₂ ([1,1′-bis(diphenylphosphino)ferrocene]palladium(II)dichloride, 4.5 g, 6.14 mmol), KOAc (36.1 g, 368.12 mmol) dissolved in 1,4-dioxane (500 ml) were put into a reaction vessel, and then the solution was stirred at 100° C. for 4 hours. The temperature of the reactants was cooled to RT, an organic layer were extracted with ethyl acetate, water in the organic layer was removed with MgSO₄, and then the organic layer was filtered and treated under reduced pressure to remove the solvent. A crude product was purified with column chromatography (eluent: hexane and ethyl acetate) to give the Intermediate A-3 (35.7 g, yield: 78%).

MS (m/z): 372.05

(4) Synthesis of Intermediate A-4

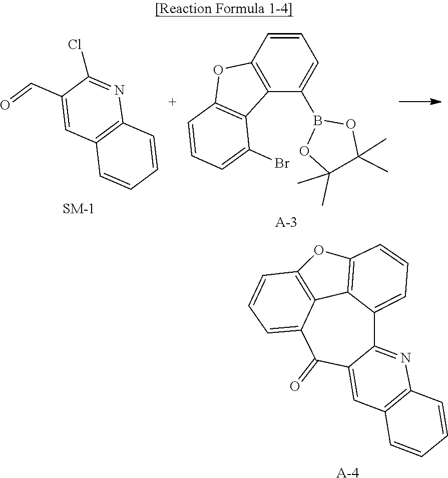

Compound SM-1 (10.0 g, 52.19 mmol), the Intermediate A-3 (23.4 g, 62.63 mmol), Pd(OAc)₂ (Palladium(II) acetate, 1.2 g, 10 mol %), PPh₃ (triphenylphosphine, 6.8 g, 26.09 mmol), NaOAc (17.1 g, 208.76 mmol) dissolved in DMF (200 ml) were put into a reaction vessel, and then the solution was stirred at 120° C. for 16 hours. After the reaction was complete, the temperature of the solution was cooled to RT, an organic layer was extracted with ethyl acetate, water in the organic layer was removed with MgSO₄, and then the organic layer was filtered and treated under reduced pressure to remove the solvent. A crude product was purified with column chromatography (eluent: ethyl acetate and hexane) to give the Intermediate A-4 (10.6 g, yield: 63%).

MS (m/z): 321.08

(5) Synthesis of Intermediate A-5

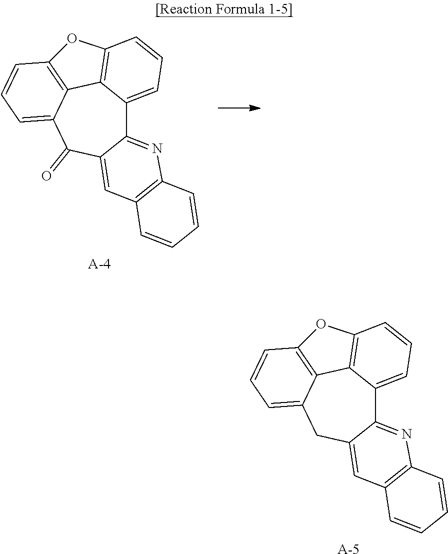 [SMILES: O=c1c2cc3ccccc3nc2c2cccc3oc4cccc1c4c32 ; "A-4" ; c1ccc2nc3c(cc2c1)Cc1cccc2oc4cccc-3c4c12 ; "A-5"]

The Intermediate A-4 (10.6 g, 32.99 mmol) dissolved in diethyl ether (200 ml) was put into a reaction vessel, and then AlCl₃ (5.3 g, 39.59 mmol) was added slowly into the reaction vessel. After the solution was stirred for 15 minutes, cooled to 0° C., LAH (lithium aluminum hydride, 1.9 g, 49.48 mmol) was added slowly into the reaction vessel, and then the reactants ware stirred at 50° C. for 1 hour. The temperature of the reactants was cooled to RT, ethyl acetate was added slowly into the reactants, and then HCl (200 ml) was added into the reactants. An organic layer was extracted with ethyl acetate, water in the organic layer was removed with MgSO₄, and then the organic layer was filtered and treated under reduced pressure to remove the solvent. A crude product was purified with column chromatography (eluent: ethyl acetate and hexane) to give the Intermediate A-5 (9.1 g, yield: 90%).

MS (m/z): 307.1

(6) Synthesis of Intermediate A-6

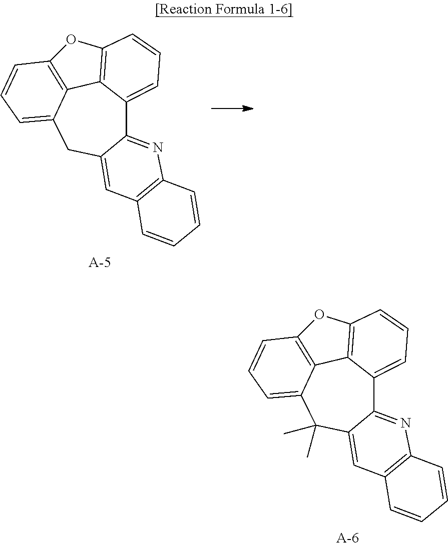 [SMILES: c1ccc2nc3c(cc2c1)Cc1cccc2oc4cccc-3c4c12 ; "A-5" ; CC1(C)c2cc3ccccc3nc2-c2cccc3oc4cccc1c4c23 ; "A-6"]

The Intermediate A-5 (9.1 g, 29.61 mmol) dissolved in DMSO (200 ml) was put into a reaction vessel, sodium tert-butoxide (21.3 g, 227.07 mmol) was added into the reaction vessel at RT, and then the solution was stirred at 70° C. for 15 minutes. Methyl iodide (33.6 g, 236.87 mmol) was added slowly into the reaction vessel, and then the solution was stirred again for 1 hour. After the reaction was complete, the temperature of the solution was cooled to RT, distilled water added into the solution, the solution was stirred for 20 minutes to produce a solid, and then the solid was filtered. The filtrate was recrystallized with methanol and acetone to give the Intermediate A-6 (5.3 g, yield: 53%).

MS (m/z): 335.13

(7) Synthesis of Intermediate A-7

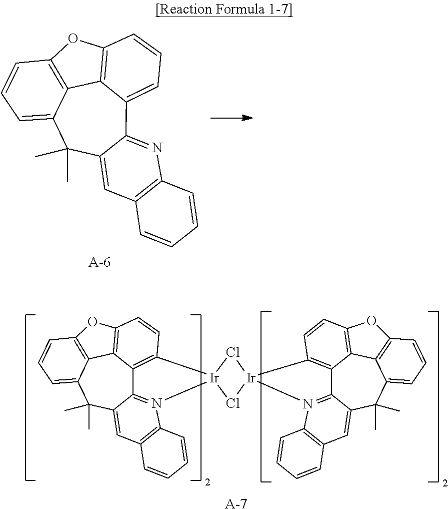

The Intermediate A-6 (5 g, 14.9 mmol) dissolved in 2-ethoxyethanol (100 ml) and distilled water (30 ml) was put into a reaction vessel, the solution was bubbled with nitrogen for 1 hour, IrCl₃—H₂O (2.1 g, 6.78 mmol) was added into the reaction vessel, and then the solution was refluxed for 2 days. After the reaction was complete, the temperature of the solution was cooled to RT slowly to produce a solid, and then the solid was filtered. The filtered solid was washed with hexane and methanol and then dried to give the Intermediate A-7 (2.1 g, yield: 34%).

(8) Synthesis of Compound 1

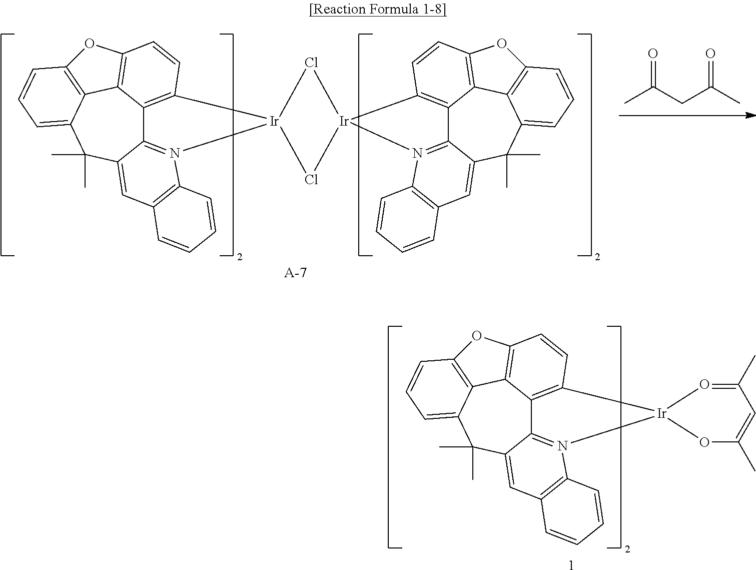

The Intermediate A-7 (2.1 g, 1.2 mmol), acetylacetone (1.2 g, 11.71 mmol), Na₂CO₃ (2.5 g, 23.4 mmol) dissolved in 2-ethoxyethanol (100 ml) were put into a reaction vessel, and then the solution was stirred slowly for 24 hours. After the reaction was complete, dichloromethane was added into the reactants to dissolve a product, and then an organic layer was extracted with dichloromethane and water. Water in the organic layer was removed with MgSO₄, and then the organic layer was filtered and treated under reduced pressure to remove the solvent. A crude product was purified with column chromatography (eluent: hexane and dichloromethane) to give Compound 1 (1.2 g, yield: 55%).

MS (m/z): 960.25

### Synthesis Example 2: Synthesis of Compound 52

(1) Synthesis of Intermediate B-1

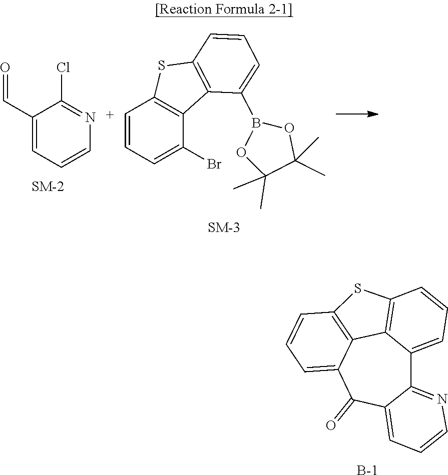

The Intermediate B-1 (14.4 g, yield 71%) was obtained with the same synthetic process of the Intermediate A-4, except that the Compound SM-2 (10.0 g, 70.64 mmol) and the Compound SM-3 (33.0 g, 84.77 mmol) were used as reactants instead of the Compound SM-1 (10.0 g, 52.19 mmol) and the Intermediate A-3 (23.4 g, 62.63 mmol).

MS (m/z): 287.04

(2) Synthesis of Intermediate B-2

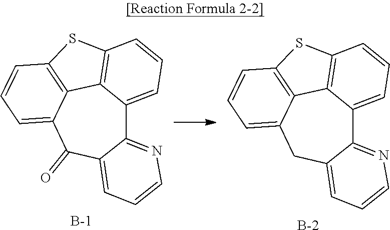

The Intermediate B-2 (12.9 g, yield: 94%) was obtained with the same synthetic process of the Intermediate A-5, except that the Intermediate B-1 (14.4 g, 50.16 mmol) was used as a reactant instead of the Intermediate A-4 (10.6 g, 32.99 mmol).

MS (m/z): 273.06

(3) Synthesis of Intermediate B-3

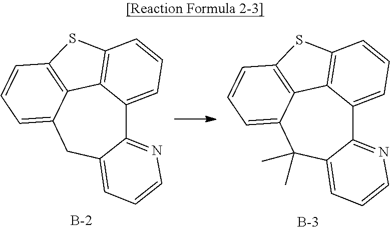

The Intermediate B-3 (7.8 g, yield: 55%) was obtained with the same synthetic process of the Intermediate A-6, except that the Intermediate B-2 (12.9 g, 47.15 mmol) was used as a reactant instead of the Intermediate A-5 (9.1 g, 29.61 mmol).

MS (m/z): 301.09

(4) Synthesis of Intermediate B-4

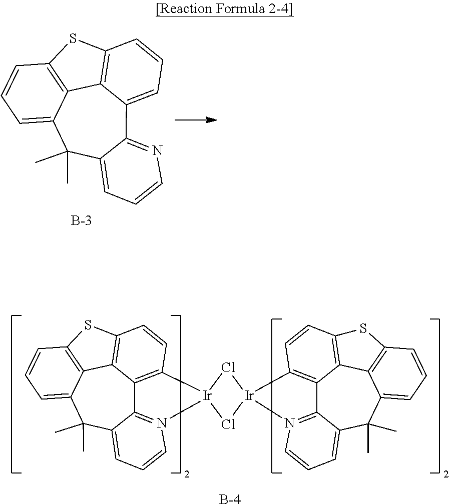

The Intermediate B-4 (2.9 g, yield: 47%) was obtained with the same synthetic process of the Intermediate A-7, except that the Intermediate B-3 (5 g, 16.59 mmol) was used as a reactant instead of the Intermediate A-6 (5 g, 14.9 mmol).

(5) Synthesis of Compound 52

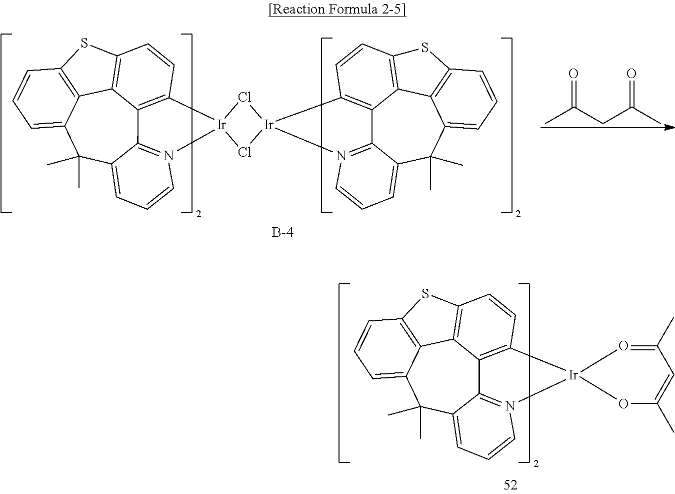

Compound 52 (1.6 g, yield: 51%) was obtained with the same synthetic process of the Compound 1, except that the Intermediate B-4 (2.9 g, 1.77 mmol) was used as a reactant instead of the Intermediate A-7 (2.1 g, 1.2 mmol).

MS (m/z): 892.18

### Synthesis Example 3: Synthesis of Compound 53

(1) Synthesis of Intermediate C-1

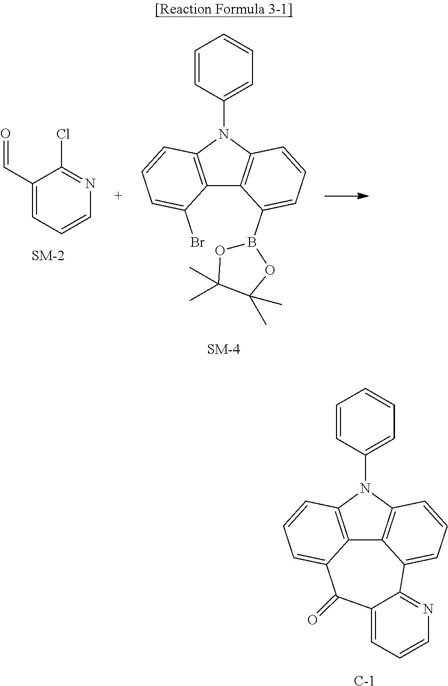

The Intermediate C-1 (18.8 g, yield 77%) was obtained with the same synthetic process of the Intermediate A-4, except that the Compound SM-2 (10.0 g, 70.64 mmol) and the Compound SM-4 (38.0 g, 84.77 mmol) were used as reactants instead of the Compound SM-1 (10.0 g, 52.19 mmol) and the Intermediate A-3 (23.4 g, 62.63 mmol).

MS (m/z): 346.11

(2) Synthesis of Intermediate C-2

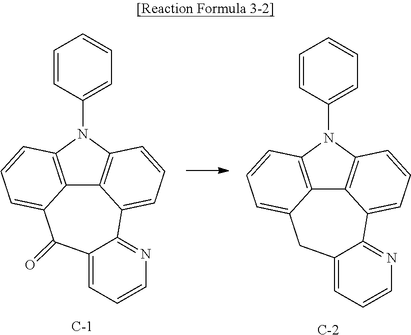

The Intermediate C-2 (16.5 g, yield: 91%) was obtained with the same synthetic process of the Intermediate A-5, except that the Intermediate C-1 (18.8 g, 54.39 mmol) was used as a reactant instead of the Intermediate A-4 (10.6 g, 32.99 mmol).

MS (m/z): 332.13

(3) Synthesis of Intermediate C-3

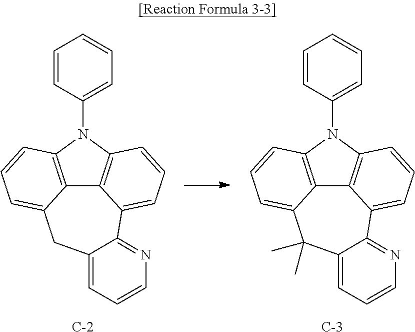

The Intermediate C-3 (8.6 g, yield: 48%) was obtained with the same synthetic process of the Intermediate A-6, except that the Intermediate C-2 (16.5 g, 49.50 mmol) was used as a reactant instead of the Intermediate A-5 (9.1 g, 29.61 mmol).

MS (m/z): 360.16

(4) Synthesis of Intermediate C-4

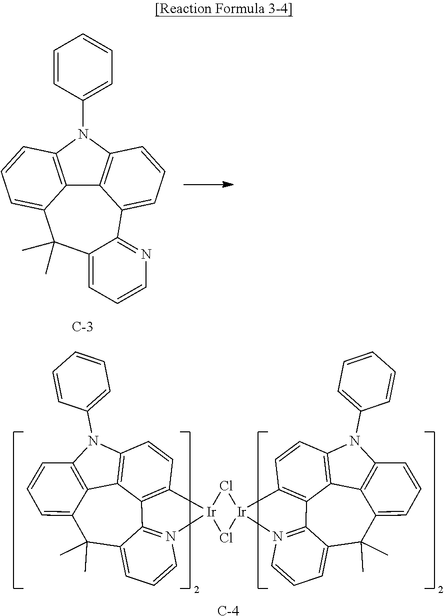

The Intermediate C-4 (3.1 g, yield: 52%) was obtained with the same synthetic process of the Intermediate A-7, except that the Intermediate C-3 (5 g, 13.9 mmol) was used as a reactant instead of the Intermediate A-6 (5 g, 14.9 mmol).

(5) Synthesis of Compound 53

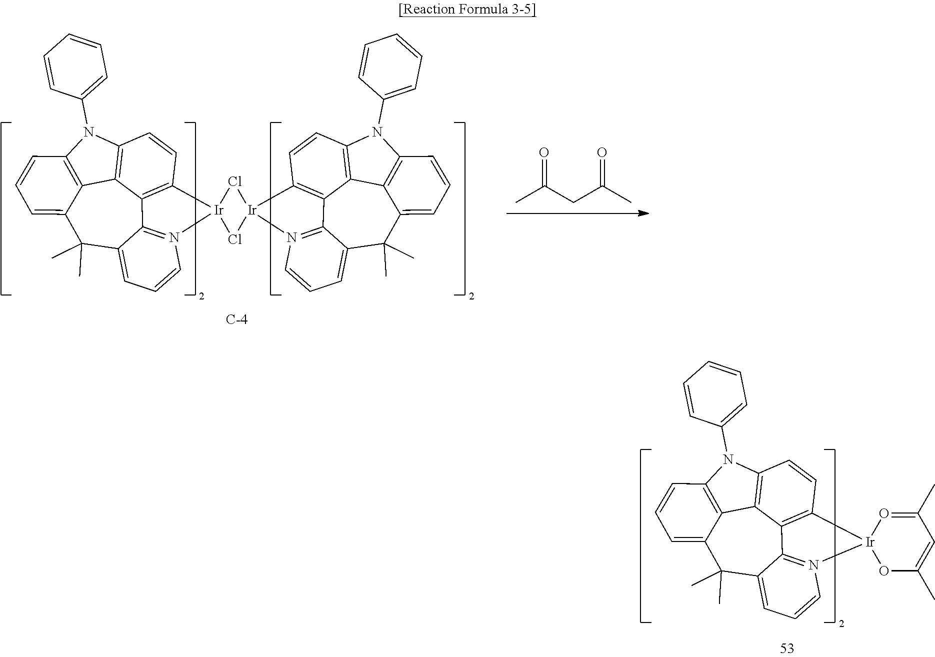

Compound 53 (1.6 g, yield: 49%) was obtained with the same synthetic process of the Compound 1, except that the Intermediate C-4 (3.1 g, 1.64 mmol) was used as a reactant instead of the Intermediate A-7 (2.1 g, 1.2 mmol).

MS (m/z): 1010.32

### Synthesis Example 4: Synthesis of Compound 86

(1) Synthesis of Intermediate D-1

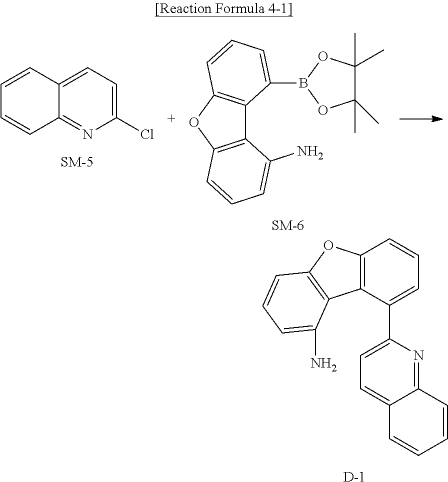

The Compound SM-5 (10.0 g, 61.12 mmol), the Compound SM-6 (22.7 g, 67.24 mmol), Pd(OAc)₂ (0.7 g, 3.06 mol), PPh₃ (3.2 g, 12.22 mmol), K₂CO₃ (25.3 g, 183.37 mmol) dissolved in 1,4-dioxane (150 ml) and water (150 ml) were put into a reaction vessel, and then the solution was stirred at 100° C. for 12 hours. After the reaction was complete, the temperature of the solution was cooled to RT, an organic layer was extracted with ethyl acetate, water in the organic layer was removed with MgSO₄, and then the organic layer was filtered and treated under reduce pressure to remove the solvent. A crude product was purified with column chromatography (eluent: hexane and ethyl acetate) to give the Intermediate D-1 (12.9 g, yield: 68%).

MS (m/z): 310.11

(2) Synthesis of Intermediate D-2

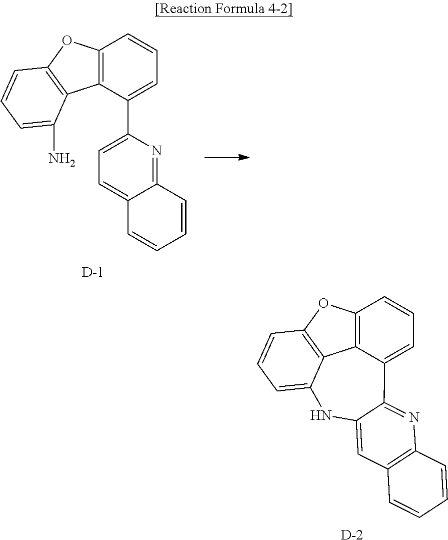

The Intermediate D-1 (12.9 g, 41.56 mmol) dissolved in DMSO (200 ml) was put into a reaction vessel, CuI (11.9 g, 62.35 mmol) was put into the reaction vessel, and then the solution was refluxed at 150° C. for 12 hours. After the reaction was complete, the solution was filtered, an organic layer was extracted with ethyl acetate, water in the organic layer was removed with MgSO₄, and then the organic layer was filtered and treated under reduced pressure to remove the solvent. A crude product was purified with column chromatography (eluent: hexane and ethyl acetate) to give the Intermediate D-2 (4.7 g, yield: 37%).

MS (m/z): 308.09

(3) Synthesis of Intermediate D-3

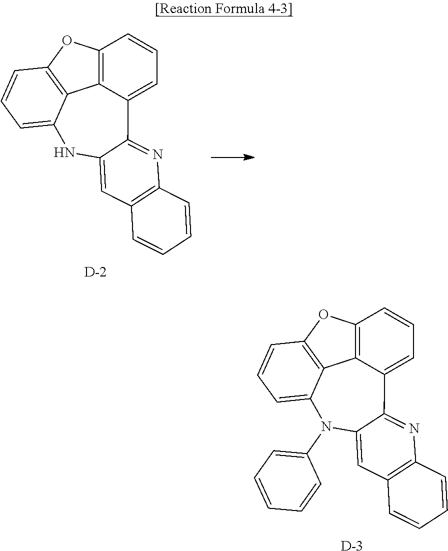

The Intermediate D-2 (4.7 g, 15.38 mmol), 1-iodobenzene (3.4 g, 16.77 mmol) dissolved in toluene (200 ml) were put into a reaction vessel, Pd₂(dba)₃ (Tris(dibenzylideneacetone)dipalladium(0), 0.7 g, 0.76 mmol), P(t-Bu)₃ (0.3 g, 1.52 mmol) and NaOt-Bu (2.9 g, 30.49 mmol) were added into the reaction vessel, and then the solution was refluxed at 100° C. for 24 hours. After the reaction was complete, an organic layer was extracted with ethyl acetate, water in the organic layer was removed with MgSO₄, and then the organic layer was filtered and treated under reduced pressure to remove the solvent. A crude product was purified with column chromatography (eluent: hexane and ethyl acetate) to give the Intermediate D-3 (5.0 g, yield: 85%).

MS (m/z): 384.13

(4) Synthesis of Intermediate D-4

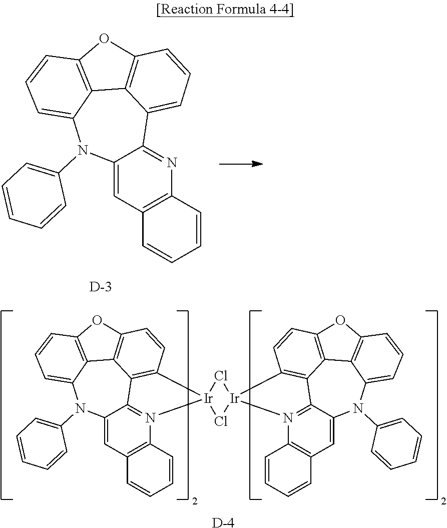

The Intermediate D-4 (2.6 g, yield: 44%) was obtained with the same synthetic process of the Intermediate A-7, except that the Intermediate D-3 (5 g, 13.01 mmol) was used as a reactant instead of the Intermediate A-6 (5 g, 14.9 mmol).

(5) Synthesis of Compound 86

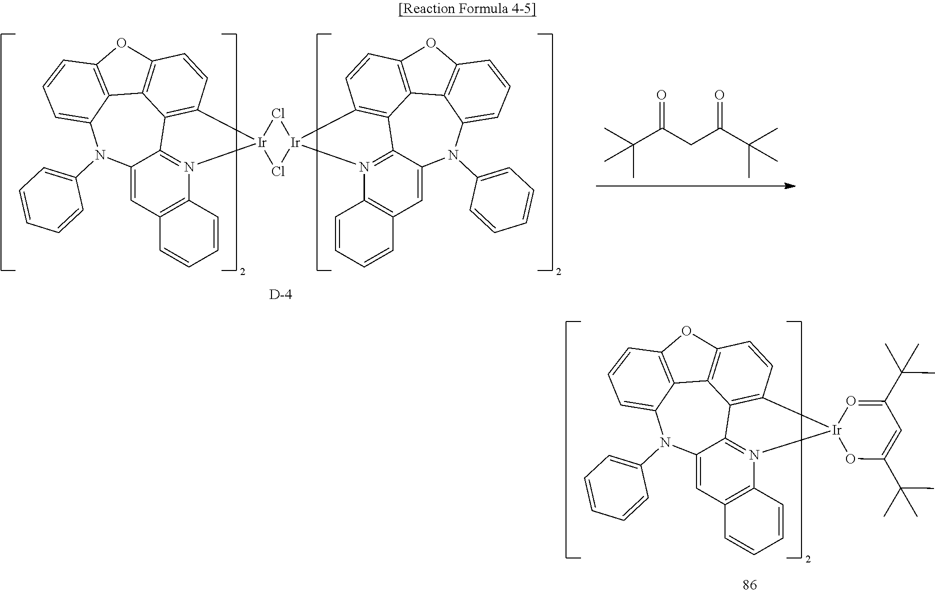

Compound 86 (1.4 g, yield: 47%) was obtained with the same synthetic process of the Compound 1, except that the Intermediate D-4 (3.5 g, 1.97 mmol) and 2,2,6,6-tetramethylheptane-3,5-dione (3.6 g, 19.65 mmol) were used as reactants instead of the Intermediate A-7 (2.1 g, 1.2 mmol) and acetylacetone (1.2 g, 11.71 mmol).

MS (m/z): 1142.34

### Synthesis Example 5: Synthesis of Compound 101

(1) Synthesis of Intermediate E-1

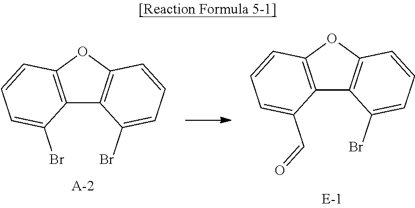

The Intermediate A-2 (50 g, 153.38 mmol) dissolved in THF/diethyl ether (1:1, 500 ml) was put into a reaction vessel, the temperature of the reaction vessel was cooled to −100° C., and then 2.5 M n-BuLi (153.38 mmol) was added slowly into the solution. After keeping the temperature for 30 minutes, N,N-dimethylformamide (207.4 g, 2.8 mol) was added slowly into the reaction vessel, and then the solution was stirred at −80° C. for 2 hours. HCl/EtOH (1:3, 500 ml) was added slowly into the solution to terminate the reaction, and then the reactants were put into HCl/EtOH (1:5, 2000 ml). An organic layer was extracted with diethyl ether, MgSO₄ was put into the organic layer, the organic layer was filtered, and then the filtrate was distilled under reduced pressure. A mixture was purified with column chromatography (eluent: hexane/CH₂Cl₂) to give the Intermediate E-1 (19.4 g, yield: 46%).

MS (m/z): 273.96

(2) Synthesis of Intermediate E-2

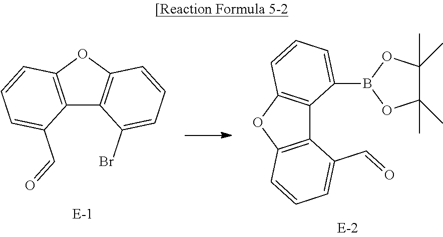 [SMILES: O=Cc1cccc2oc3cccc(Br)c3c12 ; CC1(C)OB(c2cccc3oc4cccc(C=O)c4c23)OC1(C)C]

The Intermediate E-2 (13.6 g, yield: 60%) was obtained with the same synthetic process of the Intermediate A-3, except that the Intermediate E-1 (19.4 g, 70.56 mmol) was used as a reactant instead of the Intermediate A-2 (40 g, 122.71 mmol).

MS (m/z): 322.14

(3) Synthesis of Intermediate E-3

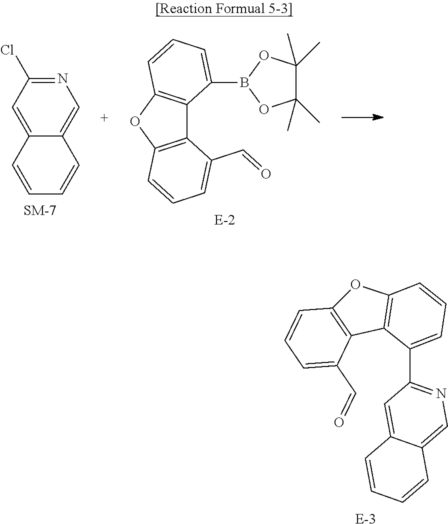

The Intermediate E-3 (15.4 g, yield: 78%) was obtained with the same synthetic process of the Intermediate D-1, except that the Compound SM-7 (10.0 g, 61.12 mmol) and the Intermediate E-2 (21.7 g, 67.24 mmol) were used as reactants instead of the Compound SM-5 (10.0 g, 61.12 mmol) and the Compound SM-6 (22.7 g, 67.24 mmol).

MS (m/z): 323.09

(4) Synthesis of Intermediate E-4

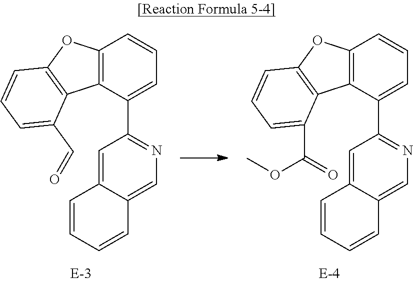 [SMILES: O=Cc1cccc2oc3cccc(-c4cc5ccccc5cn4)c3c12 ; COC(=O)c1cccc2oc3cccc(-c4cc5ccccc5cn4)c3c12]

The Intermediate E-3 (15.4 g, 47.63 mmol) dissolved in methanol (200 ml) was put into a reaction vessel, and then I₂ (12.1 g, 47.63 mmol) was added into the solution with stirring. After 12 was dissolved, NaNO₂ (3.3 g, 47.63 mmol) dissolved in H₂O (50 ml) was added into the solution, then the solution was stirred at RT for 10 minutes. After stirring at 70° C. for 18 hours to complete the reaction, the temperature of the solution was cooled to RT and the solution was washed with 1M NaS₂O₃. An organic layer was extracted with CHCl₃, water in the organic layer was removed with MgSO₄, and then the organic layer was filtered and treated under reduced pressure to remove the solvent. A crude product was purified with column chromatography (eluent: hexane and ethyl acetate) to give the Intermediate E-4 (16.3 g, yield: 97%).

MS (m/z): 353.11

(5) Synthesis of Intermediate E-5

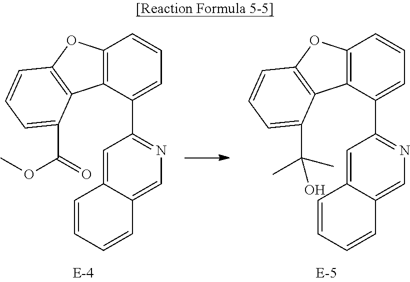 [SMILES: COC(=O)c1cccc2oc3cccc(-c4cc5ccccc5cn4)c3c12 ; CC(C)(O)c1cccc2oc3cccc(-c4cc5ccccc5cn4)c3c12]

The Intermediate E-4 (16.3 g, 46.13 mmol) dissolved in THE (500 ml) was put into a reaction vessel, CH₃MgBr (27.5 g, 230.64 mmol) was added slowly into the solution, and then the solution was stirred for 12 hours. After the reaction was complete, an organic layer was extracted with ethyl acetate, water in the organic layer was removed with MgSO₄, and then the organic layer was filtered and treated under reduced pressure to remove the solvent. A crude product was purified with column chromatography (eluent: hexane and ethyl acetate) to give the Intermediate E-5 (8.0 g, yield: 49%).

MS (m/z): 353.14

(6) Synthesis of Intermediate E-6

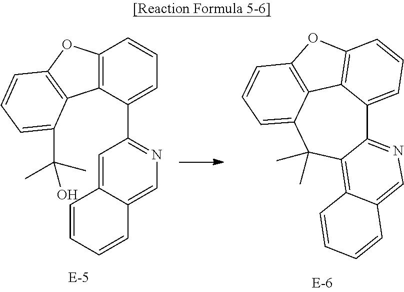 [SMILES: CC(C)(O)c1cccc2oc3cccc(-c4cc5ccccc5cn4)c3c12 ; CC1(C)c2c(ncc3ccccc23)-c2cccc3oc4cccc1c4c23]

The Intermediate E-5 (8.0 g, 22.64 mmol) dissolved in a mixed aqueous solution (100 ml) of acetic acid and sulfuric acid put into a reaction vessel, and the solution was refluxed for 16 hours. After the reaction was complete, the temperature of the solution was cooled to RT, and then the reactants were added dropwise slowly into iced sodium hydroxide aqueous solution. An organic layer was extracted with ethyl acetate, water in the organic layer was removed with MgSO₄, and then the organic layer was filtered and treated under reduced pressure to remove the solvent. A crude product was recrystallized with toluene and ethanol to give the Intermediate E-6 (3.6 g, yield: 48%).

MS (m/z): 335.13

(7) Synthesis of Intermediate E-7

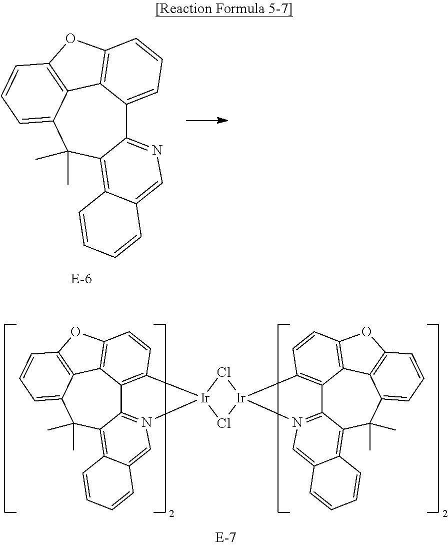

The Intermediate E-7 (3.5 g, yield: 58%) was obtained with the same synthetic process of the Intermediate A-7, except that the Intermediate E-6 (5 g, 14.9 mmol) was used as a reactant instead of the Intermediate A-6 (5 g, 14.9 mmol).

(8) Synthesis of Compound 101

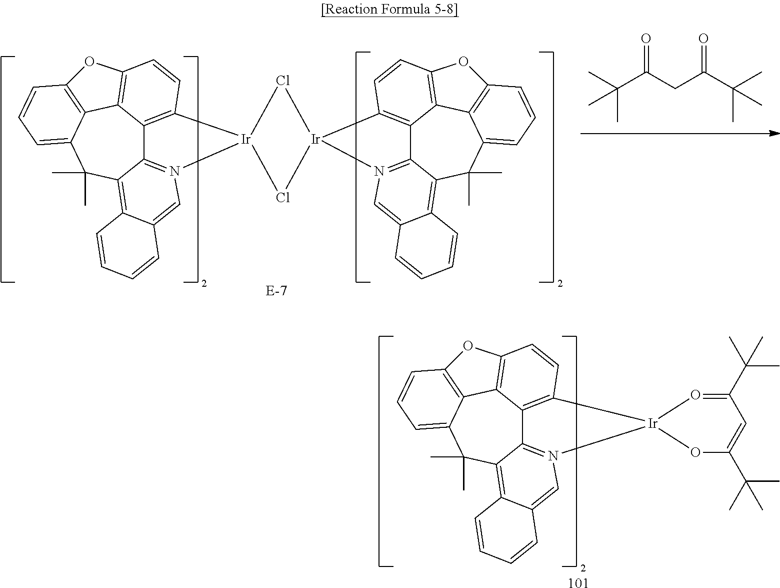

Compound 101 (2.0 g, yield: 50%) was obtained with the same synthetic process of the Compound 1, except that the Intermediate E-7 (3.5 g, 1.97 mmol) and 2,2,6,6-tetramethylheptane-3,5-dione (3.6 g, 19.65 mmol) were used as reactants instead of the Intermediate A-7 (2.1 g, 1.2 mmol) and acetylacetone (1.2 g, 11.71 mmol).

MS (m/z): 1044.35

### Synthesis Example 6: Synthesis of Compound 137

(1) Synthesis of Intermediate F-1

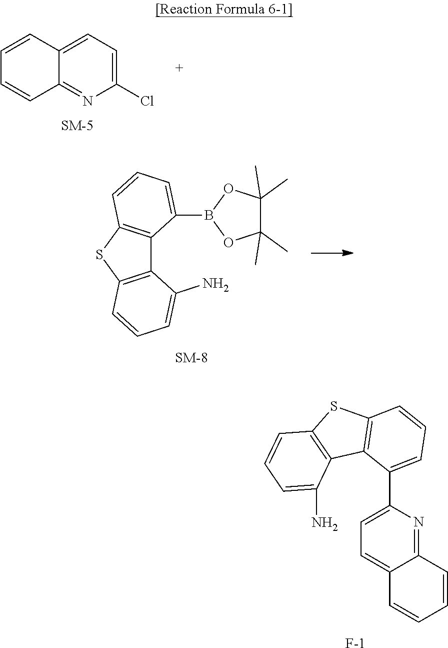

The Intermediate F-1 (13.0 g, yield: 65%) was obtained with the same synthetic process of the Intermediate D-1, except the Compound SM-5 (10.0 g, 61.12 mmol) and the Compound SM-8 (23.9 g, 73.35 mmol) were used as reactants instead of the Compound SM-5 (10.0 g, 61.12 mmol) and the Compound SM-6 (22.7 g, 67.24 mmol).

MS (m/z): 326.09

(2) Synthesis of Intermediate F-2

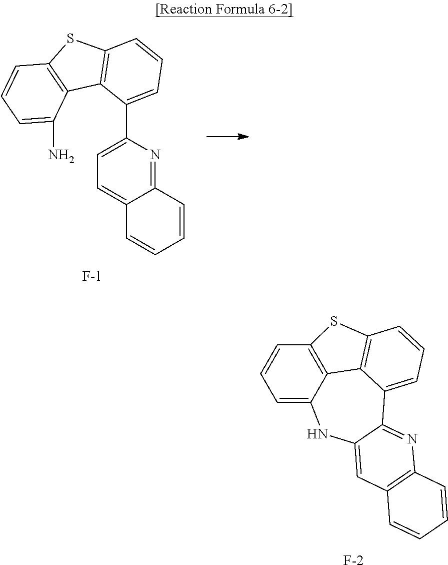

The Intermediate F-2 (5.2 g, yield: 40%) was obtained with the same synthetic process of the Intermediate D-2, except that the Intermediate F-1 (13.0 g, 39.73 mmol) was used as a reactant instead of the Intermediate D-1 (12.9 g, 41.56 mmol).

MS (m/z): 324.07

(3) Synthesis of Intermediate F-3

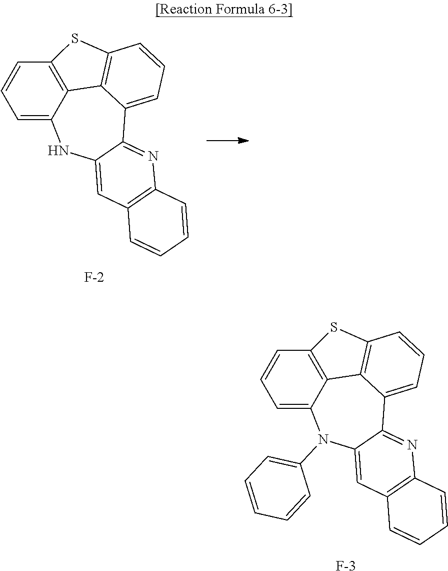

The Intermediate F-3 (5.0 g, yield: 79%) was obtained with the same synthetic process of the Intermediate D-3, except that the Intermediate F-2 (5.2 g, 15.89 mmol) was used as a reactant instead of the Intermediate D-2 (4.7 g, 15.38 mmol).

MS (m/z): 400.1

(4) Synthesis of Intermediate F-4

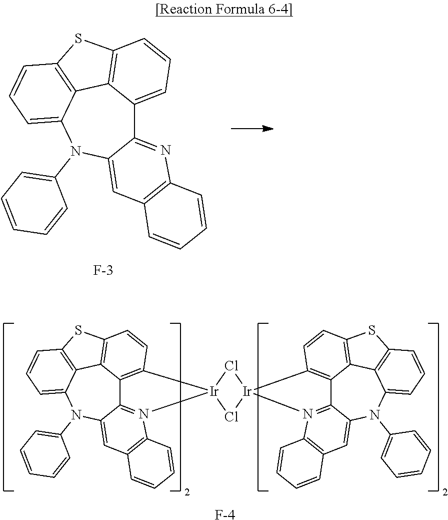

The Intermediate F-4 (3.0 g, yield: 52%) was obtained with the same synthetic process of the Intermediate A-7, except that the Intermediate F-3 (5 g, 12.48 mmol) was used as a reactant instead of the Intermediate A-6 (5 g, 14.9 mmol).

(5) Synthesis of Compound 137

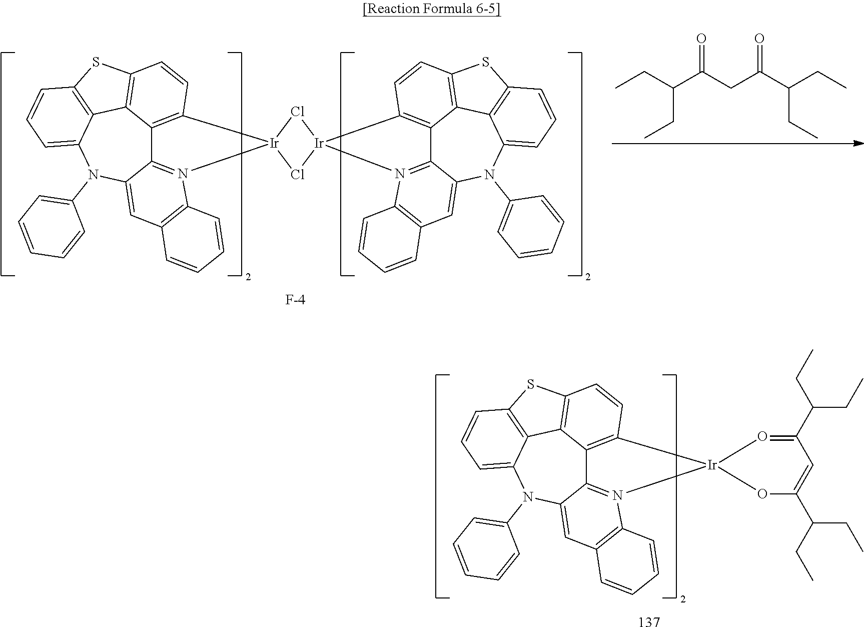

Compound 137 (1.4, yield: 39%) was obtained with the same synthetic process of the Compound 1, except that the Intermediate F-4 (3.0 g, 1.48 mmol) and 3,7-diethylnonane-4,6-dione (3.1 g, 14.75 mmol) were used as reactants instead of the Intermediate A-7 (2.1 g, 1.2 mmol) and acetylacetone (1.2 g, 11.71 mmol).

MS (m/z): 1202.32

### Synthesis Example 7: Synthesis of Compound 479

(1) Synthesis of Intermediate G-1

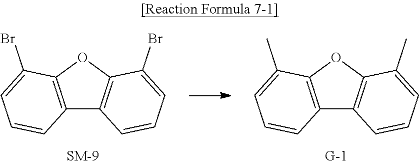

Compound SM-9 (50.0 g, 153.38 mmol), methyl boronic acid (23.0 g, 383.46 mmol), Pd₂(dba)₃ (4.2 g, 3 mol %), SPhos (2-dicyclohexylphosphino-2′,6′-dimethoxybiphenyl, 6.3 g, 15.34 mmol) and potassium phosphate monohydrate (176.6 g, 766.92 mmol) dissolved in toluene (1000 ml) were put into a reaction vessel, and then the solution was stirred at 120° C. for 12 hours. After the reaction was complete, the temperature of the solution was cooled to RT, an organic layer was extracted with ethyl acetate, and then the solvent was removed. A crude product was purified with column chromatography (eluent: ethyl acetate and hexane) to give the Intermediate G-1 (16.9 g, yield: 56%).

MS (m/z): 196.09

(2) Synthesis of Intermediate G-2

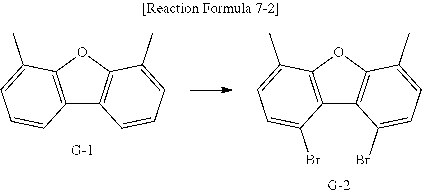 [SMILES: Cc1cccc2c1oc1c(C)cccc12 ; Cc1ccc(Br)c2c1oc1c(C)ccc(Br)c12]

The Intermediate G-1 (16.9 g, 86.12 mmol) dissolved in DMF (300 ml) was put into a reaction vessel, NBS (33.7 g, 189.46 mmol) was added into the solution, and then the solution was stirred for 12 hours with blocking light. After the reaction was complete, water was added into the solution to produce a solid, and then the solid was filtered. The filtered solid was washed with water three times, and then recrystallized with toluene and ethanol to give the Intermediate G-2 (26.8 g, yield: 88%).

MS (m/z): 351.91

(3) Synthesis of Intermediate G-3

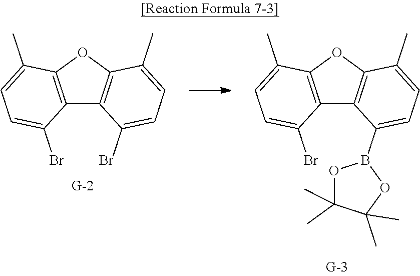 [SMILES: Cc1ccc(Br)c2c1oc1c(C)ccc(Br)c12 ; Cc1ccc(Br)c2c1oc1c(C)ccc(B3OC(C)(C)C(C)(C)O3)c12]

The Intermediate G-2 (20 g, 56.5 mmol), bis(pinacolato)diboron (16.1 g, 67.79 mmol), Pd(dppf)Cl₂ (2.1 g, 2.82 mmol), KOAc (17.1 g, 173.89 mmol) dissolved in 1,4-dioxane (300 ml) were put into a reaction vessel, and then the solution was stirred at 100° C. for 4 hours. The temperature of the reactants was cooled to RT, an organic layer were extracted with ethyl acetate, water in the organic layer was removed with MgSO₄, and then the organic layer was filtered and treated under reduced pressure to remove the solvent. A crude product was purified with column chromatography (eluent: hexane and ethyl acetate) to give the Intermediate G-3 (17.2 g, yield: 76%).

MS (m/z): 400.08

(4) Synthesis of Intermediate G-4

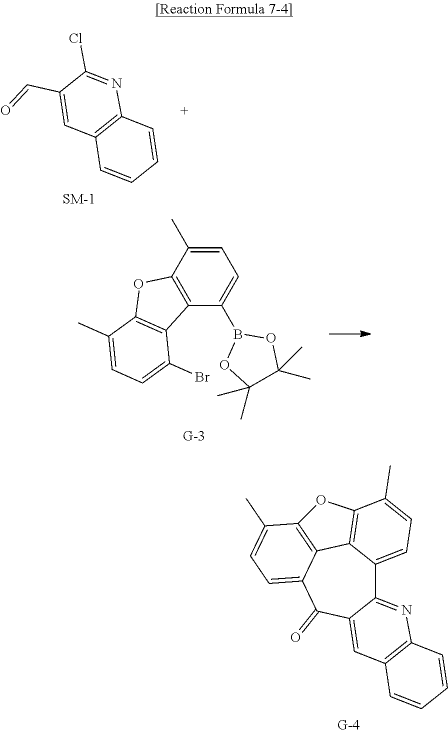

The Intermediate G-4 (12.8 g, yield: 61%) was obtained with the same synthetic process of the Intermediate A-4, except that the Intermediate G-3 (25.1 g, 62.63 mmol) was used as a reactant instead of the Intermediate A-3 (23.4 g, 62.63 mmol).

MS (m/z): 349.11

(5) Synthesis of Intermediate G-5

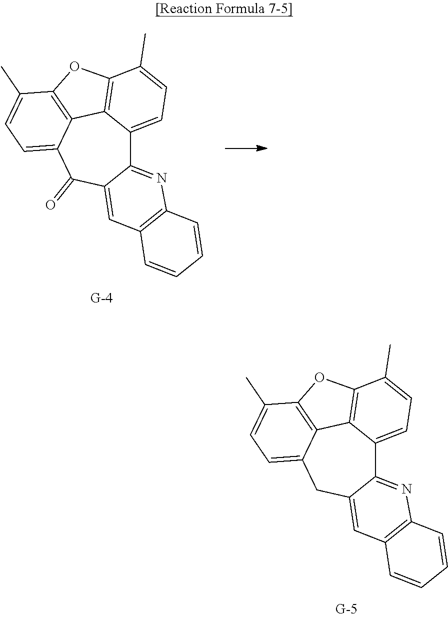 [SMILES: Cc1ccc2c(=O)c3cc4ccccc4nc3c3ccc(C)c4oc1c2c43 ; Cc1ccc2c3c1oc1c(C)ccc(c13)-c1nc3ccccc3cc1C2]

The Intermediate G-5 (11.8 g, yield: 96%) was obtained with the same synthetic process of the Intermediate A-5, except that the Intermediate G-4 (12.8 g, 36.55 mmol) was used as a reactant instead of the Intermediate A-4 (10.6 g, 32.99 mmol).

MS (m/z): 335.13

(6) Synthesis of Intermediate G-6

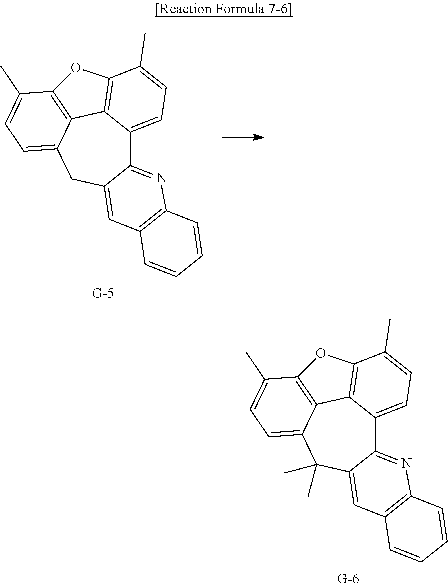 [SMILES: Cc1ccc2c3c1oc1c(C)ccc(c13)-c1nc3ccccc3cc1C2 ; "G-5" ; Cc1ccc2c3c1oc1c(C)ccc(c13)C(C)(C)c1cc3ccccc3nc1-2 ; "G-6"]

The Intermediate G-6 (7.0 g, yield: 55%) was obtained with the same synthetic process of the Intermediate A-6, except that the Intermediate G-5 (11.8 g, 35.09 mmol) was used as a reactant instead of the Intermediate A-5 (9.1 g, 29.61 mmol).

MS (m/z): 363.16

(7) Synthesis of Intermediate G-7

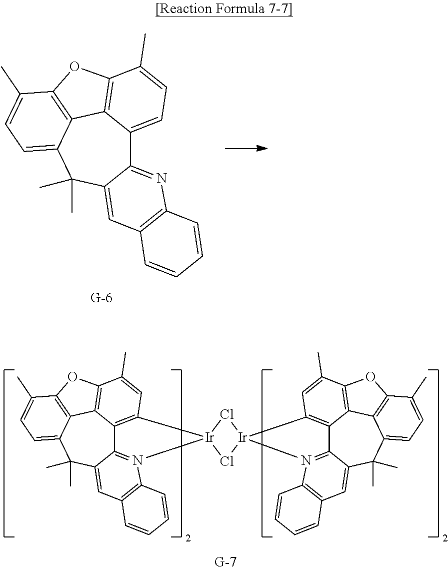

The Intermediate G-7 was obtained with the same synthetic process of the Intermediate A-7, except that the Intermediate G-6 (5 g, 13.76 mmol) was used as a reactant instead of the Intermediate A-6 (5 g, 14.9 mmol).

(8) Synthesis of Compound 479

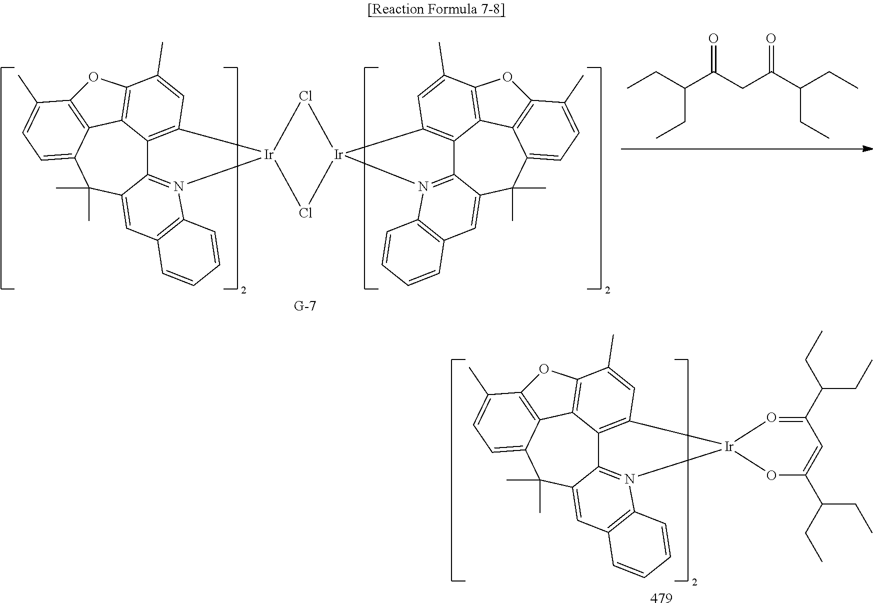

Compound 479 was obtained with the same synthetic process of Compound 1, except that the Intermediate G-7 (3.0 g, 1.59 mmol) and 3,7-diethylnonane-4,6-dione (3.4 g, 15.95 mmol) were used as reactants instead of the Intermediate A-7 (2.1 g, 1.2 mmol) and acetylacetone (1.2 g, 11.71 mmol).

MS (m/z): 1128.44

### Synthesis Example 8: Synthesis of Compound 700

(1) Synthesis of Intermediate H-1

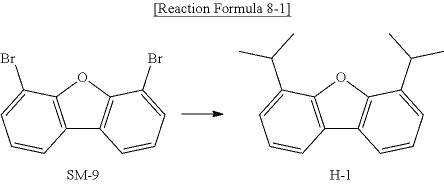

The Intermediate H-1 (24.0 g, yield: 62%) was obtained with the same synthetic process of the Intermediate G-1, except that propan-2-yl boronic acid (33.7 g, 383.46 mmol) was used as a reactant instead of methyl boronic acid (23.0 g, 383.46 mmol).

MS (m/z): 252.15

(2) Synthesis of Intermediate H-2

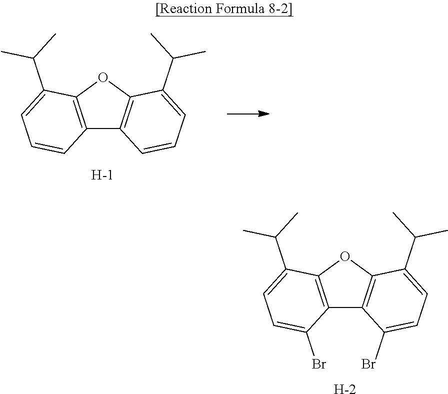

The Intermediate H-2 was obtained with the same synthetic process of the Intermediate G-2, except that the Intermediate H-1 (24.0 g, 95.10 mmol) was used as a reactant instead of the Intermediate G-1 (16.9 g, 86.12 mmol).

MS (m/z): 407.97

(3) Synthesis of Intermediate H-3

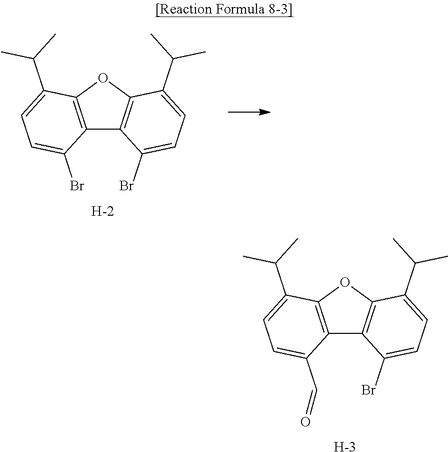

The Intermediate H-3 (13.2 g, yield: 41%) was obtained with the same synthetic process of the Intermediate E-1, except that the Intermediate H-2 (36.7 g, 89.39 mmol) was used as a reactant instead of the Intermediate A-2 (50 g, 153.38 mmol).

MS (m/z): 358.06

(3) Synthesis of Intermediate H-4

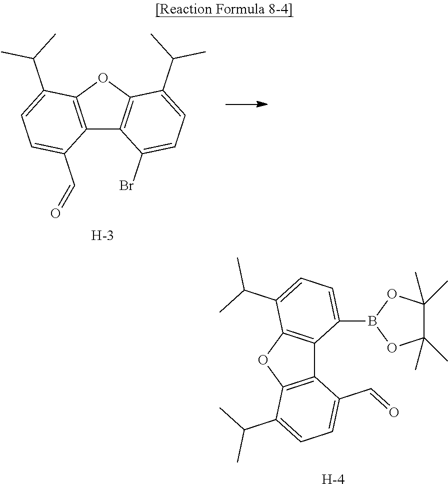

The Intermediate H-4 (8.0 g, yield: 54%) was obtained with the same synthetic process of the Intermediate A-3, except that the Intermediate H-3 (13.2 g, 36.65 mmol) was used as a reactant instead of the Intermediate A-2 (40 g, 122.71 mmol).

MS (m/z): 406.23

(5) Synthesis of Intermediate H-5

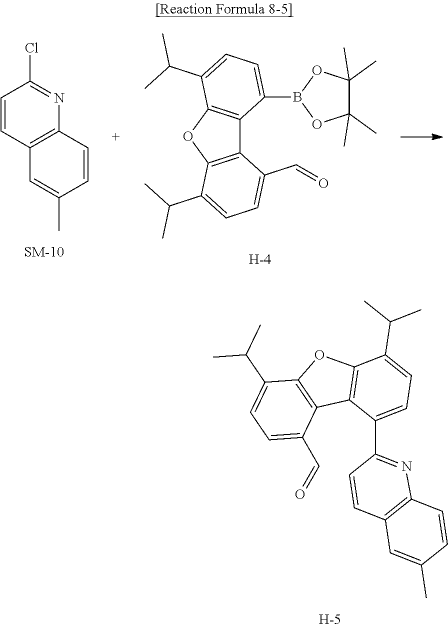

The Intermediate H-5 (18.3 g, yield: 77%) was obtained with the same synthetic process of the Intermediate E-3, except that the Compound SM-10 (10.0 g, 56.30 mmol) and the Intermediate H-4 (25.2 g, 61.93 mmol) were used as reactants instead of the Compound SM-7 (10.0 g, 61.12 mmol) and the Intermediate E-2 (21.7 g, 67.24 mmol).

MS (m/z): 421.2

(6) Synthesis of Intermediate H-6

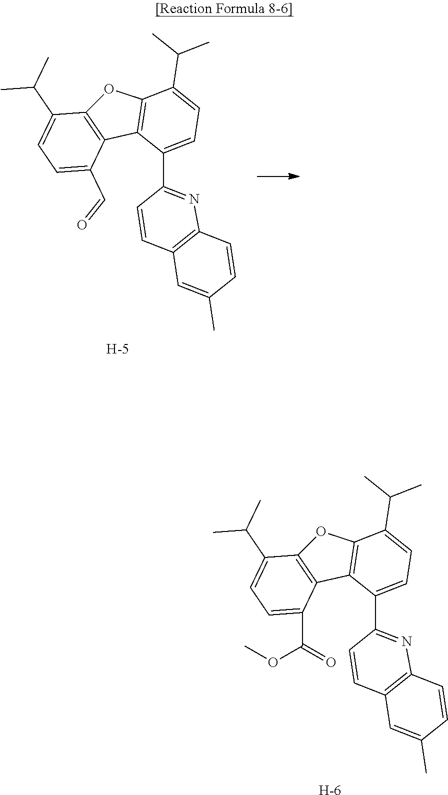

The Intermediate H-6 (18.4 g, yield: 94%) was obtained with the same synthetic process of the Intermediate E-4, except that the Intermediate H-5 (18.3 g, 43.41 mmol) was used as a reactant instead of the Intermediate E-3 (15.4 g, 47.63 mmol).

MS (m/z): 451.21

(7) Synthesis of Intermediate H-7

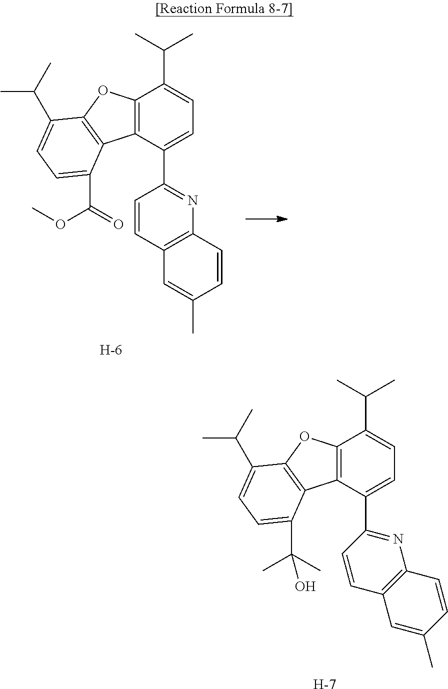

The Intermediate H-7 (8.1 g, yield: 44%) was obtained with the same synthetic process of the Intermediate E-5, except that the Intermediate H-6 (18.4 g, 40.81 mmol) was used as a reactant instead of the Intermediate E-4 (16.3 g, 46.13 mmol).

MS (m/z): 451.25

(8) Synthesis of Intermediate H-8

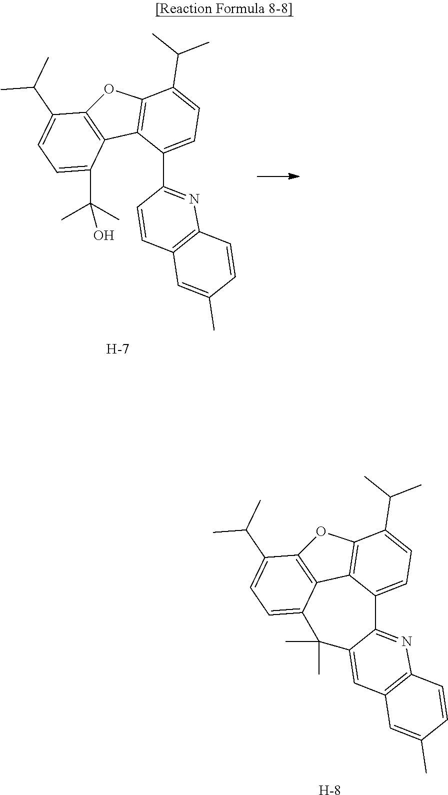

The Intermediate H-8 (4.4 g, yield: 57%) was obtained with the same synthetic process of the Intermediate E-6, except that the Intermediate H-7 (8.1 g, 17.96 mmol) was used as a reactant instead of the Intermediate E-5 (8.0 g, 22.64 mmol).

MS (m/z): 433.24

(9) Synthesis of Intermediate H-9

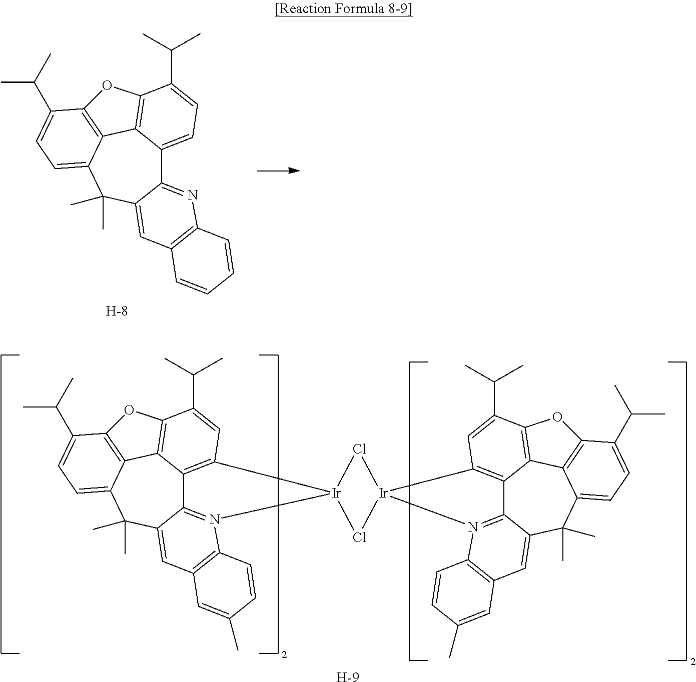

The Intermediate H-9 (2.7 g, yield: 45%) was obtained with the same synthetic process of the Intermediate A-7, except that the Intermediate H-8 (5 g, 11.92 mmol) was used as a reactant instead of the Intermediate A-6 (5 g, 14.9 mmol).

(10) Synthesis of Compound 700

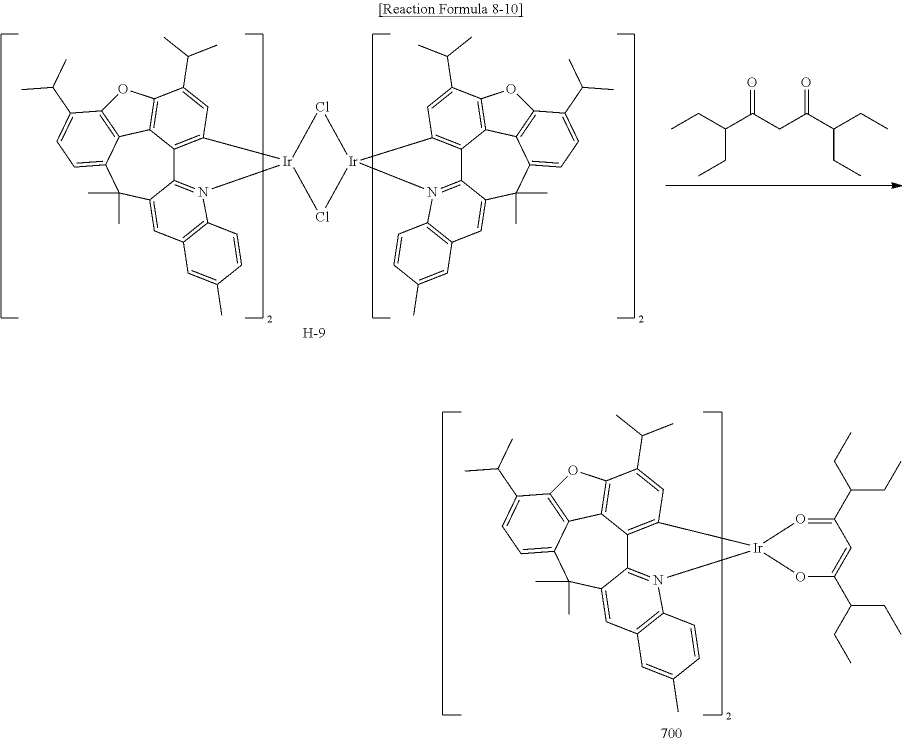

Compound 700 (1.5 g, yield: 49%) was obtained with the same synthetic process of the Compound 1, except that the Intermediate H-9 (2.7 g, 1.22 mmol) and 3,7-diethylnonane-4,6-dione (2.6 g, 12.19 mmol) were used as reactants instead of the Intermediate A-7 (2.1 g, 1.2 mmol) and acetylacetone (1.2 g, 11.71 mmol).

MS (m/z): 1268.6

### Synthesis Example 9: Synthesis of Compound 800

(1) Synthesis of Intermediate I-1

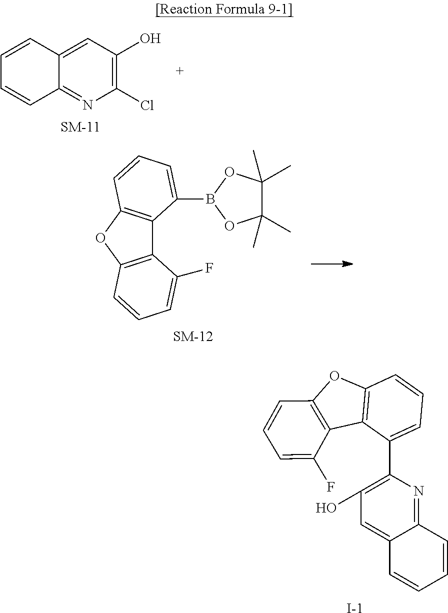 [SMILES: Oc1cc2ccccc2nc1Cl ; CC1(C)OB(c2cccc3oc4cccc(F)c4c23)OC1(C)C ; Oc1cc2ccccc2nc1-c1cccc2oc3cccc(F)c3c12 ; [I-]]

The Intermediate I-1 (12.1 g, yield: 66%) was obtained with the same synthetic process of the Intermediate E-3, except that the Compound SM-11 (10.0 g, 55.68 mmol) and the Compound SM-12 (20.9 g, 66.82 mmol) were used as reactants instead of the Compound SM-7 (10.0 g, 61.12 mmol) and the Intermediate E-2 (21.7 g, 67.24 mmol).

MS (m/z): 329.09

(2) Synthesis of Intermediate I-2

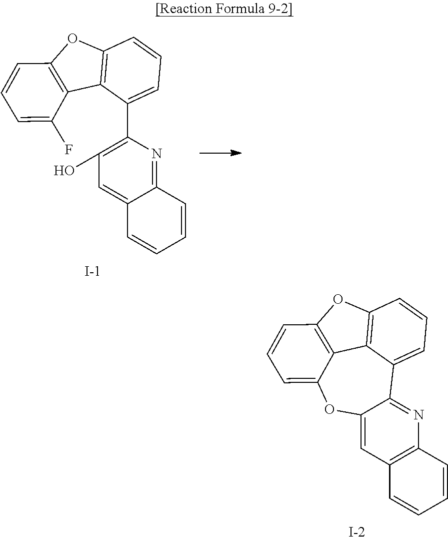

The Intermediate I-1 (12.1 g, 36.75 mmol) dissolved in DMF (100 ml) was put into a reaction vessel, K₂CO₃ (15.0 g, 108.57 mmol) was added into the solution, and then the solution was stirred at 100° C. for 1 hour. After the reaction was complete, the temperature of the solution was cooled to RT, and then ethanol (100 ml) was added slowly into the solution. The mixture was distilled under reduced pressure and then was recrystallized with chloroform/ethyl acetate to give the Intermediate I-2 (5.5 g, yield: 48%).

MS (m/z): 309.08

(3) Synthesis of Intermediate I-3

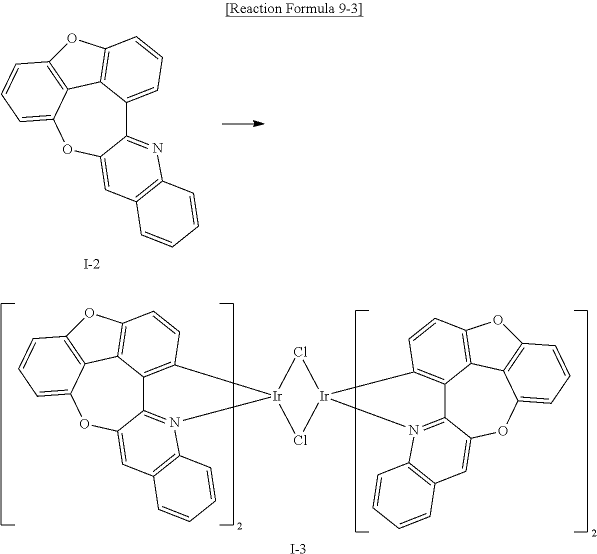

The Intermediate I-3 (2.5 g, yield: 41%) was obtained with the same synthetic process of the Intermediate A-7, except that the Intermediate I-2 (5 g, 16.16 mmol) was used as a reactant instead of the Intermediate A-6 (5 g, 14.9 mmol).

(4) Synthesis of Compound 800

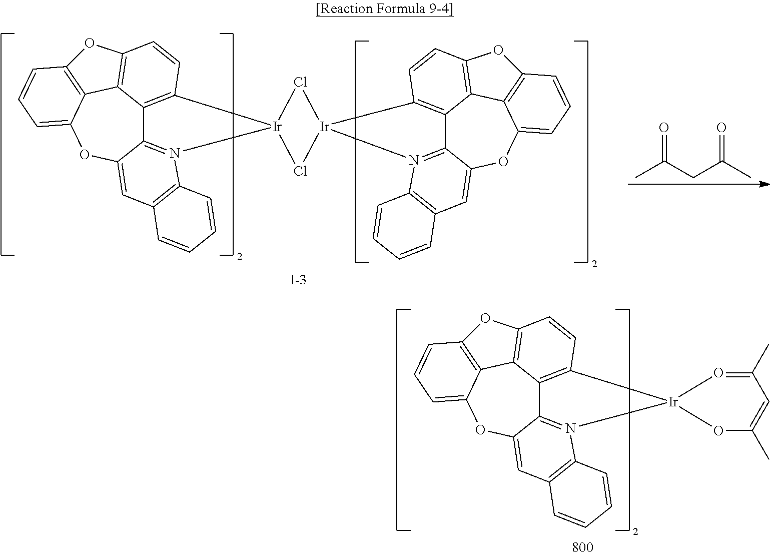

Compound 800 (1.1 g, yield: 42%) was obtained with the same synthetic process of the Compound 1, except that the Intermediate I-3 (2.5 g, 1.51 mmol) was used as a reactant instead of the Intermediate A-7 (2.1 g, 1.2 mmol).

MS (m/z): 908.15

### Synthesis Example 10: Synthesis of Compound 827

(1) Synthesis of Intermediate J-1

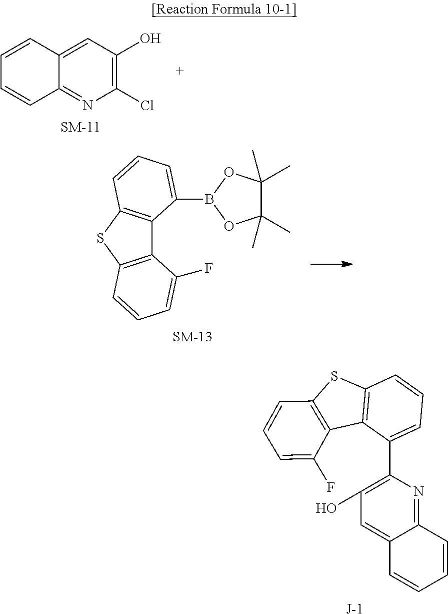 [SMILES: Oc1cc2ccccc2nc1Cl ; CC1(C)OB(c2cccc3sc4cccc(F)c4c23)OC1(C)C ; Oc1cc2ccccc2nc1-c1cccc2sc3cccc(F)c3c12 ; "J-1"]

The Intermediate J-1 (12.5 g, yield: 65%) was obtained with the same synthetic process of the Intermediate E-3, except that the Compound SM-11 (10.0 g, 55.68 mmol) and the Compound SM-13 (21.4 g, 66.82 mmol) were used as reactants instead of the Compound SM-7 (10.0 g, 61.12 mmol) and the Intermediate E-2 (21.7 g, 67.24 mmol).

MS (m/z): 345.06

(2) Synthesis of Intermediate J-2

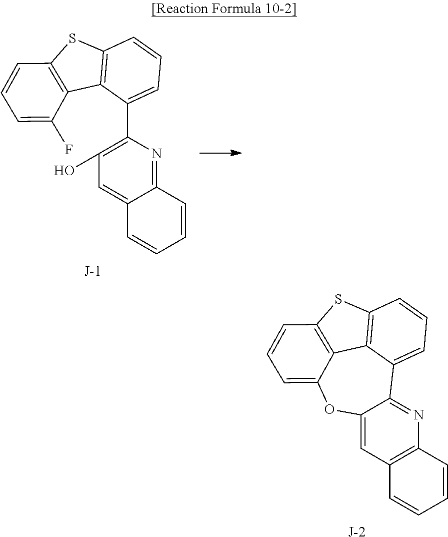 [SMILES: Oc1cc2ccccc2nc1-c1cccc2sc3cccc(F)c3c12 ; "J-1" ; c1ccc2nc3c(cc2c1)oc1cccc2sc4cccc3c4c12 ; "J-2"]

The Intermediate J-2 (6.0 g, yield: 51%) was obtained with the same synthetic process of the Intermediate I-2, except that the Intermediate J-1 (12.5 g, 36.19 mmol) was used as a reactant instead of the Intermediate I-1 (12.1 g, 36.75 mmol).

MS (m/z): 325.06

(3) Synthesis of Intermediate J-3

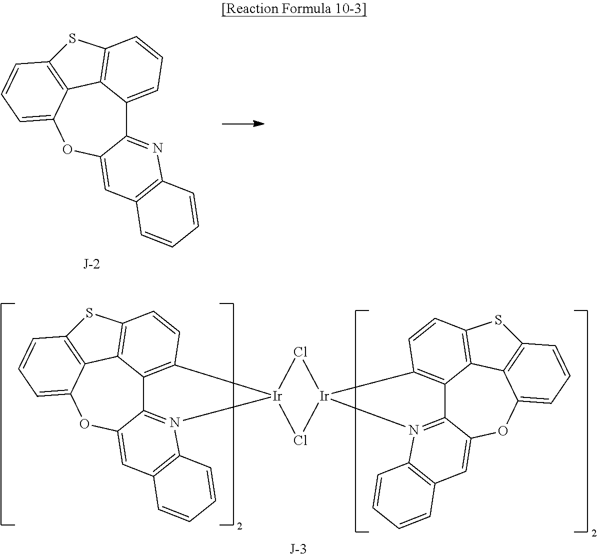

The Intermediate J-3 (3.2 g, yield: 52%) was obtained with the same synthetic process of the Intermediate A-7, except that the Intermediate J-2 (5 g, 15.17 mmol) was used as a reactant instead of the Intermediate A-6 (5 g, 14.9 mmol).

(4) Synthesis of Compound 827

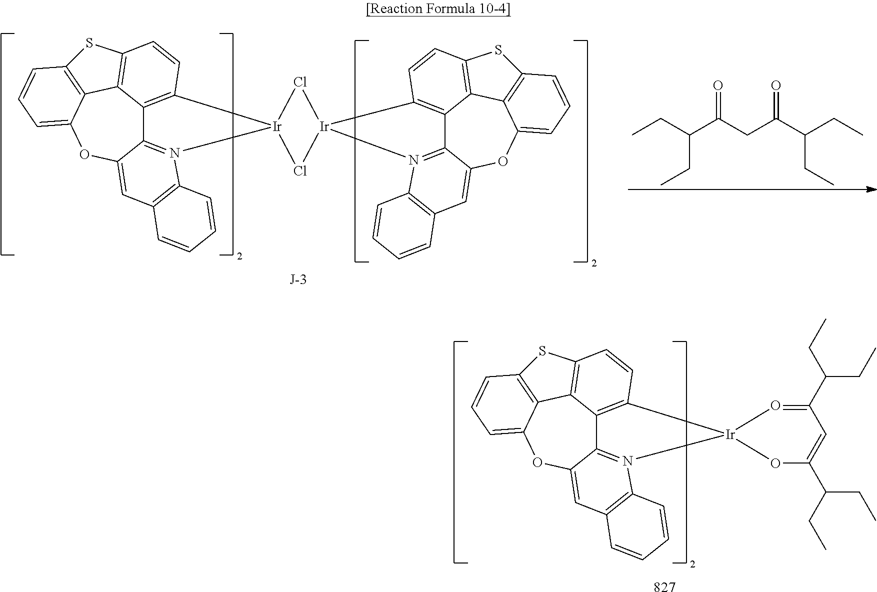

Compound 827 (2.1 g, yield: 56%) was obtained with the same synthetic process of the Compound 1, except that the Intermediate J-7 (3.2 g, 1.82 mmol) and 3,7-diethylnonane-4,6-dione (3.9 g, 18.16 mmol) were used as reactants instead of the Intermediate A-7 (2.1 g, 1.2 mmol) and acetylacetone (1.2 g, 11.71 mmol).

MS (m/z): 1052.23

### Synthesis Example 11: Synthesis of Compound 839

(1) Synthesis of Intermediate K-1

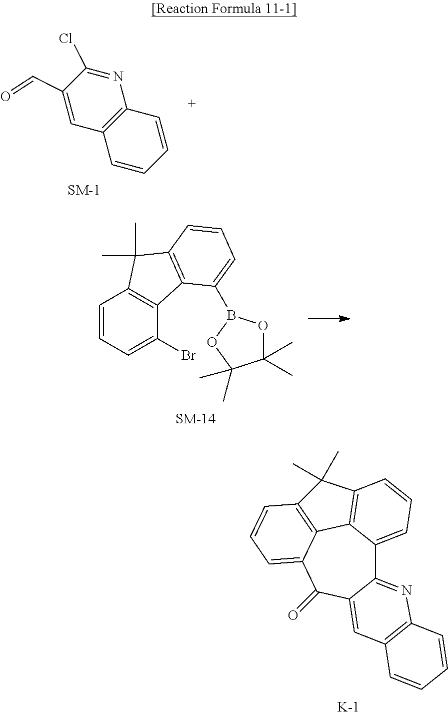

The Intermediate K-1 (10.5 g, yield: 58%) was obtained with the same synthetic process of the Intermediate A-4, except that the Compound SM-14 (25.0 g, 62.63 mmol) was used as a reactant instead of the Intermediate A-3 (23.4 g, 62.63 mmol).

MS (m/z): 347.13

(2) Synthesis of Intermediate K-2

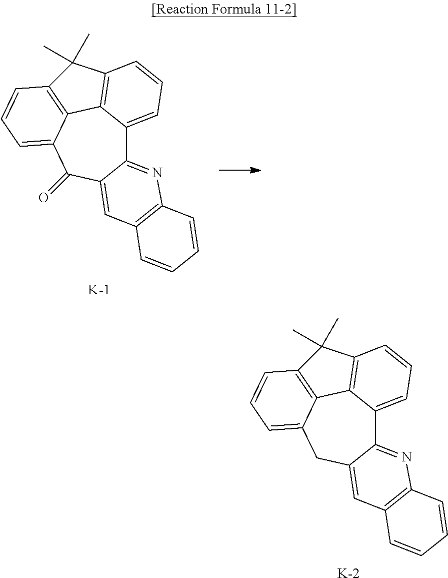

The Intermediate K-2 (9.6 g, yield: 95%) was obtained with the same synthetic process of the Intermediate A-5, except that the Intermediate K-1 (10.5 g, 30.27 mmol) was used as a reactant instead of the Intermediate A-4 (10.6 g, 32.99 mmol).

MS (m/z): 333.15

(3) Synthesis of Intermediate K-3

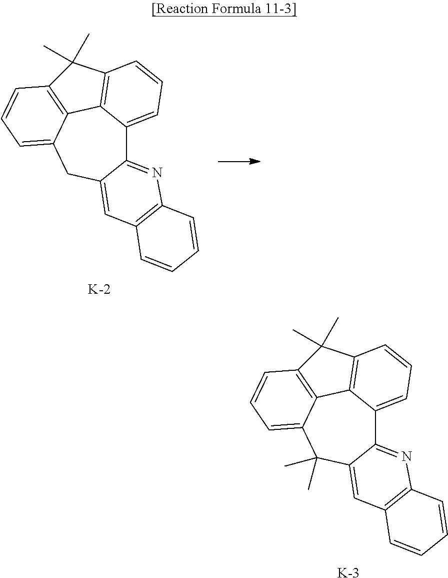

The Intermediate K-3 (5.4 g, yield: 52%) was obtained with the same synthetic process of the Intermediate A-6, except that the Intermediate K-2 (9.6 g, 28.76 mmol) was used as a reactant instead of the Intermediate A-5 (9.1 g, 29.61 mmol).

MS (m/z): 361.18

(4) Synthesis of Intermediate K-4

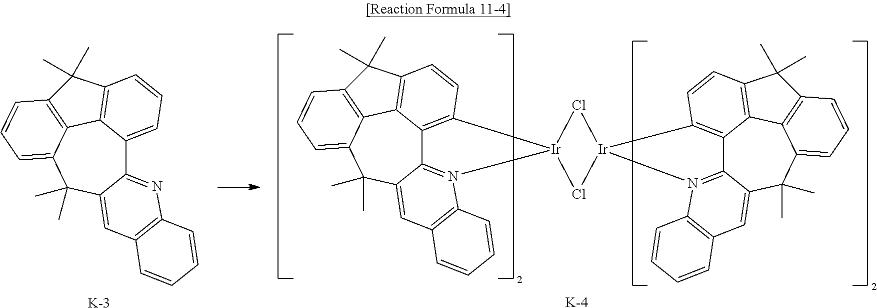

The Intermediate K-4 (3.2 g, yield: 53%) was obtained with the same synthetic process of the Intermediate A-7, except that the Intermediate K-3 (5 g, 13.83 mmol) was used as a reactant instead of the Intermediate A-6 (5 g, 14.9 mmol).

(5) Synthesis of Compound 839

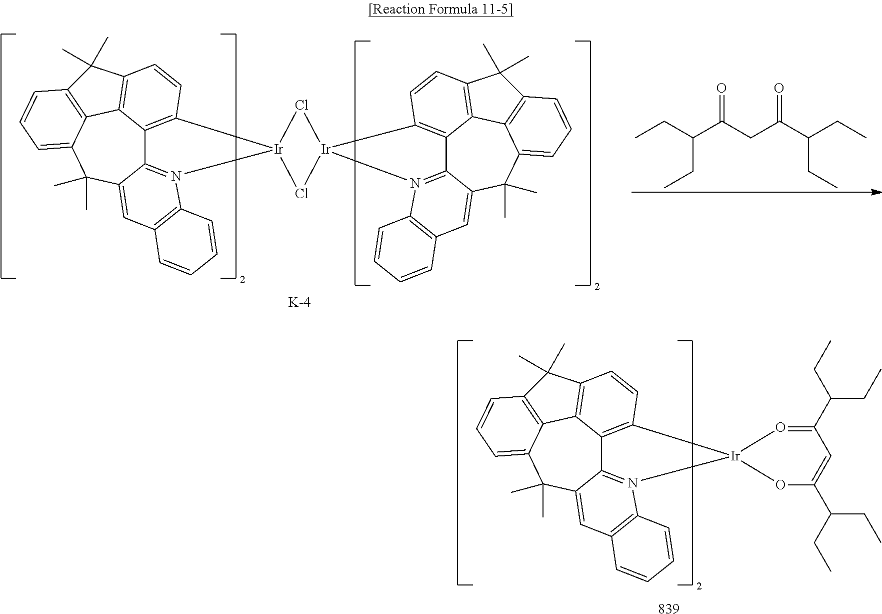

Compound 839 (2.0 g, yield: 54%) was obtained with the same synthetic process of the Compound 1, except that the Intermediate K-4 (3.2 g, 1.67 mmol) and 3,7-diethylnonane-4,6-dione (3.5 g, 16.66 mmol) were used as reactants instead of the Intermediate A-7 (2.1 g, 1.2 mmol) and acetylacetone (1.2 g, 11.71 mmol).

MS (m/z): 1124.48

### Example 1 (Ex. 1): Fabrication of OLED

An organic light emitting diode was fabricated by applying Compound 1 obtained in Synthesis Example 1 as dopant into an emitting material layer (EML). A glass substrate onto which ITO (100 nm) was coated as a thin film was washed and ultrasonically cleaned by solvent such as isopropyl alcohol, acetone and dried at 100° C. oven. The substrate was transferred to a vacuum chamber for depositing emissive layer. Subsequently, an emissive layer and a cathode were deposited by evaporation from a heating boat under about 5˜-7×10⁻⁷ Torr with setting deposition rate of 1 A/s as the following order:

A hole injection layer (HIL) (following HI-1 (NPNPB), 60 nm); a hole transport layer (HTL) (following NPB, 80 nm); an EML (Host (CBP, 95 wt %), Dopant (Compound 1, 5 wt %), 30 nm); an ETL-EIL (following ET-1(2-[4-(9,10-Di-2-naphthalenyl-2-anthracenyl)phenyl]-1-phenyl-1H-benzimidazole, ZADN, 50 wt %), Liq (50 wt %), 30 nm); and a cathode (Al, 100 nm).

And then, capping layer (CPL) was deposited over the cathode and the device was encapsulated by glass. After deposition of emissive layer and the cathode, the OLED was transferred from the deposition chamber to a dry box for film formation, followed by encapsulation using UV-curable epoxy and moisture getter. The HIL material, the HTL material, the Host in the EMT and the ETT material is illustrated in the following

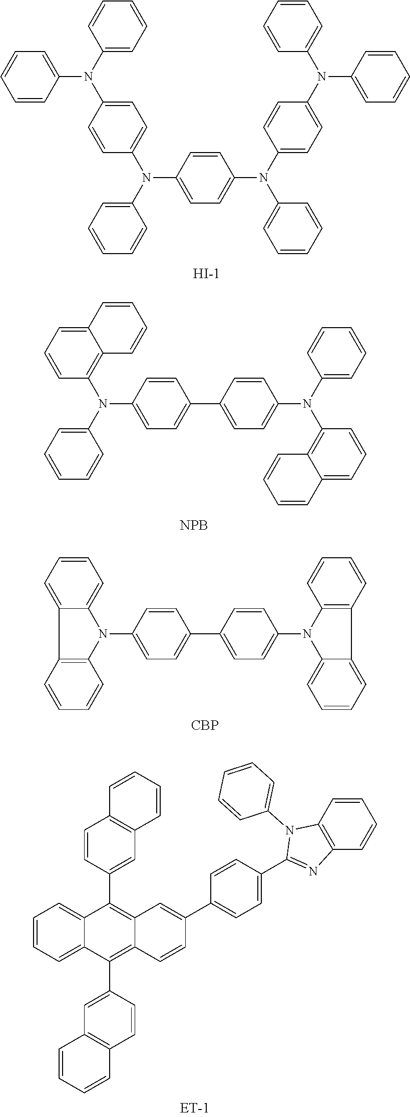

### Examples 2-11 (Ex. 2-11): Fabrication of OLEDs

An OLED was fabricated using the same procedure and the same material as in Example 1, except that Compound 52 (Ex. 2), Compound 53 (Ex. 3), Compound 86 (Ex. 4), Compound 101 (Ex. 5), Compound 137 (Ex. 6), Compound 479 (Ex. 7), Compound 700 (Ex. 8), Compound 800 (Ex. 9), Compound 827 (Ex. 10) and Compound 839 (Ex. 11), respectively, was used as the dopant in the EML instead of Compound 1.

### Comparative Example (Ref.): Fabrication of OLEDs

An OLED was fabricated using the same procedure and the same material as in Example 1, except the following Ref. Compound was used as the dopant in the EML instead of Compound 1.

[Ref. Compound]

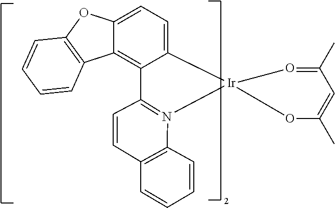

### Experimental Example 1: Measurement of Luminous Properties of OLEDs

Each of the OLEDs, having 9 mm² of emission area, fabricated in Examples 1 to 11 and Comparative Example was connected to an external power source and then luminous properties for all the OLEDs were evaluated using a constant current source (KEITHLEY) and a photometer PR650 at room temperature. In particular, driving voltage (V, relative value), External quantum efficiency (EQE, relative value) and time period (LT₉₅, relative value) at which the luminance was reduced to 95% from initial luminance was measured at a current density 10 mA/cm². The measurement results are indicated in the following Table 1.

TABLE 1
Luminous Properties of OLED

| | | Driving | EQE | LT₉₅ |
|---|---|---|---|---|
| | | Voltage V (%, | (%, relative | (%, relative |
| Sample | Dopant | relative value) | value) | value) |
| Ref. | Ref. | 100 | 100 | 100 |
| | Compound | | | |
| Ex. 1 | 1 | 94.5 | 111 | 110 |
| Ex. 2 | 52 | 92.2 | 105 | 107 |
| Ex. 3 | 53 | 92.9 | 102 | 103 |
| Ex. 4 | 86 | 96.2 | 107 | 110 |
| Ex. 5 | 101 | 95.3 | 113 | 108 |
| Ex. 6 | 137 | 93.6 | 106 | 109 |
| Ex. 7 | 479 | 95.7 | 122 | 142 |
| Ex. 8 | 700 | 97.4 | 108 | 121 |
| Ex. 9 | 800 | 96.9 | 106 | 131 |
| Ex. 10 | 827 | 92.6 | 105 | 112 |
| Ex. 11 | 839 | 93.4 | 120 | 133 |

As indicated in Table 1, compared to the OLED fabricated in Ref., the OLED fabricated in Ex. 1-11 where the EML includes the organic metal compound as the dopant lowered its driving voltage up to 7.8%, and improved its EQE and LT₉₅ up to 22% and 42%, respectively. Accordingly, when the organic metal compound of the present disclosure is applied into the EML, the OLED can lower its driving voltage and improved its luminous efficiency and luminous lifespan significantly.

It will be apparent to those skilled in the art that various modifications and variations can be made in the organic metal compound, the organic light emitting diode, and the organic light emitting device having the compound of the present disclosure without departing from the scope of the invention. Thus, it is intended that the present disclosure cover the modifications and variations of the present disclosure provided they come within the scope of the appended claims.

What is claimed is:

1. An organic metal compound having the following structure of Formula 1: 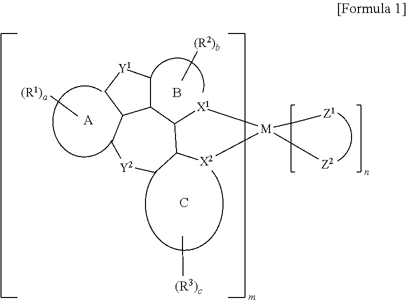
wherein M is molybdenum (Mo), tungsten (W), rhenium (Re), ruthenium (Ru), osmium (Os), rhodium (Rh), iridium (Ir), palladium (Pd), platinum (Pt) or silver (Ag); each of A, B and C is independently a 5-membered or 6-membered aromatic ring or a 5-membered or 6-membered hetero aromatic ring; each of X¹ and X² is independently CR⁴, N or P, one of X¹ and X² is CR⁴ and the other of X¹ and X² is N or P; each of Y¹ and Y² is independently selected from the group consisting of BR⁵, CR⁵R⁶, C═O, C═NR⁵, SiR⁵R⁶, NR⁵, PR⁵, AsR⁵, SbR⁵, BiR⁵, P(O)R⁵, P(S)R⁵, P(Se)R⁵, As(O)R⁵, As(S)R⁵, As(Se)R⁵, Sb(O)R⁵, Sb(S)R⁵, Sb(Se)R⁵, Bi(O)R⁵, Bi(S)R⁵, Bi(Se)R⁵, O, S, Se, Te, SO, SO₂, SeO, SeO₂, TeO and TeO₂; each of R¹ to R⁶ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R¹, adjacent two of R² and adjacent two of R³ independently forms a C₄-C₂₀ alicyclic ring, a C₃-C₂₀ hetero alicyclic ring, a C₆-C₂₀ aromatic ring or a C₃-C₂₀ hetero aromatic ring when each of a, b and c is 2 or more; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, thegrou, alkyl silyl group, the C₃-C₂₀ alicyclic group, the C₃-C₂₀ hetero alicyclic group, the C₆-C₃₀ aromatic group and the C₃-C₃₀ hetero aromatic group of R¹ to R⁶ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by each of adjacent two of R¹, adjacent two of R² and adjacent two of R³ is optionally substituted with at least one C₁-C₁₀ alkyl group; each of a, b and c is a number of substitutent R¹, R² and R³, respectively, a is an integer of 0 to 3, b is an integer of 0 to 2 and c is an integer of 0 to 4; 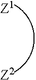
is an acetylacetonate-based auxiliary ligand; m is an integer of 1 to 3, n is an integer of 0 to 2, wherein m plus n is an oxidation number of M.

2. The organic metal compound of claim 1, wherein the organic metal compound has the following structure of Formula 2: 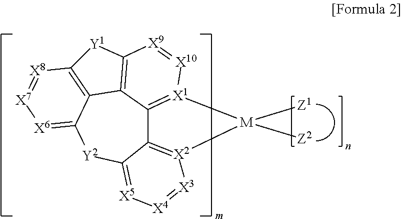
wherein each of M, X¹, X², Y¹, Y², 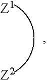
m and n is as same as defined in Formula 1; each of X³ to X⁵ is independently selected from the group consisting of CR⁷, N, P, S and O, wherein at least one of X³ to X⁵ is CR⁷; each of X⁶ to X⁸ is independently selected from the group consisting of CR⁸, N, P, S and O, wherein at least one of X⁶ to X⁸ is CR⁸; each of X⁹ and X¹⁰ is independently selected from the group consisting of CR⁹, N, P, S and O, wherein at least one of X⁹ and X¹⁰ is CR⁹; each of R⁷ to R⁹ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R⁷, adjacent two of R⁸ and adjacent two of R⁹ independently forms a C₄-C₂₀ alicyclic ring, a C₃-C₂₀ hetero alicyclic ring, a C₆-C₂₀ aromatic ring or a C₃-C₂₀ hetero aromatic ring; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of R⁷ to R⁹ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by each of adjacent two of R⁷, adjacent two of R⁸ and adjacent two of R⁹ is optionally substituted with at least one C₁-C₁₀ alkyl group.

3. The organic metal compound of claim 2, wherein the organic metal compound has the following structure of Formula 3: 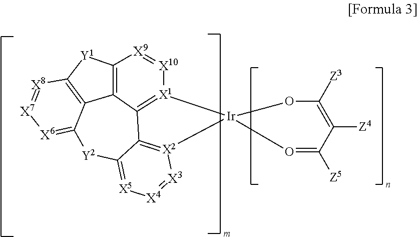
wherein each of X¹ to X¹⁰, Y¹ and Y² is as same as defined in Formula 2; m is an integer of 1 to 3, n is an integer of 0 to 2, wherein m plus n is 3; each of Z³ to Z⁵ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or adjacent two of Z³ to Z⁵ form a C₄-C₂₀ alicyclic ring, a C₃-C₂₀ hetero alicyclic ring, a C₆-C₂₀ aromatic ring or a C₃-C₂₀ hetero aromatic ring; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of Z³ to Z⁵ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by adjacent two of Z³ to Z⁵ is optionally substituted with at least one C₁-C₁₀ alkyl group.

4. The organic metal compound of claim 1, wherein the organic metal compound has the following structure of Formula 4: 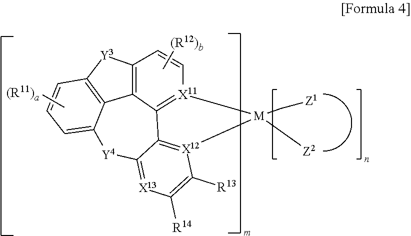
wherein each of M, a, b, m and n is as same as defined in Formula 1; each of X¹¹ to X¹³ is independently CR¹⁵ or N, wherein one of X¹¹ and X¹² is CR¹⁵ and the other of X¹¹ and X¹² is N; each of Y³ and Y⁴ is independently CR¹⁶R¹⁷, NR¹⁶, O, S, Se or SiR¹⁶R¹⁷; each of R¹¹ to R¹⁵ is independently selected from the group consisting of protium, deuterium, a C₁-C₁₀ alkyl group, a C₄-C₂₀ cyclo alkyl group, a C₄-C₂₀ hetero cyclo alkyl group, a C₆-C₂₀ aryl group and a C₃-C₂₀ hetero aryl group, or each of adjacent two of R¹¹ and adjacent two of R¹² independently forms a C₆-C₂₀ aromatic ring or a C₃-C₂₀ hetero aromatic ring unsubstituted or substituted with at least one C₁-C₁₀ alkyl group when each of a and b is 2 or more, or adjacent two of R¹³ to R¹⁵ form a C₆-C₂₀ aromatic ring or a C₃-C₂₀ hetero aromatic ring unsubstituted or substituted with at least one C₁-C₁₀ alkyl group; each of R¹⁶ and R¹⁷ is independently selected from the group consisting of protium, deuterium, a C₁-C₁₀ alkyl group, a C₄-C₂₀ cyclo alkyl group, a C₄-C₂₀ hetero cyclo alkyl group, a C₆-C₂₀ aryl group and a C₃-C₂₀ hetero aryl group.

5. The organic metal compound of claim 4, wherein the adjacent two of R¹³ to R¹⁵ in Formula 4 form a C₆-C₁₀ aromatic ring or a C₃-C₁₀ hetero aromatic ring unsubstituted or substituted with at least one C₁-C₁₀ alkyl group.

6. The organic metal compound of claim 4, wherein the organic metal compound has the following structure of Formula 5: 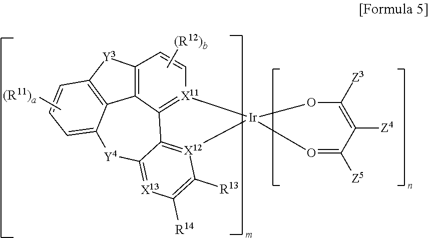
wherein each of R¹¹ to R¹⁴, X¹¹ to X¹³, Y³, Y⁴, a and b is as same as defined in Formula 4; m is an integer of 1 to 3, n is an integer of 0 to 2, wherein m plus n is 3; each of Z³ to Z⁵ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or adjacent two of Z³ to Z⁵ form a C₄-C₂₀ alicyclic ring, a C₃-C₂₀ hetero alicyclic ring, a C₆-C₂₀ aromatic ring or a C₃-C₂₀ hetero aromatic ring; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of Z³ to Z⁵ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by adjacent two of Z³ to Z⁵ is optionally substituted with at least one C₁-C₁₀ alkyl group.

7. The organic metal compound of claim 1, wherein the organic metal compound is selected from the following compounds:

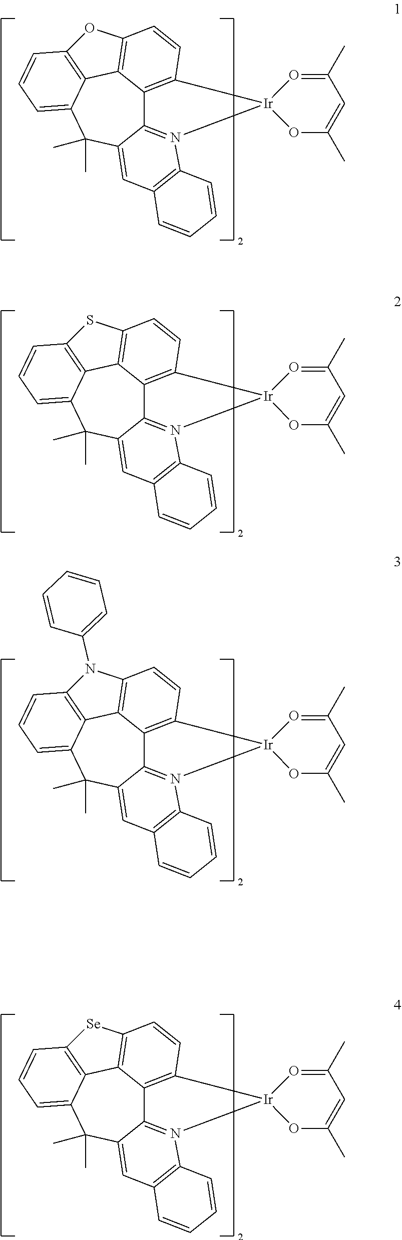

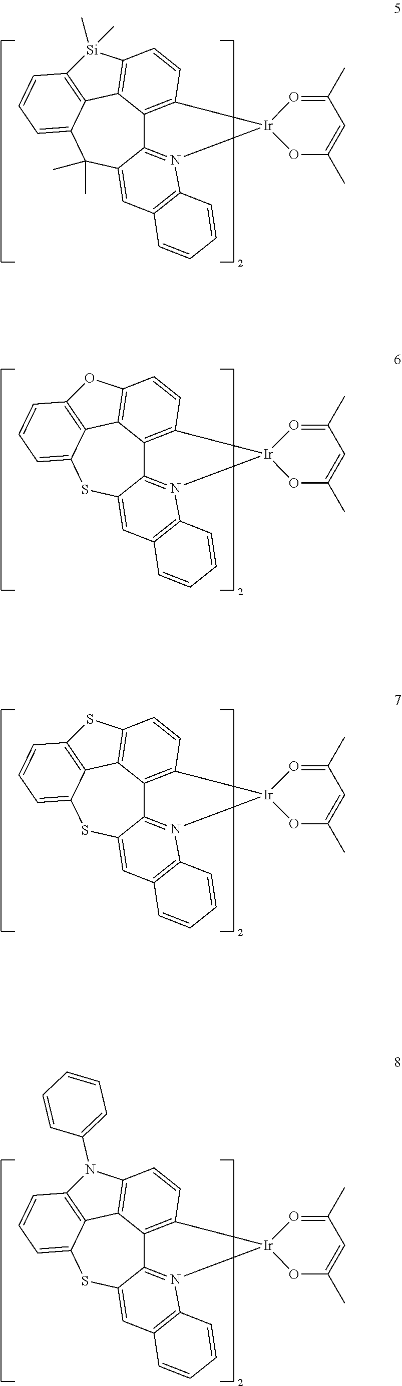

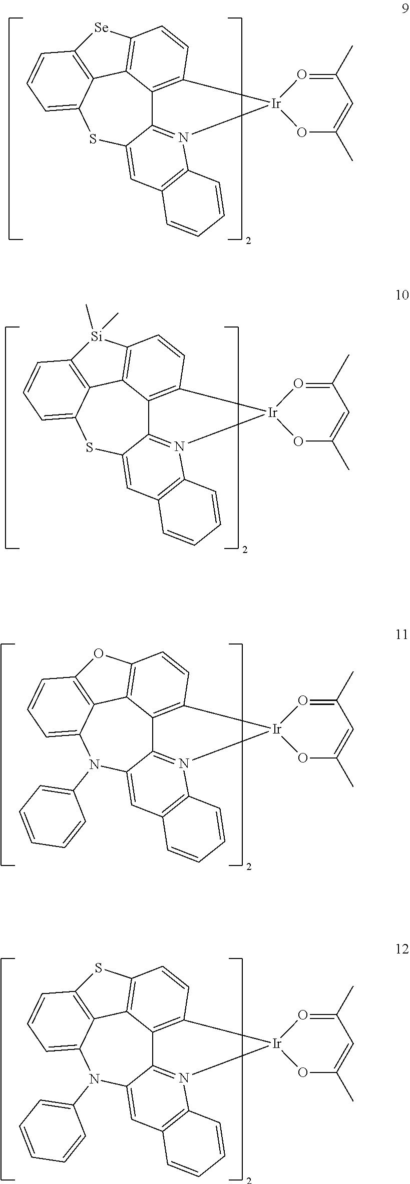

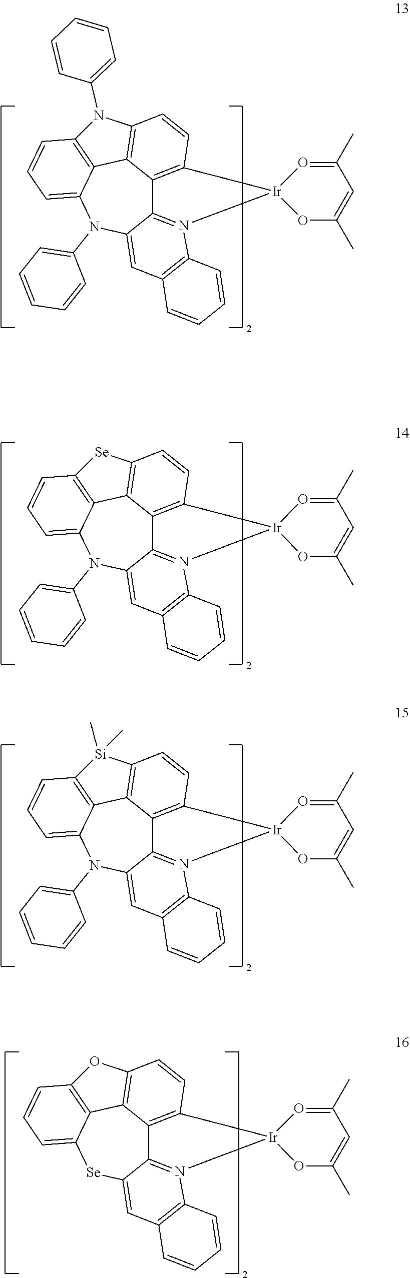

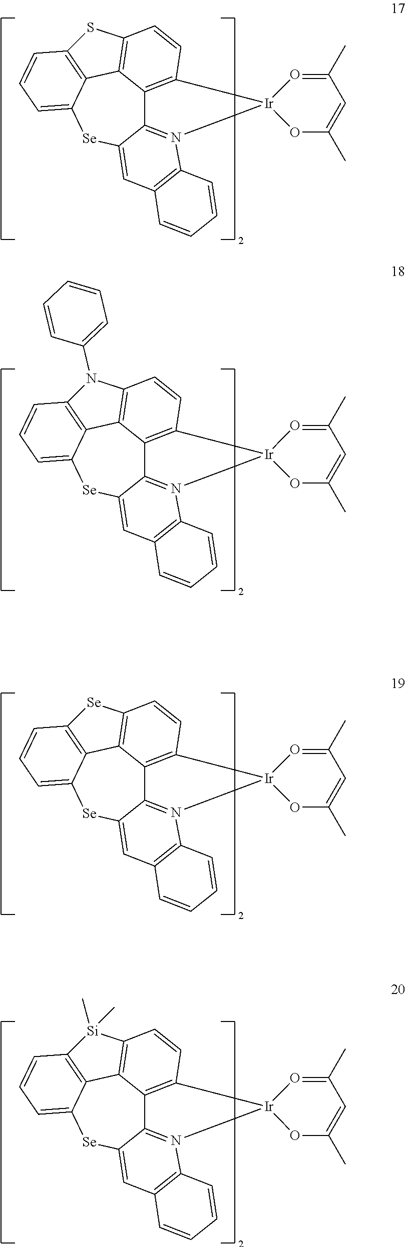

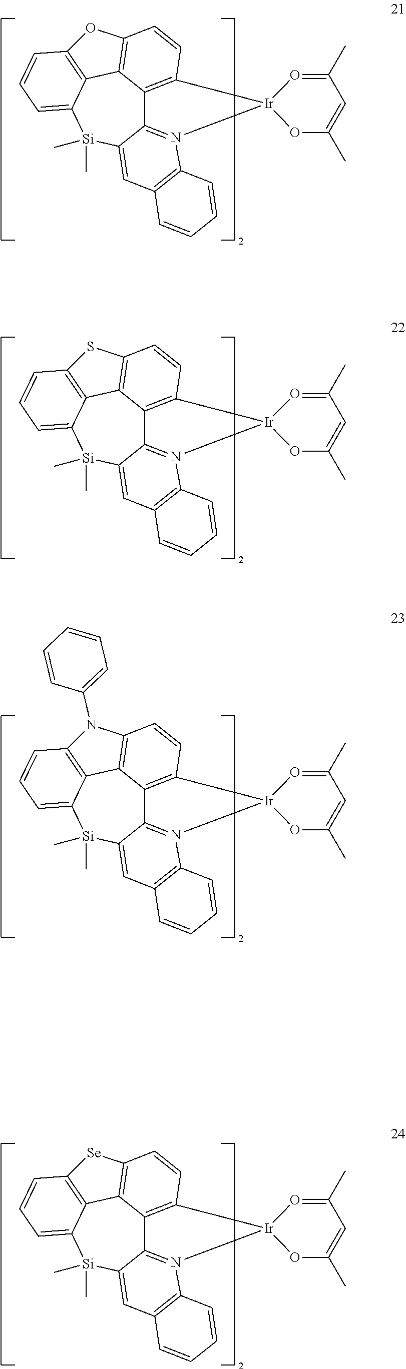

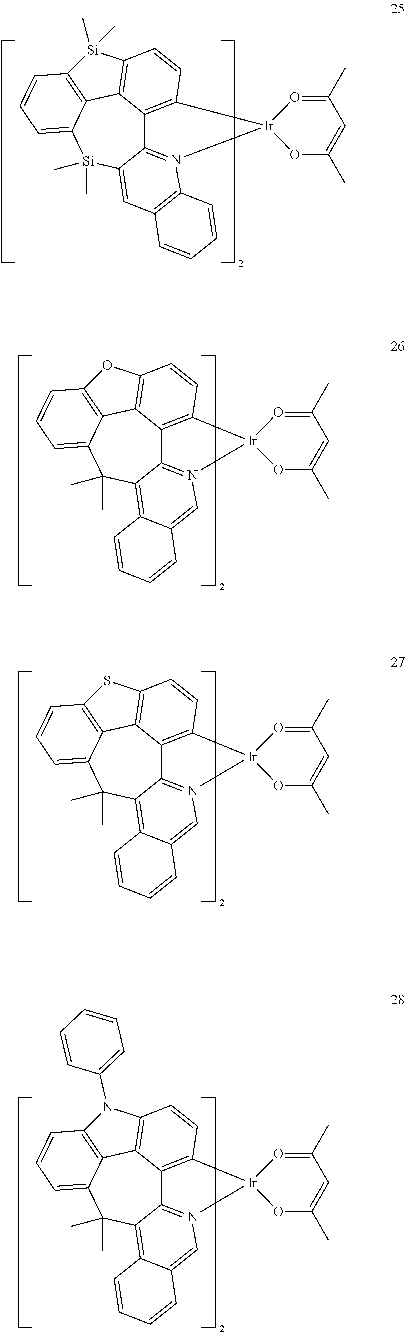

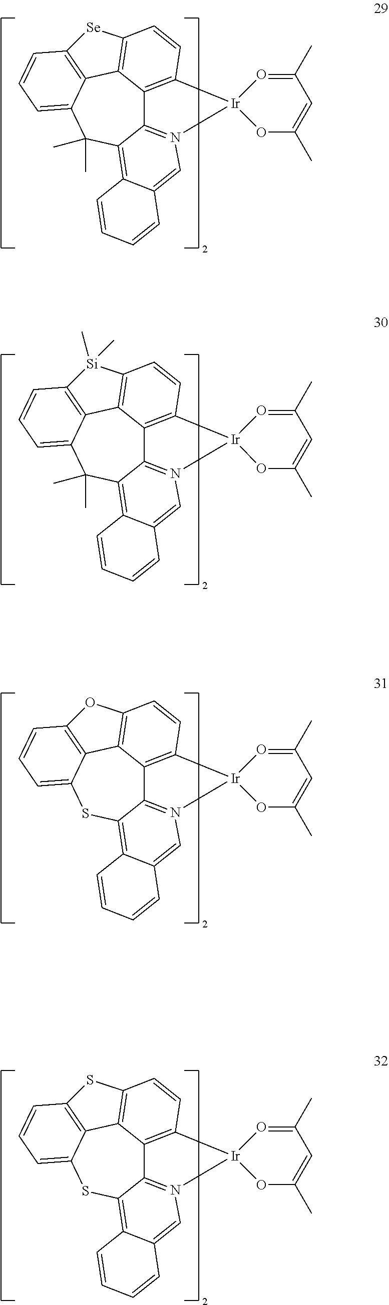

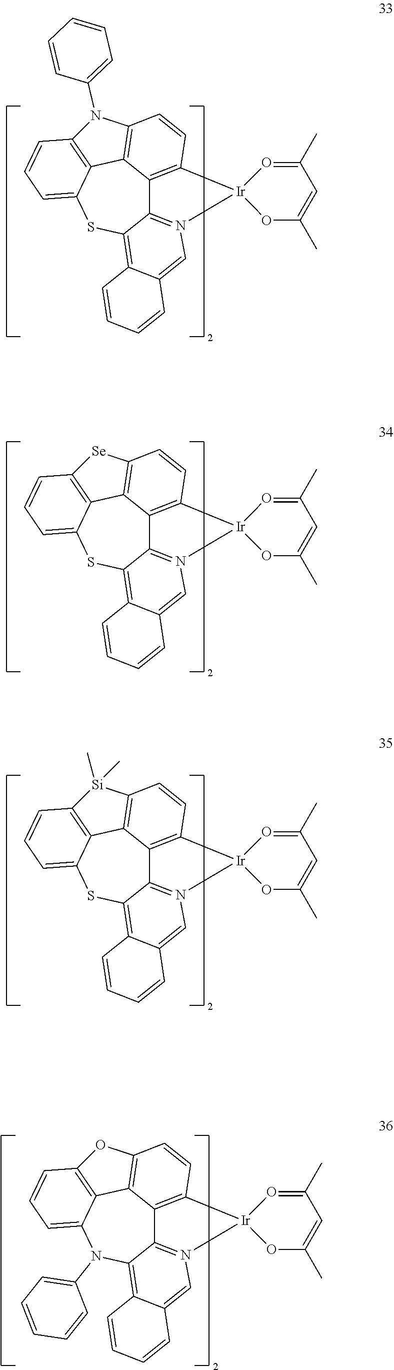

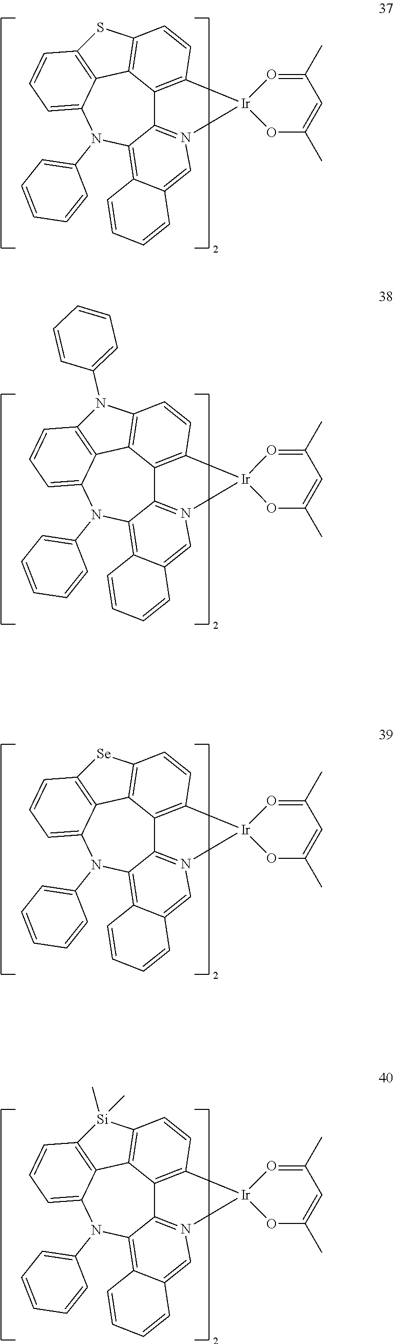

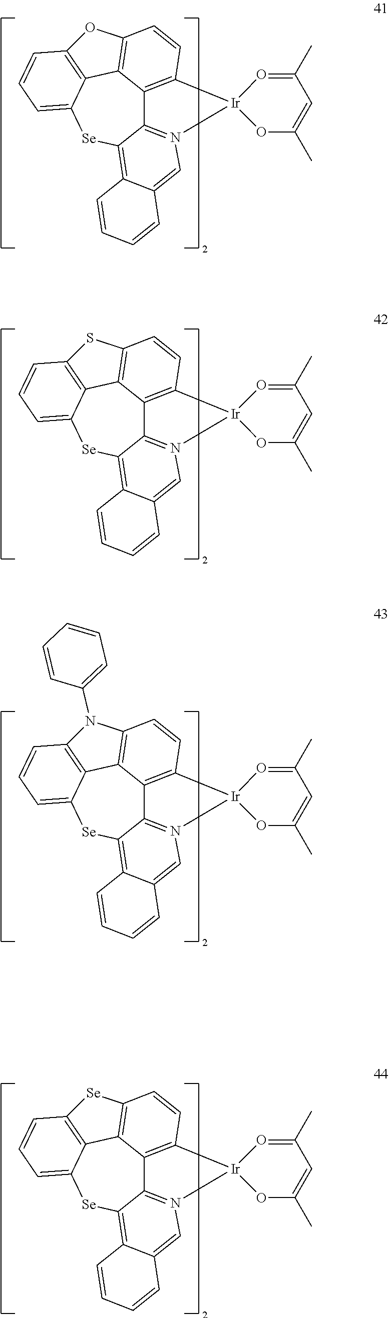

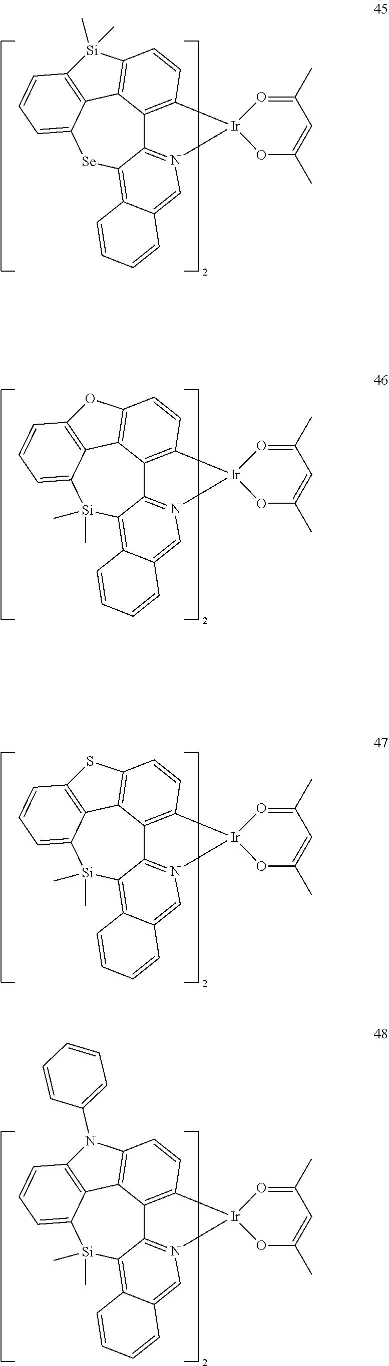

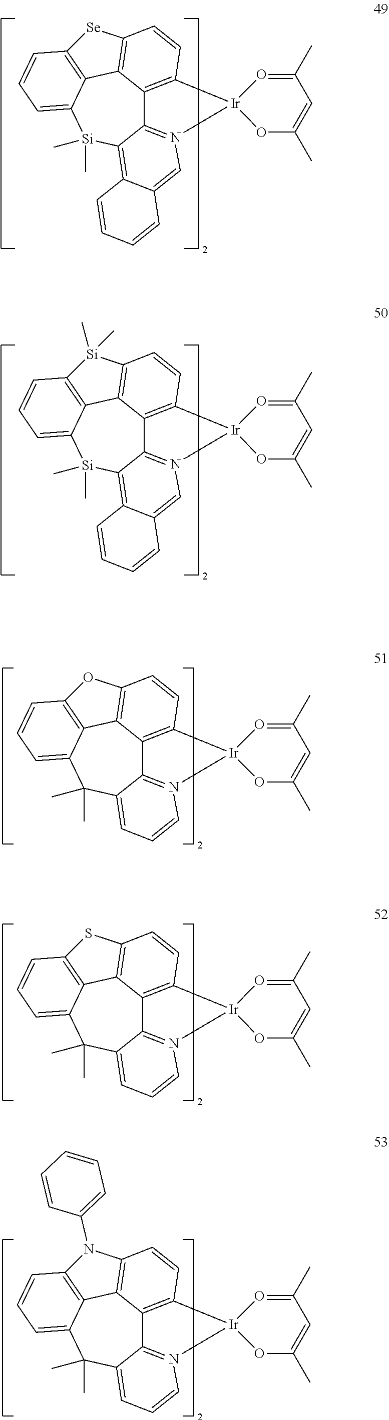

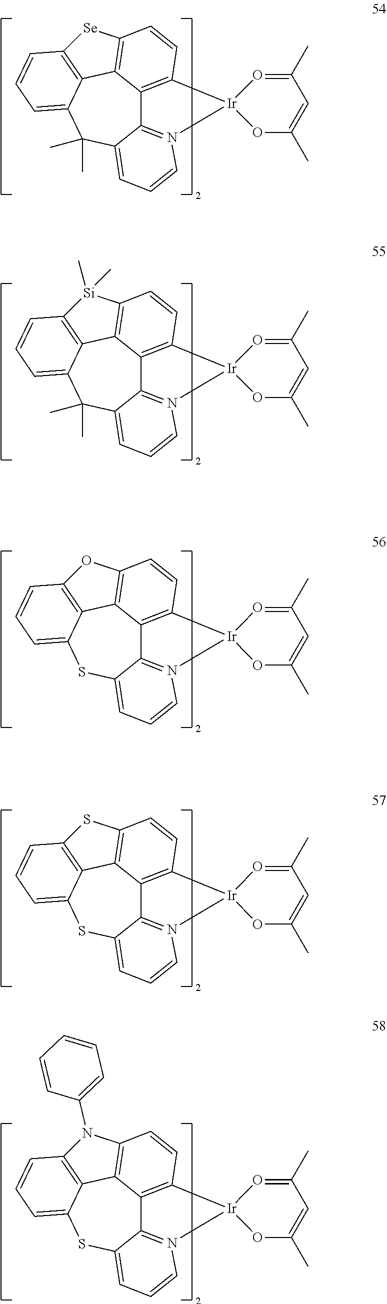

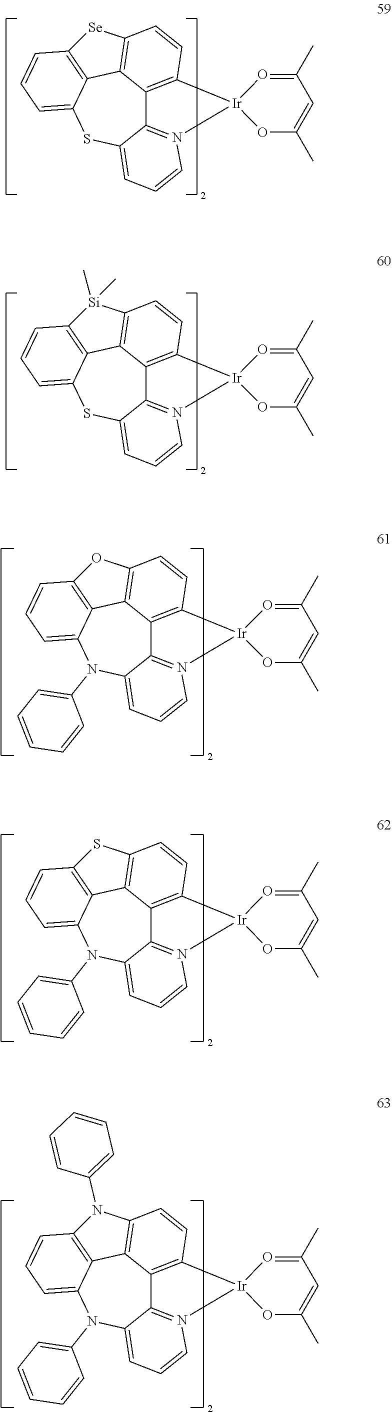

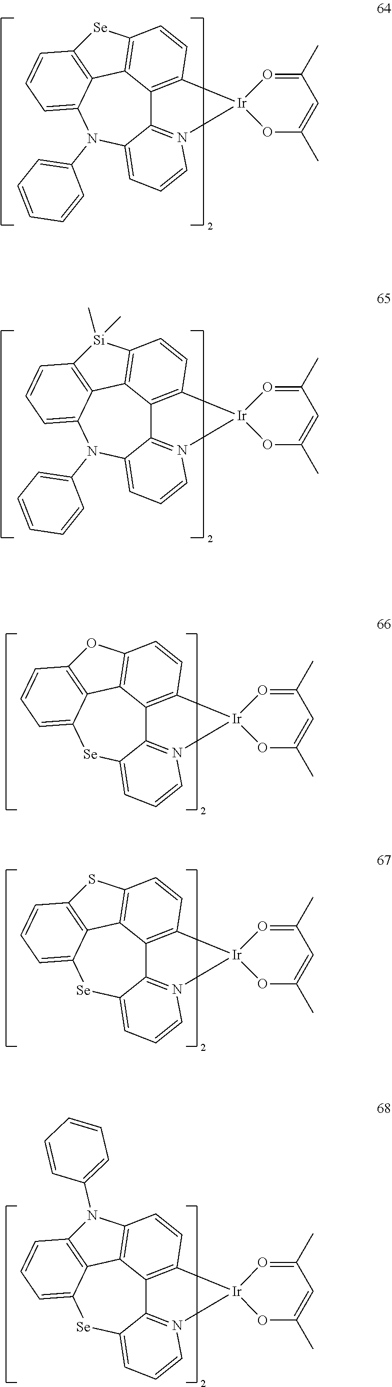

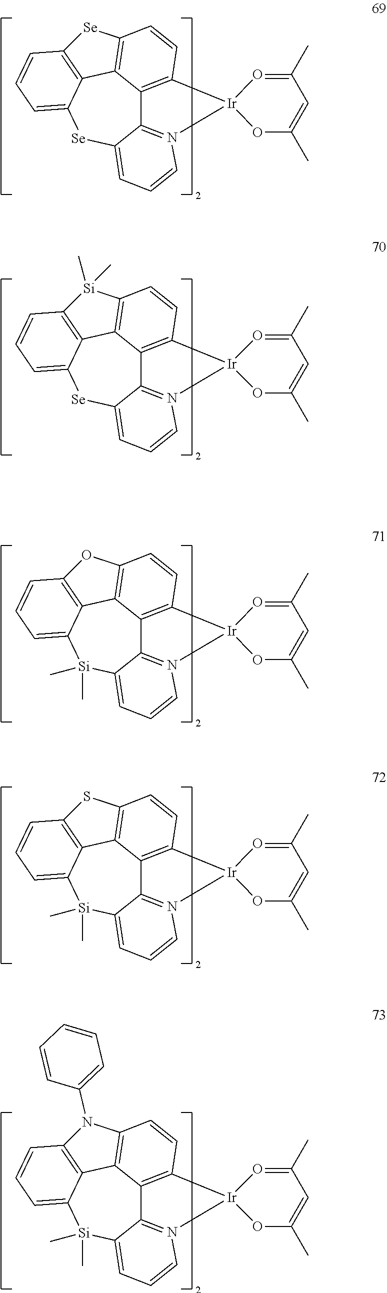

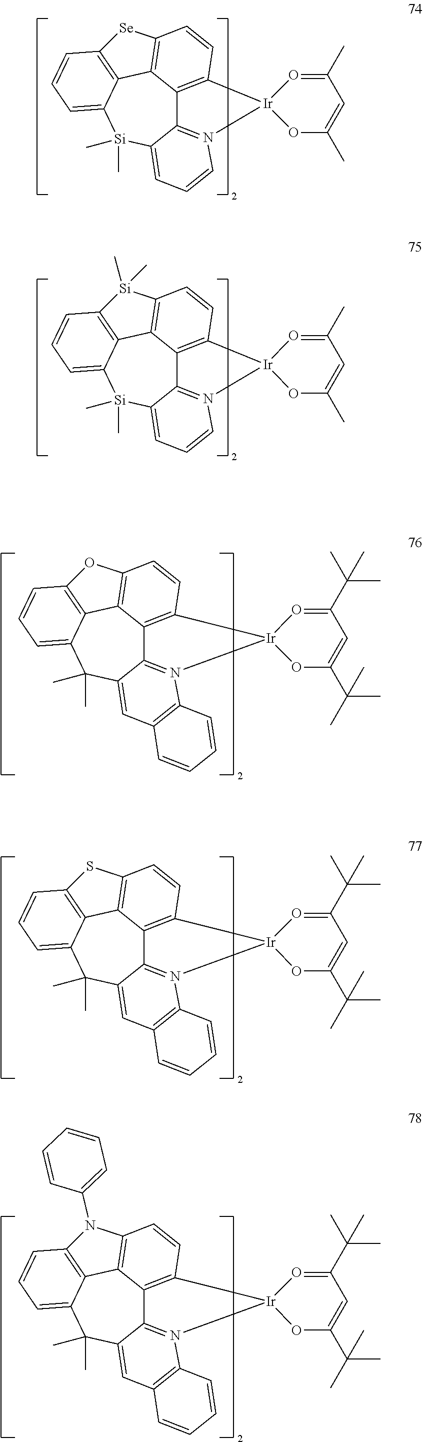

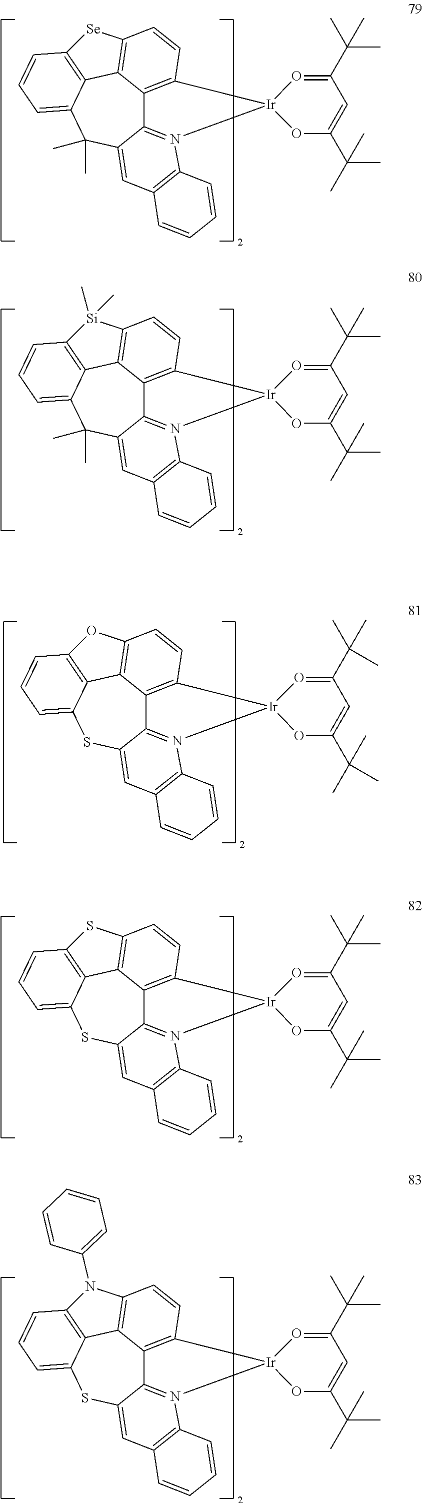

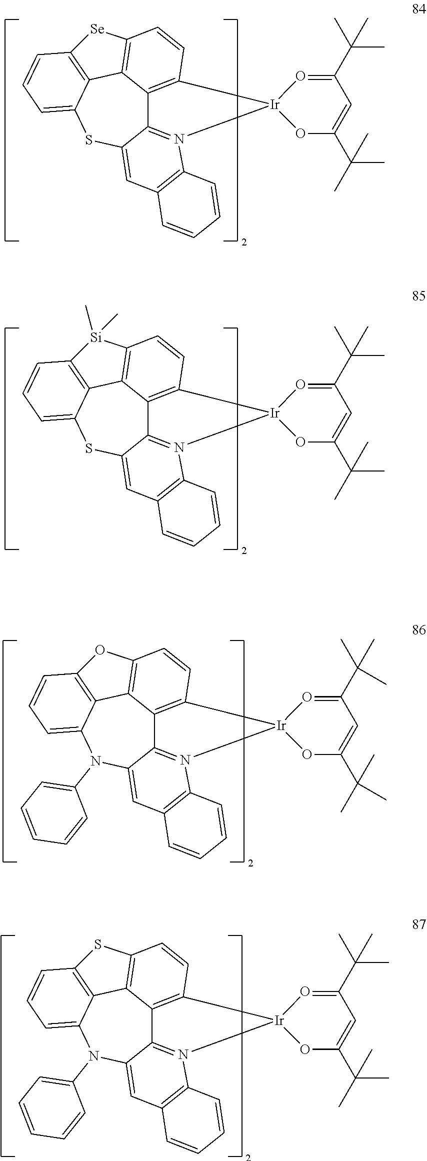

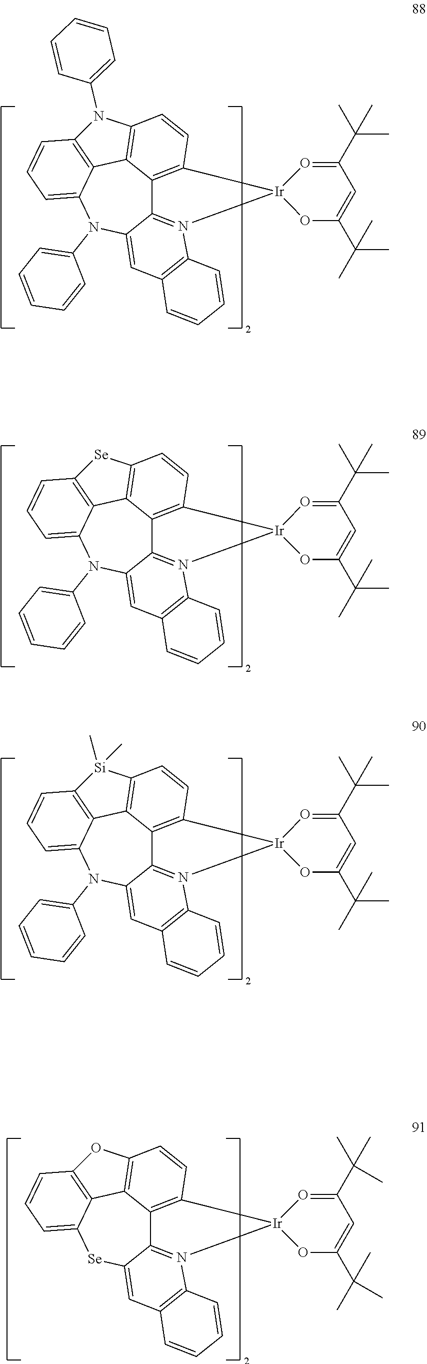

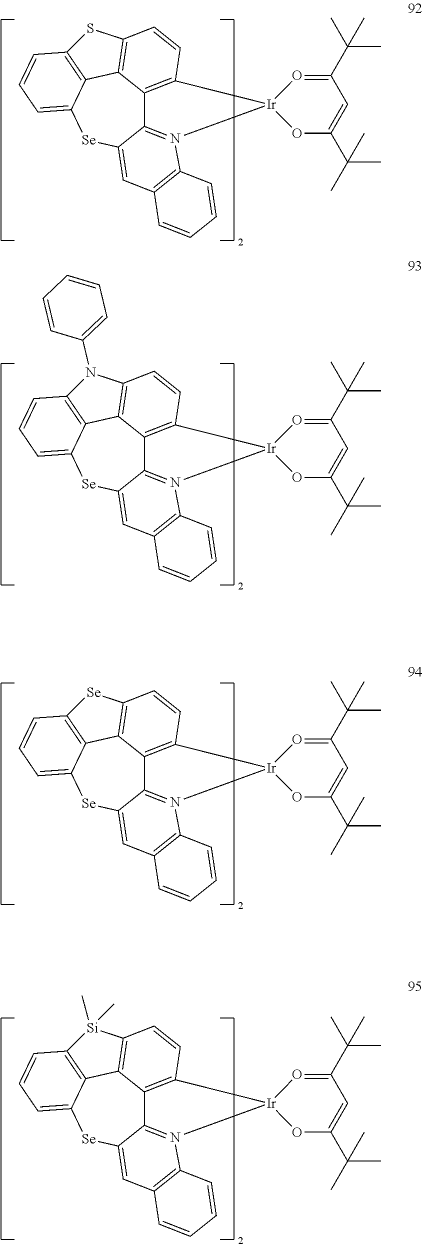

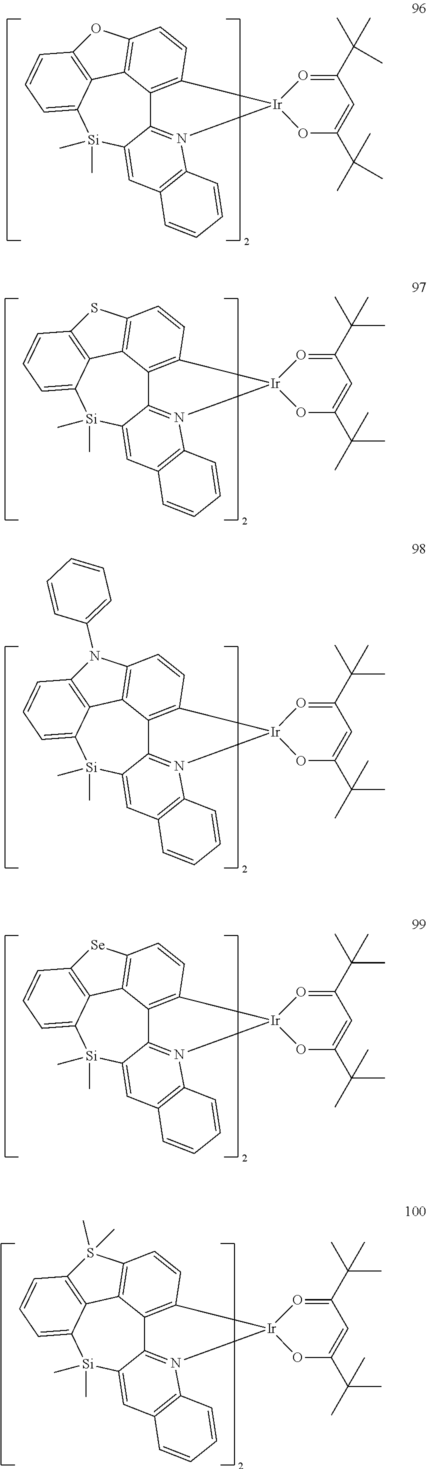

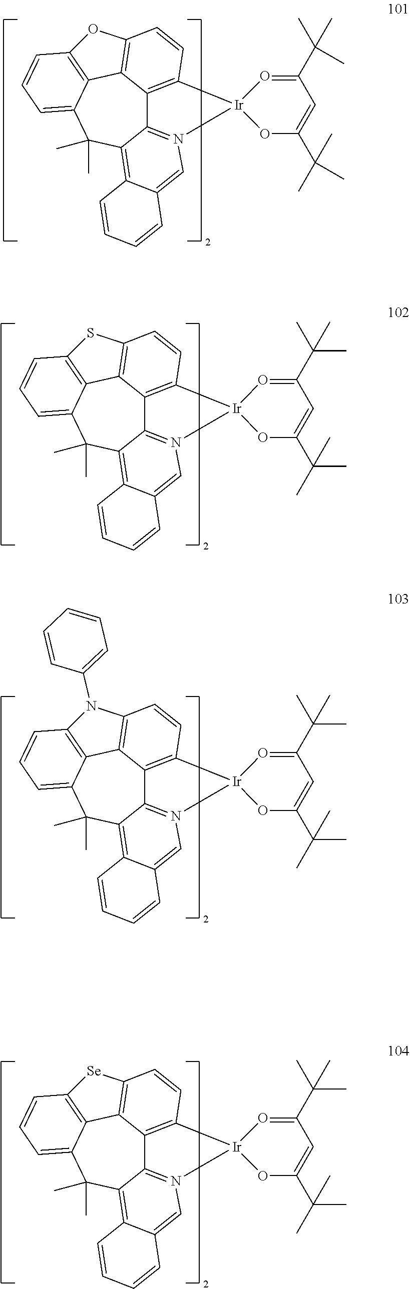

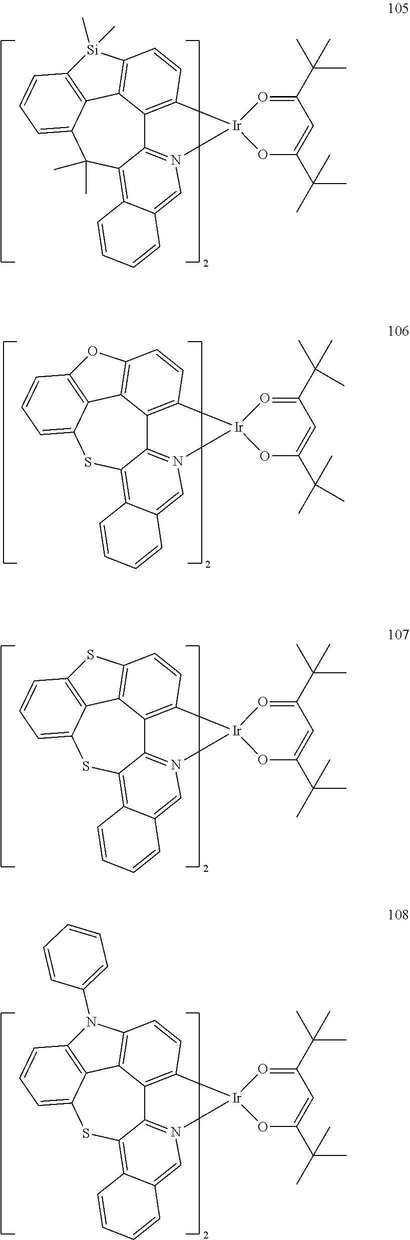

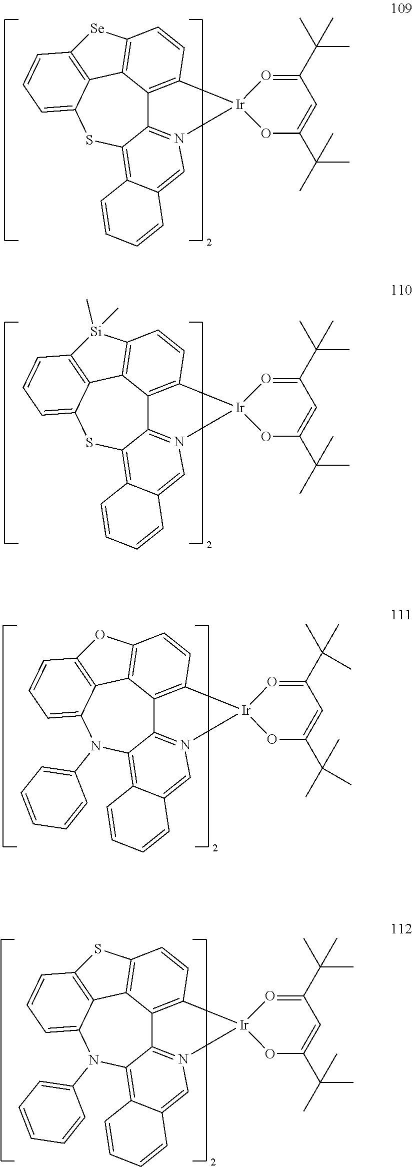

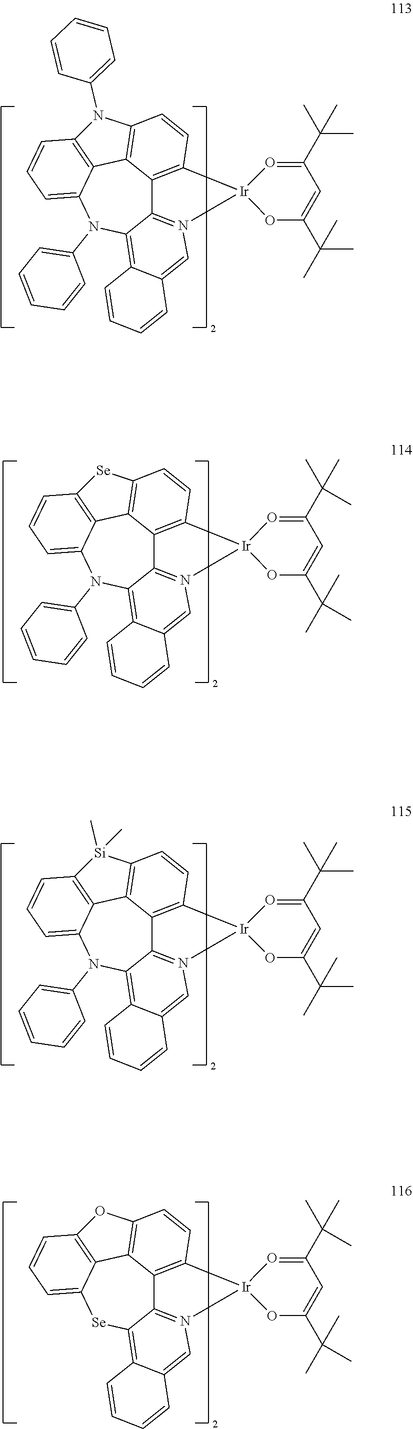

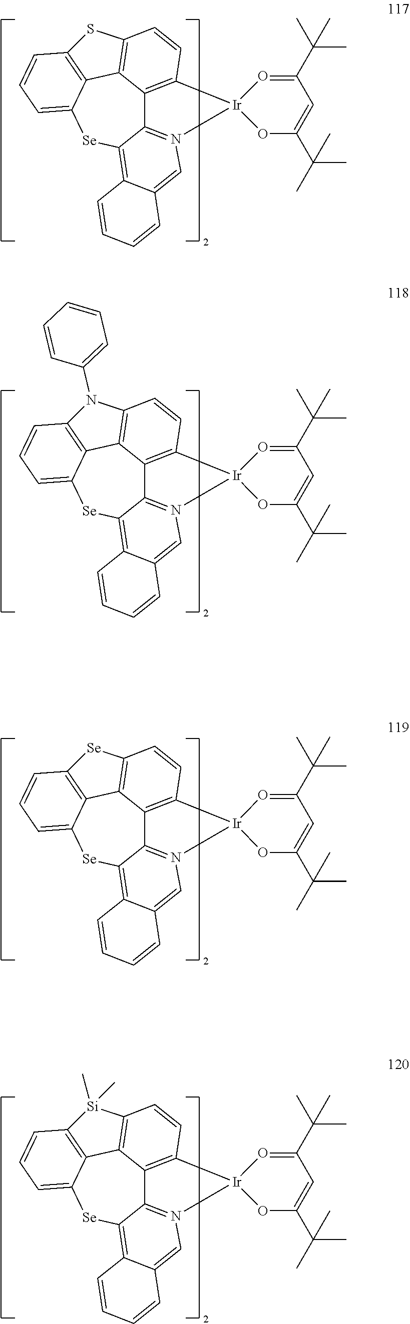

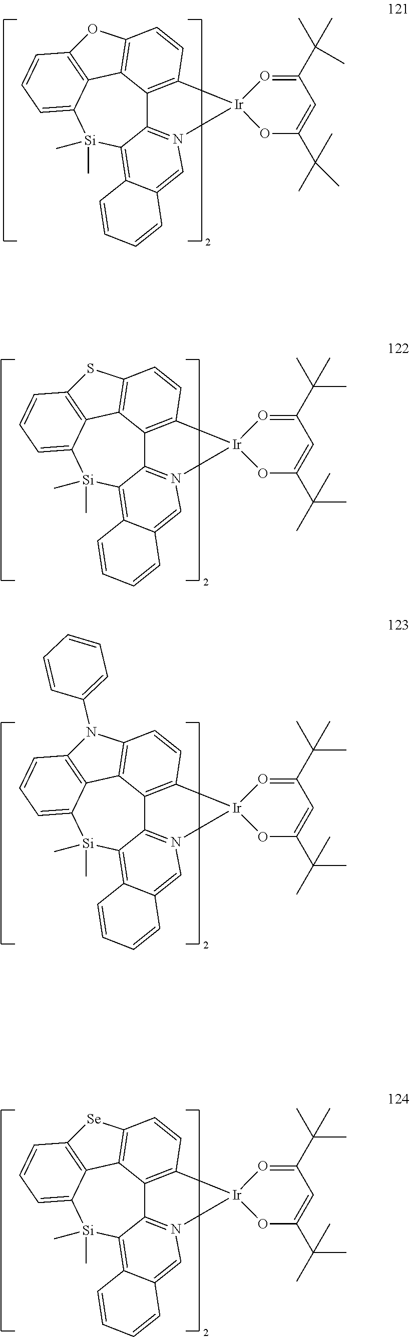

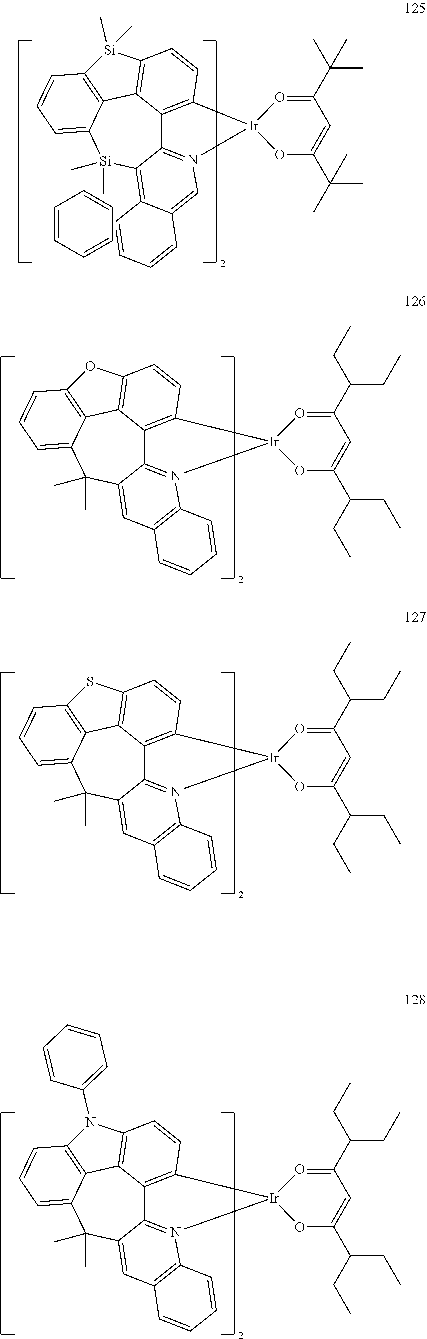

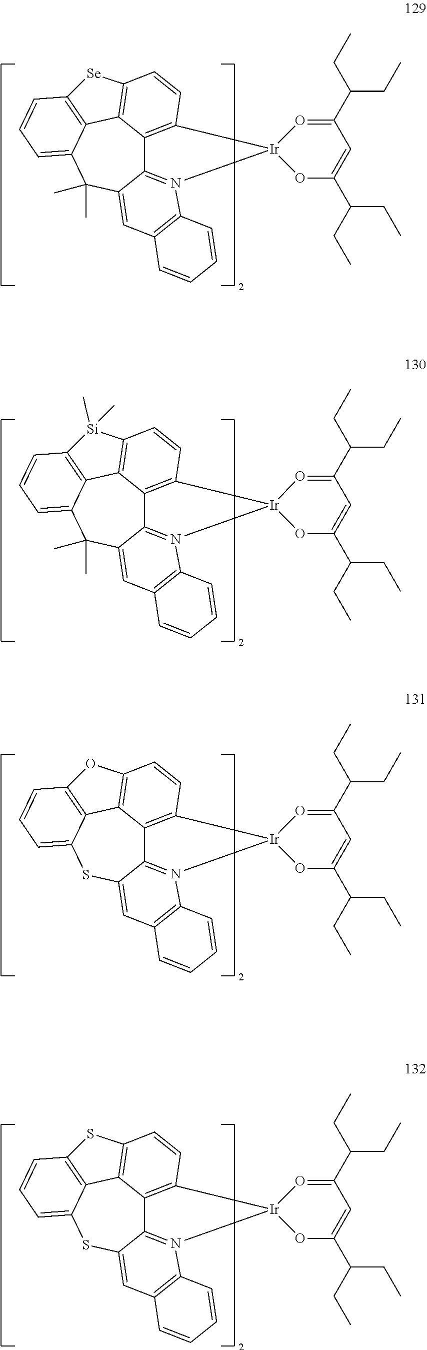

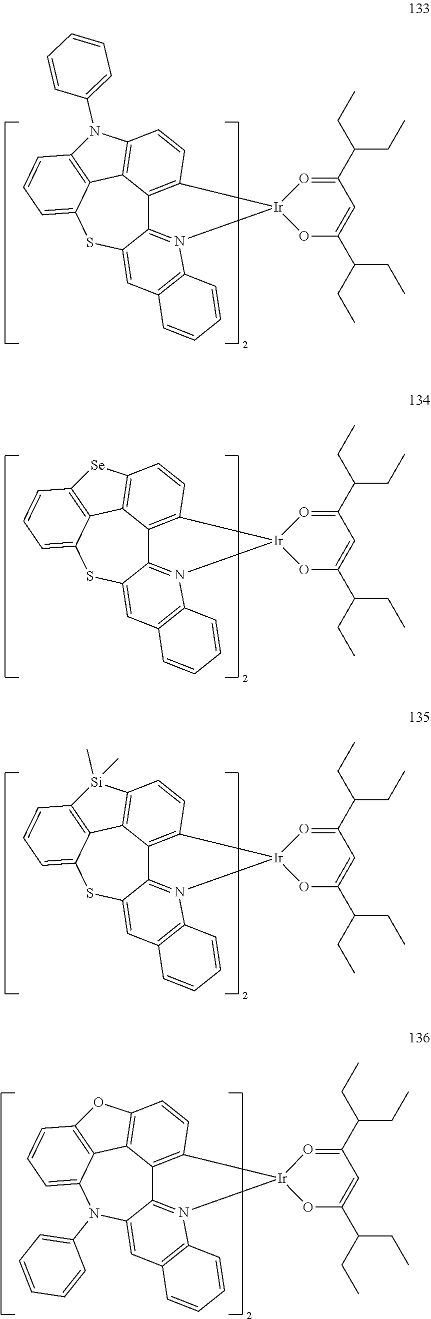

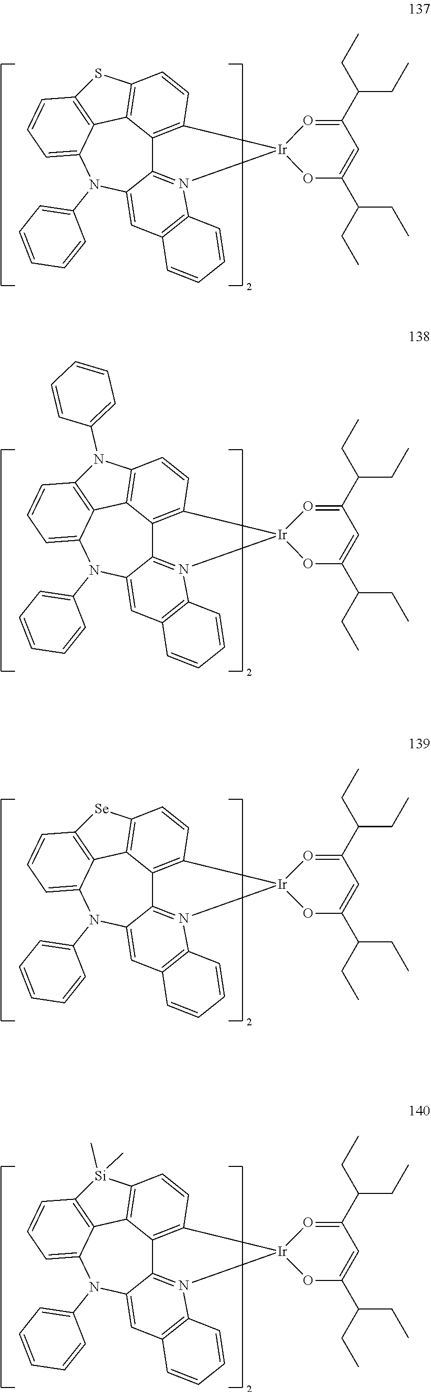

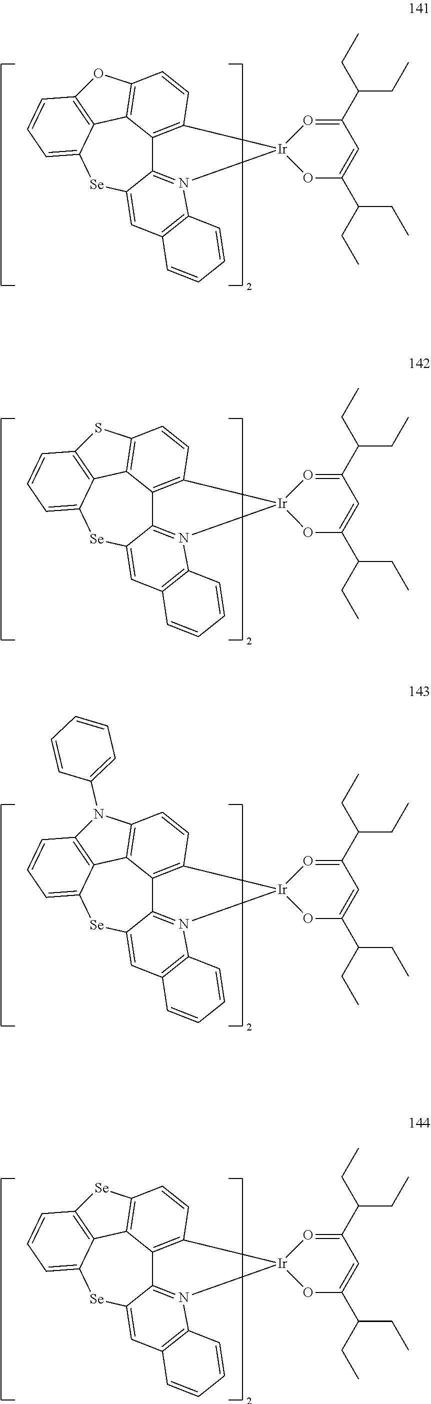

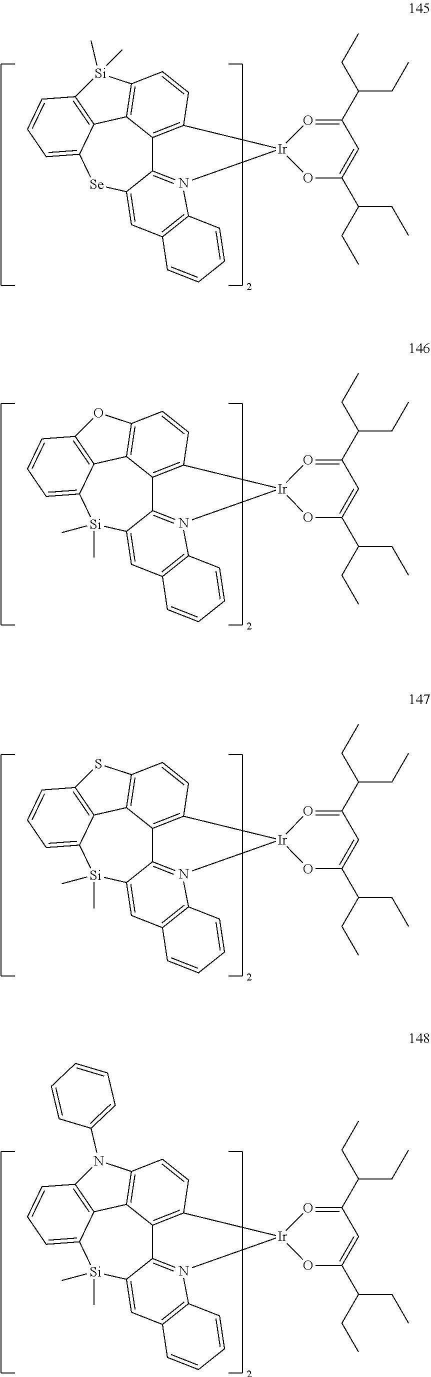

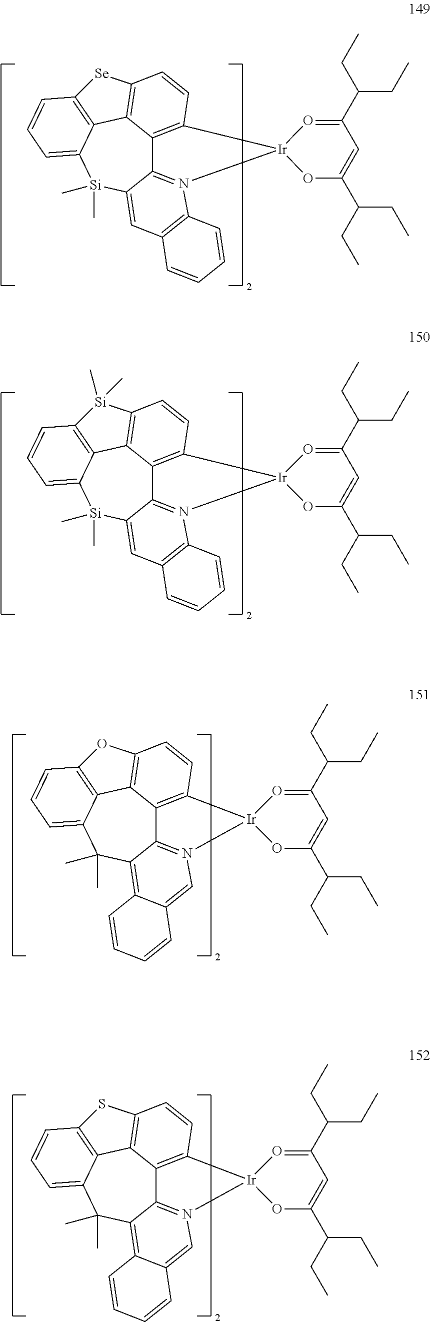

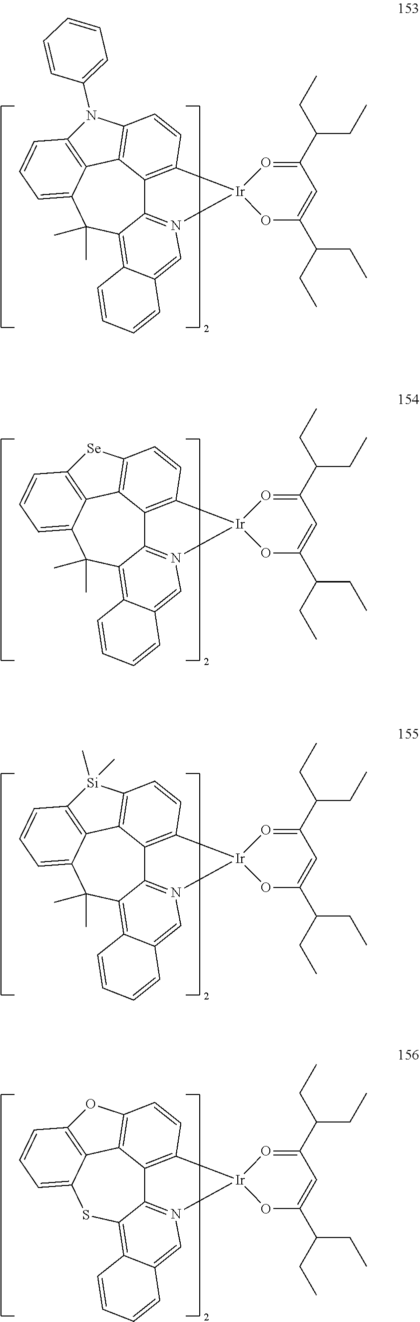

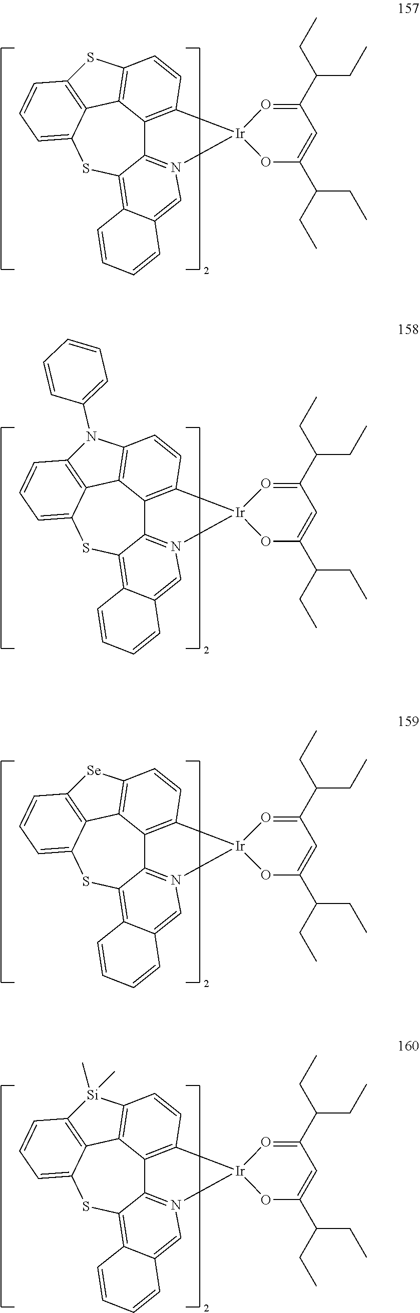

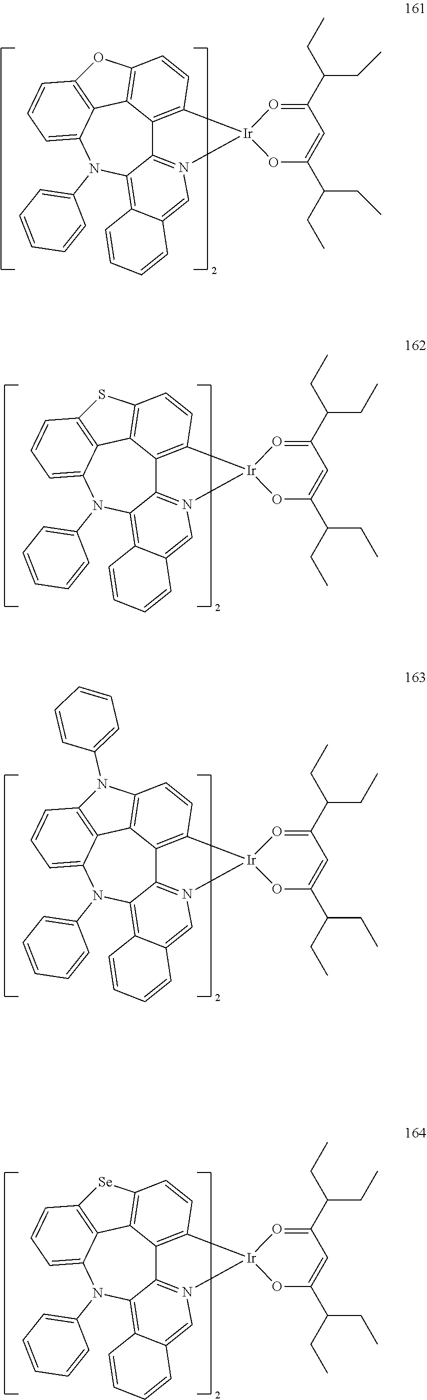

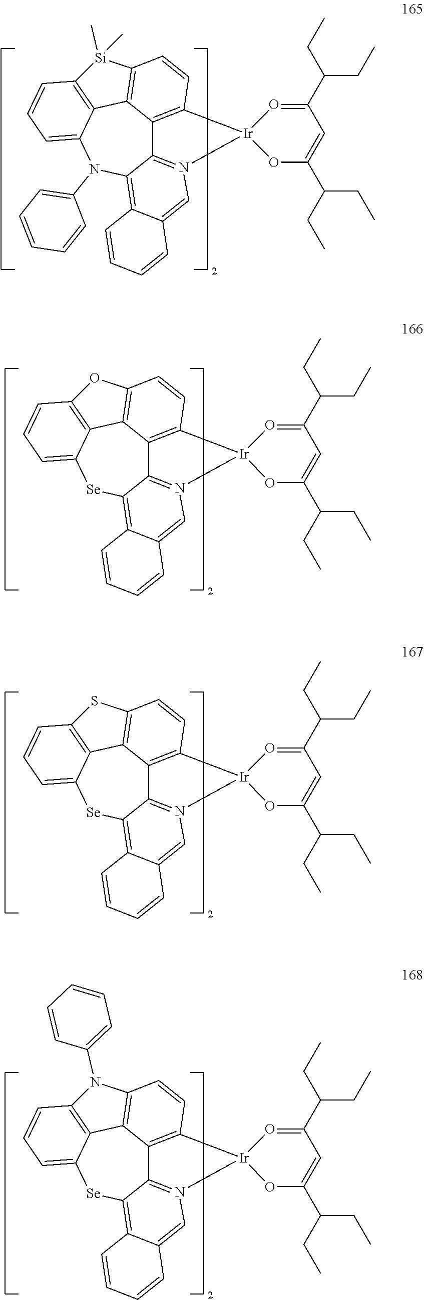

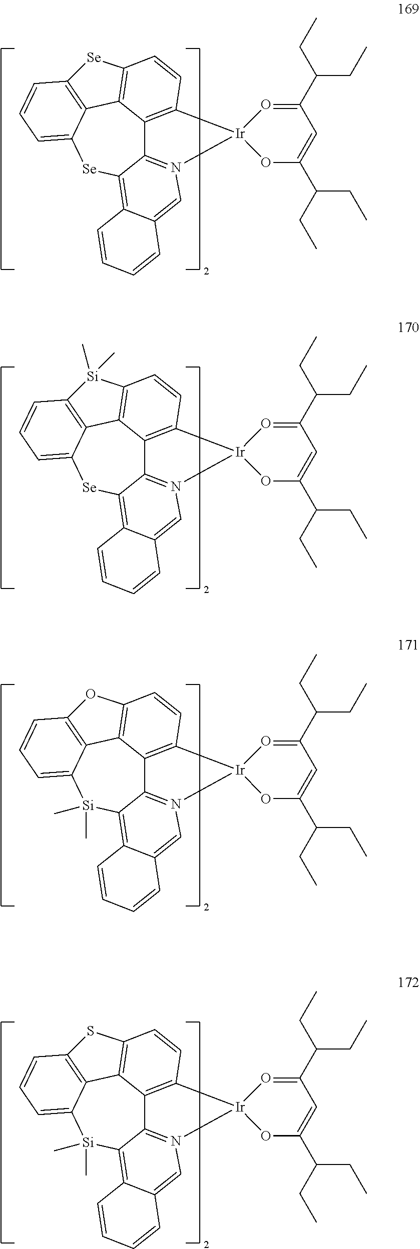

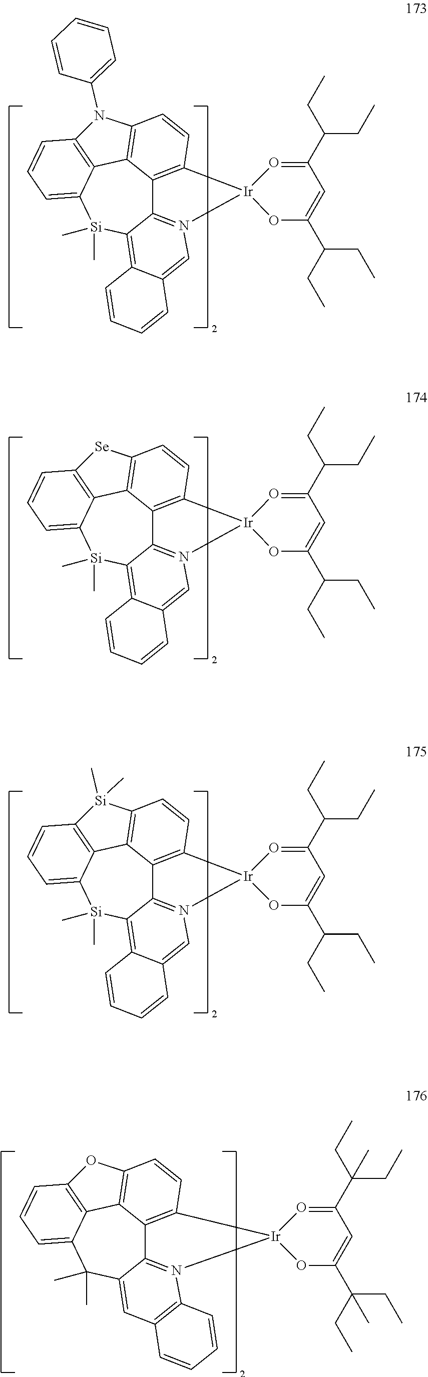

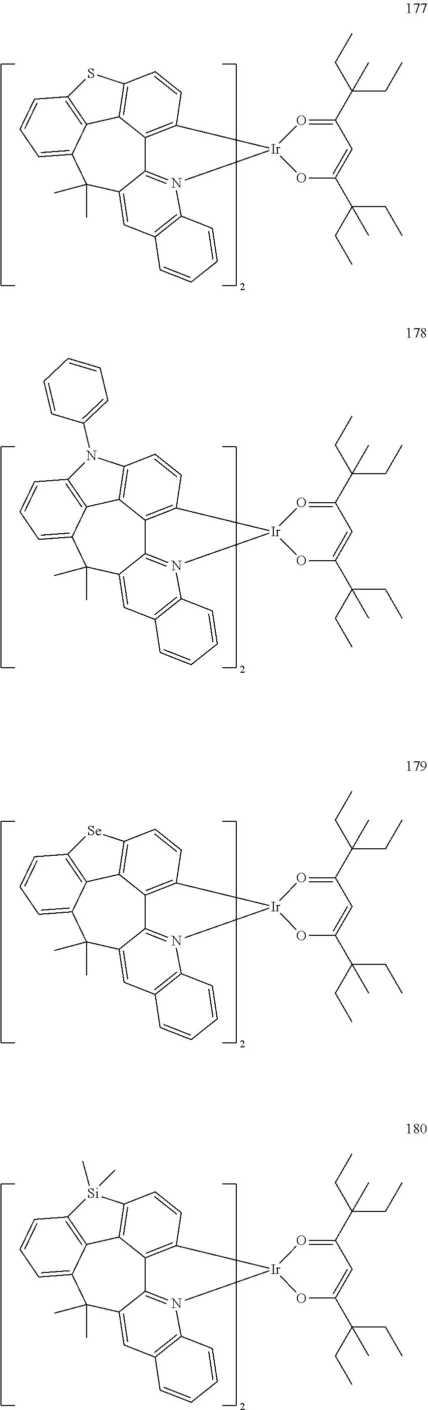

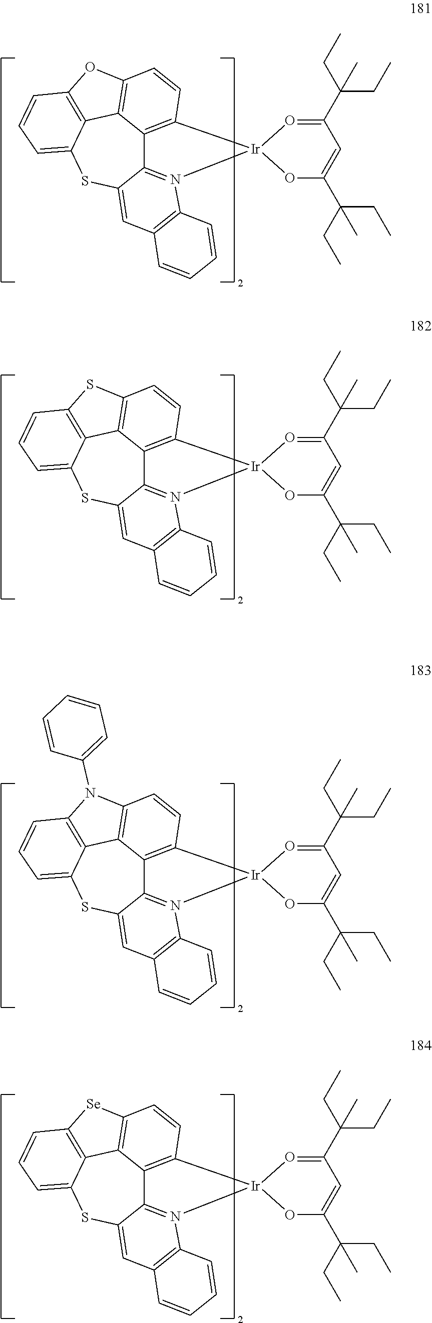

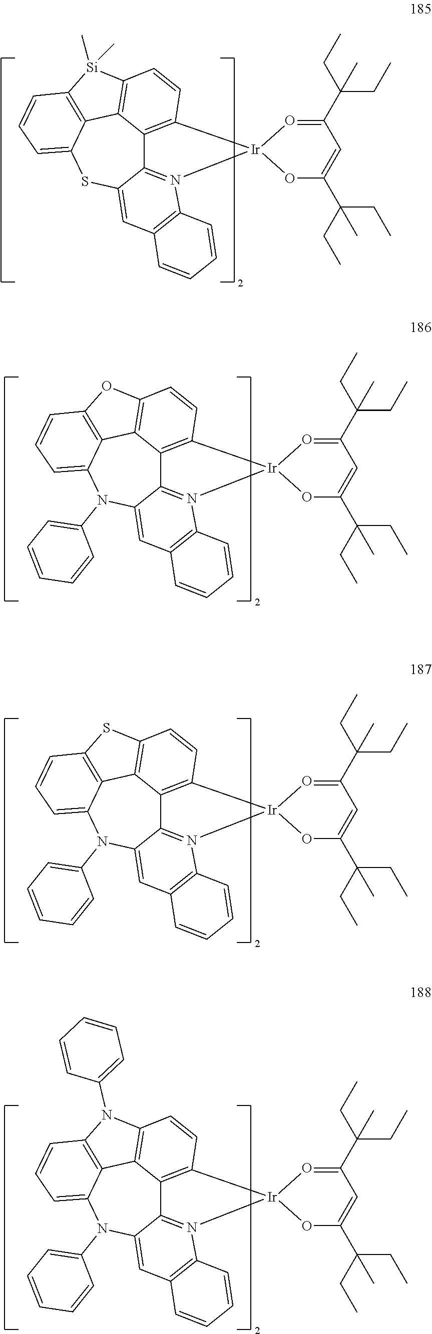

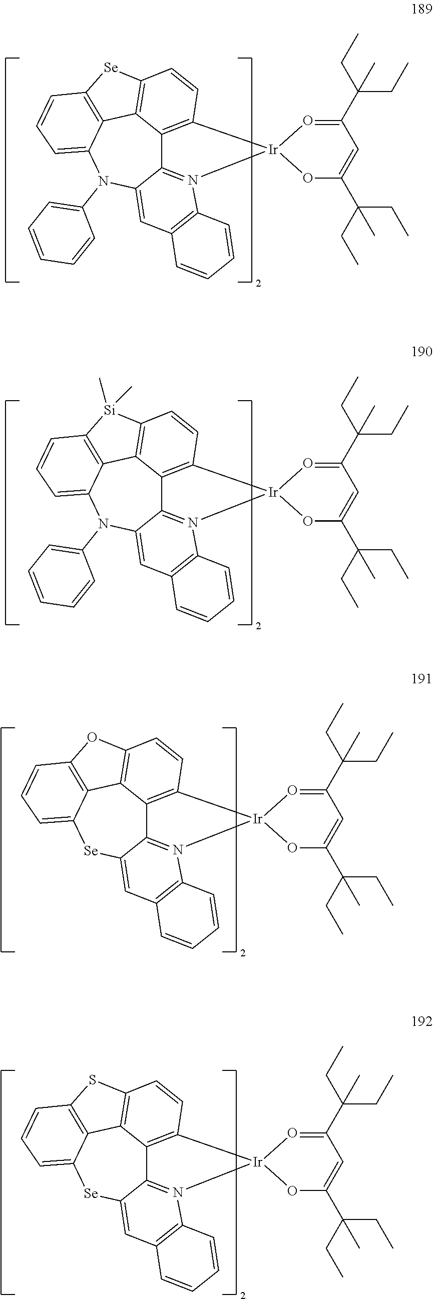

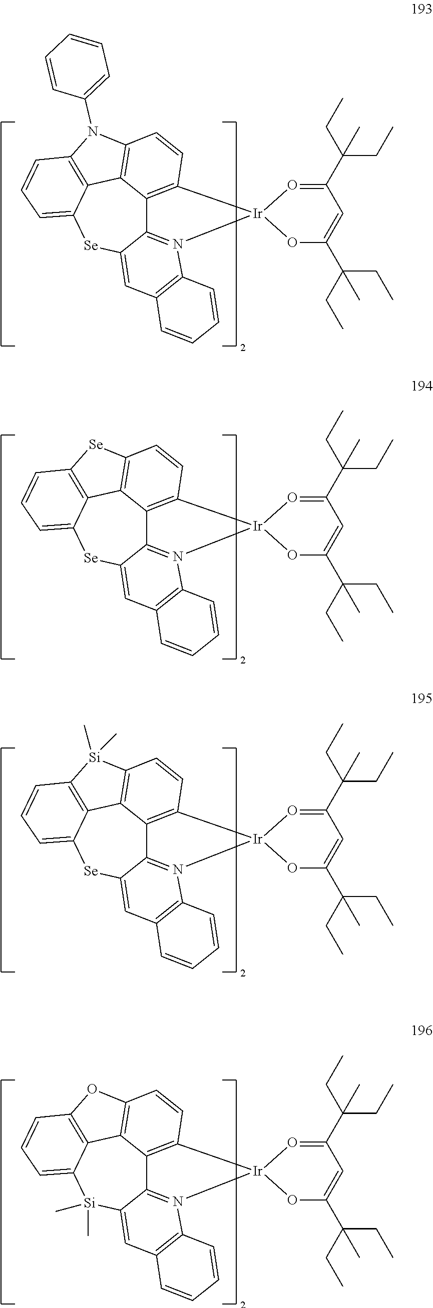

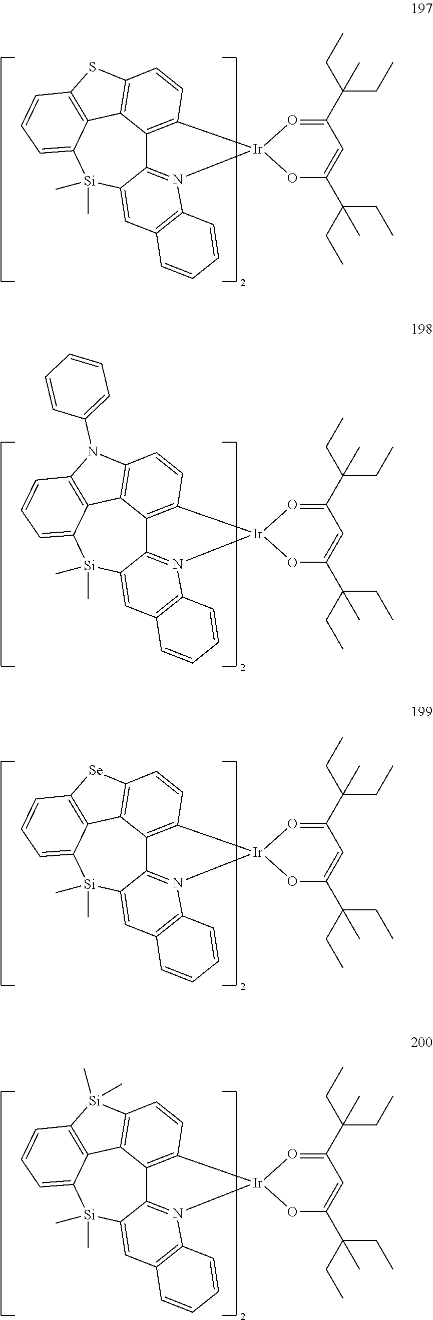

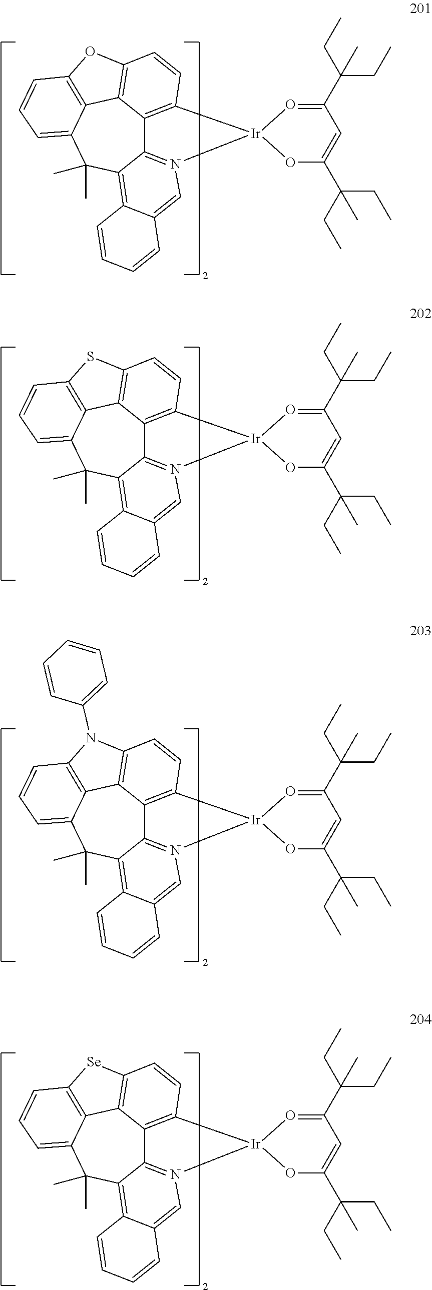

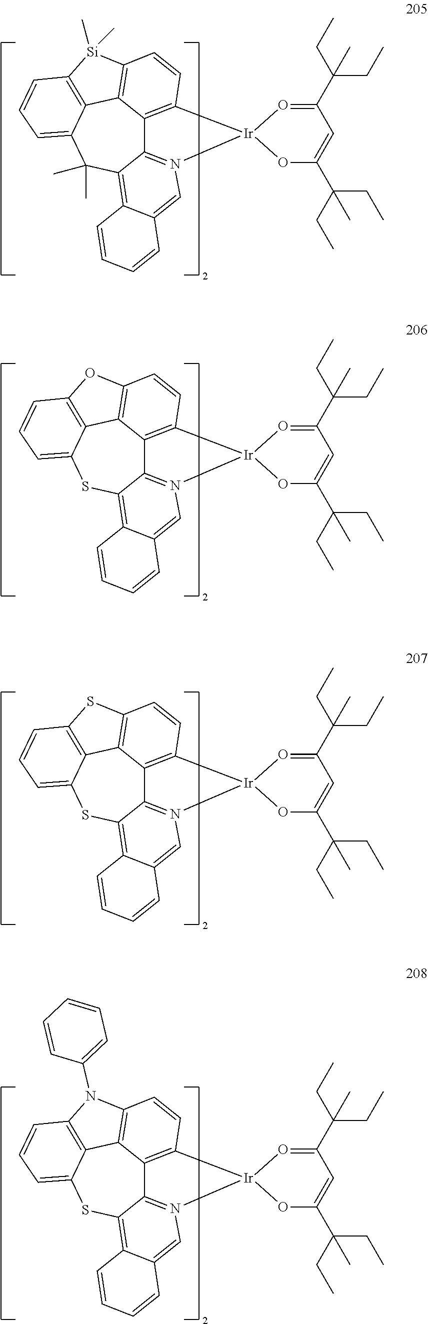

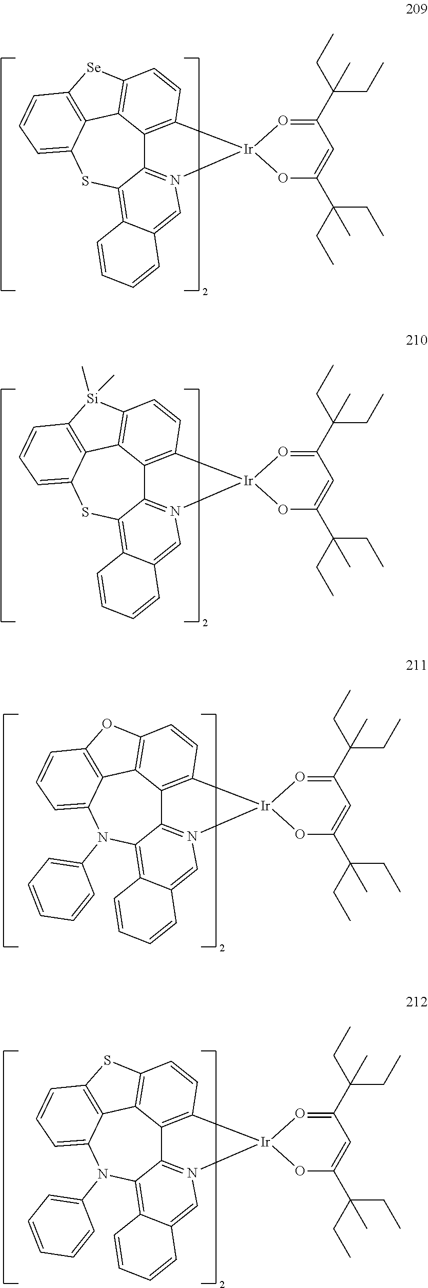

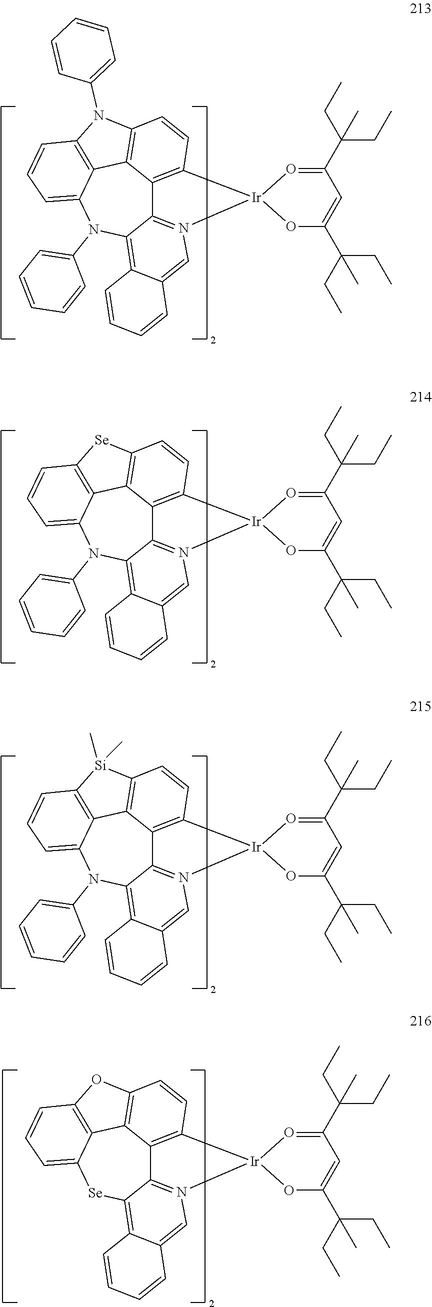

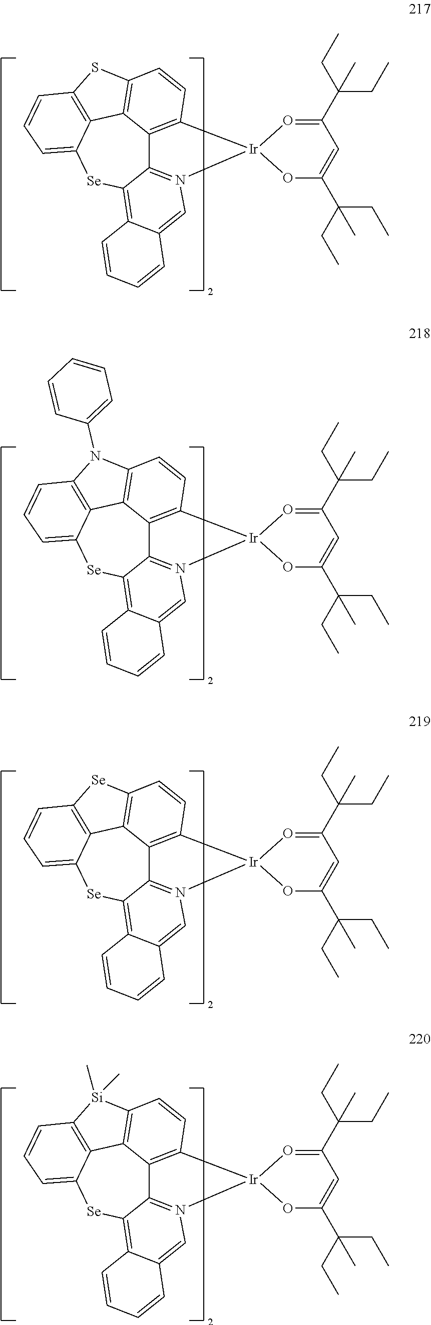

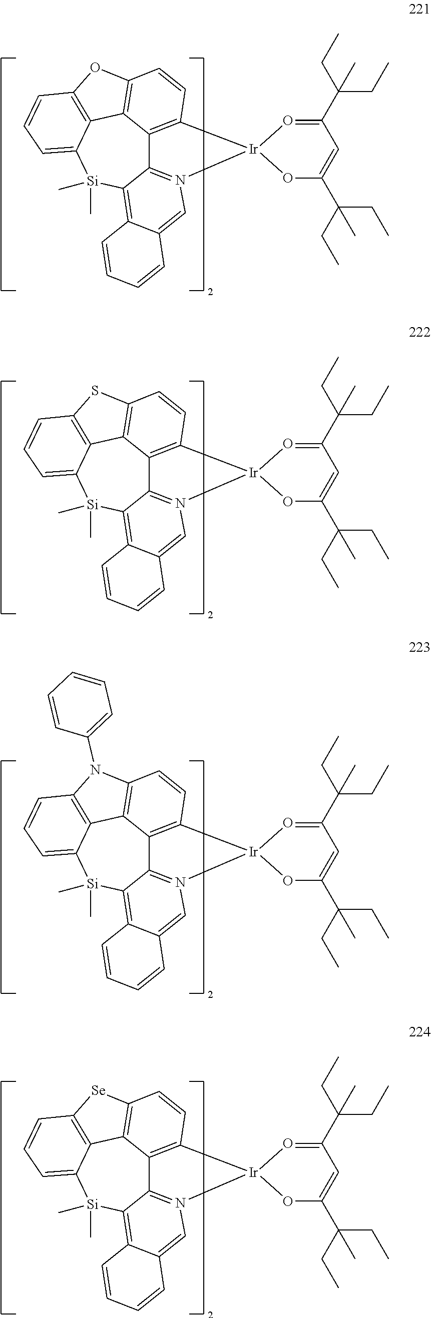

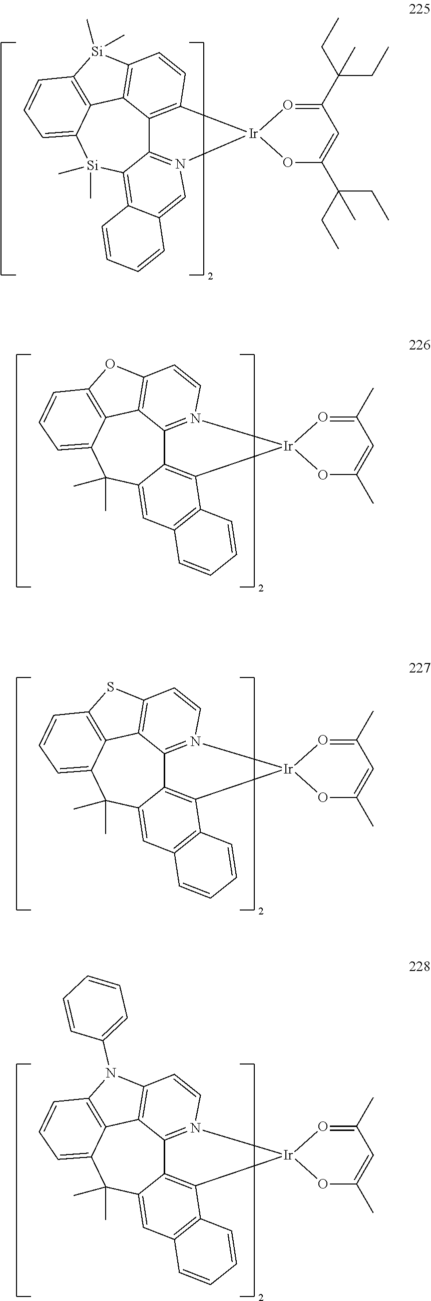

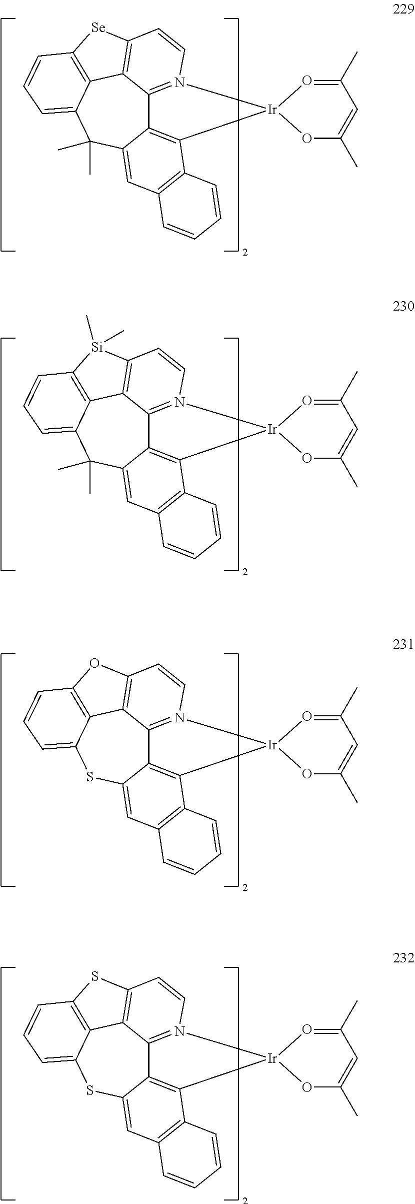

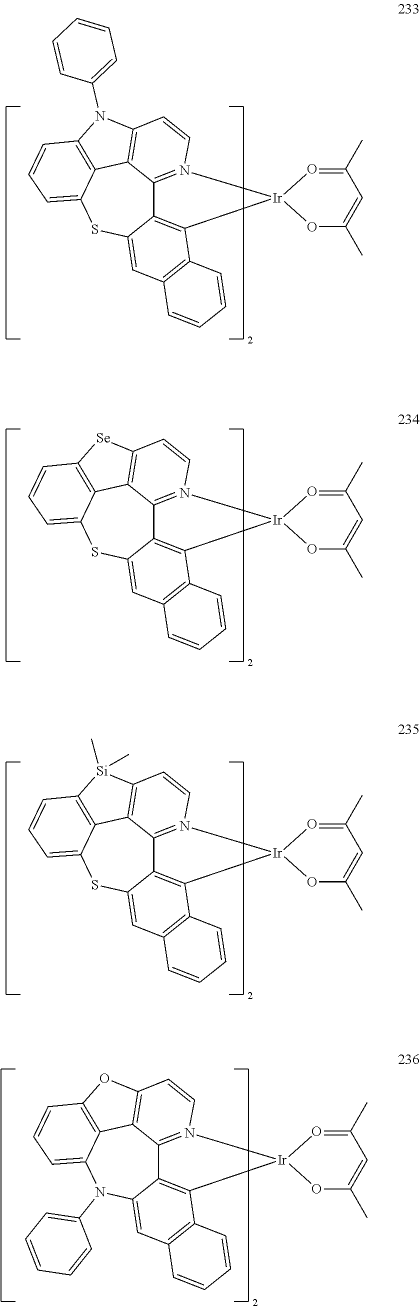

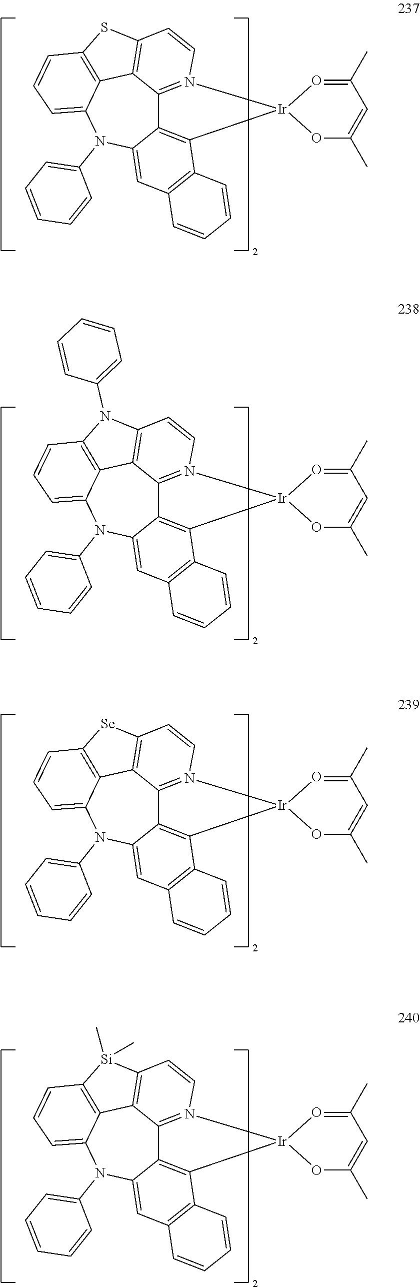

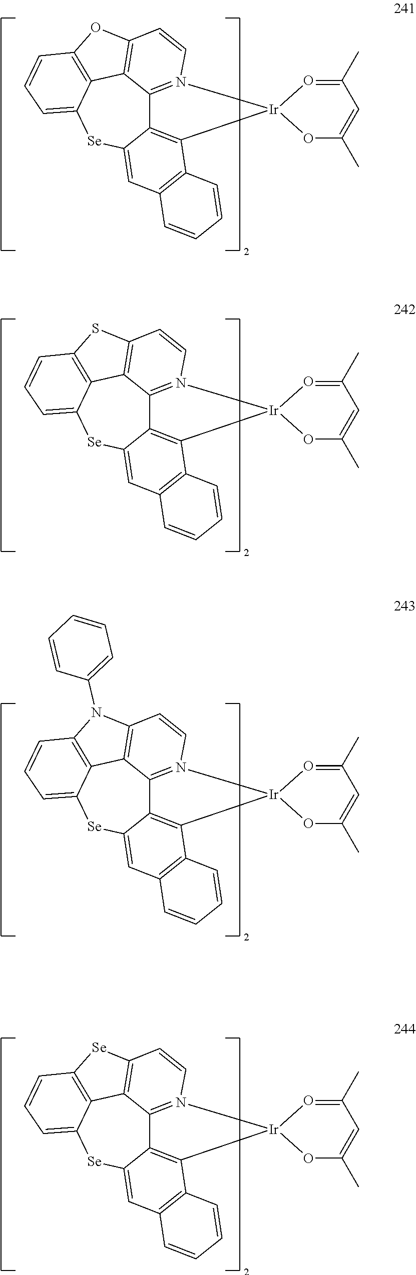

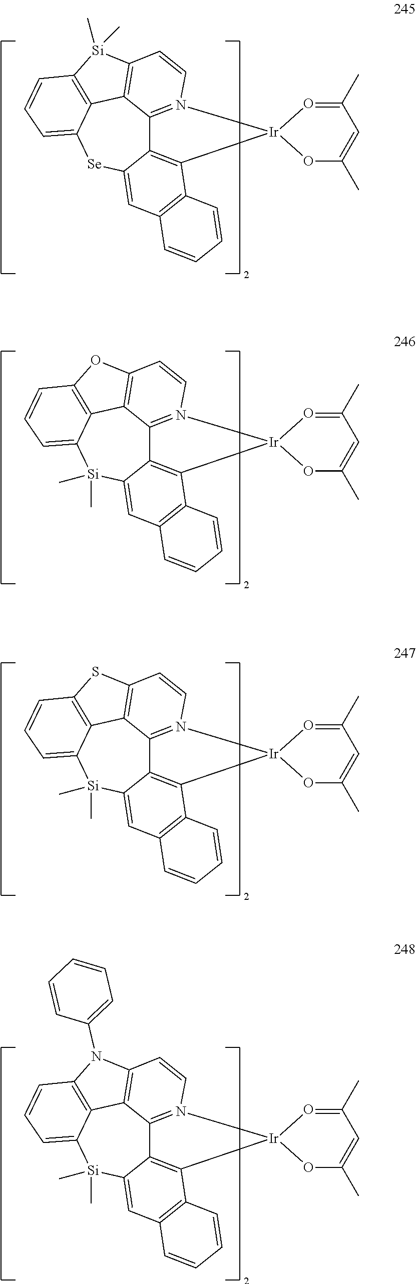

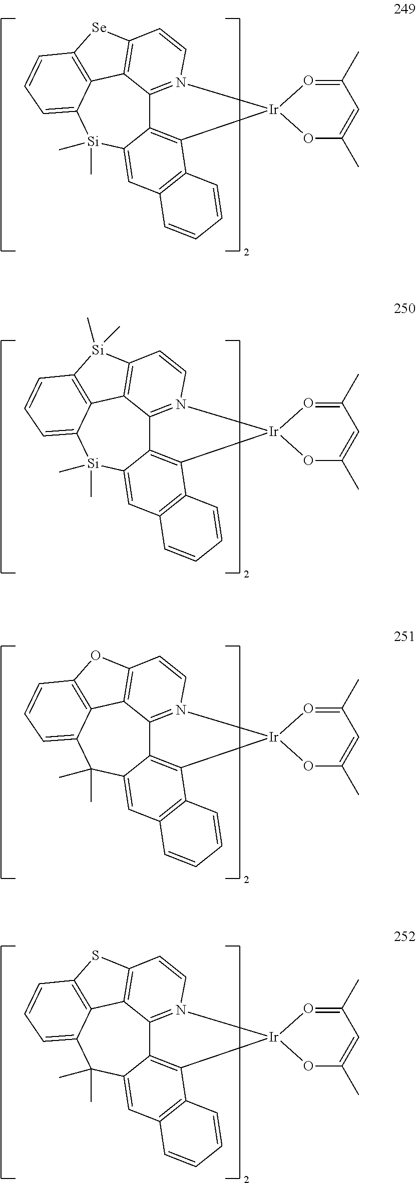

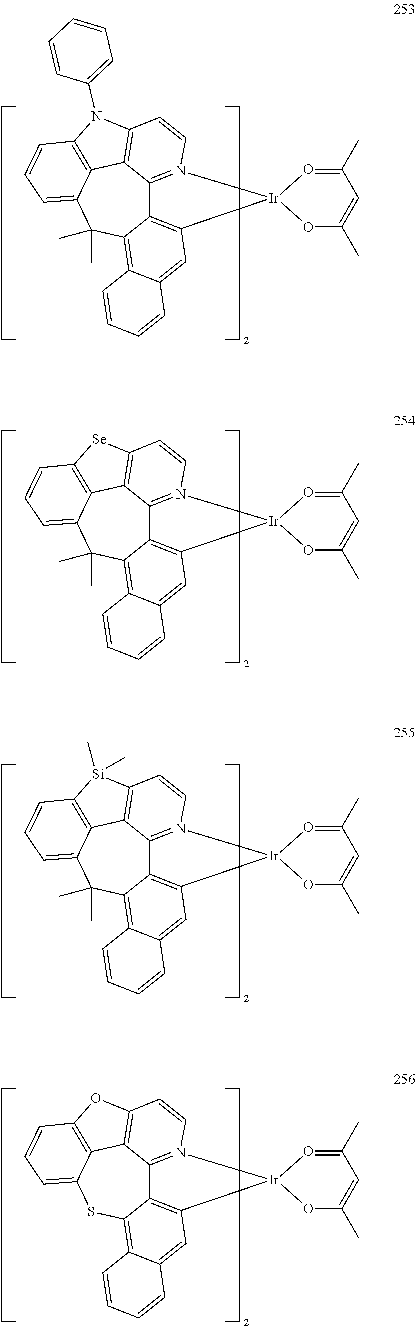

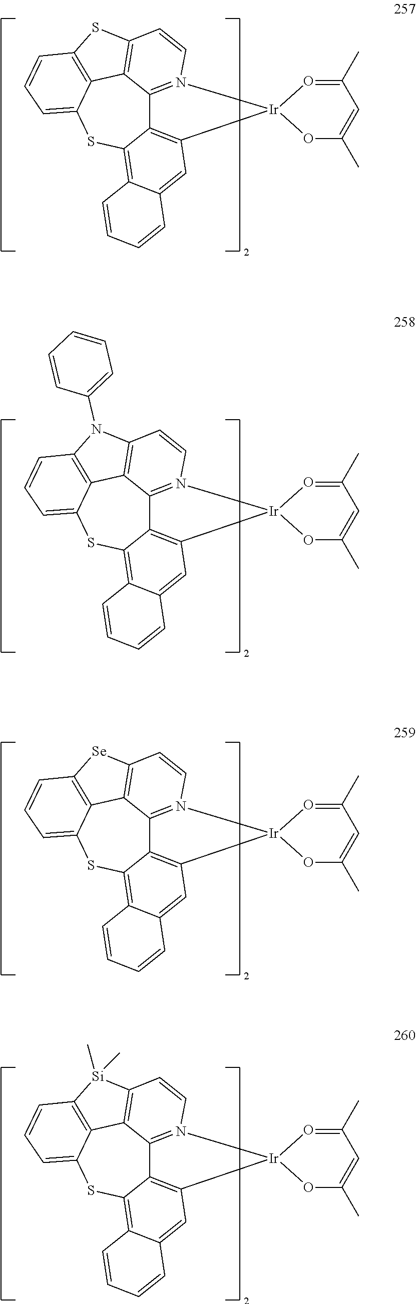

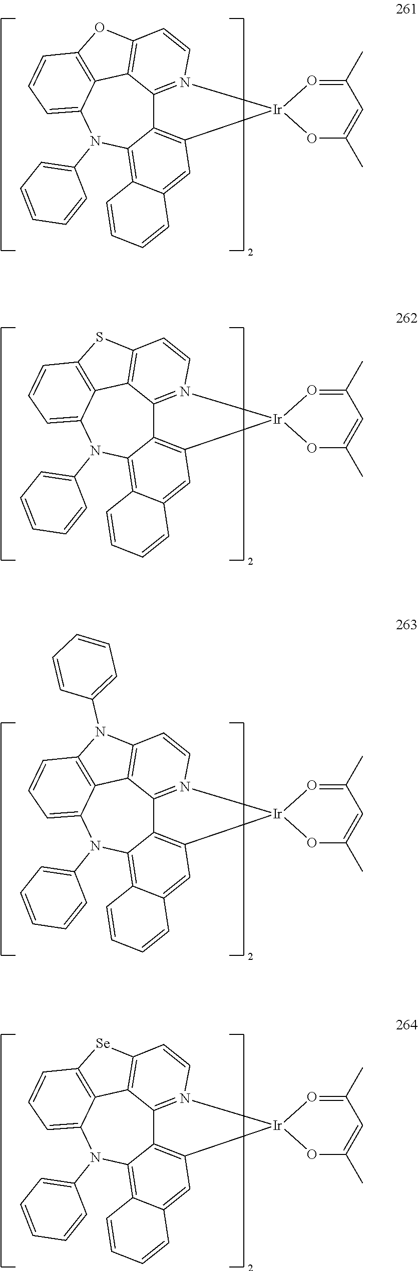

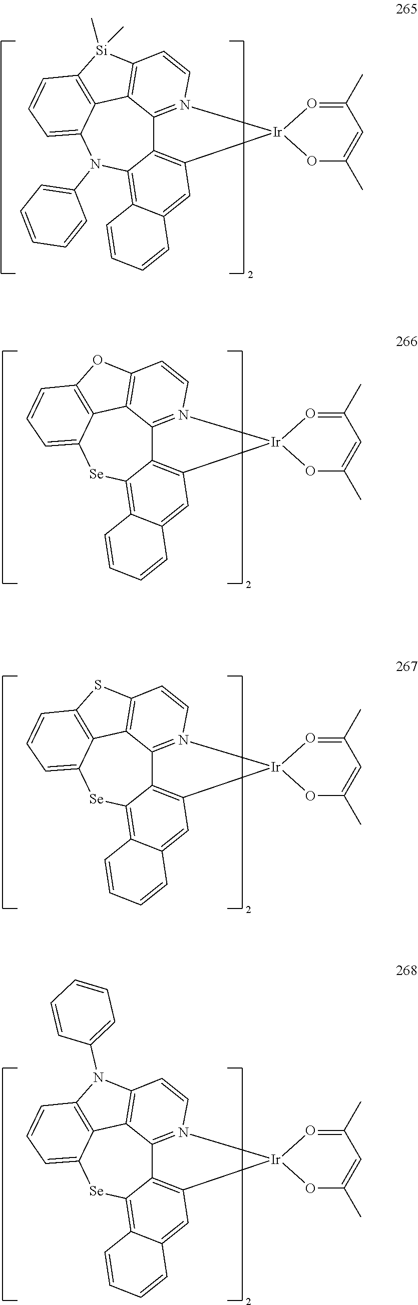

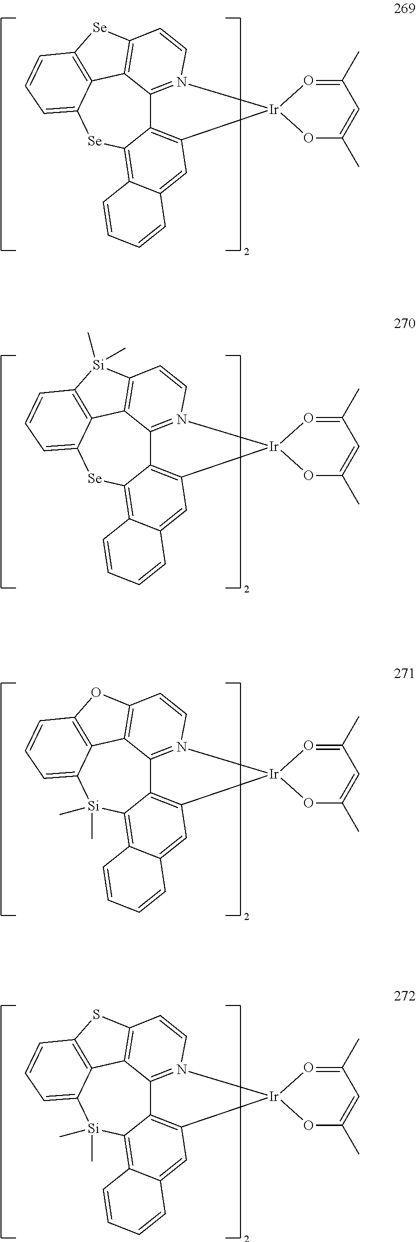

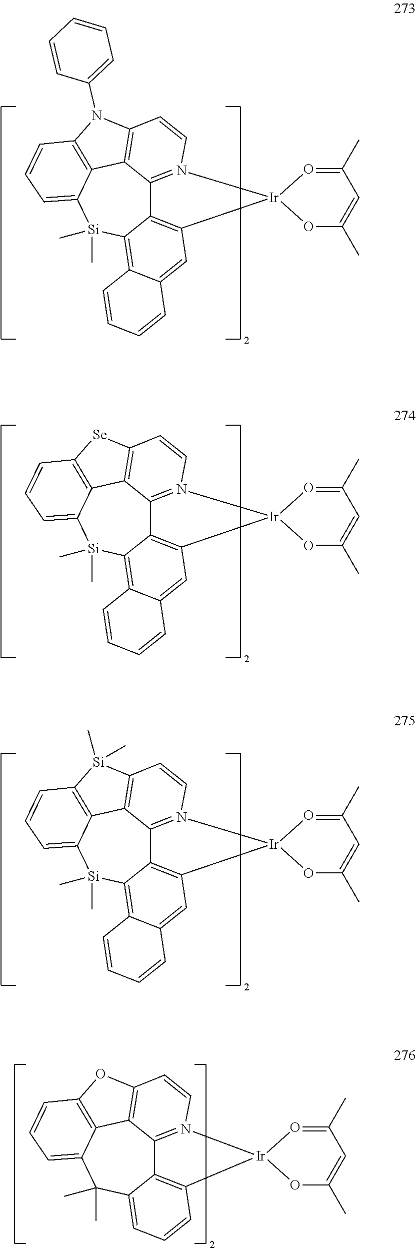

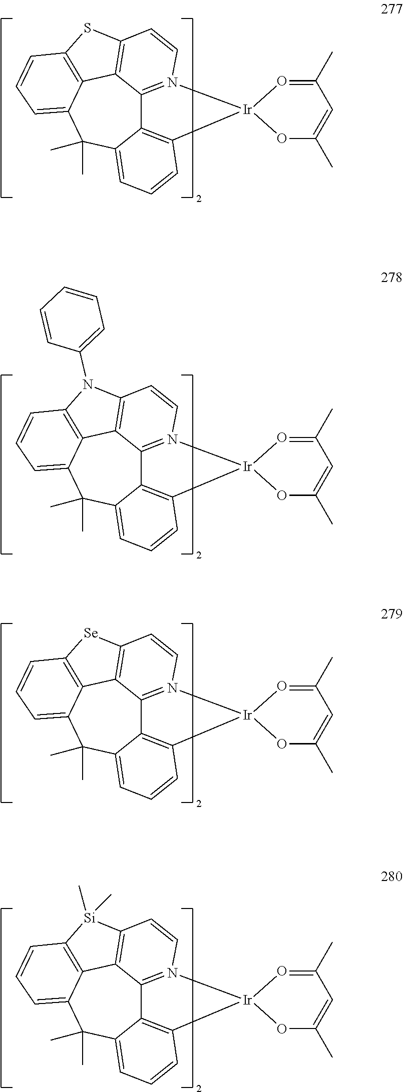

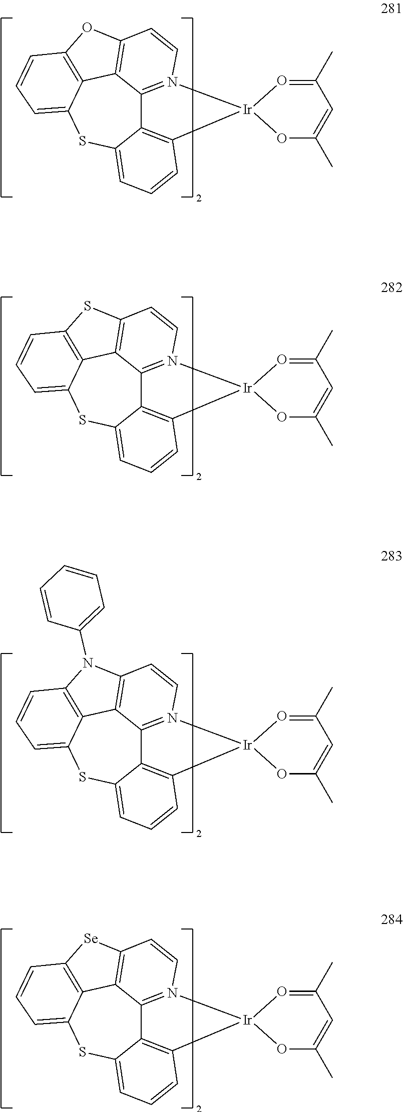

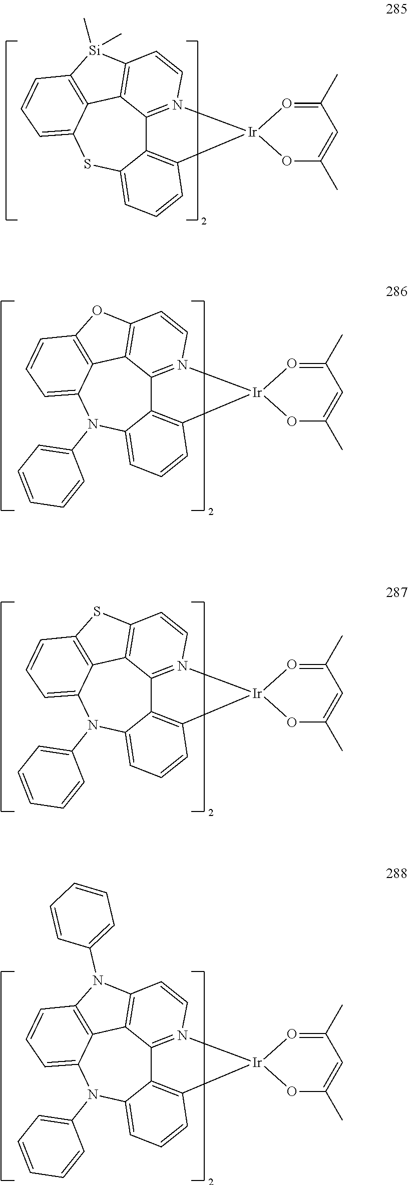

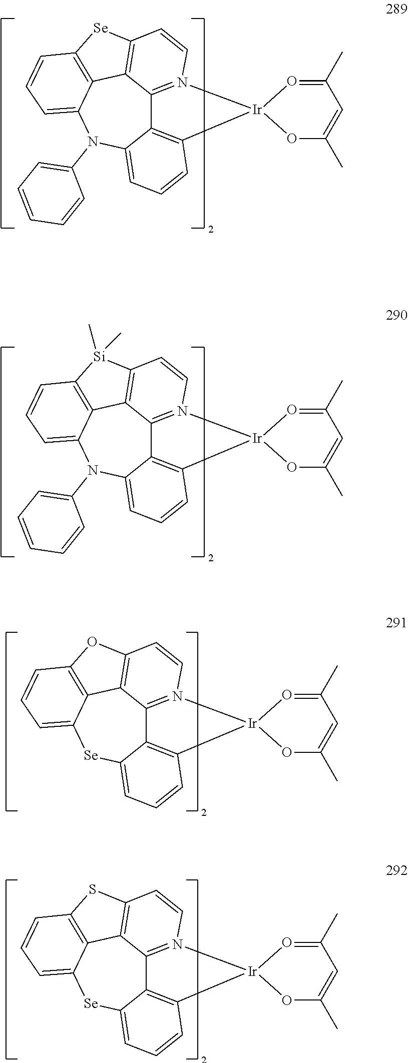

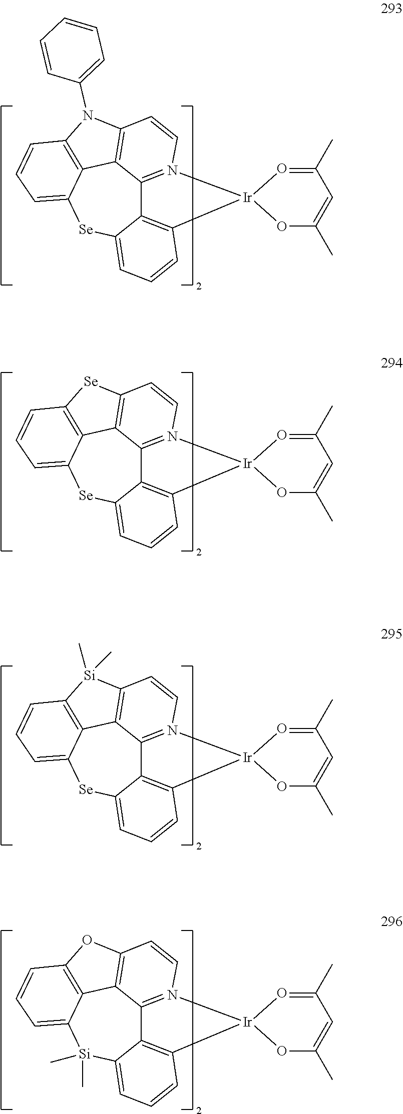

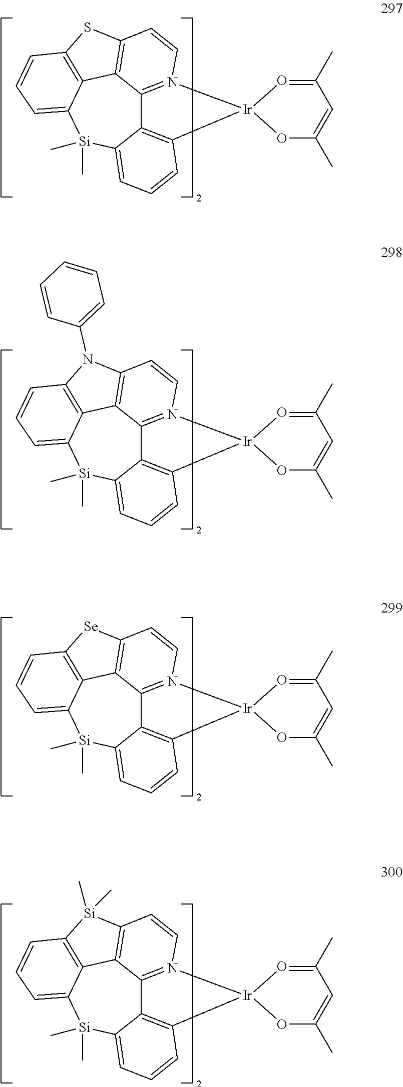

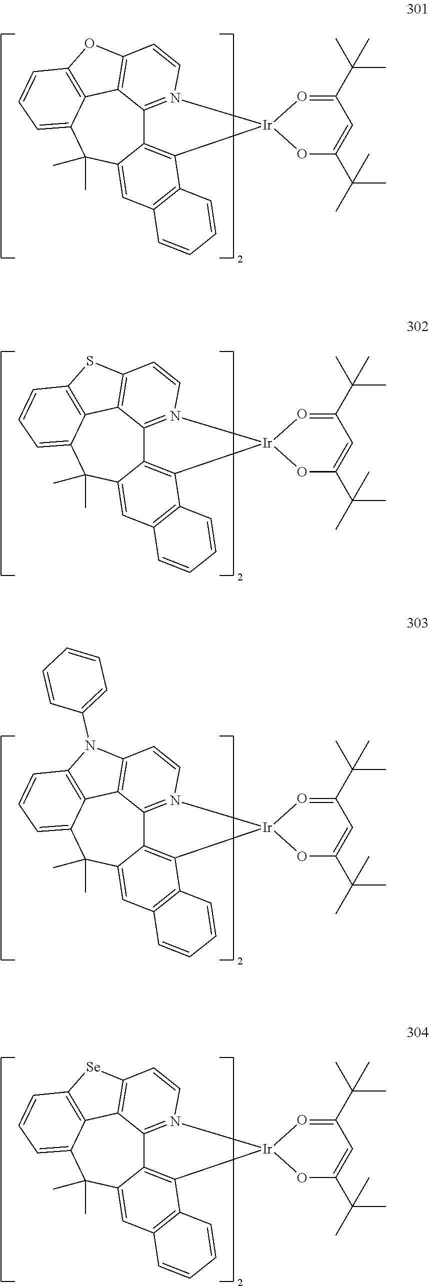

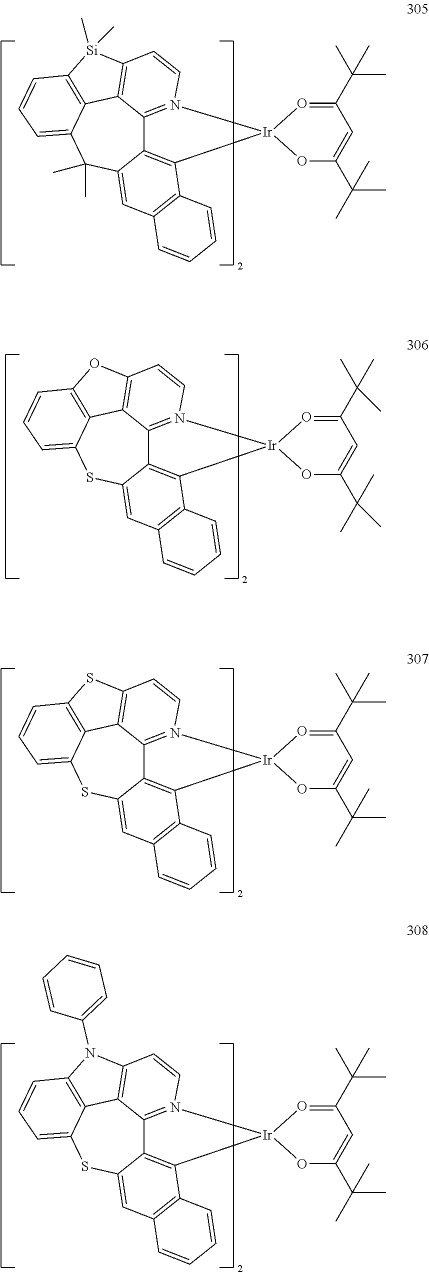

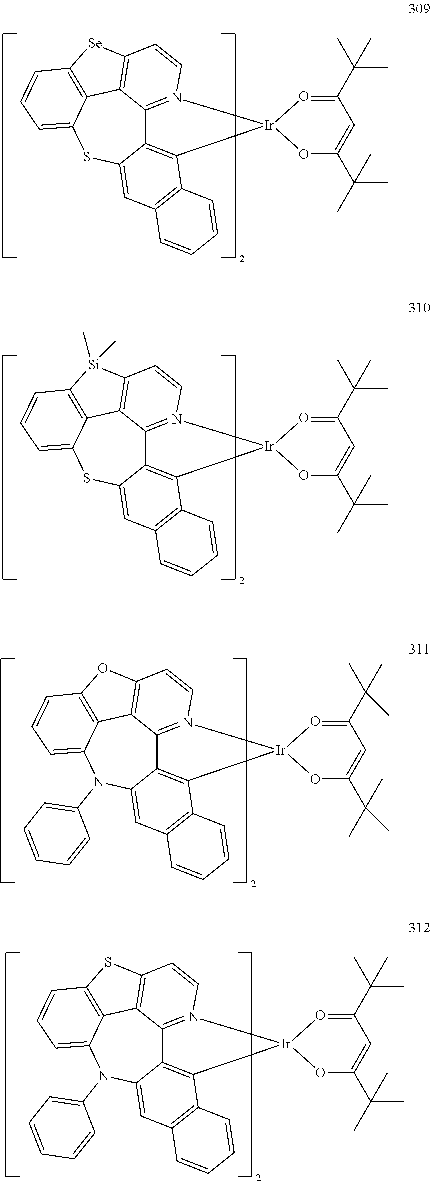

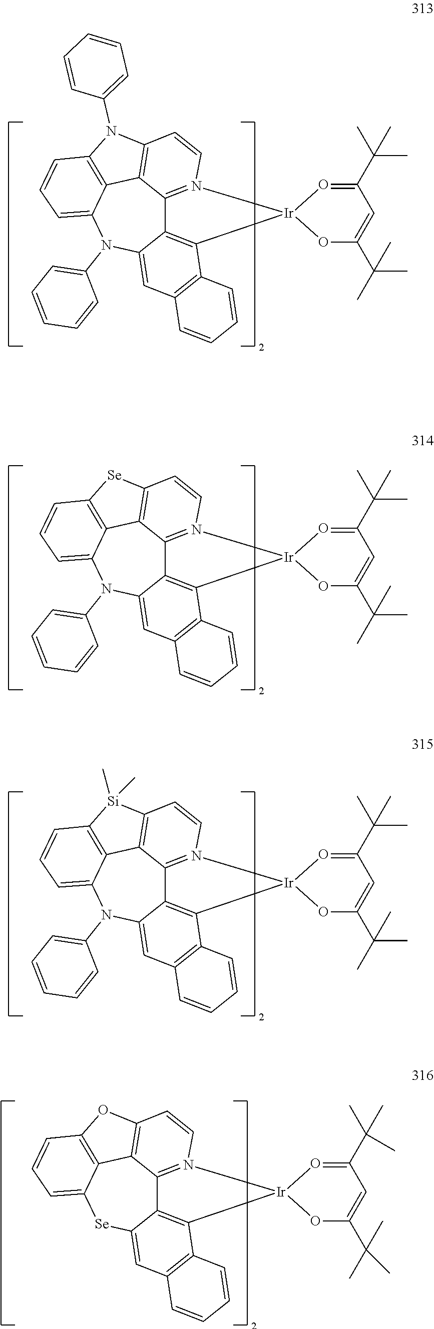

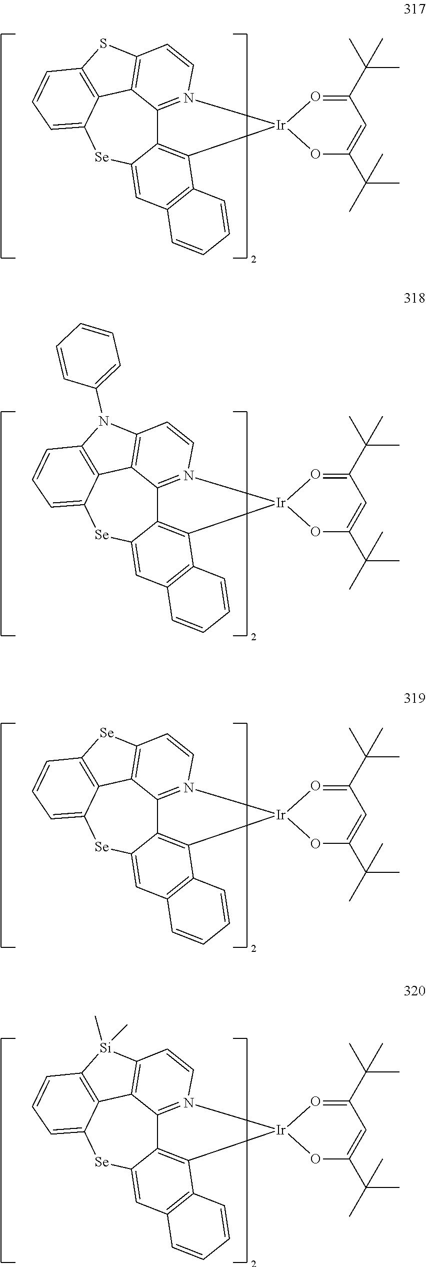

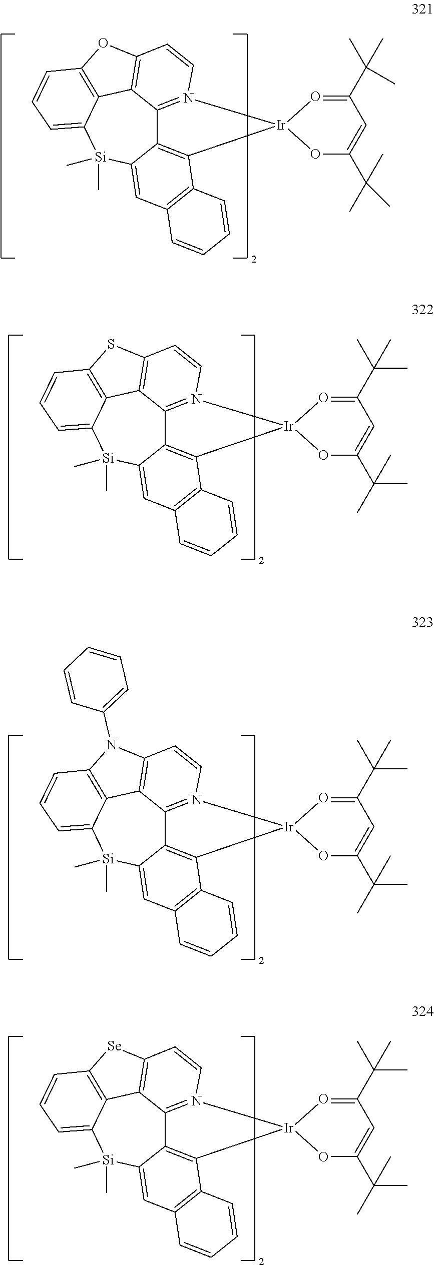

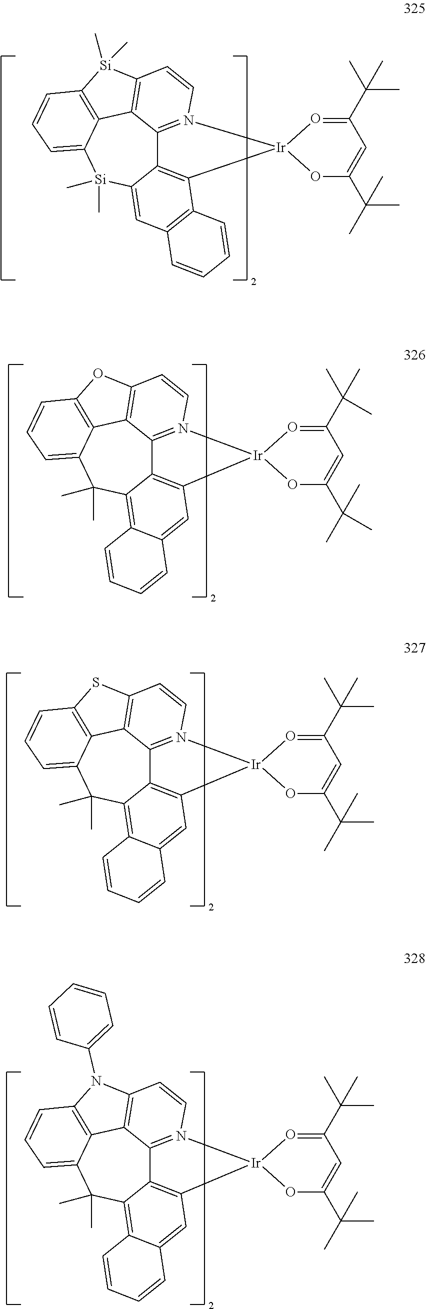

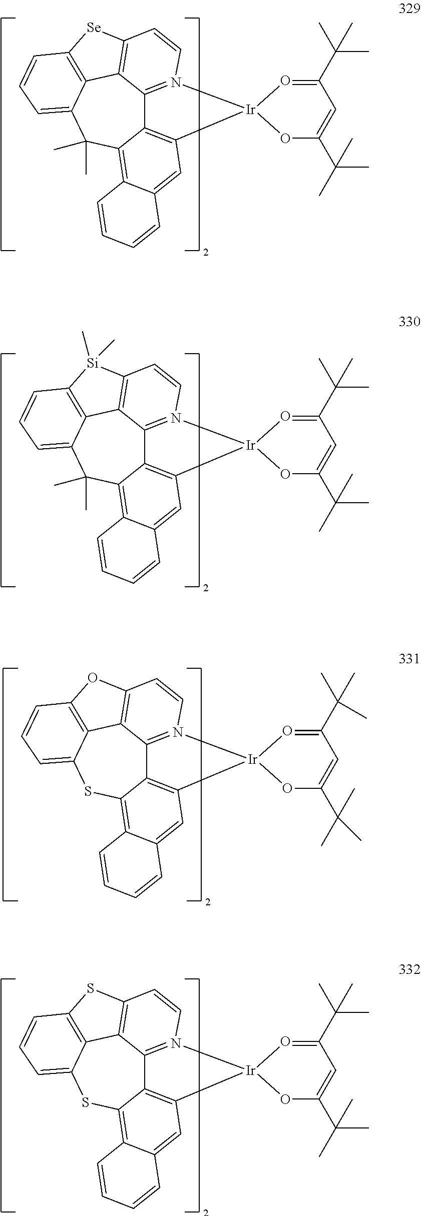

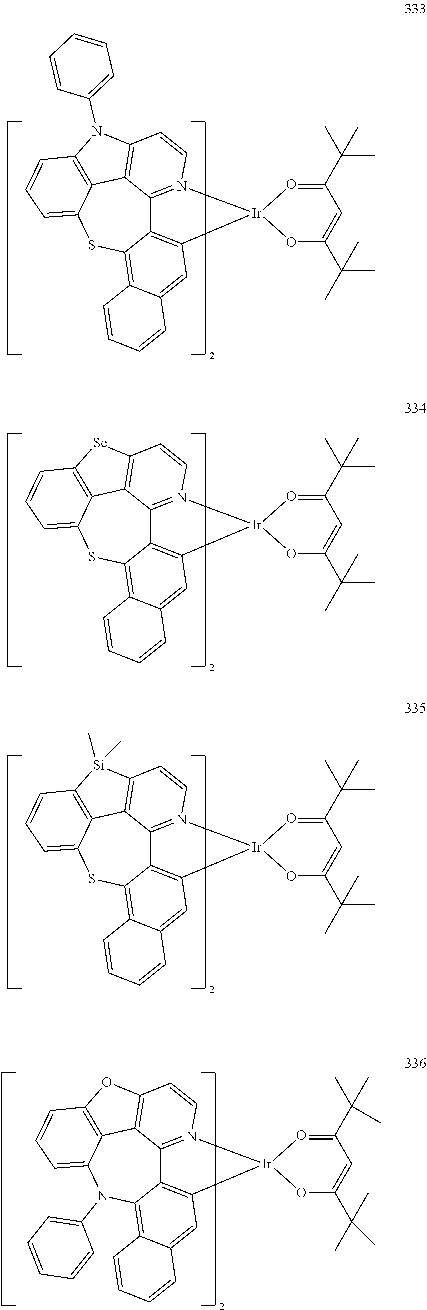

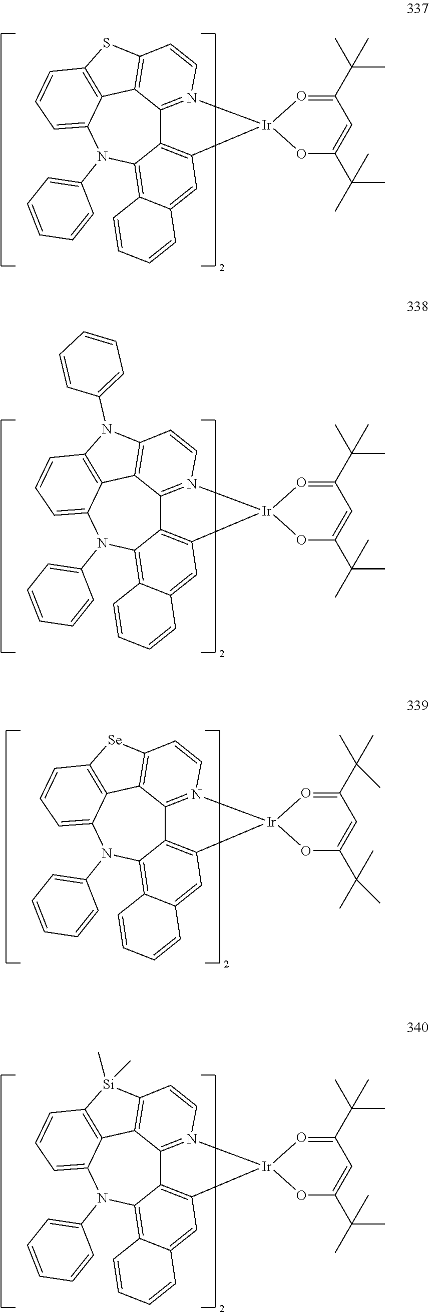

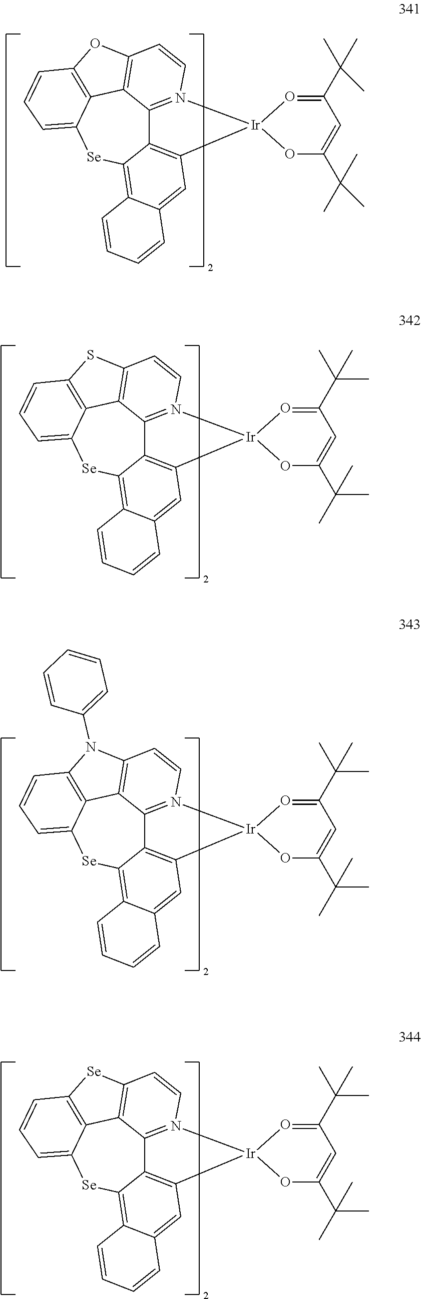

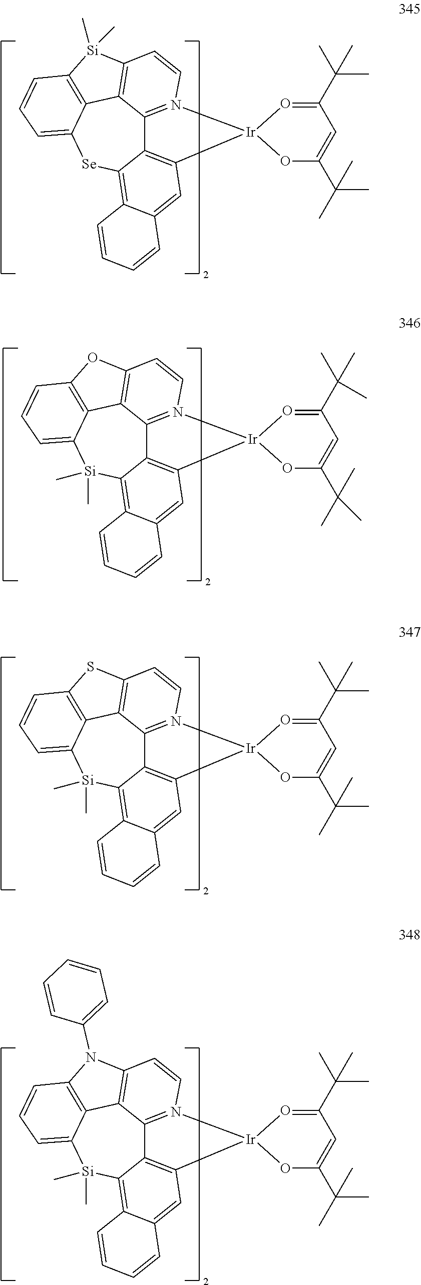

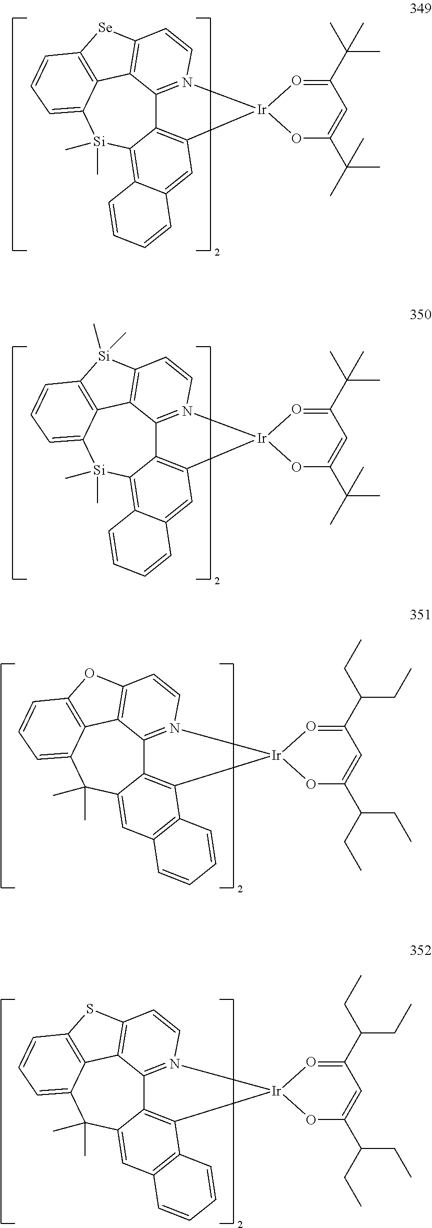

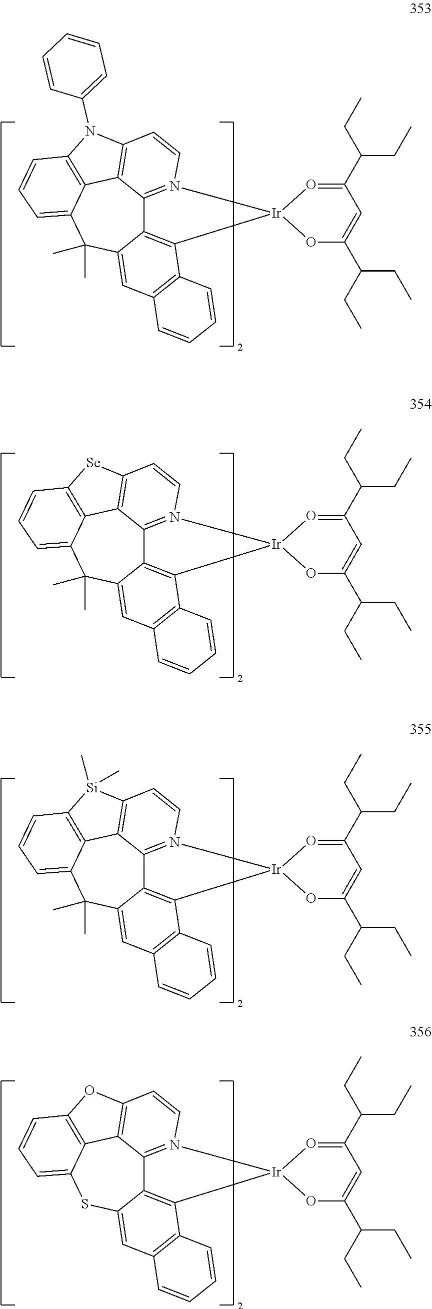

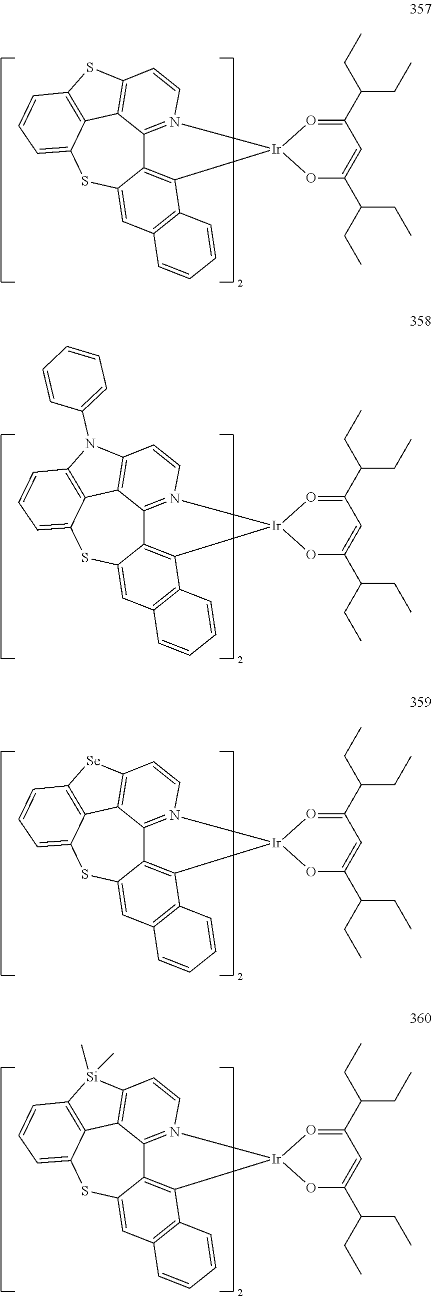

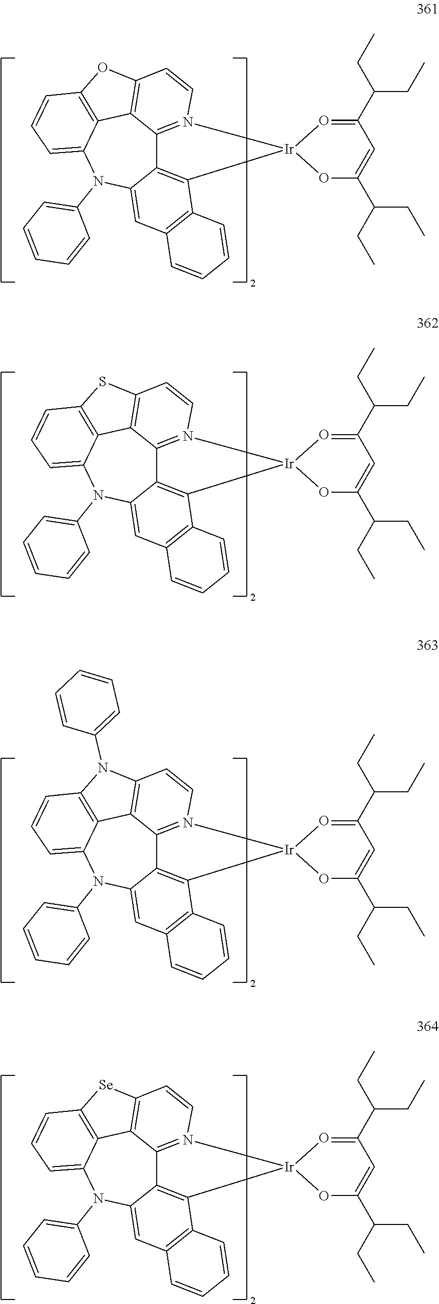

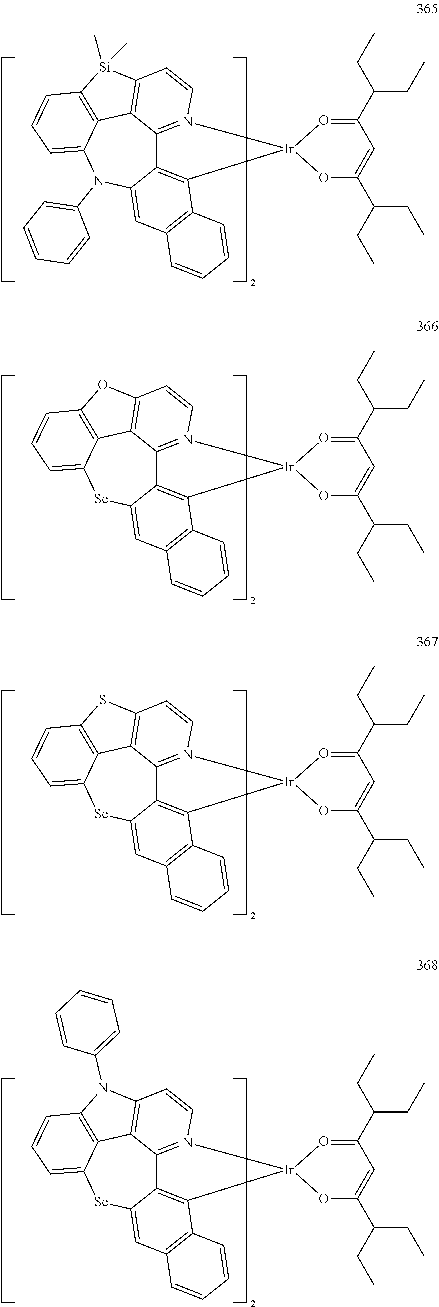

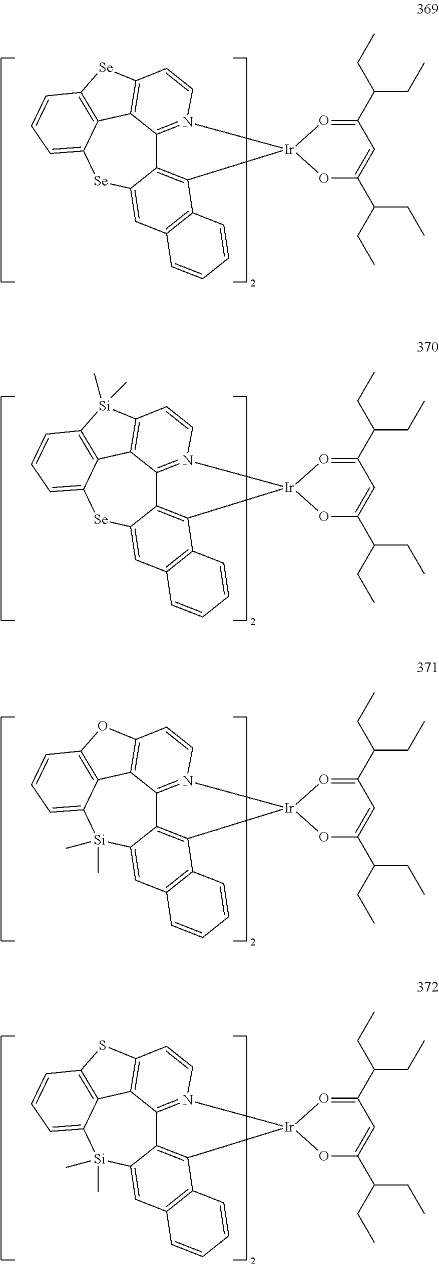

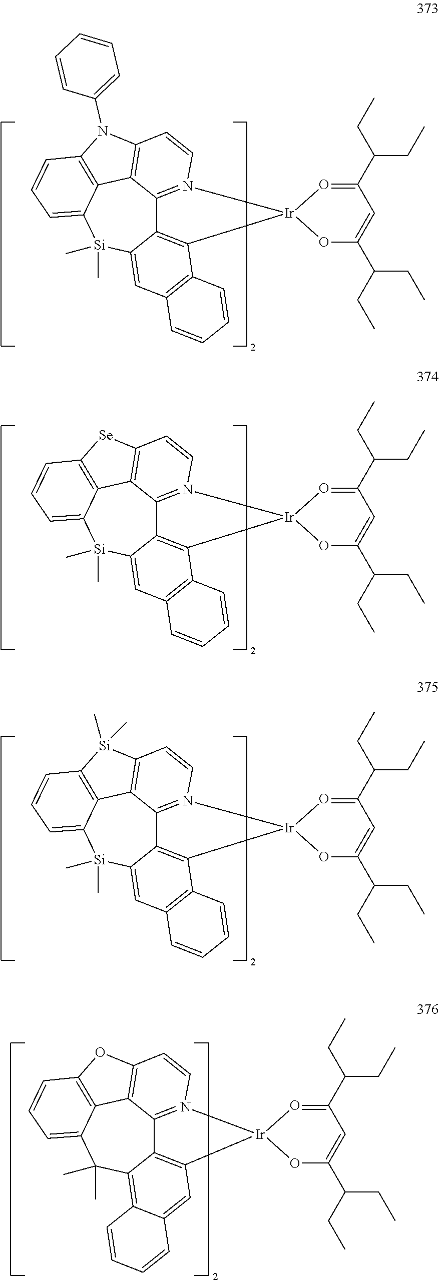

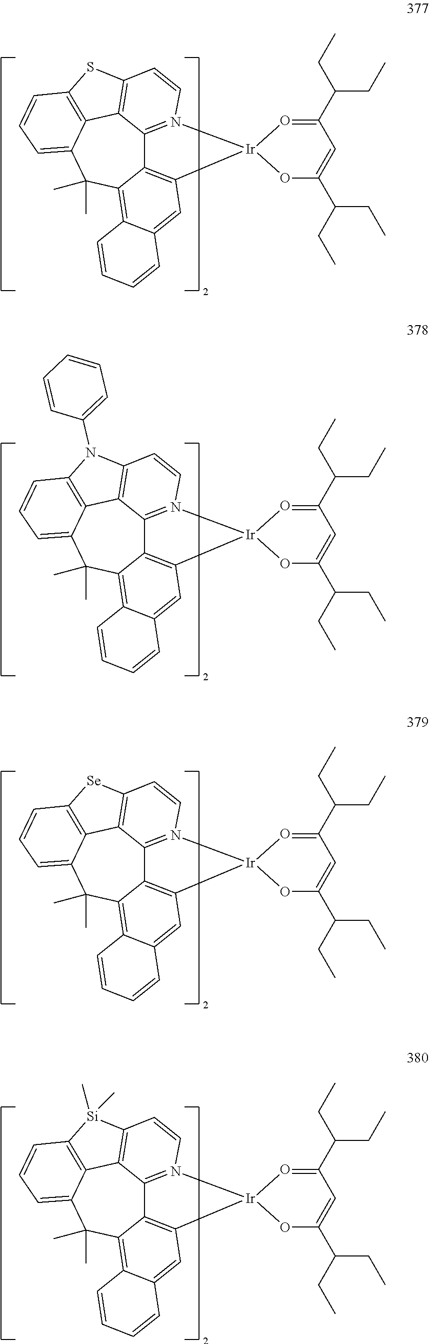

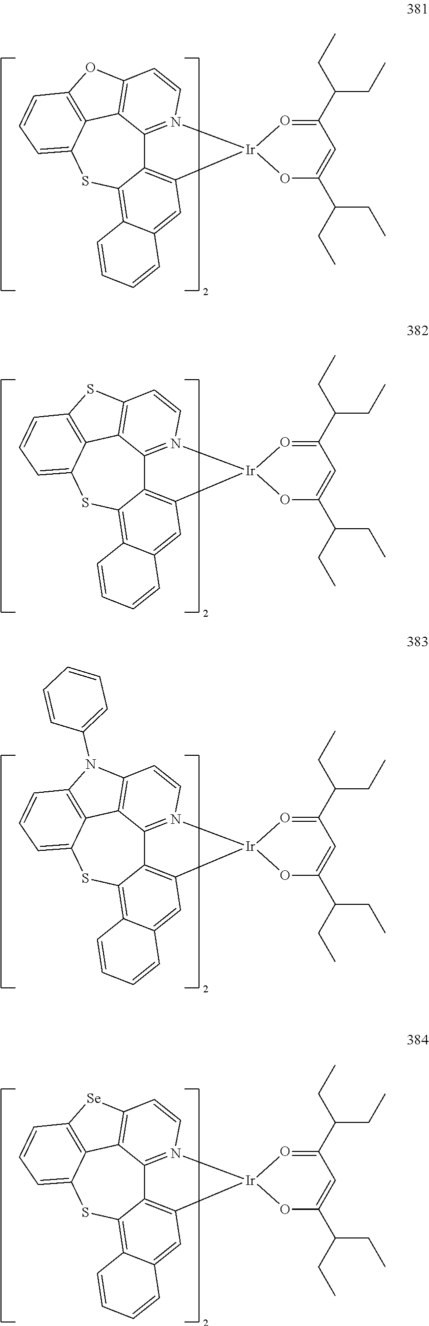

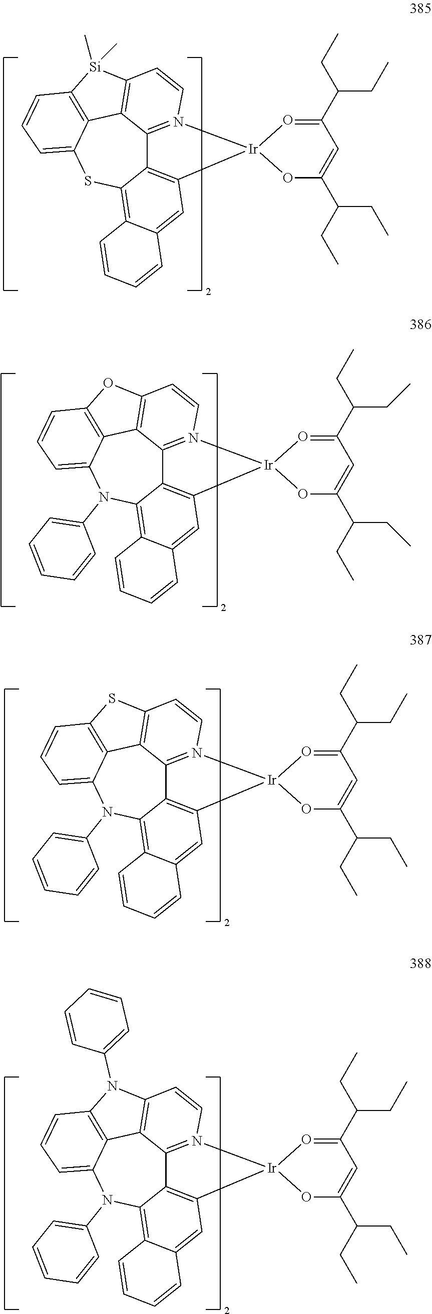

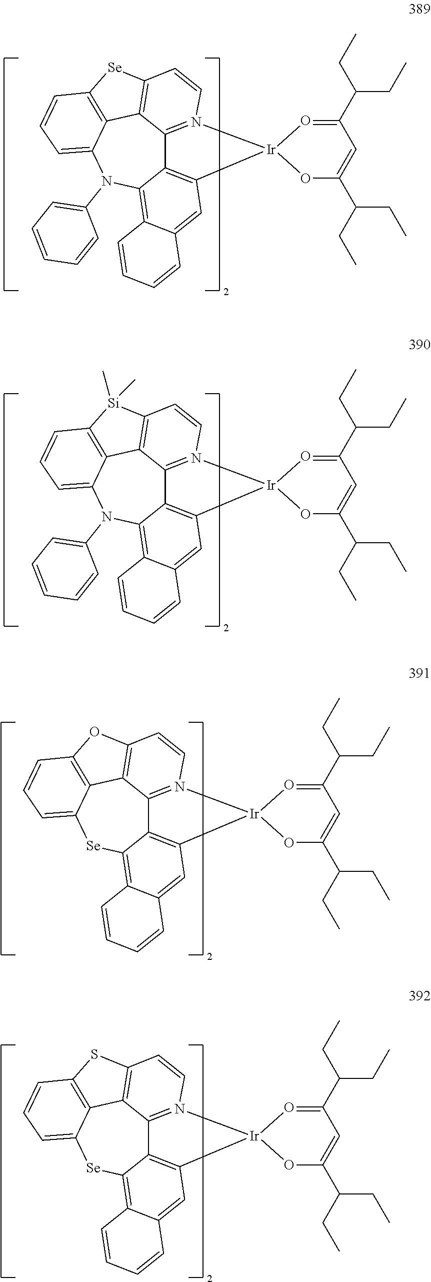

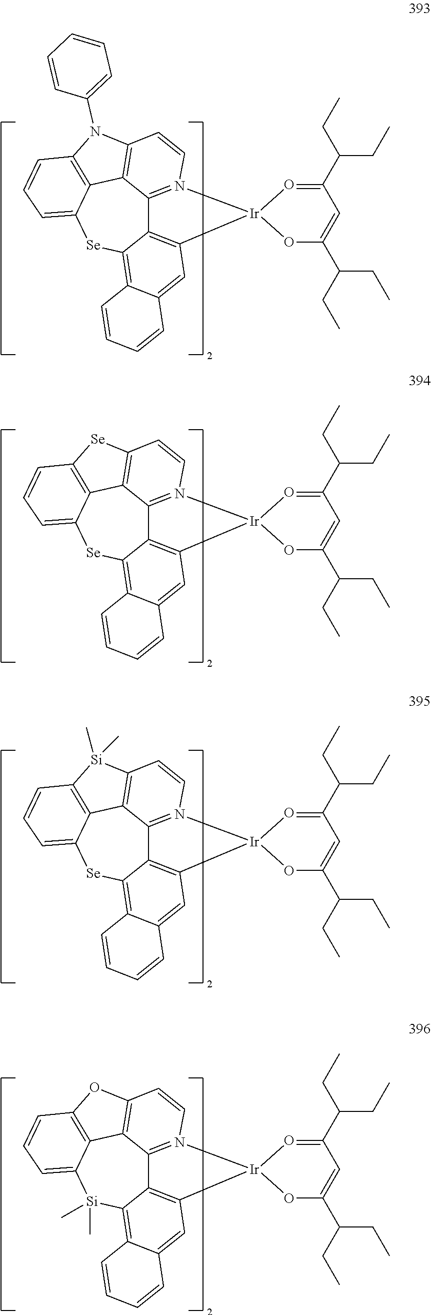

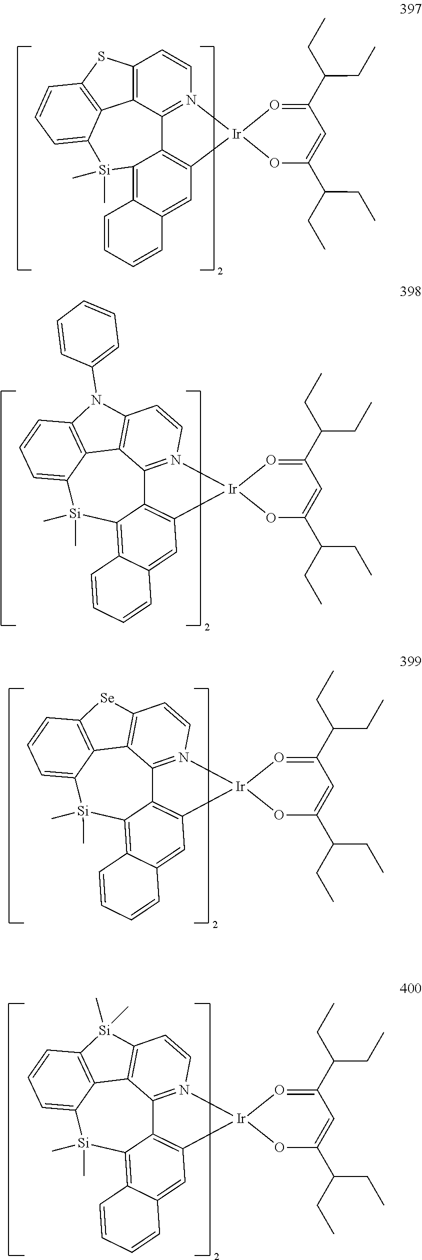

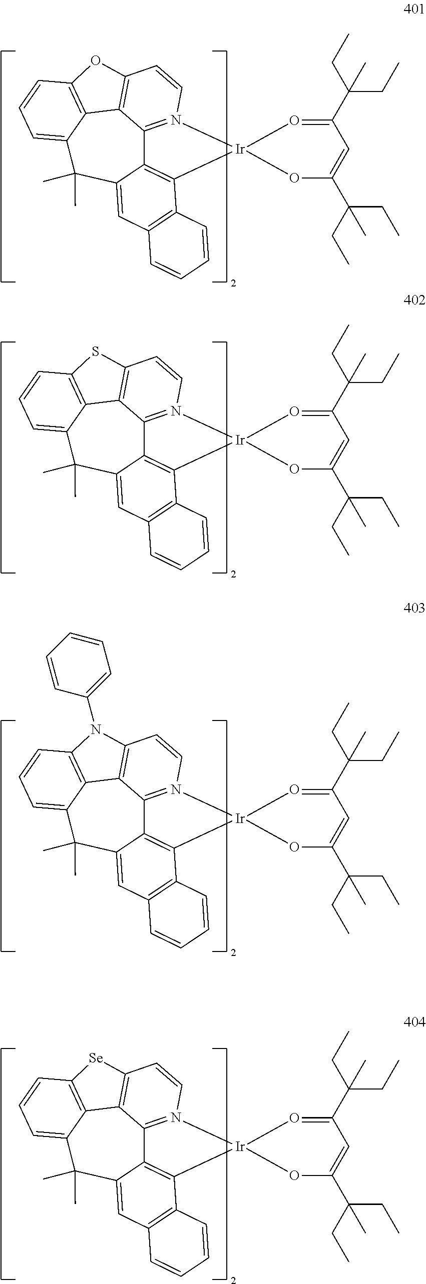

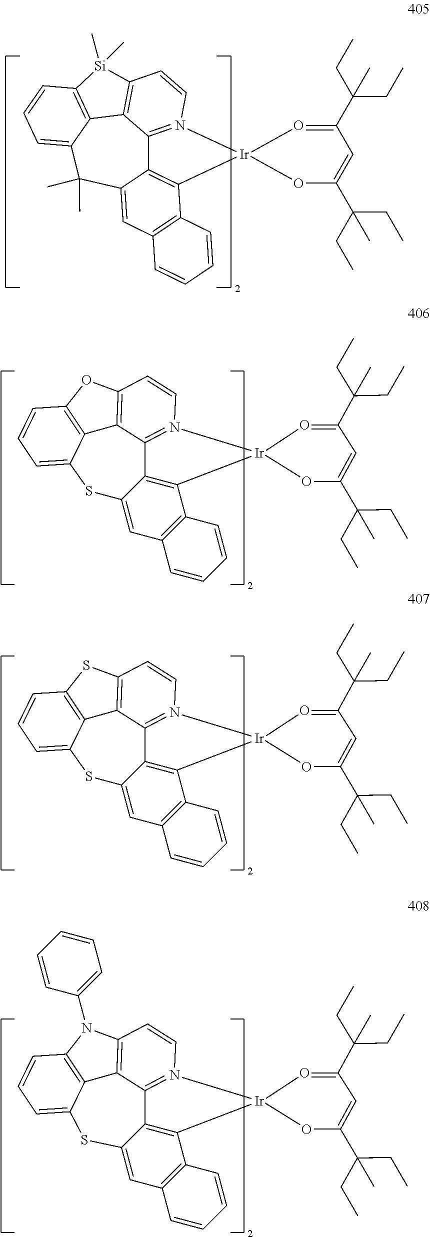

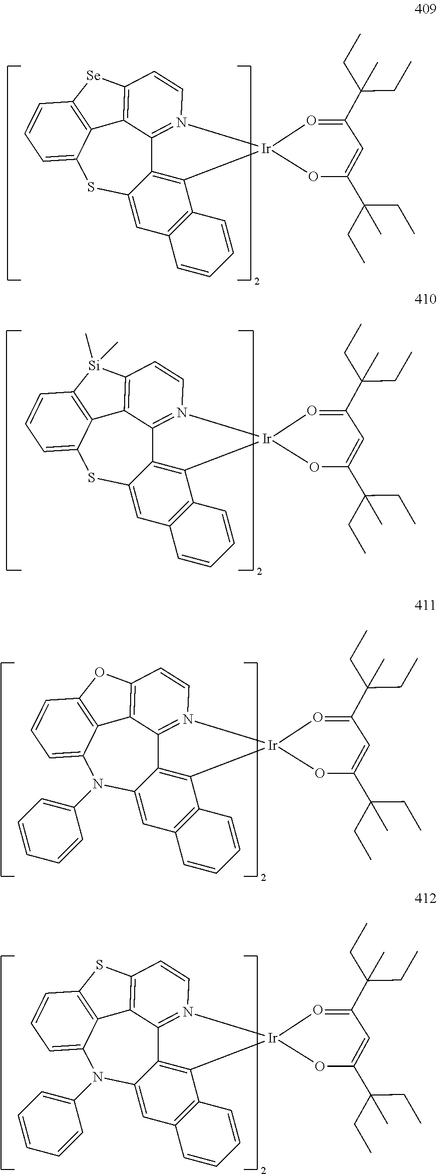

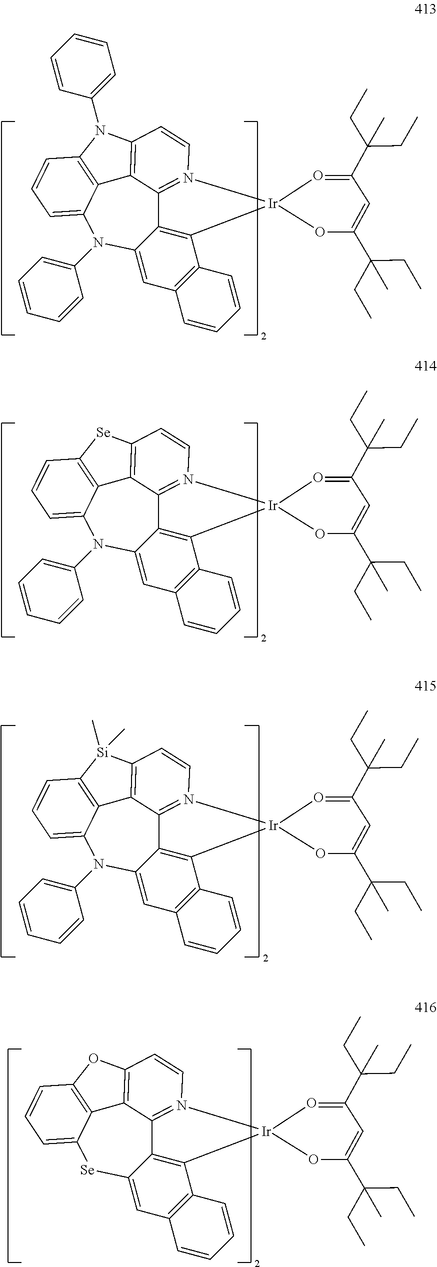

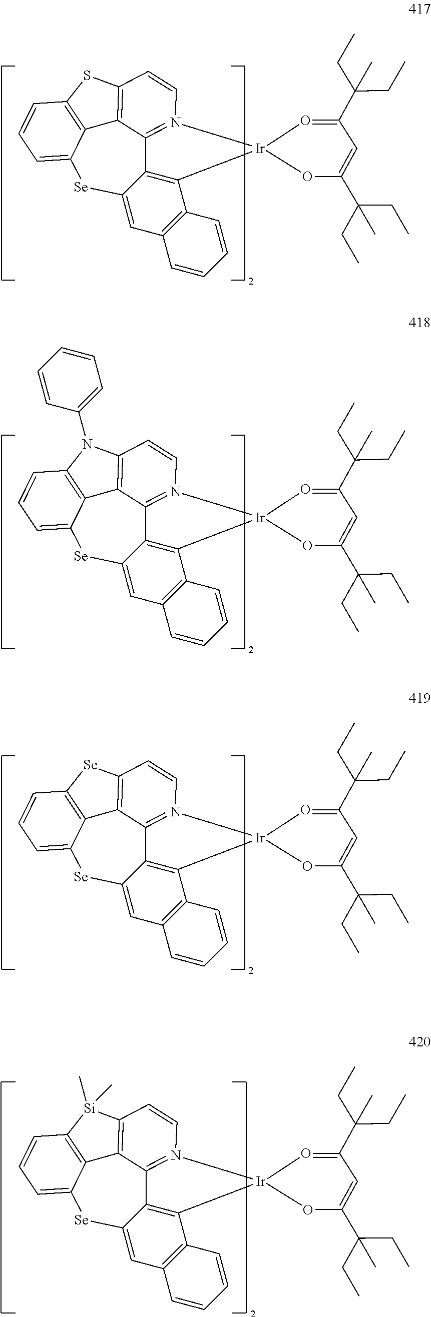

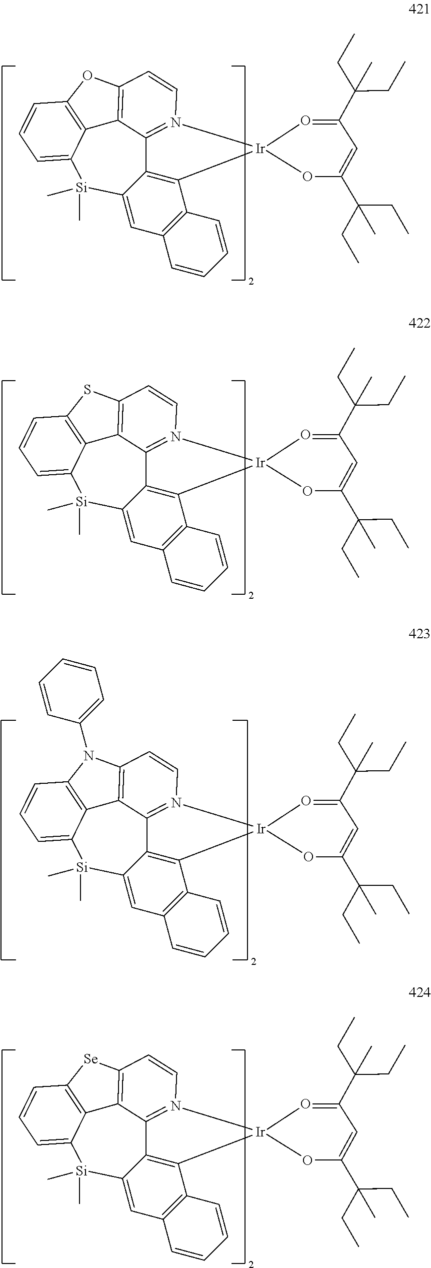

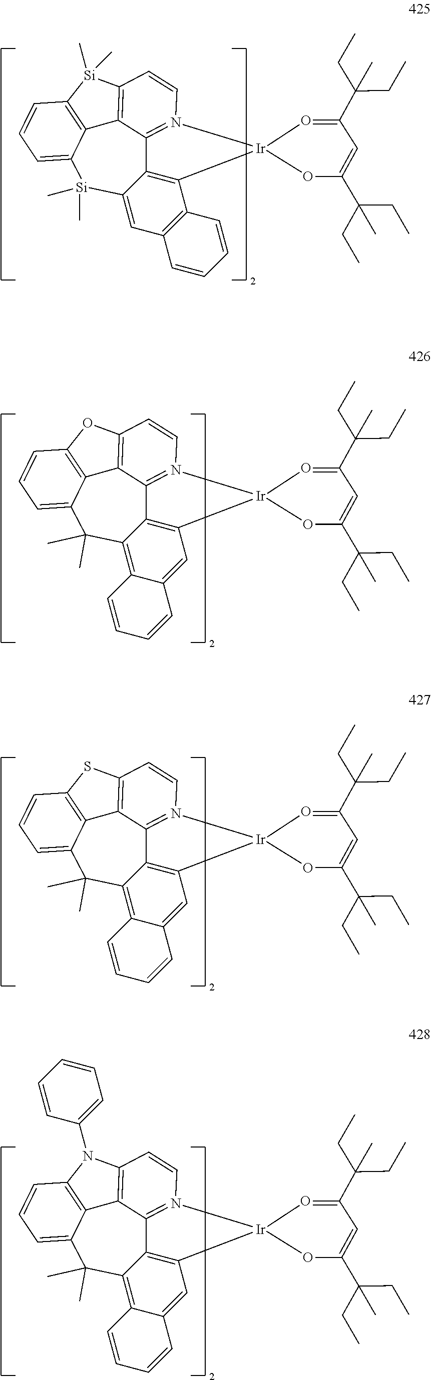

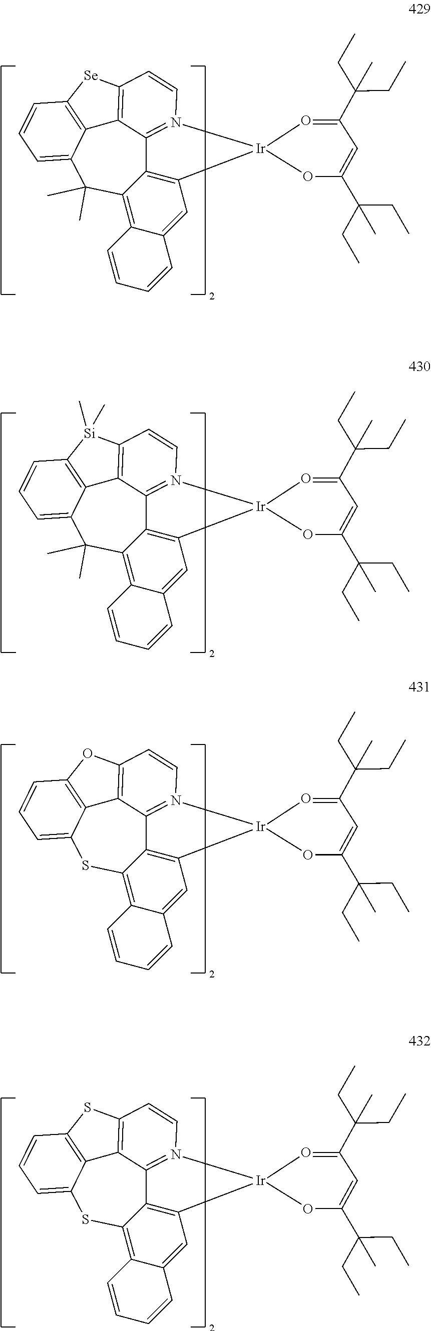

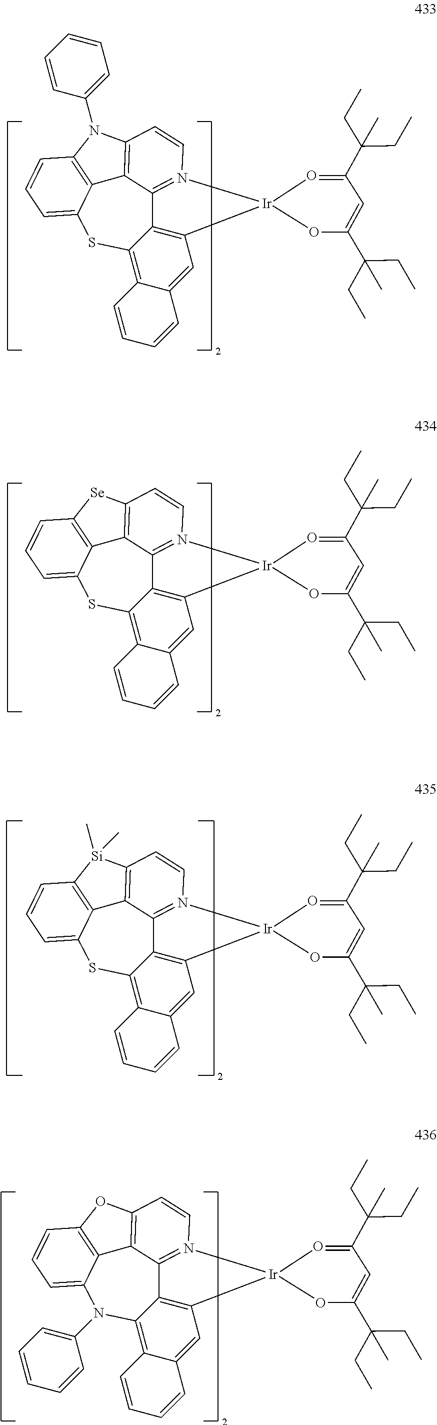

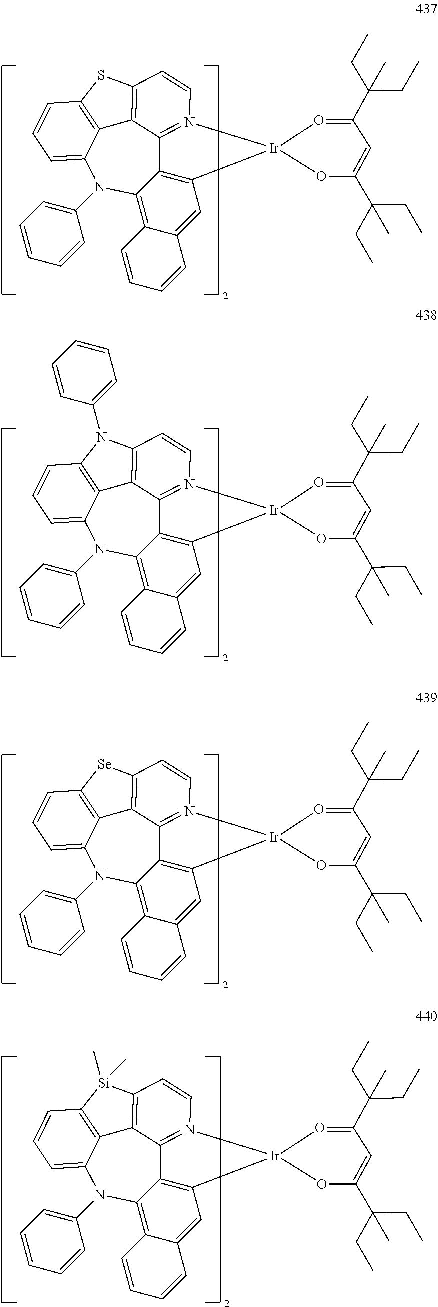

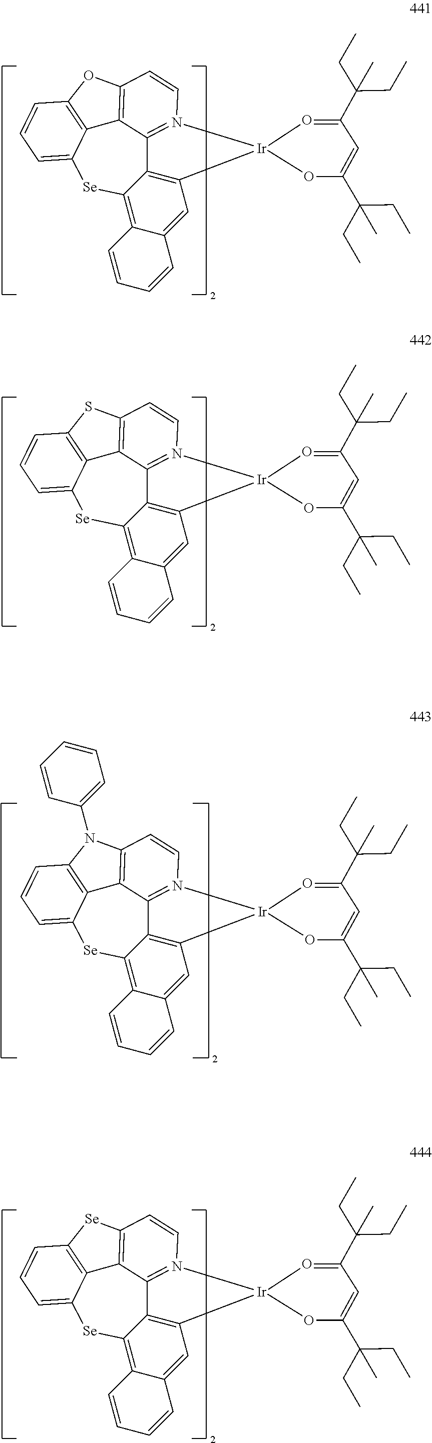

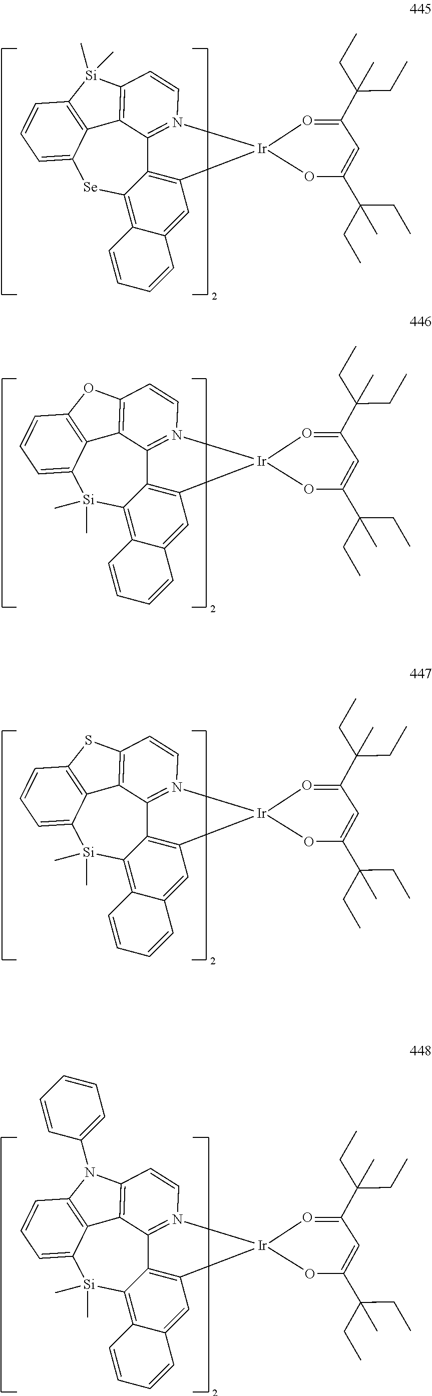

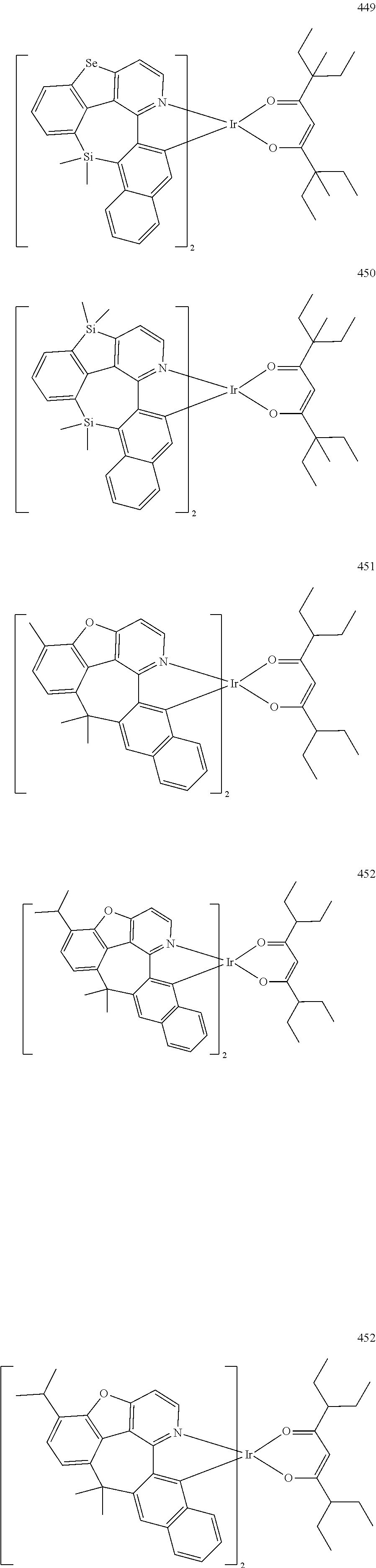

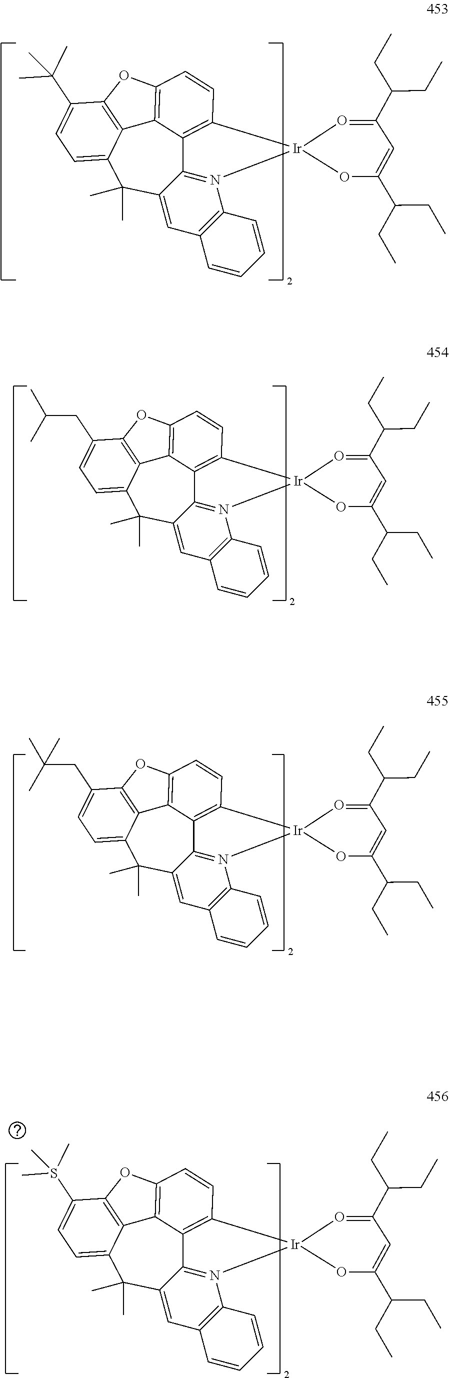

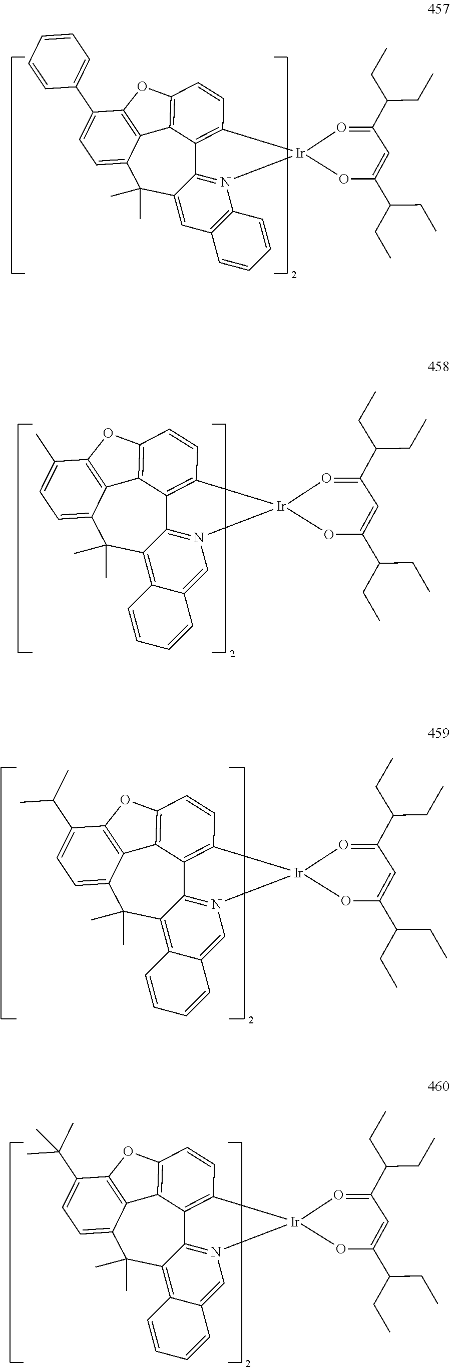

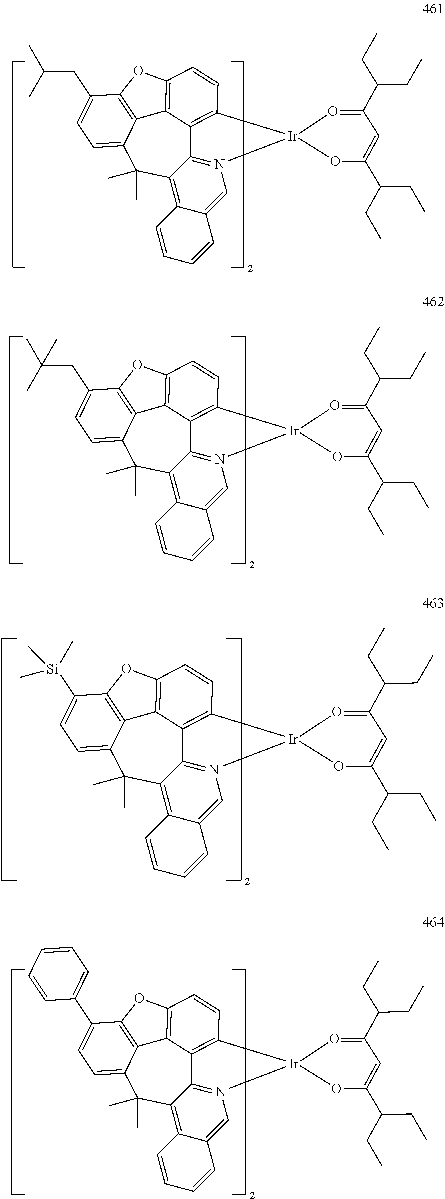

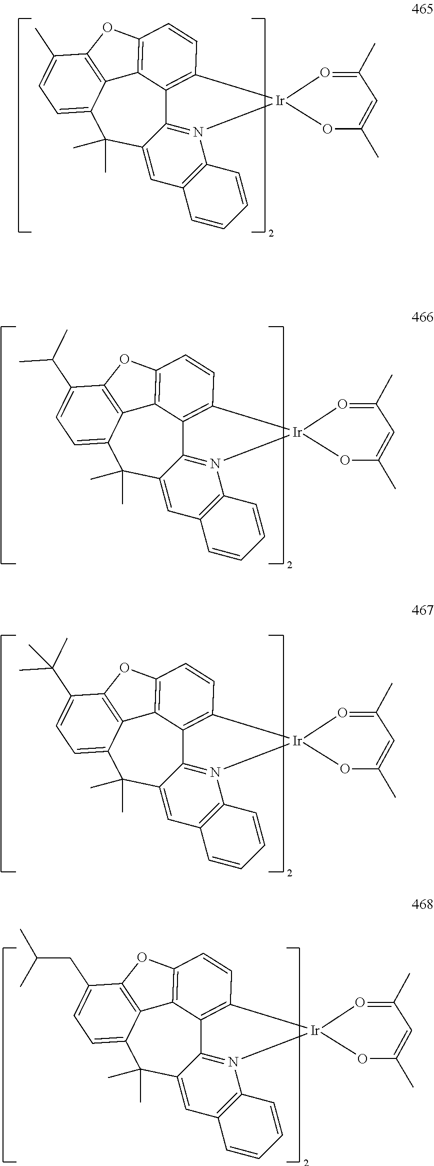

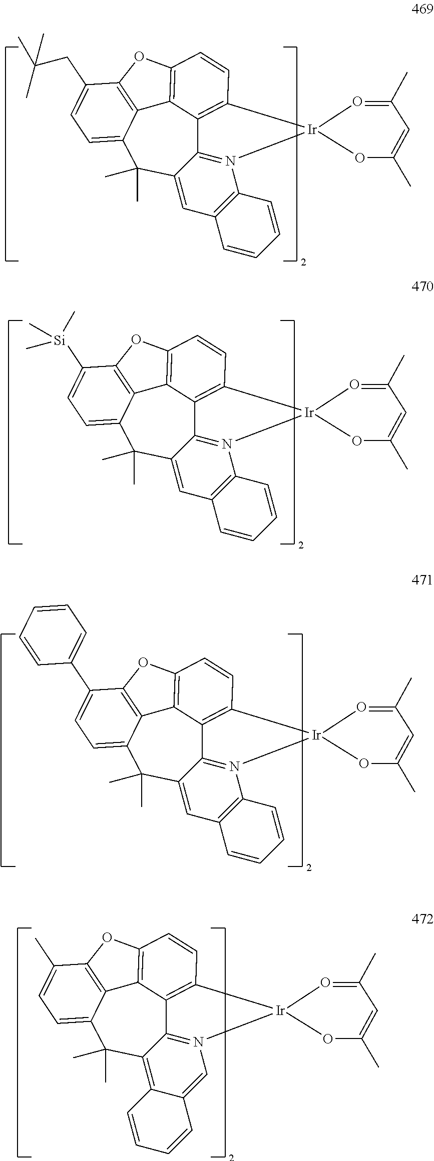

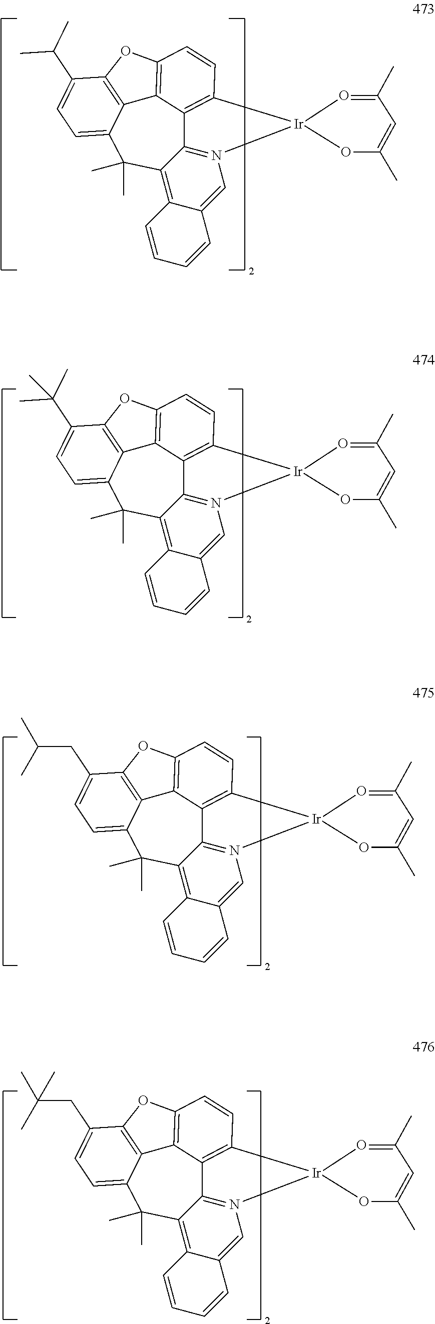

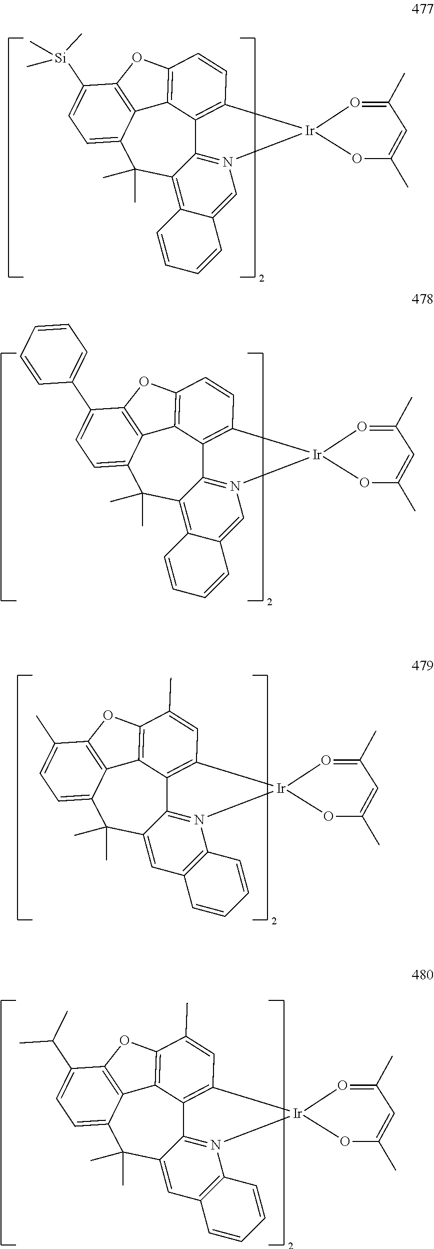

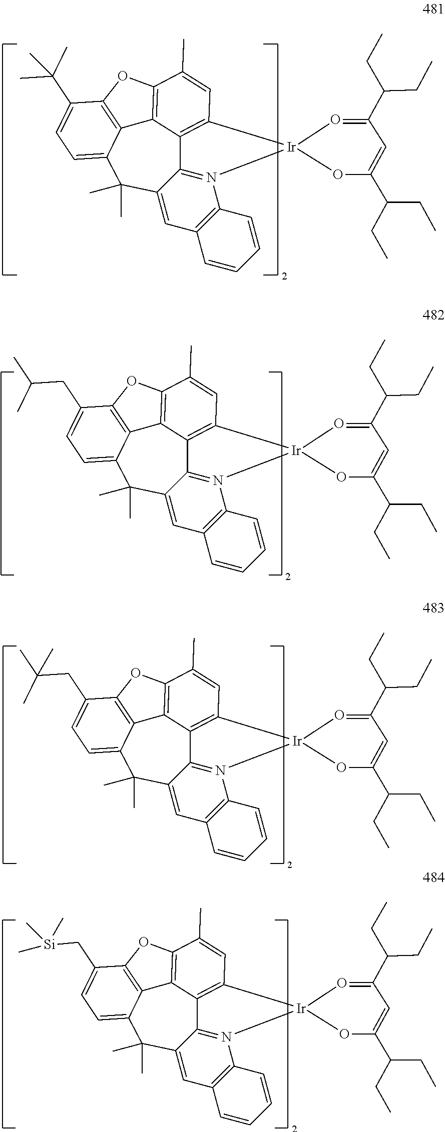

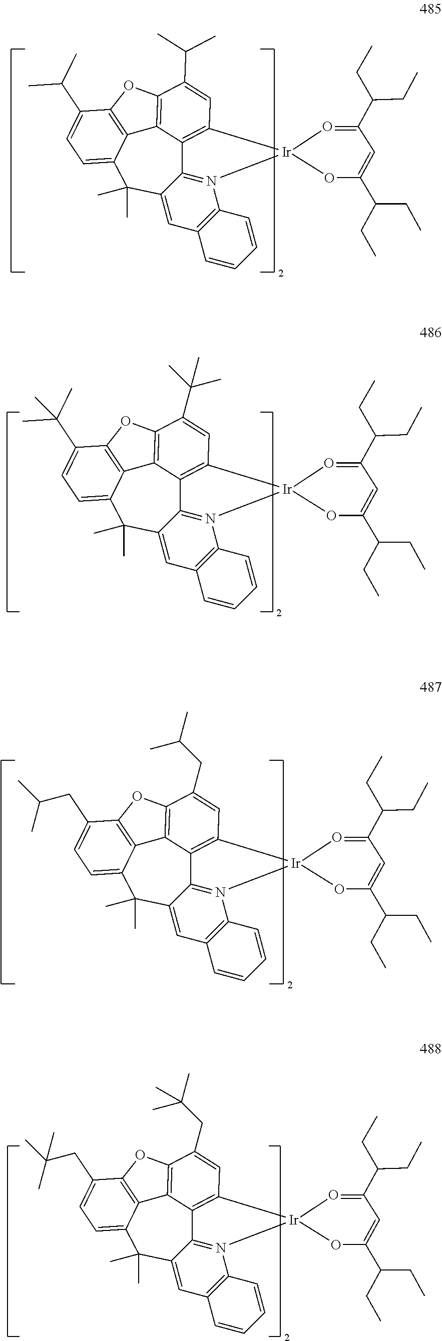

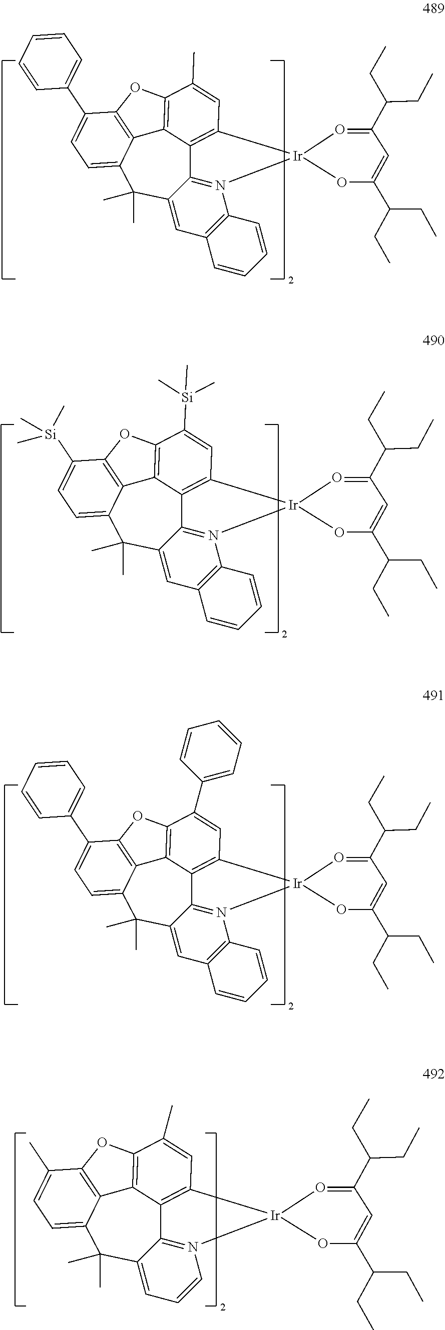

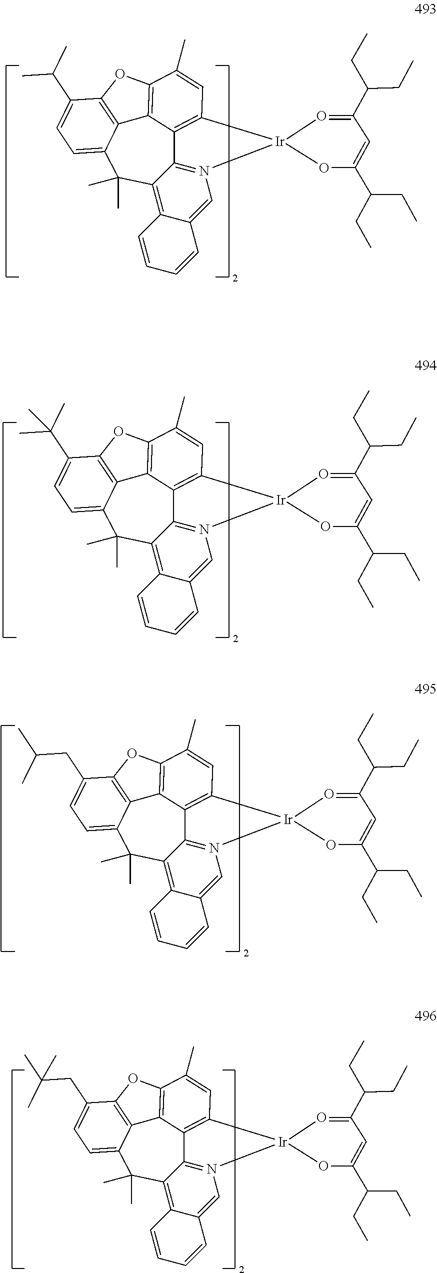

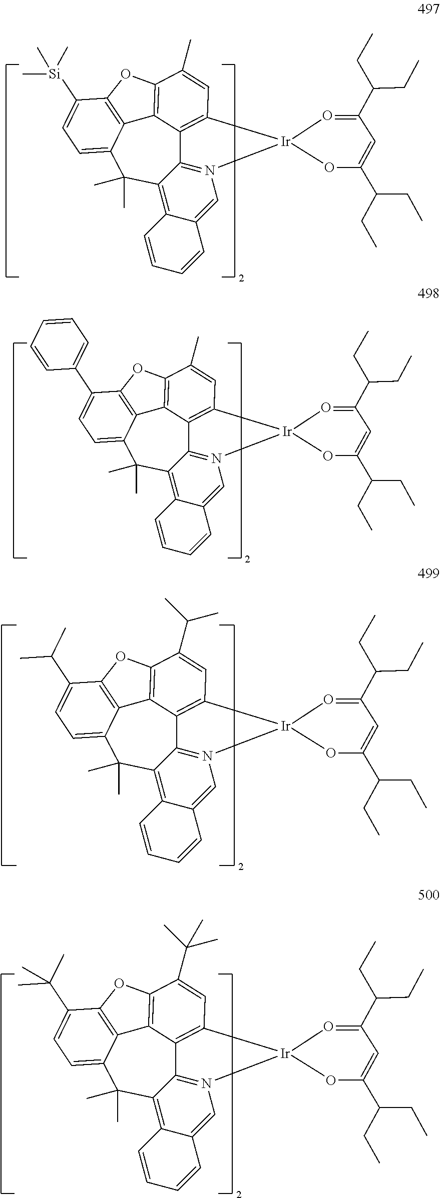

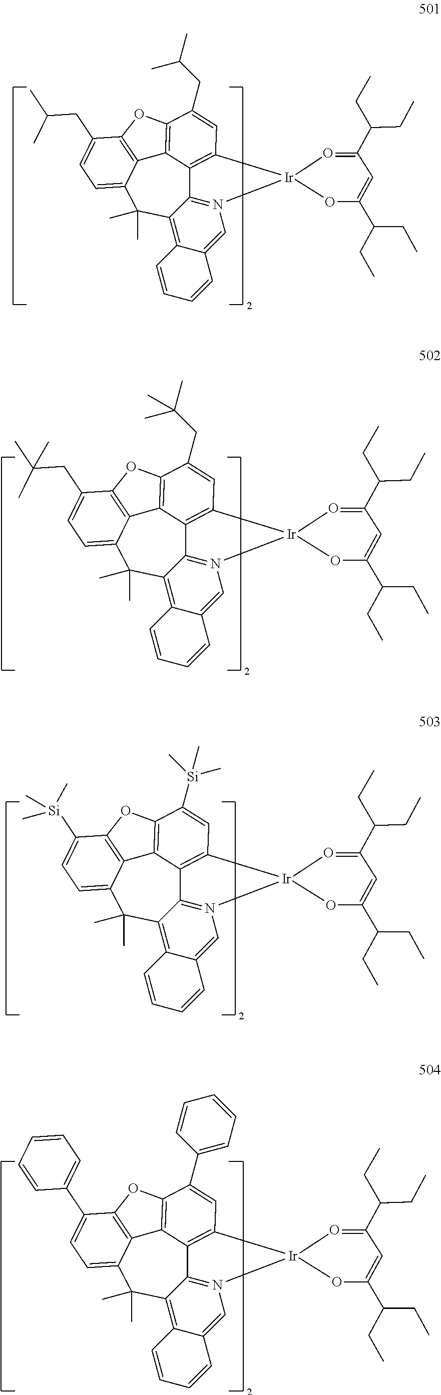

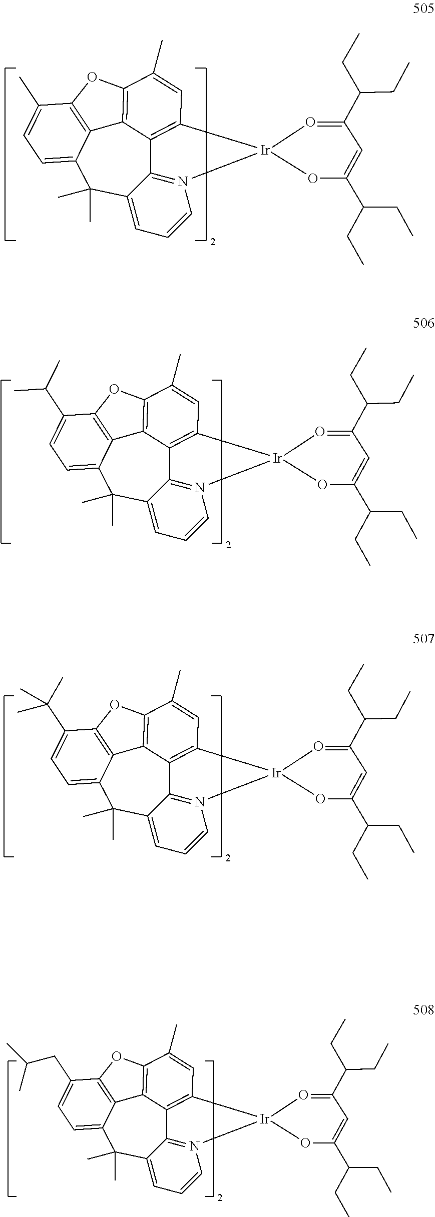

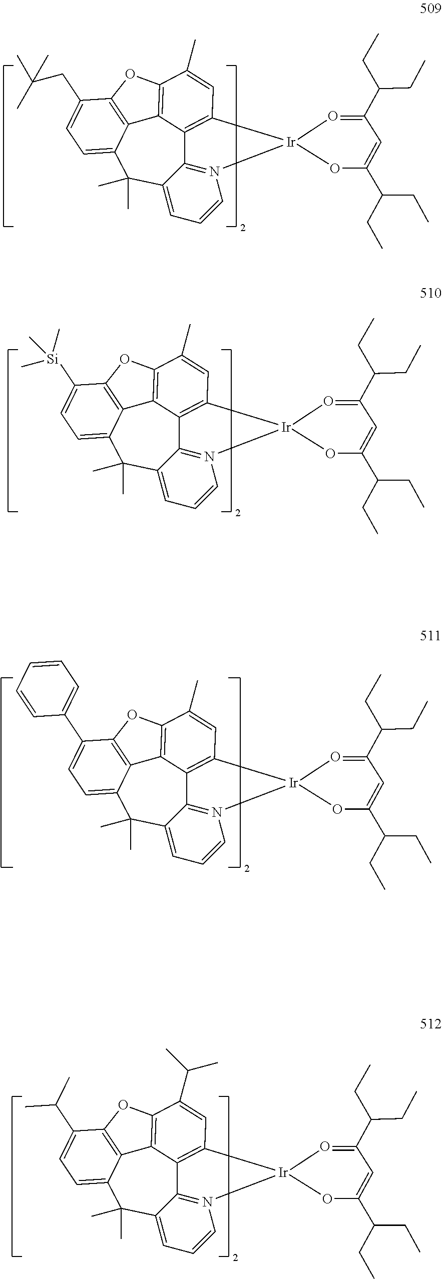

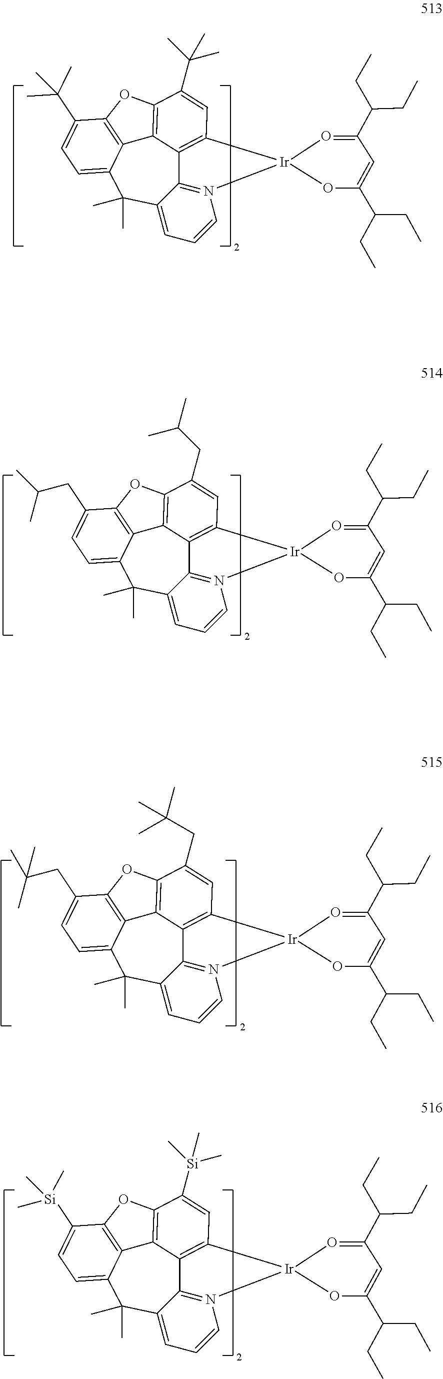

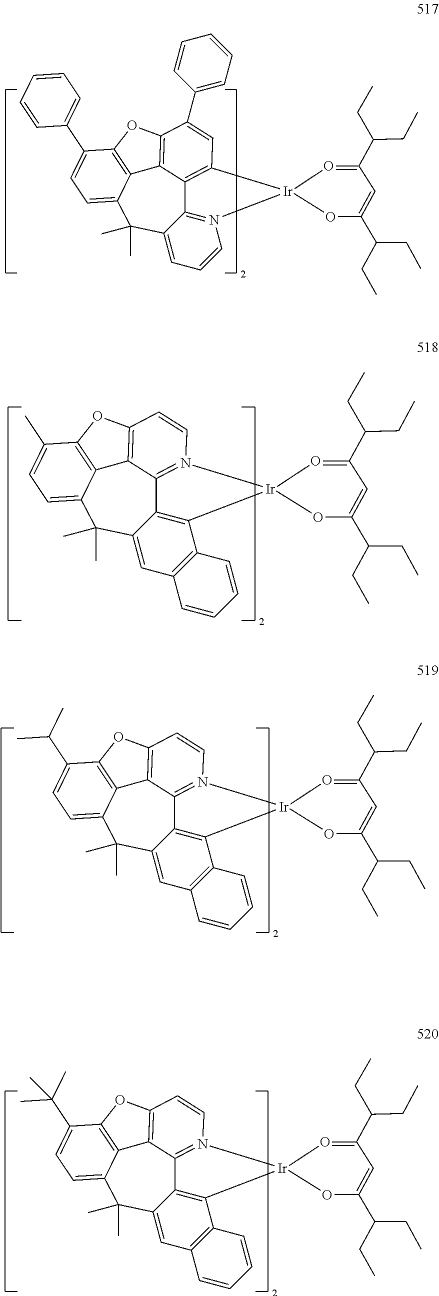

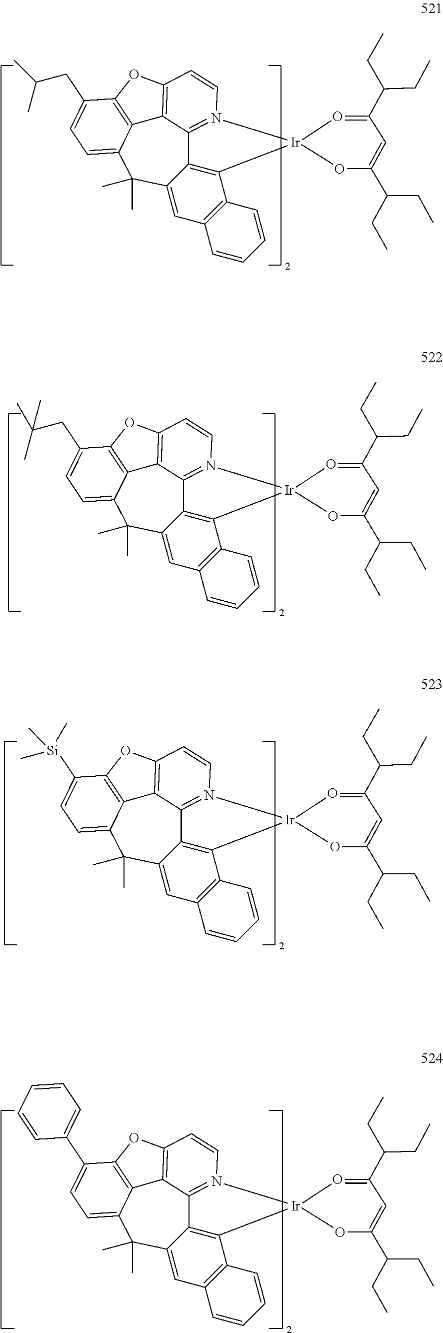

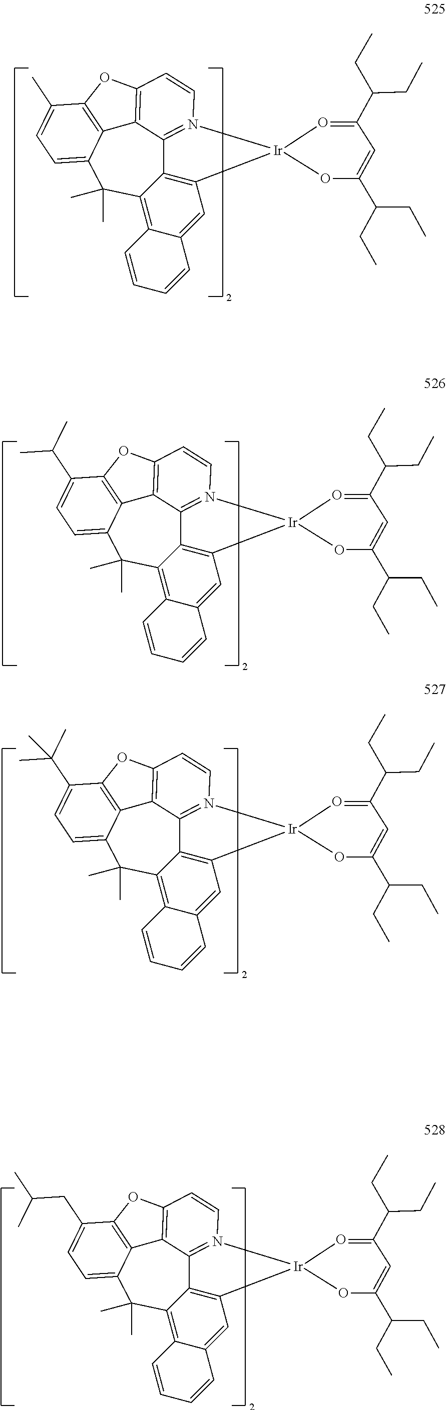

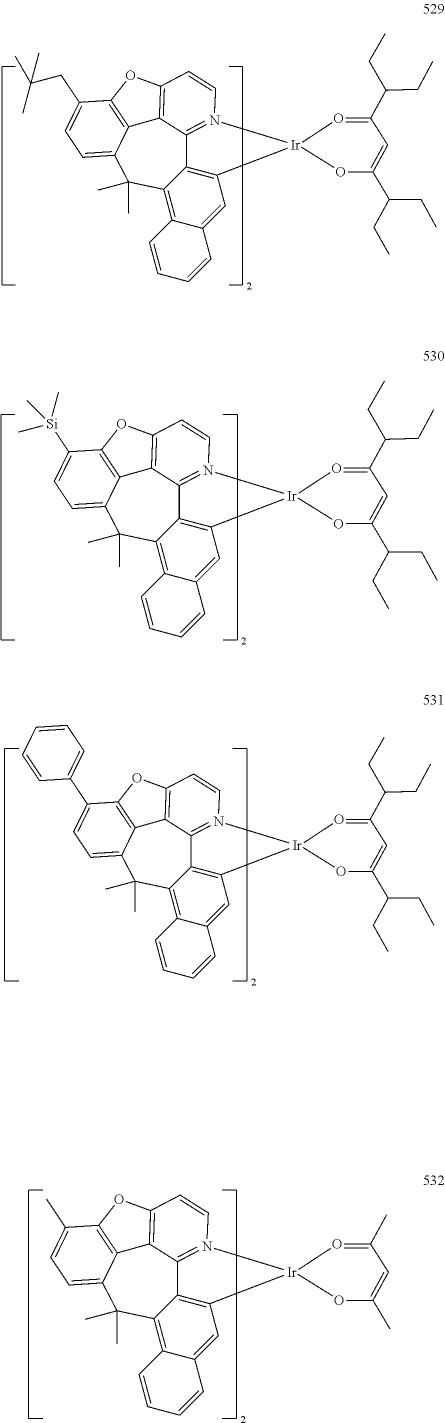

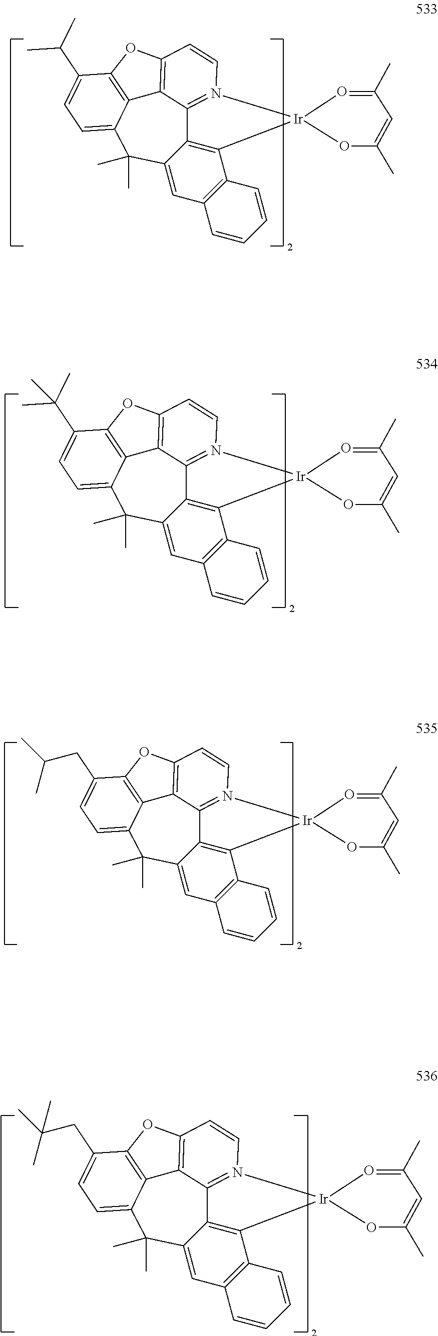

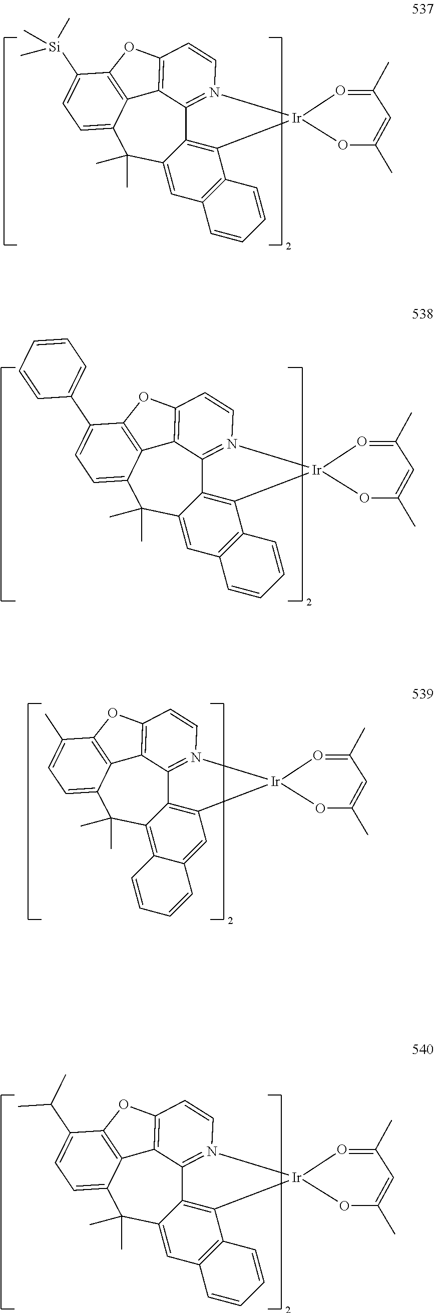

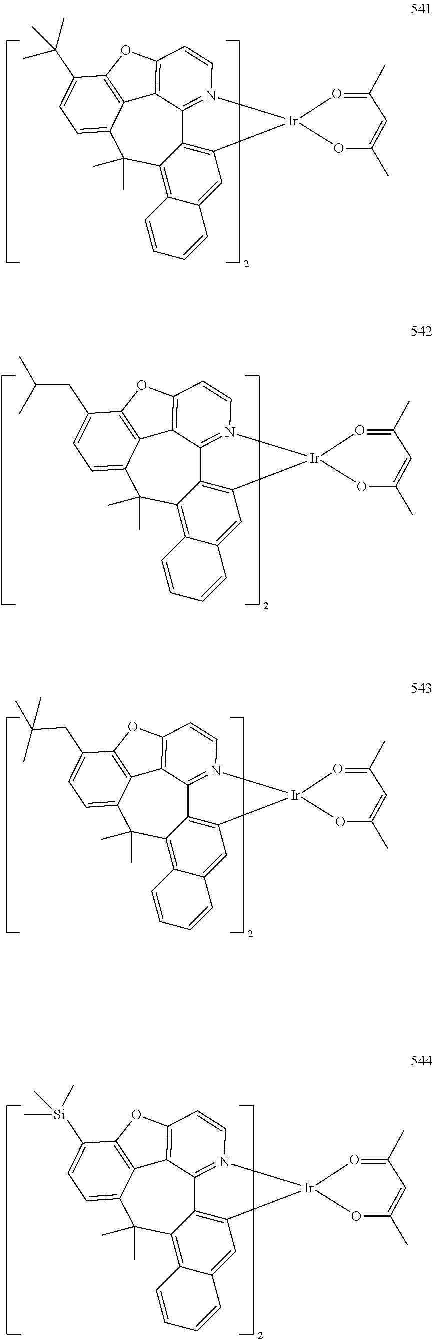

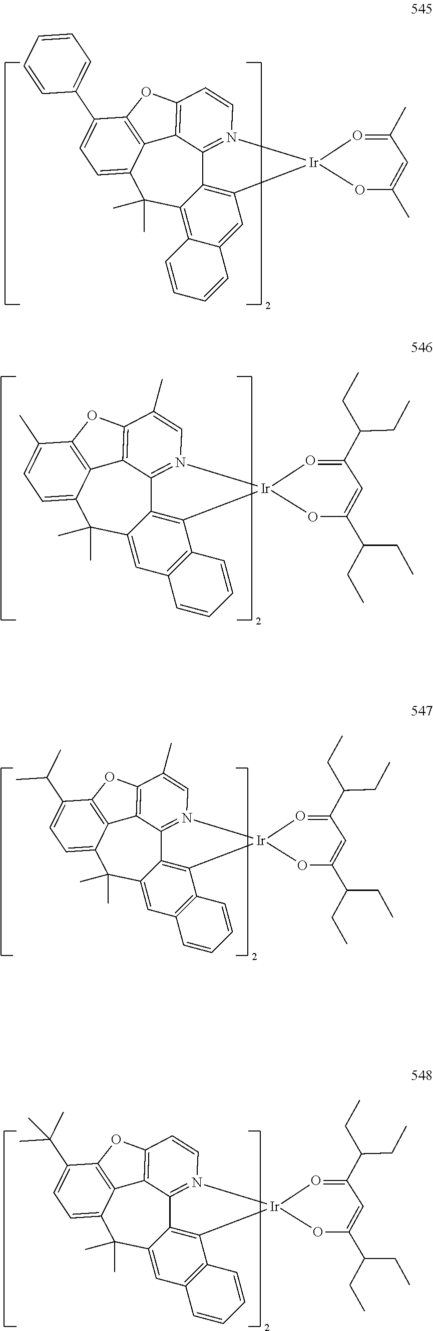

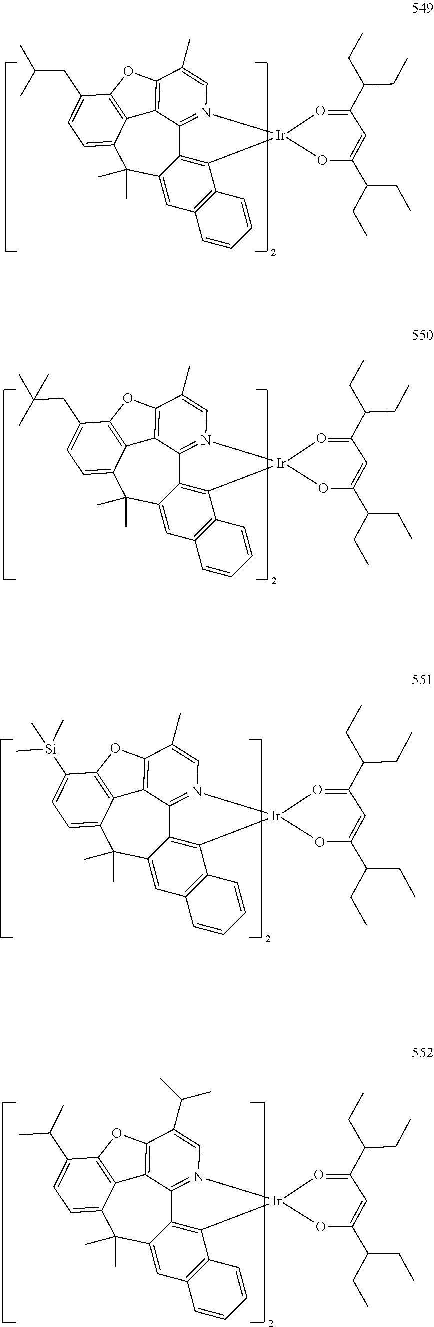

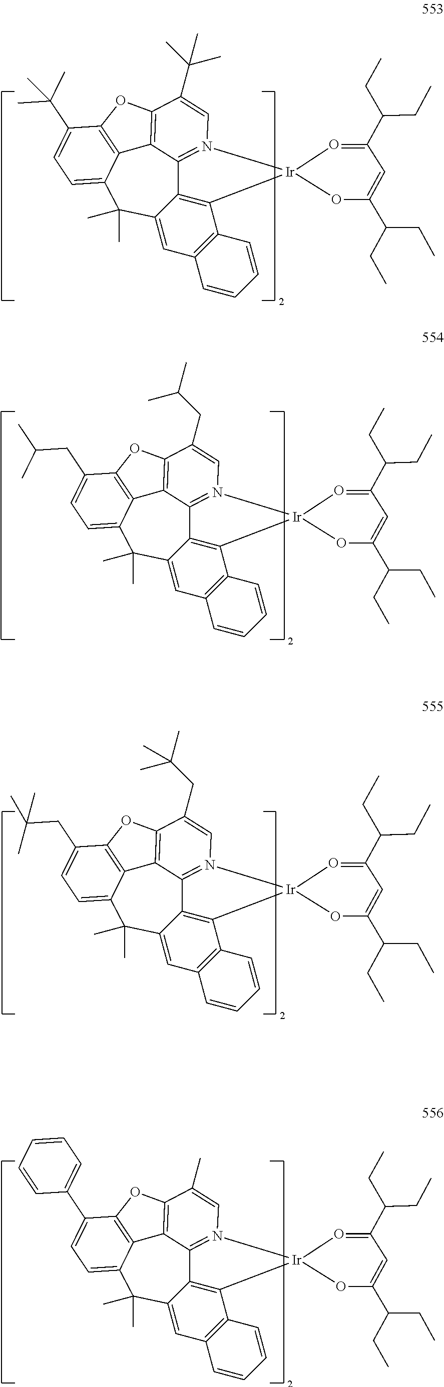

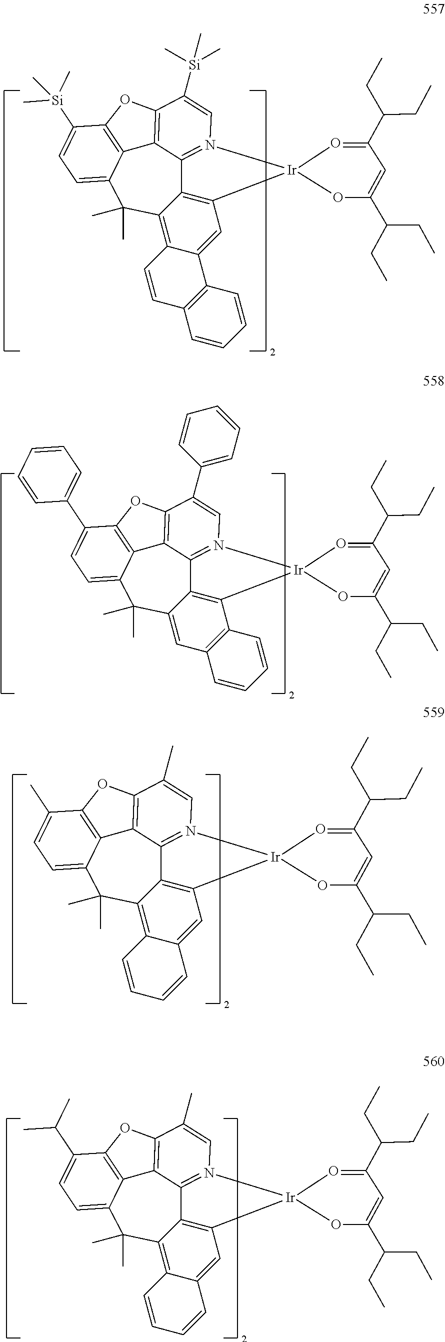

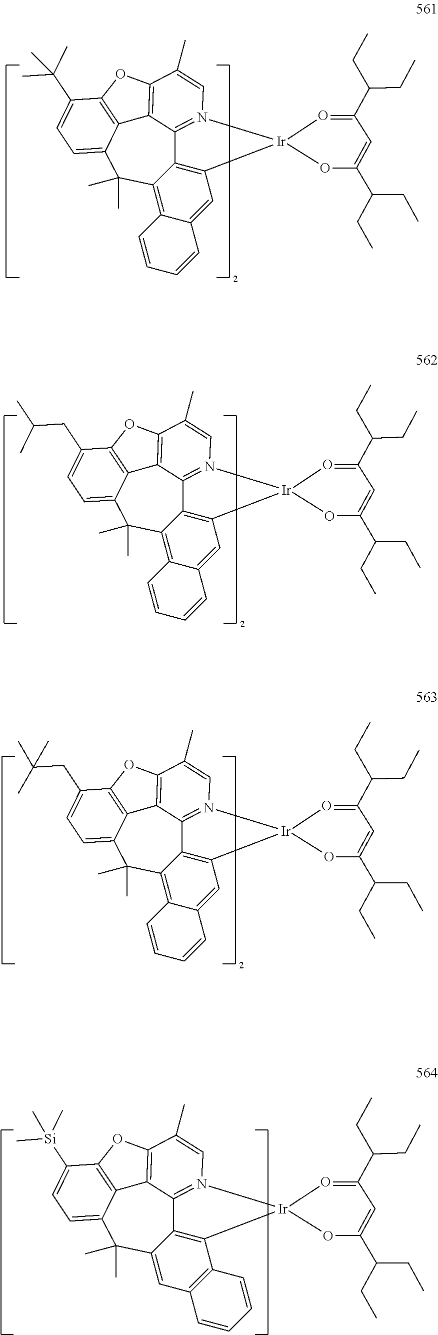

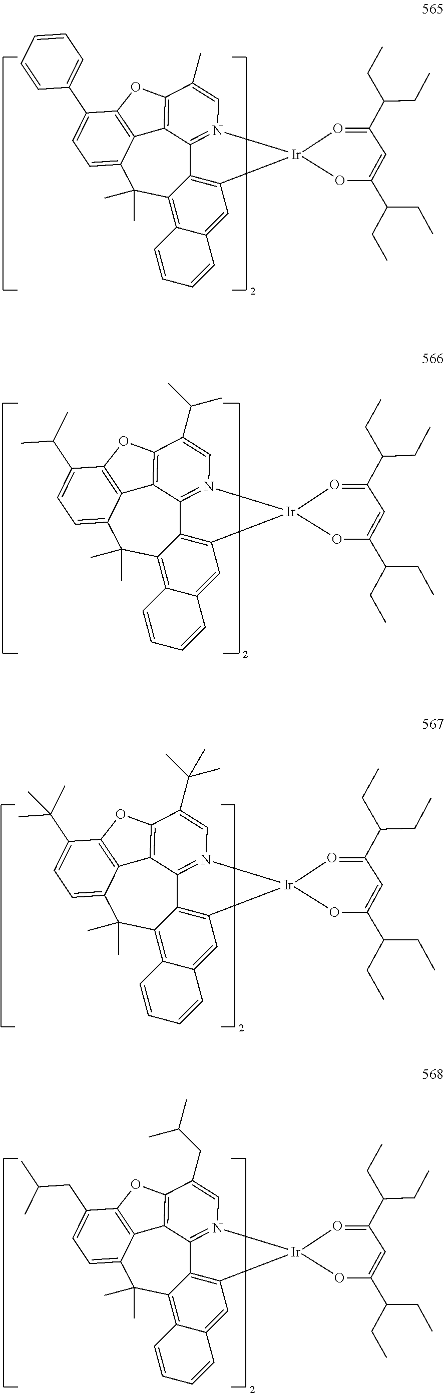

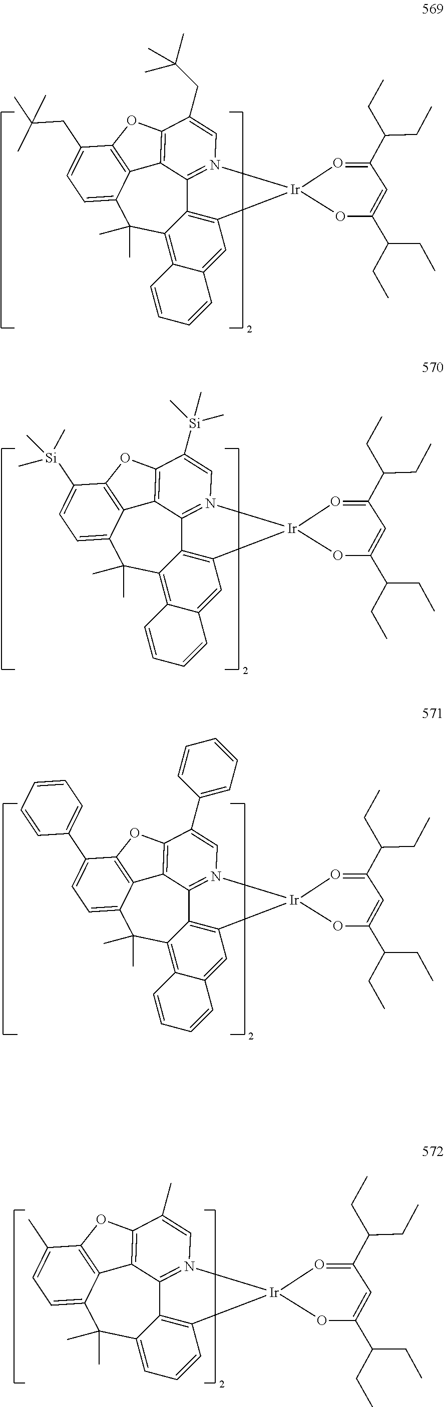

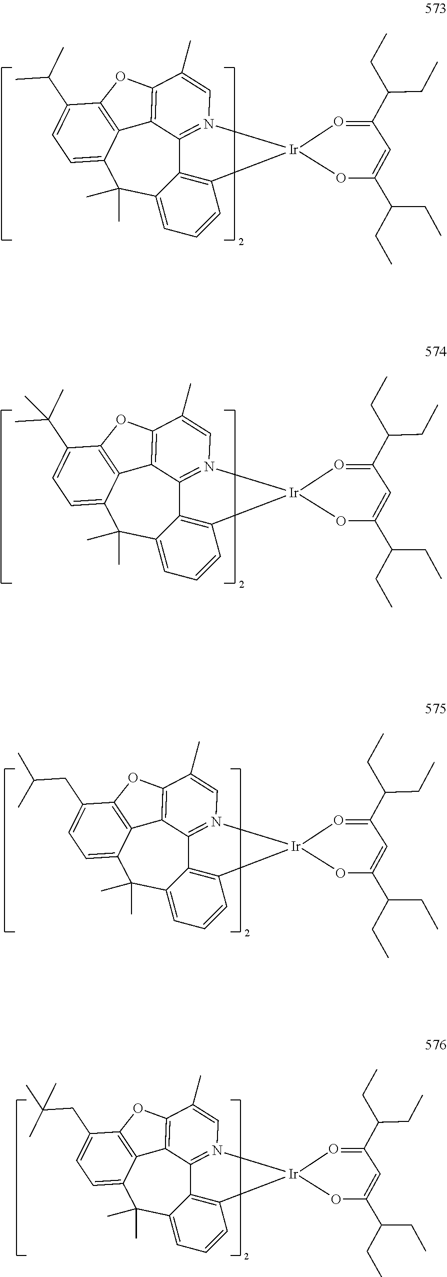

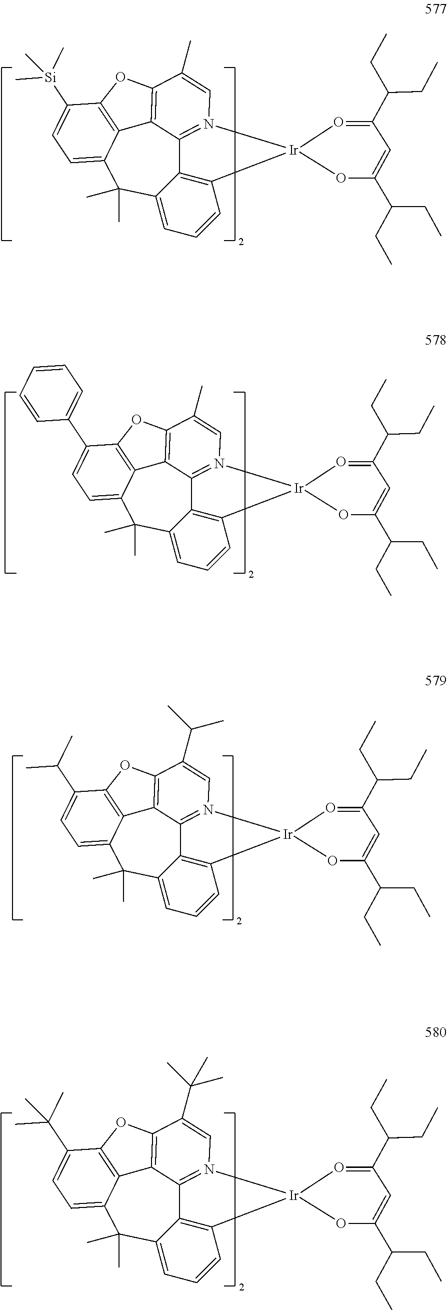

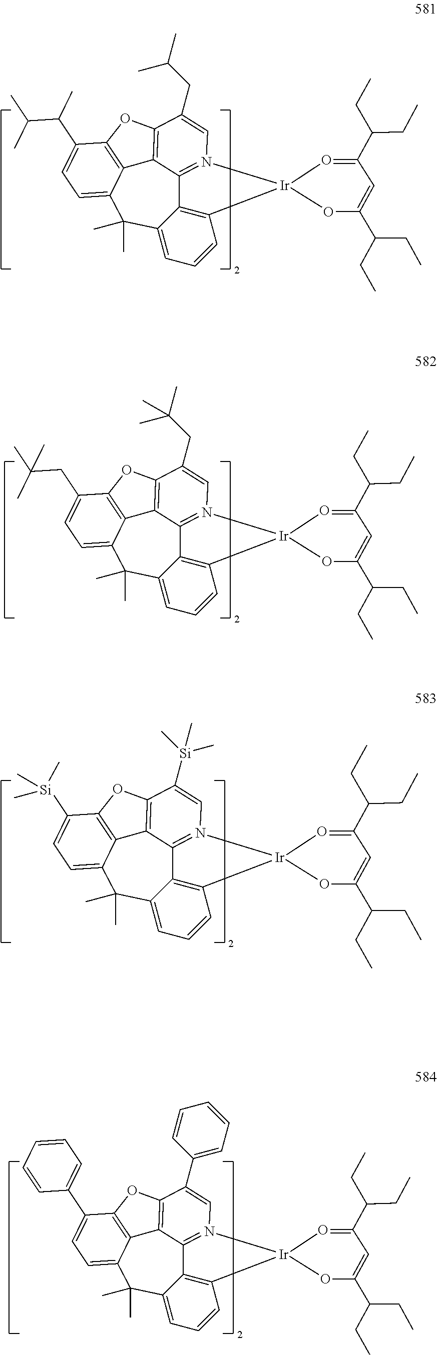

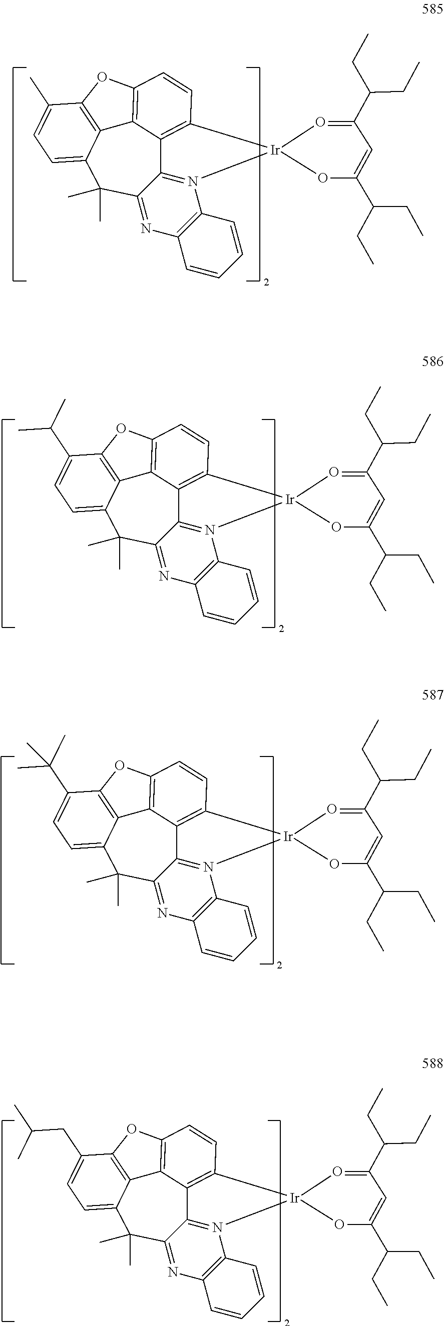

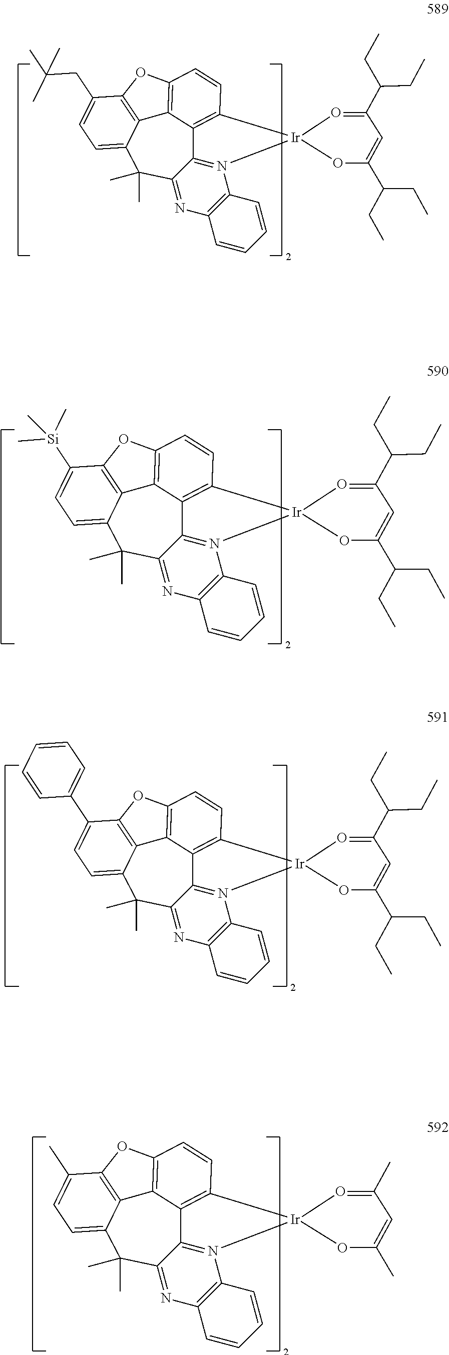

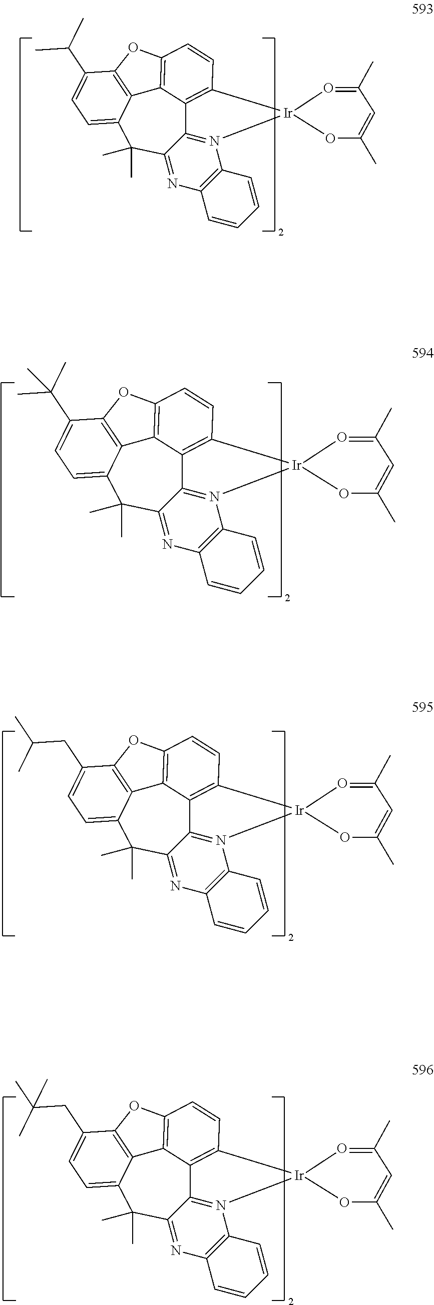

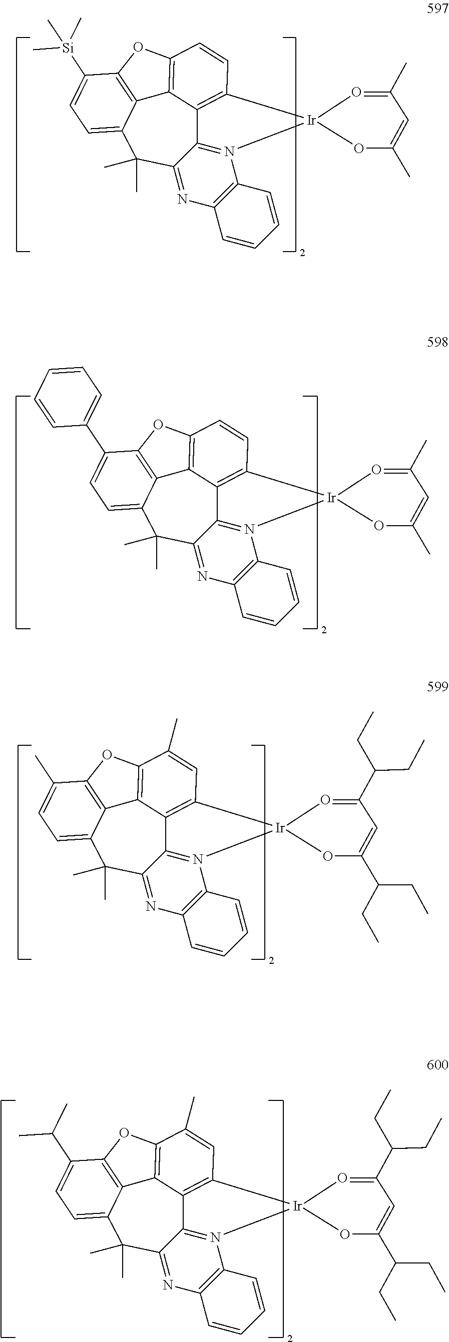

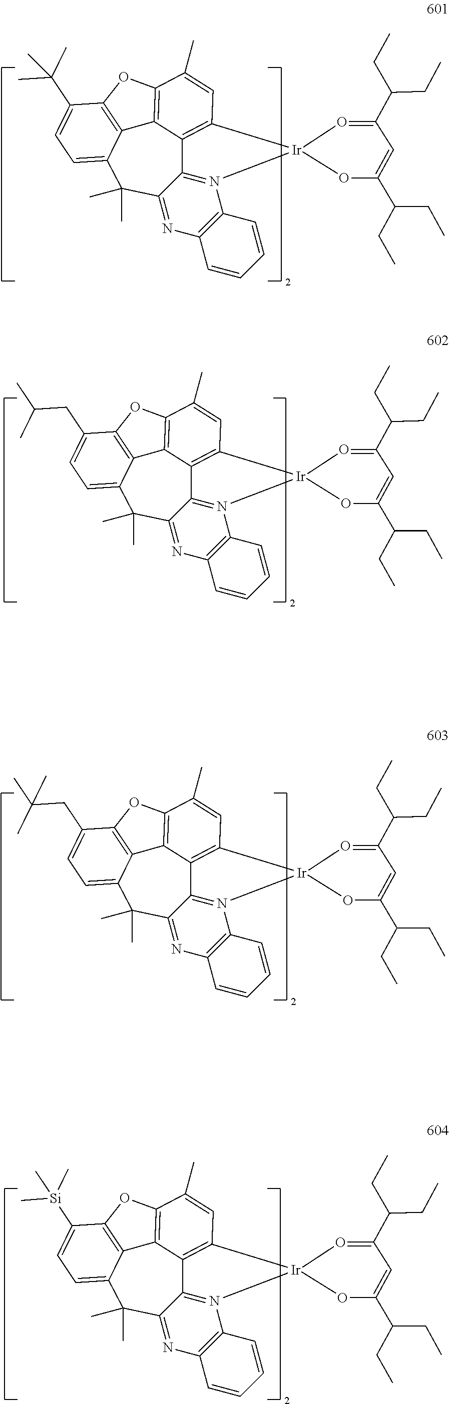

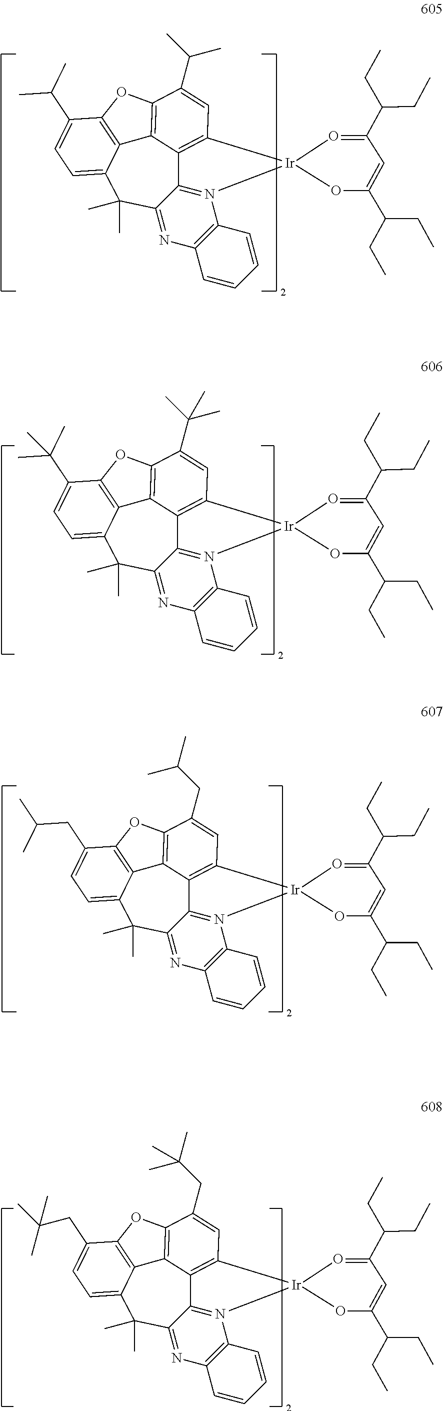

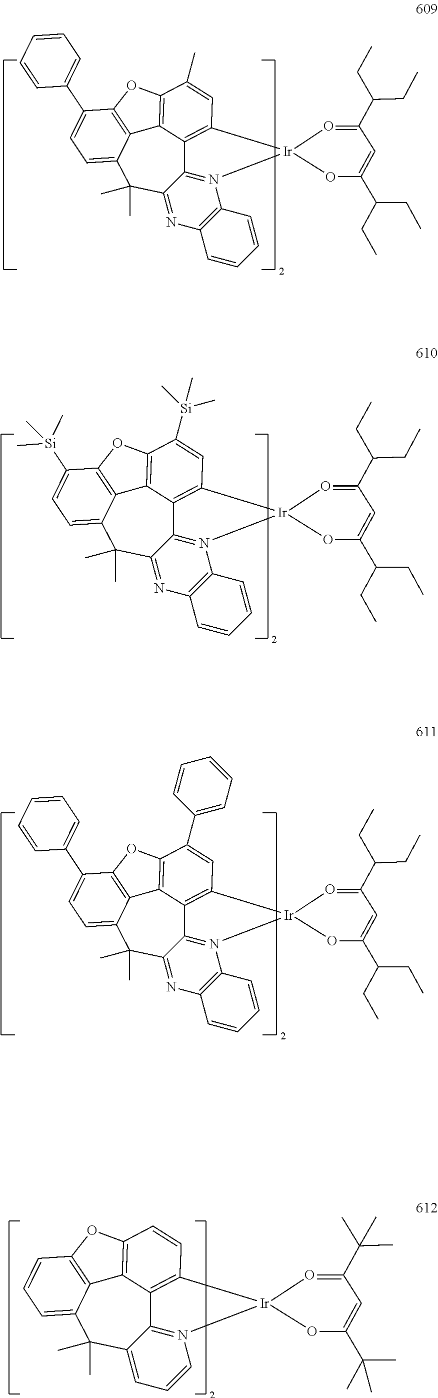

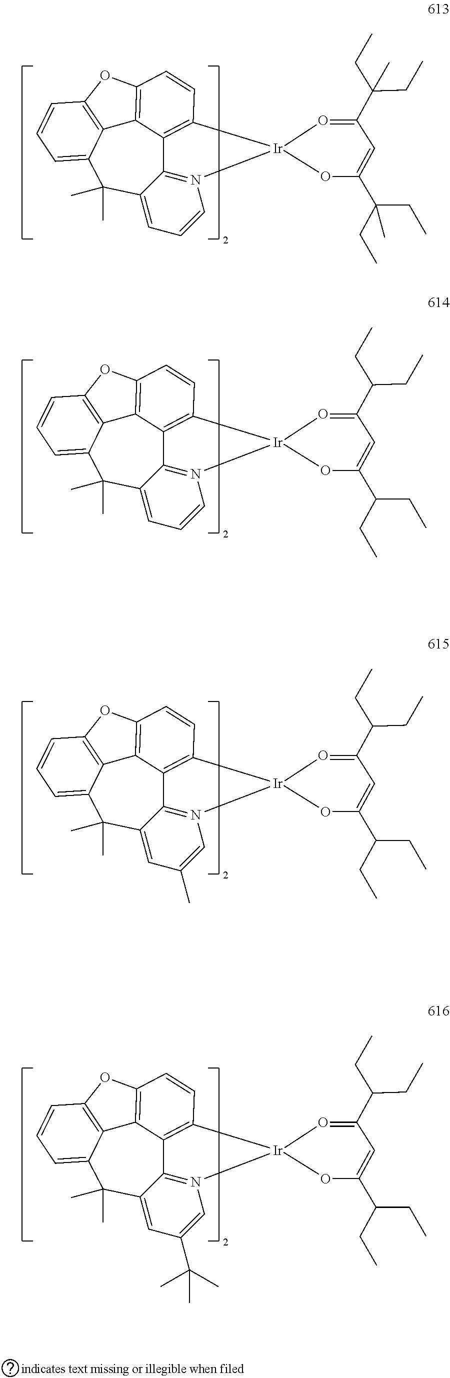

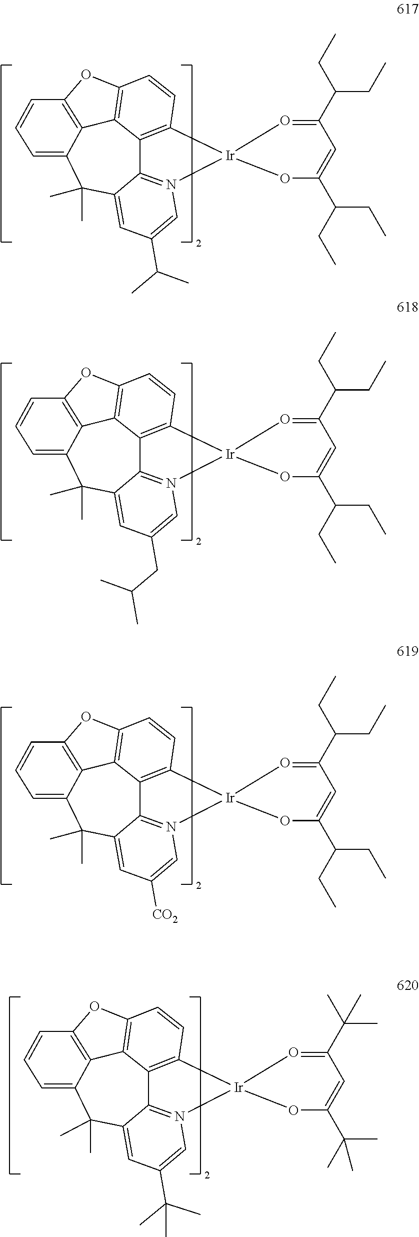

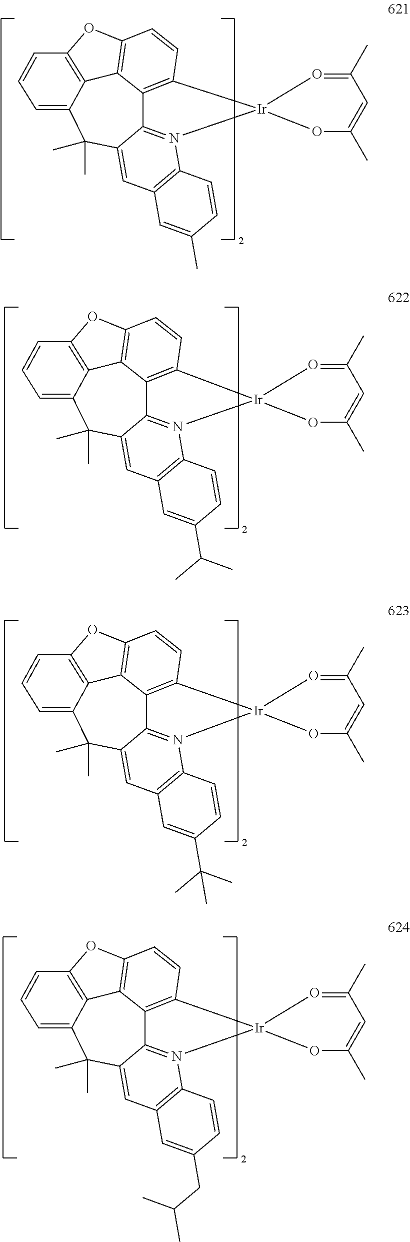

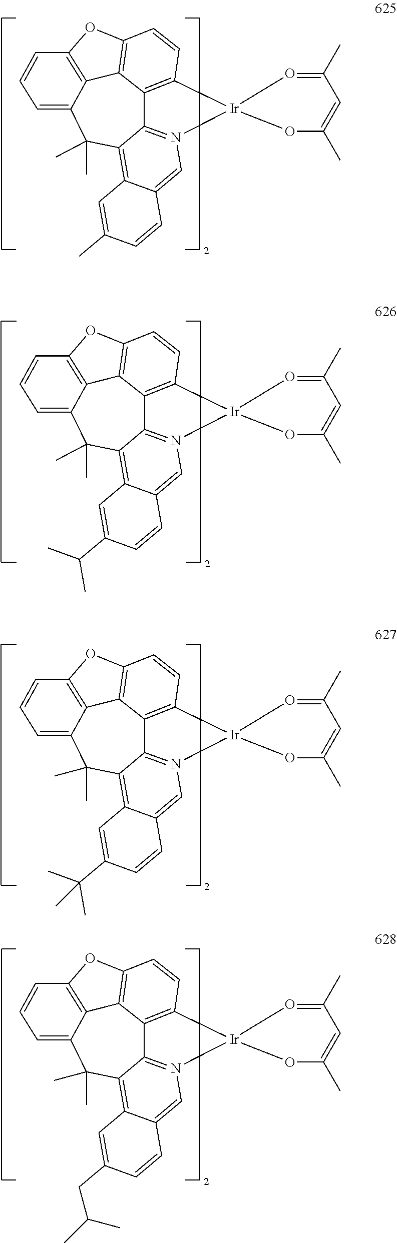

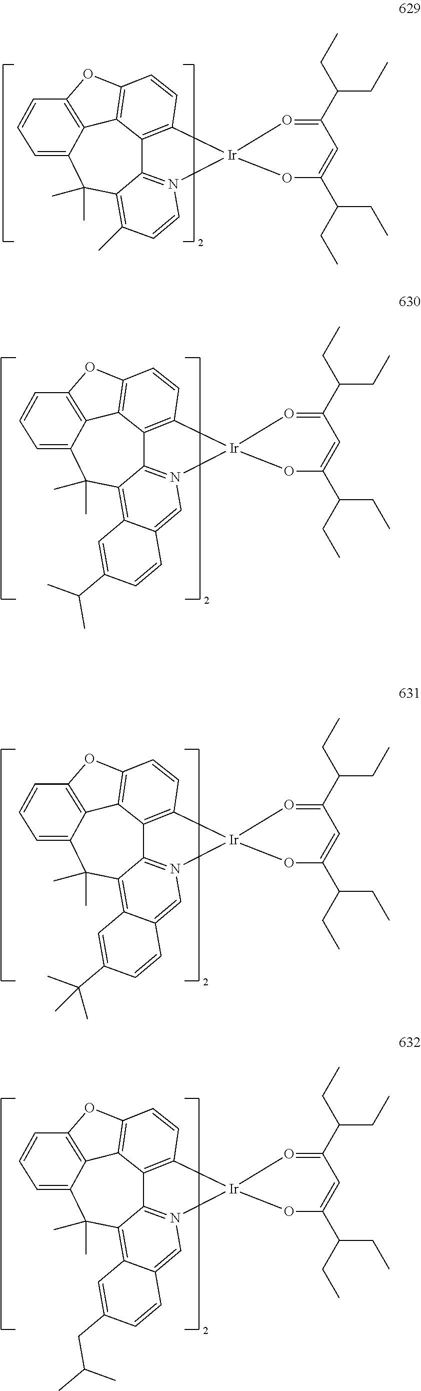

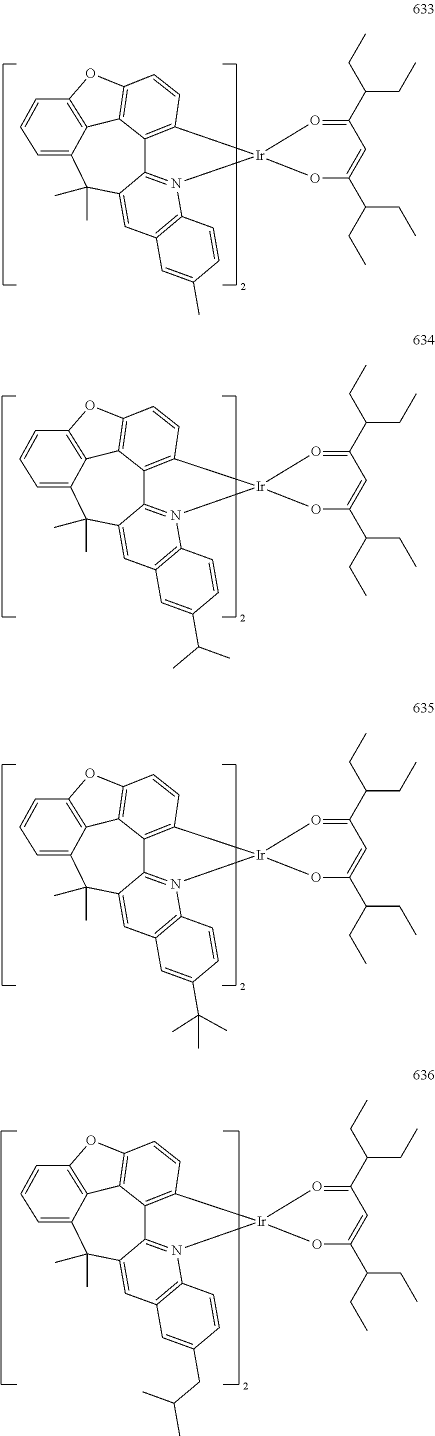

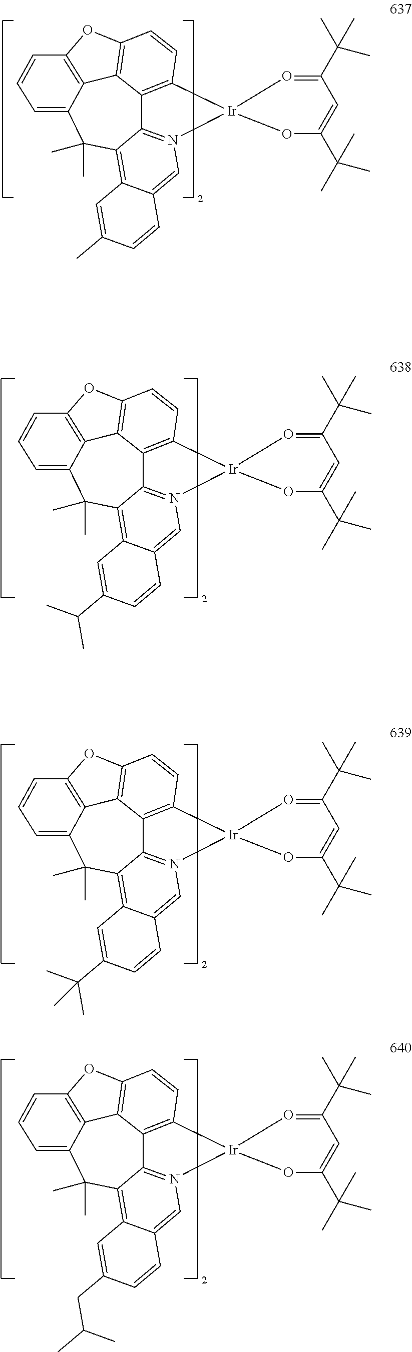

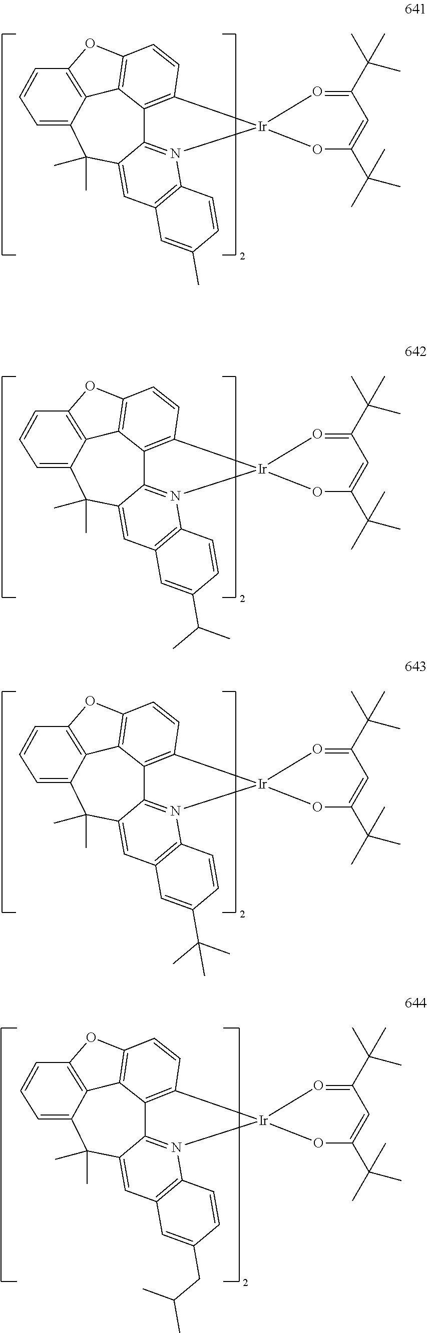

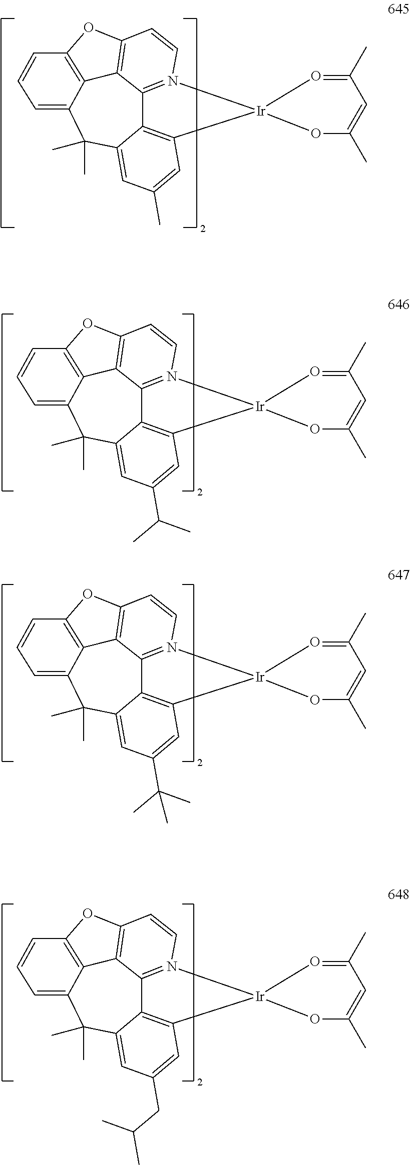

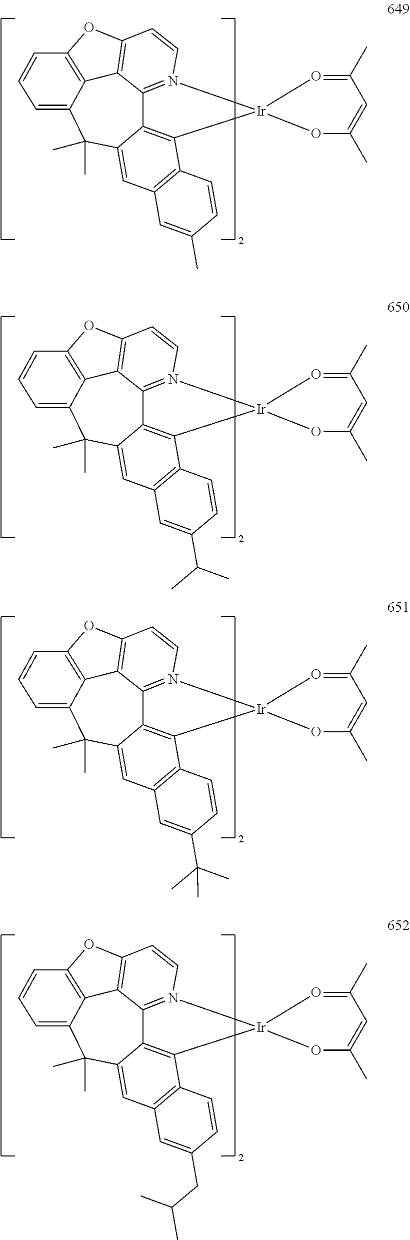

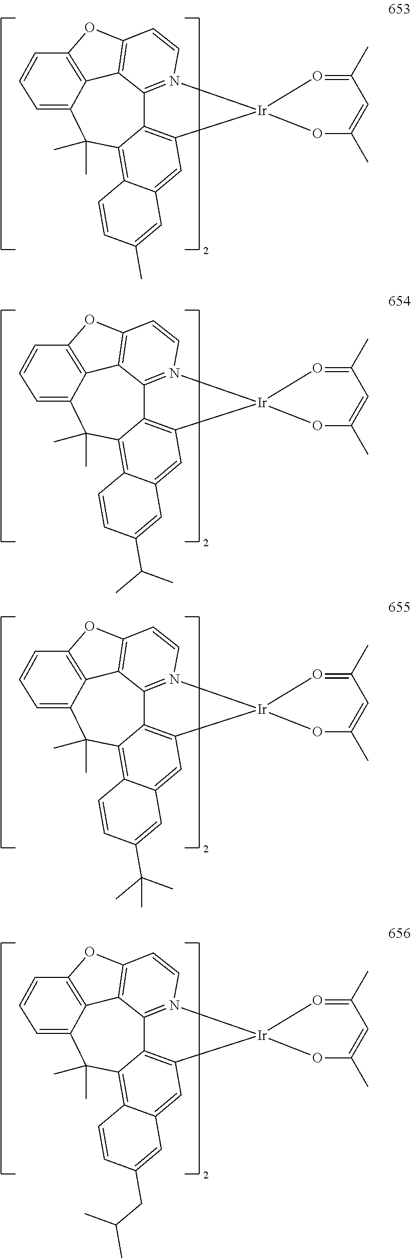

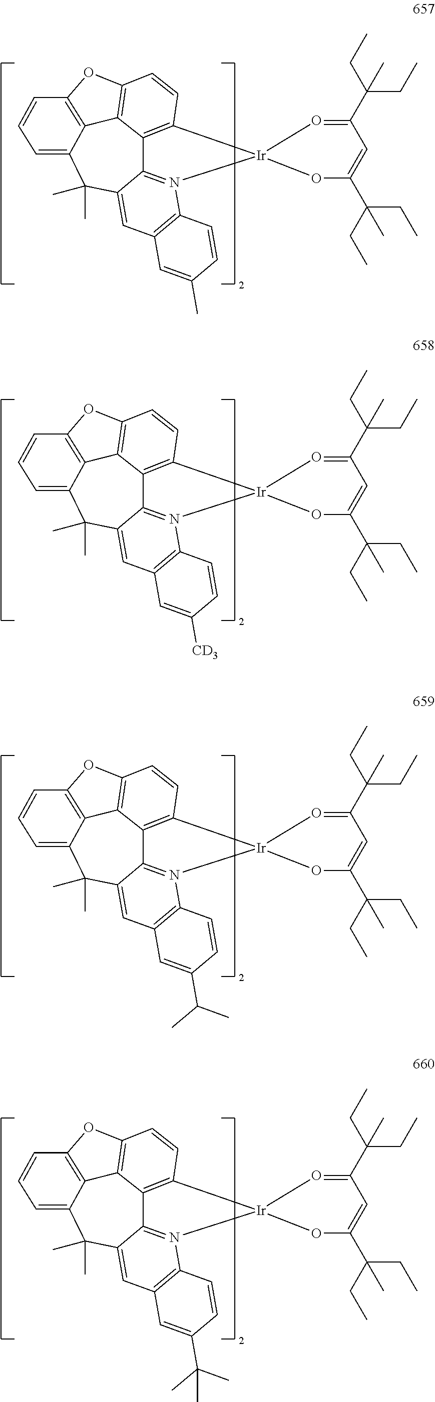

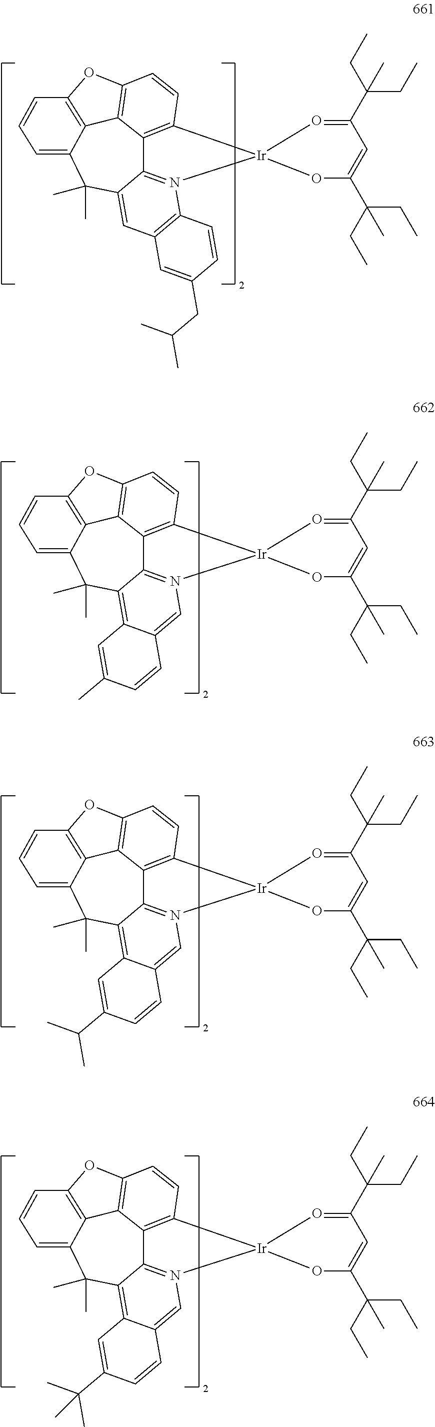

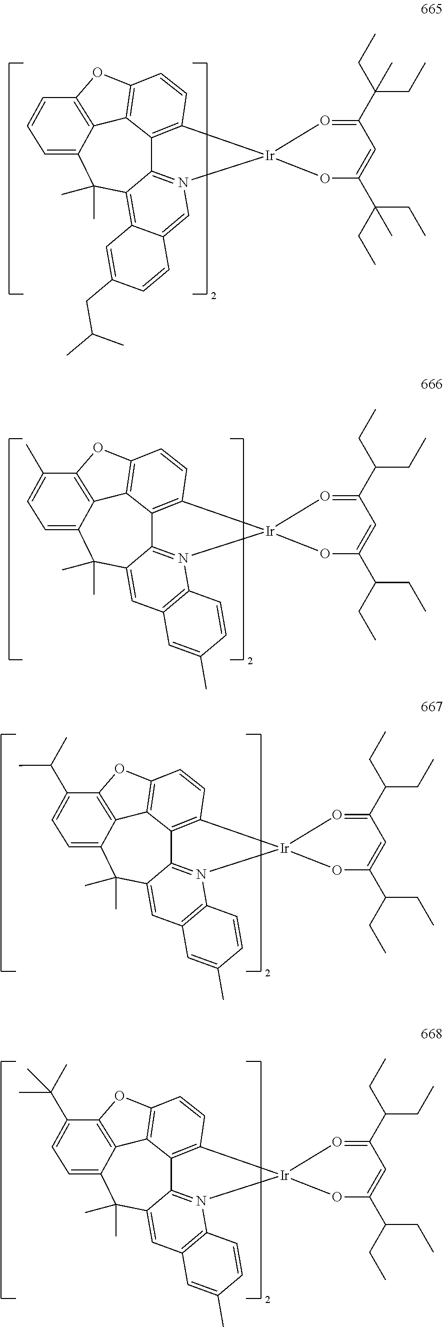

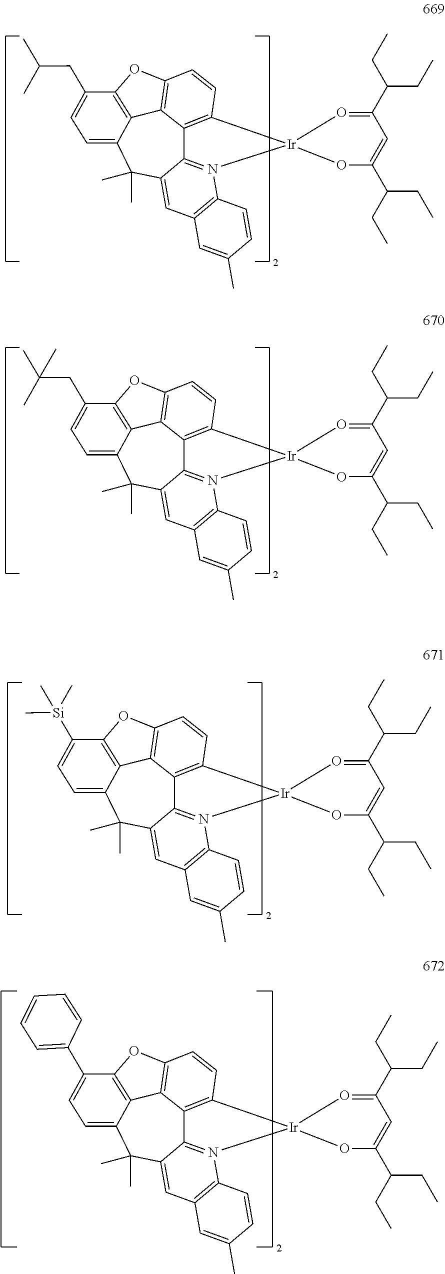

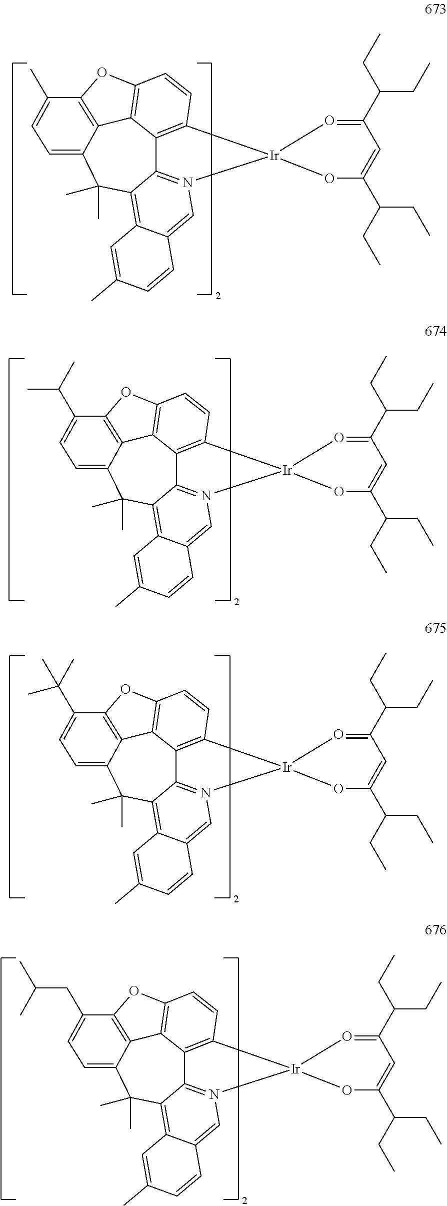

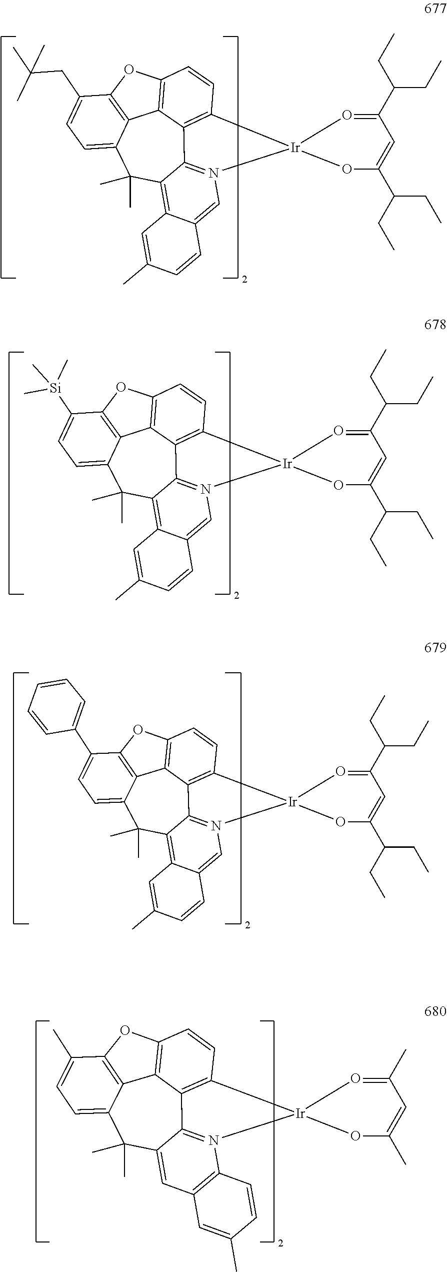

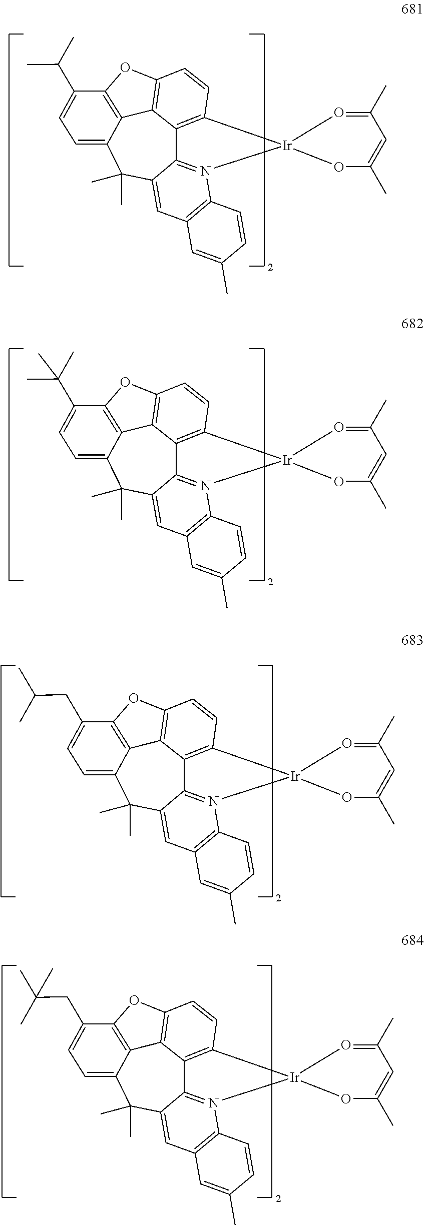

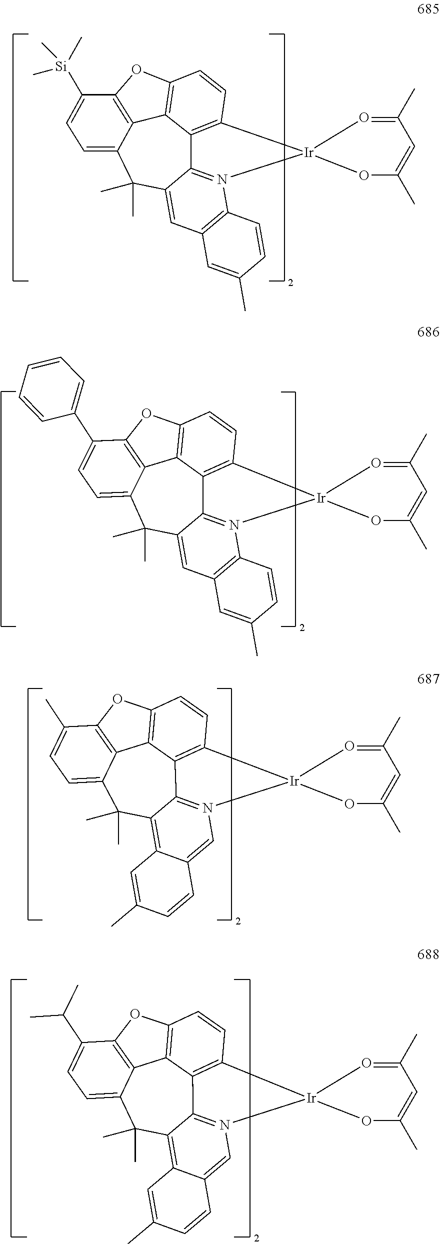

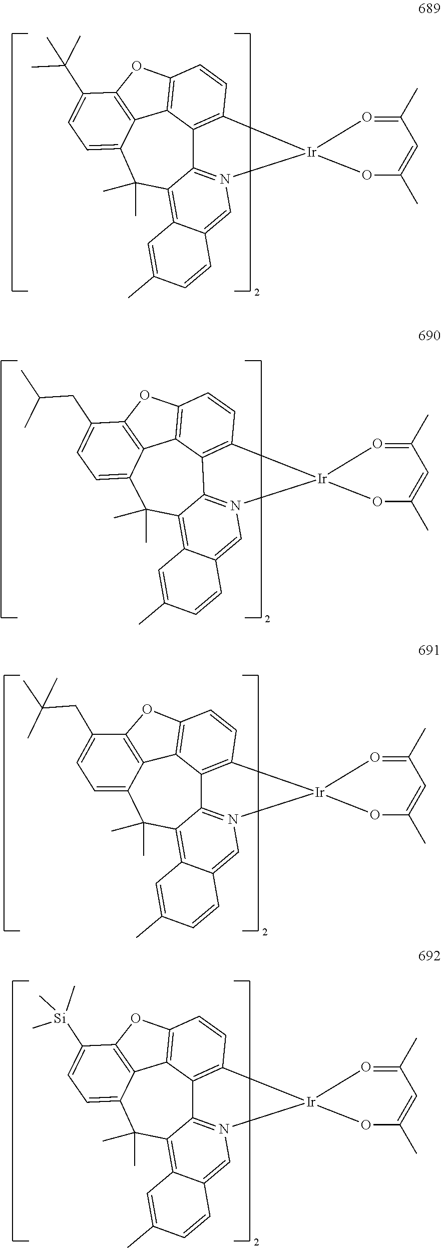

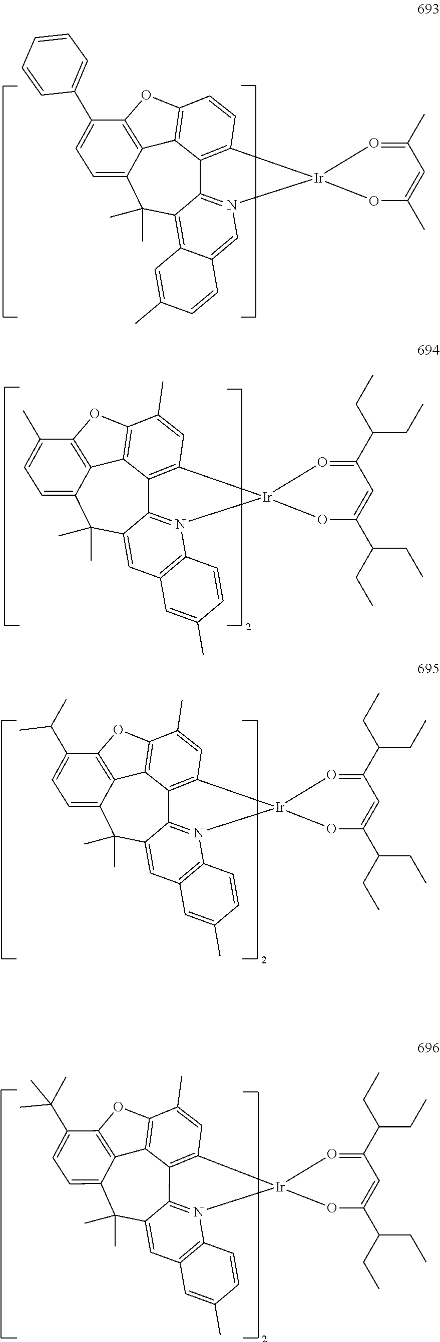

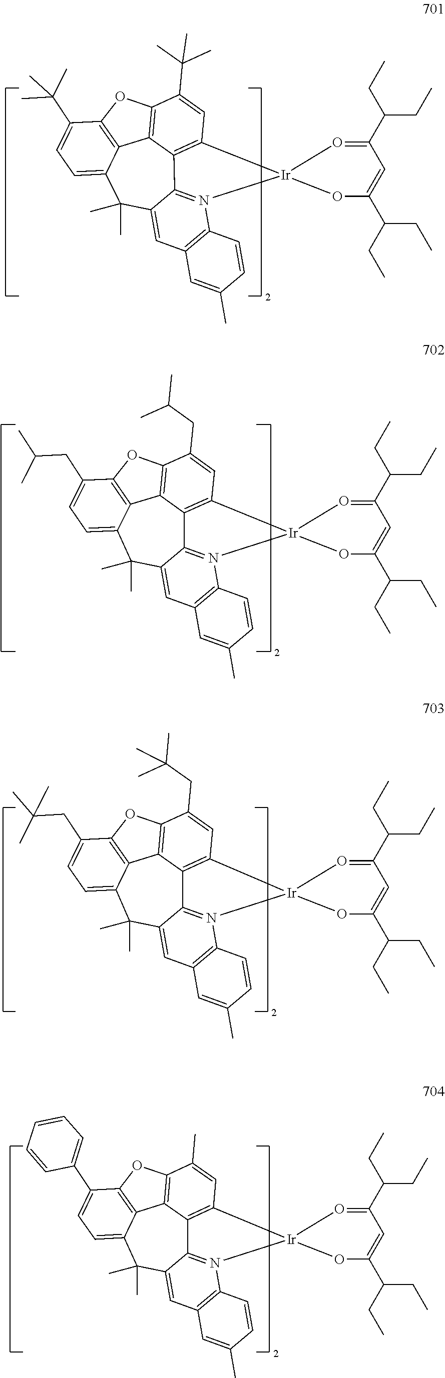

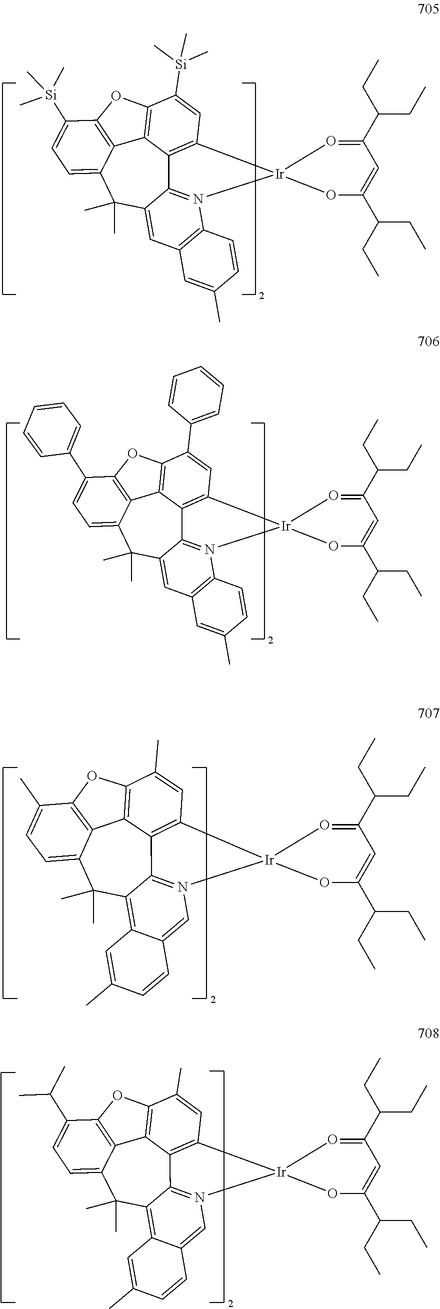

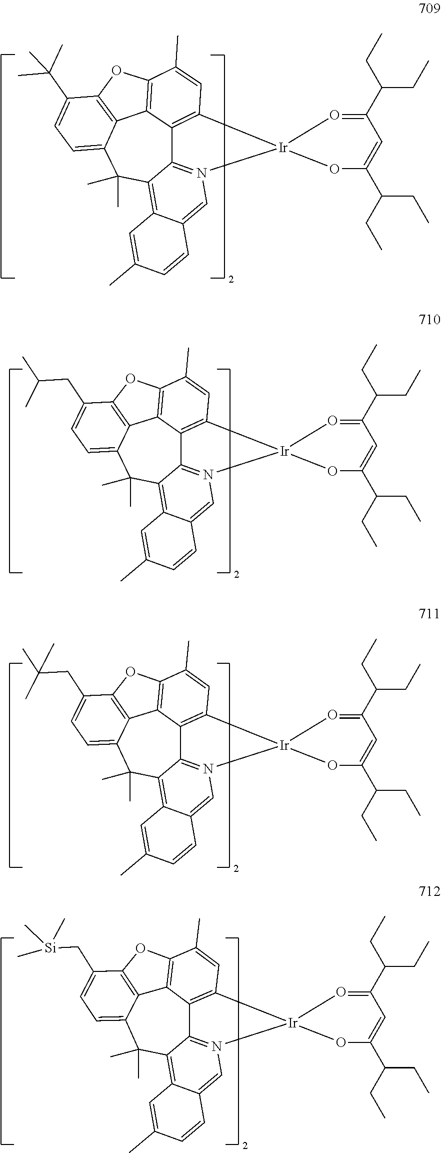

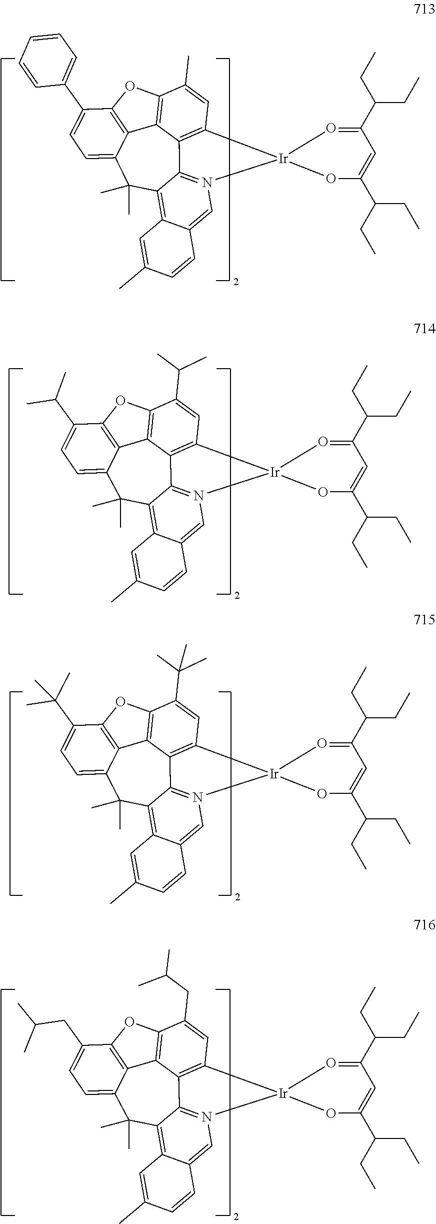

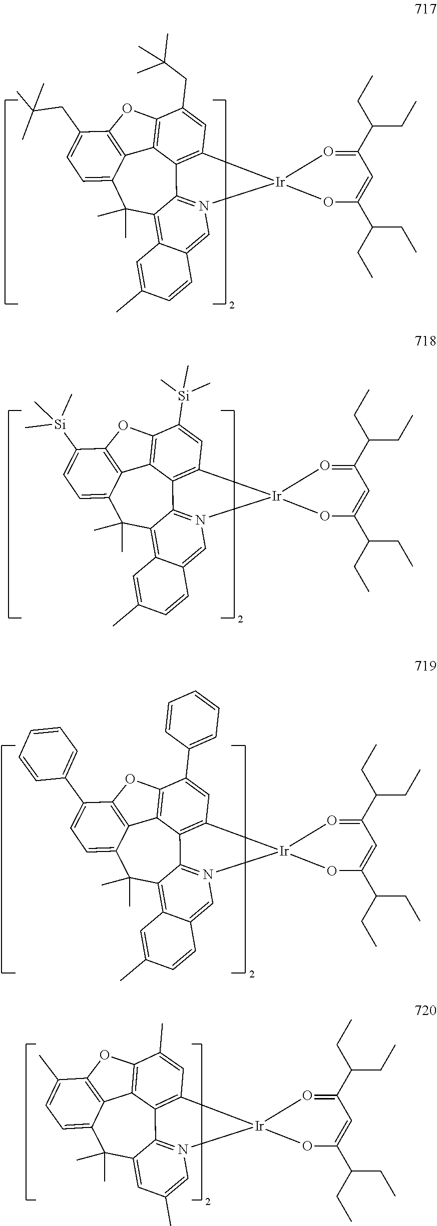

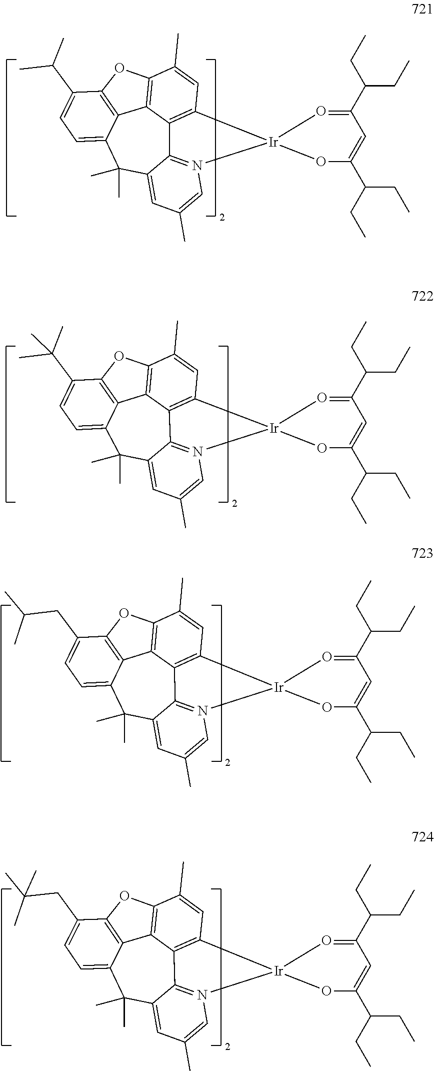

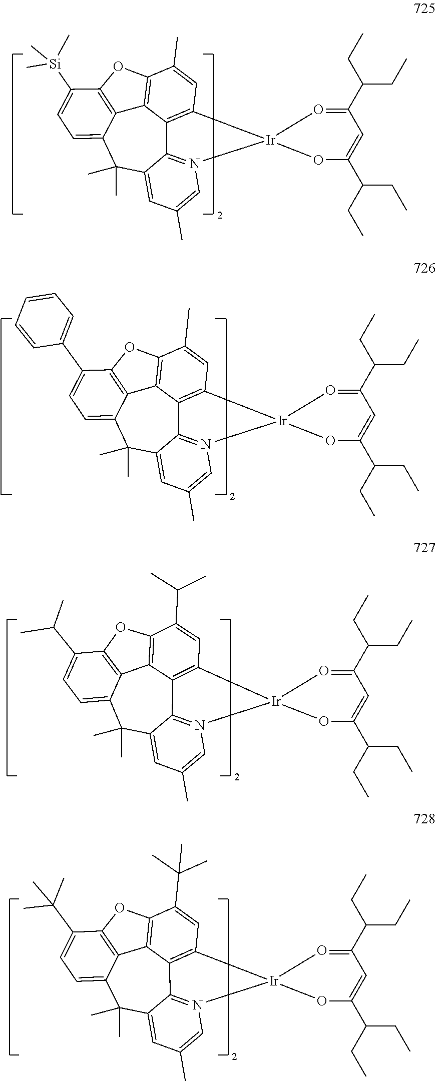

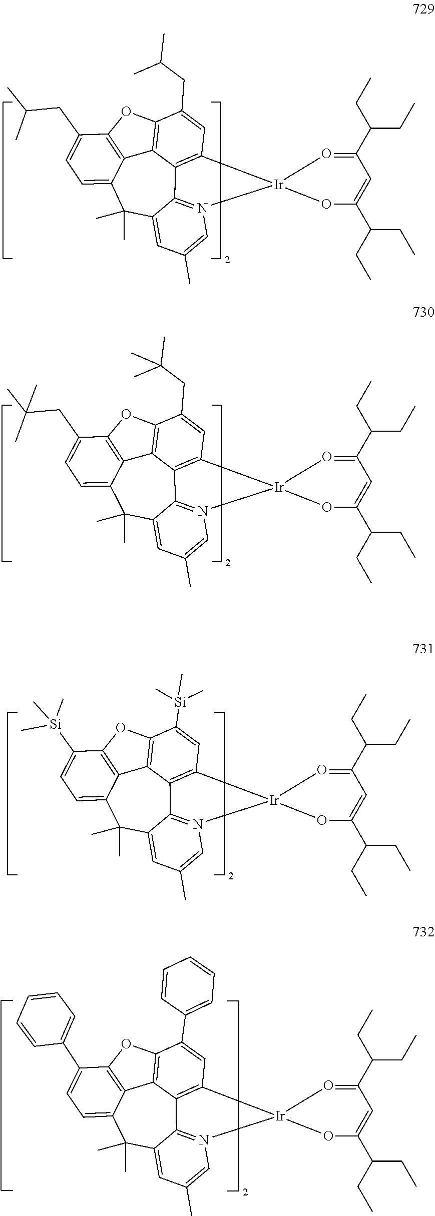

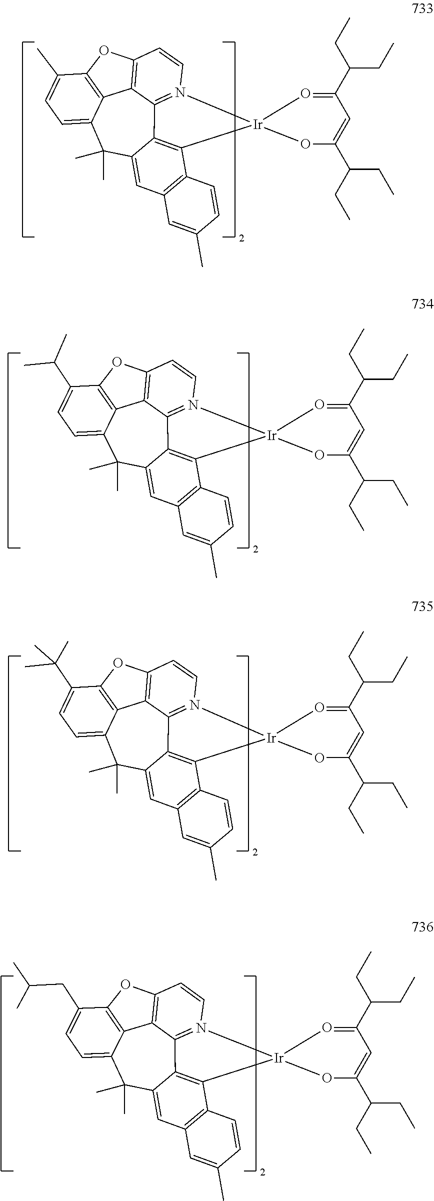

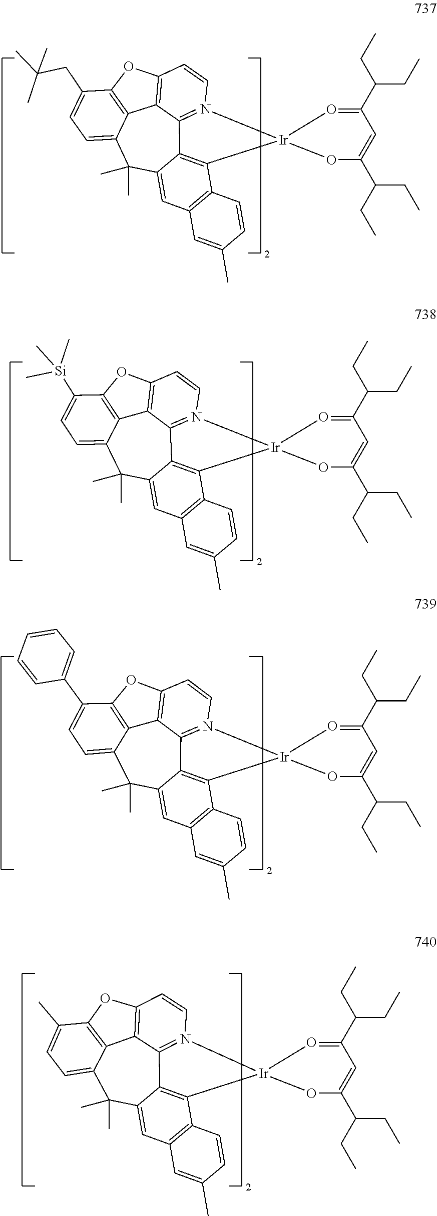

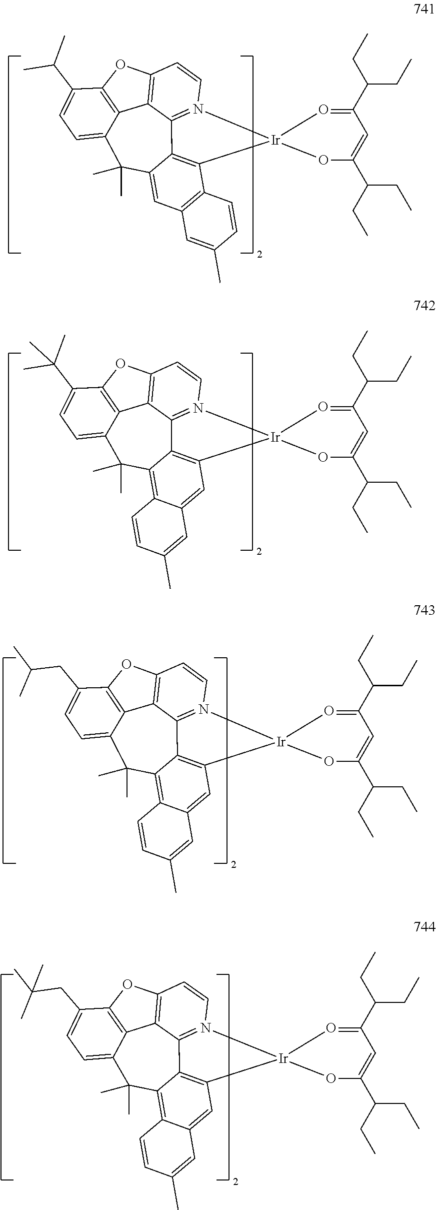

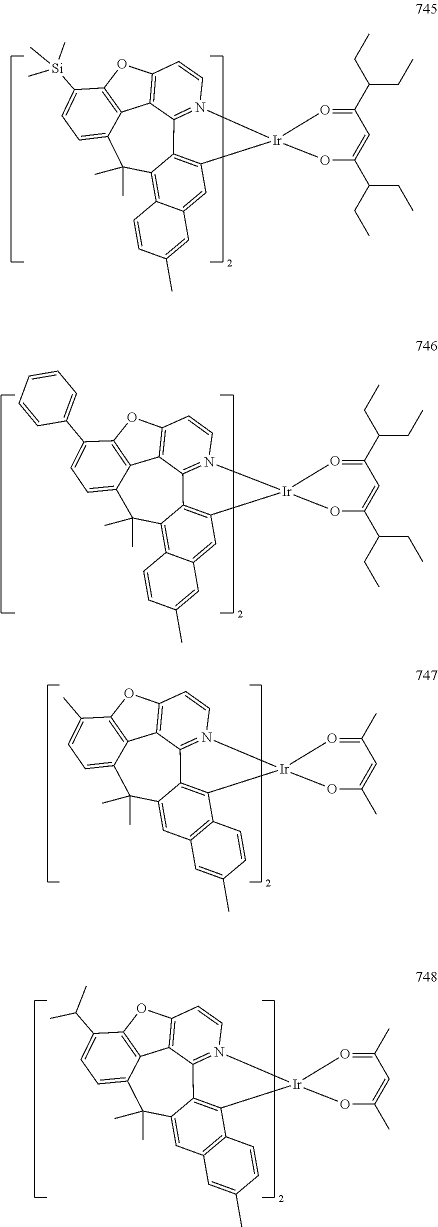

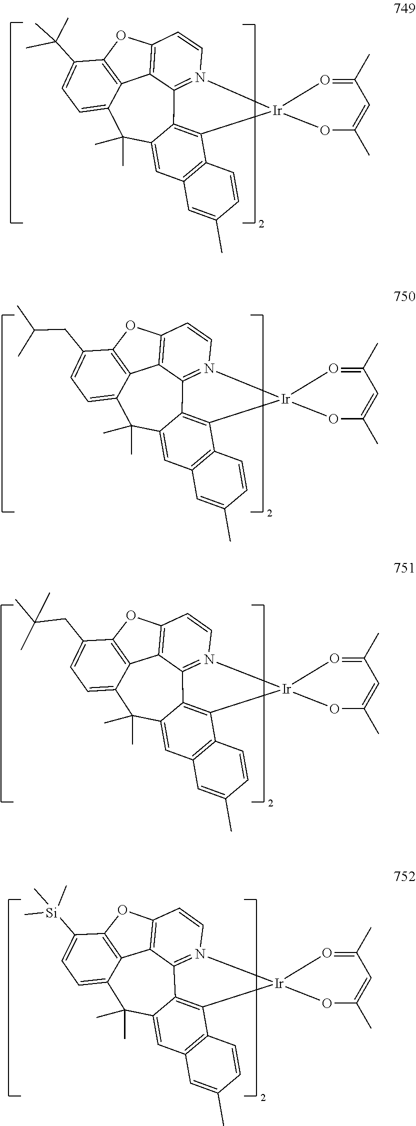

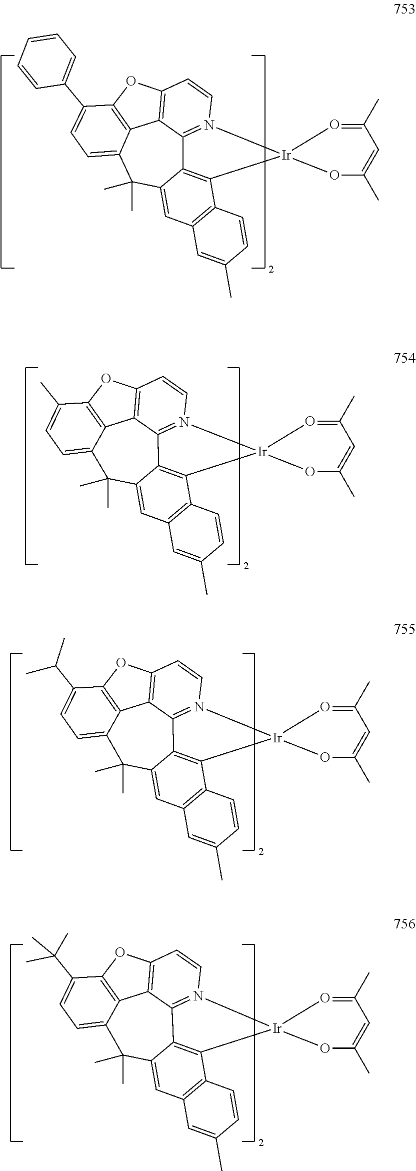

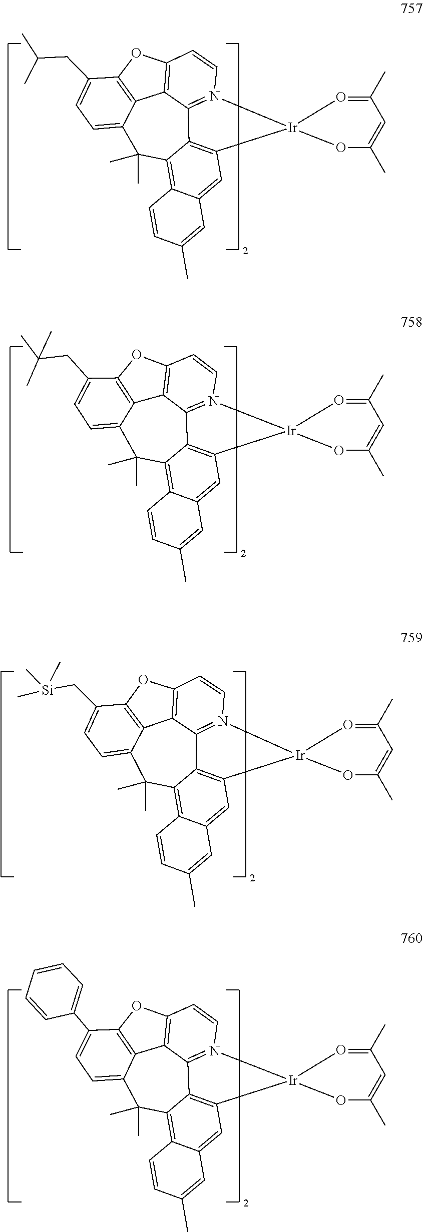

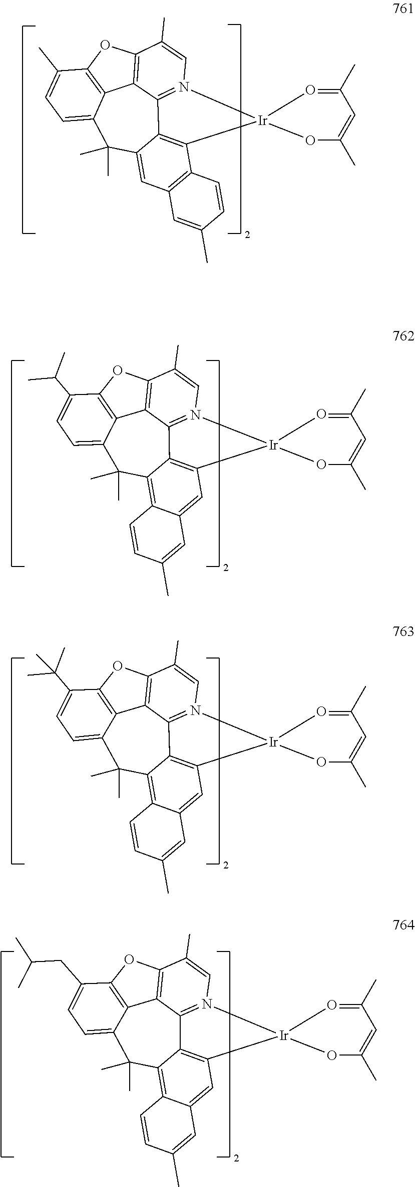

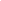

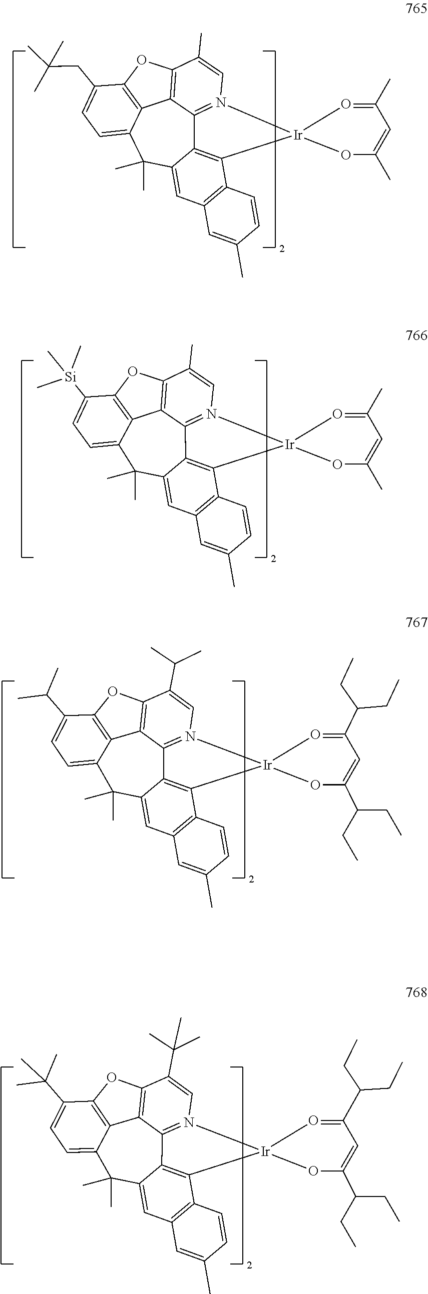

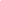

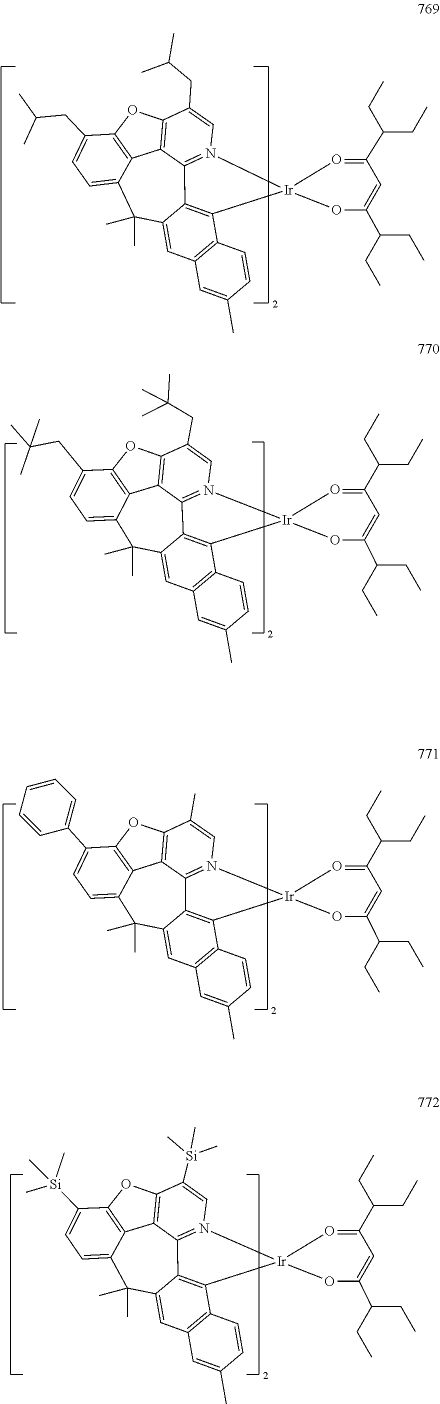

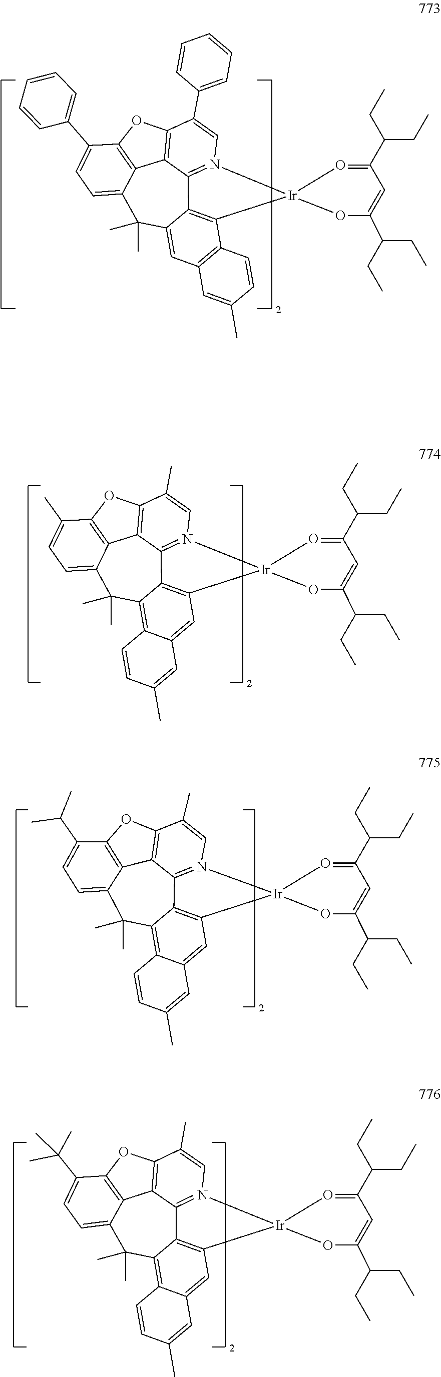

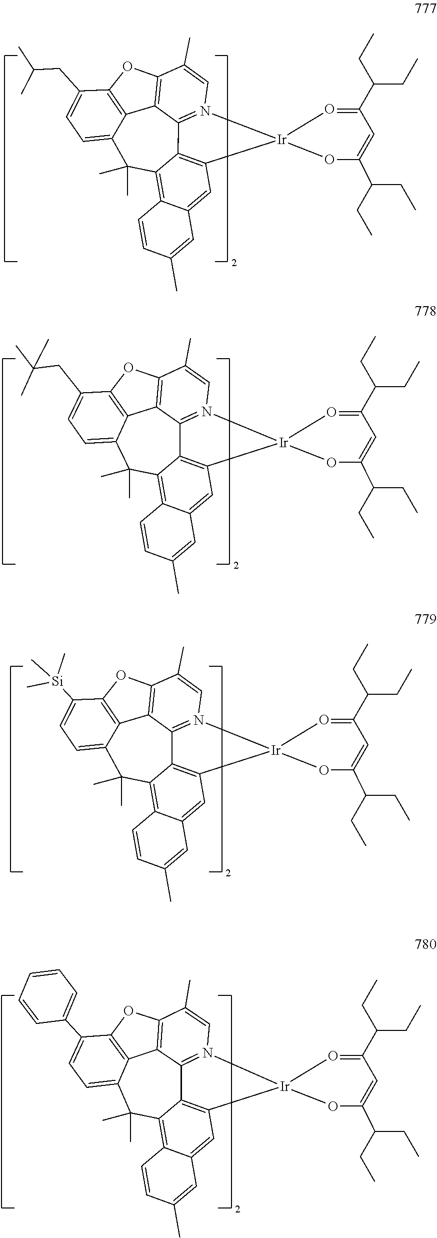

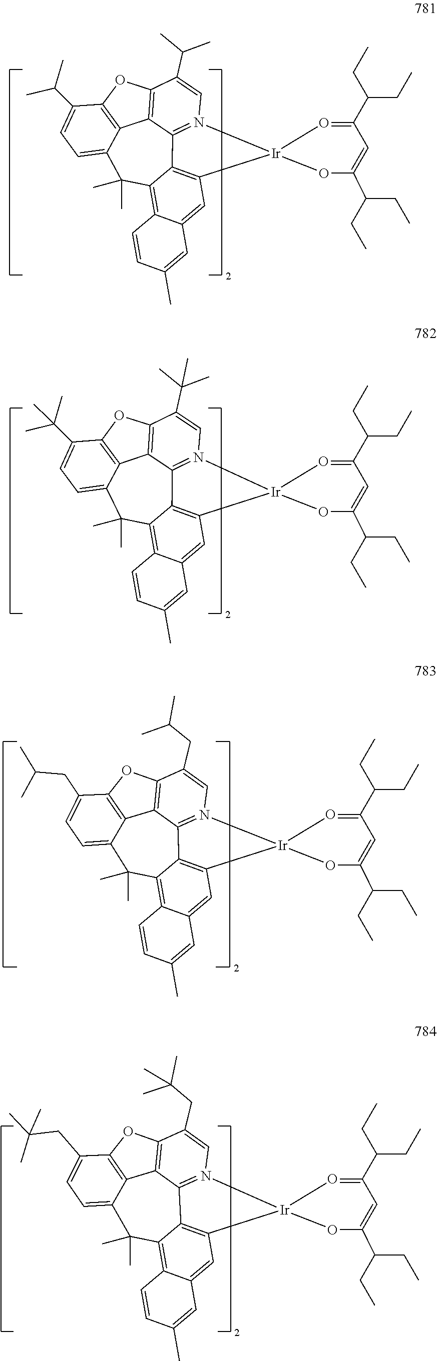

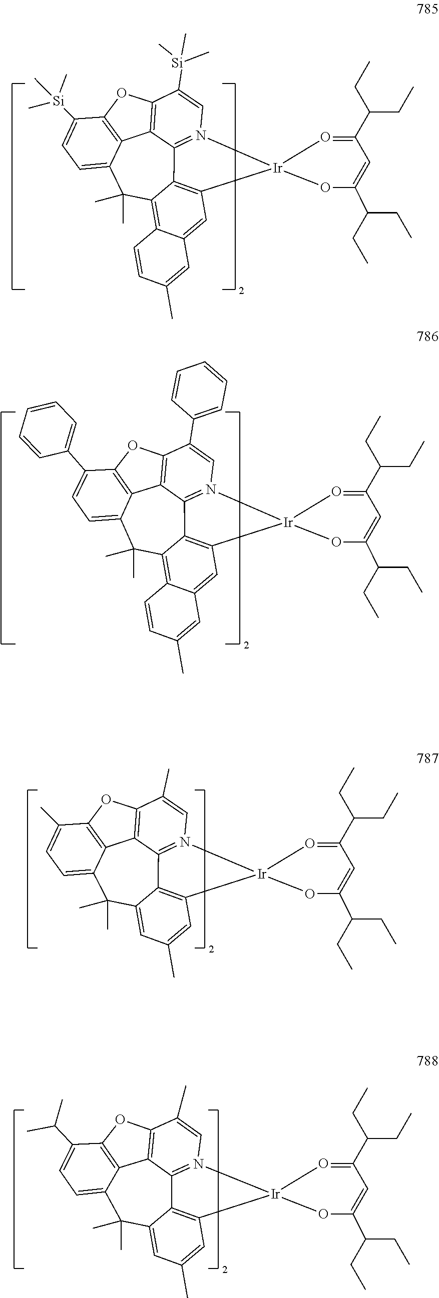

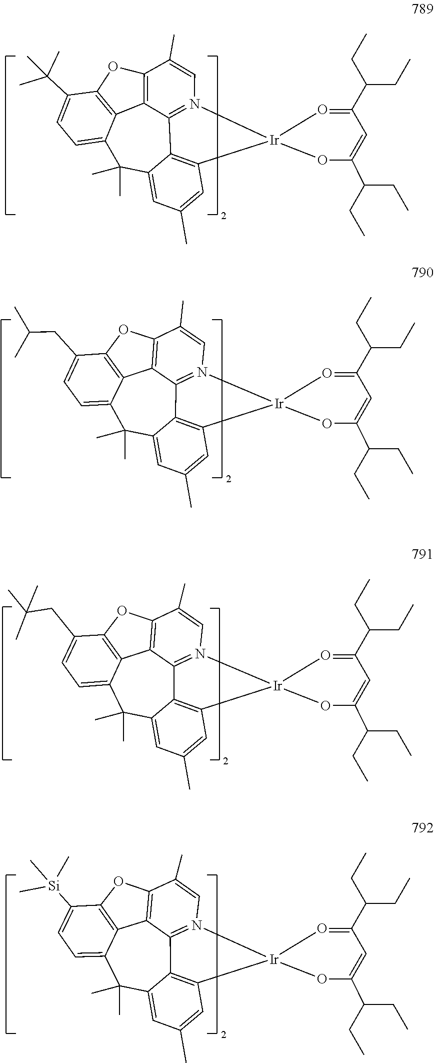

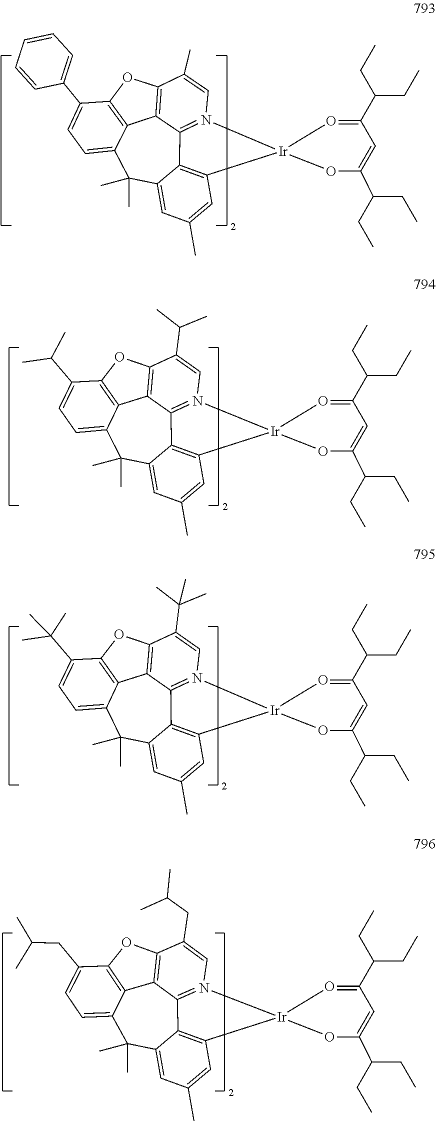

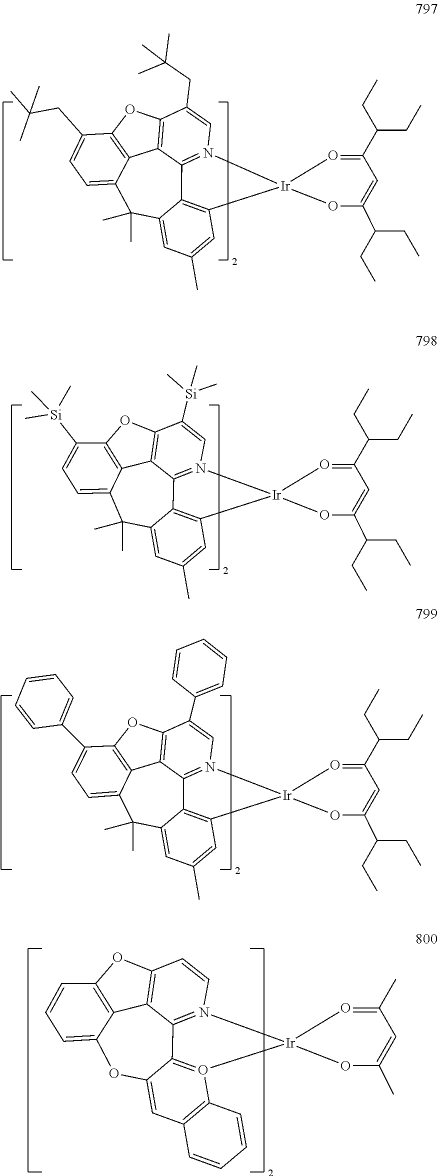

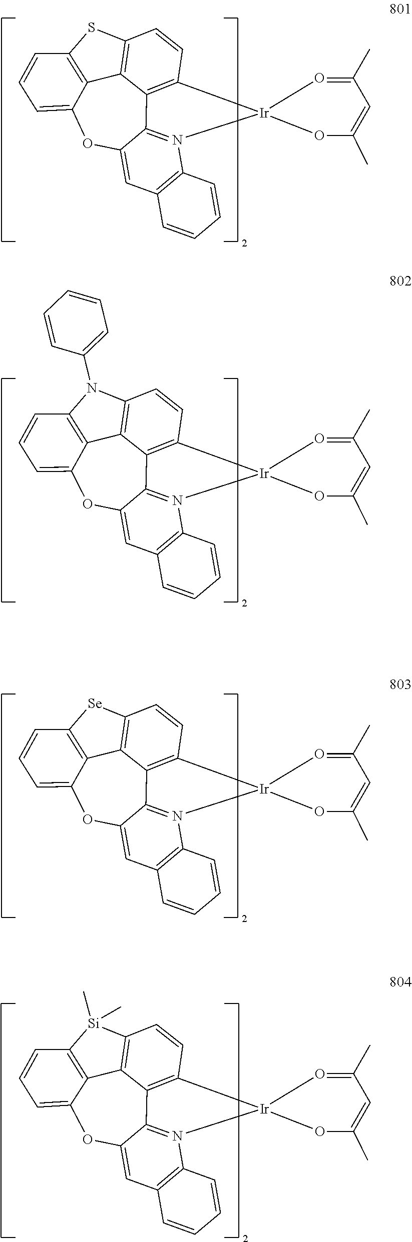

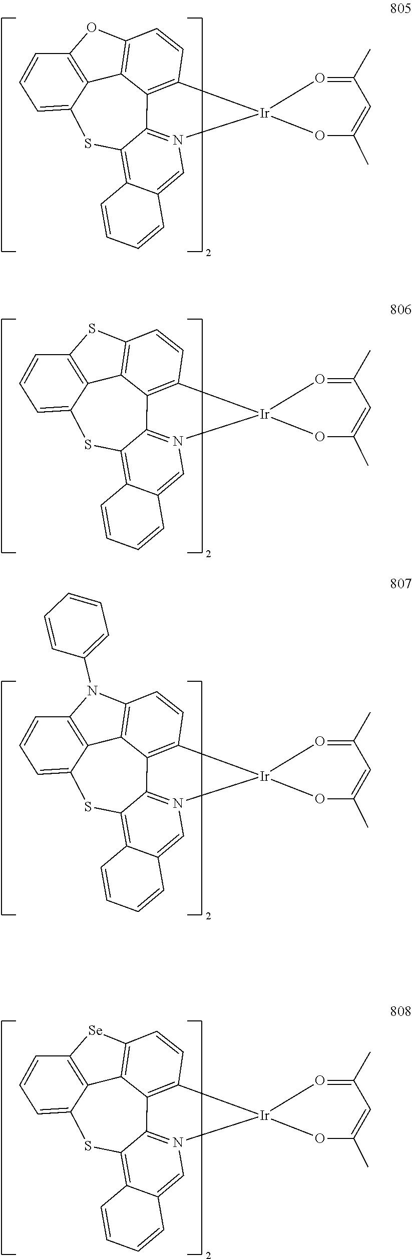

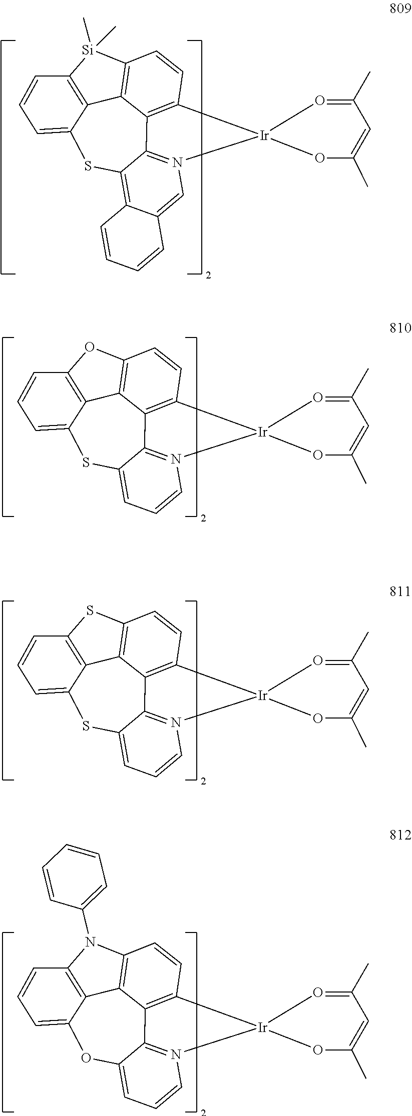

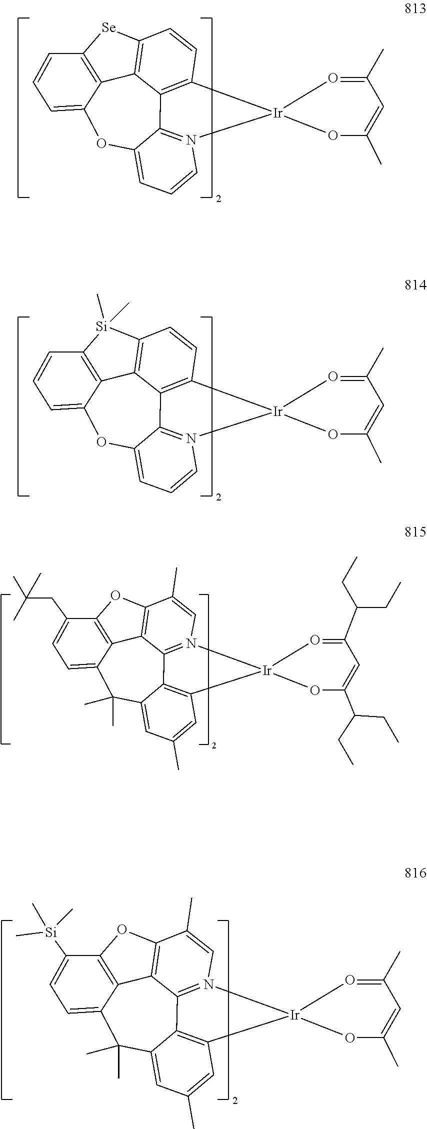

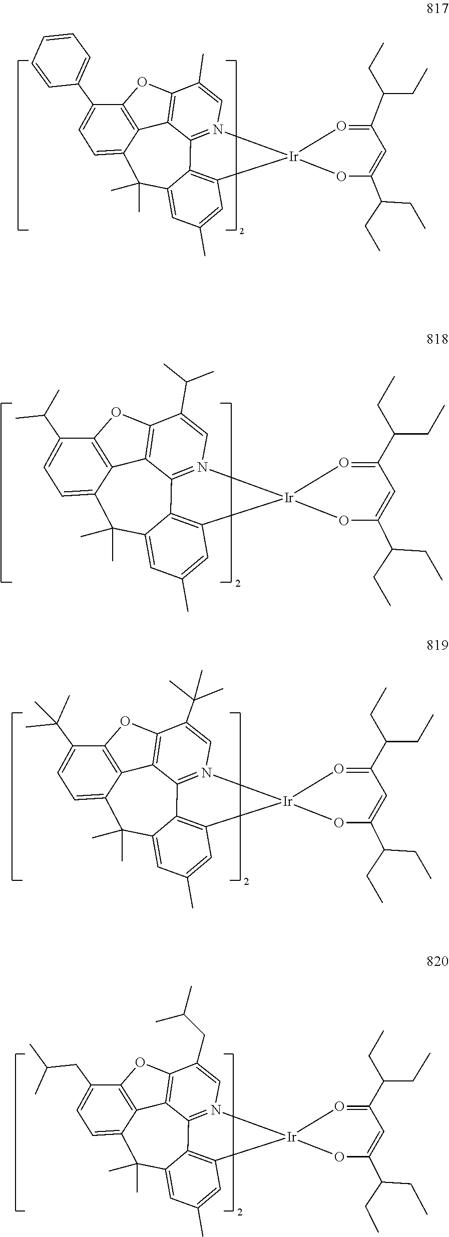

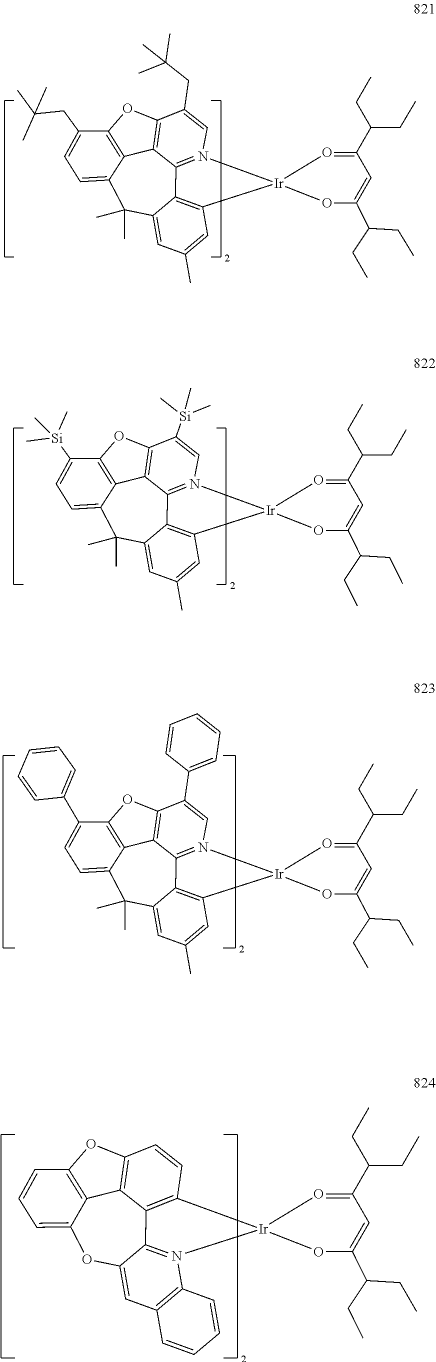

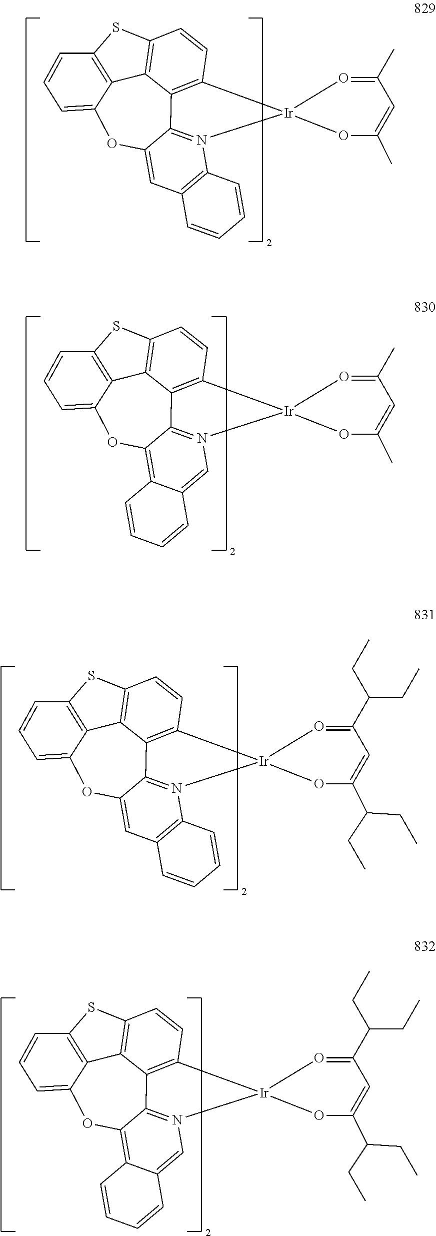

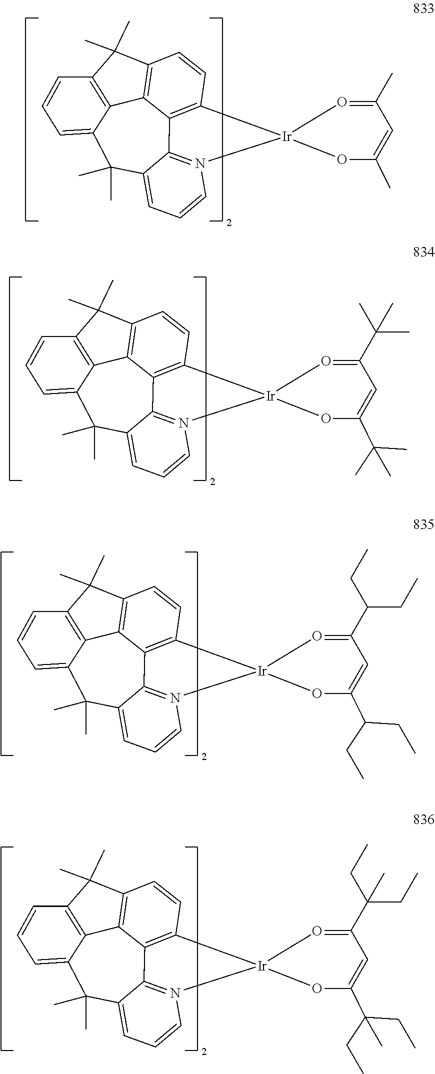

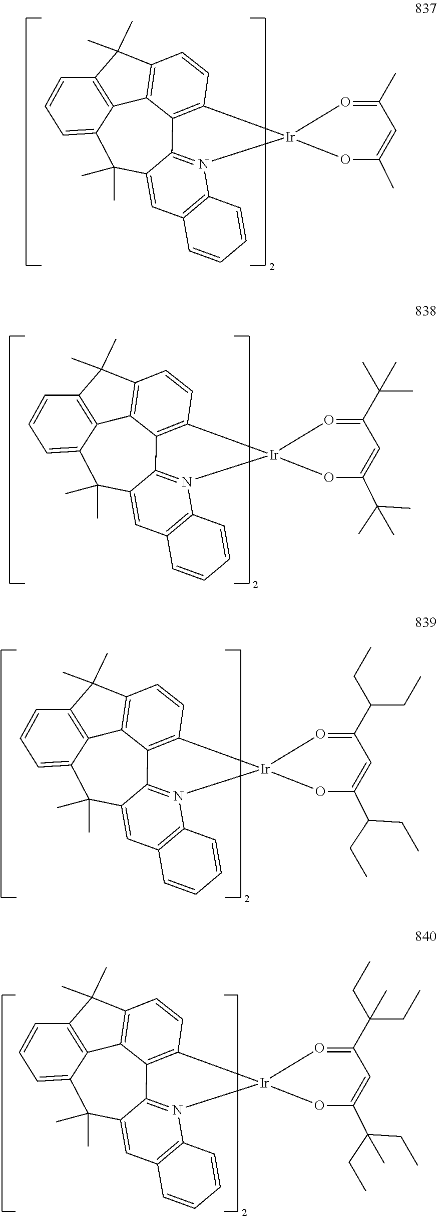

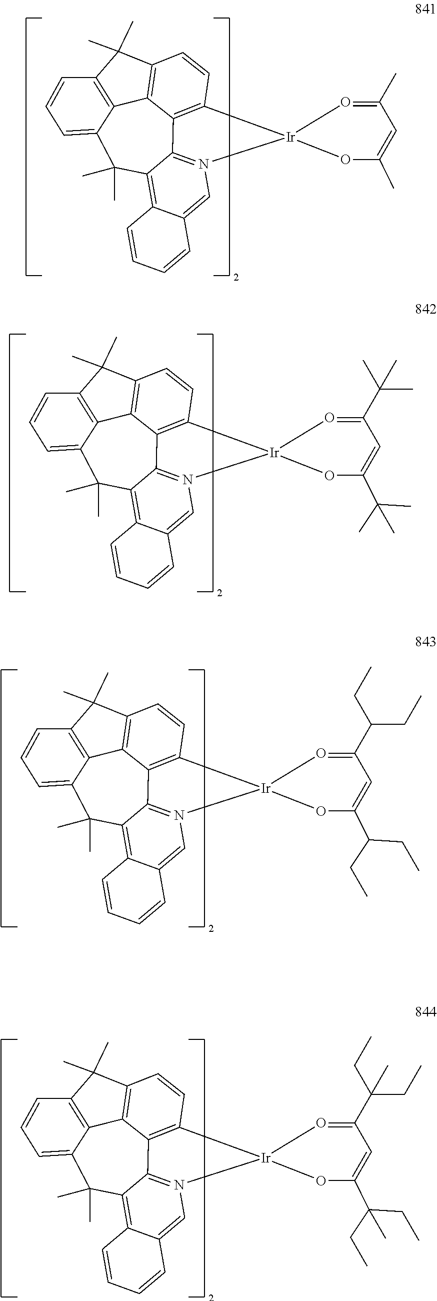

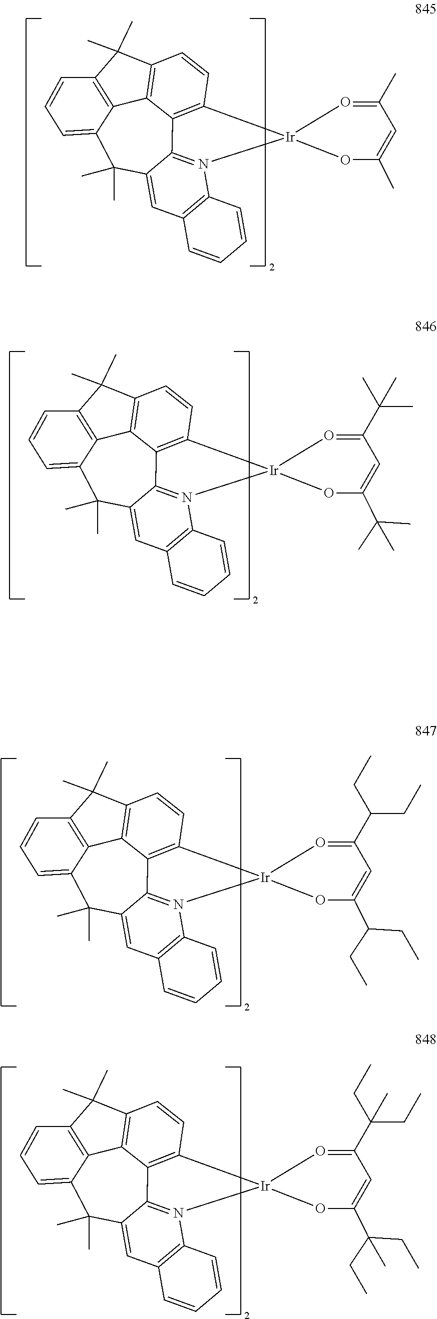

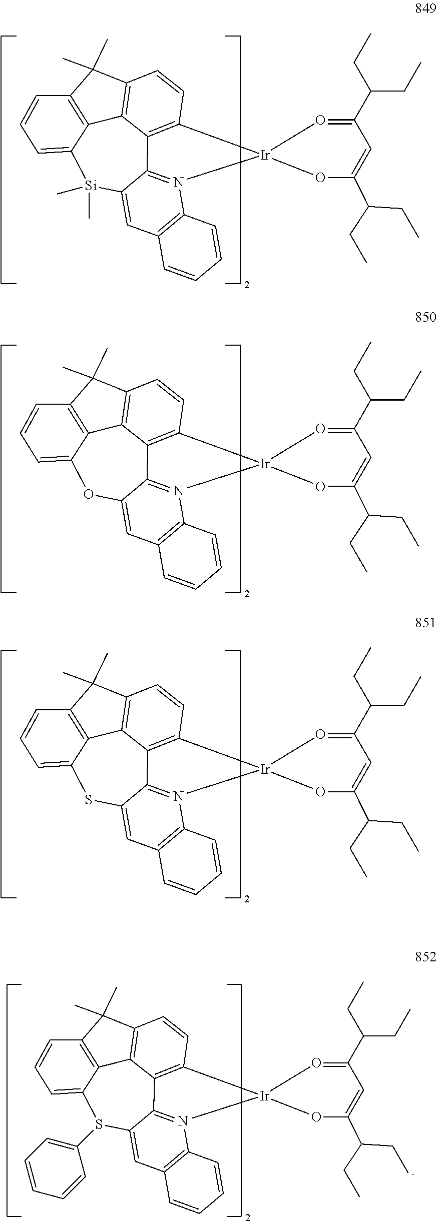

8. An organic light emitting diode comprising:
a first electrode;
a second electrode facing the first electrode; and
an emissive layer disposed between the first and second electrodes and including at least one emitting material layer,
wherein the at least one emitting material layer includes an organic metal compound having the following structure of Formula 1: 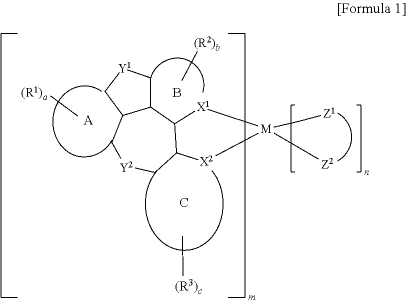
wherein M is molybdenum (Mo), tungsten (W), rhenium (Re), ruthenium (Ru), osmium (Os), rhodium (Rh), iridium (Ir), palladium (Pd), platinum (Pt) or silver (Ag); each of A, B and C is independently a 5-membered or 6-membered aromatic ring or a 5-membered or 6-membered hetero aromatic ring; each of X¹ and X² is independently CR⁴, N or P, one of X¹ and X² is CR⁴ and the other of X¹ and X² is N or P; each of Y¹ and Y² is independently selected from the group consisting of BR⁵, CR⁵R⁶, C═O, C═NR⁵, SiR⁵R⁶, NR⁵, PR⁵, AsR⁵, SbR⁵, BiR⁵, P(O)R⁵, P(S)R⁵, P(Se)R⁵, As(O)R⁵, As(S)R⁵, As(Se)R⁵, Sb(O)R⁵, Sb(S)R⁵, Sb(Se)R⁵, Bi(O)R⁵, Bi(S)R⁵, Bi(Se)R⁵, O, S, Se, Te, SO, SO₂, SeO, SeO₂, TeO and TeO₂; each of R¹ to R⁶ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R¹, adjacent two of R² and adjacent two of R³ independently forms a C₄-C₂₀ alicyclic ring, a C₃-C₂₀ hetero alicyclic ring, a C₆-C₂₀ aromatic ring or a C₃-C₂₀ hetero aromatic ring when each of a, b and c is 2 or more; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of R¹ to R⁶ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by each of adjacent two of R¹, adjacent two of R² and adjacent two of R³ is optionally substituted with at least one C₁-C₁₀ alkyl group; each of a, b and c is a number of substitutent R¹, R² and R³, respectively, a is an integer of 0 to 3, b is an integer of 0 to 2 and c is an integer of 0 to 4; 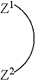
is an acetylacetonate-based auxiliary ligand; m is an integer of 1 to 3, n is an integer of 0 to 2, wherein m plus n is an oxidation number of M.

9. The organic light emitting diode of claim 8, wherein the organic metal compound has the following structure of Formula 2: 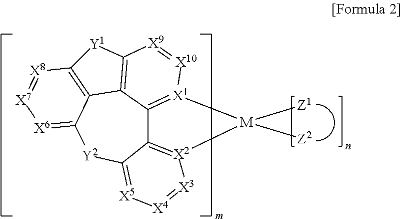
wherein each of M, X¹, X², Y¹, Y², 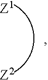
m and n is as same as defined in Formula 1; each of X³ to X⁵ is independently selected from the group consisting of CR⁷, N, P, S and O, wherein at least one of X³ to X⁵ is CR⁷; each of X⁶ to X⁸ is independently selected from the group consisting of CR⁸, N, P, S and O, wherein at least one of X⁶ to X⁸ is CR⁸; each of X⁹ and X¹⁰ is independently selected from the group consisting of CR⁹, N, P, S and O, wherein at least one of X⁹ and X¹⁰ is CR⁹; each of R⁷ to R⁹ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or each of adjacent two of R⁷, adjacent two of R⁸ and adjacent two of R⁹ independently forms a C₄-C₂₀ alicyclic ring, a C₃-C₂₀ hetero alicyclic ring, a C₆-C₂₀ aromatic ring or a C₃-C₂₀ hetero aromatic ring; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of R⁷ to R⁹ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by each of adjacent two of R⁷, adjacent two of R⁸ and adjacent two of R⁹ is optionally substituted with at least one C₁-C₁₀ alkyl group.

10. The organic light emitting diode of claim 9, wherein the organic metal compound has the following structure of Formula 3: 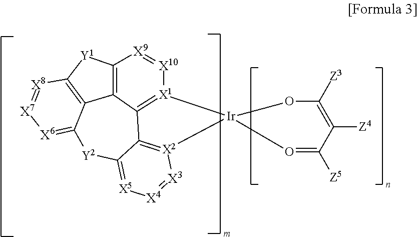
wherein each of X¹ to X¹⁰, Y¹ and Y² is as same as defined in Formula 2; m is an integer of 1 to 3, n is an integer of 0 to 2, wherein m plus n is 3; each of Z³ to Z⁵ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or adjacent two of Z³ to Z⁵ form a C₄-C₂₀ alicyclic ring, a C₃-C₂₀ hetero alicyclic ring, a C₆-C₂₀ aromatic ring or a C₃-C₂₀ hetero aromatic ring; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of Z³ to Z⁵ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by adjacent two of Z³ to Z⁵ is optionally substituted with at least one C₁-C₁₀ alkyl group.

11. The organic light emitting diode of claim 8, wherein the organic metal compound has the following structure of Formula 4: 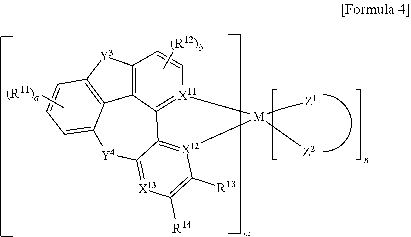
wherein each of M, a, b, m and n is as same as defined in Formula 1; each of X¹¹ to X¹³ is independently CR¹⁵ or N, wherein one of X¹¹ and X¹² is CR¹⁵ and the other of X¹¹ and X¹² is N; each of Y³ and Y⁴ is independently CR¹⁶R¹⁷, NR¹⁶, O, S, Se or SiR¹⁶R¹⁷; each of R¹¹ to R¹⁵ is independently selected from the group consisting of protium, deuterium, a C₁-C₁₀ alkyl group, a C₄-C₂₀ cyclo alkyl group, a C₄-C₂₀ hetero cyclo alkyl group, a C₆-C₂₀ aryl group and a C₃-C₂₀ hetero aryl group, or each of adjacent two of R¹¹ and adjacent two of R¹² independently forms a C₆-C₂₀ aromatic ring or a C₃-C₂₀ hetero aromatic ring unsubstituted or substituted with at least one C₁-C₁₀ alkyl group when each of a and b is 2 or more, or adjacent two of R¹³ to R¹⁵ form a C₆-C₂₀ aromatic ring or a C₃-C₂₀ hetero aromatic ring unsubstituted or substituted with at least one C₁-C₁₀ alkyl group; each of R¹⁶ and R¹⁷ is independently selected from the group consisting of protium, deuterium, a C₁-C₁₀ alkyl group, a C₄-C₂₀ cyclo alkyl group, a C₄-C₂₀ hetero cyclo alkyl group, a C₆-C₂₀ aryl group and a C₃-C₂₀ hetero aryl group.

12. The organic light emitting diode of claim 11, wherein the adjacent two of R¹³ to R¹⁵ in Formula 4 form a C₆-C₁₀ aromatic ring or a C₃-C₁₀ hetero aromatic ring unsubstituted or substituted with at least one C₁-C₁₀ alkyl group.

13. The organic light emitting diode of claim 11, wherein the organic metal compound has the following structure of Formula 5: 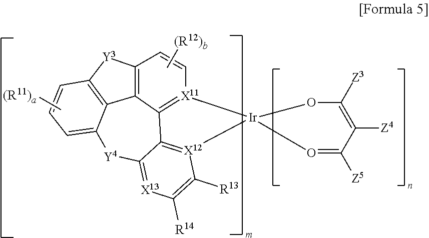
wherein each of R¹¹ to R¹⁴, X¹¹ to X¹³, Y³, Y⁴, a and b is as same as defined in Formula 4; m is an integer of 1 to 3, n is an integer of 0 to 2, wherein m plus n is 3; each of Z³ to Z⁵ is independently selected from the group consisting of protium, deuterium, halogen, a hydroxyl group, a cyano group, a nitro group, a nitrile group, an isonitrile group, a sulfanyl group, a phosphino group, an amidino group, a hydrazine group, a hydrazone group, a carboxylic group, a silyl group, a C₁-C₂₀ alkyl silyl group, a C₁-C₂₀ alkyl group, a C₁-C₂₀ hetero alkyl group, a C₂-C₂₀ alkenyl group, a C₂-C₂₀ hetero alkenyl group, a C₂-C₂₀ alkynyl group, a C₂-C₂₀ hetero alkynyl group, a C₁-C₂₀ alkoxy group, a C₁-C₂₀ alkyl amino group, a C₃-C₂₀ alicyclic group, a C₃-C₂₀ hetero alicyclic group, a C₆-C₃₀ aromatic group and a C₃-C₃₀ hetero aromatic group, or adjacent two of Z³ to Z⁵ form a C₄-C₂₀ alicyclic ring, a C₃-C₂₀ hetero alicyclic ring, a C₆-C₂₀ aromatic ring or a C₃-C₂₀ hetero aromatic ring; each of the C₁-C₂₀ alkyl group, the C₁-C₂₀ hetero alkyl group, the C₂-C₂₀ alkenyl group, the C₂-C₂₀ hetero alkenyl group, the C₁-C₂₀ alkoxy group, the C₁-C₂₀ alkyl amino group, the C₁-C₂₀ alkyl silyl group, the C₃-C₂₀ alicyclic group, the C₃-C₂₀ hetero alicyclic group, the C₆-C₃₀ aromatic group and the C₃-C₃₀ hetero aromatic group of Z³ to Z⁵ is optionally substituted with at least one of deuterium, halogen, C₁-C₂₀ alkyl, a C₄-C₂₀ alicyclic group, a C₃-C₂₀ hetero alicyclic group, a C₆-C₂₀ aromatic group, a C₃-C₂₀ hetero aromatic group; each of the C₄-C₂₀ alicyclic ring, the C₃-C₂₀ hetero alicyclic ring, the C₆-C₂₀ aromatic ring and the C₃-C₂₀ hetero aromatic ring formed by adjacent two of Z³ to Z⁵ is optionally substituted with at least one C₁-C₁₀ alkyl group.

14. The organic light emitting diode of claim 8, wherein the at least one emitting material layer includes a host and a dopant, and wherein the dopant includes the organic metal compound.

15. The organic light emitting diode of claim 8, wherein the emissive layer includes a first emitting part disposed between the first and second electrodes, a second emitting part disposed between the first emitting part and the second electrode and a first charge generation layer disposed between the first and second emitting parts, wherein the first emitting part includes a first emitting material layer and the second emitting part includes a second emitting material layer, and wherein at least one of the first and second emitting material layers includes the organic metal compound.

16. The organic light emitting diode of claim 15, wherein the second emitting material layer includes a lower emitting material layer disposed between the first charge generation layer and the second electrode and an upper emitting material layer disposed between the lower emitting material layer and the second electrode, and wherein one of the lower emitting material layer and the upper emitting material layer includes the organic metal compound.

17. The organic light emitting diode of claim 15, wherein the emissive layer further includes a third emitting part disposed between the second emitting part and the second electrode and including a third emitting material layer and a second charge generation layer disposed between the second and third emitting parts.

18. An organic light emitting device comprising:
a substrate; and
an organic light emitting diode of claim 8 over the substrate.
